(19) United States
(12) Patent Application Publication
(10) Pub. No.: US 2026/0007075 A1
(43) Pub. Date: Jan. 1, 2026

(54) LIGHT-EMITTING ELEMENT, POLYCYCLIC COMPOUND FOR THE SAME, AND ELECTRONIC APPARATUS INCLUDING THE SAME

(71) Applicant: Samsung Display Co., Ltd., Yongin-si (KR)

(72) Inventors: Giwoong HAN, Yongin-si (KR); Taeil KIM, Yongin-si (KR); Mun-Ki SIM, Yongin-si (KR); Sun Young PAK, Yongin-si (KR); Junha PARK, Yongin-si (KR); MinJae SUNG, Yongin-si (KR); Chihyun RYOO, Yongin-si (KR)

(73) Assignee: Samsung Display Co., Ltd., Yongin-si (KR)

(21) Appl. No.: 19/247,503

(22) Filed: Jun. 24, 2025

(30) Foreign Application Priority Data
Jun. 26, 2024 (KR) 10-2024-0083793
Jan. 2, 2025 (KR) 10-2025-0000251

(51) Int. Cl. H10K 85/60; C07F 5/02; C09K 11/02; C09K 11/06; H10K 50/12; H10K 85/30

(52) U.S. Cl. CPC H10K 85/658; C07F 5/027; C09K 11/02; C09K 11/06; H10K 85/346; H10K 85/654; H10K 85/6572; H10K 85/6574; H10K 85/6576; C09K 2211/1007; C09K 2211/1018; H10K 50/12

(57) ABSTRACT

Embodiments provide a light-emitting element that includes a polycyclic compound, an electronic apparatus that includes the light-emitting element, and the polycyclic compound. The light-emitting element includes a first electrode, a second electrode disposed on the first electrode, and an emission layer disposed between the first electrode and the second electrode, wherein the emission layer includes the polycyclic compound. The polycyclic compound is represented by Formula 1, which is explained in the specification:

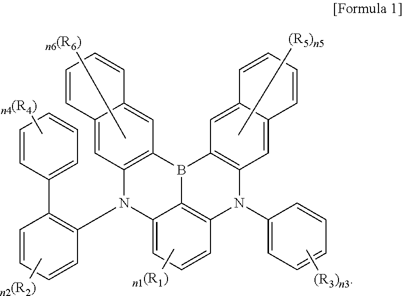

### CROSS-REFERENCE TO RELATED APPLICATION(S)

This application claims priority to and benefits of Korean Patent Application Nos. 10-2024-0083793 and 10-2025-0000251 under 35 U.S.C. § 119, respectively filed on Jun. 26, 2024 and Jan. 2, 2025, in the Korean Intellectual Property Office, the entire contents of which are incorporated herein by reference.

### BACKGROUND

### 1. Technical Field

The disclosure relates to a light-emitting element, a polycyclic compound used for the light-emitting element, and an electronic apparatus including the light-emitting element.

### 2. Description of the Related Art

Ongoing development continues for organic electroluminescence display devices as image display devices. In contrast to liquid display devices and the like, organic electroluminescence display devices are so-called self-emissive display devices in which holes and electrons respectively injected from a first electrode and a second electrode recombine in an emission layer, so that in the emission layer, an emission material that includes an organic compound emits light to achieve display.

In the application of an organic electroluminescent element to display devices, there is a persistent demand for improvements in low-driving voltage and long lifespan. Thus, continuous development is required for materials for an organic electroluminescent element that are capable of stably achieving such characteristics.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light-emitting element having improved luminous efficiency and element lifespan.

The disclosure also provides a polycyclic compound that is capable of improving luminous efficiency of the light emitting element and element lifespan.

The disclosure also provides an electronic apparatus including the light-emitting element having improved luminous efficiency and lifespan to thereby have excellent display quality.

According to an embodiment, a polycyclic compound may be represented by Formula 1:

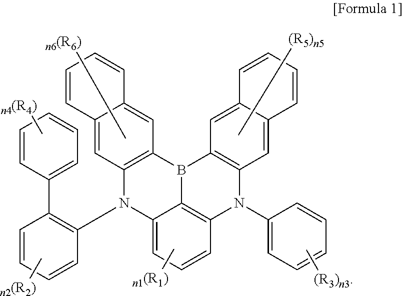

In Formula 1, R₁ to R₆ may each independently be a hydrogen atom, a deuterium atom, a cyano group, a substituted or unsubstituted amine group, a substituted or unsubstituted oxy group, a substituted or unsubstituted thio group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, or bonded to an adjacent group to form a ring; n1 may be an integer from 0 to 3; n2 may be an integer from 0 to 4; n3 and n4 may each independently be an integer from 0 to 5; and n5 and n6 may each independently be an integer from 0 to 6.

In an embodiment, the polycyclic compound represented by Formula 1 may be represented by Formula 2:

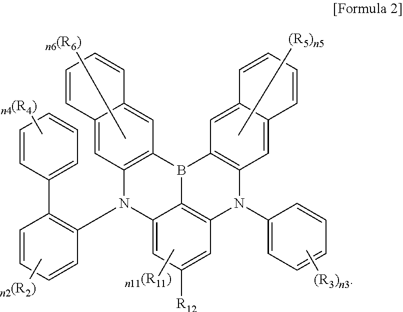

In Formula 2, R₁₁ may be a hydrogen atom, a deuterium atom, a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons; R₁₂ may be a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons; n11 may be an integer from 0 to 2; and R₂ to R₆ and n2 to n6 are the same as defined in Formula 1.

In an embodiment, the polycyclic compound represented by Formula 1 may be represented by Formula 3:

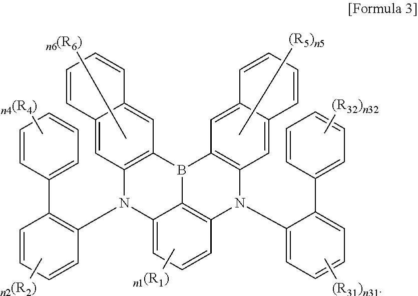

In Formula 3, R₃₁ and R₃₂ may each independently be a hydrogen atom, a deuterium atom, a cyano group, a substituted or unsubstituted amine group, a substituted or unsubstituted oxy group, a substituted or unsubstituted thio group, a substituted or unsubstituted alkyl group having 1 to 30 carbons, a substituted or unsubstituted alkenyl group having 2 to 30 carbons, or a substituted or unsubstituted aryl group having 6 to 30 ring-forming carbons, or bonded to an adjacent group to form a ring; n31 may be an integer from 0 to 4; n32 may be an integer from 0 to 5; and R₁, R₂, R₄ to R₆, n1, n2, and n4 to n6 are the same as defined in Formula 1.

In an embodiment, the polycyclic compound represented by Formula 1 may be represented by one of Formula 4-1 to Formula 4-3:

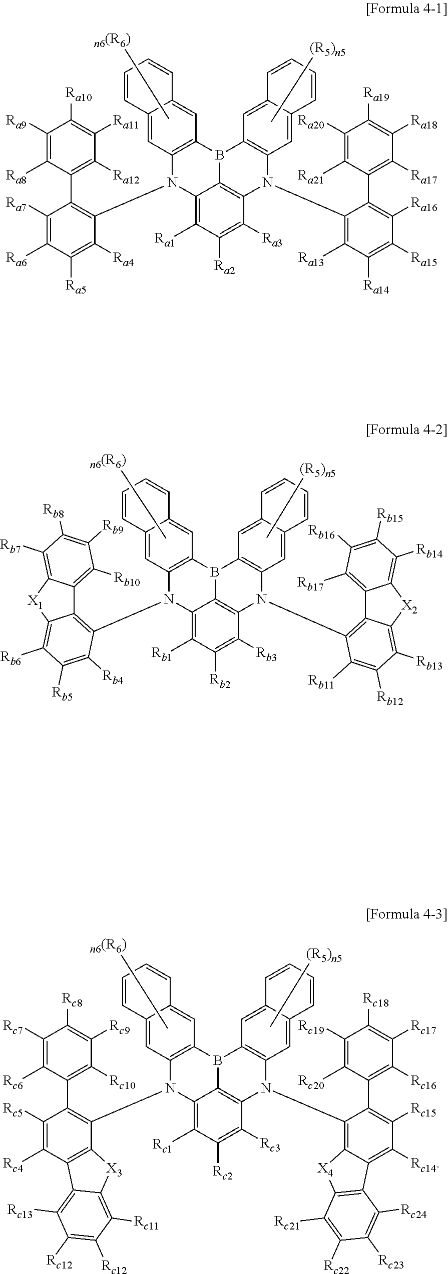

In Formula 4-2 and Formula 4-3, X₁ to X₄ may each independently be O or S. In Formula 4-1 to Formula 4-3, Rₐ₁ to Rₐ₂₁, R_{b1} to R_{b17}, and R_{c1} to R_{c24} may each independently be a hydrogen atom, a deuterium atom, a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons; and R₅, R₆, n5, and n6 are the same as defined in Formula 1.

In an embodiment, the polycyclic compound represented by Formula 1 may be represented by Formula 5-1 or Formula 5-2:

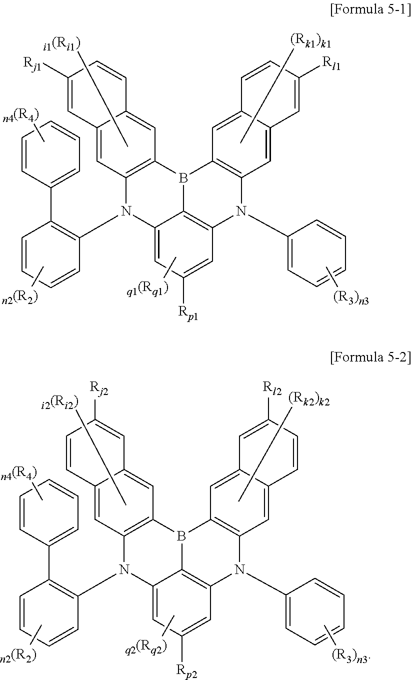

In Formula 5-1 and Formula 5-2, Rᵢ₁, Rᵢ₂, Rⱼ₁, Rⱼ₂, Rₖ₁, Rₖ₂, Rₗ₁, Rₗ₂, Rₚ₁, Rₚ₂, R_{q1}, and R_{q2} may each independently be a hydrogen atom, a deuterium atom, a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons, provided that at least one of Rⱼ₁, Rₗ₁, an Rₚ₁, and at least one of Rⱼ₂, Rₗ₂, and Rₚ₂ may each independently be a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons; i1, i2, k1, and k2 may each independently be an integer from 0 to 5; q1 and q2 may each independently be an integer from 0 to 2; and R₂ to R₄ and n2 to n4 are the same as defined in Formula 1.

In an embodiment, the polycyclic compound represented by Formula 5-1 may be represented by Formula 5-1-1, and the polycyclic compound represented by Formula 5-2 may be represented by Formula 5-2-1:

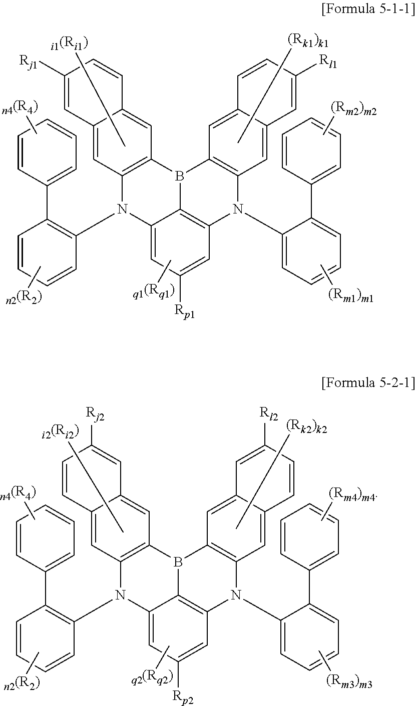

In Formula 5-1-1 and Formula 5-2-1, Rₘ₁, Rₘ₂, Rₘ₃, and Rₘ₄ may each independently be a hydrogen atom, a deuterium atom, a substituted or unsubstituted amine group, a substituted or unsubstituted oxy group, a substituted or unsubstituted thio group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, a substituted or unsubstituted heteroaryl group having 2 to 30 ring-forming carbons, or bonded to an adjacent group to form a ring; m1 and m3 may each independently be an integer from 0 to 4; m2 and m4 may each independently be an integer of 0 to 5; and R₂, R₄, Rᵢ₁, Rᵢ₂, Rⱼ₁, Rⱼ₂, Rₖ₁, Rₖ₂, Rₗ₁, Rₗ₂, Rₚ₁, Rₚ₂, R_{q1}, R_{q2}, n2, n4, i1, i2, k1, k2, q1, and q2 are the same as defined in Formula 1, Formula 5-1, and Formula 5-2.

In an embodiment, the polycyclic compound represented by Formula 1 may have a peak emission wavelength in a range of about 490 nm to about 550 nm.

In an embodiment, the polycyclic compound represented by Formula 1 may be selected from Compound Group 1, which is explained below.

According to an embodiment, a light-emitting element may include a first electrode, a second electrode disposed on the first electrode, and an emission layer disposed between the first electrode and the second electrode, wherein the emission layer includes a first compound represented by Formula 1, which is explained herein.

In an embodiment, the first compound may be represented by Formula 2, which is explained herein.

In an embodiment, the first compound may be represented by Formula 3, which is explained herein.

In an embodiment, the first compound may be represented by one of Formula 4-1 to Formula 4-3, which are explained herein.

In an embodiment, the first compound may be represented by Formula 5-1 or Formula 5-2, which are explained herein.

In an embodiment, the first compound represented by Formula 5-1 may be represented by Formula 5-1-1, which is explained herein.

In an embodiment, the first compound represented by Formula 5-2 may be represented by Formula 5-2-1, which is explained herein.

In an embodiment, the emission layer may emit green light.

In an embodiment, the emission layer may further include at least one of a second compound represented by Formula HT-1, a third compound represented by Formula ET-1, and a fourth compound represented by Formula D-1, which are explained below.

In an embodiment, the first compound may include at least one compound selected from Compound Group 1, which is explained below.

According to an embodiment, an electronic apparatus may include a display device that includes a display panel, the display device displaying an image, wherein:
the display panel may include: a circuit layer disposed on a base layer; and a display element layer disposed on the circuit layer and including a light-emitting element;
the light-emitting element may include: a first electrode; a second electrode disposed on the first electrode; and an emission layer disposed between the first electrode and the second electrode; and
the emission layer may include a polycyclic compound represented by Formula 1, which is explained herein.

In an embodiment, the electronic apparatus may further include at least one of a polarizing layer, a color filter layer, and an optical control layer.

In an embodiment, the optical control layer may include a quantum dot.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a display device according to an embodiment;

FIG. 3 is a schematic cross-sectional view of a light-emitting element according to an embodiment;

FIG. 4 is a schematic cross-sectional view of a light-emitting element according to an embodiment;

FIG. 5 is a schematic cross-sectional view of a light-emitting element according to an embodiment;

FIG. 6 is a schematic cross-sectional view of a light-emitting element according to an embodiment;

FIG. 7 and FIG. 8 are each a schematic cross-sectional view of a display device according to an embodiment;

FIG. 9 is a schematic cross-sectional view of a display device according to an embodiment;

FIG. 10 is a schematic cross-sectional view of a display device according to an embodiment; and

FIG. 11 is a schematic diagram of an interior of a vehicle in which a display device according to an embodiment is disposed.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may refer to a group that is bonded to an adjacent group to form a substituted or unsubstituted hydrocarbon ring or a substituted or unsubstituted heterocycle. A hydrocarbon ring may be aliphatic or aromatic. A heterocycle may be aliphatic or aromatic. A hydrocarbon ring and a heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, and an iodine atom.

In the specification, an alkyl group may be linear or branched. The number of carbons in an alkyl group may be 1 to 50, 1 to 30, 1 to 20, 1 to 10, or 1 to 6. Examples of a alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbons in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not particularly limited, and may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group that includes at least one carbon-carbon triple bond in the middle or at a terminus of an alkyl group having 2 or more carbon atoms. An alkynyl group may be linear or branched. The number of carbon atoms is not particularly limited, and may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring or an aromatic hydrocarbon ring. For example, a hydrocarbon ring group may be a saturated hydrocarbon ring group having 6 to 30, 5 to 30, or 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 30, 6 to 20, or 6 to 15.

Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below. However, embodiments are not limited thereto.

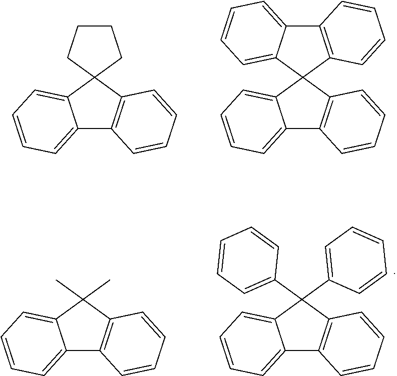

In the specification, a heterocyclic group may be any functional group or substituent derived from a ring that includes at least one of B, O, N, P, Si, and S as a heteroatom. A heterocyclic group may be aliphatic or aromatic. An aromatic heterocyclic group may be a heteroaryl group. An aliphatic heterocycle and an aromatic heterocycle may each independently be monocyclic or polycyclic.

If a heterocyclic group includes two or more heteroatoms, the two or more heteroatoms may be the same as or different from each other. The number of ring-forming carbon atoms in a heterocyclic group may be 2 to 30, 2 to 20, or 2 to 10.

Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not particularly limited, and may be 1 to 40, 1 to 30, or 1 to 20. For example, a carbonyl group may include one of the following structures, but embodiments are not limited thereto.

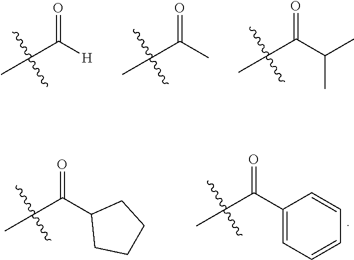

In the specification, the number of carbon atoms in a sulfinyl group or a sulfonyl group is not particularly limited, and may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not particularly limited, and may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not particularly limited, and may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group within an alkylthio group, an alkylsulfoxy group, an alkylaryl group, an alkylamino group, an alkyl boron group, an alkyl silyl group, or an alkyl amine group may be the same as an example of an alkyl group as described above.

In the specification, an aryl group within an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond.

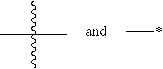

In the specification, the symbols and each represent a bond to a neighboring atom in a corresponding formula or moiety.

Hereinafter, embodiments will be described with reference to the accompanying drawings.

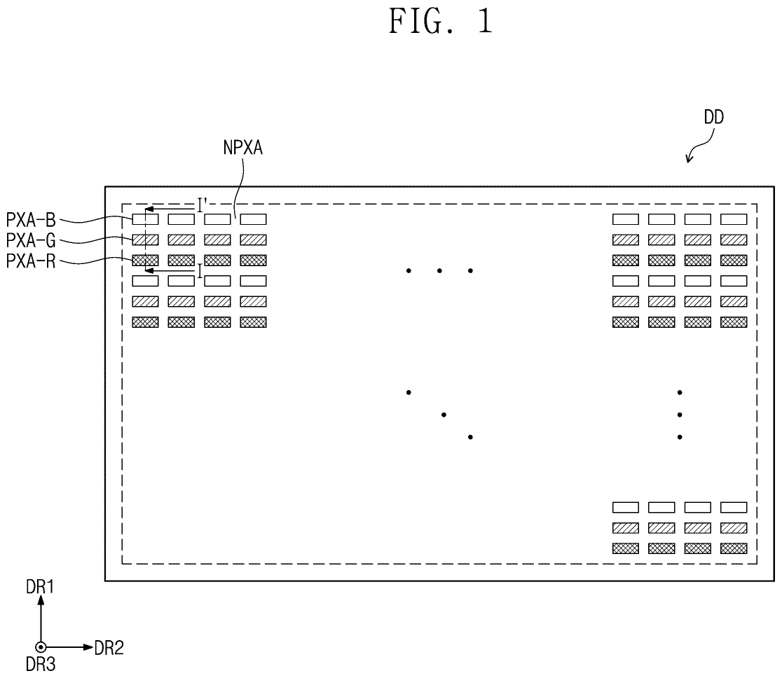

FIG. 1 is a schematic plan view of a display device DD according to an embodiment.

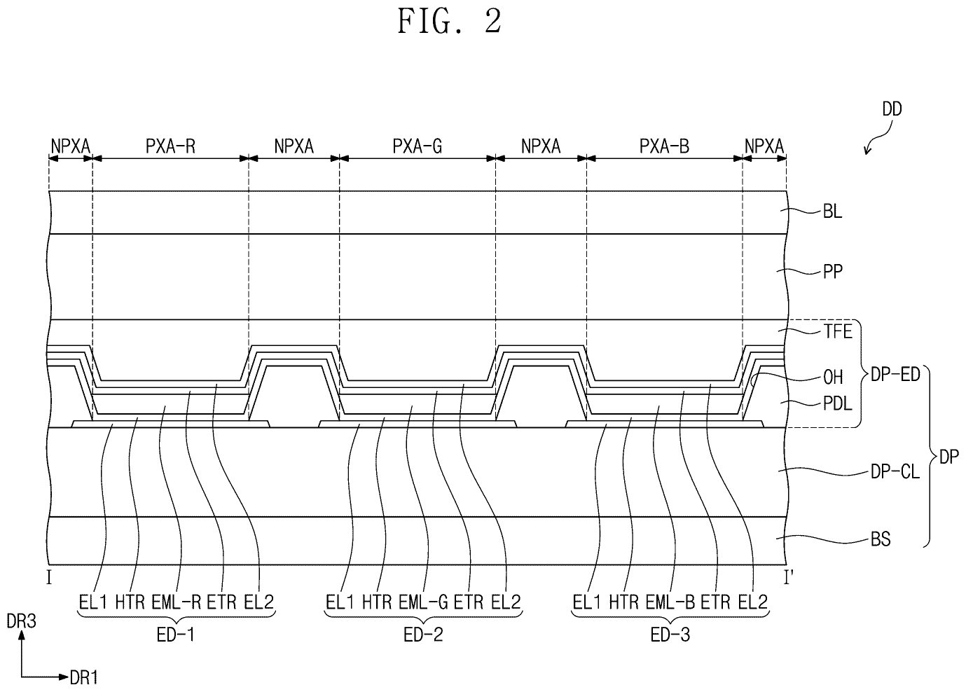

FIG. 2 is a schematic cross-sectional view of the display device DD. FIG. 2 is a schematic cross-sectional view of a portion taken along virtual line I-I′ in FIG. 1.

The display device DD may include a display panel DP and an optical layer PP disposed on the display panel DP. The display panel DP includes light-emitting elements ED-1, ED-2, and ED-3. The display device DD may include multiples of each of the light-emitting elements ED-1, ED-2, and ED-3. The optical layer PP may be disposed on the display panel DP to control light that is reflected at the display panel DP from an external light. The optical layer PP may include, for example, a polarization layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display element layer DP-ED and the base substrate BL. The filling layer (not shown) may be an organic material layer. The filling layer (not shown) may include at least one of an acrylic-based resin, a silicone-based resin, and an epoxy-based resin.

The display panel DP may include a base layer BS, a circuit layer DP-CL provided on the base layer BS, and the display element layer DP-ED. The display element layer DP-ED may include a pixel defining film PDL, light-emitting elements ED-1, ED-2, and ED-3 disposed between portions of the pixel defining film PDL, and an encapsulation layer TFE disposed on the light-emitting elements ED-1, ED-2, and ED-3.

The base layer BS may provide a base surface on which the display element layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light-emitting elements ED-1, ED-2, and ED-3 of the display element layer DP-ED.

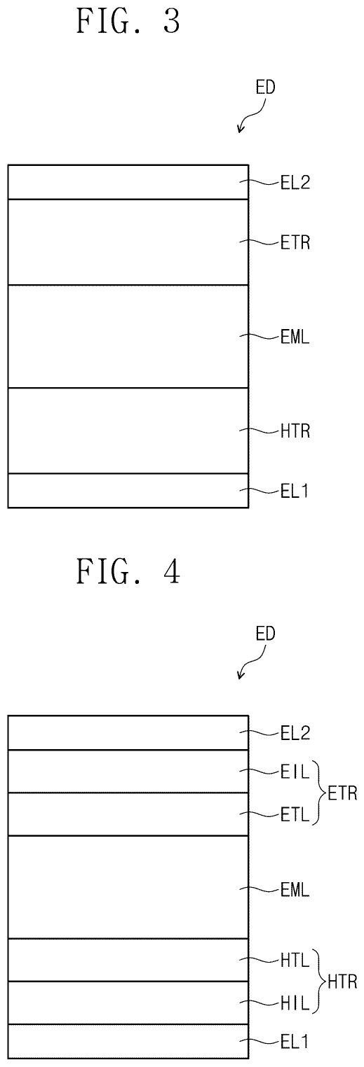

The light-emitting elements ED-1, ED-2, and ED-3 may each have a structure of a light-emitting element ED according to any one of FIGS. 3 to 6, which will be described later. The light-emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light-emitting elements ED-1, ED-2, and ED-3 are disposed in openings OH defined in the pixel defining film PDL, and the hole transport region HTR, the electron transport region ETR, and the second electrode EL2 are each provided as a common layer for the light-emitting elements ED-1, ED-2, and ED-3. However, embodiments are not limited thereto. Although not shown in FIG. 2, in an embodiment, the hole transport region HTR and the electron transport region ETR may each be provided by being patterned in the openings OH defined in the pixel defining film PDL. For example, in an embodiment, the hole transport region HTR, the emission layers EML-R, EML-G, and EML-B, and the electron transport region ETR of the light-emitting elements ED-1, ED-2, and ED-3 may be provided by being patterned through an inkjet printing method.

The encapsulation layer TFE may cover the light-emitting elements ED-1, ED-2, and ED-3. The encapsulation layer TFE may seal the display element layer DP-ED. The encapsulation layer TFE may be a thin film encapsulation layer. The encapsulation layer TFE may be formed of a single layer or of multiple layers. The encapsulation layer TFE may include at least one insulation layer. The encapsulation layer TFE according to an embodiment may include at least one inorganic film (hereinafter, an encapsulation-inorganic film). The encapsulation layer TFE according to an embodiment may include at least one organic film (hereinafter, an encapsulation-organic film) and at least one encapsulation-inorganic film.

The encapsulation-inorganic film protects the display element layer DP-ED from moisture and/or oxygen, and the encapsulation-organic film protects the display element layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region that emits light respectively generated by the light-emitting elements ED-1, ED-2, and ED-3. The light emitting regions PXA-R, PXA-G, and PXA-B may be spaced apart from each other in a plan view.

The light emitting regions PXA-R, PXA-G, and PXA-B may be regions that are separated from each other by the pixel defining film PDL. The non-light emitting regions NPXA may be regions between the adjacent light emitting regions PXA-R, PXA-G, and PXA-B, and which may correspond to the pixel defining film PDL. In an embodiment, the light emitting regions PXA-R, PXA-G, and PXA-B may each correspond to a pixel. The pixel defining film PDL may separate the light-emitting elements ED-1, ED-2, and ED-3. The emission layers EML-R, EML-G, and EML-B of the light-emitting elements ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light-emitting elements ED-1, ED-2, and ED-3. In the display device DD according to an embodiment shown in FIGS. 1 and 2, three light emitting regions PXA-R, PXA-G, and PXA-B, which respectively emit red light, green light, and blue light, are illustrated as an example. For example, the display device DD may include a red light emitting region PXA-R, a green light emitting region PXA-G, and a blue light emitting region PXA-B, which are distinct from each other.

In the display device DD according to an embodiment, the light-emitting elements ED-1, ED-2, and ED-3 may emit light having wavelengths that are different from each other. For example, in an embodiment, the display device DD may include a first light-emitting element ED-1 that emits red light, a second light-emitting element ED-2 that emits green light, and a third light-emitting element ED-3 that emits blue light. For example, the red light emitting region PXA-R, the green light emitting region PXA-G, and the blue light emitting region PXA-B of the display device DD may respectively correspond to the first light-emitting element ED-1, the second light-emitting element ED-2, and the third light-emitting element ED-3.

However, embodiments are not limited thereto, and the first to third light-emitting elements ED-1, ED-2, and ED-3 may emit light in a same wavelength range, or at least one light-emitting element may emit light in a wavelength range that is different from the remainder. For example, the first to third light-emitting elements ED-1, ED-2, and ED-3 may each emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be arranged in this repeating order along a first directional axis DR1.

FIGS. 1 and 2 illustrate that the light emitting regions PXA-R, PXA-G, and PXA-B all have a similar area, but embodiments are not limited thereto. In an embodiment, the light emitting regions PXA-R, PXA-G, and PXA-B may be different in size and/or shape from each other, according to a wavelength range of emitted light. The areas of the light emitting regions PXA-R, PXA-G, and PXA-B may be areas in a plan view that are defined by the first directional axis DR1 and the second directional axis DR2. A third directional axis DR3 may be perpendicular to a plane defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations, according to the display quality characteristics that are required for the display device DD. For example, the light emitting regions PXA-R, PXA-G, and PXA-B may be arranged in a pentile configuration (such as PenTile®) or in a diamond configuration (such as Diamond Pixel®).

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

Hereinafter, FIG. 3 to FIG. 6 are each a schematic cross-sectional view of a light-emitting element ED according to an embodiment. The light-emitting element ED according to an embodiment may include a first electrode EL1, a second electrode EL2 facing the first electrode EL1, and at least one functional layer disposed between the first electrode EL1 and the second electrode EL2. The light-emitting element ED according to an embodiment may include a polycyclic compound according to an embodiment, which will be described below, in the at least one functional layer.

The light-emitting element ED may include, as the at least one functional layer, a hole transport region HTR, an emission layer EML, an electron transport region ETR, etc., which may be stacked in that order. For example, as shown in FIG. 3, the light-emitting element ED according to an embodiment may include a first electrode EL1, a hole transport region HTR, an emission layer EML, an electron transport region ETR, and a second electrode EL2, stacked in that order.

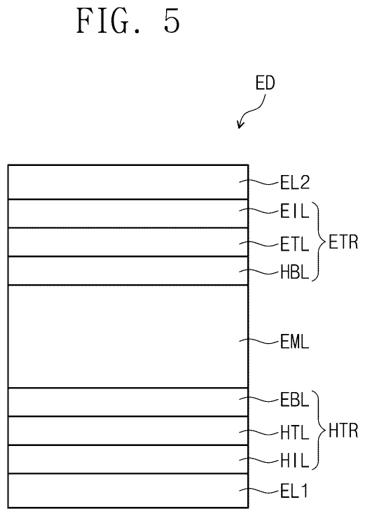

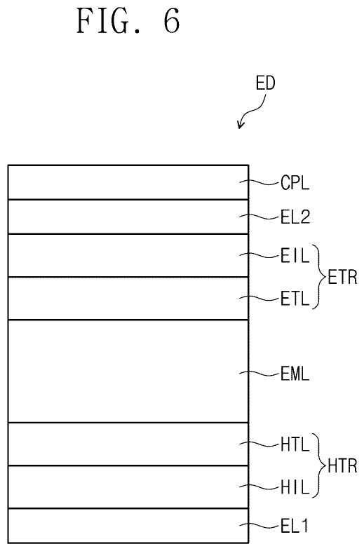

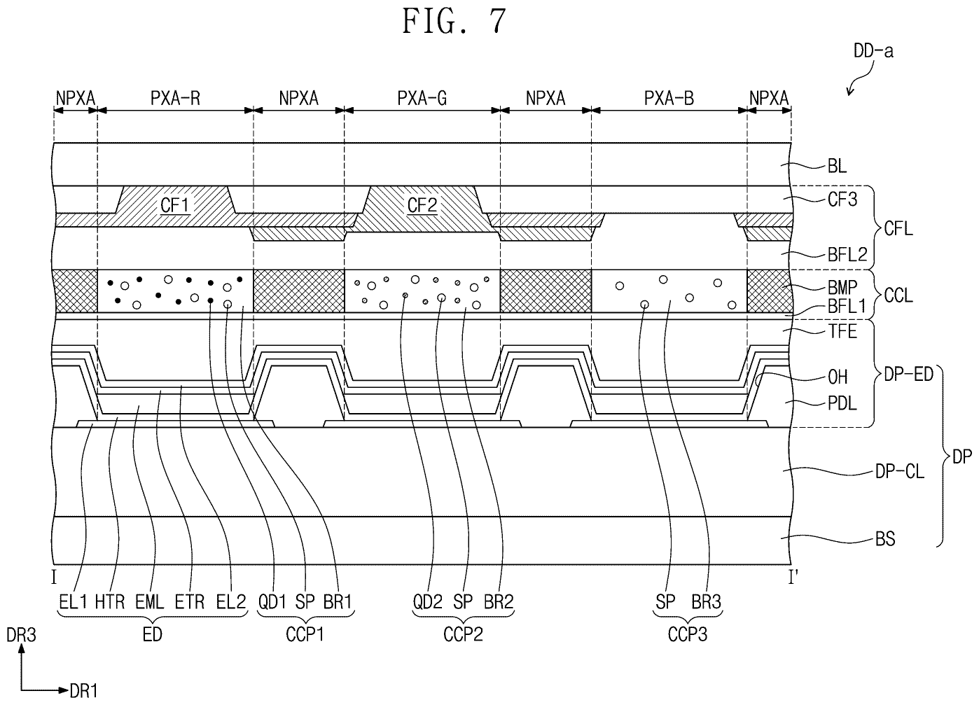

In comparison to FIG. 3, FIG. 4 is a schematic cross-sectional view of a light-emitting element ED, in which a hole transport region HTR includes a hole injection layer HIL and a hole transport layer HTL, and an electron transport region ETR includes an electron injection layer EIL and an electron transport layer ETL. In comparison to FIG. 3, FIG. 5 is a schematic cross-sectional view of a light-emitting element ED, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 is a schematic cross-sectional view of a light-emitting element ED, in which a capping layer CPL is disposed on a second electrode EL2.

The light-emitting element ED according to an embodiment may include, in the at least one functional layer included in the light-emitting element ED, a polycyclic compound according to an embodiment, which will be described below. In the light-emitting element ED according to an embodiment, at least one of a hole transport region HTR, an emission layer EML, and an electron transport region ETR may include the polycyclic compound according to an embodiment. For example, in the light-emitting element ED, the emission layer EML may include the polycyclic compound according to an embodiment.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, and a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayered structure that includes a reflective film or a transflective film formed of the above-described materials, and a transparent conductive film formed of ITO, IZO, ZnO, ITZO, etc. For example, the first electrode EL1 may have a three-layered structure of ITO/Ag/ITO, but embodiments are not limited thereto. In an embodiment, the first electrode EL1 may include the above-described metal materials, combinations of at least two of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), an emission-auxiliary layer (not shown), and an electron blocking layer EBL. A thickness of the hole transport region HTR may be, for example, in a range of about 50 Å to about 15,000 Å.

The hole transport region HTR may have a structure consisting of a layer consisting of a single material, a structure consisting of a layer including different materials, or a structure including multiple layers including different materials.

For example, the hole transport region HTR may have a single-layered structure of a hole injection layer HIL or a hole transport layer HTL, or the hole transport region HTR may have a single-layered structure formed of a hole injection material and a hole transport material. In embodiments, the hole transport region HTR may have a hole injection layer HIL/hole transport layer HTL structure, a hole injection layer HIL/hole transport layer HTL/buffer layer (not shown) structure, a hole injection layer HIL/buffer layer (not shown) structure, a hole transport layer HTL/buffer layer (not shown) structure, or a hole injection layer HIL/hole transport layer HTL/electron blocking layer EBL structure, in which the layers of each structure may be stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In light-emitting element ED according to an embodiment, the hole transport region HTR may include a compound represented by Formula H-1:

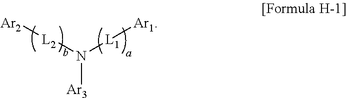

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ or multiple L₂ may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In an embodiment, the compound represented by Formula H-1 may be a monoamine compound. In another embodiment, the compound represented by Formula H-1 may be a diamine compound in which at least one of Ar₁ to Arₙ includes an amine group as a substituent. In an embodiment, the compound represented by Formula H-1 may be a carbazole-based compound in which at least one of Ar₁ and Ar₂ includes a substituted or unsubstituted carbazole group, or may be a fluorene-based compound in which at least one of Ar₁ and Ar₂ includes a substituted or unsubstituted fluorene group.

The compound represented by Formula H-1 may be any compound selected from Compound Group H. However, the compounds listed in Compound Group H are only examples, and a compound represented by Formula H-1 is not limited to Compound Group H:

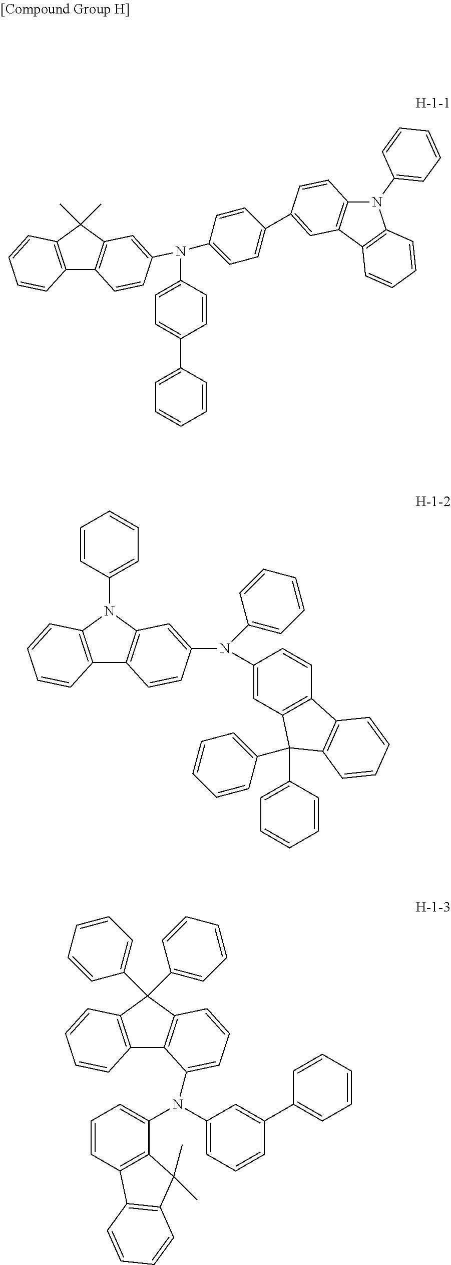 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

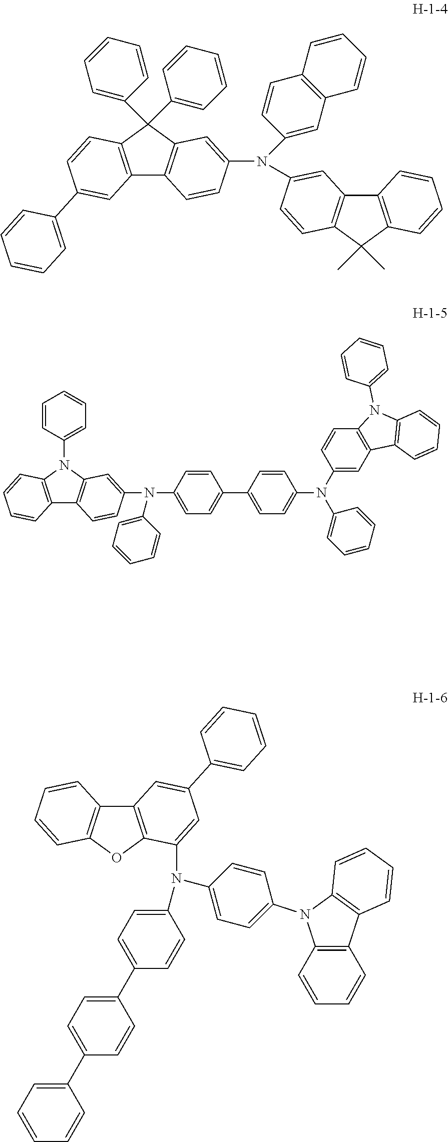 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

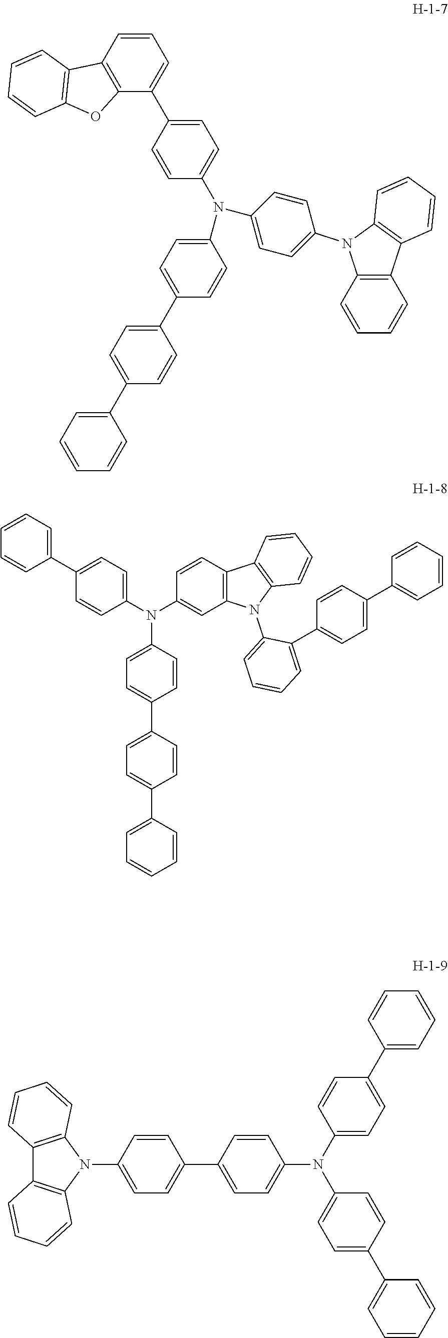 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

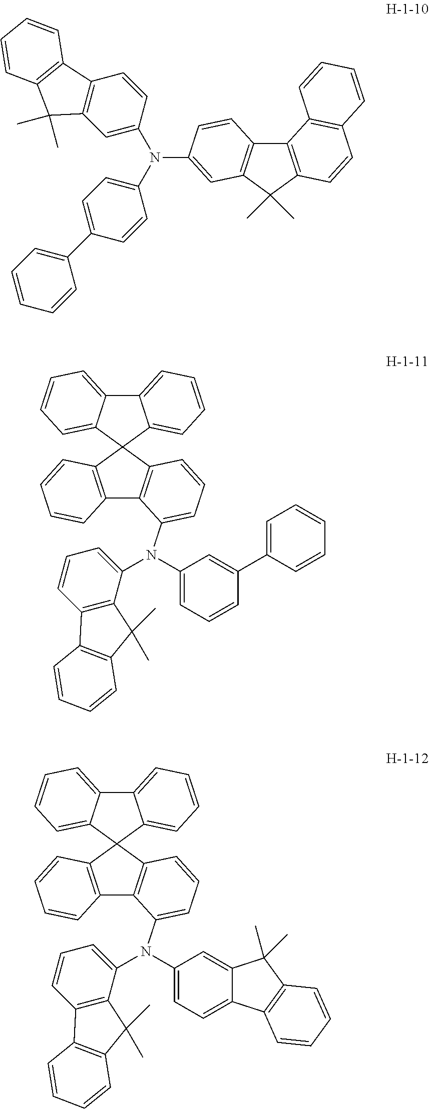 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21]

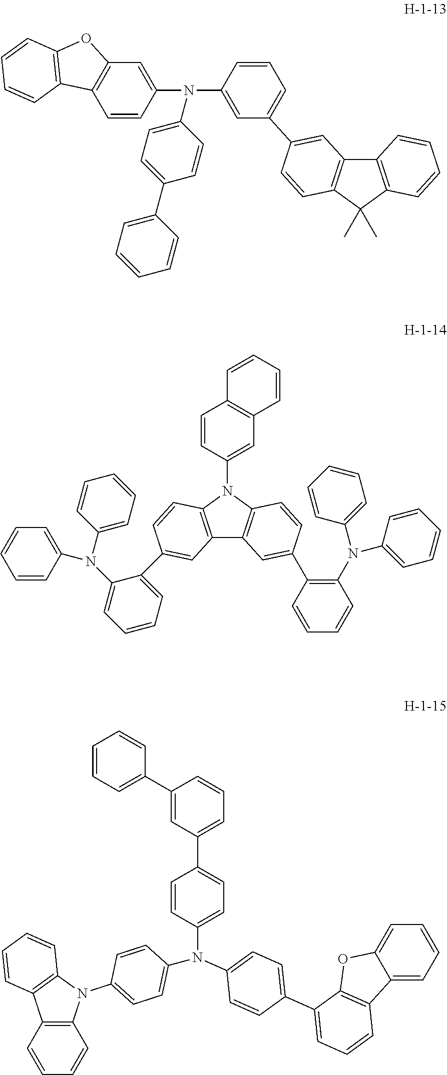 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

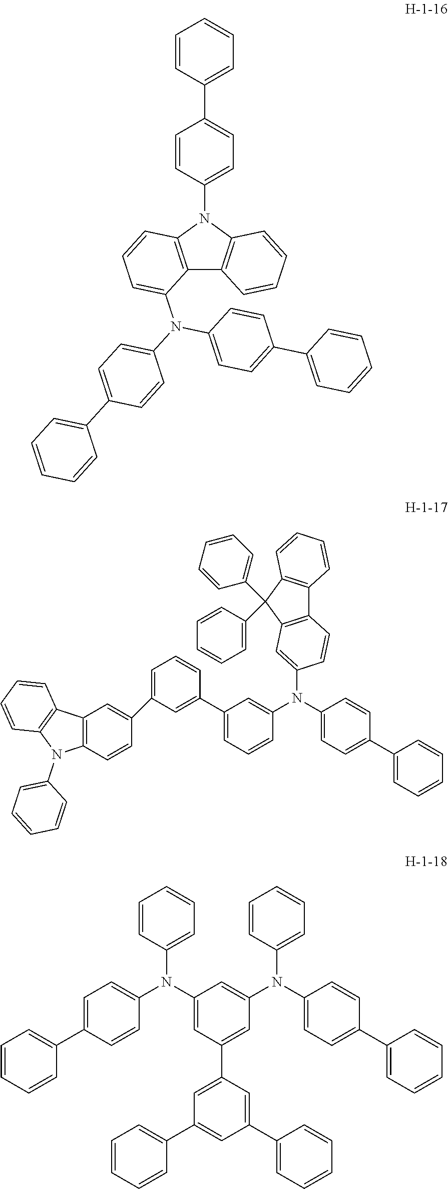 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

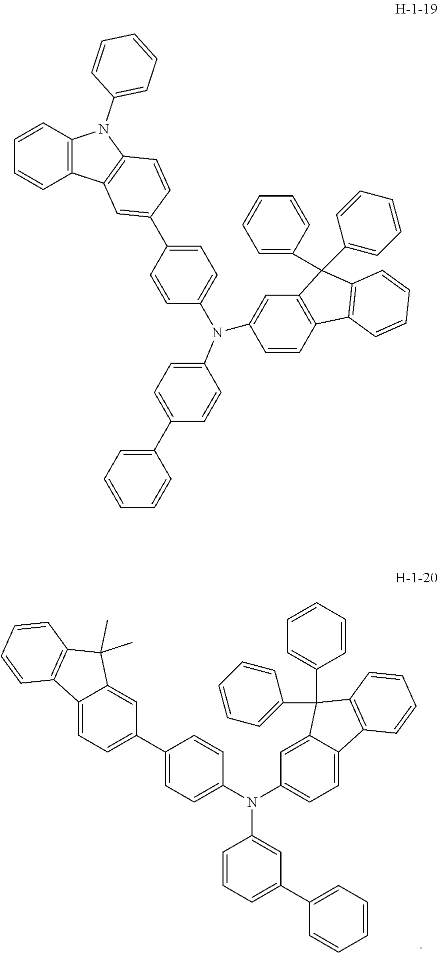 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; CC1(C)c2ccccc2-c2ccc(-c3ccc(N(c4cccc(-c5ccccc5)c4)c4ccc5c(c4)C(c4ccccc4)(c4ccccc4)c4ccccc4-5)cc3)cc21]

The hole transport region HTR may include a phthalocyanine compound such as copper phthalocyanine, N¹,N^{1′}-([1,1′-biphenyl]-4,4′-diyl)bis(N¹-phenyl-N4,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HAT-CN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD), 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), or 1,3-bis(N-carbazolyl)benzene (mCP), etc.

In an embodiment, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region HTR in at least one of a hole injection layer HIL, a hole transport layer HTL, and an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have a thickness in a range of about 30 Å to about 1,000 Å. When the hole transport region HTR includes a hole transport layer HTL, the hole transport layer HTL may have a thickness in a range of about 250 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a metal halide, a quinone derivative, a metal oxide, and a cyano group-containing compound, but embodiments are not limited thereto. For example, the p-dopant may include a metal halide such as CuI or RbI, a quinone derivative such as tetracyanoquinodimethane (TCNQ) or 2,3,5,6-tetrafluoro-7,7,8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HAT-CN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) and an electron blocking layer EBL, in addition to a hole injection layer HIL and a hole transport layer HTL. The buffer layer (not shown) may compensate for a resonance distance according to a wavelength of light emitted from the emission layer EML and may thus increase light emission efficiency. A material that may be included in the hole transport region HTR may be used as a material in the buffer layer (not shown). The electron blocking layer EBL may prevent the injection of electrons from an electron transport region ETR to the hole transport region HTR.

The emission layer EML may be provided on the hole transport region HTR. The emission layer EML may have a thickness in a range of about 100 Å to about 1,000 Å. For example, the emission layer EML may have a thickness in a range of about 100 Å to about 300 Å. The emission layer EML may have a structure consisting of a layer consisting of a single material, a structure consisting of a layer including different materials, or a structure including multiple layers including different materials.

The light-emitting element ED according to an embodiment may include a polycyclic compound represented by Formula 1 in at least one functional layer disposed between a first electrode EL1 and a second electrode EL2. The functional layer may include a hole transport region HTR, an emission layer EML, and an electron transport region ETR. For example, the light-emitting element ED may include a polycyclic compound according to an embodiment in the emission layer EML. In an embodiment, the emission layer EML may include the polycyclic compound according to an embodiment as a dopant. The polycyclic compound according to an embodiment may be a dopant material in the emission layer EML. In the specification, the polycyclic compound according to an embodiment may be referred to as a first compound.

The polycyclic compound according to an embodiment may include a core structure having seven rings in which two naphthalene group and a benzene group are fused via two nitrogen atoms and a boron atom. In the polycyclic compound according to an embodiment, the core may include a first nitrogen atom, a second nitrogen atom, and a boron atom as ring forming atoms, and may include a first naphthalene ring, a second naphthalene ring, and a benzene ring, and the first naphthalene, second naphthalene, and benzene rings may be connected via the first nitrogen atom, the second nitrogen atom, and the boron atom. In the core, the first nitrogen atom and the boron atom may be connected to the first naphthalene, and the second nitrogen atom and the boron atom may be connected to the second naphthalene. The benzene ring of the core may be connected to the first nitrogen atom, the second nitrogen atom, and the boron atom. In the polycyclic compound according to an embodiment, the core may be a structure represented by Formula CR. In Formula CR, symbols that designate a substituent connected to the core are omitted, but the polycyclic compound according to an embodiment may include various substituents connected to the core.

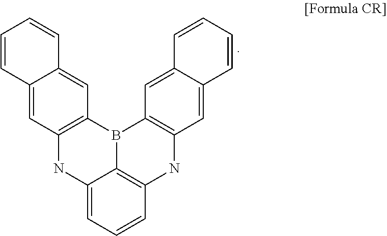 [SMILES: c1cc2c3c(c1)Nc1cc4ccccc4cc1B3c1cc3ccccc3cc1N2]

The polycyclic compound according to an embodiment may include a steric protection substituent for protecting the core. The steric protection substituent may be connected to at least one nitrogen atom of the core and surround the core, and thus protect an unoccupied p-orbital of the boron atom in the core. For example, the steric protection substituent may be a substituted or unsubstituted biphenyl group in which a benzene ring of the biphenyl group is bonded at an ortho position to a nitrogen atom of the core.

The polycyclic compound according to an embodiment may be represented by Formula

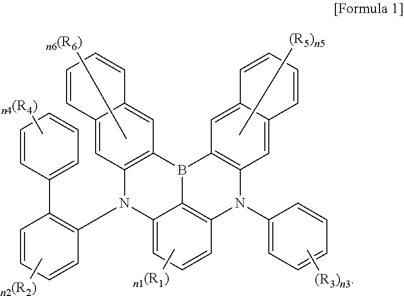

In Formula 1, R₁ to R₆ may each independently be a hydrogen atom, a deuterium atom, a cyano group, a substituted or unsubstituted amine group, a substituted or unsubstituted oxy group, a substituted or unsubstituted thio group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, or bonded to an adjacent group to form a ring. For example, R₁ to R₆ may each independently be a hydrogen atom, a deuterium atom, a substituted or unsubstituted methyl group, a substituted or unsubstituted t-butyl group, a substituted or unsubstituted arylamine group, a substituted or unsubstituted aryloxy group, a substituted or unsubstituted arylthio group, a substituted or unsubstituted phenyl group, a substituted or unsubstituted biphenyl group, a substituted or unsubstituted carbazole group, a substituted or unsubstituted dibenzofuran group, or a substituted or unsubstituted dibenzothiophene group, but embodiments are not limited thereto. For example, R₁ to R₆ may each independently be bonded to an adjacent group to form a heterocycle.

In Formula 1, n1 may be an integer from 0 to 3. If n1 is 0, the polycyclic compound may not be substituted with R₁. A case where n1 is 3 and three R₁ are all hydrogen atoms may be the same as a case where n1 is 0. If n1 is 2 or greater, multiple R₁ may all be the same, or at least one thereof may be different from the remainder.

In Formula 1, n2 may be an integer from 0 to 4. If n2 is 0, the polycyclic compound may not be substituted with R₂. A case where n2 is 4 and four R₂ are all hydrogen atoms may be the same as a case where n2 is 0. If n2 is 2 or greater, multiple R₂ may all be the same, or at least one thereof may be different from the remainder.

In Formula 1, n3 and n4 may each independently be an integer from 0 to 5. If n3 and n4 are each 0, the polycyclic compound may not be substituted with R₃ and R₄, respectively. A case where n3 is 5 and five R₃ are all hydrogen atoms may be the same as a case where n3 is 0, and a case where n4 is 5 and five R₄ are all hydrogen atoms may be the same as a case where n4 is 0. If n3 is 2 or more, multiple R₃ may all be the same, or at least one thereof may be different from the remainder, and if n4 is 2 or more, multiple R₄ may all be the same or at least one thereof may be different from the remainder.

In Formula 1, n5 and n6 may each independently be an integer from 0 to 6. If n5 and n6 are each 0, the polycyclic compound may not be substituted with R₅ and R₆, respectively. A case where n5 is 6 and six R₅ are all hydrogen atoms may be the same as a case where n5 is 0, and a case where n6 is 6 and six R₆ are all hydrogen atoms may be the same as a case where n6 is 0. If n5 is 2 or more, multiple R₅ may all be the same or at least one thereof may be different from the remainder, and if n6 is 2 or more, multiple R₆ may all be the same or at least one thereof may be different from the remainder.

In an embodiment, in the polycyclic compound represented by Formula 1, at least one substituent may be connected to the benzene ring of the core. In an embodiment, the polycyclic compound represented by Formula 1 may be represented by Formula 2:

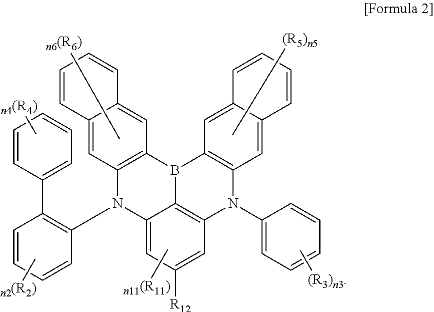

In Formula 2, R₁₁ may be a hydrogen atom, a deuterium atom, a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons. For example, R₁₁ may be a hydrogen atom or a deuterium atom, but embodiments are not limited thereto.

In Formula 2, R₁₂ may be a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons. For example, R₁₂ may be a substituted or unsubstituted t-butyl group, a substituted or unsubstituted phenyl group, a substituted or unsubstituted dibenzofuran group, a substituted or unsubstituted dibenzothiophene group, or a substituted or unsubstituted carbazole group.

In Formula 2, n11 may be an integer from 0 to 2. If n11 is 0, the polycyclic compound may not be substituted with R₁₁. A case where n11 is 2 and two R₁₁ are both hydrogen atoms may be the same as a case where n11 is 0. If n11 is 2, two R₁₁ may both be the same, or two R₁₁ may be different from each other.

In Formula 2, R₂ to R₆ and n2 to n6 are the same as defined in Formula 1.

In the polycyclic compound according to an embodiment, a steric protection substituent may be connected to each of the first nitrogen atom and the second nitrogen atom of the core. In an embodiment, the polycyclic compound represented by Formula 1 may be represented by Formula 3. In the polycyclic compound represented by Formula 3, steric protection substituents are connected each of the two nitrogen atoms in the core, and thus a p-orbital of the boron atom of the core may be effectively protected, which may prevent other substances from interacting with the polycyclic compound.

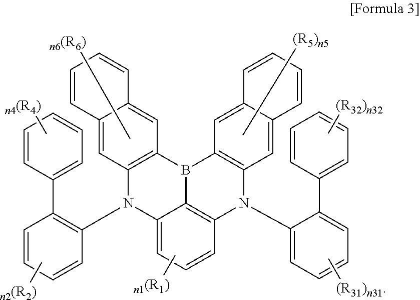

In Formula 3, R₃₁ and R₃₂ may each independently be a hydrogen atom, a deuterium atom, a cyano group, a substituted or unsubstituted amine group, a substituted or unsubstituted oxy group, a substituted or unsubstituted thio group, a substituted or unsubstituted alkyl group having 1 to 30 carbons, a substituted or unsubstituted alkenyl group having 2 to 30 carbons, or a substituted or unsubstituted aryl group having 6 to 30 ring-forming carbons, or bonded to an adjacent group to form a ring. For example, R₃₁ and R₃₂ may each independently be a hydrogen atom, a deuterium atom, a substituted or unsubstituted t-butyl group, a substituted or unsubstituted arylamine group, a substituted or unsubstituted aryloxy group, a substituted or unsubstituted arylthio group, a substituted or unsubstituted phenyl group, or a substituted or unsubstituted biphenyl group, but embodiments are not limited thereto. For example, R₃₁ and R₃₂ may each independently be bonded to an adjacent group to form a heterocycle.

In Formula 3, n31 may be an integer from 0 to 4. If n31 is 0, the polycyclic compound may not be substituted with R₃₁. A case where n31 is 4 and four R₃₁ are all hydrogen atoms may be the same as a case where n31 is 0. If n31 is 2 or greater, multiple R₃₁ may all be the same or at least one thereof may be different from the remainder.

In Formula 3, n32 may be an integer from 0 to 5. If n32 is 0, the polycyclic compound may not be substituted with R₃₂. A case where n32 is 5 and five R₃₂ are all hydrogen atoms may be the same as a case where n32 is 0. If n32 is 2 or greater, multiple R₃₂ may all be the same or at least one thereof may be different from the remainder.

In Formula 3, R₁, R₂, R₄ to R₆, n1, n2, and n4 to n6 are the same as defined in Formula 1.

In an embodiment, the polycyclic compound represented by Formula 1 may be represented by any one of Formula 4-1 to Formula 4-3. Formula 4-1 to Formula 4-3 may each represent a further embodiment of Formula 3.

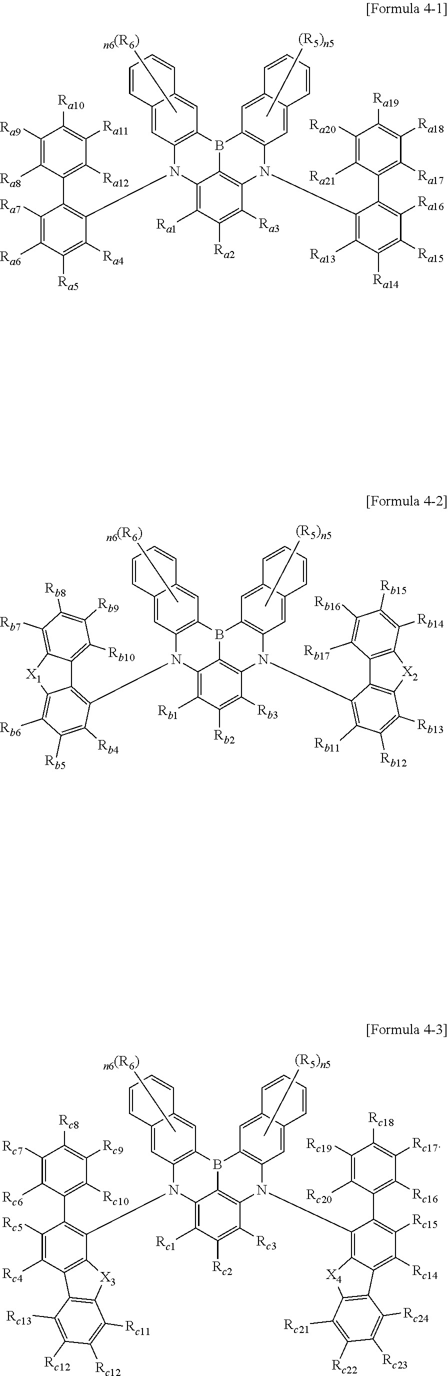

In Formula 4-2 and Formula 4-3, X₁ to X₄ may each independently be O or S. For example, X₁ may be the same as or different from X₂. For example, X₃ may be the same as or different from X₄.

In Formula 4-1 to Formula 4-3, Rₐ₁ to Rₐ₂₁, R_{b1} to R_{b17}, and R_{c1} to R_{c24} may each independently be a hydrogen atom, a deuterium atom, a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons. For example, Rₐ₁ to Rₐ₂₁, R_{b1} to R_{b17}, and R_{c1} to R_{c24} may each independently be a hydrogen atom, a deuterium atom, a substituted or unsubstituted t-butyl group, a substituted or unsubstituted phenyl group, a substituted or unsubstituted biphenyl group, a substituted or unsubstituted carbazole group, a substituted or unsubstituted dibenzofuran group, or a substituted or unsubstituted dibenzothiophene group, but embodiments are not limited thereto.

In Formula 4-1 to Formula 4-3, R₅, R₆, n5, and n6 are the same as defined in Formula 1.

In an embodiment, the polycyclic compound represented by Formula 1 or the polycyclic compound represented by Formula 3 may each independently be represented by Formula 4-4 or Formula 4-5:

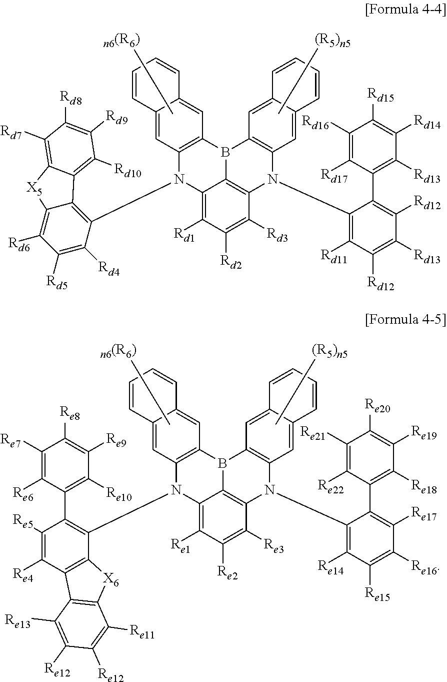

In Formula 4-4 and Formula 4-5, X₅ and X₆ may each independently be O or S. In Formula 4-4 and Formula 4-5, R_{d1} to R_{d17} and Rₑ₁ to Rₑ₂₂ may each independently be a hydrogen atom, a deuterium atom, a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons. For example, R_{d1} to R_{d17} and Rₑ₁ to Rₑ₂₂ may each independently be a hydrogen atom, a deuterium atom, a substituted or unsubstituted t-butyl group, a substituted or unsubstituted phenyl group, a substituted or unsubstituted biphenyl group, a substituted or unsubstituted carbazole group, a substituted or unsubstituted dibenzofuran group, or a substituted or unsubstituted dibenzothiophene group, but embodiments are not limited thereto.

In Formula 4-4 and Formula 4-5, R₅, R₆, n5, and n6 are the same as defined in Formula 1.

In an embodiment, the polycyclic compound represented by Formula 1 may be represented by Formula 5-1 or Formula 5-2:

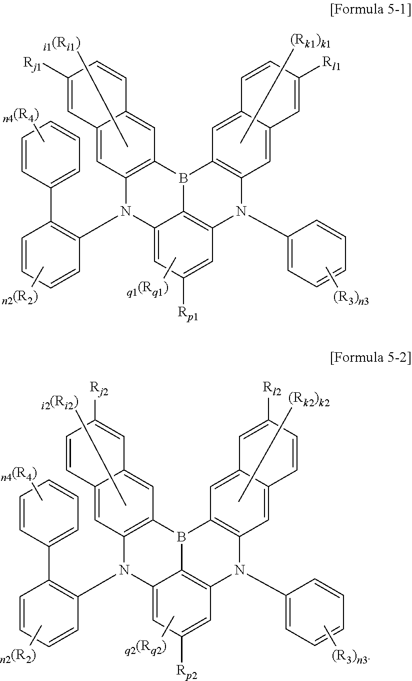

In Formula 5-1 and Formula 5-2, Rᵢ₁, Rᵢ₂, Rⱼ₁, Rⱼ₂, Rₖ₁, Rₖ₂, Rₗ₁, Rₗ₂, Rₚ₁, Rₚ₂, R_{q1}, and R_{q2} may each independently be a hydrogen atom, a deuterium atom, a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons. For example, Rᵢ₁, Rᵢ₂, Rⱼ₁, Rⱼ₂, Rₖ₁, Rₖ₂, Rₗ₁, Rₗ₂, Rₚ₁, Rₚ₂, R_{q1}, and R_{q2} may each independently be a hydrogen atom, a deuterium atom, a substituted or unsubstituted t-butyl group, a substituted or unsubstituted phenyl group, a substituted or unsubstituted carbazole group, a substituted or unsubstituted dibenzofuran group, or a substituted or unsubstituted dibenzothiophene group.

In Formula 5-1 and Formula 5-2, at least one of Rⱼ₁, Rₗ₁, and Rₚ₁, and at least one of Rⱼ₂, Rₗ₂, and Rₚ₂ may each independently be a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons. For example, at least one of Rⱼ₁, Rₗ₁, and Rₚ₁, and at least one of Rⱼ₂, Rₗ₂, and Rₚ₂ may each independently be a substituted or unsubstituted t-butyl group, a substituted or unsubstituted phenyl group, a substituted or unsubstituted carbazole group, a substituted or unsubstituted dibenzofuran group, or a substituted or unsubstituted dibenzothiophene group.

In Formula 5-1 and Formula 5-2, i1, i2, k1, and k2 may each independently be an integer from 0 to 5. If i1, i2, k1, and k2 are each 0, the polycyclic compound may not be substituted with Rᵢ₁, Rᵢ₂, Rₖ₁ and Rₖ₂, respectively. A case where i1 is 5 and five Rᵢ₁ are all hydrogen atoms, a case where i2 is 5 and five Rᵢ₂ are all hydrogen atoms, a case where k1 is 5 and five Rₖ₁ are all hydrogen atoms, and a case where k2 is 5 and five Rₖ₂ are all hydrogen atoms, may be the same as a case where i1 is 0, i2 is 0, k1 is 0, and k2 is 0, respectively. If i1 is 2 or greater, multiple Rᵢ₁ may all be the same, or at least one thereof may be different from the remainder. If i2 is 2 or greater, multiple Rᵢ₂ may all be the same, or at least one thereof may be different from the remainder. If k1 is 2 or greater, multiple Rₖ₁ may all be the same, or at least one thereof may be different from the remainder. If k2 is 2 or greater, multiple Rₖ₂ may all be the same, or at least one thereof may be different from the remainder.

In Formula 5-1 and Formula 5-2, q1 and q2 may each independently be an integer from 0 to 2. If q1 and q2 are each 0, the polycyclic compound may not be substituted with R_{q1} and R_{q2}, respectively. A case where q1 is 2 and two R_{q1} are both hydrogen atoms may be the same as a case where q1 is 0. A case where q2 is 2 and two R_{q2} are both hydrogen atoms may be the same as a case where q2 is 0. If q1 is 2, two R_{q1} may be the same as or different from each other. If q2 is 2, two R_{q2} may be the same as or different from each other.

In Formula 5-1 and Formula 5-2, R₂ to R₄ and n2 to n4 are the same as defined in Formula 1.

In an embodiment, the polycyclic compound represented by Formula 5-1 may be represented by Formula 5-1-1:

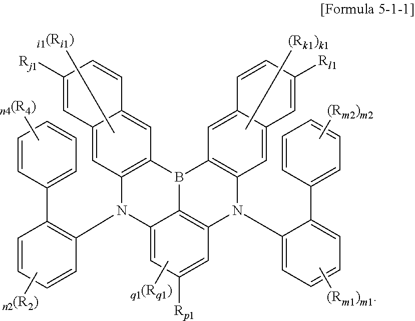

In Formula 5-1-1, Rₘ₁ and Rₘ₂ may each independently be a hydrogen atom, a deuterium atom, a substituted or unsubstituted amine group, a substituted or unsubstituted oxy group, a substituted or unsubstituted thio group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, a substituted or unsubstituted heteroaryl group having 2 to 30 ring-forming carbons, or bonded to an adjacent group to form a ring. For example, Rₘ₁ and Rₘ₂ may each independently be a hydrogen atom, a deuterium atom, a substituted or unsubstituted t-butyl group, a substituted or unsubstituted arylamine group, a substituted or unsubstituted aryloxy group, a substituted or unsubstituted arylthio group, a substituted or unsubstituted phenyl group, or a substituted or unsubstituted biphenyl group, but embodiments are not limited thereto. For example, Rₘ₁ and Rₘ₂ may each independently be bonded to an adjacent group to form a heterocycle.

In Formula 5-1-1, m1 may be an integer from 0 to 4. If m1 is 0, the polycyclic compound may not be substituted with Rₘ₁. A case where Rₘ₁ is 4 and four Rₘ₁ are all hydrogen atoms may be the same as a case where m1 is 0. If m1 is 2 or greater, multiple Rₘ₁ may all be the same or at least one thereof may be different from the remainder.

In Formula 5-1-1, m2 may be an integer from 0 to 5. If m2 is 0, the polycyclic compound may not be substituted with Rₘ₂. A case where Rₘ₂ is 5 and five Rₘ₂ are all hydrogen atoms may be the same as a case where m2 is 0. If m2 is 2 or greater, multiple Rₘ₂ may all be the same or at least one thereof may be different from the remainder.

In Formula 5-1-1, R₂, R₄, Rᵢ₁, Rⱼ₁, Rₖ₁, Rₗ₁, Rₚ₁, R_{q1}, n2, n4, i1, k1, and q1 are the same as defined in Formula 1 and Formula 5-1.

In an embodiment, the polycyclic compound represented by Formula 5-2 may be represented by Formula 5-2-1:

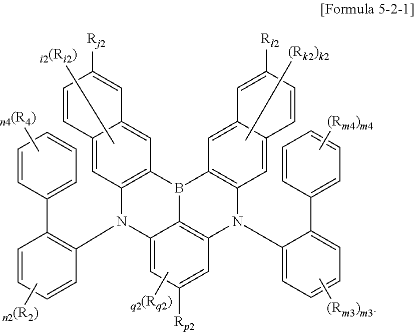

In Formula 5-2-1, Rₘ₃ and Rₘ₄ may each independently be a hydrogen atom, a deuterium atom, a substituted or unsubstituted amine group, a substituted or unsubstituted oxy group, a substituted or unsubstituted thio group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, or bonded to an adjacent group to form a ring. For example, Rₘ₃ and Rₘ₄ may each independently be a hydrogen atom, a deuterium atom, a substituted or unsubstituted t-butyl group, a substituted or unsubstituted arylamine group, a substituted or unsubstituted aryloxy group, a substituted or unsubstituted arylthio group, a substituted or unsubstituted phenyl group, or a substituted or unsubstituted biphenyl group, but embodiments are not limited thereto. For example, Rₘ₃ and Rₘ₄ may each independently be bonded to an adjacent group to form a heterocycle.

In Formula 5-2-1, m3 may be an integer from 0 to 4. If m3 is 0, the polycyclic compound may not be substituted with Rₘ₃. A case where m3 is 4 and four Rₘ₃ are all hydrogen atoms may be the same as a case where m3 is 0. If m3 is 2 or greater, multiple Rₘ₃ may all be the same or at least one thereof may be different from the remainder.

In Formula 5-2-1, m4 may be an integer from 0 to 5. If m4 is 0, the polycyclic compound may not be substituted with Rₘ₄. A case where m4 is 5 and four Rₘ₄ are all hydrogen atoms may be the same as a case where m4 is 0. If m4 is 2 or greater, multiple Rₘ₄ may all be the same or at least one thereof may be different from the remainder.

In Formula 5-2-1, R₂, R₄, Rᵢ₂, Rⱼ₂, Rₖ₂, Rₗ₂, Rₚ₂, R_{q2}, n2, n4, i2, k2, and q2 are the same as defined in Formula 1 and Formula 5-2.

In an embodiment, the polycyclic compound according to an embodiment may include at least one deuterium atom as a substituent. For example, in the polycyclic compound represented by Formula 1, at least one hydrogen atom may be substituted with a deuterium atom.

In an embodiment, the polycyclic compound represented by Formula 1 may be any compound selected from Compound Group 1. In an embodiment, in the light-emitting element ED, at least one functional layer may include at least one compound selected from Compound Group 1. In an embodiment, in the light-emitting element ED, the first compound may include at least one compound selected from Compound Group 1:

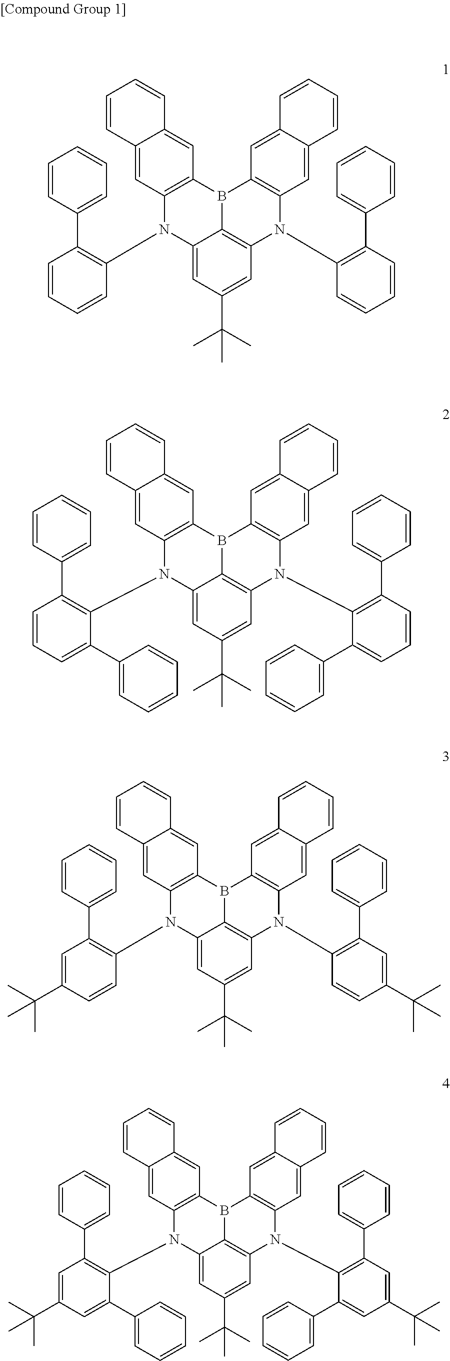

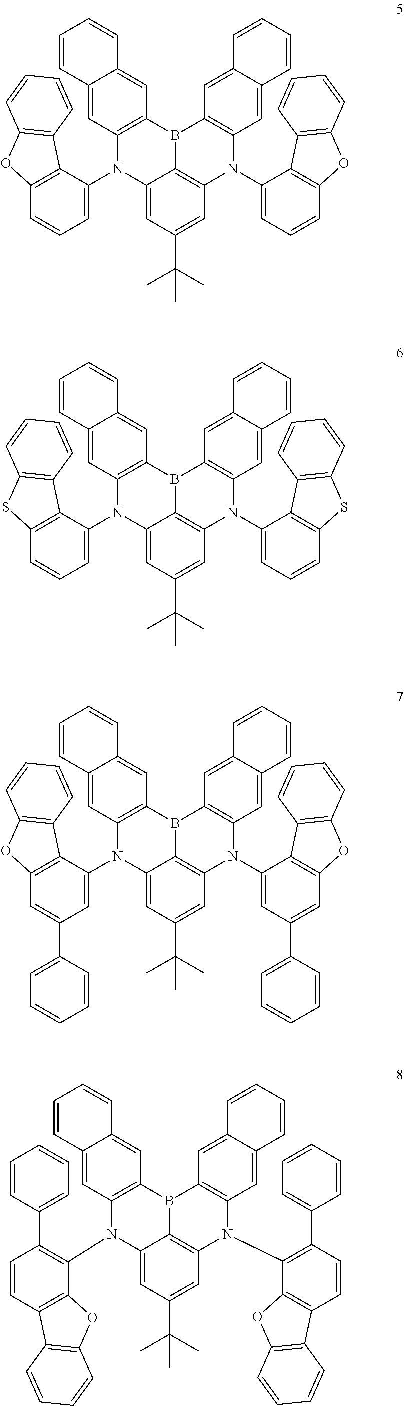 [SMILES: CC(C)(C)c1cc2c3c(c1)N(c1cccc4oc5ccccc5c14)c1cc4ccccc4cc1B3c1cc3ccccc3cc1N2c1cccc2oc3ccccc3c12 ; CC(C)(C)c1cc2c3c(c1)N(c1cccc4sc5ccccc5c14)c1cc4ccccc4cc1B3c1cc3ccccc3cc1N2c1cccc2sc3ccccc3c12 ; CC(C)(C)c1cc2c3c(c1)N(c1cc(-c4ccccc4)cc4oc5ccccc5c14)c1cc4ccccc4cc1B3c1cc3ccccc3cc1N2c1cc(-c2ccccc2)cc2oc3ccccc3c12 ; CC(C)(C)c1cc2c3c(c1)N(c1c(-c4ccccc4)ccc4c1oc1ccccc14)c1cc4ccccc4cc1B3c1cc3ccccc3cc1N2c1c(-c2ccccc2)ccc2c1oc1ccccc12]

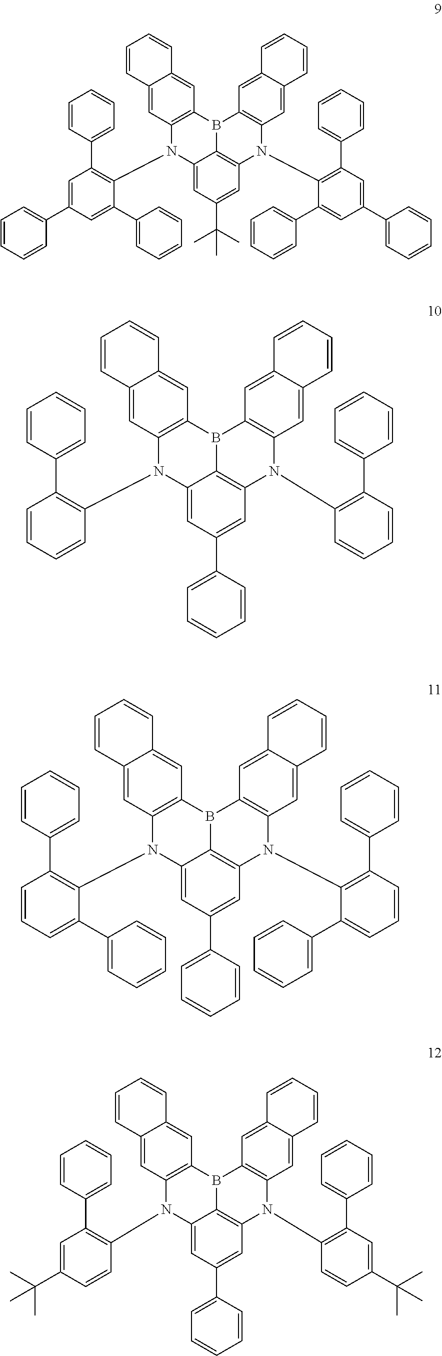 [SMILES: CC(C)(C)c1cc2c3c(c1)N(c1c(-c4ccccc4)cc(-c4ccccc4)cc1-c1ccccc1)c1cc4ccccc4cc1B3c1cc3ccccc3cc1N2c1c(-c2ccccc2)cc(-c2ccccc2)cc1-c1ccccc1 ; c1ccc(-c2cc3c4c(c2)N(c2ccccc2-c2ccccc2)c2cc5ccccc5cc2B4c2cc4ccccc4cc2N3c2ccccc2-c2ccccc2)cc1 ; c1ccc(-c2cc3c4c(c2)N(c2c(-c5ccccc5)cccc2-c2ccccc2)c2cc5ccccc5cc2B4c2cc4ccccc4cc2N3c2c(-c3ccccc3)cccc2-c2ccccc2)cc1 ; CC(C)(C)c1ccc(N2c3cc4ccccc4cc3B3c4cc5ccccc5cc4N(c4ccc(C(C)(C)C)cc4-c4ccccc4)c4cc(-c5ccccc5)cc2c43)c(-c2ccccc2)c1]

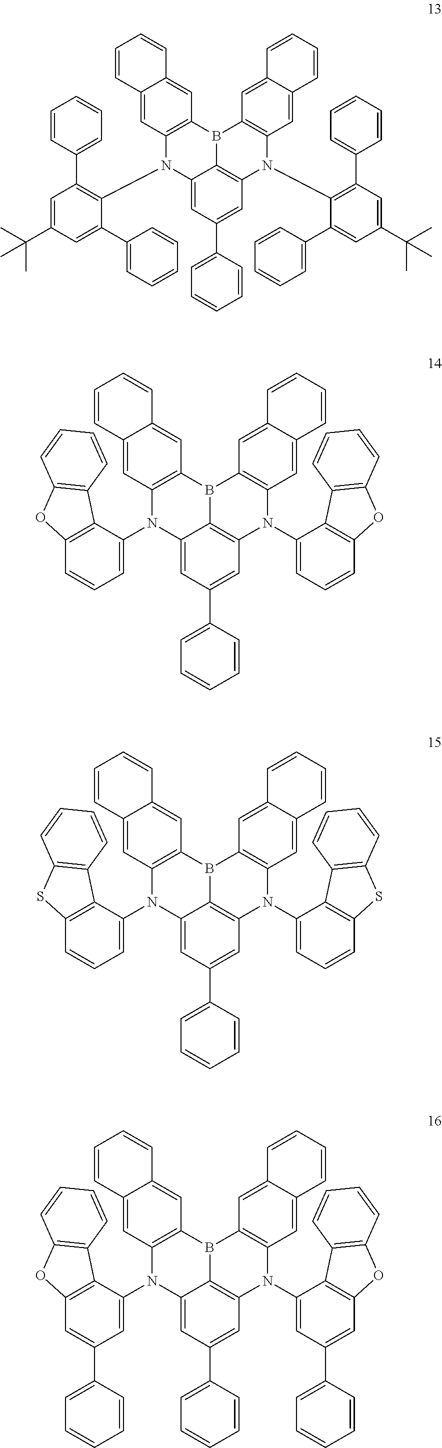 [SMILES: CC(C)(C)c1cc(-c2ccccc2)c(N2c3cc4ccccc4cc3B3c4cc5ccccc5cc4N(c4c(-c5ccccc5)cc(C(C)(C)C)cc4-c4ccccc4)c4cc(-c5ccccc5)cc2c43)c(-c2ccccc2)c1 ; c1ccc(-c2cc3c4c(c2)N(c2cccc5oc6ccccc6c25)c2cc5ccccc5cc2B4c2cc4ccccc4cc2N3c2cccc3oc4ccccc4c23)cc1 ; c1ccc(-c2cc3c4c(c2)N(c2cccc5sc6ccccc6c25)c2cc5ccccc5cc2B4c2cc4ccccc4cc2N3c2cccc3sc4ccccc4c23)cc1 ; c1ccc(-c2cc3c4c(c2)N(c2cc(-c5ccccc5)cc5oc6ccccc6c25)c2cc5ccccc5cc2B4c2cc4ccccc4cc2N3c2cc(-c3ccccc3)cc3oc4ccccc4c23)cc1]

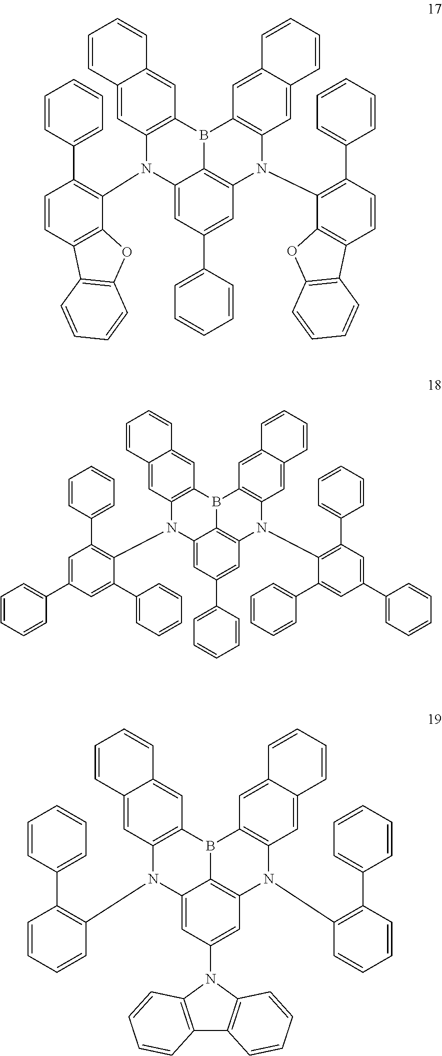 [SMILES: c1ccc(-c2cc3c4c(c2)N(c2c(-c5ccccc5)ccc5c2oc2ccccc25)c2cc5ccccc5cc2B4c2cc4ccccc4cc2N3c2c(-c3ccccc3)ccc3c2oc2ccccc23)cc1 ; c1ccc(-c2cc(-c3ccccc3)c(N3c4cc5ccccc5cc4B4c5cc6ccccc6cc5N(c5c(-c6ccccc6)cc(-c6ccccc6)cc5-c5ccccc5)c5cc(-c6ccccc6)cc3c54)c(-c3ccccc3)c2)cc1 ; c1ccc(-c2ccccc2N2c3cc4ccccc4cc3B3c4cc5ccccc5cc4N(c4ccccc4-c4ccccc4)c4cc(-n5c6ccccc6c6ccccc65)cc2c43)cc1]

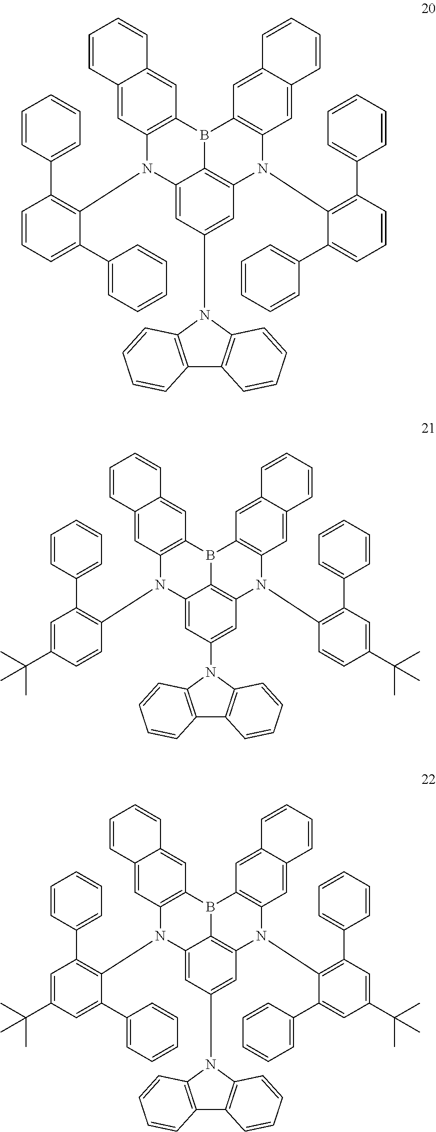

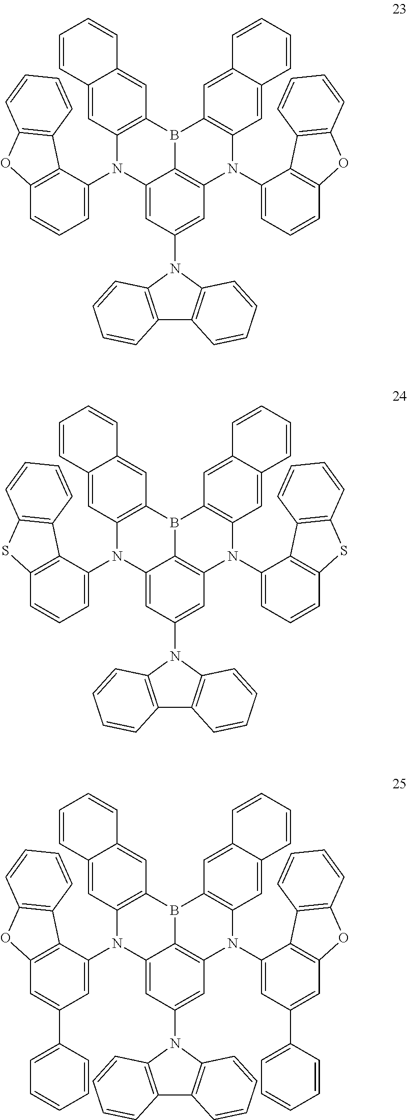 [SMILES: c1ccc2cc3c(cc2c1)B1c2cc4ccccc4cc2N(c2cccc4oc5ccccc5c24)c2cc(-n4c5ccccc5c5ccccc54)cc(c21)N3c1cccc2oc3ccccc3c12 ; c1ccc2cc3c(cc2c1)B1c2cc4ccccc4cc2N(c2cccc4sc5ccccc5c24)c2cc(-n4c5ccccc5c5ccccc54)cc(c21)N3c1cccc2sc3ccccc3c12 ; c1ccc(-c2cc(N3c4cc5ccccc5cc4B4c5cc6ccccc6cc5N(c5cc(-c6ccccc6)cc6oc7ccccc7c56)c5cc(-n6c7ccccc7c7ccccc76)cc3c54)c3c(c2)oc2ccccc23)cc1]

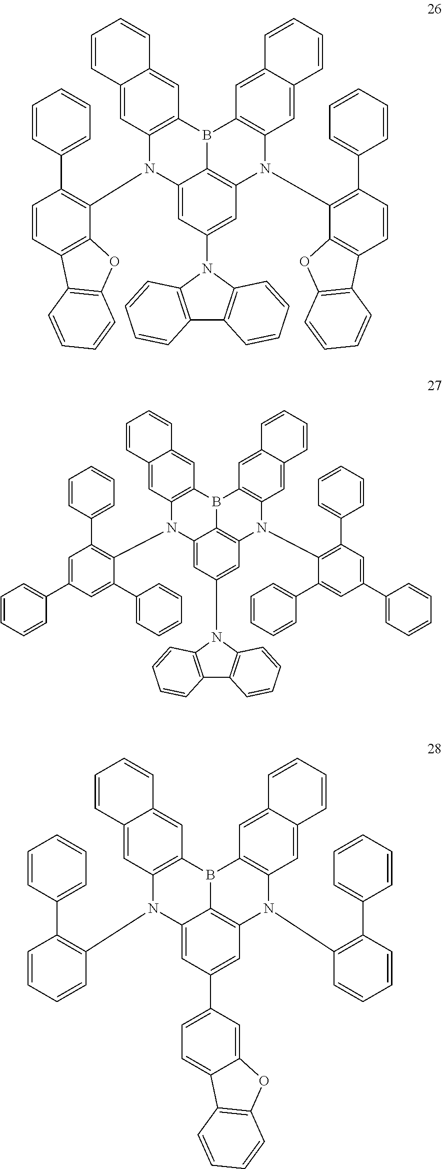 [SMILES: c1ccc(-c2ccc3c(oc4ccccc43)c2N2c3cc4ccccc4cc3B3c4cc5ccccc5cc4N(c4c(-c5ccccc5)ccc5c4oc4ccccc45)c4cc(-n5c6ccccc6c6ccccc65)cc2c43)cc1 ; c1ccc(-c2cc(-c3ccccc3)c(N3c4cc5ccccc5cc4B4c5cc6ccccc6cc5N(c5c(-c6ccccc6)cc(-c6ccccc6)cc5-c5ccccc5)c5cc(-n6c7ccccc7c7ccccc76)cc3c54)c(-c3ccccc3)c2)cc1 ; c1ccc(-c2ccccc2N2c3cc4ccccc4cc3B3c4cc5ccccc5cc4N(c4ccccc4-c4ccccc4)c4cc(-c5ccc6c(c5)oc5ccccc56)cc2c43)cc1]

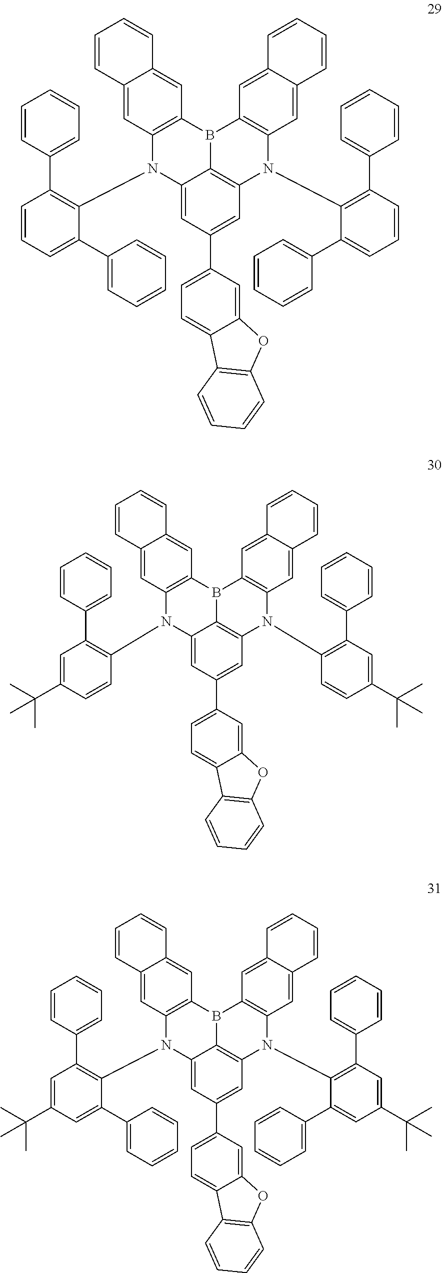

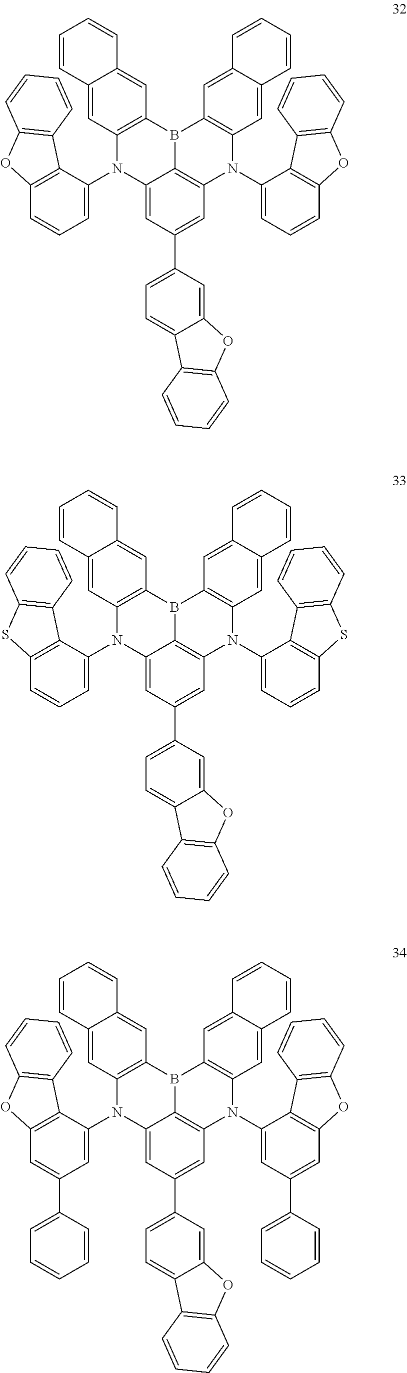 [SMILES: c1ccc2cc3c(cc2c1)B1c2cc4ccccc4cc2N(c2cccc4oc5ccccc5c24)c2cc(-c4ccc5c(c4)oc4ccccc45)cc(c21)N3c1cccc2oc3ccccc3c12 ; c1ccc2cc3c(cc2c1)B1c2cc4ccccc4cc2N(c2cccc4sc5ccccc5c24)c2cc(-c4ccc5c(c4)oc4ccccc45)cc(c21)N3c1cccc2sc3ccccc3c12 ; c1ccc(-c2cc(N3c4cc5ccccc5cc4B4c5cc6ccccc6cc5N(c5cc(-c6ccccc6)cc6oc7ccccc7c56)c5cc(-c6ccc7c(c6)oc6ccccc67)cc3c54)c3c(c2)oc2ccccc23)cc1]

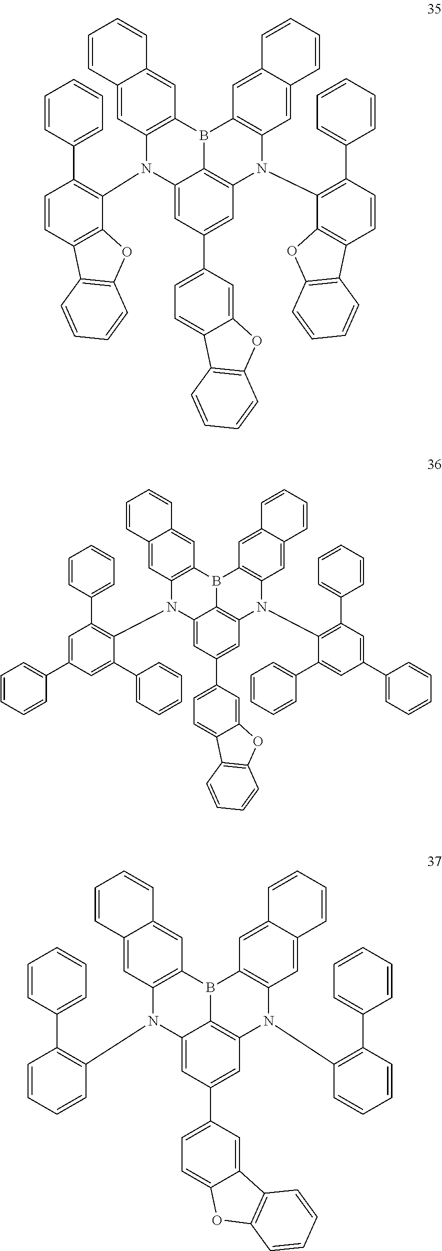 [SMILES: c1ccc(-c2ccc3c(oc4ccccc43)c2N2c3cc4ccccc4cc3B3c4cc5ccccc5cc4N(c4c(-c5ccccc5)ccc5c4oc4ccccc45)c4cc(-c5ccc6c(c5)oc5ccccc56)cc2c43)cc1 ; c1ccc(-c2cc(-c3ccccc3)c(N3c4cc5ccccc5cc4B4c5cc6ccccc6cc5N(c5c(-c6ccccc6)cc(-c6ccccc6)cc5-c5ccccc5)c5cc(-c6ccc7c(c6)oc6ccccc67)cc3c54)c(-c3ccccc3)c2)cc1 ; c1ccc(-c2ccccc2N2c3cc4ccccc4cc3B3c4cc5ccccc5cc4N(c4ccccc4-c4ccccc4)c4cc(-c5ccc6oc7ccccc7c6c5)cc2c43)cc1]

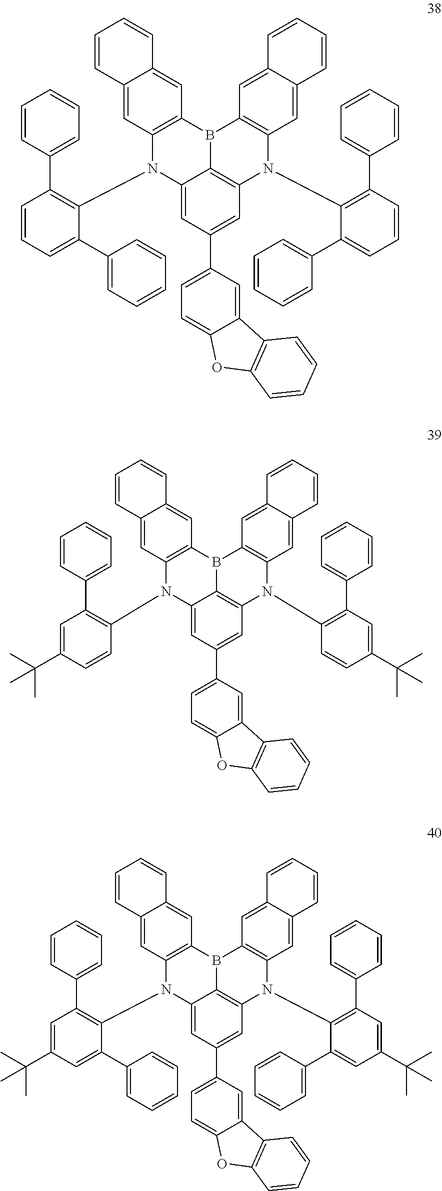

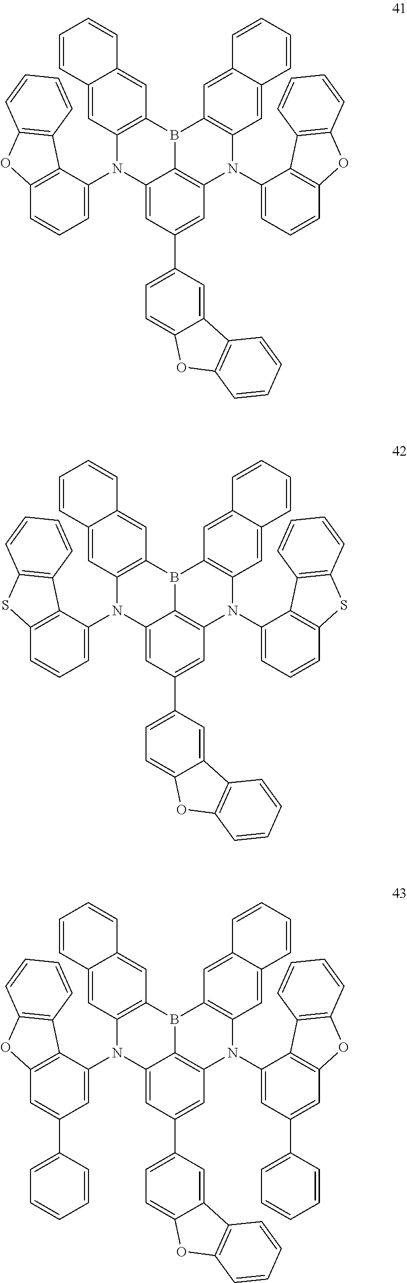 [SMILES: c1ccc2cc3c(cc2c1)B1c2cc4ccccc4cc2N(c2cccc4oc5ccccc5c24)c2cc(-c4ccc5oc6ccccc6c5c4)cc(c21)N3c1cccc2oc3ccccc3c12 ; c1ccc2cc3c(cc2c1)B1c2cc4ccccc4cc2N(c2cccc4sc5ccccc5c24)c2cc(-c4ccc5oc6ccccc6c5c4)cc(c21)N3c1cccc2sc3ccccc3c12 ; c1ccc(-c2cc(N3c4cc5ccccc5cc4B4c5cc6ccccc6cc5N(c5cc(-c6ccccc6)cc6oc7ccccc7c56)c5cc(-c6ccc7oc8ccccc8c7c6)cc3c54)c3c(c2)oc2ccccc23)cc1]

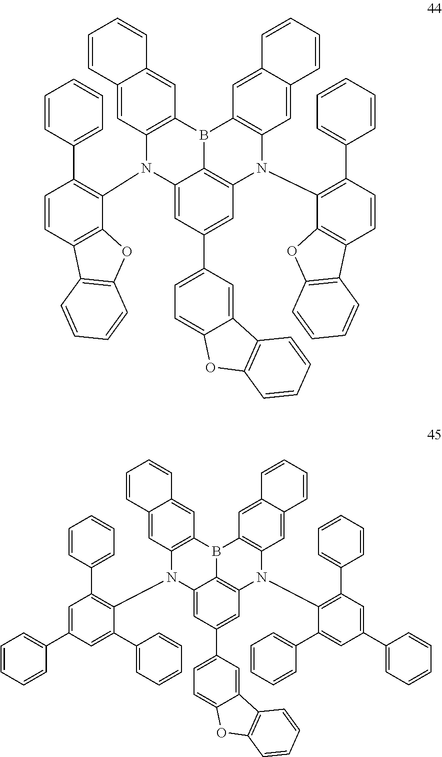 [SMILES: c1ccc(-c2ccc3c(oc4ccccc43)c2N2c3cc4ccccc4cc3B3c4cc5ccccc5cc4N(c4c(-c5ccccc5)ccc5c4oc4ccccc45)c4cc(-c5ccc6oc7ccccc7c6c5)cc2c43)cc1 ; c1ccc(-c2cc(-c3ccccc3)c(N3c4cc5ccccc5cc4B4c5cc6ccccc6cc5N(c5c(-c6ccccc6)cc(-c6ccccc6)cc5-c5ccccc5)c5cc(-c6ccc7oc8ccccc8c7c6)cc3c54)c(-c3ccccc3)c2)cc1]

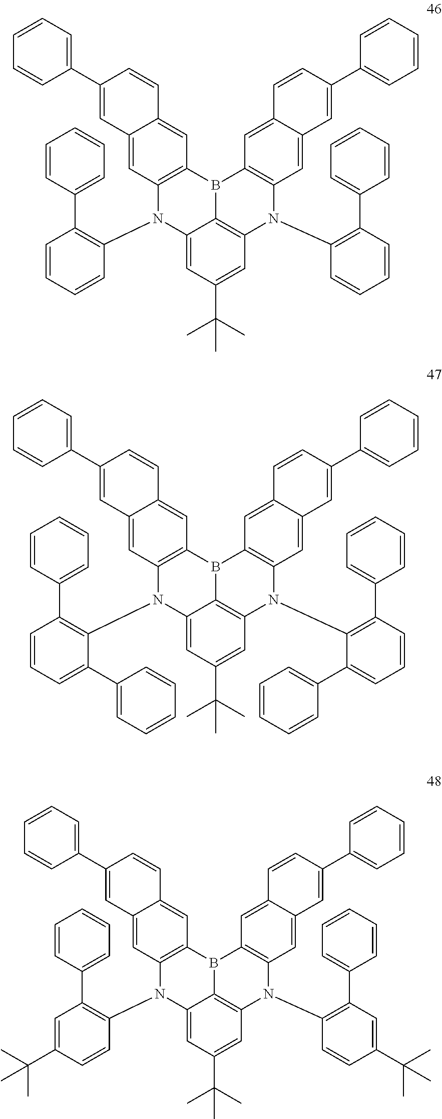 [SMILES: CC(C)(C)c1cc2c3c(c1)N(c1ccccc1-c1ccccc1)c1cc4cc(-c5ccccc5)ccc4cc1B3c1cc3ccc(-c4ccccc4)cc3cc1N2c1ccccc1-c1ccccc1 ; CC(C)(C)c1cc2c3c(c1)N(c1c(-c4ccccc4)cccc1-c1ccccc1)c1cc4cc(-c5ccccc5)ccc4cc1B3c1cc3ccc(-c4ccccc4)cc3cc1N2c1c(-c2ccccc2)cccc1-c1ccccc1 ; CC(C)(C)c1ccc(N2c3cc4cc(-c5ccccc5)ccc4cc3B3c4cc5ccc(-c6ccccc6)cc5cc4N(c4ccc(C(C)(C)C)cc4-c4ccccc4)c4cc(C(C)(C)C)cc2c43)c(-c2ccccc2)c1]

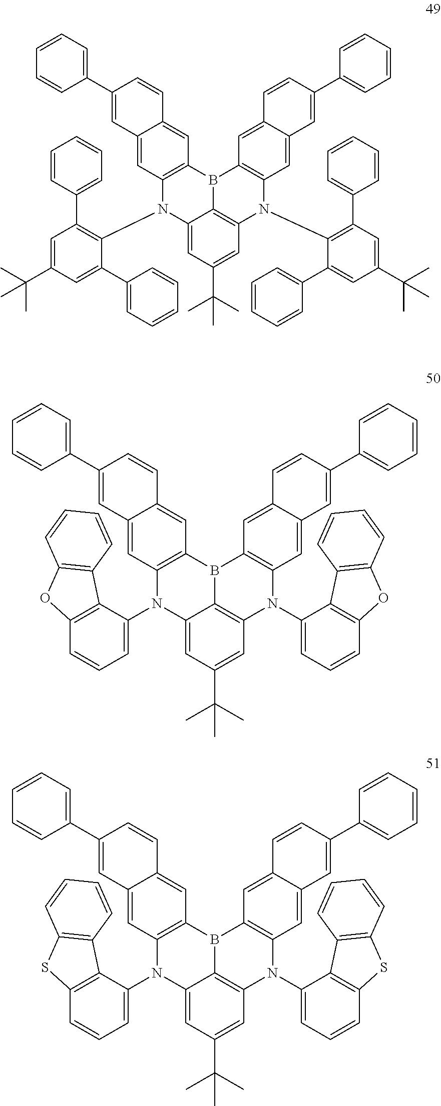 [SMILES: CC(C)(C)c1cc(-c2ccccc2)c(N2c3cc4cc(-c5ccccc5)ccc4cc3B3c4cc5ccc(-c6ccccc6)cc5cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc2c3c(c1)N(c1cccc4oc5ccccc5c14)c1cc4cc(-c5ccccc5)ccc4cc1B3c1cc3ccc(-c4ccccc4)cc3cc1N2c1cccc2oc3ccccc3c12 ; CC(C)(C)c1cc2c3c(c1)N(c1cccc4sc5ccccc5c14)c1cc4cc(-c5ccccc5)ccc4cc1B3c1cc3ccc(-c4ccccc4)cc3cc1N2c1cccc2sc3ccccc3c12]

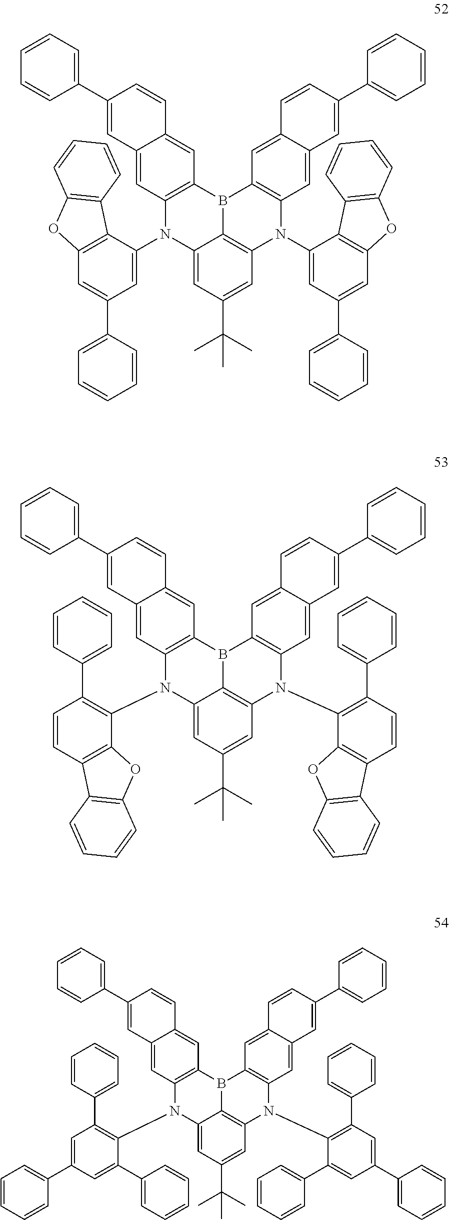 [SMILES: CC(C)(C)c1cc2c3c(c1)N(c1cc(-c4ccccc4)cc4oc5ccccc5c14)c1cc4cc(-c5ccccc5)ccc4cc1B3c1cc3ccc(-c4ccccc4)cc3cc1N2c1cc(-c2ccccc2)cc2oc3ccccc3c12 ; CC(C)(C)c1cc2c3c(c1)N(c1c(-c4ccccc4)ccc4c1oc1ccccc14)c1cc4cc(-c5ccccc5)ccc4cc1B3c1cc3ccc(-c4ccccc4)cc3cc1N2c1c(-c2ccccc2)ccc2c1oc1ccccc12 ; CC(C)(C)c1cc2c3c(c1)N(c1c(-c4ccccc4)cc(-c4ccccc4)cc1-c1ccccc1)c1cc4cc(-c5ccccc5)ccc4cc1B3c1cc3ccc(-c4ccccc4)cc3cc1N2c1c(-c2ccccc2)cc(-c2ccccc2)cc1-c1ccccc1]

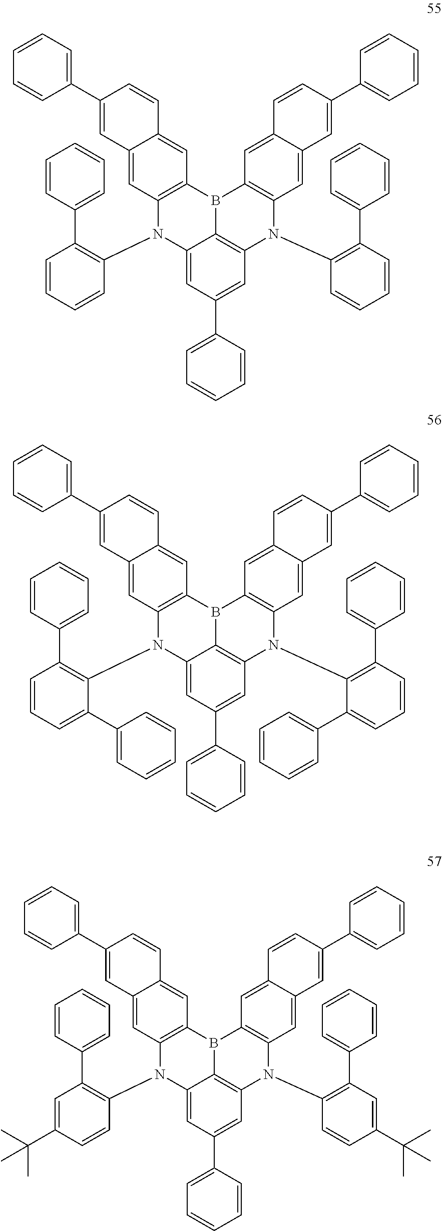 [SMILES: c1ccc(-c2cc3c4c(c2)N(c2ccccc2-c2ccccc2)c2cc5cc(-c6ccccc6)ccc5cc2B4c2cc4ccc(-c5ccccc5)cc4cc2N3c2ccccc2-c2ccccc2)cc1 ; c1ccc(-c2cc3c4c(c2)N(c2c(-c5ccccc5)cccc2-c2ccccc2)c2cc5cc(-c6ccccc6)ccc5cc2B4c2cc4ccc(-c5ccccc5)cc4cc2N3c2c(-c3ccccc3)cccc2-c2ccccc2)cc1 ; CC(C)(C)c1ccc(N2c3cc4cc(-c5ccccc5)ccc4cc3B3c4cc5ccc(-c6ccccc6)cc5cc4N(c4ccc(C(C)(C)C)cc4-c4ccccc4)c4cc(-c5ccccc5)cc2c43)c(-c2ccccc2)c1]

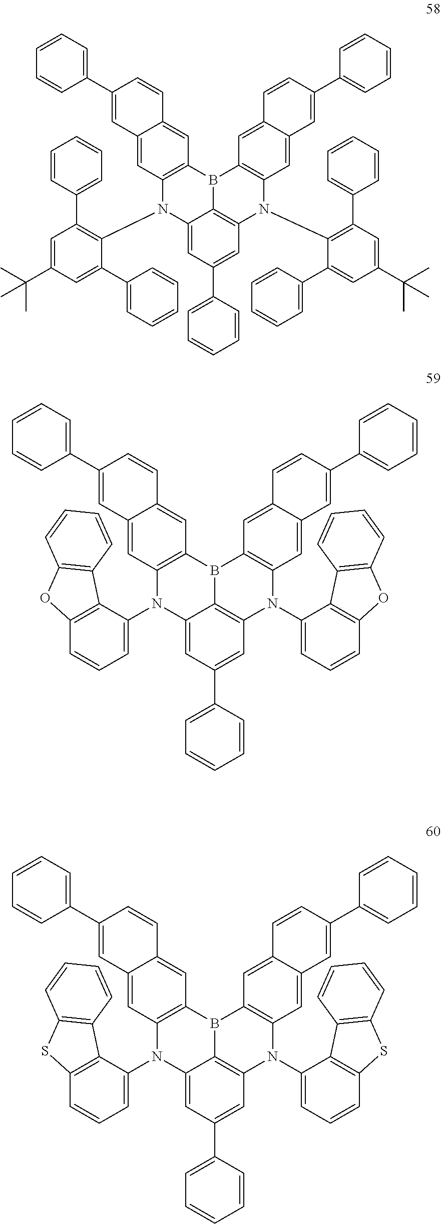 [SMILES: CC(C)(C)c1cc(-c2ccccc2)c(N2c3cc4cc(-c5ccccc5)ccc4cc3B3c4cc5ccc(-c6ccccc6)cc5cc4N(c4c(-c5ccccc5)cc(C(C)(C)C)cc4-c4ccccc4)c4cc(-c5ccccc5)cc2c43)c(-c2ccccc2)c1 ; c1ccc(-c2cc3c4c(c2)N(c2cccc5oc6ccccc6c25)c2cc5cc(-c6ccccc6)ccc5cc2B4c2cc4ccc(-c5ccccc5)cc4cc2N3c2cccc3oc4ccccc4c23)cc1 ; c1ccc(-c2cc3c4c(c2)N(c2cccc5sc6ccccc6c25)c2cc5cc(-c6ccccc6)ccc5cc2B4c2cc4ccc(-c5ccccc5)cc4cc2N3c2cccc3sc4ccccc4c23)cc1]

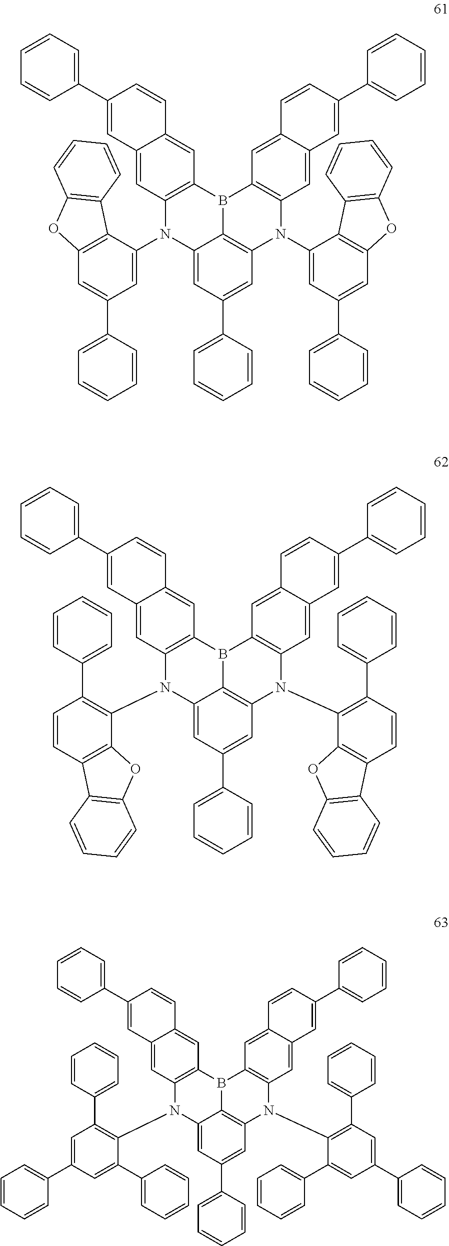 [SMILES: c1ccc(-c2cc3c4c(c2)N(c2cc(-c5ccccc5)cc5oc6ccccc6c25)c2cc5cc(-c6ccccc6)ccc5cc2B4c2cc4ccc(-c5ccccc5)cc4cc2N3c2cc(-c3ccccc3)cc3oc4ccccc4c23)cc1 ; c1ccc(-c2cc3c4c(c2)N(c2c(-c5ccccc5)ccc5c2oc2ccccc25)c2cc5cc(-c6ccccc6)ccc5cc2B4c2cc4ccc(-c5ccccc5)cc4cc2N3c2c(-c3ccccc3)ccc3c2oc2ccccc23)cc1 ; c1ccc(-c2cc(-c3ccccc3)c(N3c4cc5cc(-c6ccccc6)ccc5cc4B4c5cc6ccc(-c7ccccc7)cc6cc5N(c5c(-c6ccccc6)cc(-c6ccccc6)cc5-c5ccccc5)c5cc(-c6ccccc6)cc3c54)c(-c3ccccc3)c2)cc1]

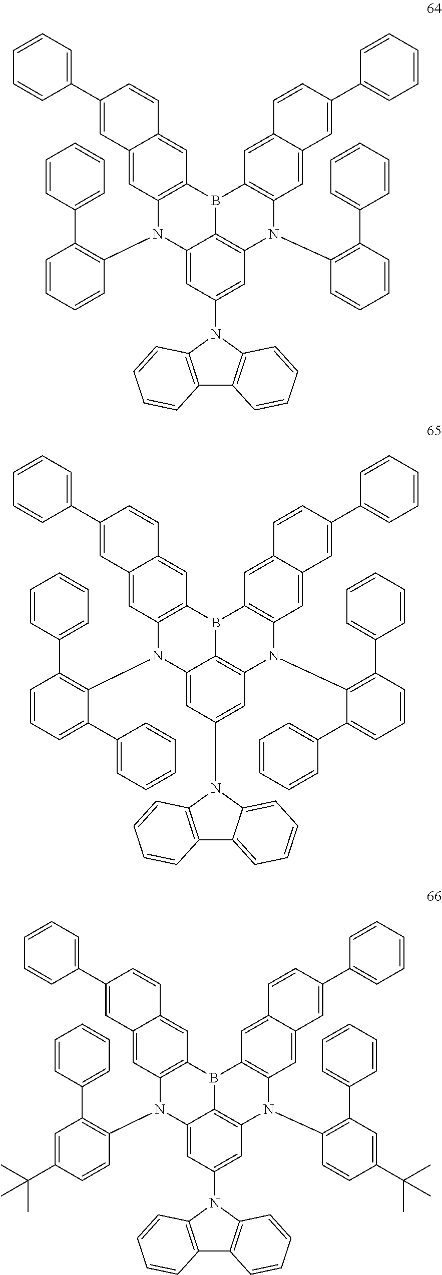 [SMILES: c1ccc(-c2ccc3cc4c(cc3c2)N(c2ccccc2-c2ccccc2)c2cc(-n3c5ccccc5c5ccccc53)cc3c2B4c2cc4ccc(-c5ccccc5)cc4cc2N3c2ccccc2-c2ccccc2)cc1 ; c1ccc(-c2ccc3cc4c(cc3c2)N(c2c(-c3ccccc3)cccc2-c2ccccc2)c2cc(-n3c5ccccc5c5ccccc53)cc3c2B4c2cc4ccc(-c5ccccc5)cc4cc2N3c2c(-c3ccccc3)cccc2-c2ccccc2)cc1 ; CC(C)(C)c1ccc(N2c3cc4cc(-c5ccccc5)ccc4cc3B3c4cc5ccc(-c6ccccc6)cc5cc4N(c4ccc(C(C)(C)C)cc4-c4ccccc4)c4cc(-n5c6ccccc6c6ccccc65)cc2c43)c(-c2ccccc2)c1]

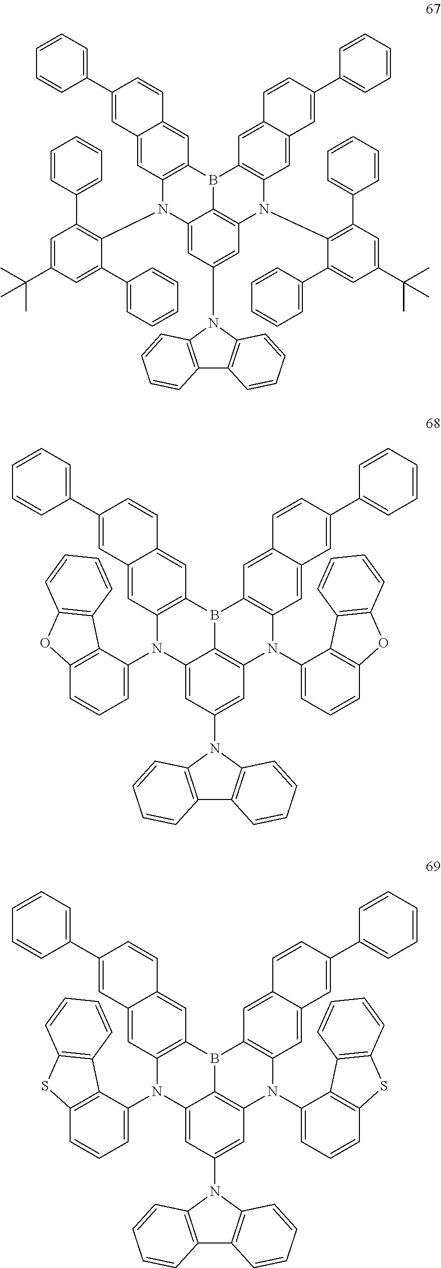 [SMILES: CC(C)(C)c1cc(-c2ccccc2)c(N2c3cc4cc(-c5ccccc5)ccc4cc3B3c4cc5ccc(-c6ccccc6)cc5cc4N(c4c(-c5ccccc5)cc(C(C)(C)C)cc4-c4ccccc4)c4cc(-n5c6ccccc6c6ccccc65)cc2c43)c(-c2ccccc2)c1 ; c1ccc(-c2ccc3cc4c(cc3c2)N(c2cccc3oc5ccccc5c23)c2cc(-n3c5ccccc5c5ccccc53)cc3c2B4c2cc4ccc(-c5ccccc5)cc4cc2N3c2cccc3oc4ccccc4c23)cc1 ; c1ccc(-c2ccc3cc4c(cc3c2)N(c2cccc3sc5ccccc5c23)c2cc(-n3c5ccccc5c5ccccc53)cc3c2B4c2cc4ccc(-c5ccccc5)cc4cc2N3c2cccc3sc4ccccc4c23)cc1]

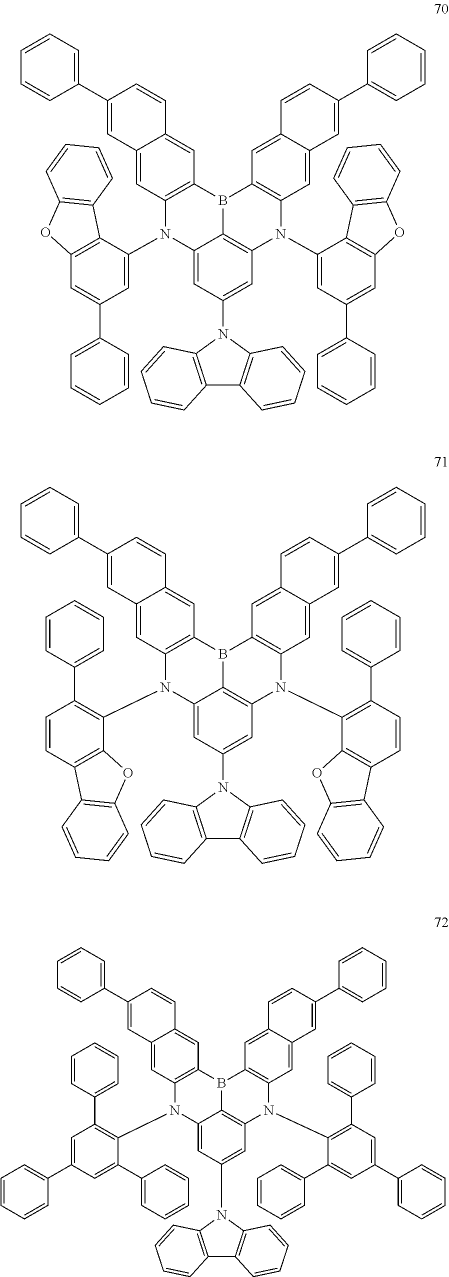 [SMILES: c1ccc(-c2ccc3cc4c(cc3c2)N(c2cc(-c3ccccc3)cc3oc5ccccc5c23)c2cc(-n3c5ccccc5c5ccccc53)cc3c2B4c2cc4ccc(-c5ccccc5)cc4cc2N3c2cc(-c3ccccc3)cc3oc4ccccc4c23)cc1 ; c1ccc(-c2ccc3cc4c(cc3c2)N(c2c(-c3ccccc3)ccc3c2oc2ccccc23)c2cc(-n3c5ccccc5c5ccccc53)cc3c2B4c2cc4ccc(-c5ccccc5)cc4cc2N3c2c(-c3ccccc3)ccc3c2oc2ccccc23)cc1 ; c1ccc(-c2cc(-c3ccccc3)c(N3c4cc5cc(-c6ccccc6)ccc5cc4B4c5cc6ccc(-c7ccccc7)cc6cc5N(c5c(-c6ccccc6)cc(-c6ccccc6)cc5-c5ccccc5)c5cc(-n6c7ccccc7c7ccccc76)cc3c54)c(-c3ccccc3)c2)cc1]

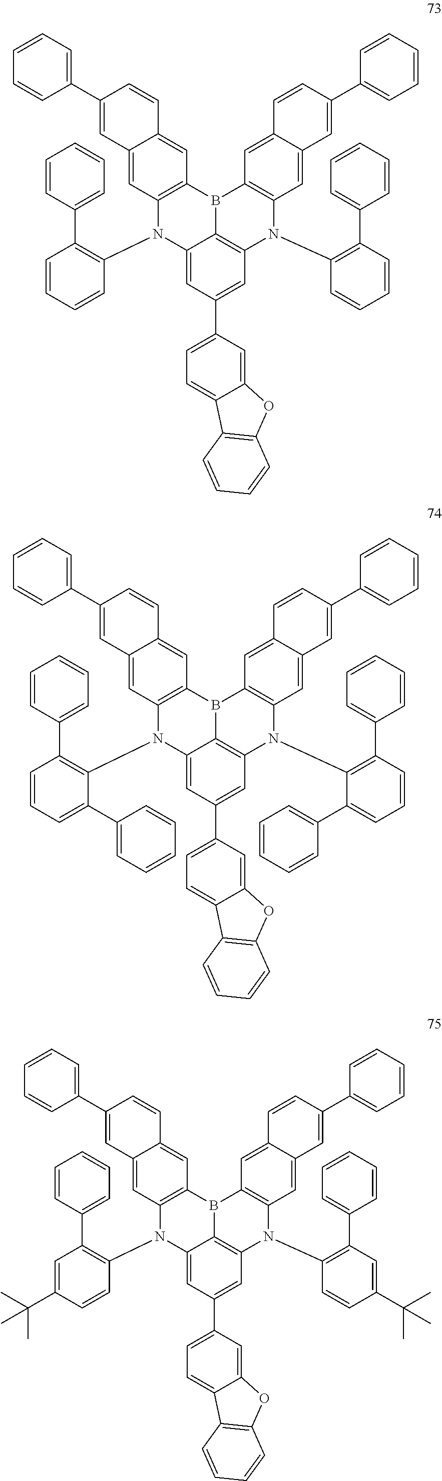 [SMILES: c1ccc(-c2ccc3cc4c(cc3c2)N(c2ccccc2-c2ccccc2)c2cc(-c3ccc5c(c3)oc3ccccc35)cc3c2B4c2cc4ccc(-c5ccccc5)cc4cc2N3c2ccccc2-c2ccccc2)cc1 ; c1ccc(-c2ccc3cc4c(cc3c2)N(c2c(-c3ccccc3)cccc2-c2ccccc2)c2cc(-c3ccc5c(c3)oc3ccccc35)cc3c2B4c2cc4ccc(-c5ccccc5)cc4cc2N3c2c(-c3ccccc3)cccc2-c2ccccc2)cc1 ; CC(C)(C)c1ccc(N2c3cc4cc(-c5ccccc5)ccc4cc3B3c4cc5ccc(-c6ccccc6)cc5cc4N(c4ccc(C(C)(C)C)cc4-c4ccccc4)c4cc(-c5ccc6c(c5)oc5ccccc56)cc2c43)c(-c2ccccc2)c1]

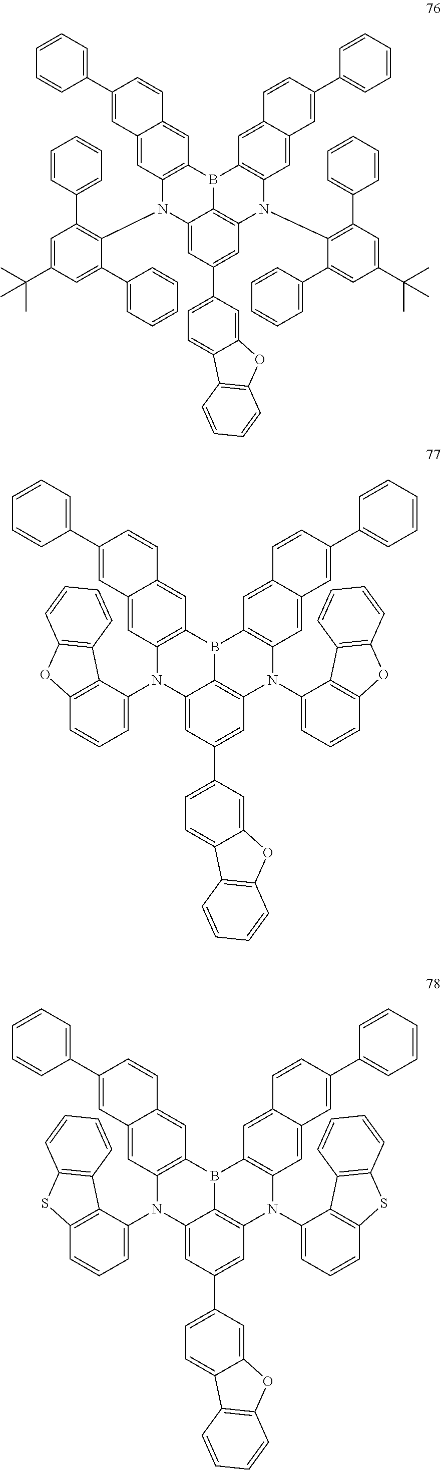 [SMILES: CC(C)(C)c1cc(-c2ccccc2)c(N2c3cc4cc(-c5ccccc5)ccc4cc3B3c4cc5ccc(-c6ccccc6)cc5cc4N(c4c(-c5ccccc5)cc(C(C)(C)C)cc4-c4ccccc4)c4cc(-c5ccc6c(c5)oc5ccccc56)cc2c43)c(-c2ccccc2)c1 ; c1ccc(-c2ccc3cc4c(cc3c2)N(c2cccc3oc5ccccc5c23)c2cc(-c3ccc5c(c3)oc3ccccc35)cc3c2B4c2cc4ccc(-c5ccccc5)cc4cc2N3c2cccc3oc4ccccc4c23)cc1 ; c1ccc(-c2ccc3cc4c(cc3c2)N(c2cccc3sc5ccccc5c23)c2cc(-c3ccc5c(c3)oc3ccccc35)cc3c2B4c2cc4ccc(-c5ccccc5)cc4cc2N3c2cccc3sc4ccccc4c23)cc1]

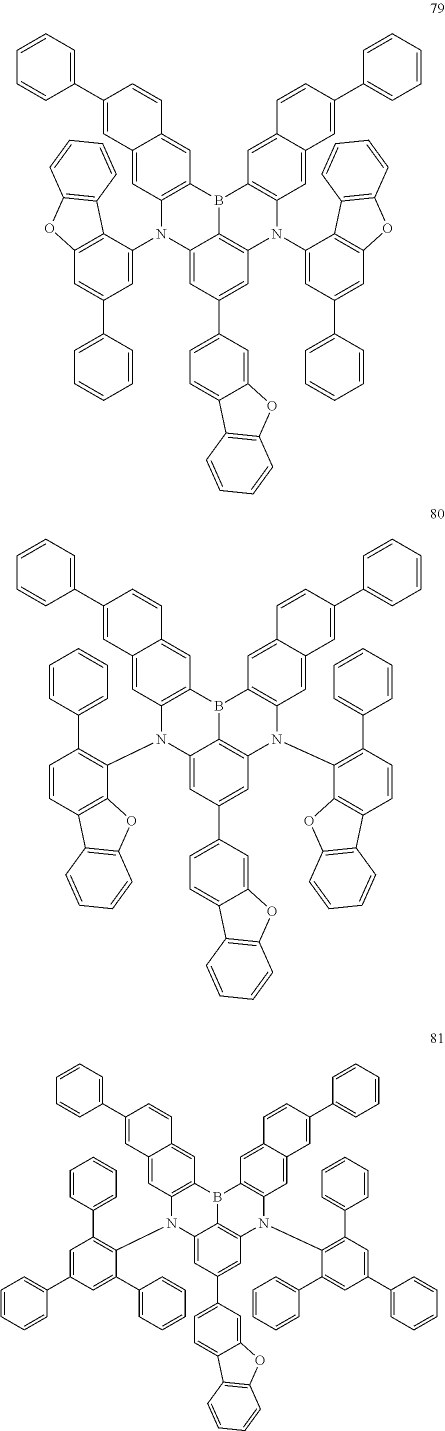 [SMILES: c1ccc(-c2ccc3cc4c(cc3c2)N(c2cc(-c3ccccc3)cc3oc5ccccc5c23)c2cc(-c3ccc5c(c3)oc3ccccc35)cc3c2B4c2cc4ccc(-c5ccccc5)cc4cc2N3c2cc(-c3ccccc3)cc3oc4ccccc4c23)cc1 ; c1ccc(-c2ccc3cc4c(cc3c2)N(c2c(-c3ccccc3)ccc3c2oc2ccccc23)c2cc(-c3ccc5c(c3)oc3ccccc35)cc3c2B4c2cc4ccc(-c5ccccc5)cc4cc2N3c2c(-c3ccccc3)ccc3c2oc2ccccc23)cc1 ; c1ccc(-c2cc(-c3ccccc3)c(N3c4cc5cc(-c6ccccc6)ccc5cc4B4c5cc6ccc(-c7ccccc7)cc6cc5N(c5c(-c6ccccc6)cc(-c6ccccc6)cc5-c5ccccc5)c5cc(-c6ccc7c(c6)oc6ccccc67)cc3c54)c(-c3ccccc3)c2)cc1]

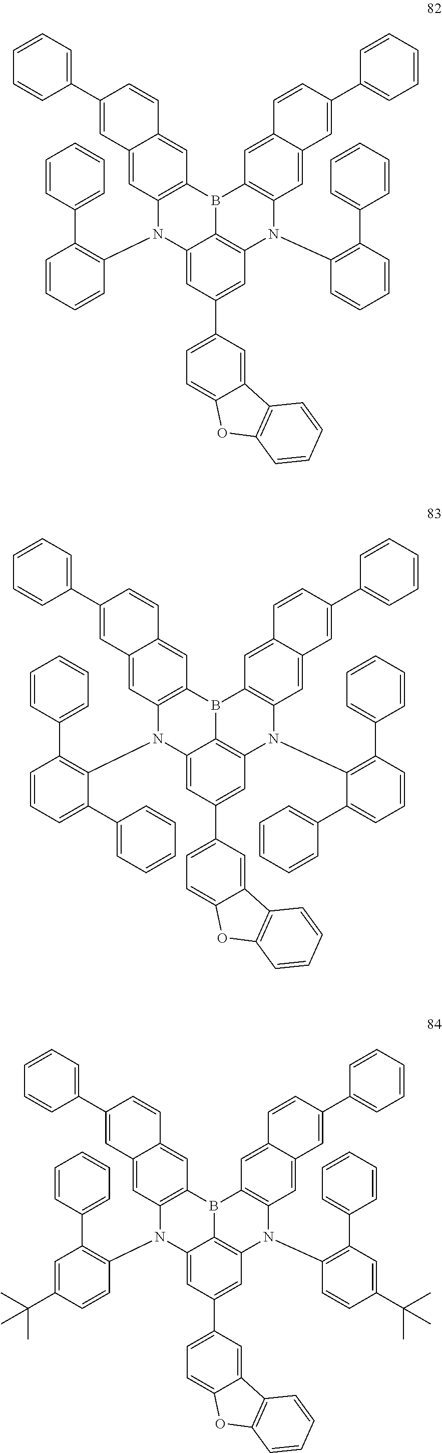 [SMILES: c1ccc(-c2ccc3cc4c(cc3c2)N(c2ccccc2-c2ccccc2)c2cc(-c3ccc5oc6ccccc6c5c3)cc3c2B4c2cc4ccc(-c5ccccc5)cc4cc2N3c2ccccc2-c2ccccc2)cc1 ; c1ccc(-c2ccc3cc4c(cc3c2)N(c2c(-c3ccccc3)cccc2-c2ccccc2)c2cc(-c3ccc5oc6ccccc6c5c3)cc3c2B4c2cc4ccc(-c5ccccc5)cc4cc2N3c2c(-c3ccccc3)cccc2-c2ccccc2)cc1 ; CC(C)(C)c1ccc(N2c3cc4cc(-c5ccccc5)ccc4cc3B3c4cc5ccc(-c6ccccc6)cc5cc4N(c4ccc(C(C)(C)C)cc4-c4ccccc4)c4cc(-c5ccc6oc7ccccc7c6c5)cc2c43)c(-c2ccccc2)c1]

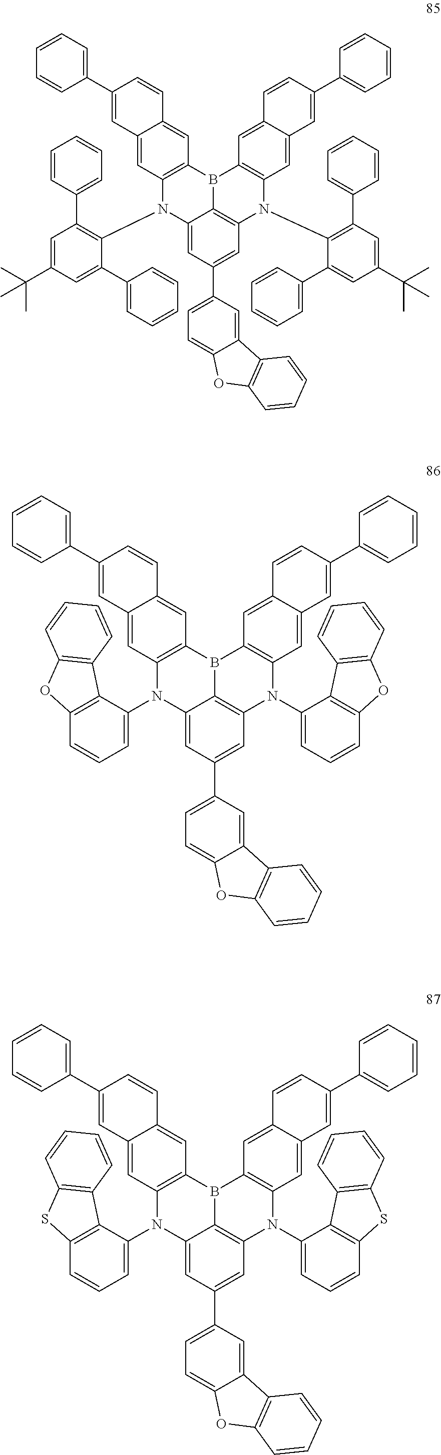 [SMILES: CC(C)(C)c1cc(-c2ccccc2)c(N2c3cc4cc(-c5ccccc5)ccc4cc3B3c4cc5ccc(-c6ccccc6)cc5cc4N(c4c(-c5ccccc5)cc(C(C)(C)C)cc4-c4ccccc4)c4cc(-c5ccc6oc7ccccc7c6c5)cc2c43)c(-c2ccccc2)c1 ; c1ccc(-c2ccc3cc4c(cc3c2)N(c2cccc3oc5ccccc5c23)c2cc(-c3ccc5oc6ccccc6c5c3)cc3c2B4c2cc4ccc(-c5ccccc5)cc4cc2N3c2cccc3oc4ccccc4c23)cc1 ; c1ccc(-c2ccc3cc4c(cc3c2)N(c2cccc3sc5ccccc5c23)c2cc(-c3ccc5oc6ccccc6c5c3)cc3c2B4c2cc4ccc(-c5ccccc5)cc4cc2N3c2cccc3sc4ccccc4c23)cc1]

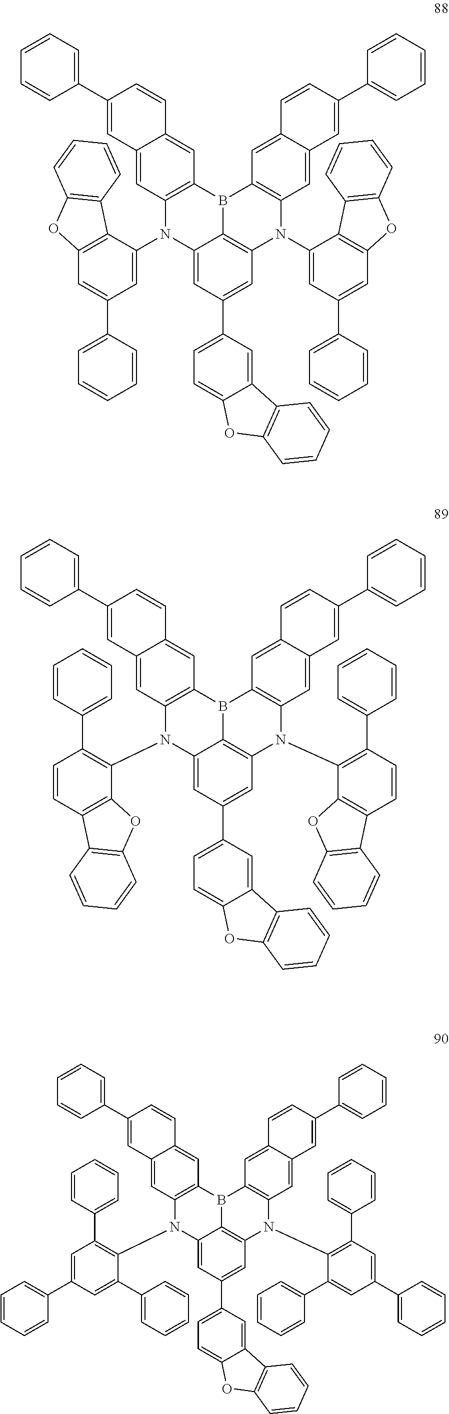 [SMILES: c1ccc(-c2ccc3cc4c(cc3c2)N(c2cc(-c3ccccc3)cc3oc5ccccc5c23)c2cc(-c3ccc5oc6ccccc6c5c3)cc3c2B4c2cc4ccc(-c5ccccc5)cc4cc2N3c2cc(-c3ccccc3)cc3oc4ccccc4c23)cc1 ; c1ccc(-c2ccc3cc4c(cc3c2)N(c2c(-c3ccccc3)ccc3c2oc2ccccc23)c2cc(-c3ccc5oc6ccccc6c5c3)cc3c2B4c2cc4ccc(-c5ccccc5)cc4cc2N3c2c(-c3ccccc3)ccc3c2oc2ccccc23)cc1 ; c1ccc(-c2cc(-c3ccccc3)c(N3c4cc5cc(-c6ccccc6)ccc5cc4B4c5cc6ccc(-c7ccccc7)cc6cc5N(c5c(-c6ccccc6)cc(-c6ccccc6)cc5-c5ccccc5)c5cc(-c6ccc7oc8ccccc8c7c6)cc3c54)c(-c3ccccc3)c2)cc1]

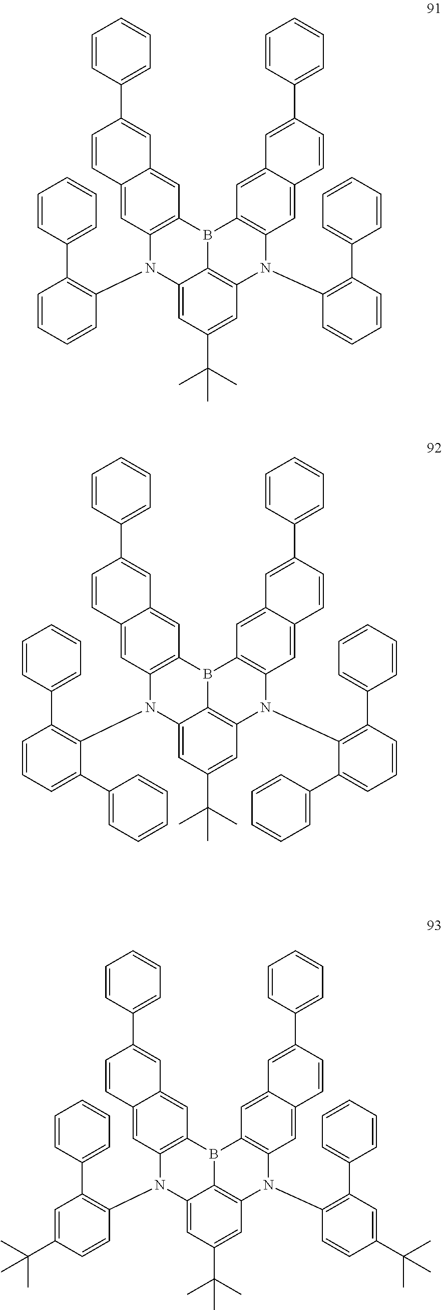 [SMILES: CC(C)(C)c1cc2c3c(c1)N(c1ccccc1-c1ccccc1)c1cc4ccc(-c5ccccc5)cc4cc1B3c1cc3cc(-c4ccccc4)ccc3cc1N2c1ccccc1-c1ccccc1 ; CC(C)(C)c1cc2c3c(c1)N(c1c(-c4ccccc4)cccc1-c1ccccc1)c1cc4ccc(-c5ccccc5)cc4cc1B3c1cc3cc(-c4ccccc4)ccc3cc1N2c1c(-c2ccccc2)cccc1-c1ccccc1 ; CC(C)(C)c1ccc(N2c3cc4ccc(-c5ccccc5)cc4cc3B3c4cc5cc(-c6ccccc6)ccc5cc4N(c4ccc(C(C)(C)C)cc4-c4ccccc4)c4cc(C(C)(C)C)cc2c43)c(-c2ccccc2)c1]

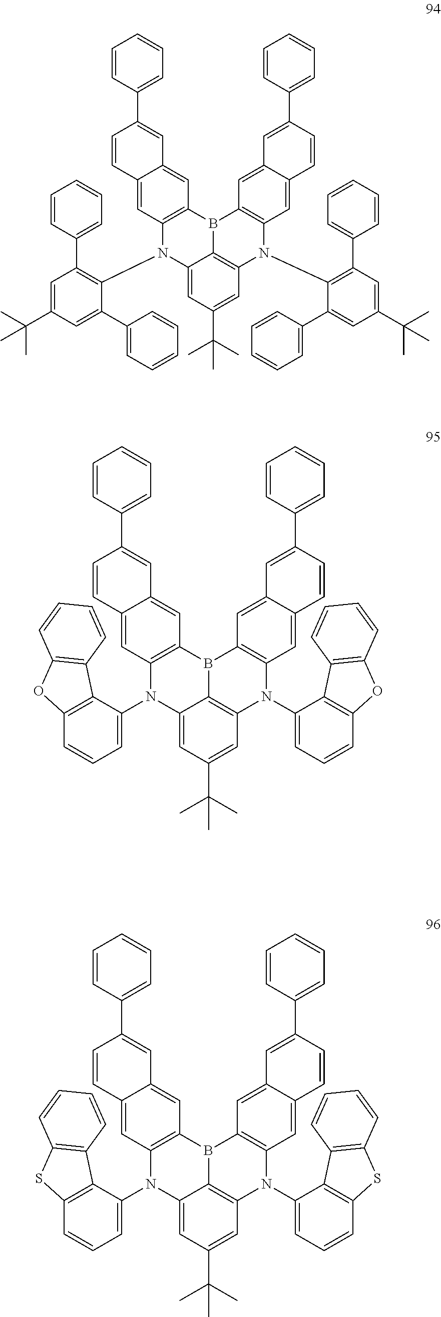 [SMILES: CC(C)(C)c1cc(-c2ccccc2)c(N2c3cc4ccc(-c5ccccc5)cc4cc3B3c4cc5cc(-c6ccccc6)ccc5cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc2c3c(c1)N(c1cccc4oc5ccccc5c14)c1cc4ccc(-c5ccccc5)cc4cc1B3c1cc3cc(-c4ccccc4)ccc3cc1N2c1cccc2oc3ccccc3c12 ; CC(C)(C)c1cc2c3c(c1)N(c1cccc4sc5ccccc5c14)c1cc4ccc(-c5ccccc5)cc4cc1B3c1cc3cc(-c4ccccc4)ccc3cc1N2c1cccc2sc3ccccc3c12]

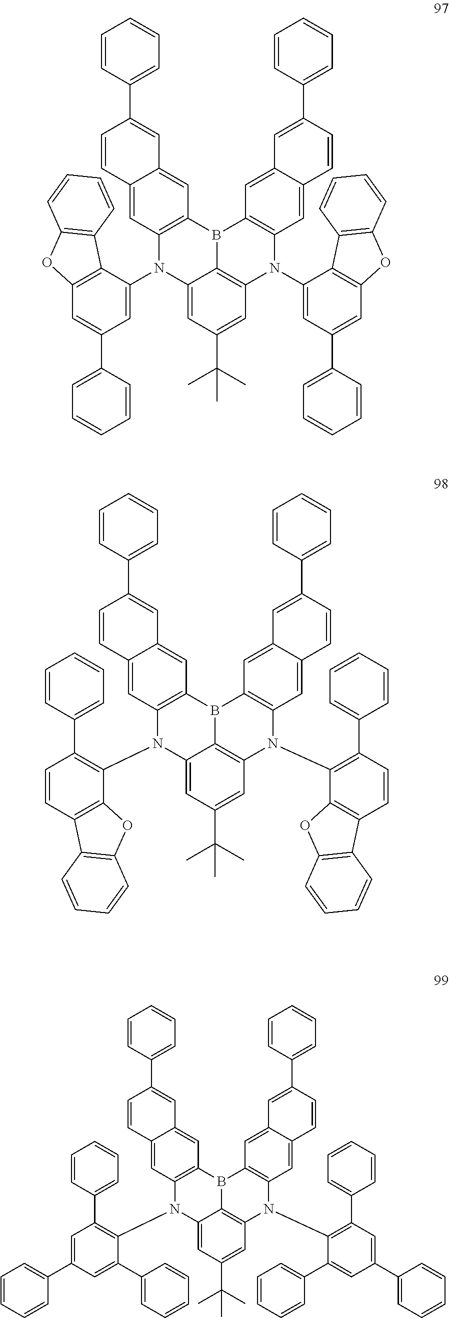 [SMILES: CC(C)(C)c1cc2c3c(c1)N(c1cc(-c4ccccc4)cc4oc5ccccc5c14)c1cc4ccc(-c5ccccc5)cc4cc1B3c1cc3cc(-c4ccccc4)ccc3cc1N2c1cc(-c2ccccc2)cc2oc3ccccc3c12 ; CC(C)(C)c1cc2c3c(c1)N(c1c(-c4ccccc4)ccc4c1oc1ccccc14)c1cc4ccc(-c5ccccc5)cc4cc1B3c1cc3cc(-c4ccccc4)ccc3cc1N2c1c(-c2ccccc2)ccc2c1oc1ccccc12 ; CC(C)(C)c1cc2c3c(c1)N(c1c(-c4ccccc4)cc(-c4ccccc4)cc1-c1ccccc1)c1cc4ccc(-c5ccccc5)cc4cc1B3c1cc3cc(-c4ccccc4)ccc3cc1N2c1c(-c2ccccc2)cc(-c2ccccc2)cc1-c1ccccc1]

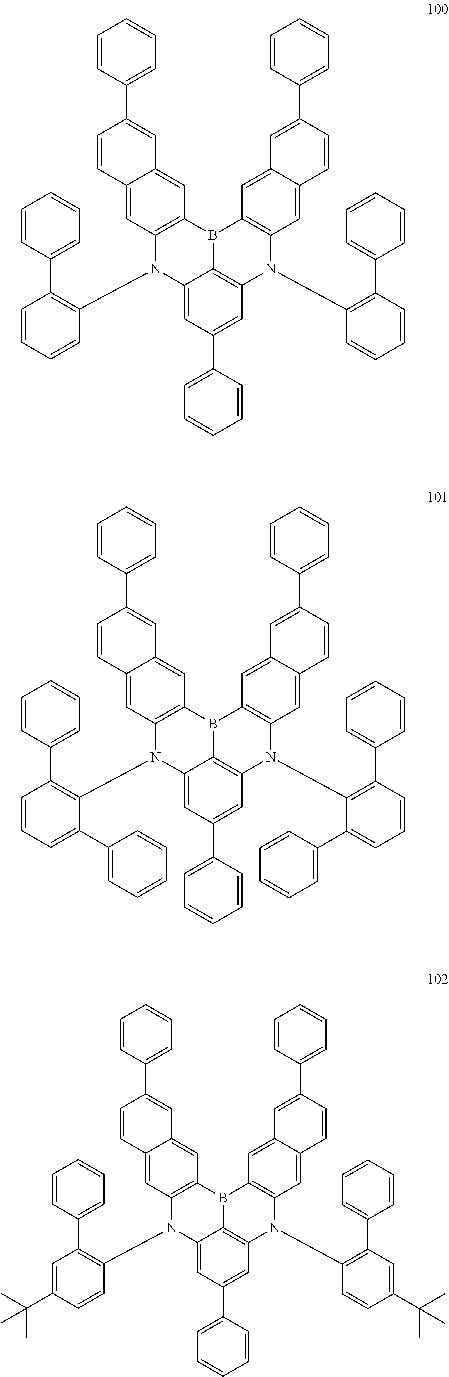 [SMILES: c1ccc(-c2cc3c4c(c2)N(c2ccccc2-c2ccccc2)c2cc5ccc(-c6ccccc6)cc5cc2B4c2cc4cc(-c5ccccc5)ccc4cc2N3c2ccccc2-c2ccccc2)cc1 ; c1ccc(-c2cc3c4c(c2)N(c2c(-c5ccccc5)cccc2-c2ccccc2)c2cc5ccc(-c6ccccc6)cc5cc2B4c2cc4cc(-c5ccccc5)ccc4cc2N3c2c(-c3ccccc3)cccc2-c2ccccc2)cc1 ; CC(C)(C)c1ccc(N2c3cc4ccc(-c5ccccc5)cc4cc3B3c4cc5cc(-c6ccccc6)ccc5cc4N(c4ccc(C(C)(C)C)cc4-c4ccccc4)c4cc(-c5ccccc5)cc2c43)c(-c2ccccc2)c1]

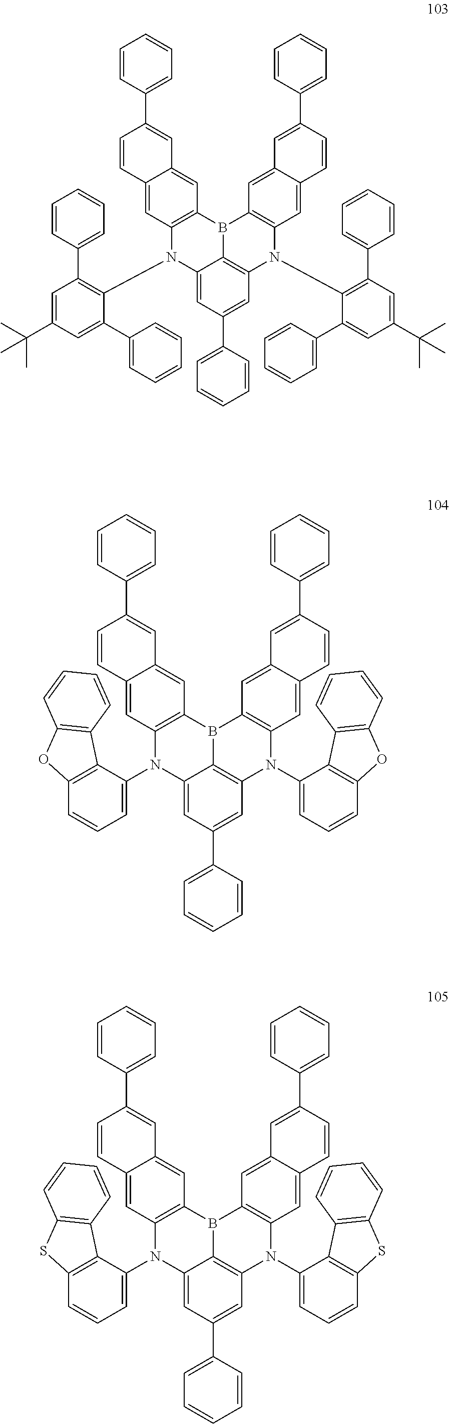 [SMILES: CC(C)(C)c1cc(-c2ccccc2)c(N2c3cc4ccc(-c5ccccc5)cc4cc3B3c4cc5cc(-c6ccccc6)ccc5cc4N(c4c(-c5ccccc5)cc(C(C)(C)C)cc4-c4ccccc4)c4cc(-c5ccccc5)cc2c43)c(-c2ccccc2)c1 ; c1ccc(-c2cc3c4c(c2)N(c2cccc5oc6ccccc6c25)c2cc5ccc(-c6ccccc6)cc5cc2B4c2cc4cc(-c5ccccc5)ccc4cc2N3c2cccc3oc4ccccc4c23)cc1 ; c1ccc(-c2cc3c4c(c2)N(c2cccc5sc6ccccc6c25)c2cc5ccc(-c6ccccc6)cc5cc2B4c2cc4cc(-c5ccccc5)ccc4cc2N3c2cccc3sc4ccccc4c23)cc1]

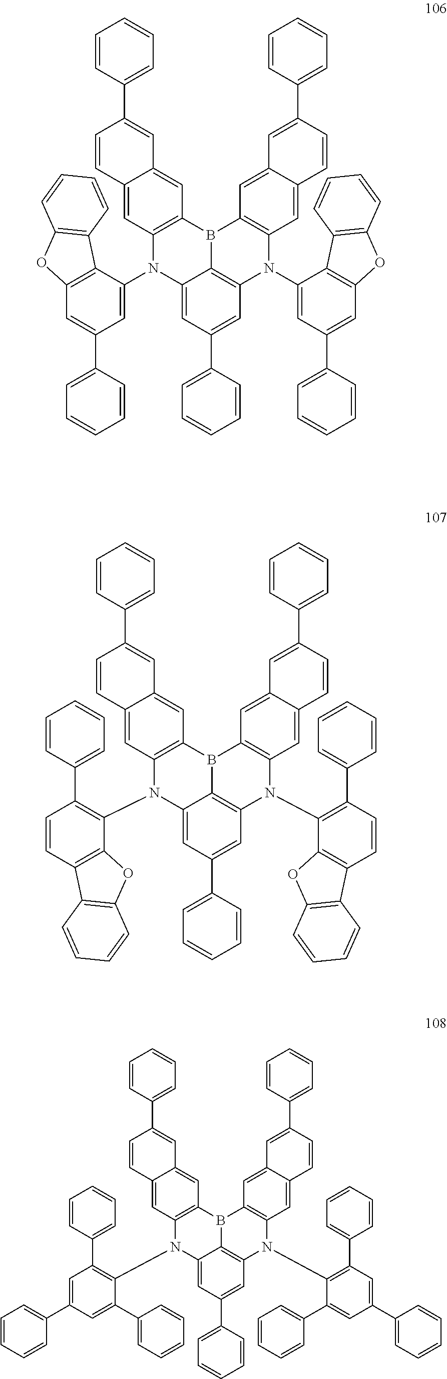 [SMILES: c1ccc(-c2cc3c4c(c2)N(c2cc(-c5ccccc5)cc5oc6ccccc6c25)c2cc5ccc(-c6ccccc6)cc5cc2B4c2cc4cc(-c5ccccc5)ccc4cc2N3c2cc(-c3ccccc3)cc3oc4ccccc4c23)cc1 ; c1ccc(-c2cc3c4c(c2)N(c2c(-c5ccccc5)ccc5c2oc2ccccc25)c2cc5ccc(-c6ccccc6)cc5cc2B4c2cc4cc(-c5ccccc5)ccc4cc2N3c2c(-c3ccccc3)ccc3c2oc2ccccc23)cc1 ; c1ccc(-c2cc(-c3ccccc3)c(N3c4cc5ccc(-c6ccccc6)cc5cc4B4c5cc6cc(-c7ccccc7)ccc6cc5N(c5c(-c6ccccc6)cc(-c6ccccc6)cc5-c5ccccc5)c5cc(-c6ccccc6)cc3c54)c(-c3ccccc3)c2)cc1]

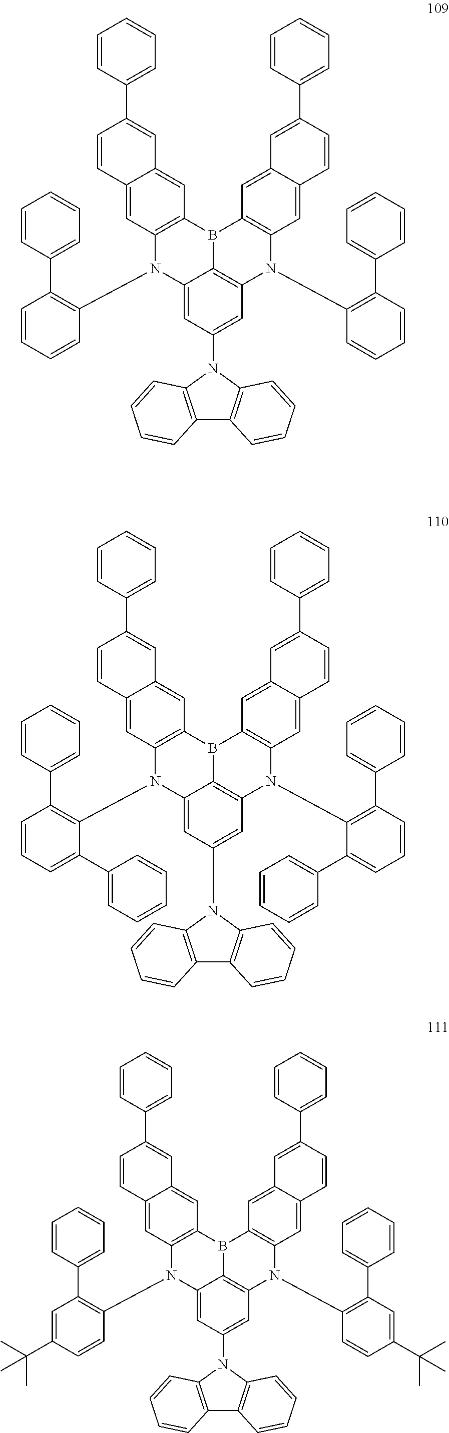 [SMILES: c1ccc(-c2ccc3cc4c(cc3c2)B2c3cc5cc(-c6ccccc6)ccc5cc3N(c3ccccc3-c3ccccc3)c3cc(-n5c6ccccc6c6ccccc65)cc(c32)N4c2ccccc2-c2ccccc2)cc1 ; c1ccc(-c2ccc3cc4c(cc3c2)B2c3cc5cc(-c6ccccc6)ccc5cc3N(c3c(-c5ccccc5)cccc3-c3ccccc3)c3cc(-n5c6ccccc6c6ccccc65)cc(c32)N4c2c(-c3ccccc3)cccc2-c2ccccc2)cc1 ; CC(C)(C)c1ccc(N2c3cc4ccc(-c5ccccc5)cc4cc3B3c4cc5cc(-c6ccccc6)ccc5cc4N(c4ccc(C(C)(C)C)cc4-c4ccccc4)c4cc(-n5c6ccccc6c6ccccc65)cc2c43)c(-c2ccccc2)c1]

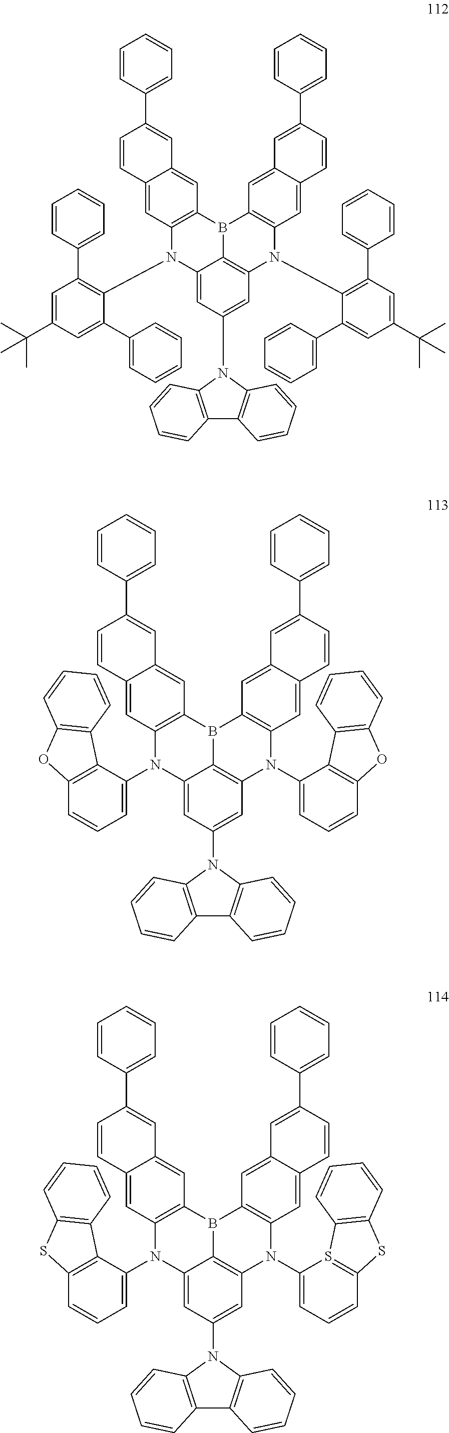 [SMILES: CC(C)(C)c1cc(-c2ccccc2)c(N2c3cc4ccc(-c5ccccc5)cc4cc3B3c4cc5cc(-c6ccccc6)ccc5cc4N(c4c(-c5ccccc5)cc(C(C)(C)C)cc4-c4ccccc4)c4cc(-n5c6ccccc6c6ccccc65)cc2c43)c(-c2ccccc2)c1 ; c1ccc(-c2ccc3cc4c(cc3c2)B2c3cc5cc(-c6ccccc6)ccc5cc3N(c3cccc5oc6ccccc6c35)c3cc(-n5c6ccccc6c6ccccc65)cc(c32)N4c2cccc3oc4ccccc4c23)cc1 ; C1=CC2=S(C(N3c4cc5ccc(-c6ccccc6)cc5cc4B4c5cc6cc(-c7ccccc7)ccc6cc5N(c5cccc6sc7ccccc7c56)c5cc(-n6c7ccccc7c7ccccc76)cc3c54)=C1)c1ccccc1S2]

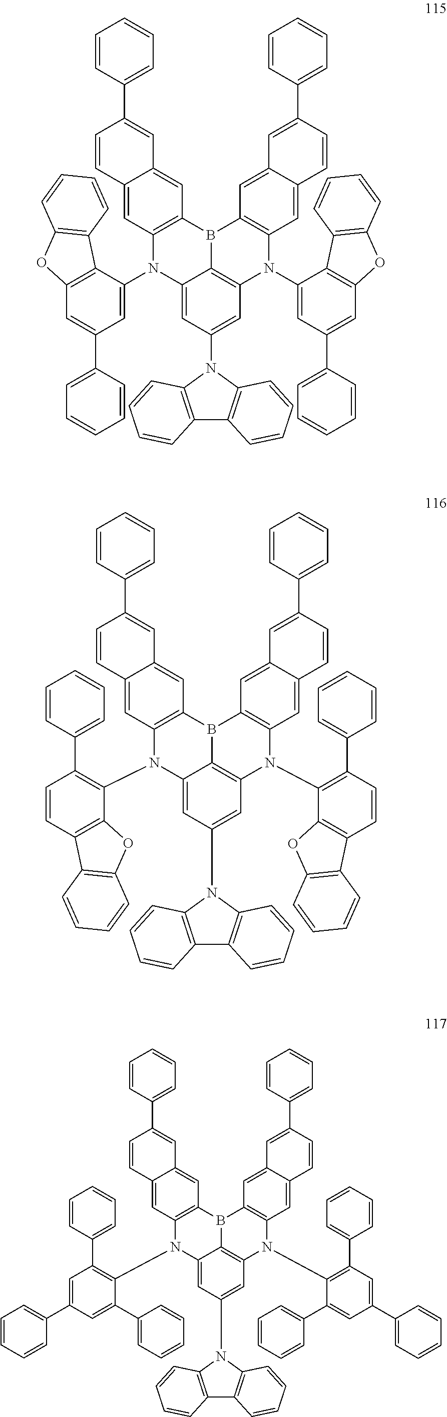 [SMILES: c1ccc(-c2ccc3cc4c(cc3c2)B2c3cc5cc(-c6ccccc6)ccc5cc3N(c3cc(-c5ccccc5)cc5oc6ccccc6c35)c3cc(-n5c6ccccc6c6ccccc65)cc(c32)N4c2cc(-c3ccccc3)cc3oc4ccccc4c23)cc1 ; c1ccc(-c2ccc3cc4c(cc3c2)B2c3cc5cc(-c6ccccc6)ccc5cc3N(c3c(-c5ccccc5)ccc5c3oc3ccccc35)c3cc(-n5c6ccccc6c6ccccc65)cc(c32)N4c2c(-c3ccccc3)ccc3c2oc2ccccc23)cc1 ; c1ccc(-c2cc(-c3ccccc3)c(N3c4cc5ccc(-c6ccccc6)cc5cc4B4c5cc6cc(-c7ccccc7)ccc6cc5N(c5c(-c6ccccc6)cc(-c6ccccc6)cc5-c5ccccc5)c5cc(-n6c7ccccc7c7ccccc76)cc3c54)c(-c3ccccc3)c2)cc1]

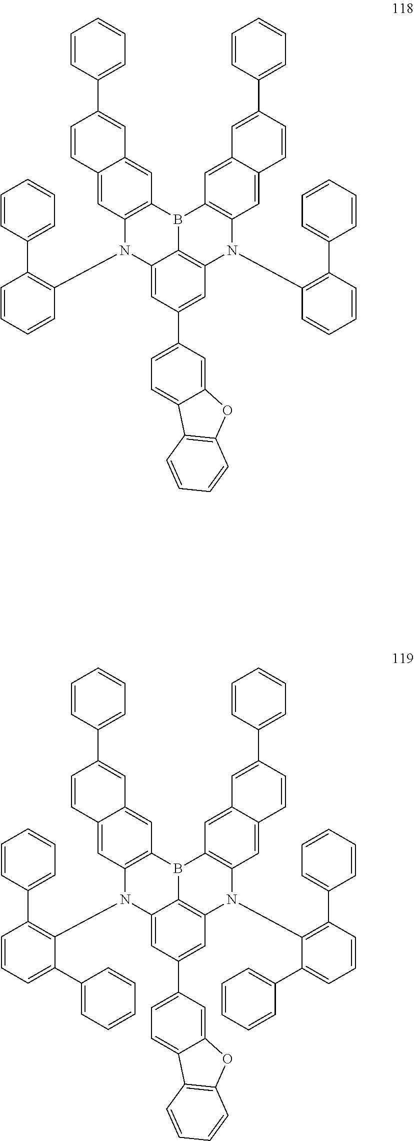 [SMILES: c1ccc(-c2ccc3cc4c(cc3c2)B2c3cc5cc(-c6ccccc6)ccc5cc3N(c3ccccc3-c3ccccc3)c3cc(-c5ccc6c(c5)oc5ccccc56)cc(c32)N4c2ccccc2-c2ccccc2)cc1 ; c1ccc(-c2ccc3cc4c(cc3c2)B2c3cc5cc(-c6ccccc6)ccc5cc3N(c3c(-c5ccccc5)cccc3-c3ccccc3)c3cc(-c5ccc6c(c5)oc5ccccc56)cc(c32)N4c2c(-c3ccccc3)cccc2-c2ccccc2)cc1]

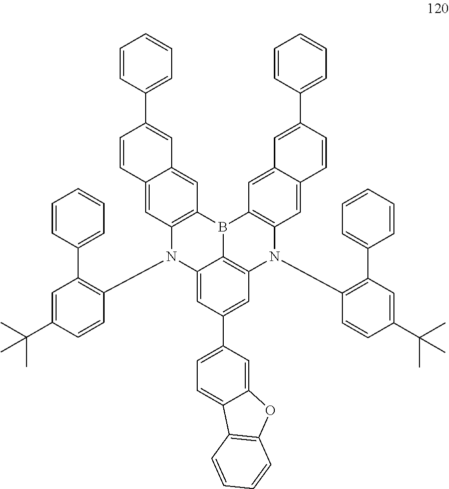 [SMILES: CC(C)(C)c1ccc(N2c3cc4ccc(-c5ccccc5)cc4cc3B3c4cc5cc(-c6ccccc6)ccc5cc4N(c4ccc(C(C)(C)C)cc4-c4ccccc4)c4cc(-c5ccc6c(c5)oc5ccccc56)cc2c43)c(-c2ccccc2)c1]

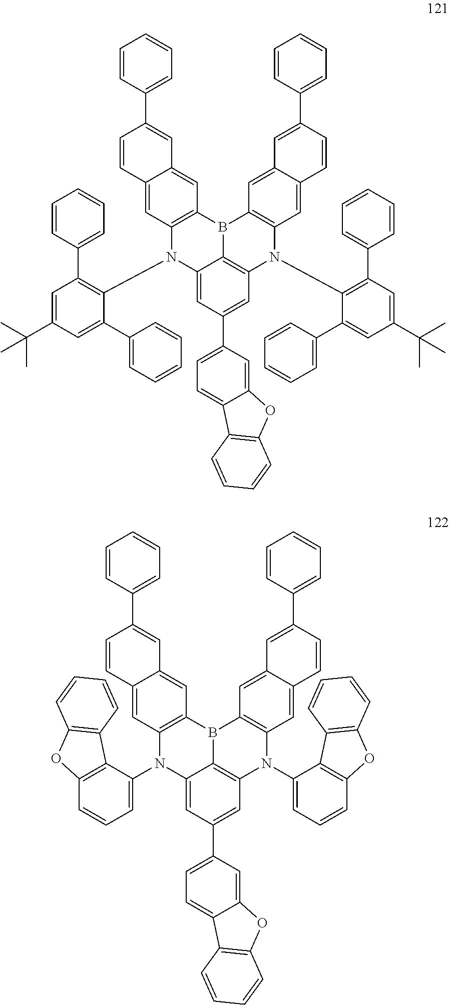 [SMILES: CC(C)(C)c1cc(-c2ccccc2)c(N2c3cc4ccc(-c5ccccc5)cc4cc3B3c4cc5cc(-c6ccccc6)ccc5cc4N(c4c(-c5ccccc5)cc(C(C)(C)C)cc4-c4ccccc4)c4cc(-c5ccc6c(c5)oc5ccccc56)cc2c43)c(-c2ccccc2)c1 ; c1ccc(-c2ccc3cc4c(cc3c2)B2c3cc5cc(-c6ccccc6)ccc5cc3N(c3cccc5oc6ccccc6c35)c3cc(-c5ccc6c(c5)oc5ccccc56)cc(c32)N4c2cccc3oc4ccccc4c23)cc1]

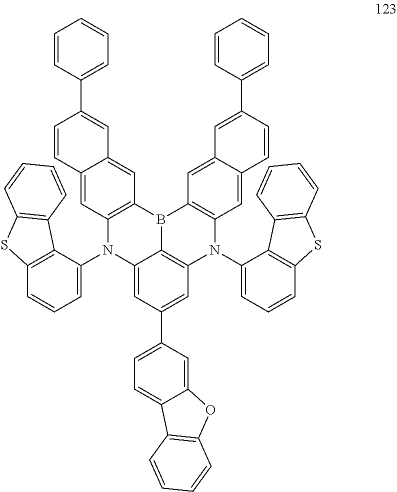 [SMILES: c1ccc(-c2ccc3cc4c(cc3c2)B2c3cc5cc(-c6ccccc6)ccc5cc3N(c3cccc5sc6ccccc6c35)c3cc(-c5ccc6c(c5)oc5ccccc56)cc(c32)N4c2cccc3sc4ccccc4c23)cc1]

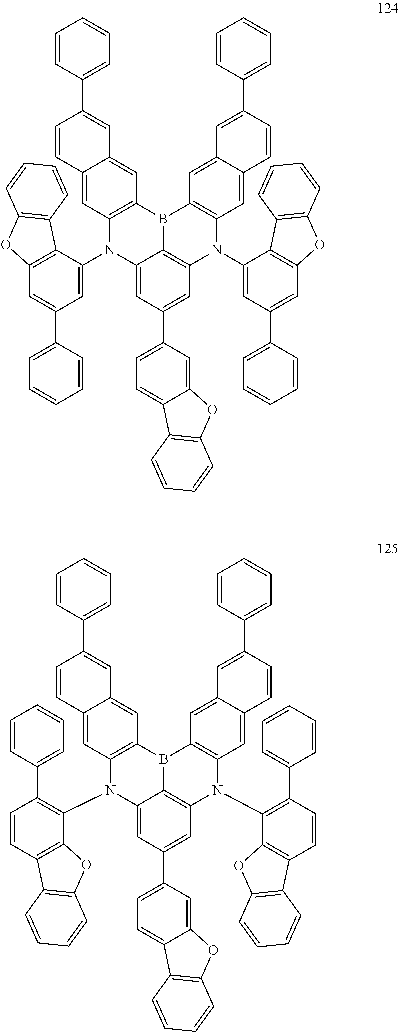 [SMILES: c1ccc(-c2ccc3cc4c(cc3c2)B2c3cc5cc(-c6ccccc6)ccc5cc3N(c3cc(-c5ccccc5)cc5oc6ccccc6c35)c3cc(-c5ccc6c(c5)oc5ccccc56)cc(c32)N4c2cc(-c3ccccc3)cc3oc4ccccc4c23)cc1 ; c1ccc(-c2ccc3cc4c(cc3c2)B2c3cc5cc(-c6ccccc6)ccc5cc3N(c3c(-c5ccccc5)ccc5c3oc3ccccc35)c3cc(-c5ccc6c(c5)oc5ccccc56)cc(c32)N4c2c(-c3ccccc3)ccc3c2oc2ccccc23)cc1]

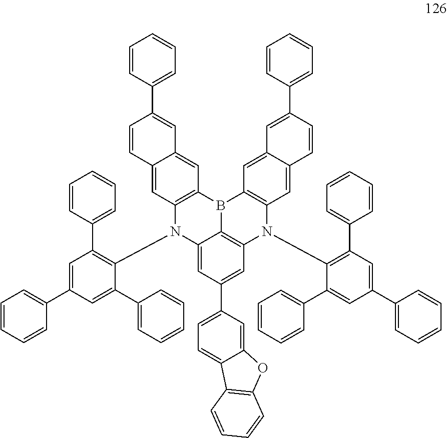 [SMILES: c1ccc(-c2cc(-c3ccccc3)c(N3c4cc5ccc(-c6ccccc6)cc5cc4B4c5cc6cc(-c7ccccc7)ccc6cc5N(c5c(-c6ccccc6)cc(-c6ccccc6)cc5-c5ccccc5)c5cc(-c6ccc7c(c6)oc6ccccc67)cc3c54)c(-c3ccccc3)c2)cc1]

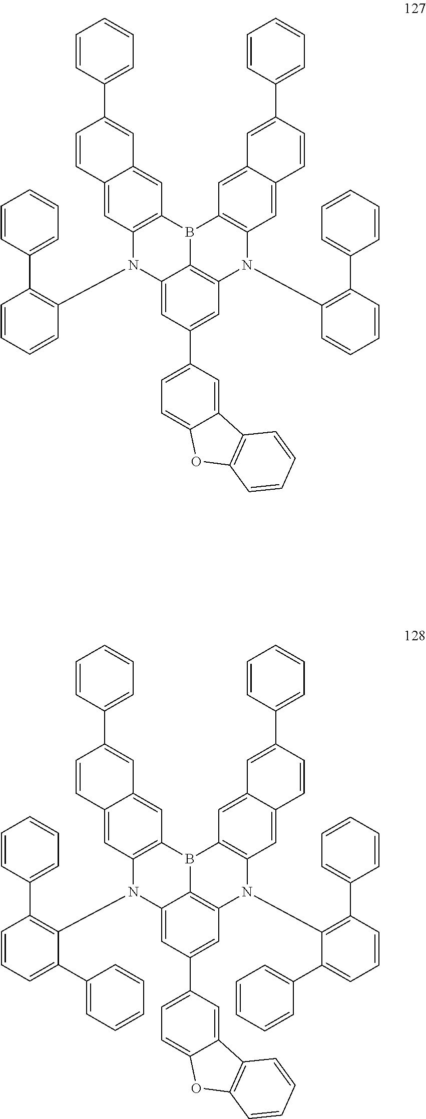 [SMILES: c1ccc(-c2ccc3cc4c(cc3c2)B2c3cc5cc(-c6ccccc6)ccc5cc3N(c3ccccc3-c3ccccc3)c3cc(-c5ccc6oc7ccccc7c6c5)cc(c32)N4c2ccccc2-c2ccccc2)cc1 ; c1ccc(-c2ccc3cc4c(cc3c2)B2c3cc5cc(-c6ccccc6)ccc5cc3N(c3c(-c5ccccc5)cccc3-c3ccccc3)c3cc(-c5ccc6oc7ccccc7c6c5)cc(c32)N4c2c(-c3ccccc3)cccc2-c2ccccc2)cc1]

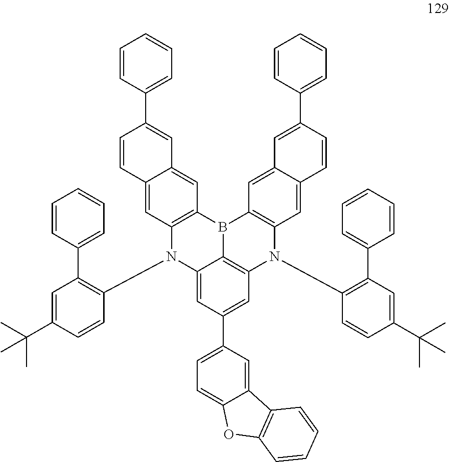 [SMILES: CC(C)(C)c1ccc(N2c3cc4ccc(-c5ccccc5)cc4cc3B3c4cc5cc(-c6ccccc6)ccc5cc4N(c4ccc(C(C)(C)C)cc4-c4ccccc4)c4cc(-c5ccc6oc7ccccc7c6c5)cc2c43)c(-c2ccccc2)c1]

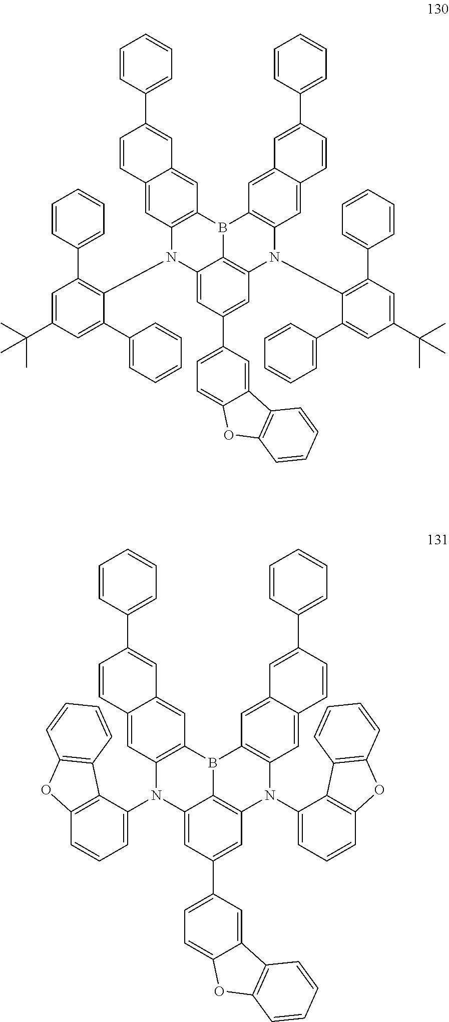 [SMILES: CC(C)(C)c1cc(-c2ccccc2)c(N2c3cc4ccc(-c5ccccc5)cc4cc3B3c4cc5cc(-c6ccccc6)ccc5cc4N(c4c(-c5ccccc5)cc(C(C)(C)C)cc4-c4ccccc4)c4cc(-c5ccc6oc7ccccc7c6c5)cc2c43)c(-c2ccccc2)c1 ; c1ccc(-c2ccc3cc4c(cc3c2)B2c3cc5cc(-c6ccccc6)ccc5cc3N(c3cccc5oc6ccccc6c35)c3cc(-c5ccc6oc7ccccc7c6c5)cc(c32)N4c2cccc3oc4ccccc4c23)cc1]

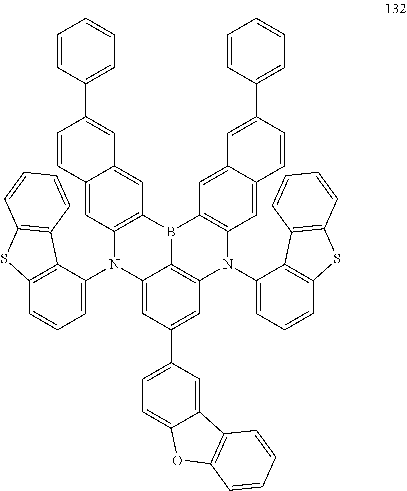 [SMILES: c1ccc(-c2ccc3cc4c(cc3c2)B2c3cc5cc(-c6ccccc6)ccc5cc3N(c3cccc5sc6ccccc6c35)c3cc(-c5ccc6oc7ccccc7c6c5)cc(c32)N4c2cccc3sc4ccccc4c23)cc1]

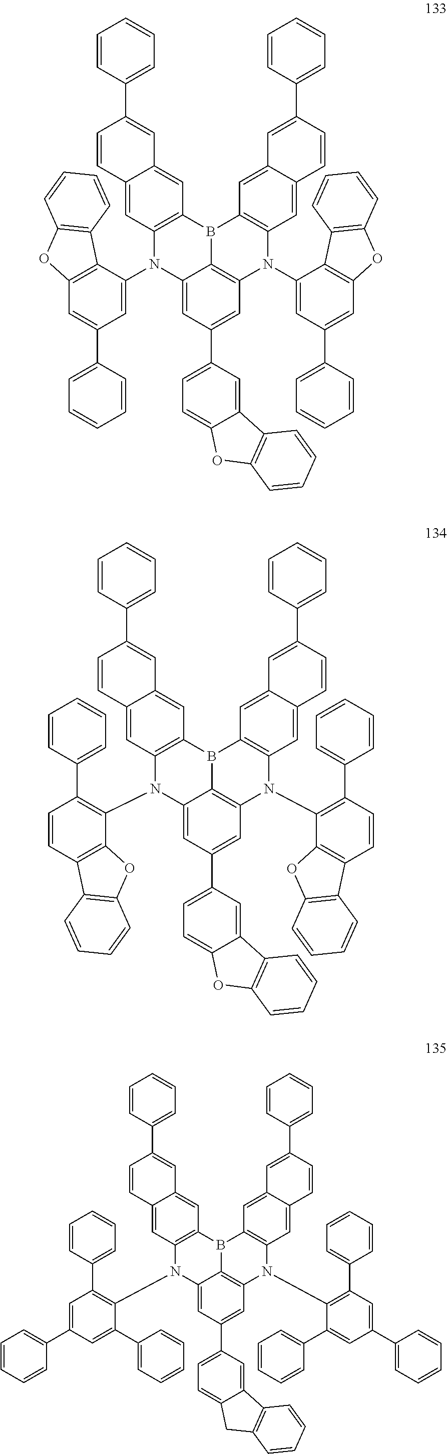 [SMILES: c1ccc(-c2ccc3cc4c(cc3c2)B2c3cc5cc(-c6ccccc6)ccc5cc3N(c3cc(-c5ccccc5)cc5oc6ccccc6c35)c3cc(-c5ccc6oc7ccccc7c6c5)cc(c32)N4c2cc(-c3ccccc3)cc3oc4ccccc4c23)cc1 ; c1ccc(-c2ccc3cc4c(cc3c2)B2c3cc5cc(-c6ccccc6)ccc5cc3N(c3c(-c5ccccc5)ccc5c3oc3ccccc35)c3cc(-c5ccc6oc7ccccc7c6c5)cc(c32)N4c2c(-c3ccccc3)ccc3c2oc2ccccc23)cc1 ; c1ccc(-c2cc(-c3ccccc3)c(N3c4cc5ccc(-c6ccccc6)cc5cc4B4c5cc6cc(-c7ccccc7)ccc6cc5N(c5c(-c6ccccc6)cc(-c6ccccc6)cc5-c5ccccc5)c5cc(-c6ccc7c(c6)-c6ccccc6C7)cc3c54)c(-c3ccccc3)c2)cc1]

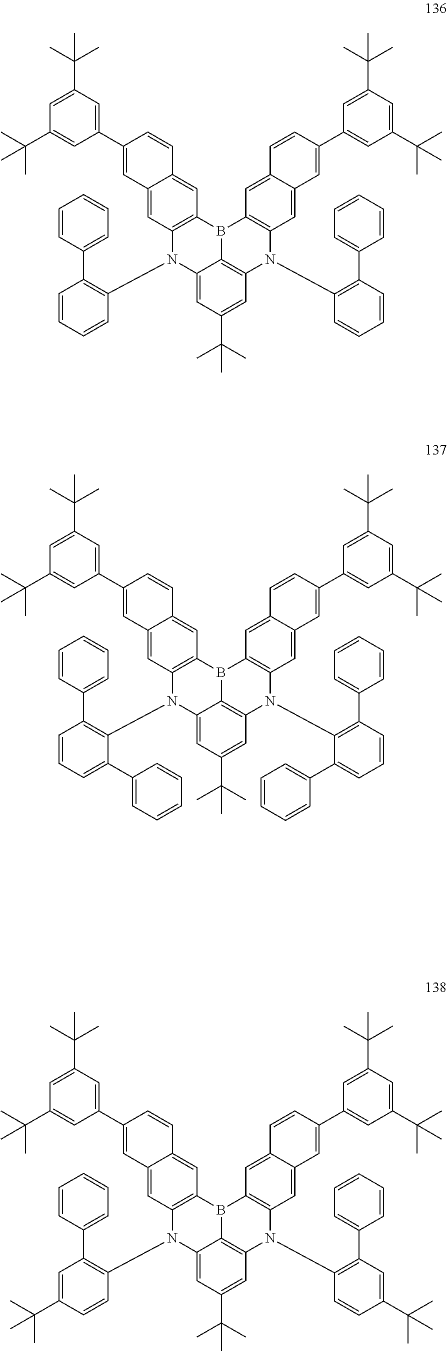

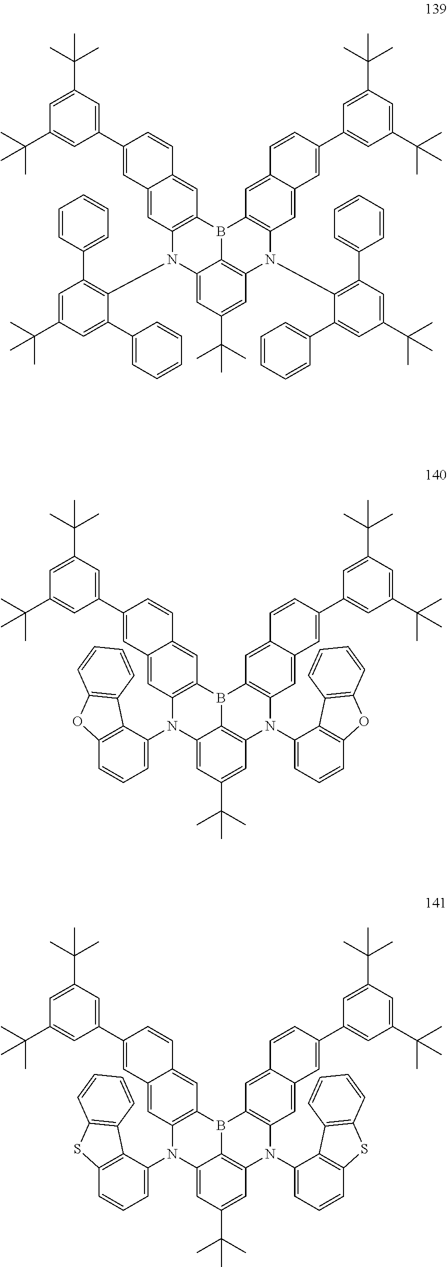

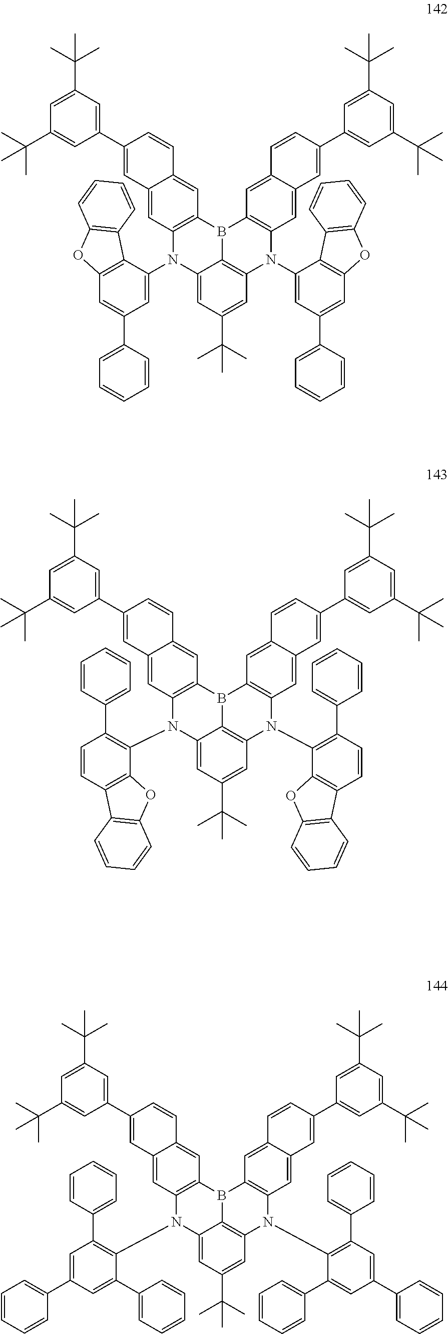

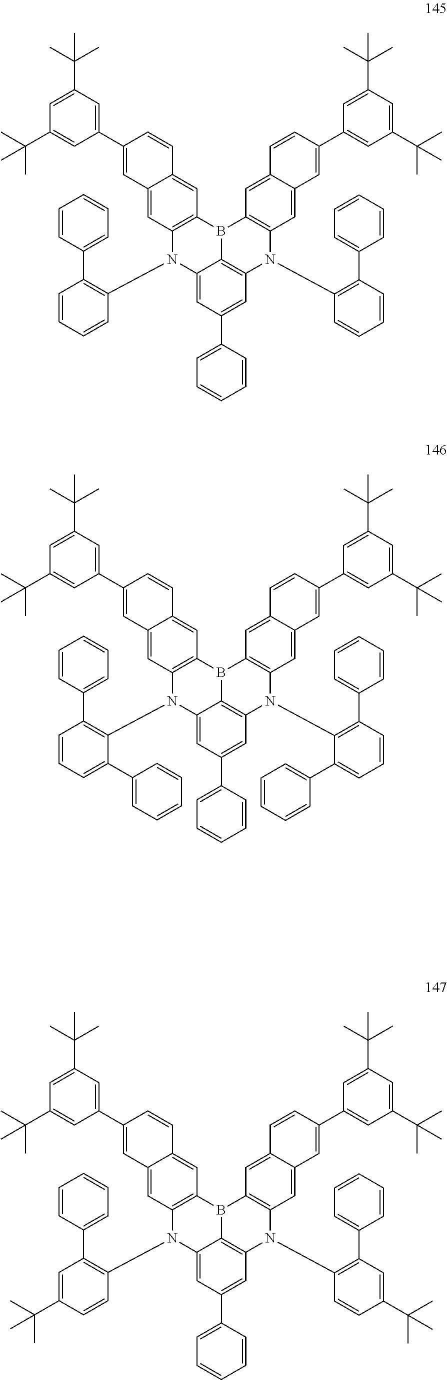

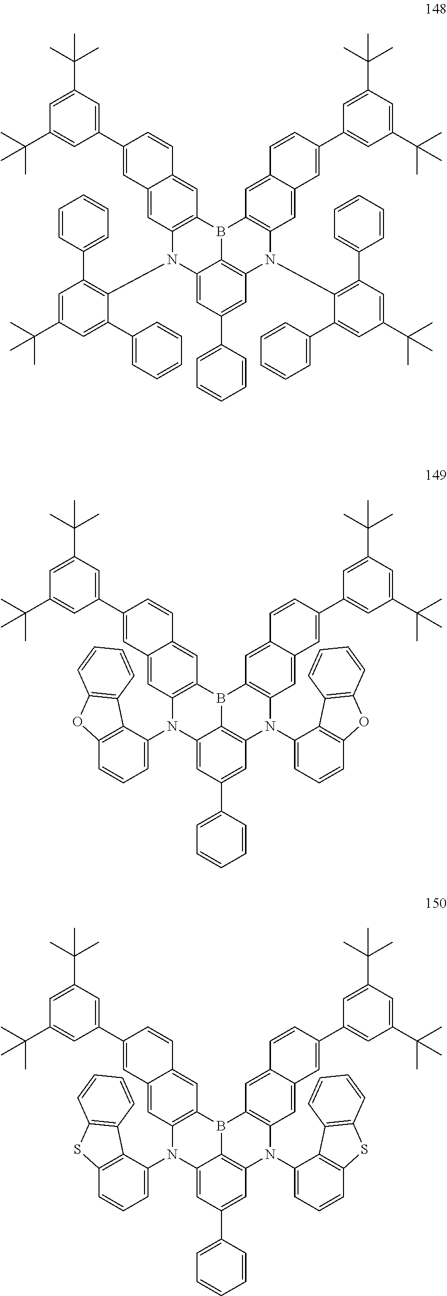

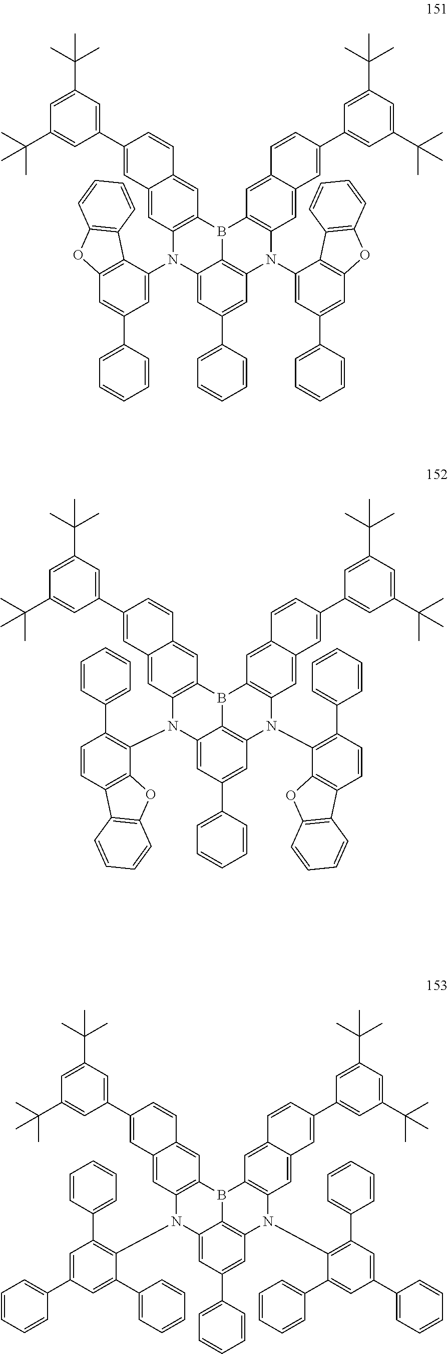

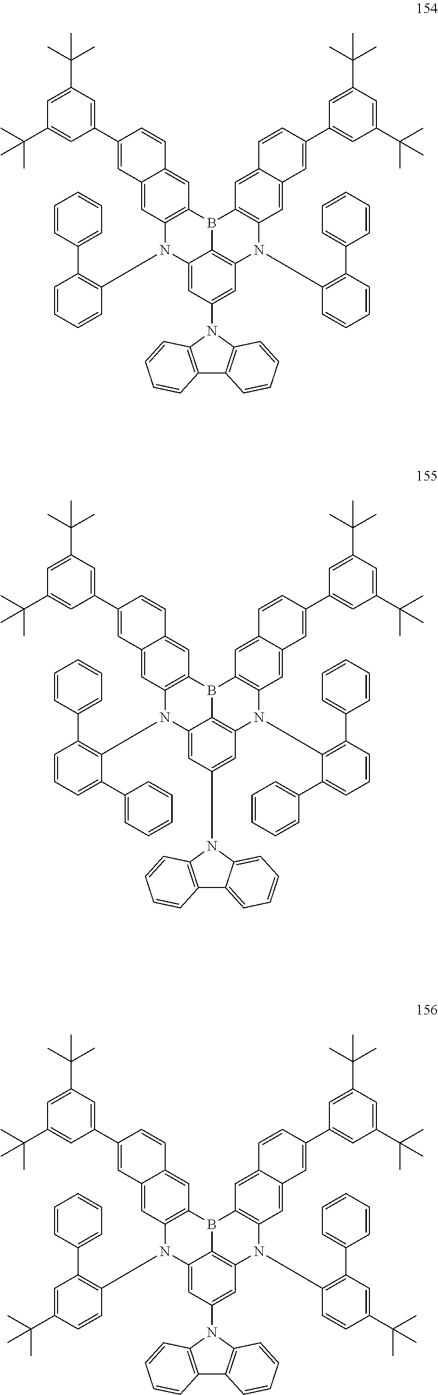

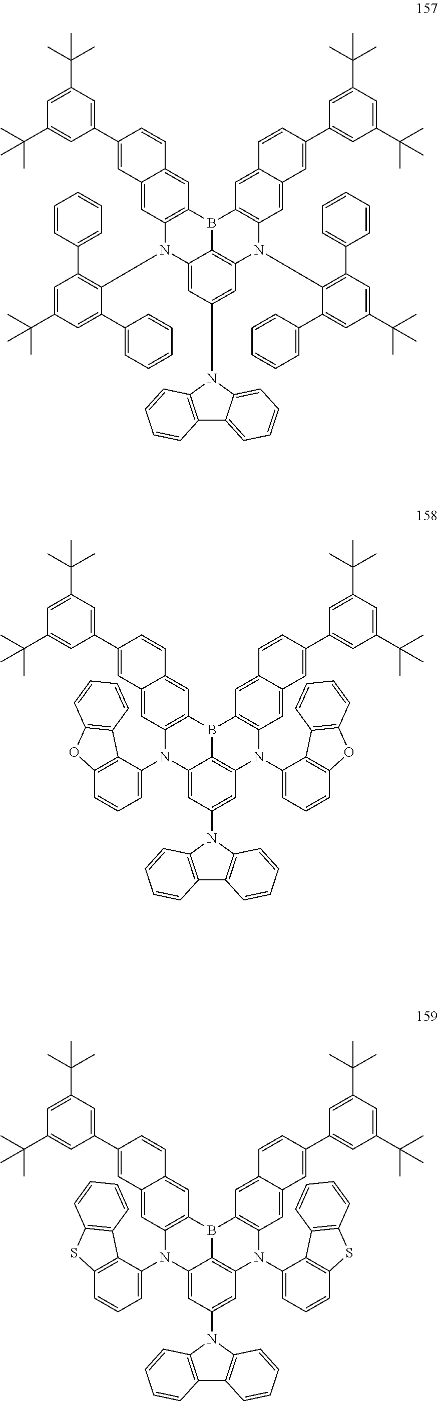

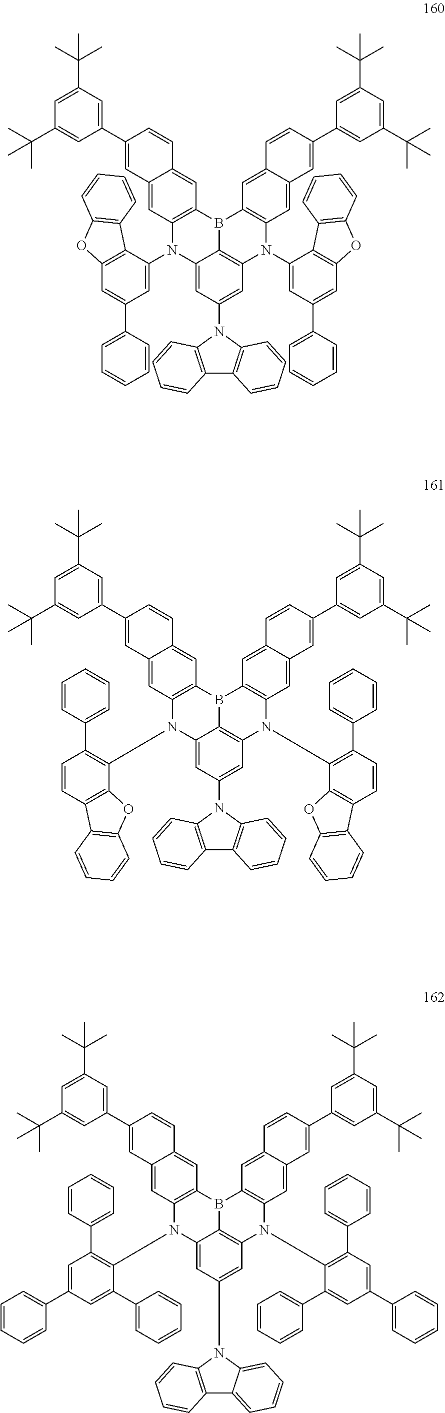

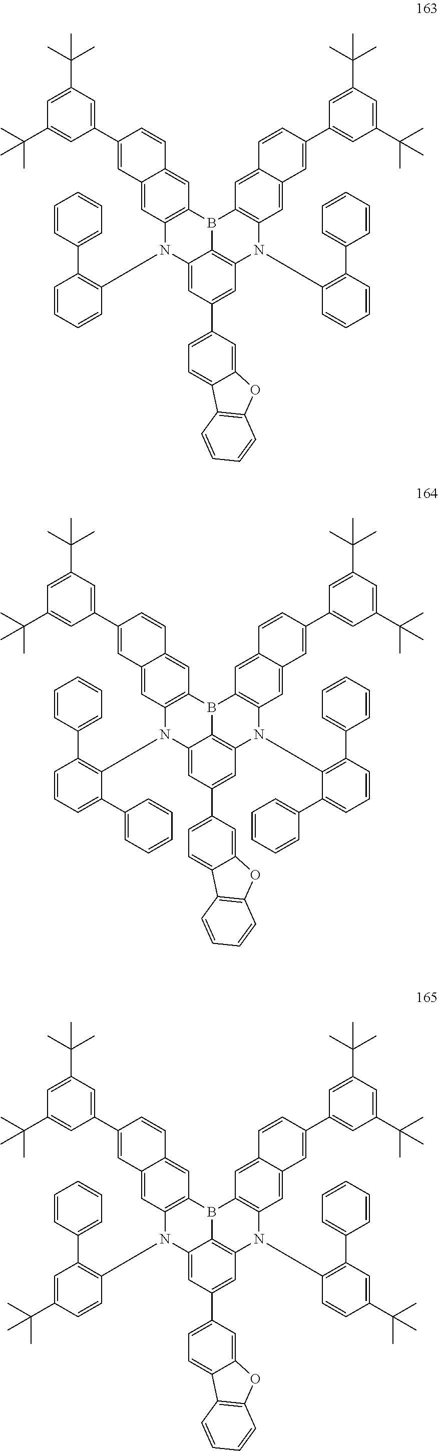

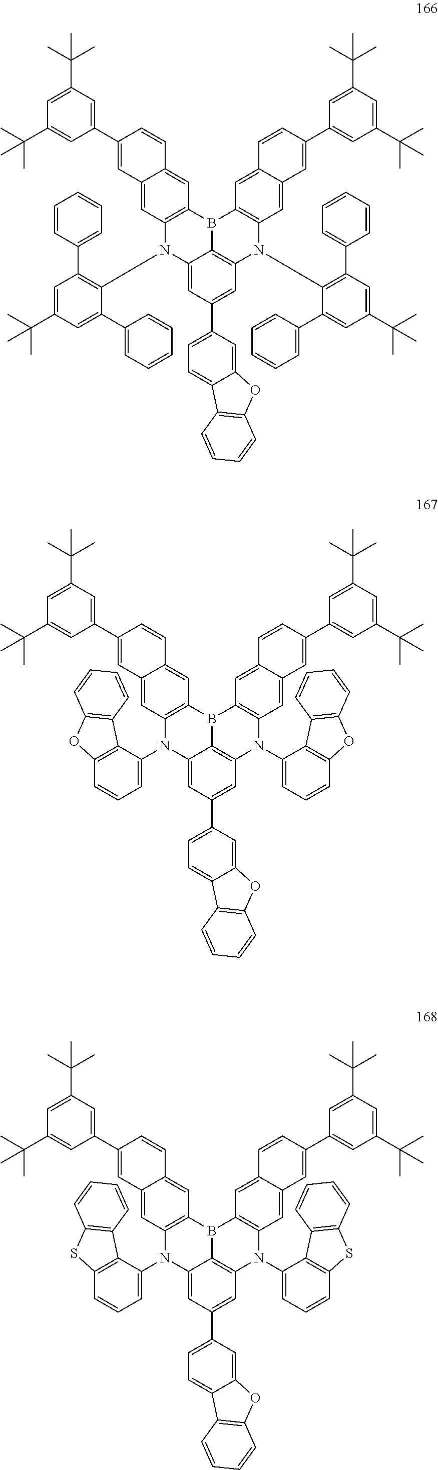

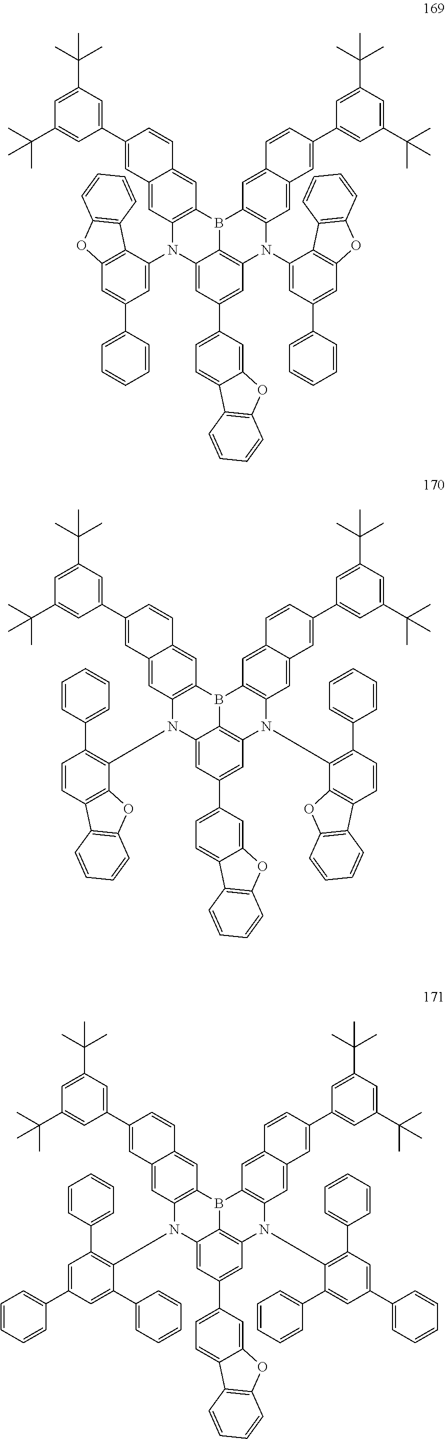

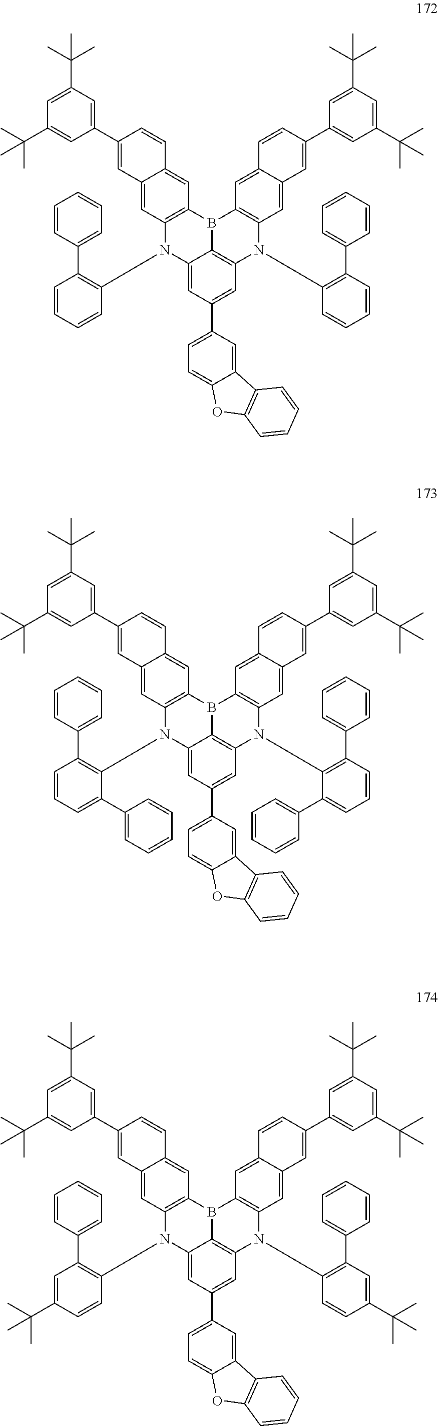

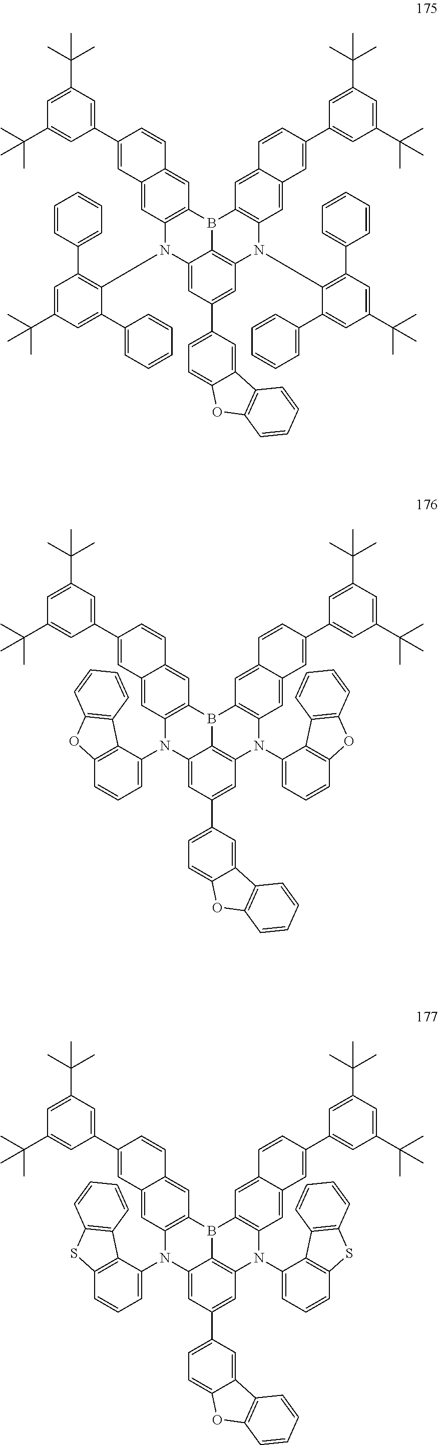

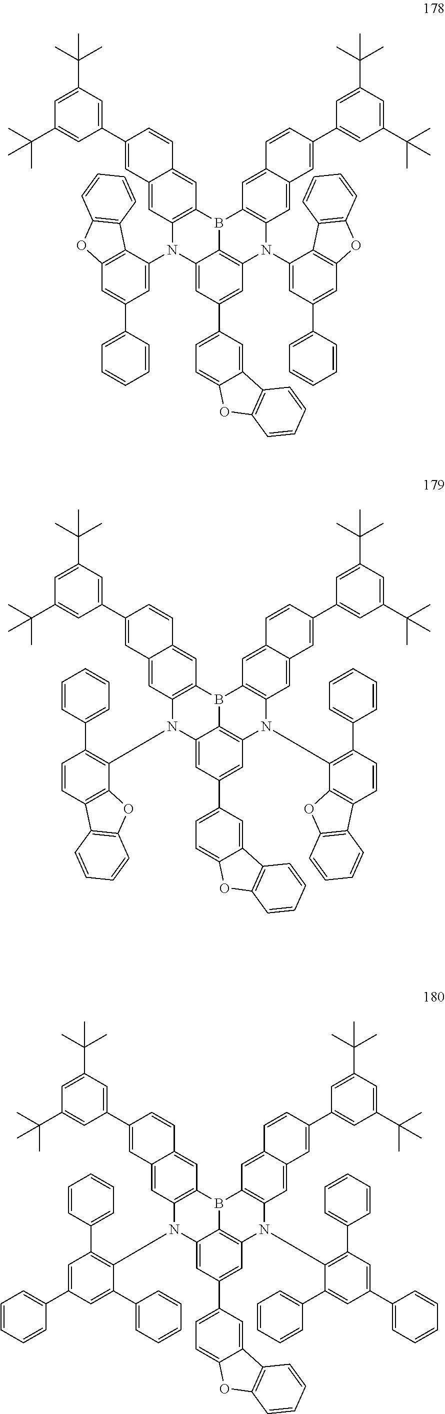

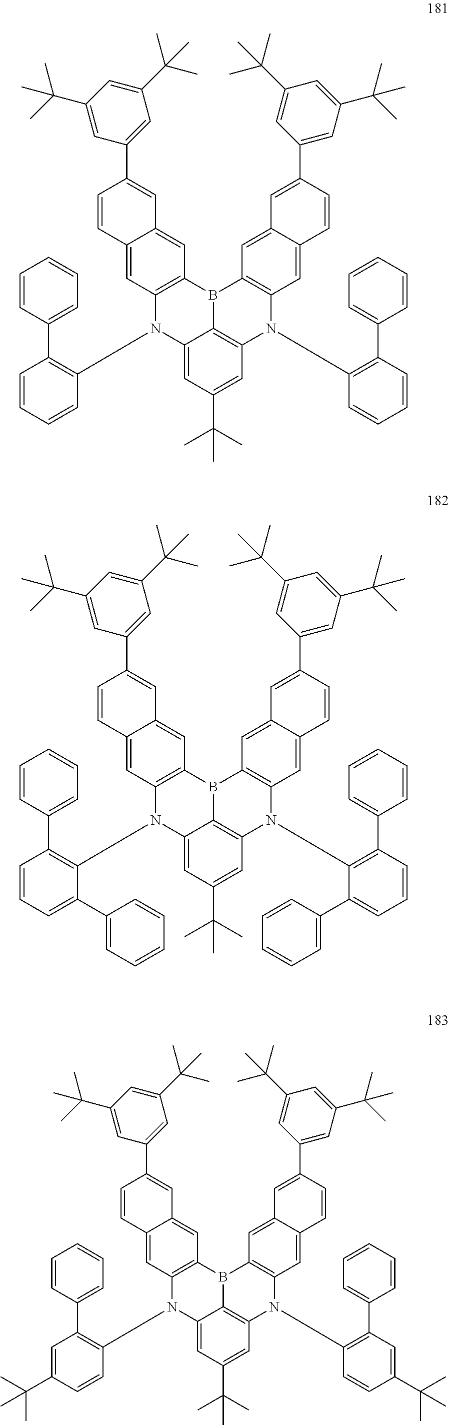

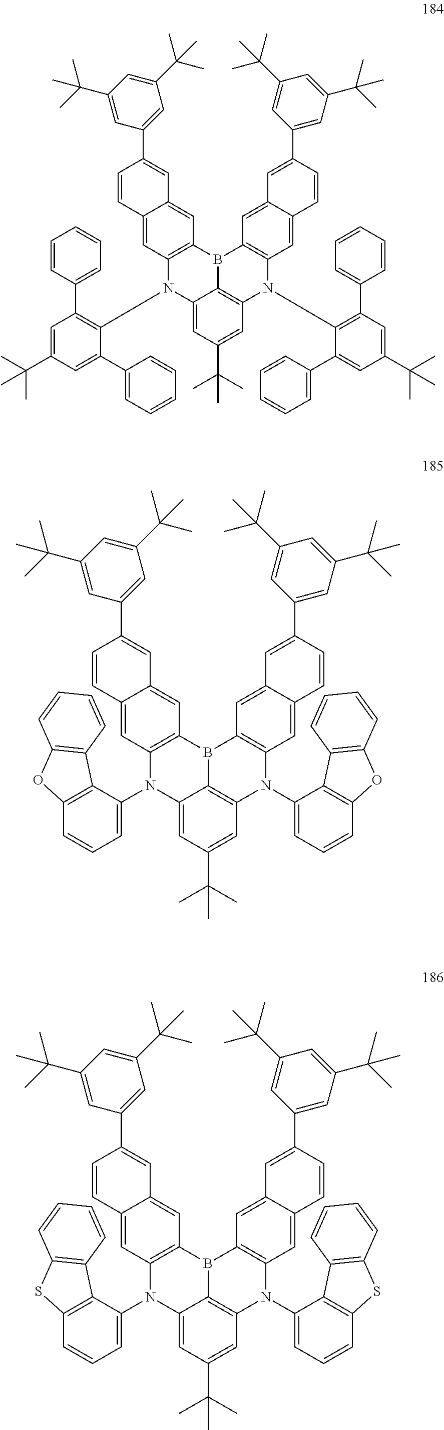

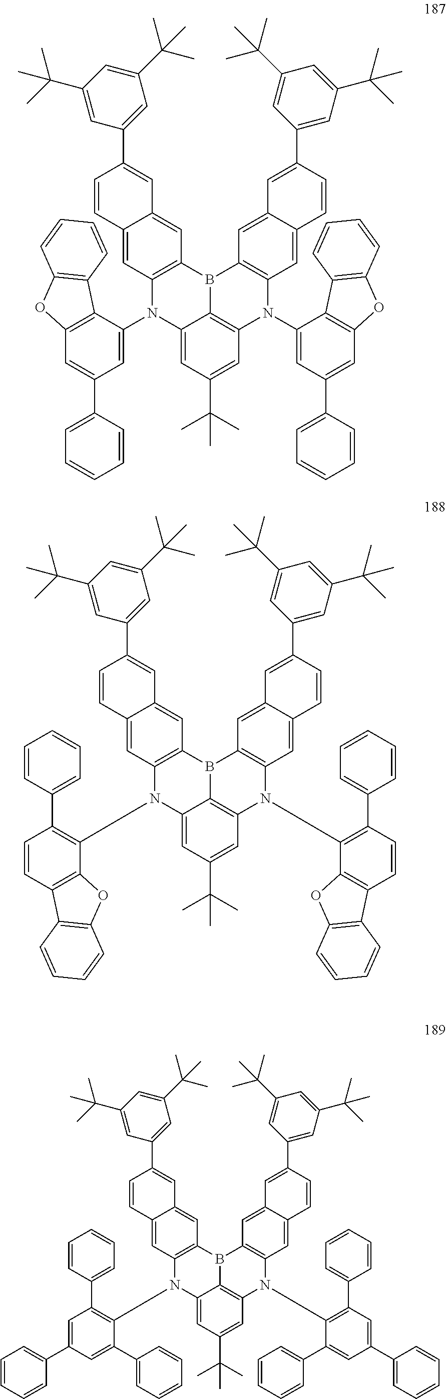

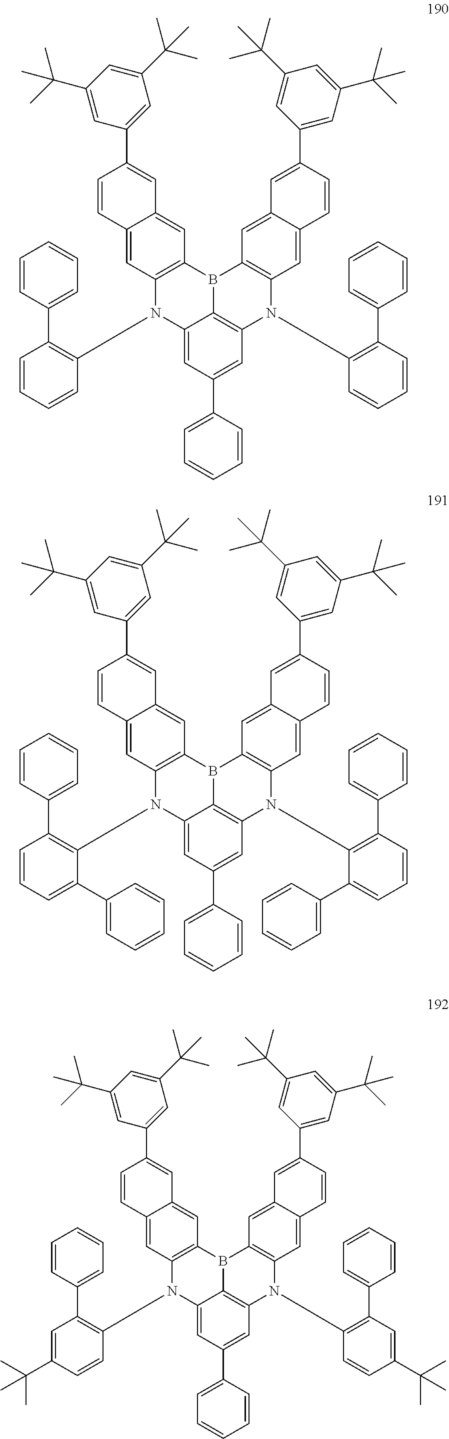

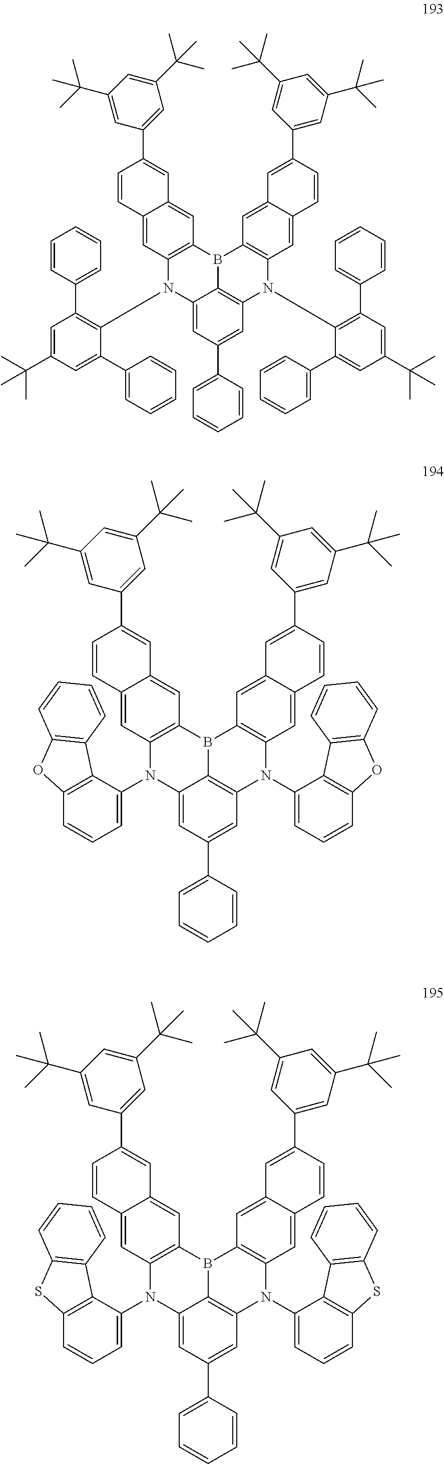

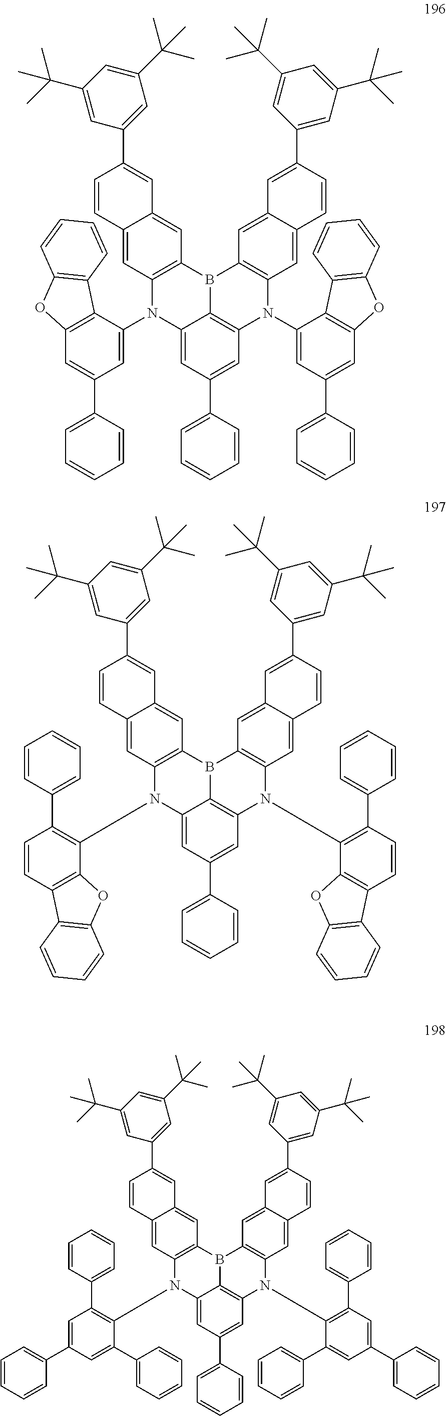

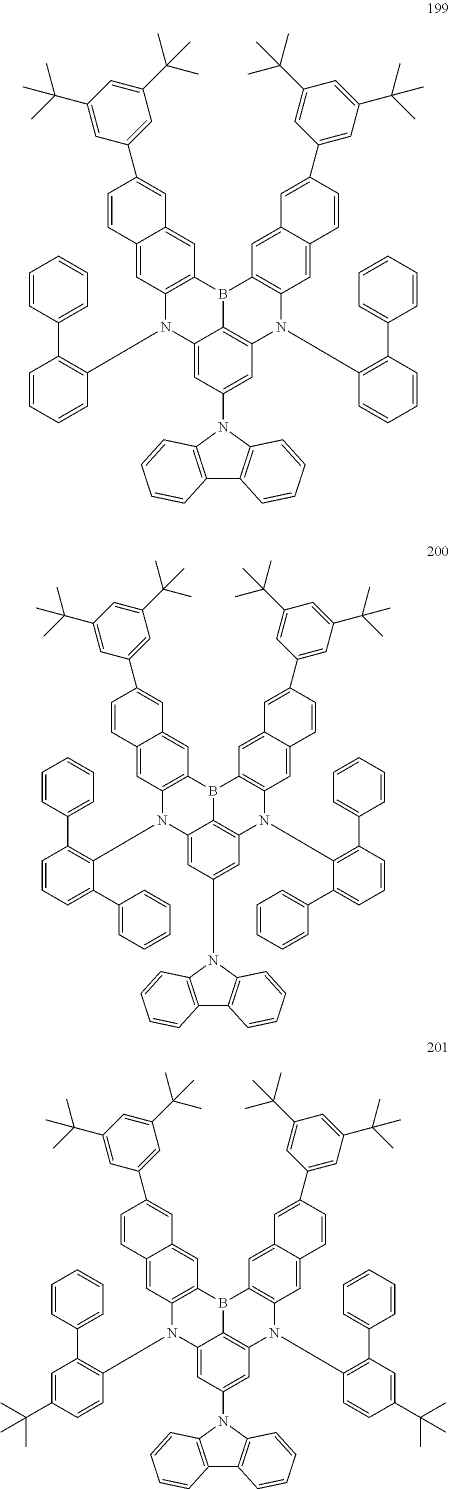

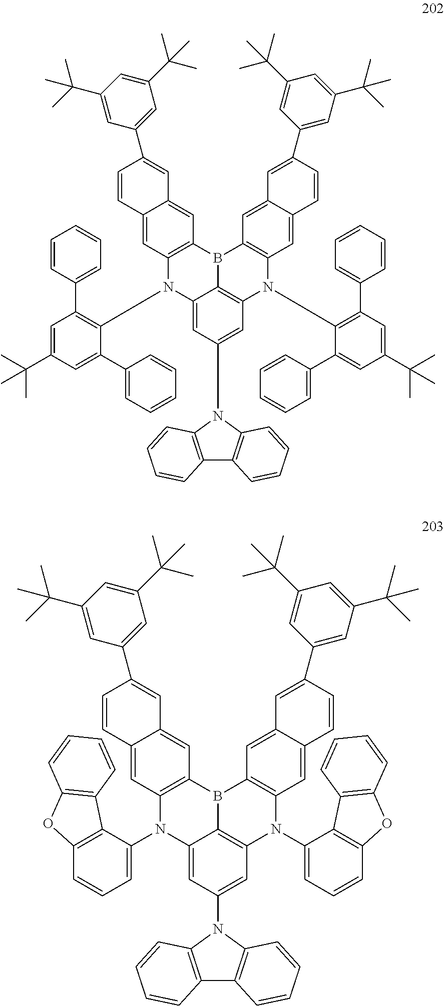

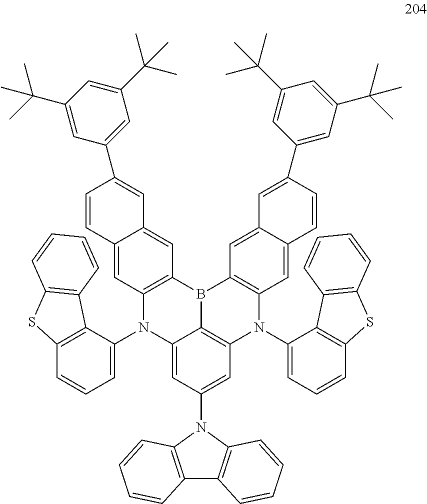 [SMILES: CC(C)(C)c1cc(-c2ccc3cc4c(cc3c2)B2c3cc5cc(-c6cc(C(C)(C)C)cc(C(C)(C)C)c6)ccc5cc3N(c3cccc5sc6ccccc6c35)c3cc(-n5c6ccccc6c6ccccc65)cc(c32)N4c2cccc3sc4ccccc4c23)cc(C(C)(C)C)c1]

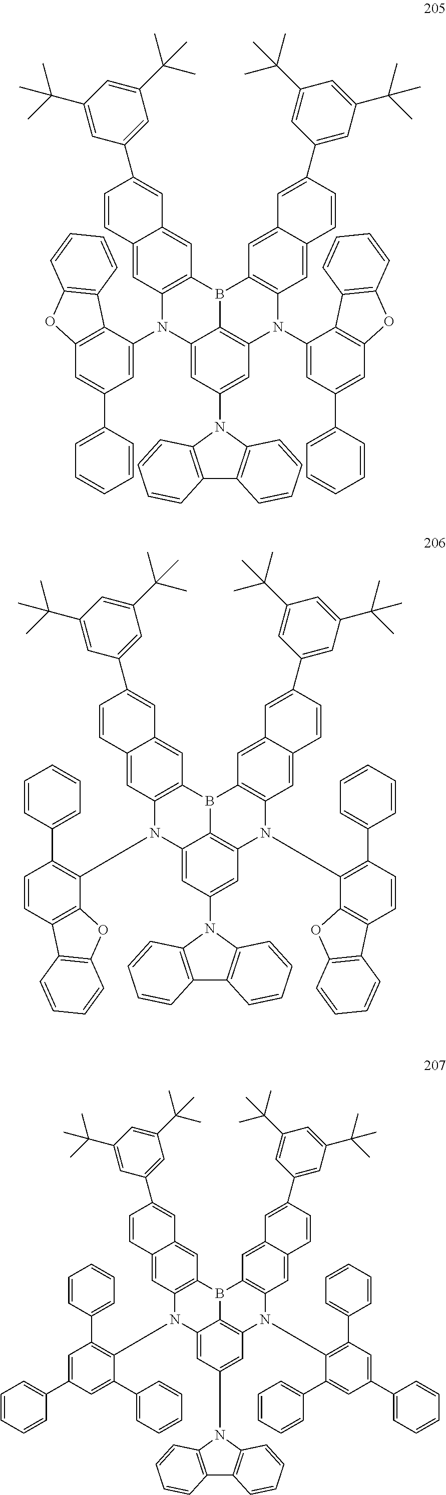

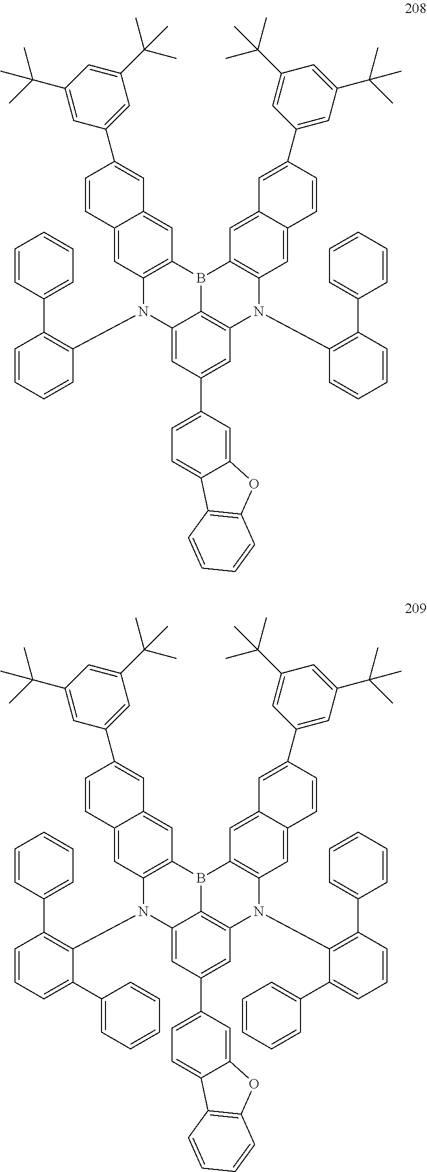

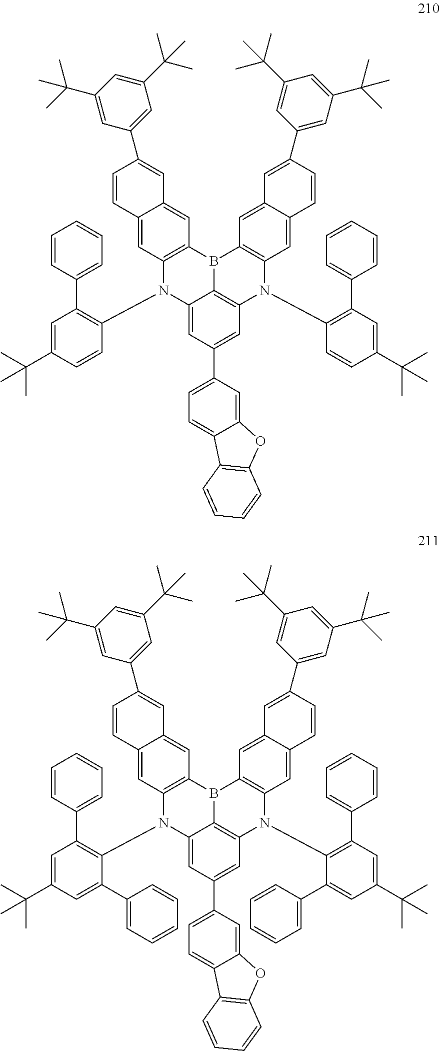

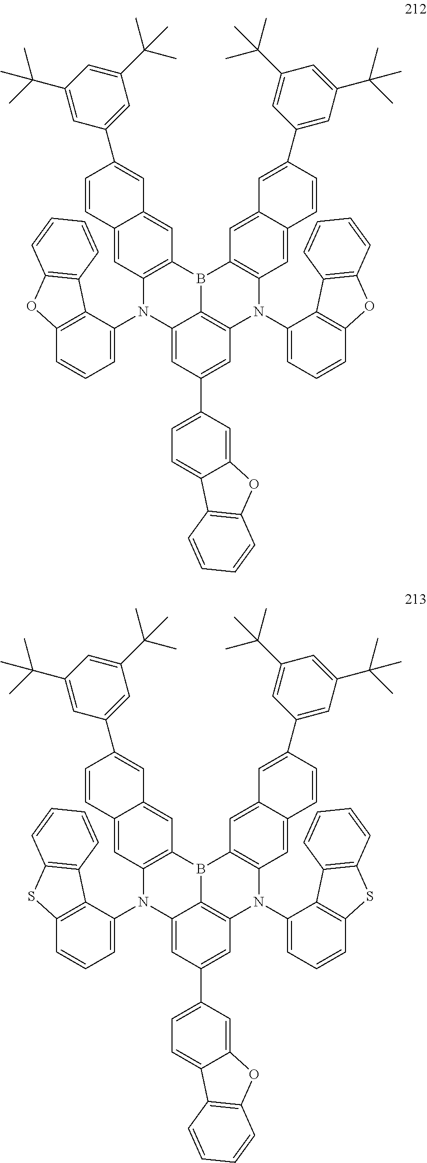

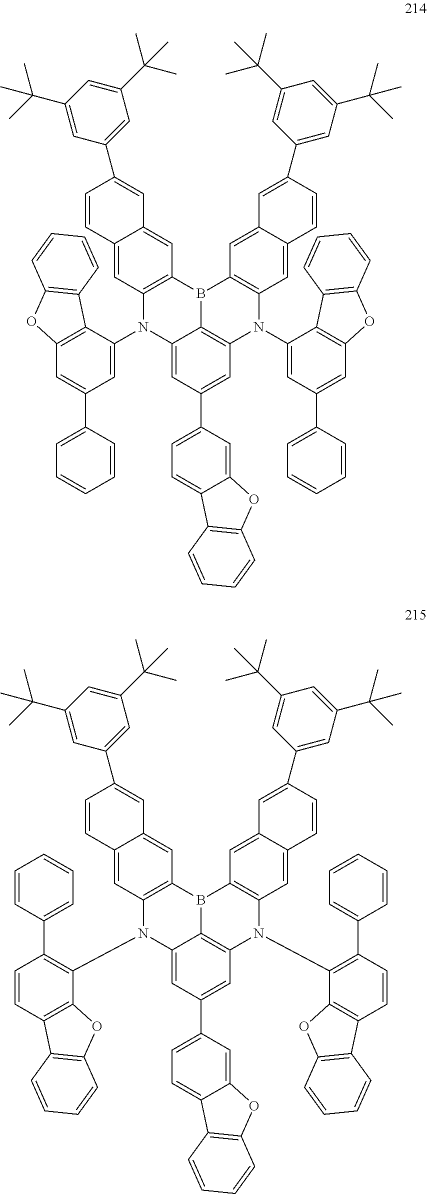

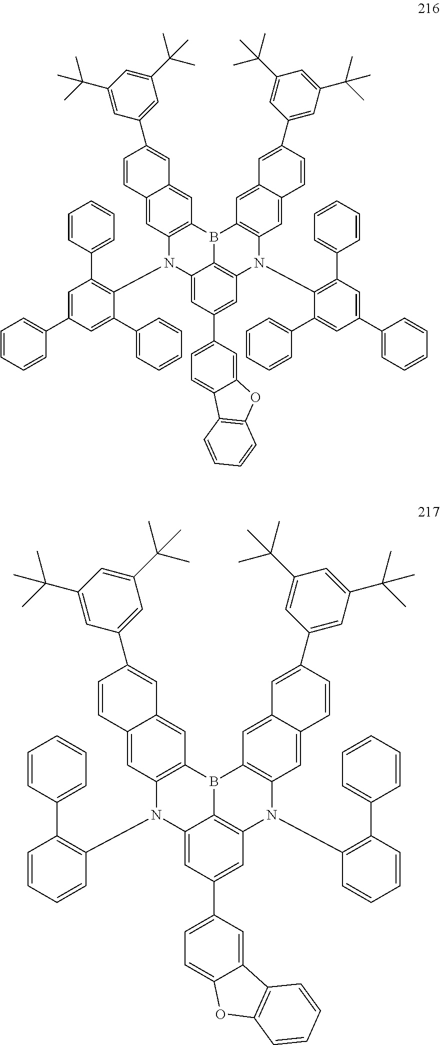 [SMILES: CC(C)(C)c1cc(-c2ccc3cc4c(cc3c2)B2c3cc5cc(-c6cc(C(C)(C)C)cc(C(C)(C)C)c6)ccc5cc3N(c3c(-c5ccccc5)cc(-c5ccccc5)cc3-c3ccccc3)c3cc(-c5ccc6c(c5)oc5ccccc56)cc(c32)N4c2c(-c3ccccc3)cc(-c3ccccc3)cc2-c2ccccc2)cc(C(C)(C)C)c1 ; CC(C)(C)c1cc(-c2ccc3cc4c(cc3c2)B2c3cc5cc(-c6cc(C(C)(C)C)cc(C(C)(C)C)c6)ccc5cc3N(c3ccccc3-c3ccccc3)c3cc(-c5ccc6oc7ccccc7c6c5)cc(c32)N4c2ccccc2-c2ccccc2)cc(C(C)(C)C)c1]

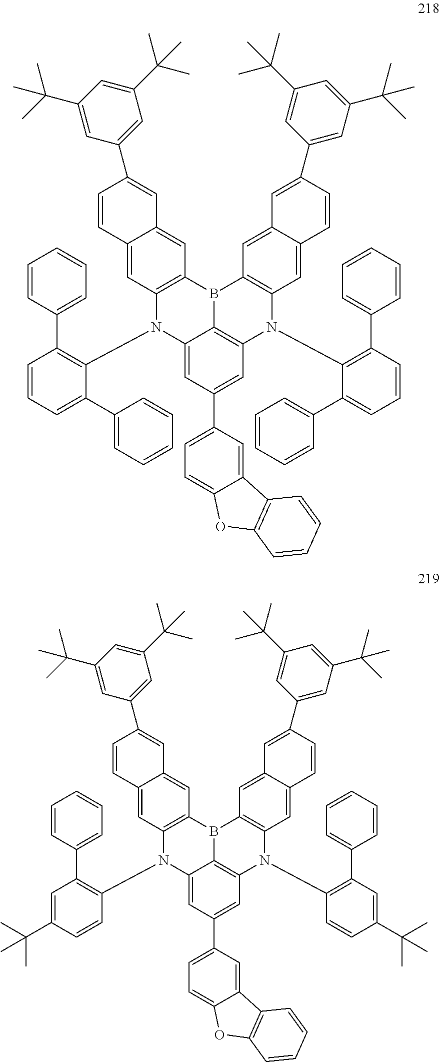

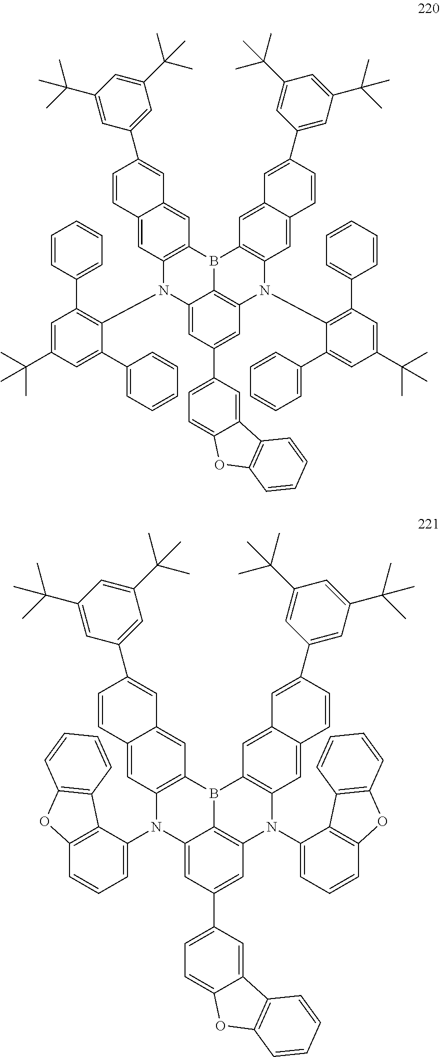

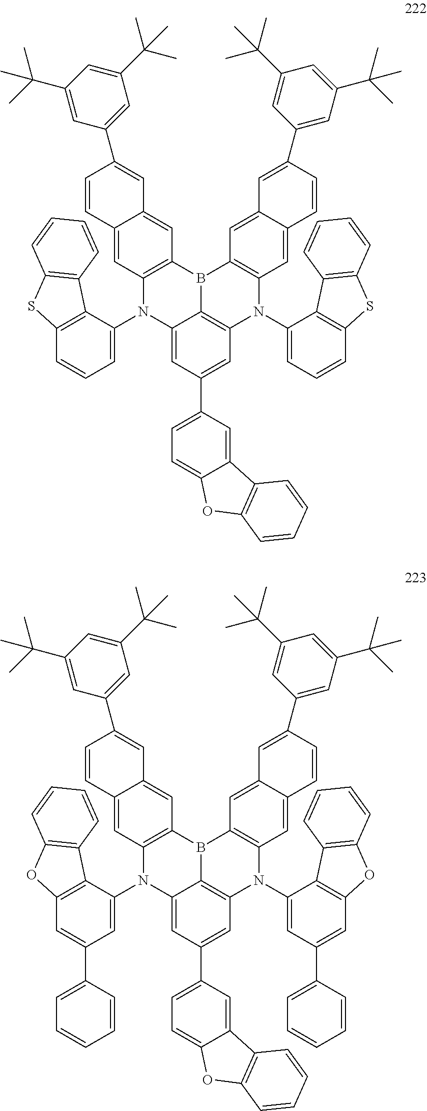

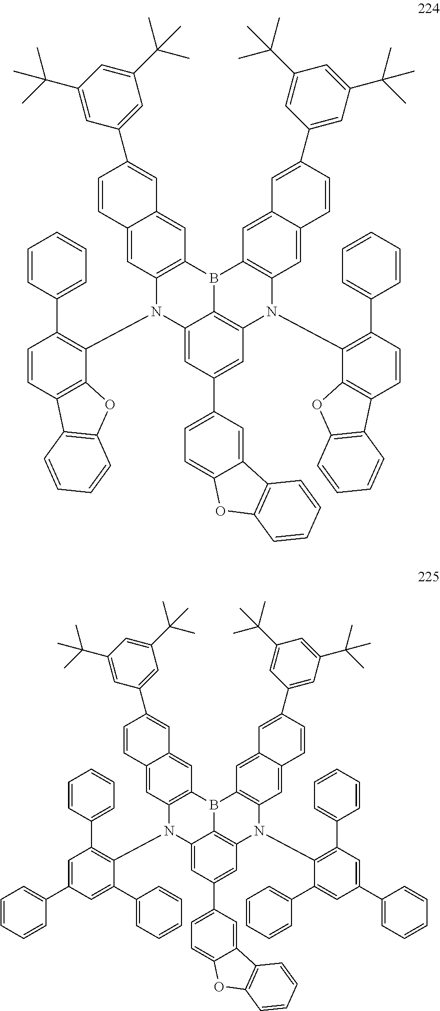 [SMILES: CC(C)(C)c1cc(-c2ccc3cc4c(cc3c2)B2c3cc5cc(-c6cc(C(C)(C)C)cc(C(C)(C)C)c6)ccc5cc3N(c3c(-c5ccccc5)ccc5c3oc3ccccc35)c3cc(-c5ccc6oc7ccccc7c6c5)cc(c32)N4c2c(-c3ccccc3)ccc3c2oc2ccccc23)cc(C(C)(C)C)c1 ; CC(C)(C)c1cc(-c2ccc3cc4c(cc3c2)B2c3cc5cc(-c6cc(C(C)(C)C)cc(C(C)(C)C)c6)ccc5cc3N(c3c(-c5ccccc5)cc(-c5ccccc5)cc3-c3ccccc3)c3cc(-c5ccc6oc7ccccc7c6c5)cc(c32)N4c2c(-c3ccccc3)cc(-c3ccccc3)cc2-c2ccccc2)cc(C(C)(C)C)c1]

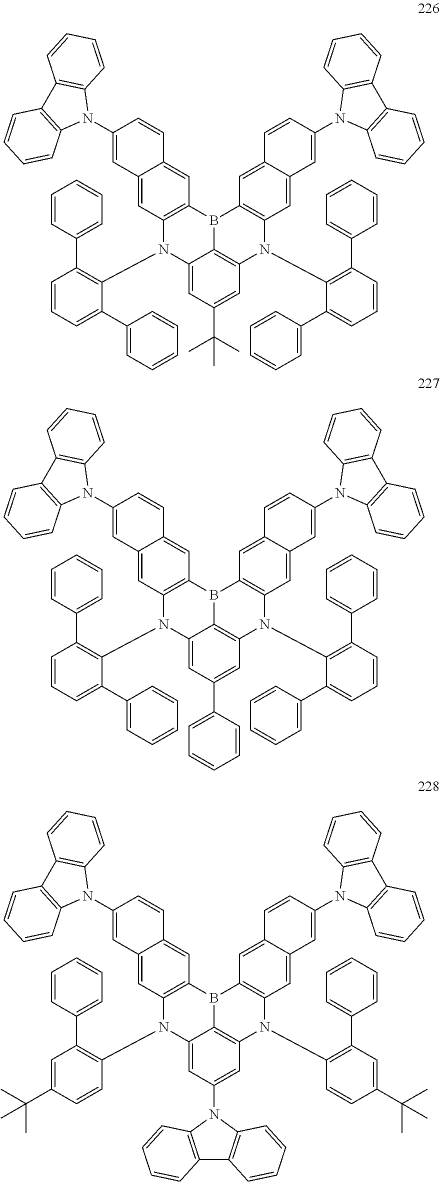 [SMILES: CC(C)(C)c1cc2c3c(c1)N(c1c(-c4ccccc4)cccc1-c1ccccc1)c1cc4cc(-n5c6ccccc6c6ccccc65)ccc4cc1B3c1cc3ccc(-n4c5ccccc5c5ccccc54)cc3cc1N2c1c(-c2ccccc2)cccc1-c1ccccc1 ; c1ccc(-c2cc3c4c(c2)N(c2c(-c5ccccc5)cccc2-c2ccccc2)c2cc5cc(-n6c7ccccc7c7ccccc76)ccc5cc2B4c2cc4ccc(-n5c6ccccc6c6ccccc65)cc4cc2N3c2c(-c3ccccc3)cccc2-c2ccccc2)cc1 ; CC(C)(C)c1ccc(N2c3cc4cc(-n5c6ccccc6c6ccccc65)ccc4cc3B3c4cc5ccc(-n6c7ccccc7c7ccccc76)cc5cc4N(c4ccc(C(C)(C)C)cc4-c4ccccc4)c4cc(-n5c6ccccc6c6ccccc65)cc2c43)c(-c2ccccc2)c1]

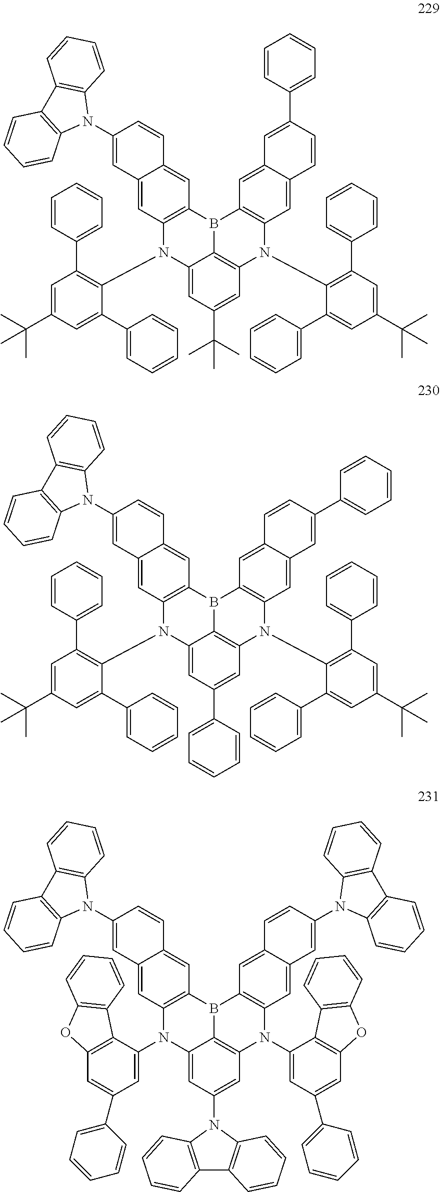

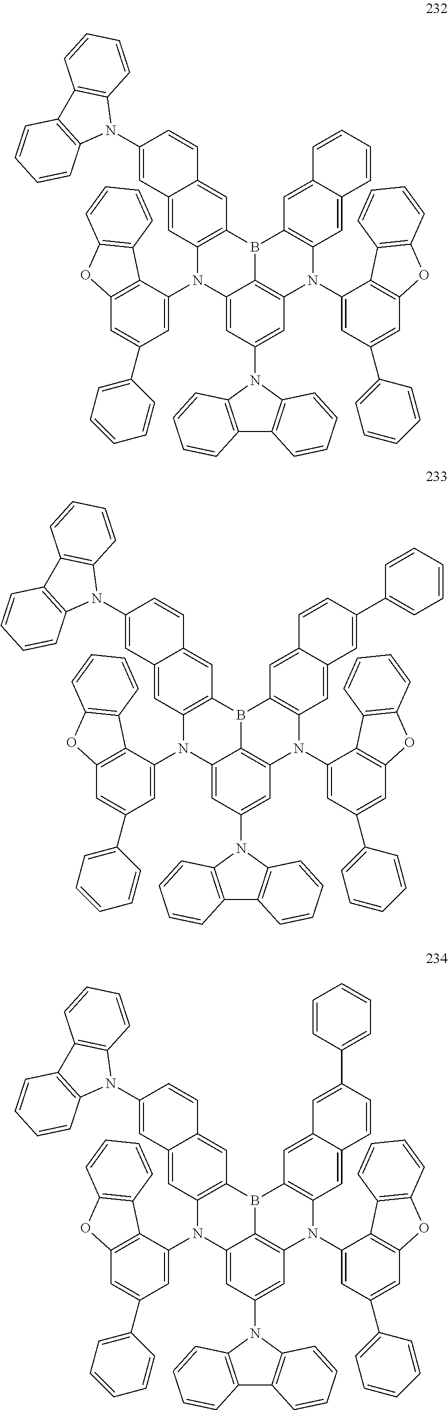 [SMILES: c1ccc(-c2cc(N3c4cc5ccccc5cc4B4c5cc6ccc(-n7c8ccccc8c8ccccc87)cc6cc5N(c5cc(-c6ccccc6)cc6oc7ccccc7c56)c5cc(-n6c7ccccc7c7ccccc76)cc3c54)c3c(c2)oc2ccccc23)cc1 ; c1ccc(-c2ccc3cc4c(cc3c2)N(c2cc(-c3ccccc3)cc3oc5ccccc5c23)c2cc(-n3c5ccccc5c5ccccc53)cc3c2B4c2cc4ccc(-n5c6ccccc6c6ccccc65)cc4cc2N3c2cc(-c3ccccc3)cc3oc4ccccc4c23)cc1 ; c1ccc(-c2ccc3cc4c(cc3c2)B2c3cc5ccc(-n6c7ccccc7c7ccccc76)cc5cc3N(c3cc(-c5ccccc5)cc5oc6ccccc6c35)c3cc(-n5c6ccccc6c6ccccc65)cc(c32)N4c2cc(-c3ccccc3)cc3oc4ccccc4c23)cc1]

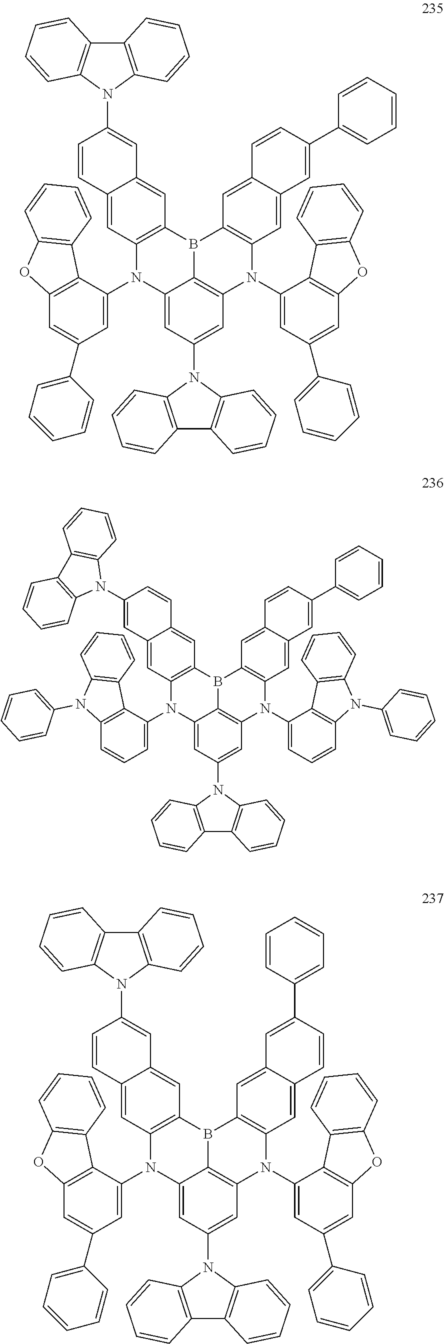 [SMILES: c1ccc(-c2ccc3cc4c(cc3c2)N(c2cc(-c3ccccc3)cc3oc5ccccc5c23)c2cc(-n3c5ccccc5c5ccccc53)cc3c2B4c2cc4cc(-n5c6ccccc6c6ccccc65)ccc4cc2N3c2cc(-c3ccccc3)cc3oc4ccccc4c23)cc1 ; c1ccc(-c2ccc3cc4c(cc3c2)N(c2cccc3c2c2ccccc2n3-c2ccccc2)c2cc(-n3c5ccccc5c5ccccc53)cc3c2B4c2cc4ccc(-n5c6ccccc6c6ccccc65)cc4cc2N3c2cccc3c2c2ccccc2n3-c2ccccc2)cc1 ; c1ccc(-c2ccc3cc4c(cc3c2)B2c3cc5cc(-n6c7ccccc7c7ccccc76)ccc5cc3N(c3cc(-c5ccccc5)cc5oc6ccccc6c35)c3cc(-n5c6ccccc6c6ccccc65)cc(c32)N4c2cc(-c3ccccc3)cc3oc4ccccc4c23)cc1]

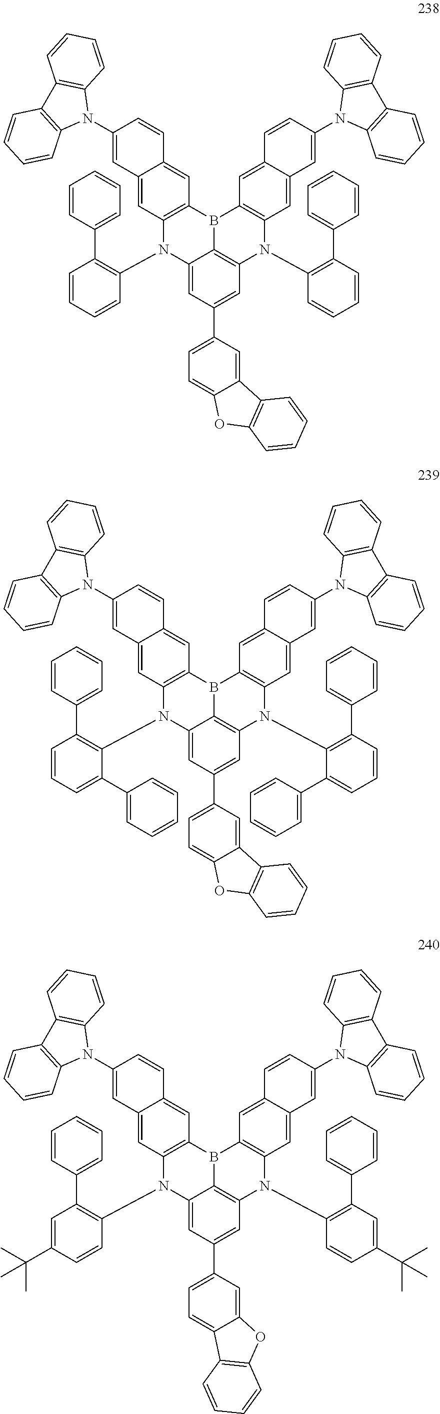 [SMILES: c1ccc(-c2ccccc2N2c3cc4cc(-n5c6ccccc6c6ccccc65)ccc4cc3B3c4cc5ccc(-n6c7ccccc7c7ccccc76)cc5cc4N(c4ccccc4-c4ccccc4)c4cc(-c5ccc6oc7ccccc7c6c5)cc2c43)cc1 ; c1ccc(-c2cccc(-c3ccccc3)c2N2c3cc4cc(-n5c6ccccc6c6ccccc65)ccc4cc3B3c4cc5ccc(-n6c7ccccc7c7ccccc76)cc5cc4N(c4c(-c5ccccc5)cccc4-c4ccccc4)c4cc(-c5ccc6oc7ccccc7c6c5)cc2c43)cc1 ; CC(C)(C)c1ccc(N2c3cc4cc(-n5c6ccccc6c6ccccc65)ccc4cc3B3c4cc5ccc(-n6c7ccccc7c7ccccc76)cc5cc4N(c4ccc(C(C)(C)C)cc4-c4ccccc4)c4cc(-c5ccc6c(c5)oc5ccccc56)cc2c43)c(-c2ccccc2)c1]

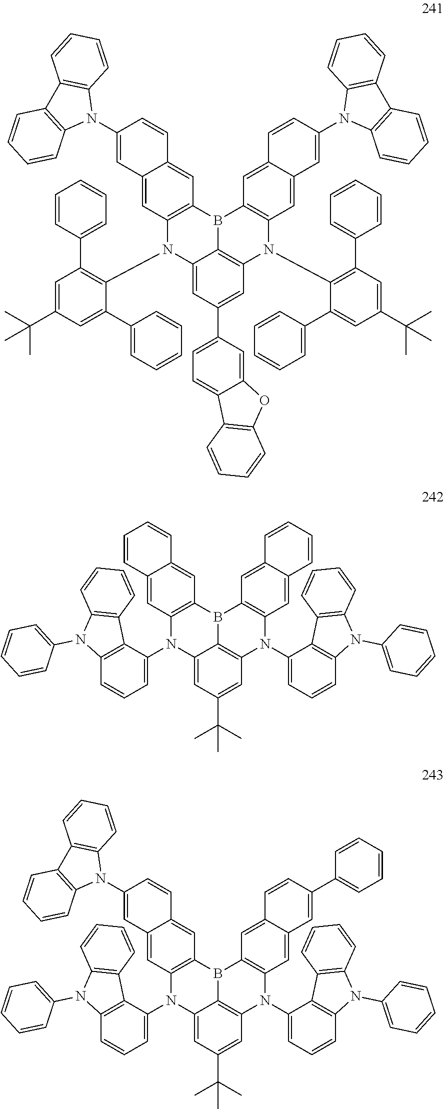 [SMILES: CC(C)(C)c1cc(-c2ccccc2)c(N2c3cc4cc(-n5c6ccccc6c6ccccc65)ccc4cc3B3c4cc5ccc(-n6c7ccccc7c7ccccc76)cc5cc4N(c4c(-c5ccccc5)cc(C(C)(C)C)cc4-c4ccccc4)c4cc(-c5ccc6c(c5)oc5ccccc56)cc2c43)c(-c2ccccc2)c1 ; CC(C)(C)c1cc2c3c(c1)N(c1cccc4c1c1ccccc1n4-c1ccccc1)c1cc4ccccc4cc1B3c1cc3ccccc3cc1N2c1cccc2c1c1ccccc1n2-c1ccccc1 ; CC(C)(C)c1cc2c3c(c1)N(c1cccc4c1c1ccccc1n4-c1ccccc1)c1cc4cc(-n5c6ccccc6c6ccccc65)ccc4cc1B3c1cc3ccc(-c4ccccc4)cc3cc1N2c1cccc2c1c1ccccc1n2-c1ccccc1]

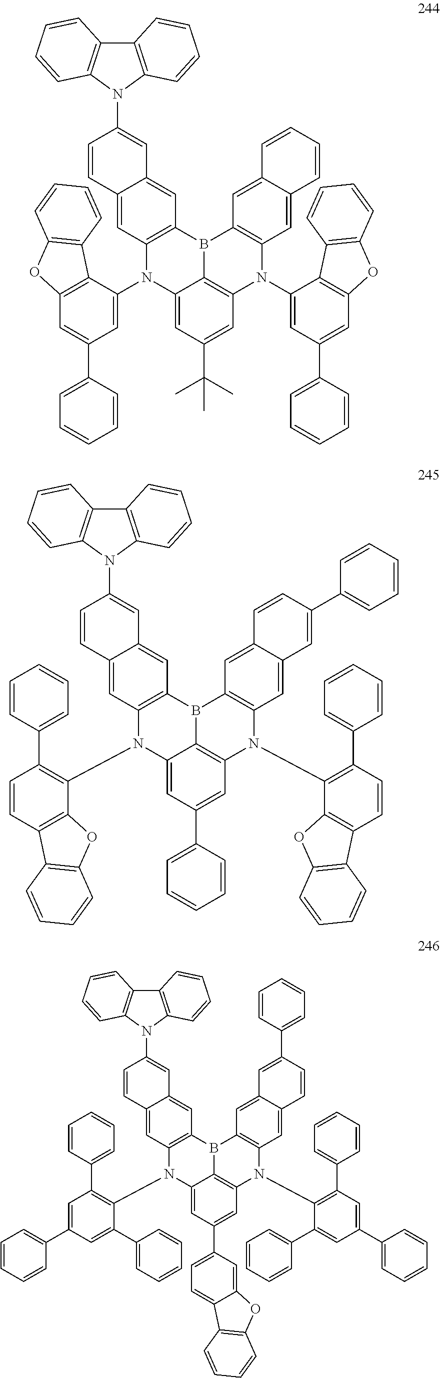

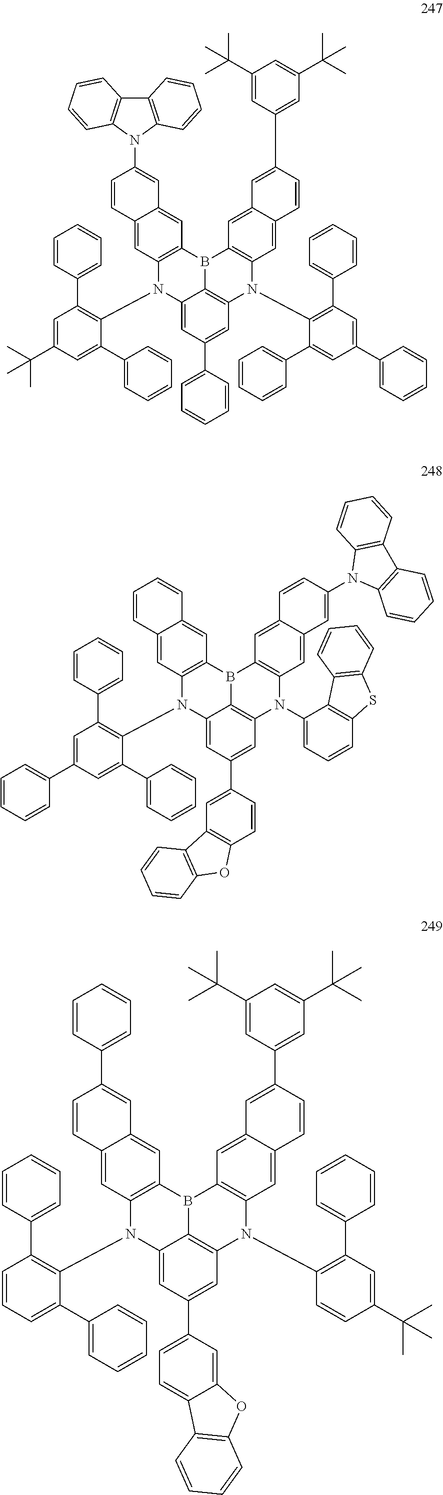

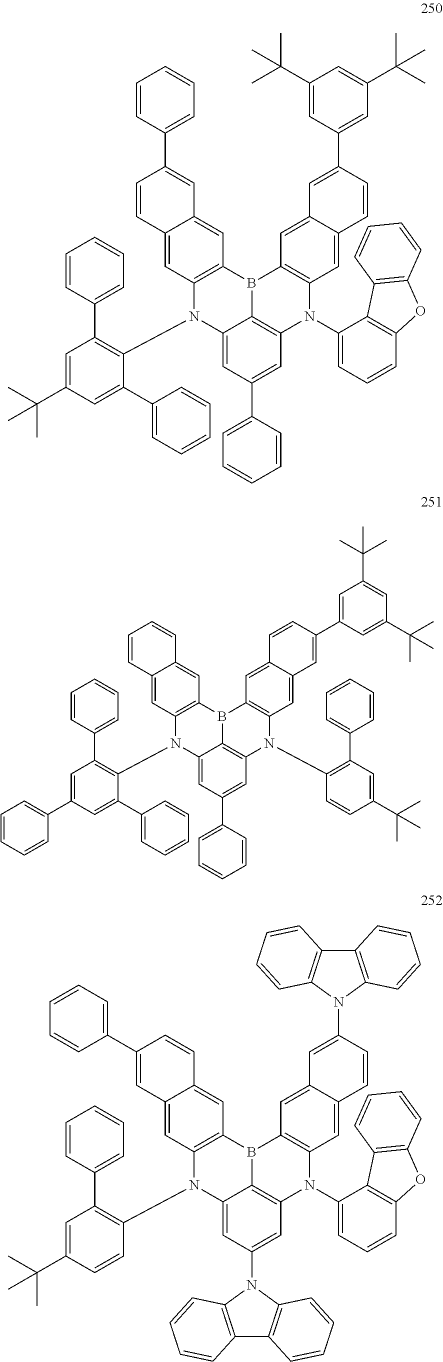

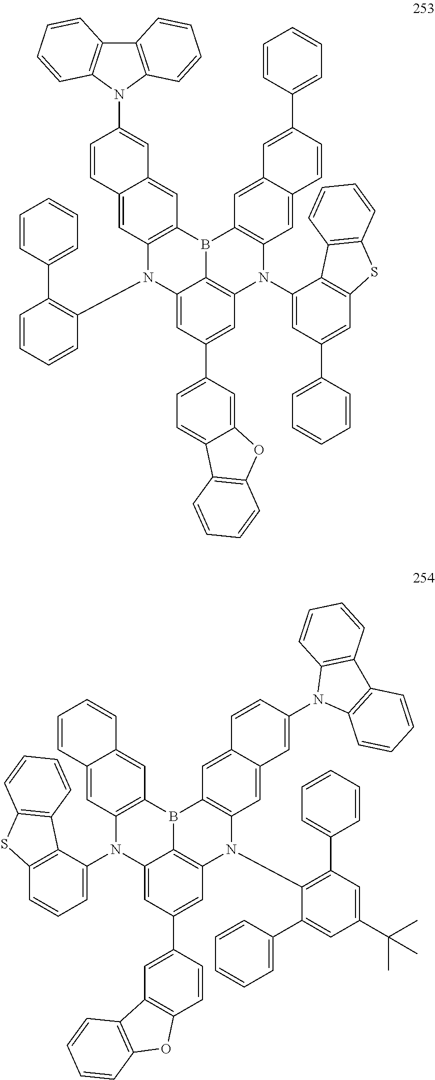 [SMILES: c1ccc(-c2ccc3cc4c(cc3c2)B2c3cc5cc(-n6c7ccccc7c7ccccc76)ccc5cc3N(c3ccccc3-c3ccccc3)c3cc(-c5ccc6c(c5)oc5ccccc56)cc(c32)N4c2cc(-c3ccccc3)cc3sc4ccccc4c23)cc1 ; CC(C)(C)c1cc(-c2ccccc2)c(N2c3cc4cc(-n5c6ccccc6c6ccccc65)ccc4cc3B3c4cc5ccccc5cc4N(c4cccc5sc6ccccc6c45)c4cc(-c5ccc6oc7ccccc7c6c5)cc2c43)c(-c2ccccc2)c1]

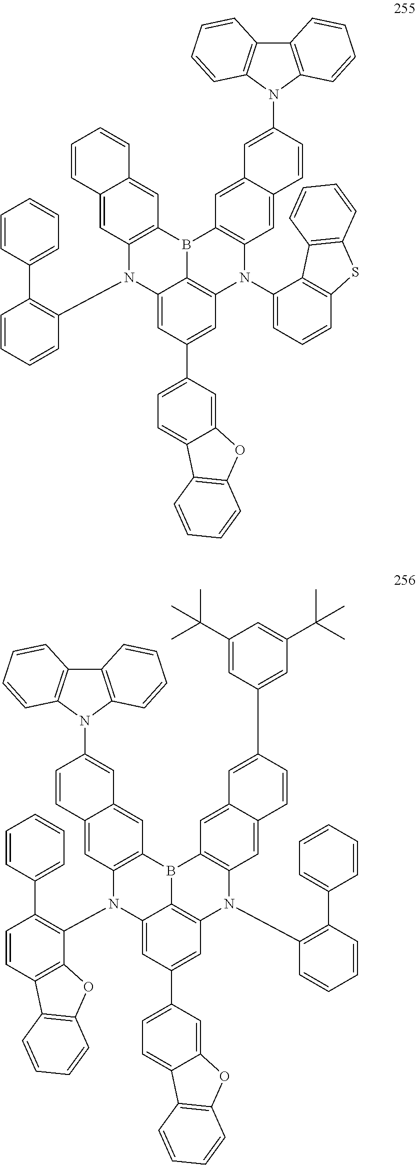 [SMILES: c1ccc(-c2ccccc2N2c3cc4ccccc4cc3B3c4cc5cc(-n6c7ccccc7c7ccccc76)ccc5cc4N(c4cccc5sc6ccccc6c45)c4cc(-c5ccc6c(c5)oc5ccccc56)cc2c43)cc1 ; CC(C)(C)c1cc(-c2ccc3cc4c(cc3c2)B2c3cc5cc(-n6c7ccccc7c7ccccc76)ccc5cc3N(c3c(-c5ccccc5)ccc5c3oc3ccccc35)c3cc(-c5ccc6c(c5)oc5ccccc56)cc(c32)N4c2ccccc2-c2ccccc2)cc(C(C)(C)C)c1]

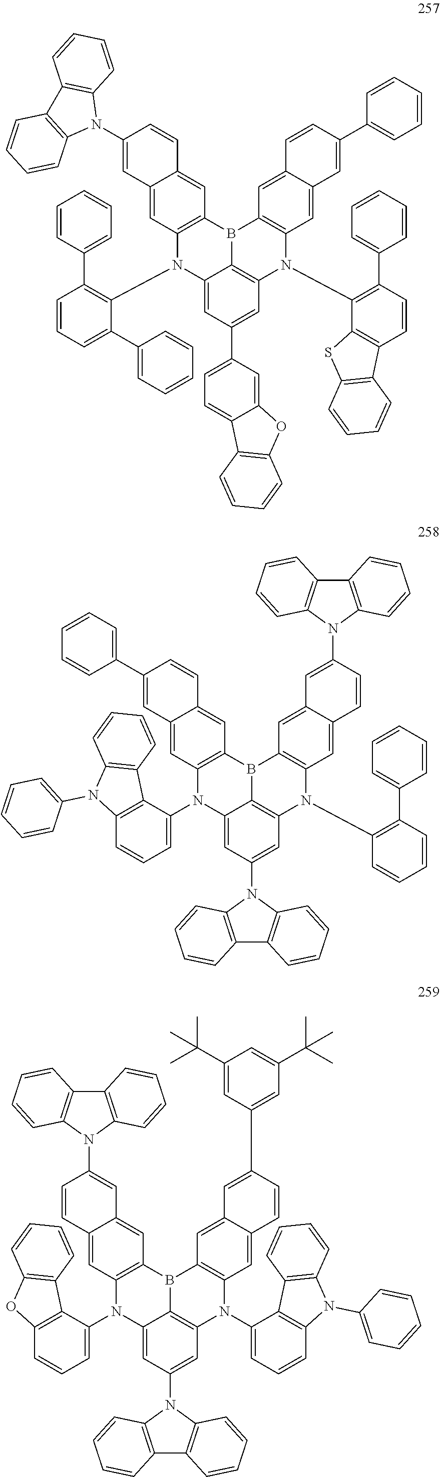 [SMILES: c1ccc(-c2ccc3cc4c(cc3c2)N(c2c(-c3ccccc3)ccc3c2sc2ccccc23)c2cc(-c3ccc5c(c3)oc3ccccc35)cc3c2B4c2cc4ccc(-n5c6ccccc6c6ccccc65)cc4cc2N3c2c(-c3ccccc3)cccc2-c2ccccc2)cc1 ; c1ccc(-c2ccc3cc4c(cc3c2)N(c2cccc3c2c2ccccc2n3-c2ccccc2)c2cc(-n3c5ccccc5c5ccccc53)cc3c2B4c2cc4cc(-n5c6ccccc6c6ccccc65)ccc4cc2N3c2ccccc2-c2ccccc2)cc1 ; CC(C)(C)c1cc(-c2ccc3cc4c(cc3c2)B2c3cc5cc(-n6c7ccccc7c7ccccc76)ccc5cc3N(c3cccc5oc6ccccc6c35)c3cc(-n5c6ccccc6c6ccccc65)cc(c32)N4c2cccc3c2c2ccccc2n3-c2ccccc2)cc(C(C)(C)C)c1]

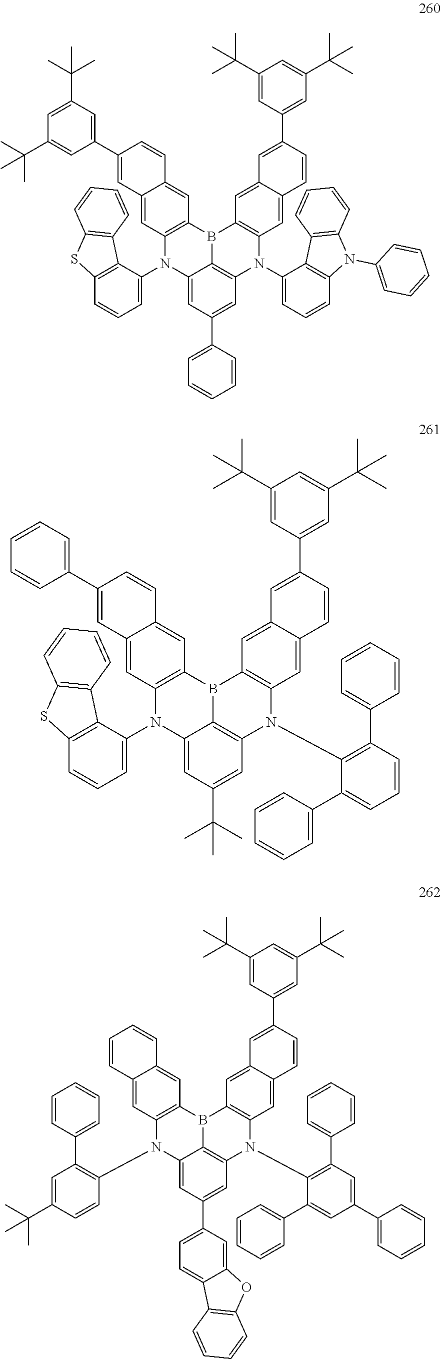 [SMILES: CC(C)(C)c1cc(-c2ccc3cc4c(cc3c2)B2c3cc5ccc(-c6cc(C(C)(C)C)cc(C(C)(C)C)c6)cc5cc3N(c3cccc5sc6ccccc6c35)c3cc(-c5ccccc5)cc(c32)N4c2cccc3c2c2ccccc2n3-c2ccccc2)cc(C(C)(C)C)c1 ; CC(C)(C)c1cc(-c2ccc3cc4c(cc3c2)B2c3cc5ccc(-c6ccccc6)cc5cc3N(c3cccc5sc6ccccc6c35)c3cc(C(C)(C)C)cc(c32)N4c2c(-c3ccccc3)cccc2-c2ccccc2)cc(C(C)(C)C)c1 ; CC(C)(C)c1cc(-c2ccc3cc4c(cc3c2)B2c3cc5ccccc5cc3N(c3ccc(C(C)(C)C)cc3-c3ccccc3)c3cc(-c5ccc6c(c5)oc5ccccc56)cc(c32)N4c2c(-c3ccccc3)cc(-c3ccccc3)cc2-c2ccccc2)cc(C(C)(C)C)c1]

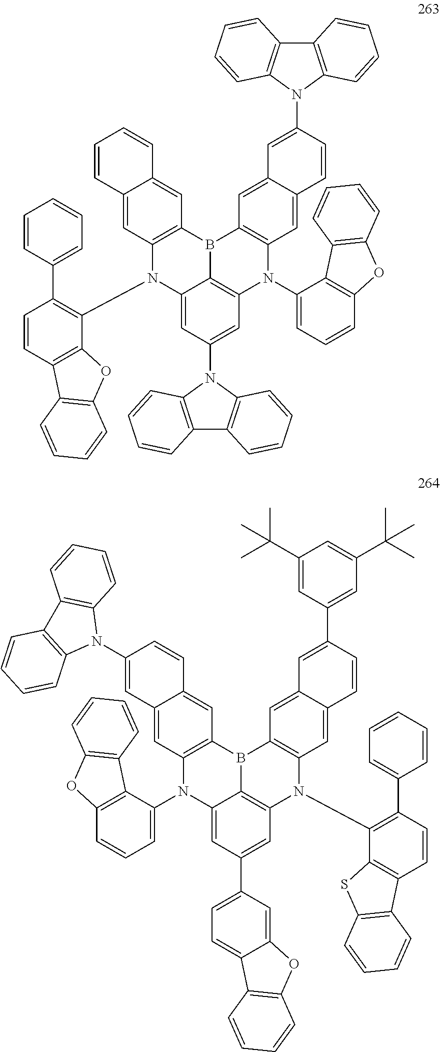 [SMILES: c1ccc(-c2ccc3c(oc4ccccc43)c2N2c3cc4ccccc4cc3B3c4cc5cc(-n6c7ccccc7c7ccccc76)ccc5cc4N(c4cccc5oc6ccccc6c45)c4cc(-n5c6ccccc6c6ccccc65)cc2c43)cc1 ; CC(C)(C)c1cc(-c2ccc3cc4c(cc3c2)B2c3cc5ccc(-n6c7ccccc7c7ccccc76)cc5cc3N(c3cccc5oc6ccccc6c35)c3cc(-c5ccc6c(c5)oc5ccccc56)cc(c32)N4c2c(-c3ccccc3)ccc3c2sc2ccccc23)cc(C(C)(C)C)c1]

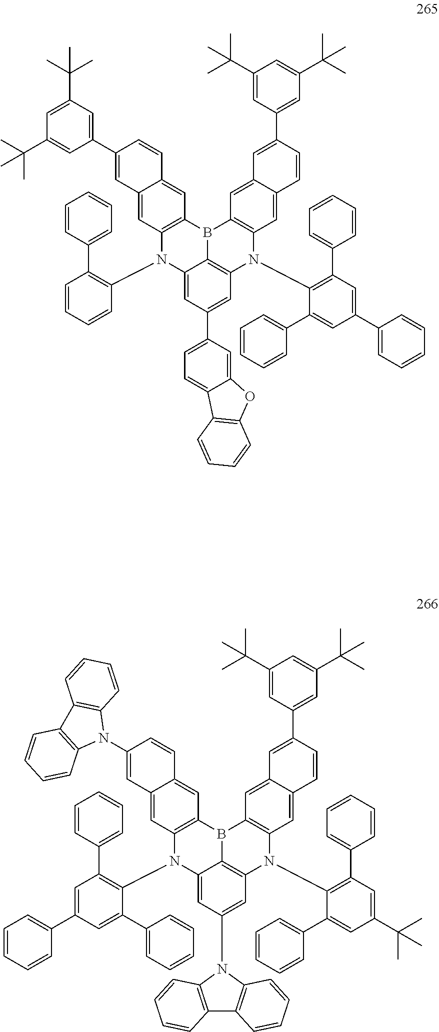 [SMILES: CC(C)(C)c1cc(-c2ccc3cc4c(cc3c2)B2c3cc5ccc(-c6cc(C(C)(C)C)cc(C(C)(C)C)c6)cc5cc3N(c3ccccc3-c3ccccc3)c3cc(-c5ccc6c(c5)oc5ccccc56)cc(c32)N4c2c(-c3ccccc3)cc(-c3ccccc3)cc2-c2ccccc2)cc(C(C)(C)C)c1 ; CC(C)(C)c1cc(-c2ccc3cc4c(cc3c2)B2c3cc5ccc(-n6c7ccccc7c7ccccc76)cc5cc3N(c3c(-c5ccccc5)cc(-c5ccccc5)cc3-c3ccccc3)c3cc(-n5c6ccccc6c6ccccc65)cc(c32)N4c2c(-c3ccccc3)cc(C(C)(C)C)cc2-c2ccccc2)cc(C(C)(C)C)c1]

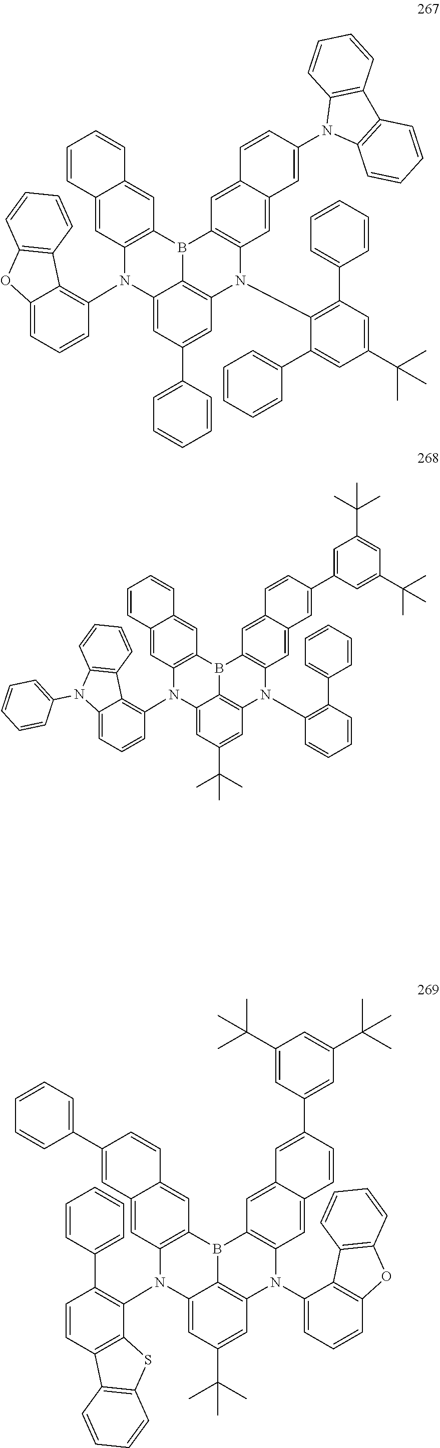 [SMILES: CC(C)(C)c1cc(-c2ccccc2)c(N2c3cc4cc(-n5c6ccccc6c6ccccc65)ccc4cc3B3c4cc5ccccc5cc4N(c4cccc5oc6ccccc6c45)c4cc(-c5ccccc5)cc2c43)c(-c2ccccc2)c1 ; CC(C)(C)c1cc(-c2ccc3cc4c(cc3c2)N(c2ccccc2-c2ccccc2)c2cc(C(C)(C)C)cc3c2B4c2cc4ccccc4cc2N3c2cccc3c2c2ccccc2n3-c2ccccc2)cc(C(C)(C)C)c1 ; CC(C)(C)c1cc(-c2ccc3cc4c(cc3c2)B2c3cc5ccc(-c6ccccc6)cc5cc3N(c3c(-c5ccccc5)ccc5c3sc3ccccc35)c3cc(C(C)(C)C)cc(c32)N4c2cccc3oc4ccccc4c23)cc(C(C)(C)C)c1]

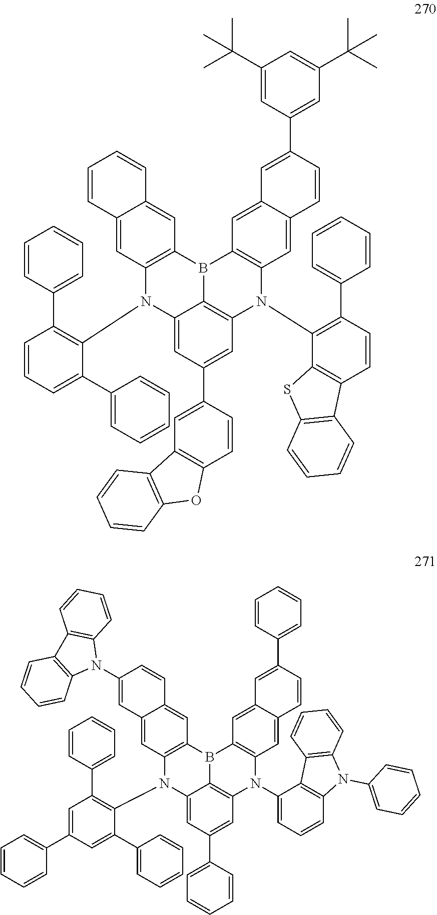 [SMILES: CC(C)(C)c1cc(-c2ccc3cc4c(cc3c2)B2c3cc5ccccc5cc3N(c3c(-c5ccccc5)cccc3-c3ccccc3)c3cc(-c5ccc6oc7ccccc7c6c5)cc(c32)N4c2c(-c3ccccc3)ccc3c2sc2ccccc23)cc(C(C)(C)C)c1 ; c1ccc(-c2cc(-c3ccccc3)c(N3c4cc5cc(-n6c7ccccc7c7ccccc76)ccc5cc4B4c5cc6cc(-c7ccccc7)ccc6cc5N(c5cccc6c5c5ccccc5n6-c5ccccc5)c5cc(-c6ccccc6)cc3c54)c(-c3ccccc3)c2)cc1]

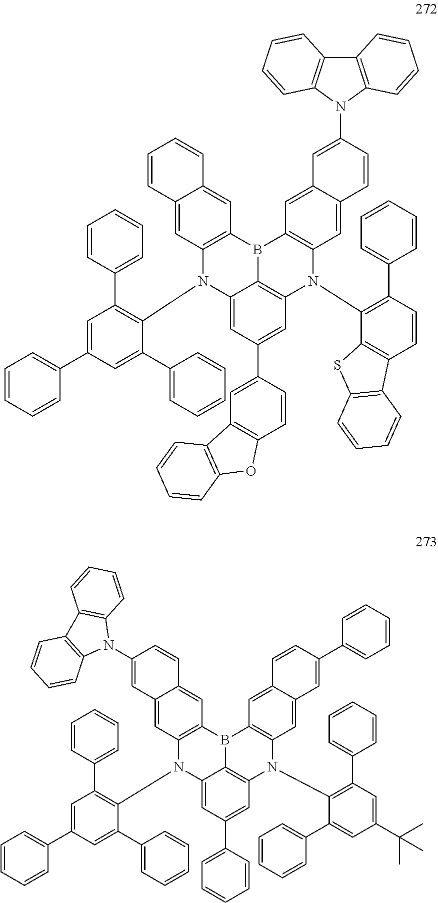 [SMILES: c1ccc(-c2cc(-c3ccccc3)c(N3c4cc5ccccc5cc4B4c5cc6cc(-n7c8ccccc8c8ccccc87)ccc6cc5N(c5c(-c6ccccc6)ccc6c5sc5ccccc56)c5cc(-c6ccc7oc8ccccc8c7c6)cc3c54)c(-c3ccccc3)c2)cc1 ; CC(C)(C)c1cc(-c2ccccc2)c(N2c3cc4cc(-c5ccccc5)ccc4cc3B3c4cc5ccc(-n6c7ccccc7c7ccccc76)cc5cc4N(c4c(-c5ccccc5)cc(-c5ccccc5)cc4-c4ccccc4)c4cc(-c5ccccc5)cc2c43)c(-c2ccccc2)c1]

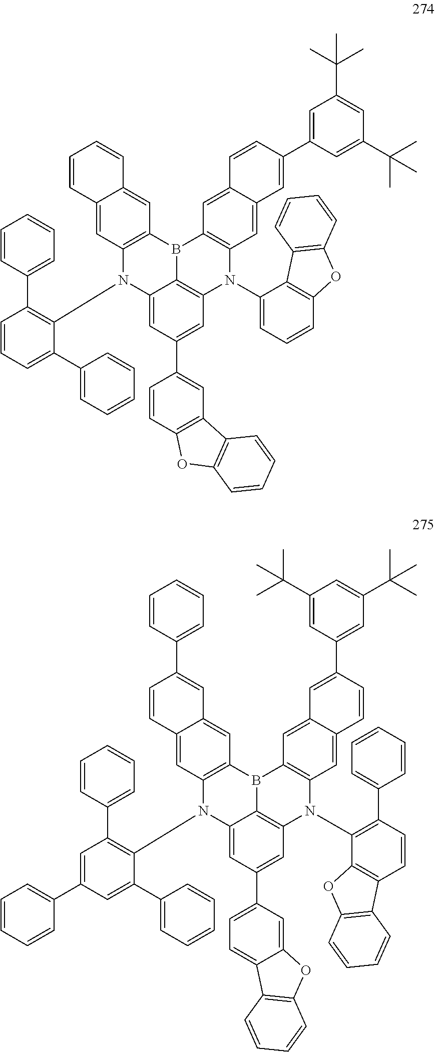 [SMILES: CC(C)(C)c1cc(-c2ccc3cc4c(cc3c2)N(c2cccc3oc5ccccc5c23)c2cc(-c3ccc5oc6ccccc6c5c3)cc3c2B4c2cc4ccccc4cc2N3c2c(-c3ccccc3)cccc2-c2ccccc2)cc(C(C)(C)C)c1 ; CC(C)(C)c1cc(-c2ccc3cc4c(cc3c2)B2c3cc5cc(-c6ccccc6)ccc5cc3N(c3c(-c5ccccc5)cc(-c5ccccc5)cc3-c3ccccc3)c3cc(-c5ccc6c(c5)oc5ccccc56)cc(c32)N4c2c(-c3ccccc3)ccc3c2oc2ccccc23)cc(C(C)(C)C)c1]

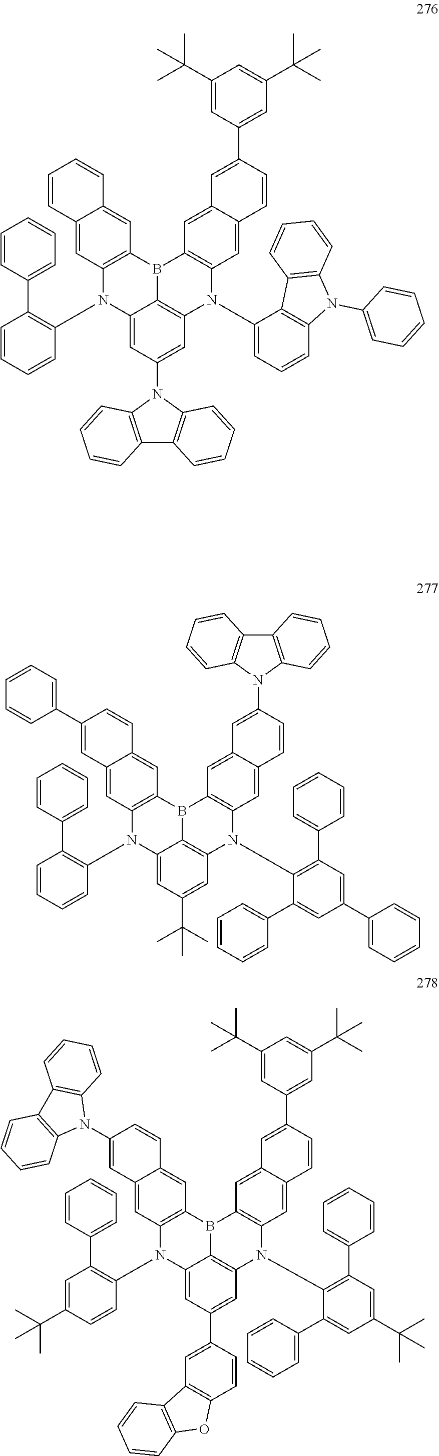 [SMILES: CC(C)(C)c1cc(-c2ccc3cc4c(cc3c2)B2c3cc5ccccc5cc3N(c3ccccc3-c3ccccc3)c3cc(-n5c6ccccc6c6ccccc65)cc(c32)N4c2cccc3c2c2ccccc2n3-c2ccccc2)cc(C(C)(C)C)c1 ; CC(C)(C)c1cc2c3c(c1)N(c1c(-c4ccccc4)cc(-c4ccccc4)cc1-c1ccccc1)c1cc4ccc(-n5c6ccccc6c6ccccc65)cc4cc1B3c1cc3ccc(-c4ccccc4)cc3cc1N2c1ccccc1-c1ccccc1 ; CC(C)(C)c1cc(-c2ccc3cc4c(cc3c2)B2c3cc5ccc(-n6c7ccccc7c7ccccc76)cc5cc3N(c3ccc(C(C)(C)C)cc3-c3ccccc3)c3cc(-c5ccc6oc7ccccc7c6c5)cc(c32)N4c2c(-c3ccccc3)cc(C(C)(C)C)cc2-c2ccccc2)cc(C(C)(C)C)c1]

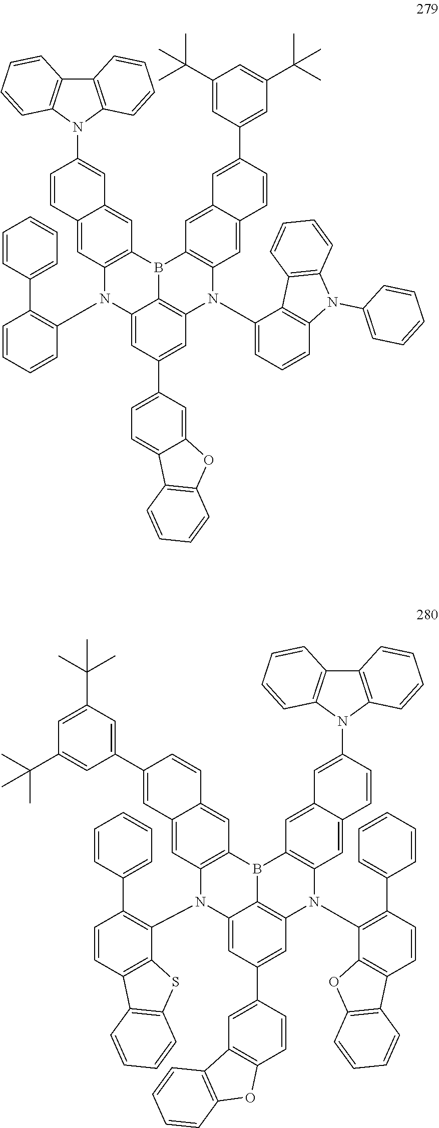 [SMILES: CC(C)(C)c1cc(-c2ccc3cc4c(cc3c2)B2c3cc5cc(-n6c7ccccc7c7ccccc76)ccc5cc3N(c3ccccc3-c3ccccc3)c3cc(-c5ccc6c(c5)oc5ccccc56)cc(c32)N4c2cccc3c2c2ccccc2n3-c2ccccc2)cc(C(C)(C)C)c1 ; CC(C)(C)c1cc(-c2ccc3cc4c(cc3c2)N(c2c(-c3ccccc3)ccc3c2sc2ccccc23)c2cc(-c3ccc5oc6ccccc6c5c3)cc3c2B4c2cc4cc(-n5c6ccccc6c6ccccc65)ccc4cc2N3c2c(-c3ccccc3)ccc3c2oc2ccccc23)cc(C(C)(C)C)c1]

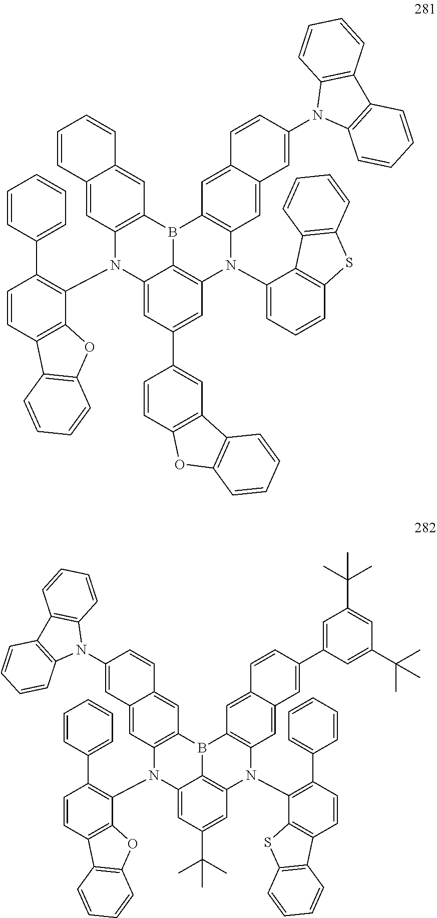 [SMILES: c1ccc(-c2ccc3c(oc4ccccc43)c2N2c3cc4ccccc4cc3B3c4cc5ccc(-n6c7ccccc7c7ccccc76)cc5cc4N(c4cccc5sc6ccccc6c45)c4cc(-c5ccc6oc7ccccc7c6c5)cc2c43)cc1 ; CC(C)(C)c1cc(-c2ccc3cc4c(cc3c2)N(c2c(-c3ccccc3)ccc3c2sc2ccccc23)c2cc(C(C)(C)C)cc3c2B4c2cc4ccc(-n5c6ccccc6c6ccccc65)cc4cc2N3c2c(-c3ccccc3)ccc3c2oc2ccccc23)cc(C(C)(C)C)c1]

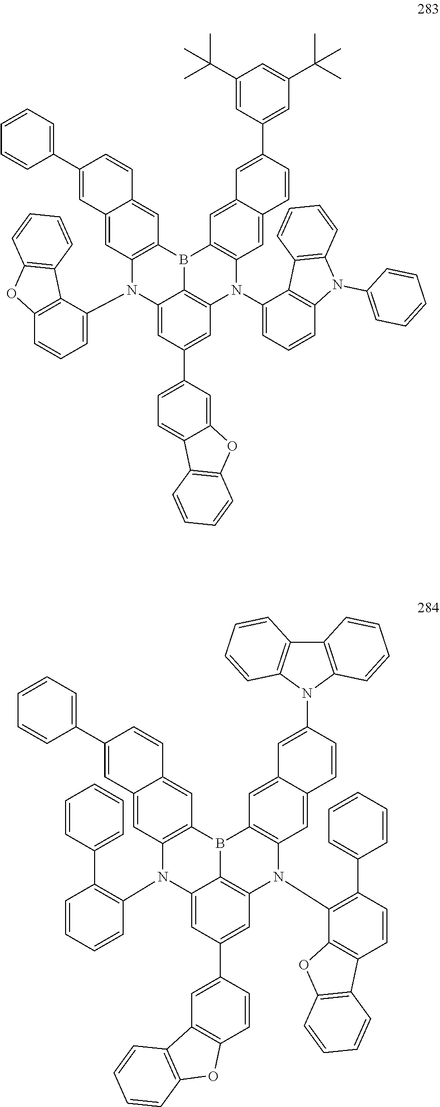 [SMILES: CC(C)(C)c1cc(-c2ccc3cc4c(cc3c2)B2c3cc5ccc(-c6ccccc6)cc5cc3N(c3cccc5oc6ccccc6c35)c3cc(-c5ccc6c(c5)oc5ccccc56)cc(c32)N4c2cccc3c2c2ccccc2n3-c2ccccc2)cc(C(C)(C)C)c1 ; c1ccc(-c2ccc3cc4c(cc3c2)N(c2ccccc2-c2ccccc2)c2cc(-c3ccc5oc6ccccc6c5c3)cc3c2B4c2cc4cc(-n5c6ccccc6c6ccccc65)ccc4cc2N3c2c(-c3ccccc3)ccc3c2oc2ccccc23)cc1]

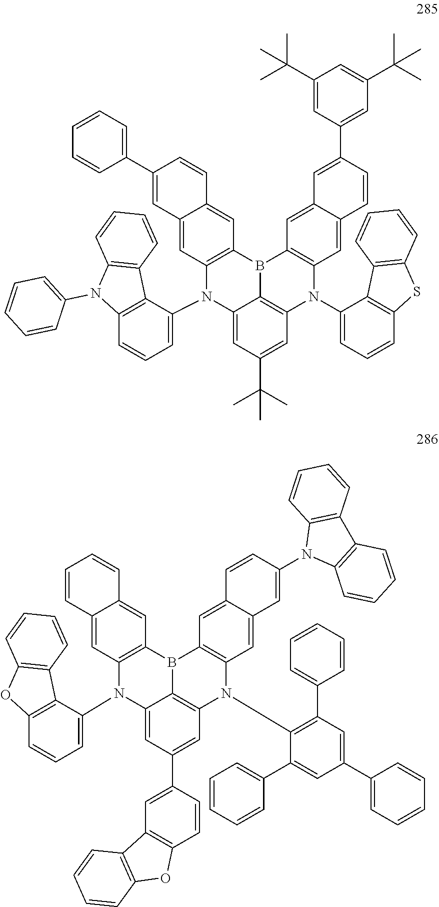 [SMILES: CC(C)(C)c1cc(-c2ccc3cc4c(cc3c2)B2c3cc5ccc(-c6ccccc6)cc5cc3N(c3cccc5c3c3ccccc3n5-c3ccccc3)c3cc(C(C)(C)C)cc(c32)N4c2cccc3sc4ccccc4c23)cc(C(C)(C)C)c1 ; c1ccc(-c2cc(-c3ccccc3)c(N3c4cc5cc(-n6c7ccccc7c7ccccc76)ccc5cc4B4c5cc6ccccc6cc5N(c5cccc6oc7ccccc7c56)c5cc(-c6ccc7oc8ccccc8c7c6)cc3c54)c(-c3ccccc3)c2)cc1]

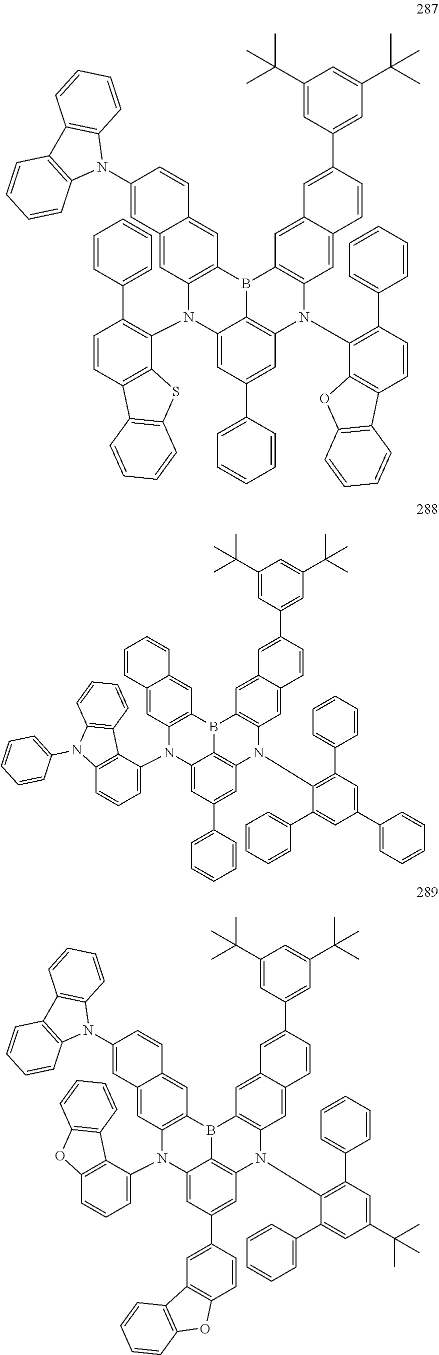

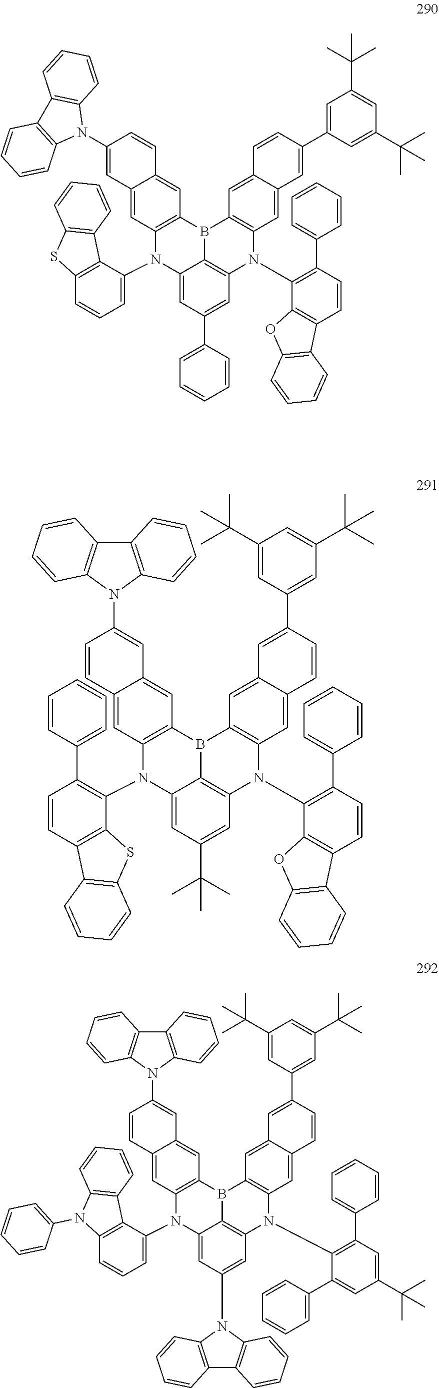

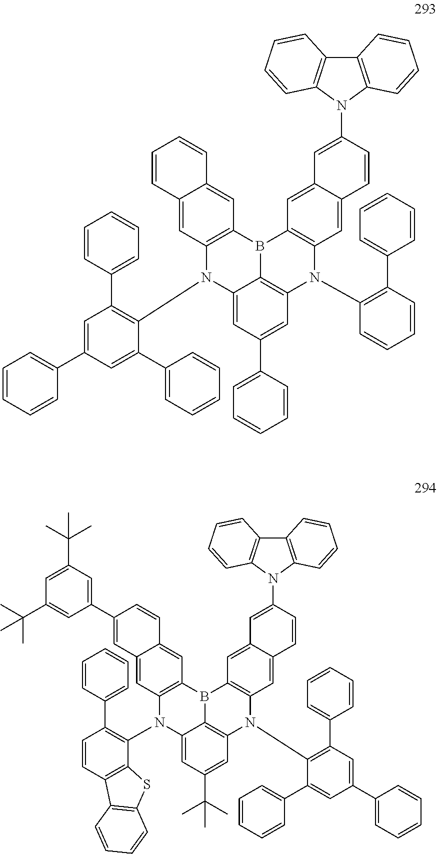 [SMILES: c1ccc(-c2cc(-c3ccccc3)c(N3c4cc5ccccc5cc4B4c5cc6cc(-n7c8ccccc8c8ccccc87)ccc6cc5N(c5ccccc5-c5ccccc5)c5cc(-c6ccccc6)cc3c54)c(-c3ccccc3)c2)cc1 ; CC(C)(C)c1cc(-c2ccc3cc4c(cc3c2)N(c2c(-c3ccccc3)ccc3c2sc2ccccc23)c2cc(C(C)(C)C)cc3c2B4c2cc4cc(-n5c6ccccc6c6ccccc65)ccc4cc2N3c2c(-c3ccccc3)cc(-c3ccccc3)cc2-c2ccccc2)cc(C(C)(C)C)c1]

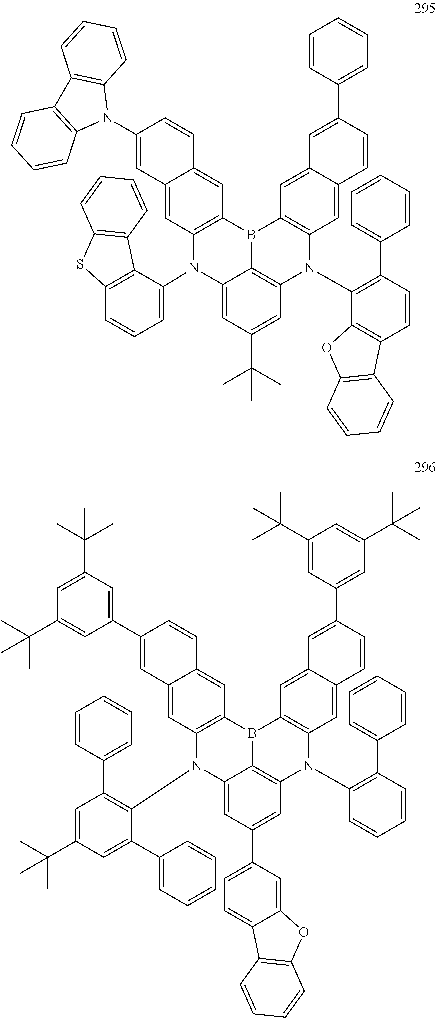 [SMILES: CC(C)(C)c1cc2c3c(c1)N(c1cccc4sc5ccccc5c14)c1cc4cc(-n5c6ccccc6c6ccccc65)ccc4cc1B3c1cc3cc(-c4ccccc4)ccc3cc1N2c1c(-c2ccccc2)ccc2c1oc1ccccc12 ; CC(C)(C)c1cc(-c2ccc3cc4c(cc3c2)B2c3cc5ccc(-c6cc(C(C)(C)C)cc(C(C)(C)C)c6)cc5cc3N(c3c(-c5ccccc5)cc(C(C)(C)C)cc3-c3ccccc3)c3cc(-c5ccc6c(c5)oc5ccccc56)cc(c32)N4c2ccccc2-c2ccccc2)cc(C(C)(C)C)c1]

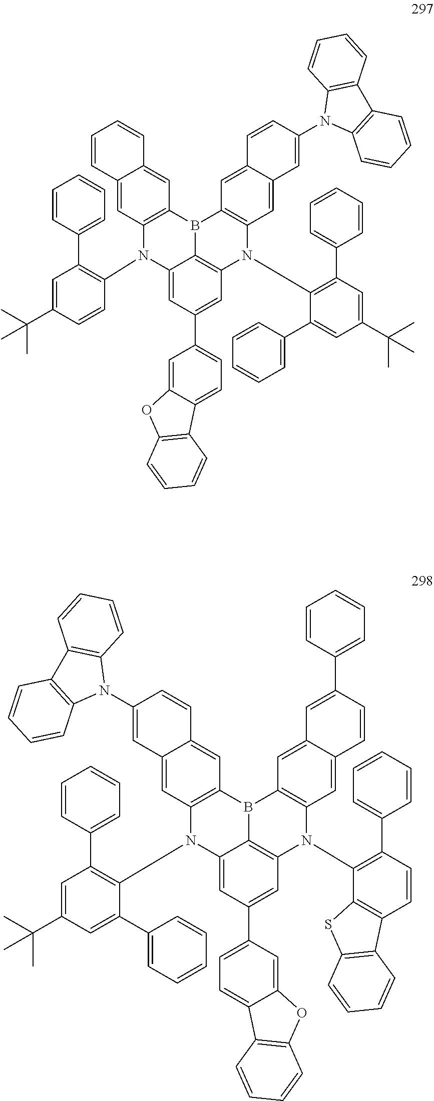

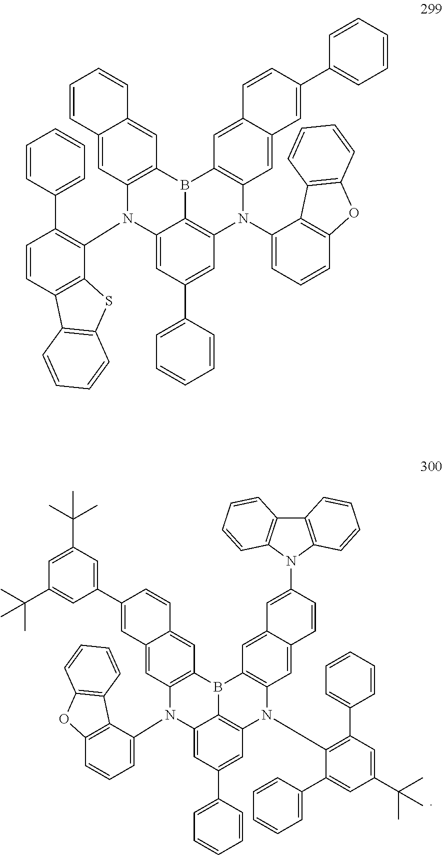 [SMILES: c1ccc(-c2cc3c4c(c2)N(c2cccc5oc6ccccc6c25)c2cc5cc(-c6ccccc6)ccc5cc2B4c2cc4ccccc4cc2N3c2c(-c3ccccc3)ccc3c2sc2ccccc23)cc1 ; CC(C)(C)c1cc(-c2ccc3cc4c(cc3c2)N(c2cccc3oc5ccccc5c23)c2cc(-c3ccccc3)cc3c2B4c2cc4cc(-n5c6ccccc6c6ccccc65)ccc4cc2N3c2c(-c3ccccc3)cc(C(C)(C)C)cc2-c2ccccc2)cc(C(C)(C)C)c1]

In the polycyclic compound according to an embodiment, multiple resonance between a nitrogen atom and the boron atom of the core may separate a highest occupied molecular orbital (HOMO) energy level and a lowest unoccupied molecular orbital (LUMO) energy level. As a result, in the polycyclic compound, a difference (ΔE_{ST}) between a lowest excited triplet energy level (T1 level) and a lowest excited singlet energy level (S1 level) is reduced, and thus characteristics of thermally activated delayed fluorescence (TADF) may be exhibited.

The polycyclic compound according to an embodiment includes a core in which a first naphthalene group and a second naphthalene group are fused around a first nitrogen atom, a second nitrogen atom, and a boron atom. In the polycyclic compound according to an embodiment, conjugation length may be extended by the two naphthalene groups included in the core, and thus a red shift may be induced.

For example, the polycyclic compound according to an embodiment has a structure in which two naphthalene rings and a benzene ring are fused around the boron atom having electron-withdrawing properties and two nitrogen atoms having electron-donating properties are constituent atoms of the fused ring. In the polycyclic compound, a fused portion of the naphthalene rings of the core exhibits strong conjugation bonding forms due to characteristics of a bonding molecular orbital, and thus red shift may be induced. Therefore, the polycyclic compound according to an embodiment may exhibit high efficiency and long lifespan characteristics in a green light wavelength region.

The polycyclic compound according to an embodiment may protect an unoccupied p-orbital of the boron atom by a steric protection substituent connected to at least one of the nitrogen atoms of the core. Therefore, in the polycyclic compound, the boron atom of the core is inhibited from reacting with Lewis bases, degradation materials (e.g., a radical), or the like within the light-emitting element, which may effectively maintain a trigonal planar structure of the boron atom, thereby preventing degradation due to structural deformation of the boron atom.

In the polycyclic compound according to an embodiment, since intermolecular interaction is inhibited by the steric protection substituent connected to the core, the formation of aggregates, excimers, or exciplexes may be controlled, which may increase luminous efficiency. The polycyclic compound according to an embodiment has a bulky structure, thereby increasing intermolecular distance, and thus Dexter energy transfer may be reduced.

Therefore, an increase in the concentration of triplet excitons of the polycyclic compound may be inhibited. High concentrations of triplet excitons may remain in an excited state for a long time, thereby inducing decomposition of the polycyclic compound and generating a hot exciton having high energy by triplet-triplet annihilation (TTA), and thus degrading the surrounding compound structure. Triplet-triplet annihilation is a bimolecular reaction that rapidly depletes triplet excitons used for emission through a non-radiative transition, thereby decreasing luminescence efficiency. In the polycyclic compound according to an embodiment, intermolecular distance increases due to the steric protection substituent connected to the core, and thus Dexter energy transfer may be inhibited. Therefore, reduction of lifespan caused by high concentrations of triplet excitons may be inhibited, and intermolecular interactions may be inhibited. Therefore, when the polycyclic compound according to an embodiment is used as a material in the emission layer EML of the light-emitting element ED, element life span may be improved, and luminous efficiency may increase.

The polycyclic compound according to an embodiment may be an emission material having a peak emission wavelength (lₘₐₓ) equal to or greater than about 490 nm. In an embodiment, the polycyclic compound may be an emission material having a peak emission wavelength (lₘₐₓ) in a range of about 490 nm to about 550 nm. The polycyclic compound according to an embodiment may be an emission material that emits green light.

In the light-emitting element ED according to an embodiment, the emission layer EML includes a host and a dopant. The emission layer EML may include the polycyclic compound according to an embodiment as a dopant. For example, in the light-emitting element ED, the emission layer EML may include a host and a dopant, and may include the polycyclic compound according to an embodiment as a dopant for emitting delayed fluorescence. For example, the emission layer EML may include at least one polycyclic compound according to an embodiment as a dopant for thermally activated delayed fluorescence (TADF).

An emission spectrum of the polycyclic compound according to an embodiment may have a full width at half maximum (FWHM) in a range of about 10 nm to about 50 nm. For example, the emission spectrum of the polycyclic compound may have an FWHM in a range of about 20 nm to about 40 nm. Since an emission spectrum of the polycyclic compound according to an embodiment has a full width at half maximum in the range described above, luminous efficiency may be improved when the polycyclic compound is included in the light-emitting element ED. When the polycyclic compound is used as a green emission material for the light-emitting element ED, element lifespan may be improved.

In an embodiment, the polycyclic compound may be a thermally delayed fluorescent emission material. The polycyclic compound according to an embodiment may be a dopant for thermally activated delayed fluorescence in which a difference (ΔE_{ST}) between a lowest excited triplet energy level (T1 level) and a lowest excited singlet energy level (S1 level) may be equal to or less than about 0.6 eV. For example, the polycyclic compound may be a dopant for thermally activated delayed fluorescence in which the difference (ΔE_{ST}) between the lowest excited triplet energy level (T1 level) and the lowest excited singlet energy level (S1 level) may be equal to or less than about 0.2 eV. However, embodiments are not limited thereto.

In the light-emitting element ED according to an embodiment, the emission layer EML may emit delayed fluorescence. For example, the emission layer EML may emit thermally activated delayed fluorescence (TADF). In an embodiment, the emission layer EML of the light-emitting element ED may emit green light. For example, the emission layer EML of the light-emitting element ED according to an embodiment may emit green light having a wavelength equal to or greater than about 490 nm. However, embodiments are not limited thereto, and the emission layer EML may emit blue light or red light.

The polycyclic compound according to an embodiment may be included in the emission layer EML. For example, the polycyclic compound according to an embodiment may be included in the emission layer EML as a dopant material. For example, the polycyclic compound according to an embodiment may be an emission material for thermally activated delayed fluorescence. For example, the polycyclic compound according to an embodiment may be used as a dopant for thermally activated delayed fluorescence. For example, in the light-emitting element ED, the emission layer EML may include at least one compound selected from Compound Group 1 as a dopant for thermally activated delayed fluorescence. However, a use of the polycyclic compound according to an embodiment is not limited thereto.

In an embodiment, the emission layer EML may include multiple compounds. The emission layer EML according to an embodiment may include the polycyclic compound represented by Formula 1, which is the first compound, and may further include at least one of a second compound represented by Formula HT-1, a third compound represented by Formula ET-1, and a fourth compound represented by Formula D-1.

In an embodiment, the emission layer EML may include the first compound represented by Formula 1, and may further include at least one of the second compound represented by Formula HT-1 and the third compound represented by Formula ET-1. For example, the emission layer EML may include the first compound represented by Formula 1 and the third compound represented by Formula ET-1. However, embodiments are not limited thereto, and the emission layer EML may include the first compound, the second compound, and the third compound.

In an embodiment, the emission layer EML may further include a second compound represented by Formula HT-1. In an embodiment, the second compound may be used as a hole transport host material in the emission layer EML.

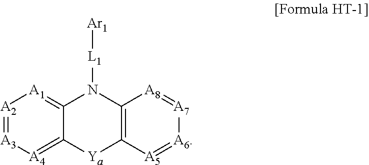

In Formula HT-1, A₁ to A₈ may each independently be N or C(R₅₁). For example, A₁ to A₈ may each independently be C(R₅₁). As another example, one of A₁ to A₈ may be N, and the remainder of A₁ to A₈ may each independently be C(R₅₁).

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but embodiments are not limited thereto.

In Formula HT-1, Yₐ may be a direct linkage, C(R₅₂)(R₅₃), or Si(R₅₄)(R₅₅). For example, the two benzene rings that are linked to the nitrogen atom in Formula HT-1 may be linked to each other via a direct linkage,

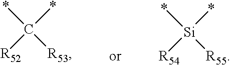

In Formula HT-1, when Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms or a substituted or unsubstituted heteroaryl group having 2 to 30 ring-forming carbon atoms. For example, An may be a substituted or unsubstituted carbazole group, a substituted or unsubstituted dibenzofuran group, a substituted or unsubstituted dibenzothiophene group, a substituted or unsubstituted biphenyl group, etc., but embodiments are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₅₁ to R₅₅ may each independently be a hydrogen atom or a deuterium atom. As another example, R₅₁ to R₅₅ may each independently be an unsubstituted methyl group or an unsubstituted phenyl group.

In an embodiment, the second compound represented by Formula HT-1 may be selected from Compound Group 2. In an embodiment, in the light-emitting element ED, the second compound may include at least one compound selected from Compound Group 2:

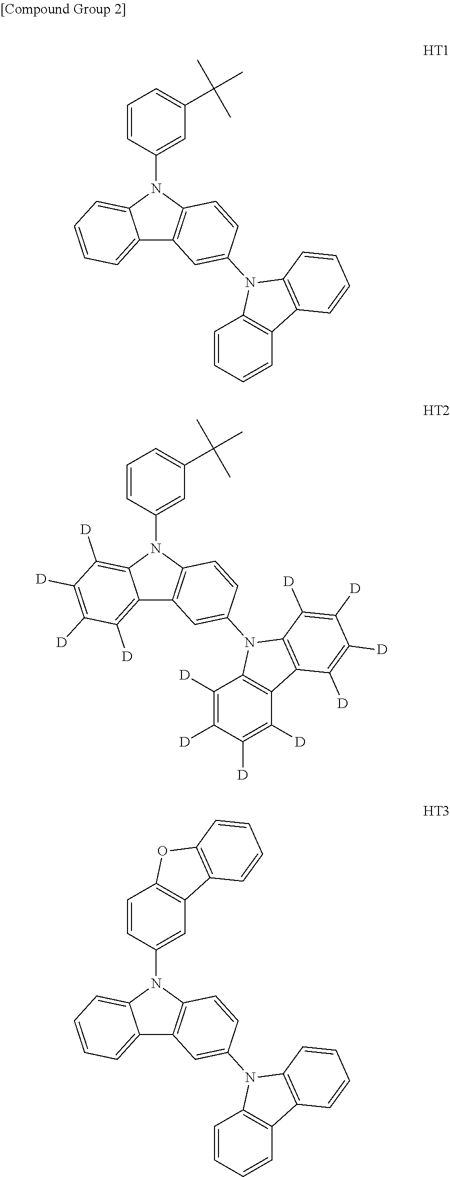 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

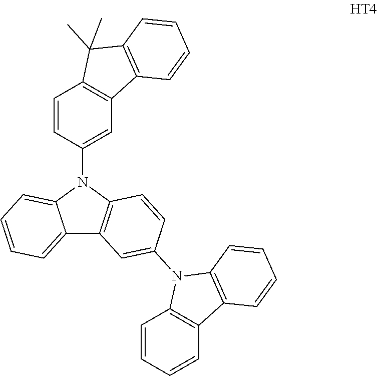 [SMILES: CC1(C)c2ccccc2-c2cc(-n3c4ccccc4c4cc(-n5c6ccccc6c6ccccc65)ccc43)ccc21]

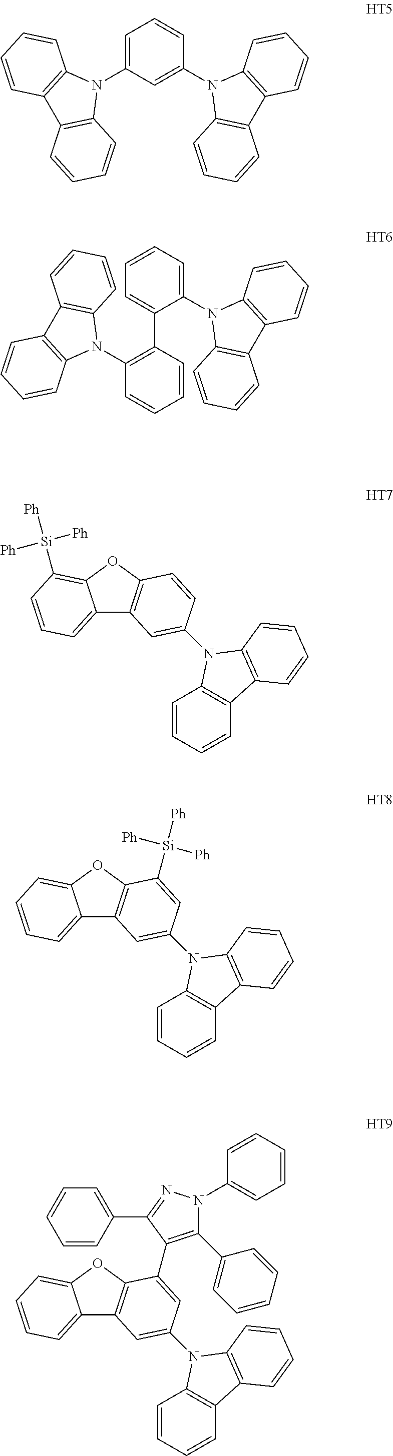 [SMILES: c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1]

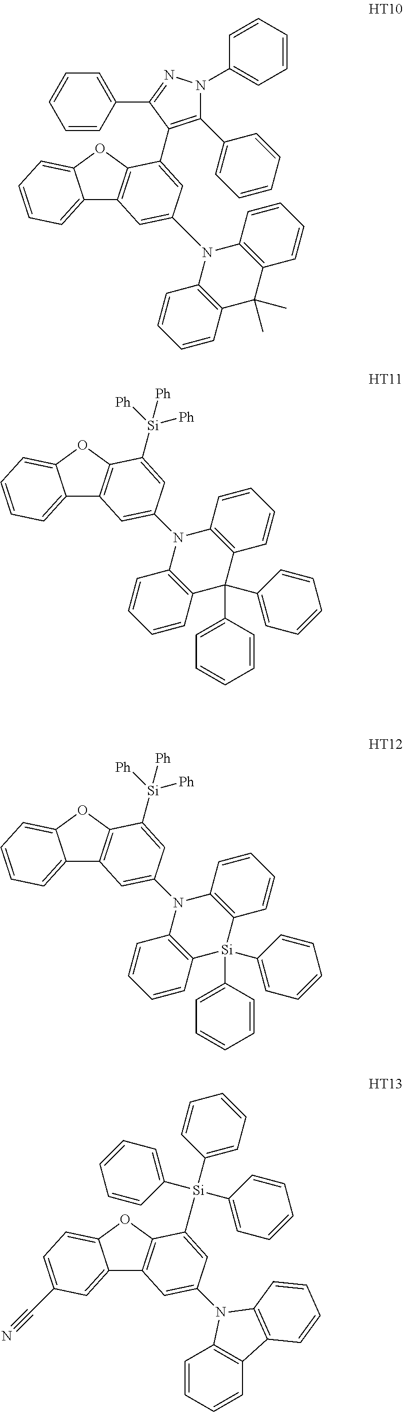

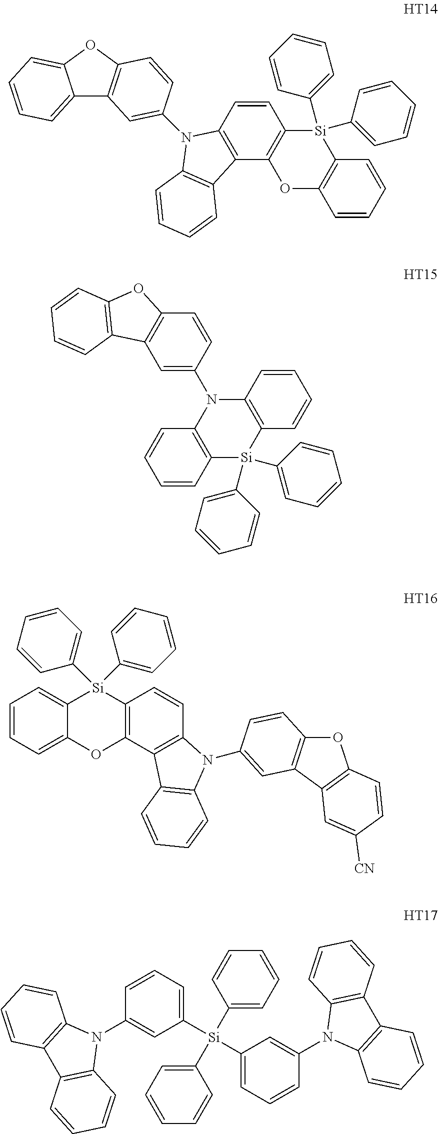 [SMILES: c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1]

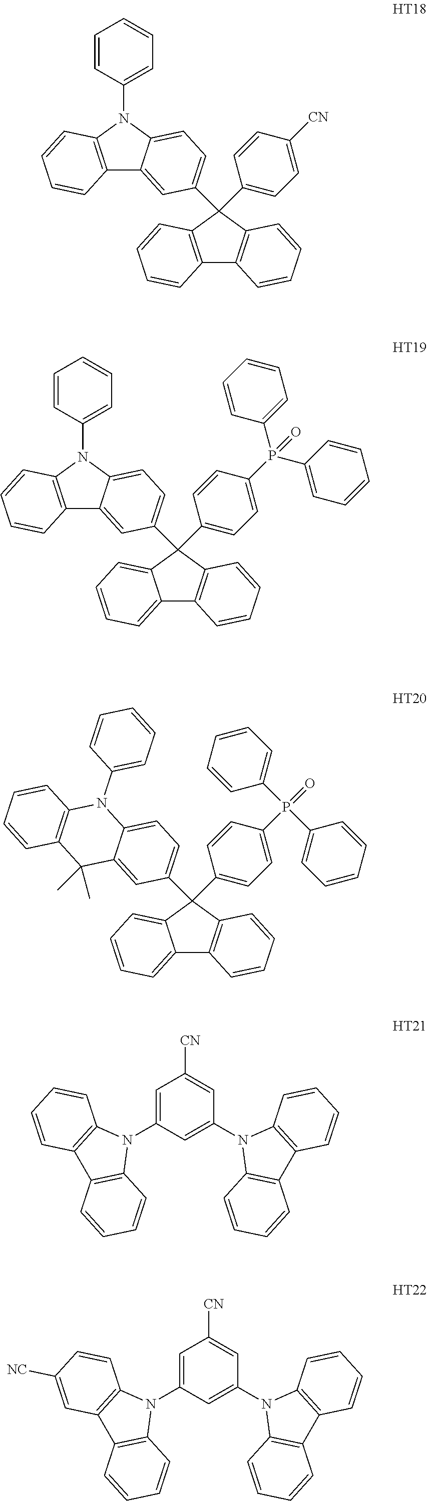 [SMILES: N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

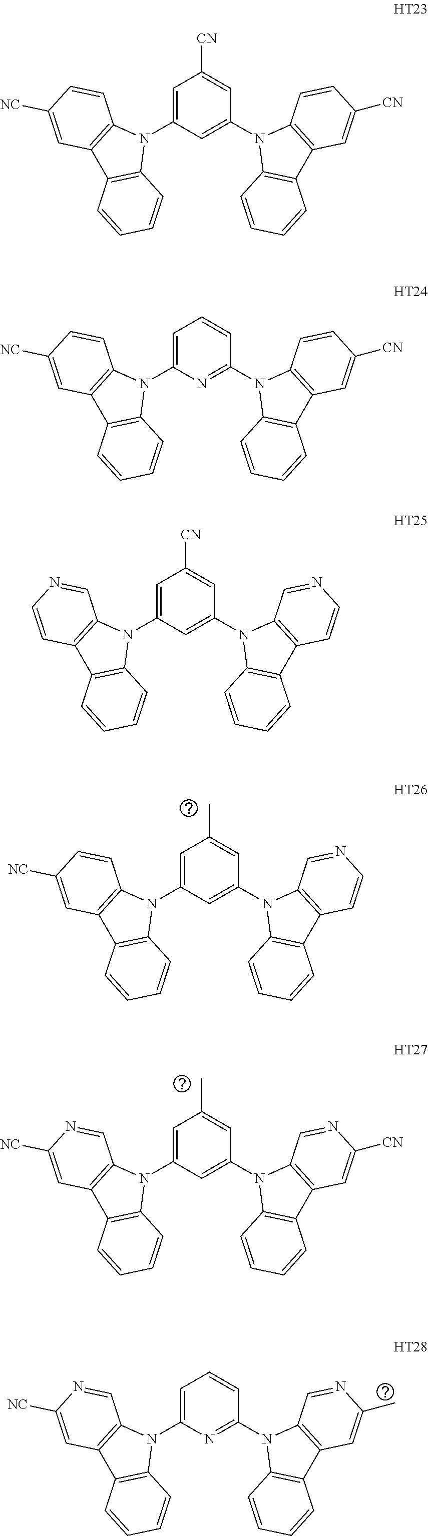 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; Cc1cc(-n2c3ccccc3c3cc(C#N)ccc32)cc(-n2c3ccccc3c3ccncc32)c1 ; Cc1cc(-n2c3ccccc3c3cc(C#N)ncc32)cc(-n2c3ccccc3c3cc(C#N)ncc32)c1 ; Cc1cc2c3ccccc3n(-c3cccc(-n4c5ccccc5c5cc(C#N)ncc54)n3)c2cn1]

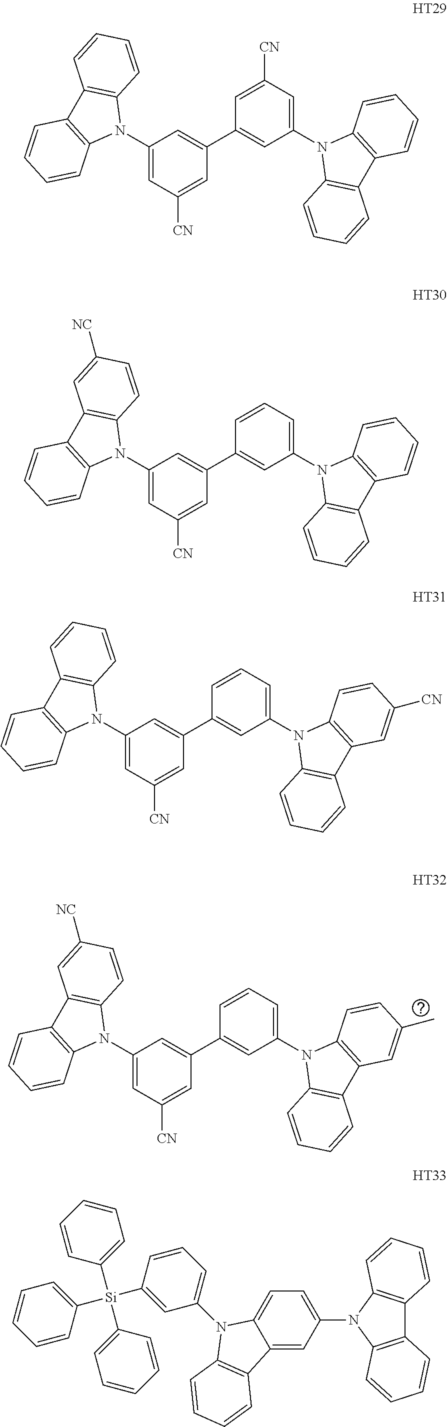 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; Cc1ccc2c(c1)c1ccccc1n2-c1cccc(-c2cc(C#N)cc(-n3c4ccccc4c4cc(C#N)ccc43)c2)c1 ; c1ccc([Si](c2ccccc2)(c2ccccc2)c2cccc(-n3c4ccccc4c4cc(-n5c6ccccc6c6ccccc65)ccc43)c2)cc1]

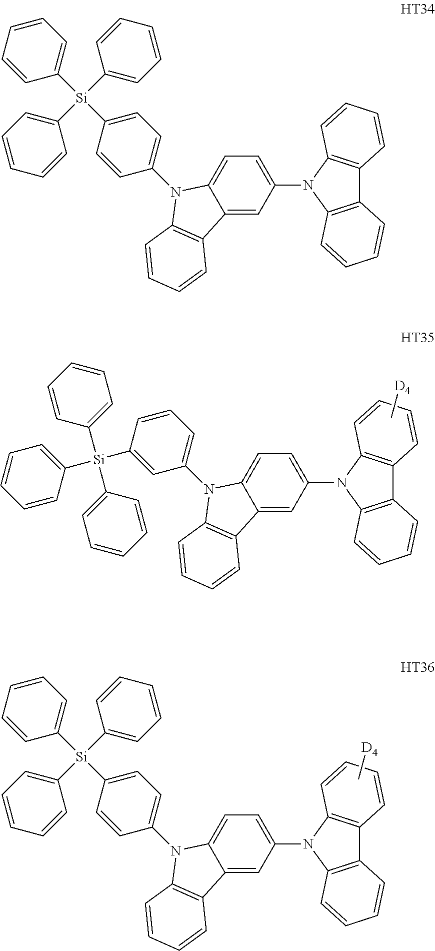

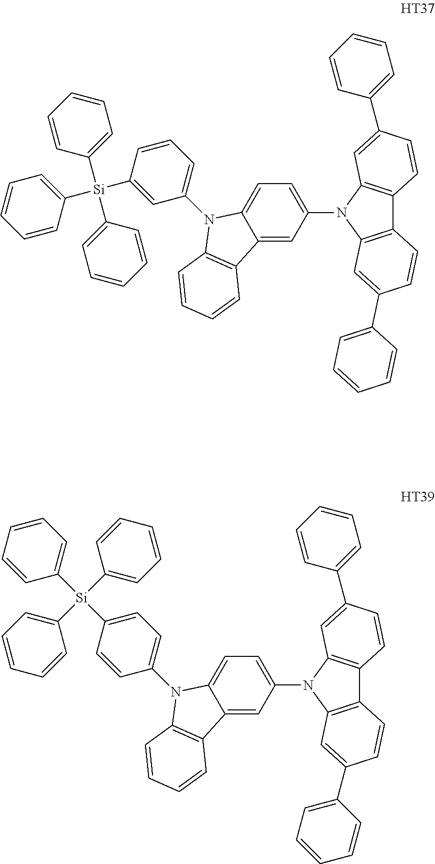 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1]

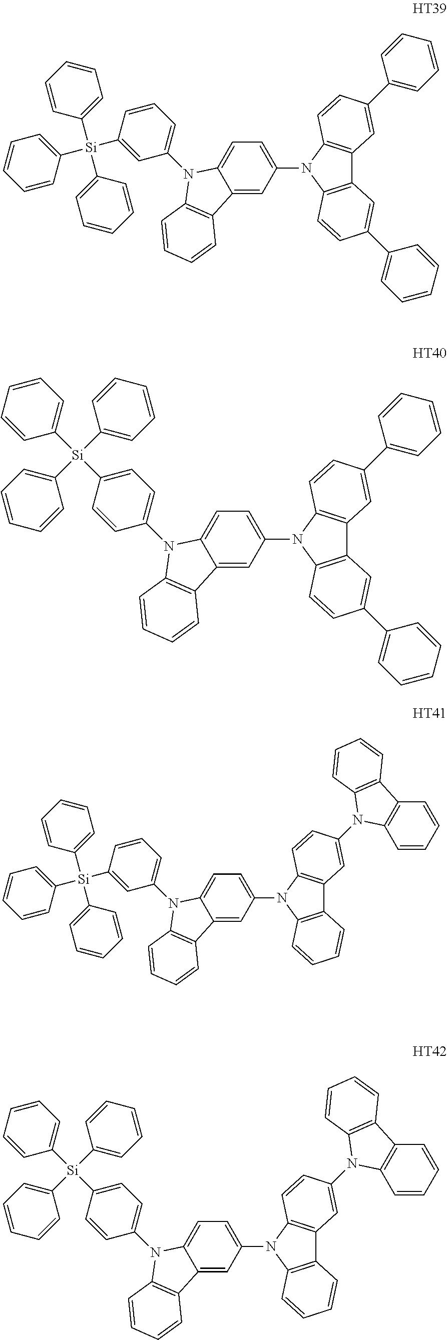 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

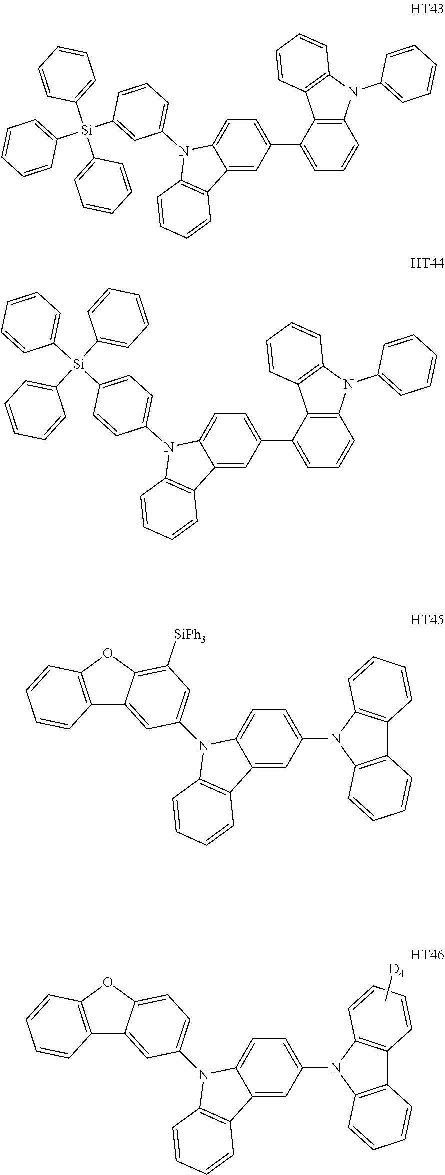

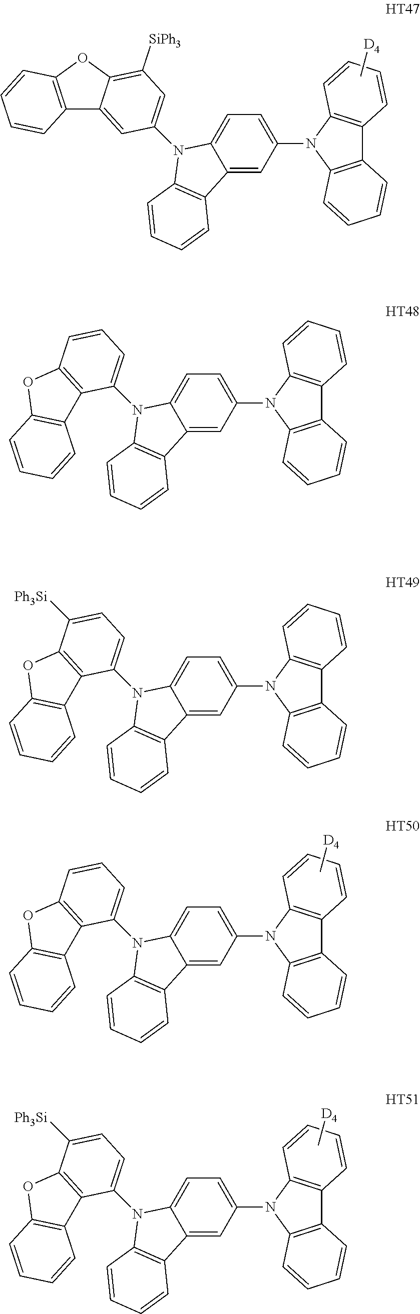

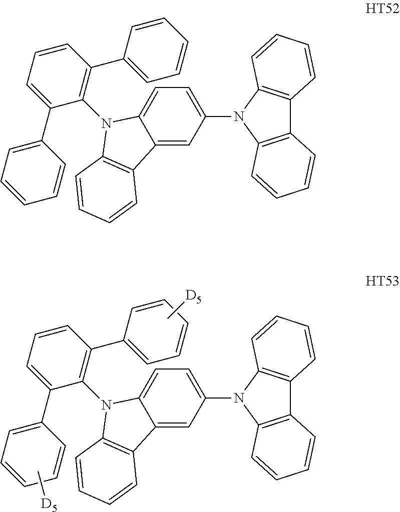

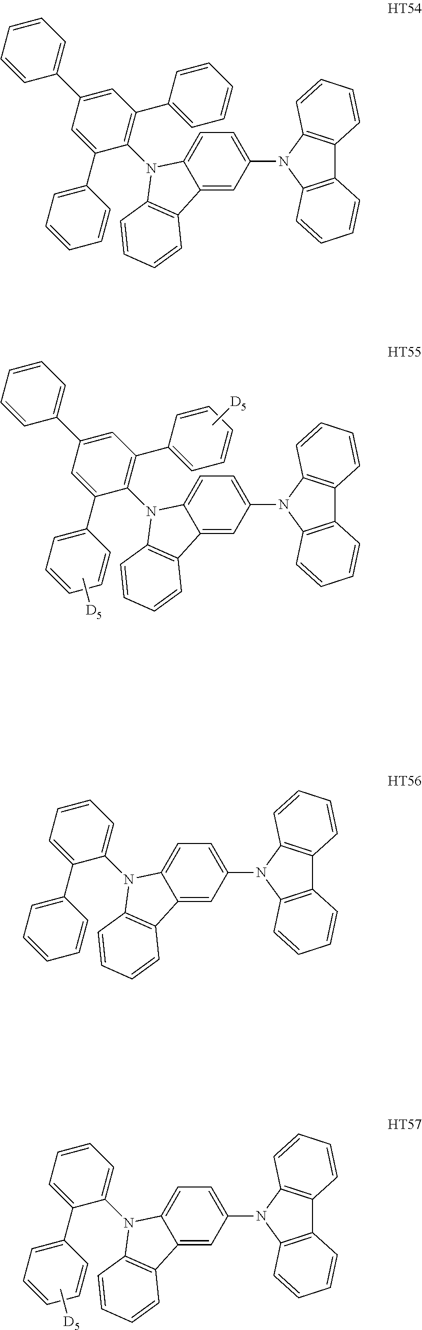

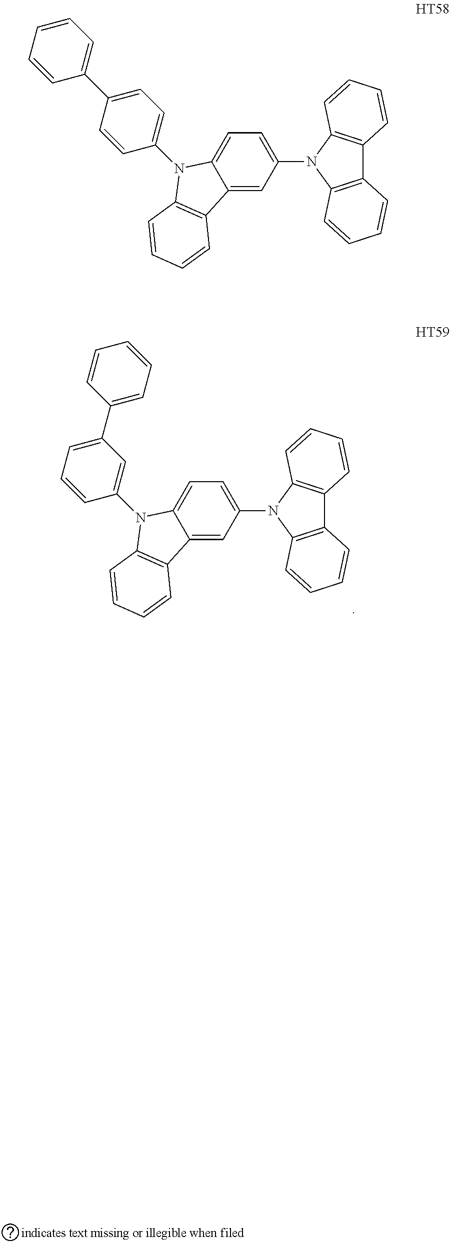 [SMILES: c1ccc(-c2ccc(-n3c4ccccc4c4cc(-n5c6ccccc6c6ccccc65)ccc43)cc2)cc1 ; c1ccc(-c2cccc(-n3c4ccccc4c4cc(-n5c6ccccc6c6ccccc65)ccc43)c2)cc1]

In Compound Group 2, D represents a deuterium atom, and Ph represents a substituted or unsubstituted phenyl group. For example, in Compound Group 2, Ph may represent an unsubstituted phenyl group.

In an embodiment, the emission layer EML may further include a third compound represented by Formula ET-1. In an embodiment, the third compound may be used as an electron transport host material in the emission layer EML.

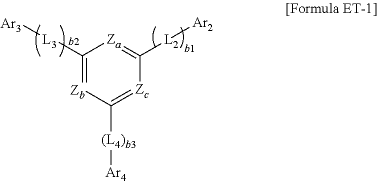

In Formula ET-1, at least one of Zₐ to Z_{c} may be N; and the remainder of Zₐ to Z_{c} may each independently be C(R₅₆). For example, one of Zₐ to Z_{c} may be N, and the remainder of Zₐto Z_{c} may each independently be C(R₅₆). Thus, the third compound represented by Formula ET-1 may include a pyridine moiety. As another example, two of Zₐ to Z_{c} may each be N, and the remainder of Zₐ to Z_{c} may be C(R₅₆). Thus, the third compound represented by Formula ET-1 may include a pyrimidine moiety. As yet another example, Zₐ to Z_{c} may each be N. Thus, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer from 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. When b1 to b3 are each 2 or greater, multiple groups of each of L₂ to L₄ may each independently be a substituted or unsubstituted arylene group having 6 to 30 ring-forming carbon atoms or a substituted or unsubstituted heteroarylene group having 2 to 30 ring-forming carbon atoms.

In an embodiment, the third compound represented by Formula ET-1 may be selected from Compound Group 3. In an embodiment, in the light-emitting element ED, the third compound may include at least one compound selected from Compound Group 3:

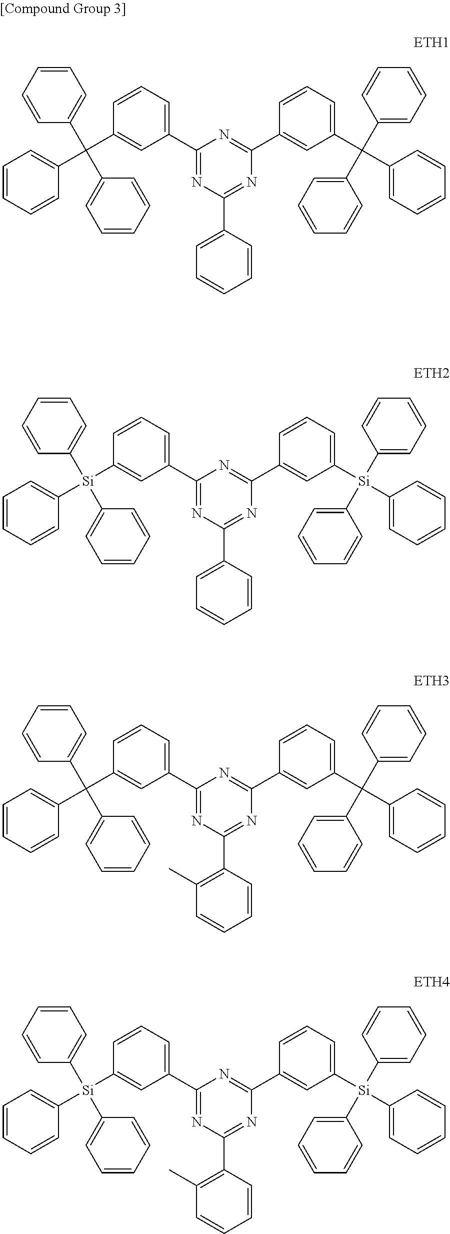 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

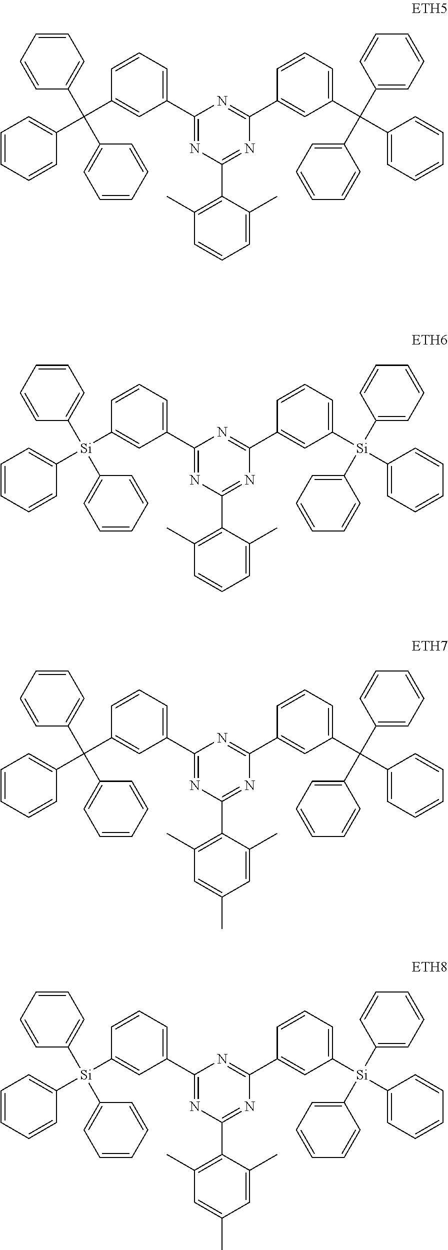 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

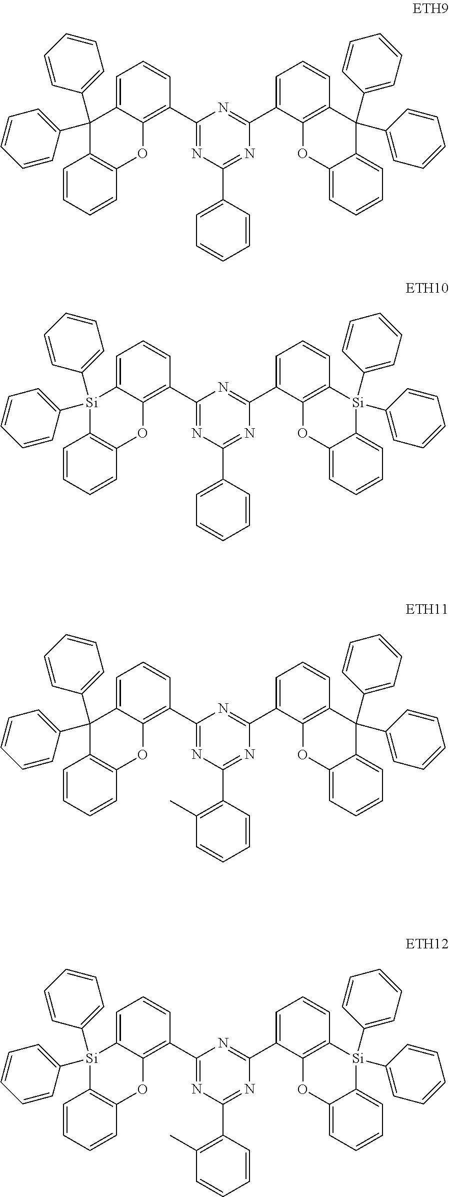 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

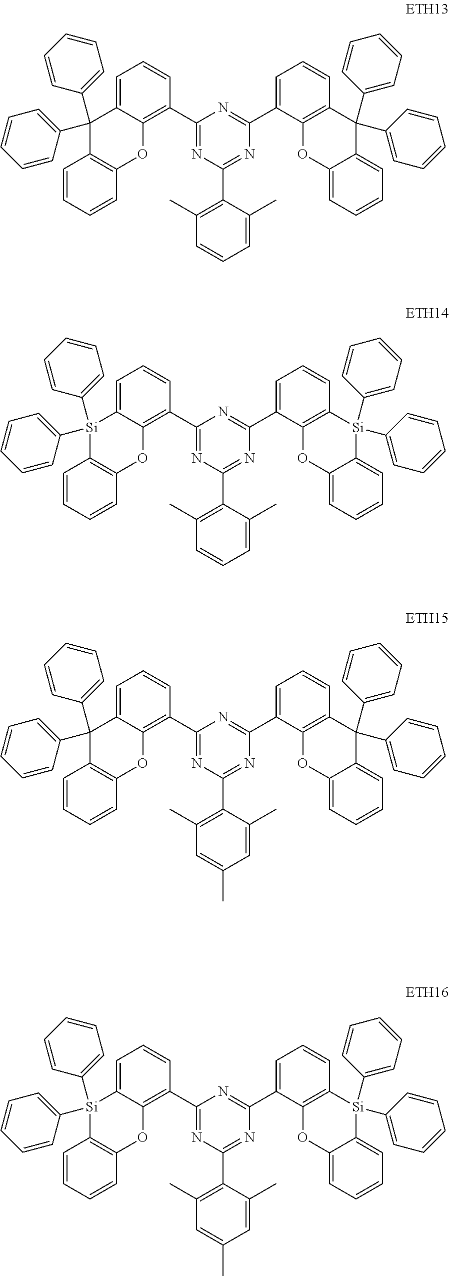 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

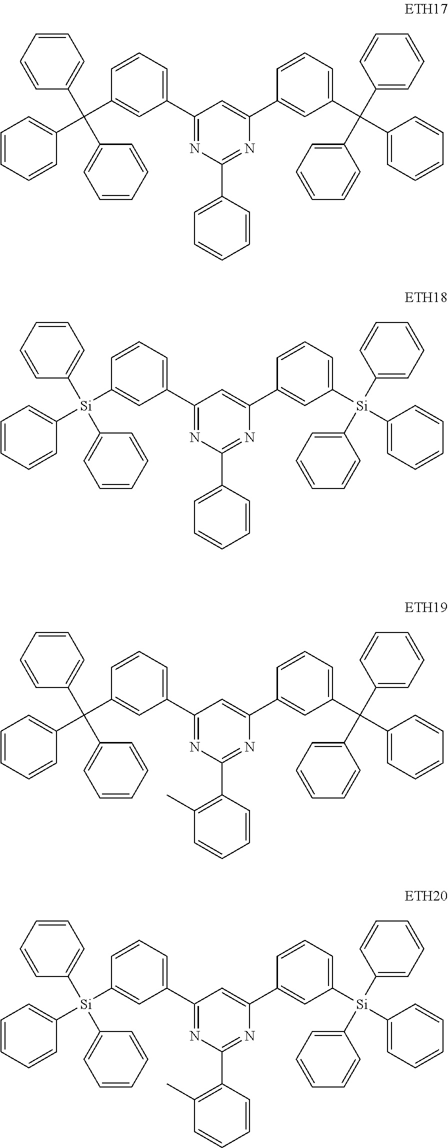 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

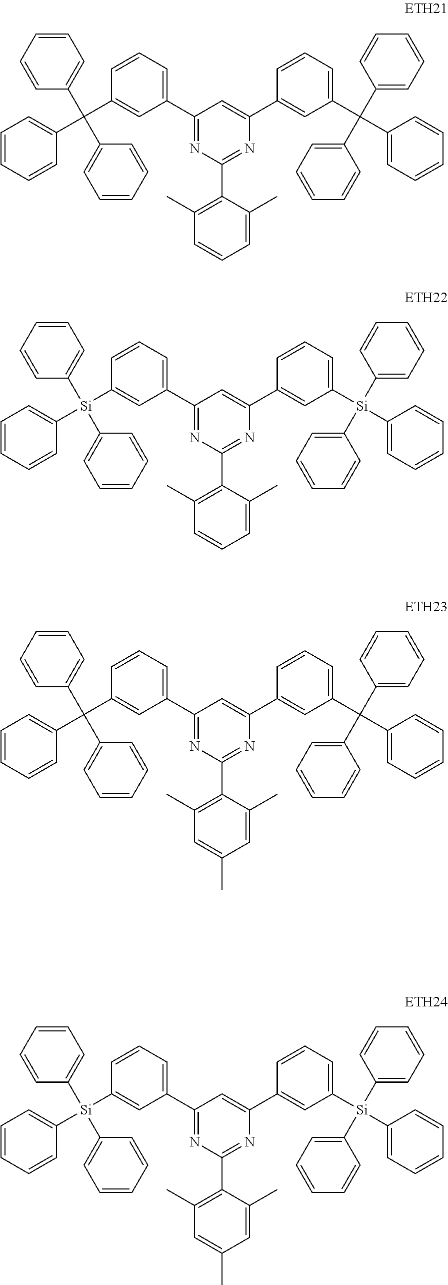 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

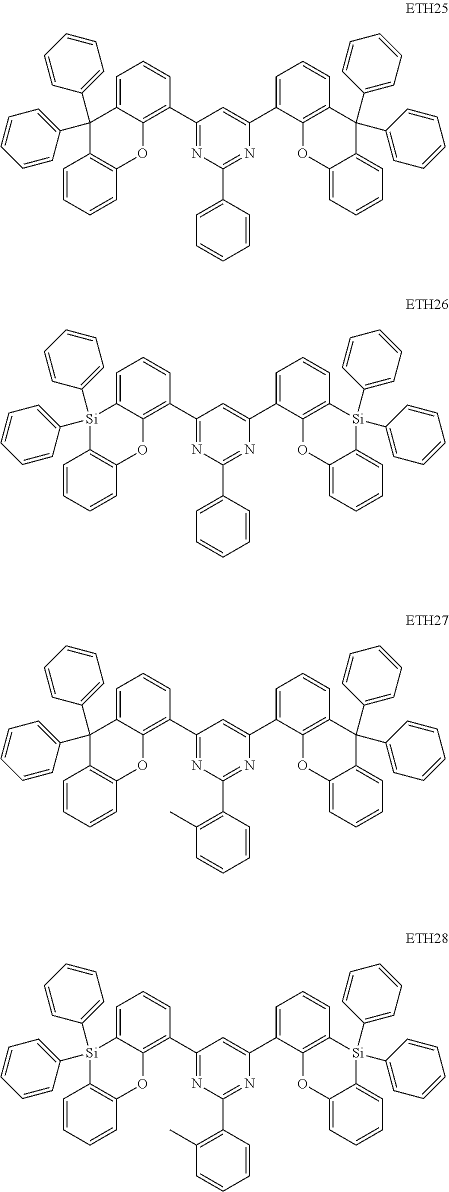 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

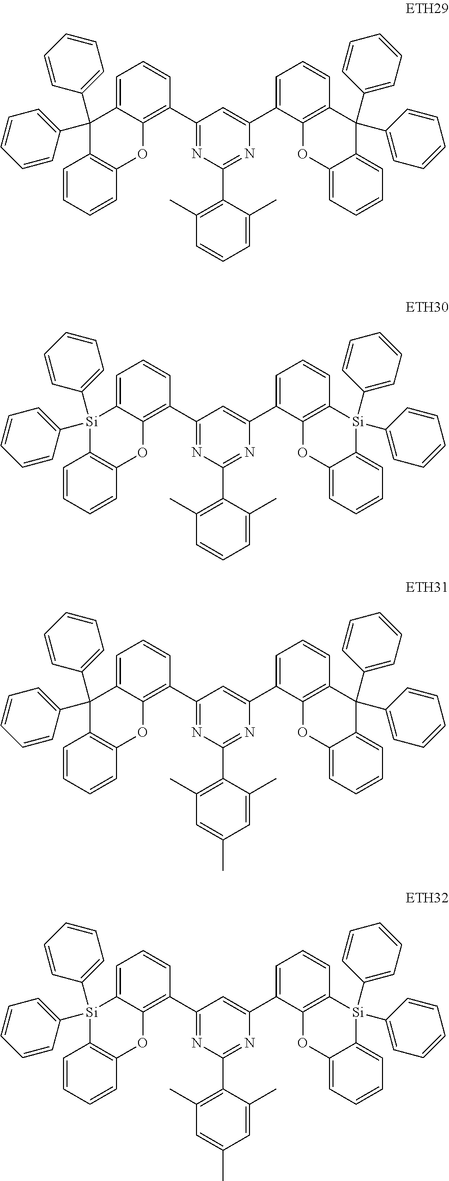 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

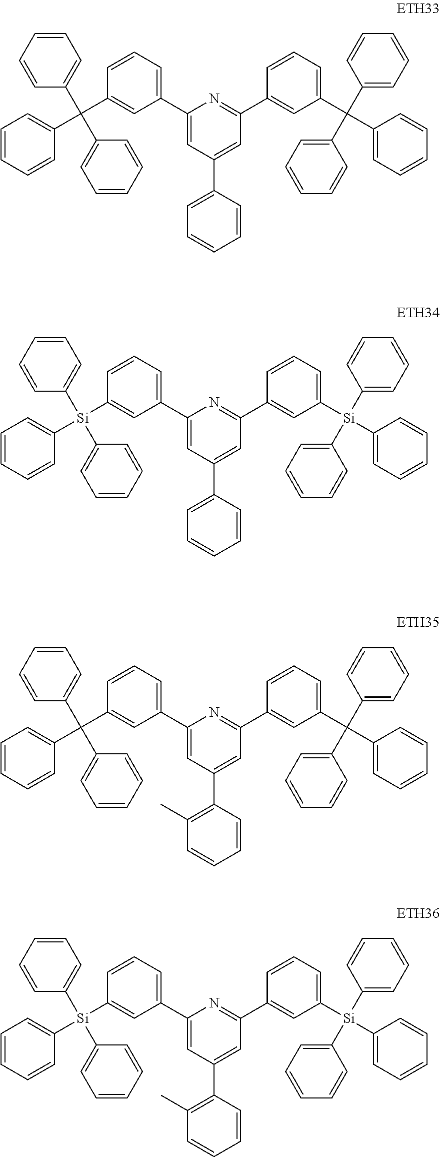 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

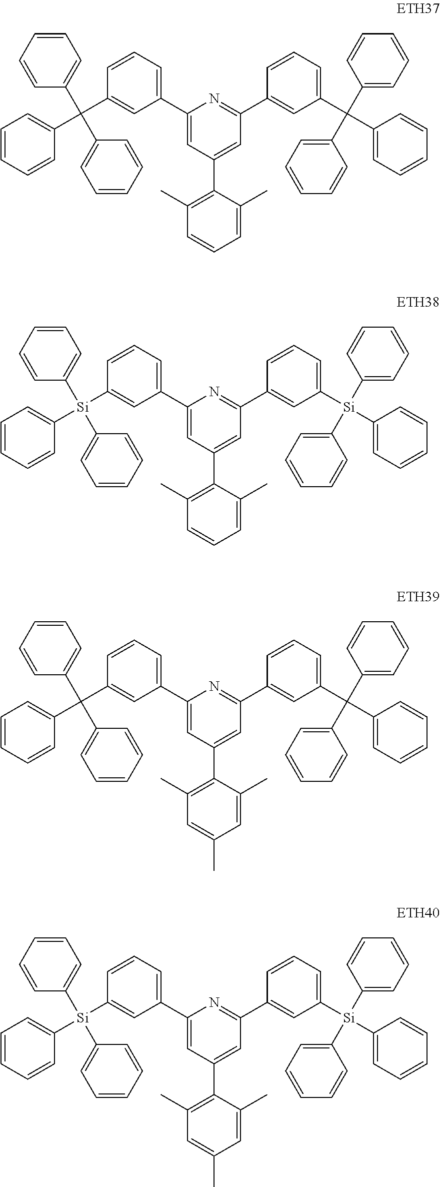 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

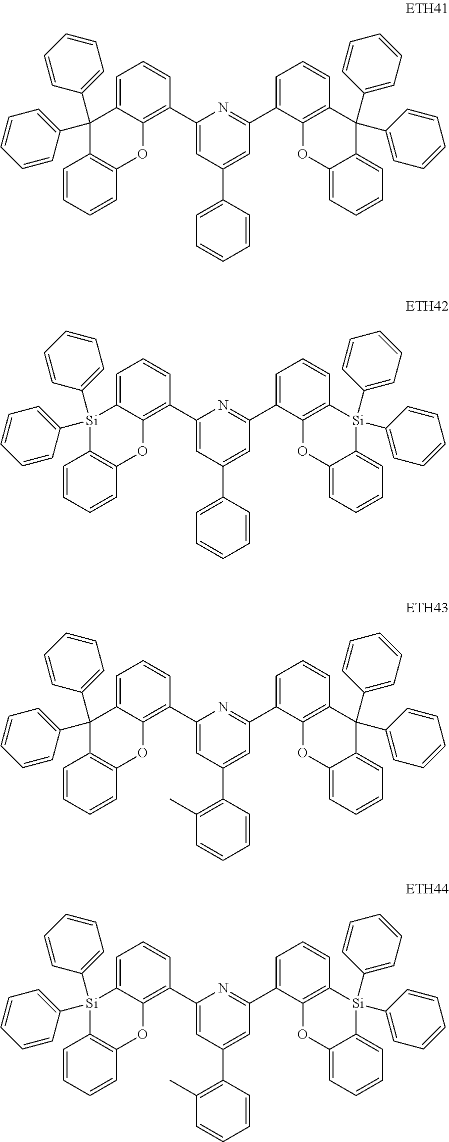 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

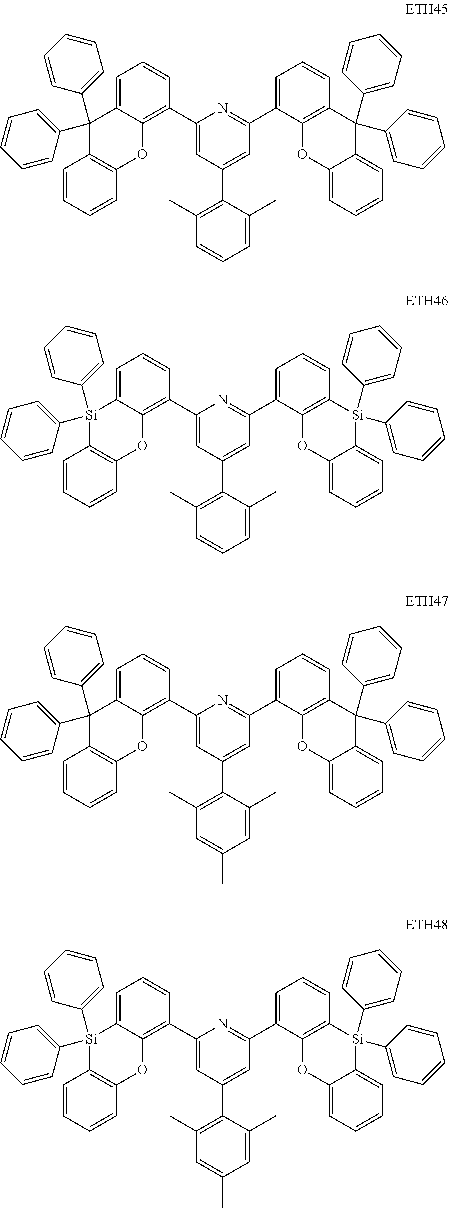 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

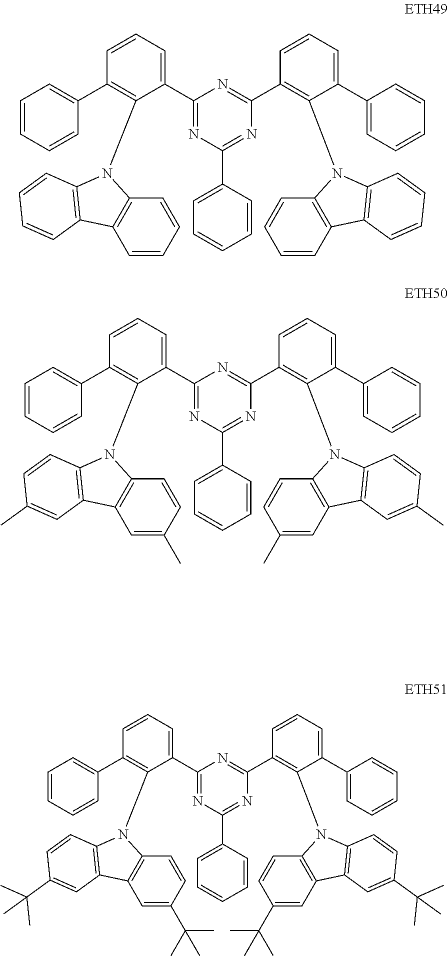

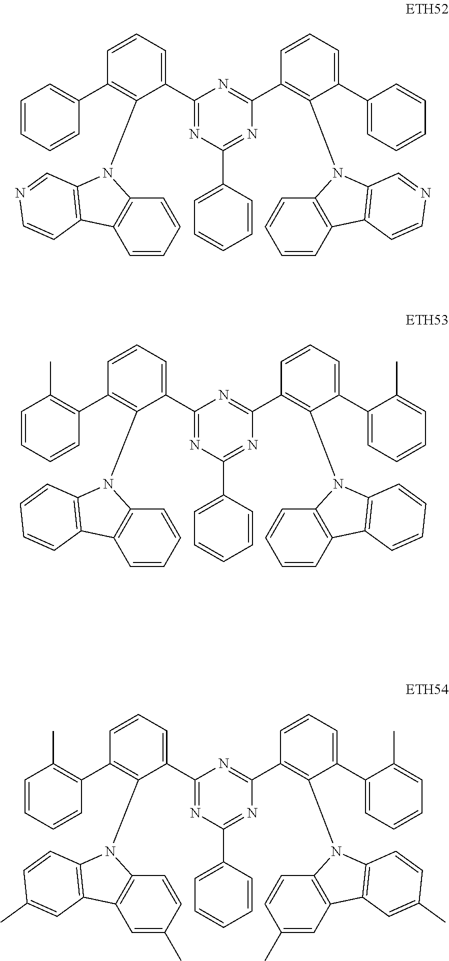

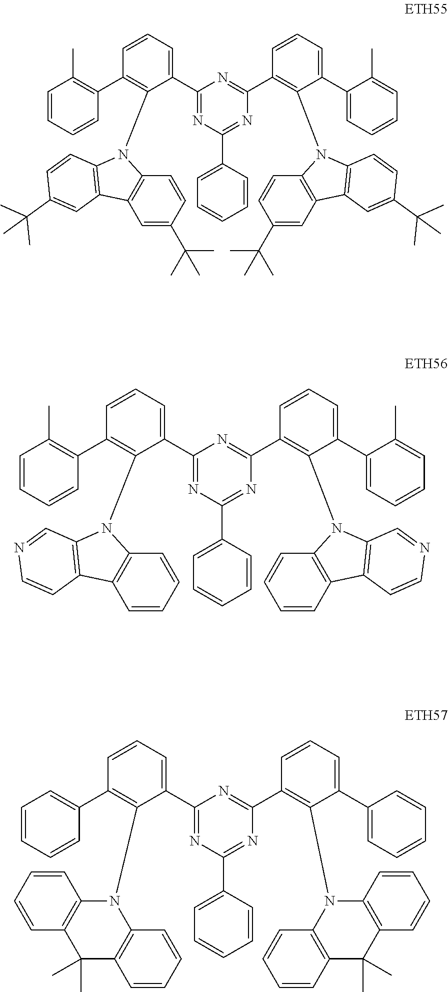 [SMILES: Cc1ccccc1-c1cccc(-c2nc(-c3ccccc3)nc(-c3cccc(-c4ccccc4C)c3-n3c4ccc(C(C)(C)C)cc4c4cc(C(C)(C)C)ccc43)n2)c1-n1c2ccc(C(C)(C)C)cc2c2cc(C(C)(C)C)ccc21 ; Cc1ccccc1-c1cccc(-c2nc(-c3ccccc3)nc(-c3cccc(-c4ccccc4C)c3-n3c4ccccc4c4ccncc43)n2)c1-n1c2ccccc2c2ccncc21 ; CC1(C)c2ccccc2N(c2c(-c3ccccc3)cccc2-c2nc(-c3ccccc3)nc(-c3cccc(-c4ccccc4)c3N3c4ccccc4C(C)(C)c4ccccc43)n2)c2ccccc21]

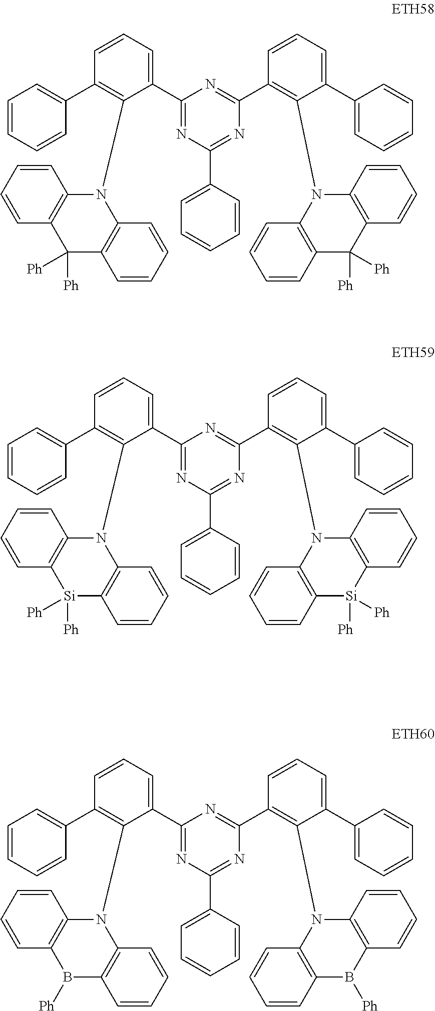 [SMILES: c1ccc(-c2nc(-c3cccc(-c4ccccc4)c3N3c4ccccc4C(c4ccccc4)(c4ccccc4)c4ccccc43)nc(-c3cccc(-c4ccccc4)c3N3c4ccccc4C(c4ccccc4)(c4ccccc4)c4ccccc43)n2)cc1 ; c1ccc(-c2nc(-c3cccc(-c4ccccc4)c3N3c4ccccc4[Si](c4ccccc4)(c4ccccc4)c4ccccc43)nc(-c3cccc(-c4ccccc4)c3N3c4ccccc4[Si](c4ccccc4)(c4ccccc4)c4ccccc43)n2)cc1 ; c1ccc(B2c3ccccc3N(c3c(-c4ccccc4)cccc3-c3nc(-c4ccccc4)nc(-c4cccc(-c5ccccc5)c4N4c5ccccc5B(c5ccccc5)c5ccccc54)n3)c3ccccc32)cc1]

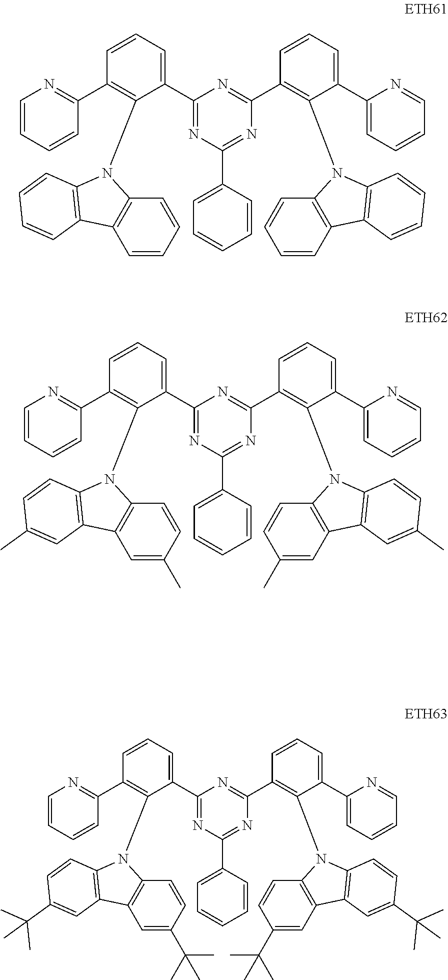

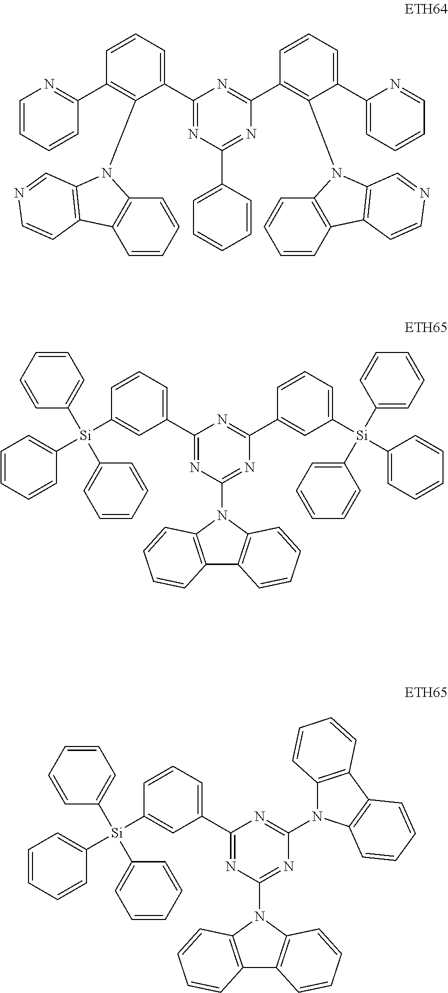 [SMILES: c1ccc(-c2nc(-c3cccc(-c4ccccn4)c3-n3c4ccccc4c4ccncc43)nc(-c3cccc(-c4ccccn4)c3-n3c4ccccc4c4ccncc43)n2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

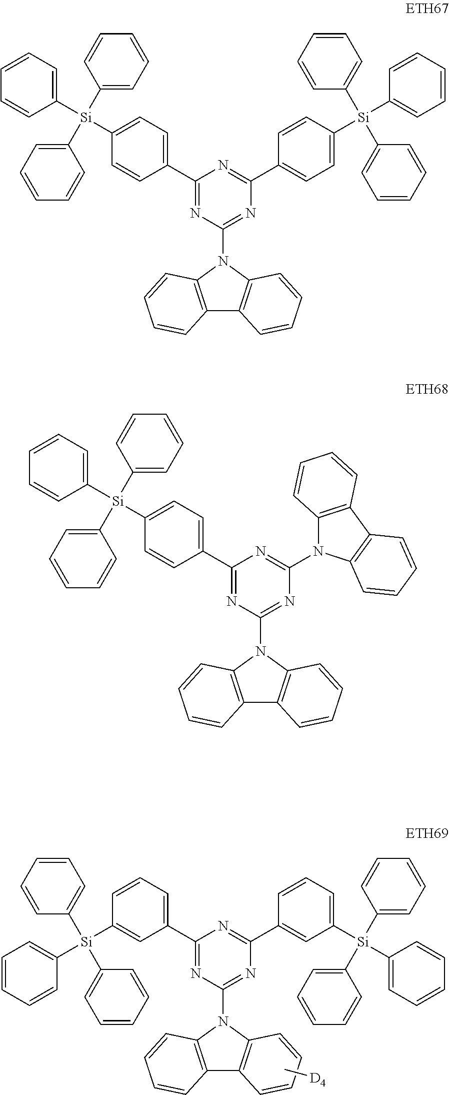

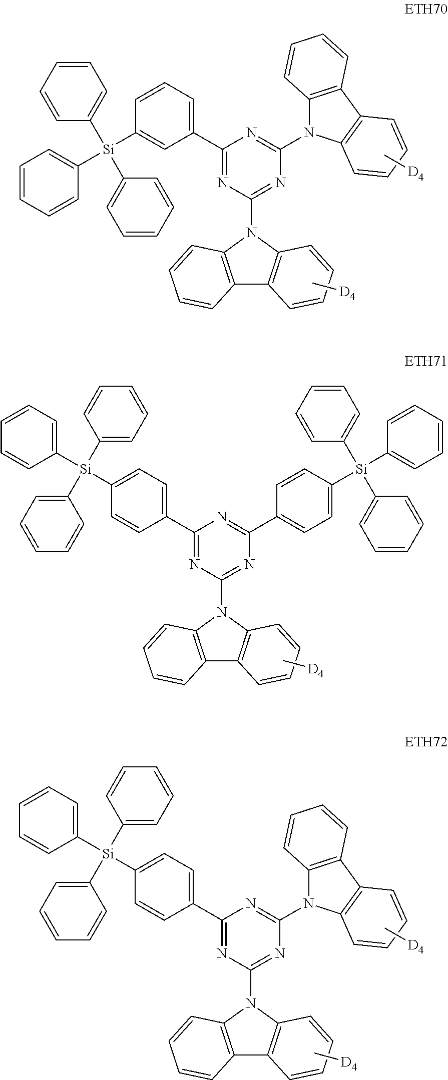

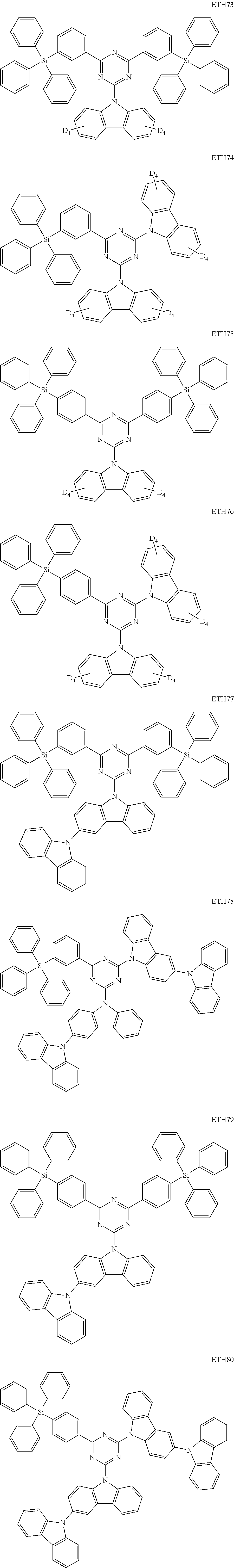

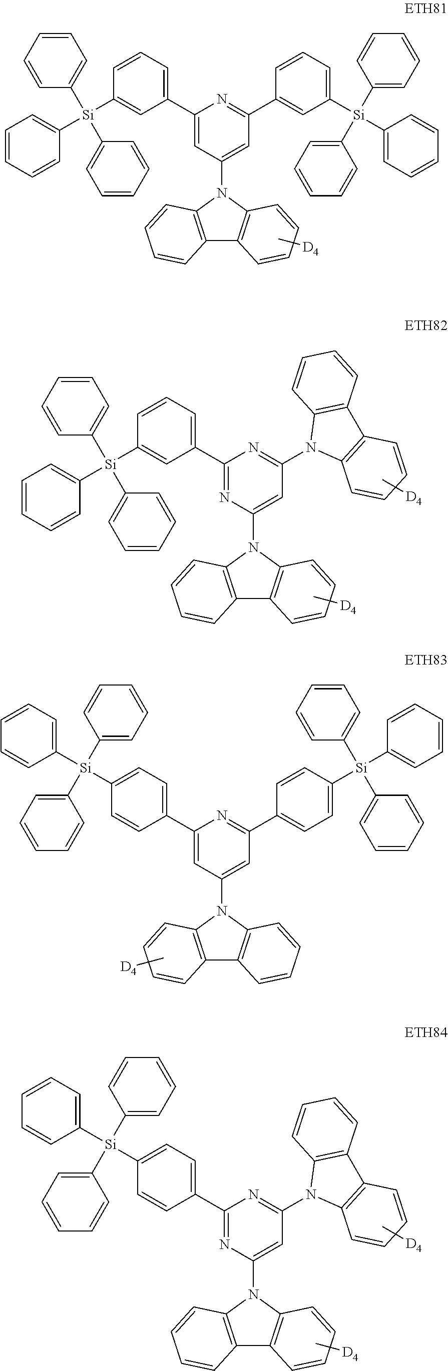

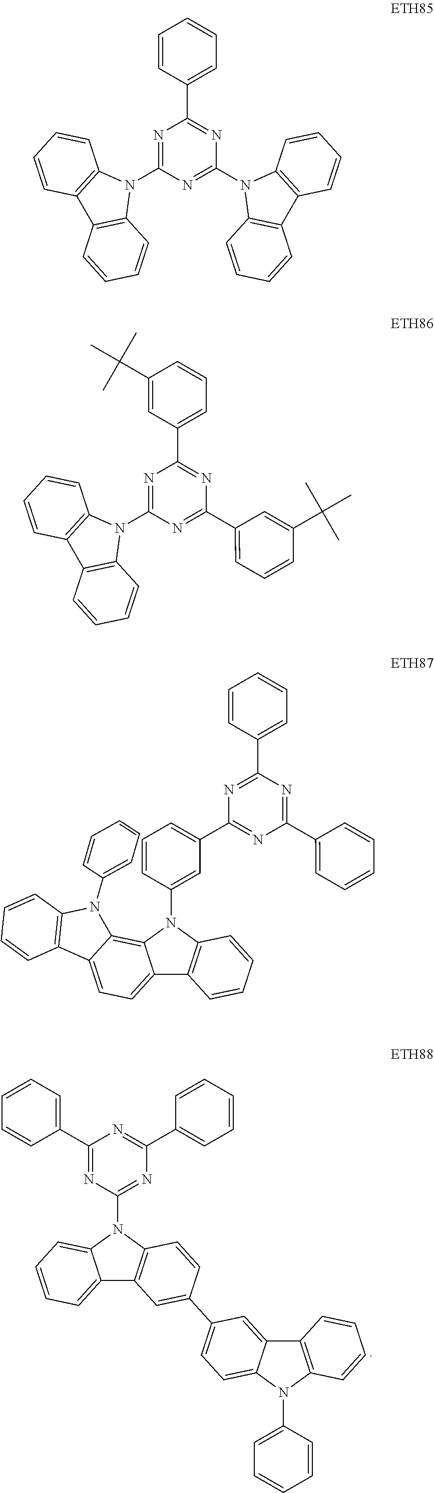 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1 ; c1ccc(-c2nc(-c3ccccc3)nc(-c3cccc(-n4c5ccccc5c5ccc6c7ccccc7n(-c7ccccc7)c6c54)c3)n2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

In Compound Group 3, D represents a deuterium atom, and Ph represents an unsubstituted phenyl group.

In an embodiment, the emission layer EML may include the second compound and the third compound, and the second compound and the third compound may form an exciplex. In the emission layer EML, an exciplex may be formed by a hole transport host and an electron transport host. A triplet energy level of the exciplex formed by a hole transport host and an electron transport host may correspond to a difference between a lowest unoccupied molecular orbital (LUMO) energy level of the electron transport host and a highest occupied molecular orbital (HOMO) energy level of the hole transport host.

For example, an absolute value of a triplet energy level (T1) of the exciplex formed by the hole transport host and the electron transport host may be in a range of about 2.4 eV to about 3.0 eV. The triplet energy level of the exciplex may be a value that is less than an energy gap of each host material. The exciplex may have a triplet energy level equal to or less than about 3.0 eV, which is an energy gap between the hole transport host and the electron transport host.

In an embodiment, the emission layer EML may further include a fourth compound, in addition to the first compound, the second compound, and the third compound as described above. The fourth compound may be used as a phosphorescent sensitizer in the emission layer EML. Energy may be transferred from the fourth compound to the first compound, thereby implementing light emission.

In an embodiment, the emission layer EML may further include, as a fourth compound, an organometallic complex that includes platinum (Pt) as a central metal atom and ligands linked to the central metal atom. In an embodiment, the emission layer EML may include a fourth compound represented by Formula D-1:

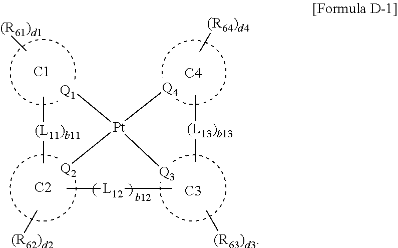

In Formula D-1, Q₁ to Q₄ may each independently be C or N.

In Formula D-1, C1 to C4 may each independently be a substituted or unsubstituted hydrocarbon ring having 5 to 30 ring-forming carbon atoms or a substituted or unsubstituted heterocycle having 2 to 30 ring-forming carbon atoms.

In Formula D-1, L₁₁ to L₁₃ may each independently be a direct linkage,

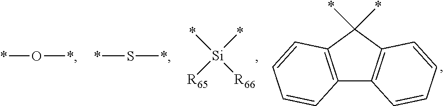

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃,

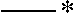 [SMILES: *C]

represents a bond to one of C1 to C4.

In Formula D-1, b11 to b13 may each independently be 0 or 1. If b11 is 0, C1 and C2 may not be directly linked to each other. If b12 is 0, C2 and C3 may not be directly linked to each other. If b13 is 0, C3 and C4 may not be directly linked to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₆₁ to R₆₆ may each independently be a substituted or unsubstituted methyl group or a substituted or unsubstituted t-butyl group.

In Formula D-1, d1 to d4 may each independently be an integer from 0 to 4. In Formula D-1, if d1 to d4 are each 0, the fourth compound may not be substituted with R₆₁ to R₆₄, respectively. A case where d1 to d4 are each 4 and four groups of each of R₆₁ to R₆₄ are all hydrogen atoms may be the same as a case where d1 to d4 are each 0. When d1 to d4 are each 2 or more, multiple groups of each of R₆₁ to R₆₄ may all be the same, or at least one thereof may be different from the remainder.

In an embodiment, in Formula D-1, C1 to C4 may each independently be a substituted or unsubstituted hydrocarbon ring or a substituted or unsubstituted heterocycle that is represented by one of Formula C-1 to Formula C-4:

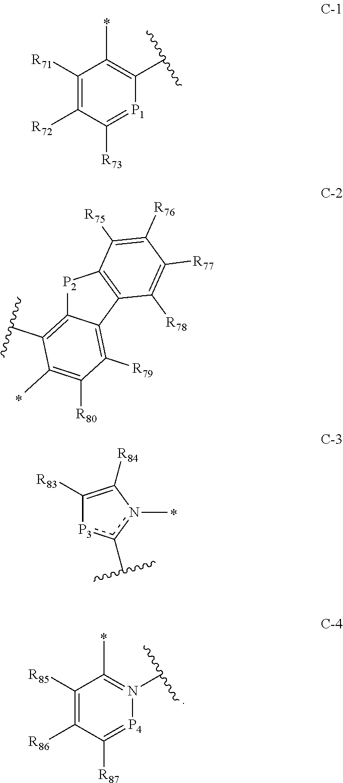

In Formula C-1 to Formula C-4, P₁ may be

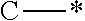 [SMILES: *C]

or C(R₇₄), P₂ may be

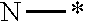 [SMILES: *N]

or N(R₈₁), P₃ may be

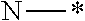 [SMILES: *N]

or N(R₈₂), and P₄ may be

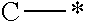 [SMILES: *C]

or C(R₈₈). In Formula C-1 to Formula C-4, R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula C-1 to Formula C-4,

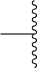

represents a bond to Pt, which is a central metal atom, and,

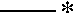 [SMILES: *C]

represents a bond to a neighboring cyclic group (C1 to C4) or to a linking moiety (L₁₁ to L₁₃).

In an embodiment, the emission layer EML may include the first compound represented by Formula 1, and at least one of the second compound, the third compound, and the fourth compound. In an embodiment, the emission layer EML may include the first compound, the second compound, and the third compound. In the emission layer EML, the second compound and the third compound may form an exciplex, and energy may be transferred from the exciplex to the first compound, thereby implementing light emission.

In another embodiment, the emission layer EML may include the first compound, the second compound, the third compound, and the fourth compound. In the emission layer EML, the second compound and the third compound may form an exciplex, and energy may be transferred from the exciplex to the fourth compound and to the first compound, thereby implementing light emission. In an embodiment, the fourth compound may be a sensitizer. In the light-emitting element ED, the fourth compound included in the emission layer EML may serve as a sensitizer that transfers energy from a host (for example, an exciplex host) to the first compound, which is a light emitting dopant. For example, the fourth compound, which serves as an auxiliary dopant, may accelerate energy transfer to the first compound, which is a light emitting dopant, thereby increasing an emission ratio of the first compound. Therefore, luminous efficiency of the emission layer EML may improve. When energy transfer to the first compound increases, excitons formed in the emission layer EML may not accumulate and may emit light rapidly, so that deterioration of the device may be reduced. Therefore, the service life of the light-emitting element ED according to an embodiment may increase.

The light-emitting element ED may include the first compound, the second compound, the third compound, and the fourth compound, and the emission layer EML may include a combination of two host materials and two dopant materials. In the light-emitting element ED, the emission layer EML may include the second compound and the third compound, which are two different hosts, the first compound that emits delayed fluorescence, and the fourth compound that includes an organometallic complex, so that the light-emitting element ED may exhibit excellent luminous efficiency characteristics.

In an embodiment, the fourth compound represented by Formula D-1 may be selected from Compound Group 4. In an embodiment, in the light-emitting element ED, the fourth compound may include at least one compound selected from Compound Group 4:

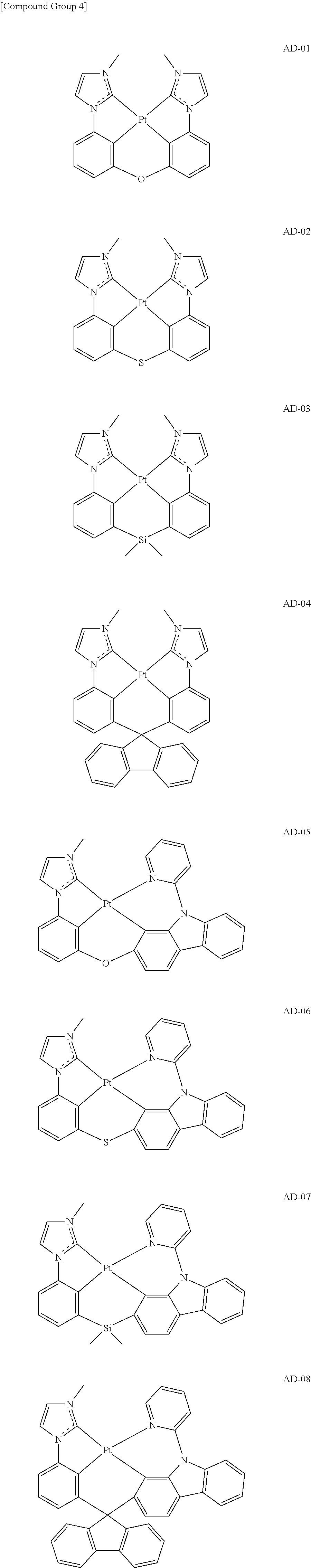

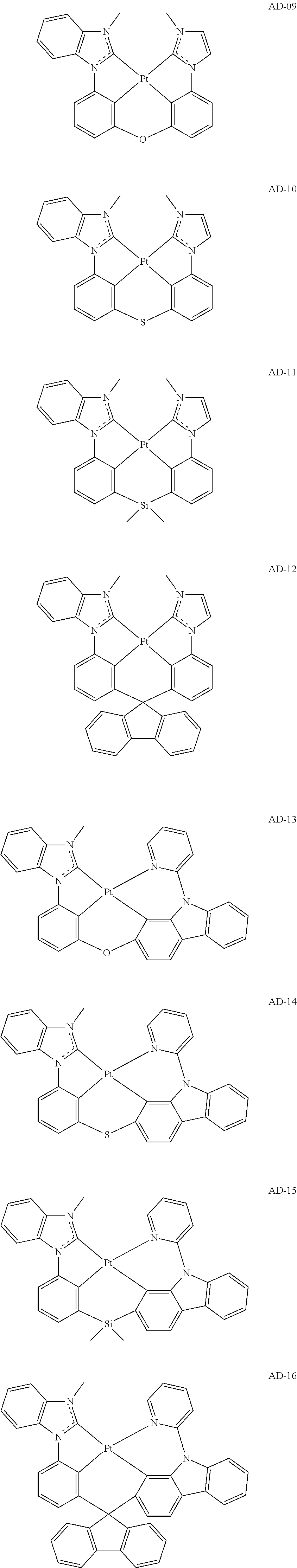

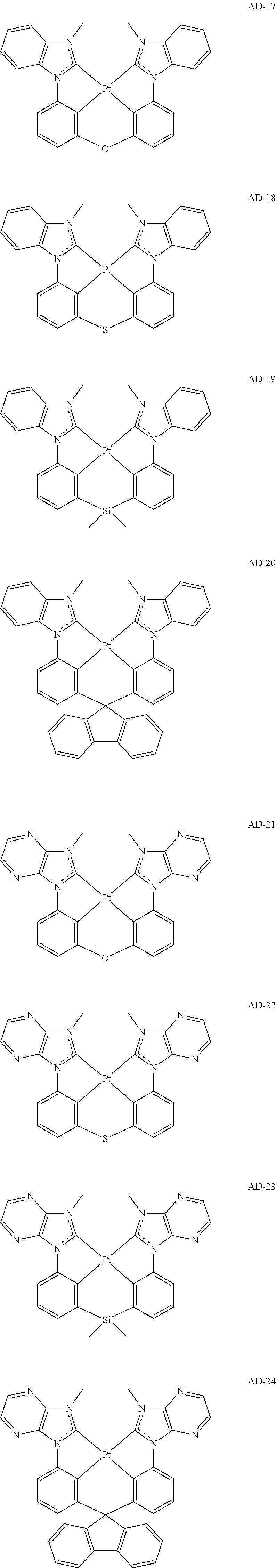

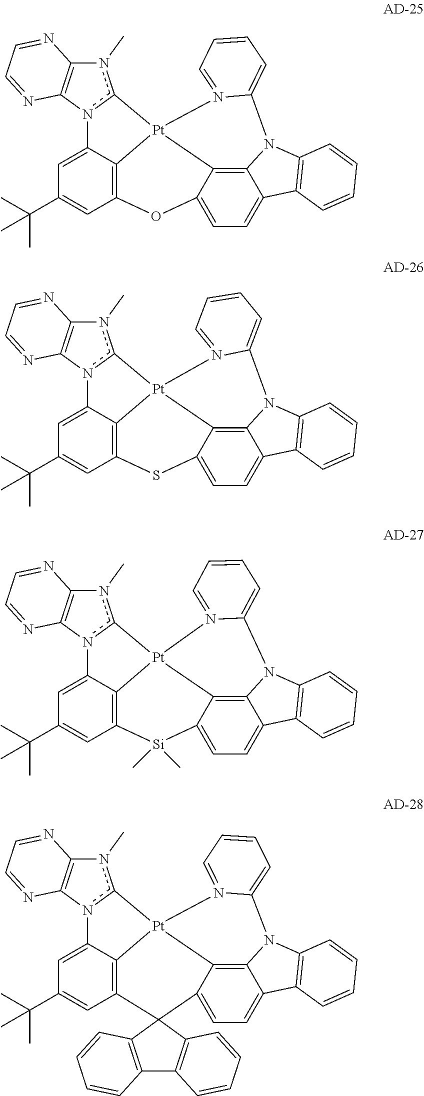

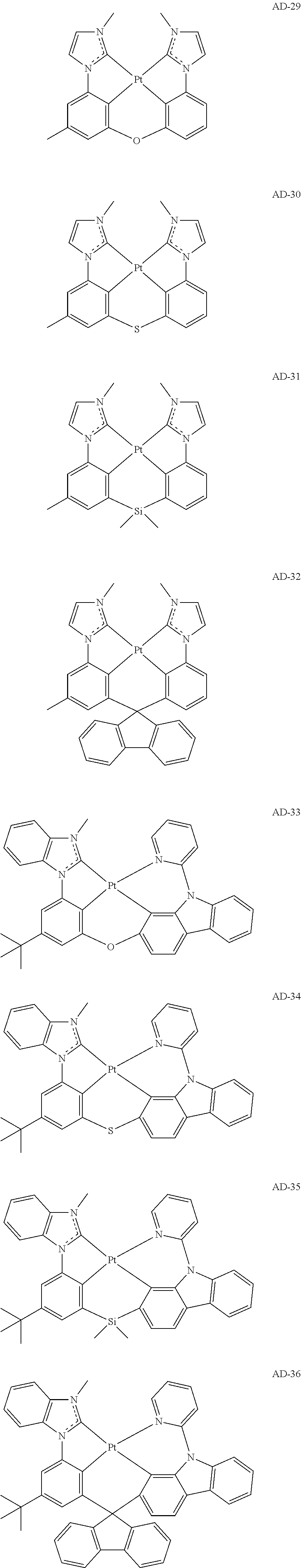

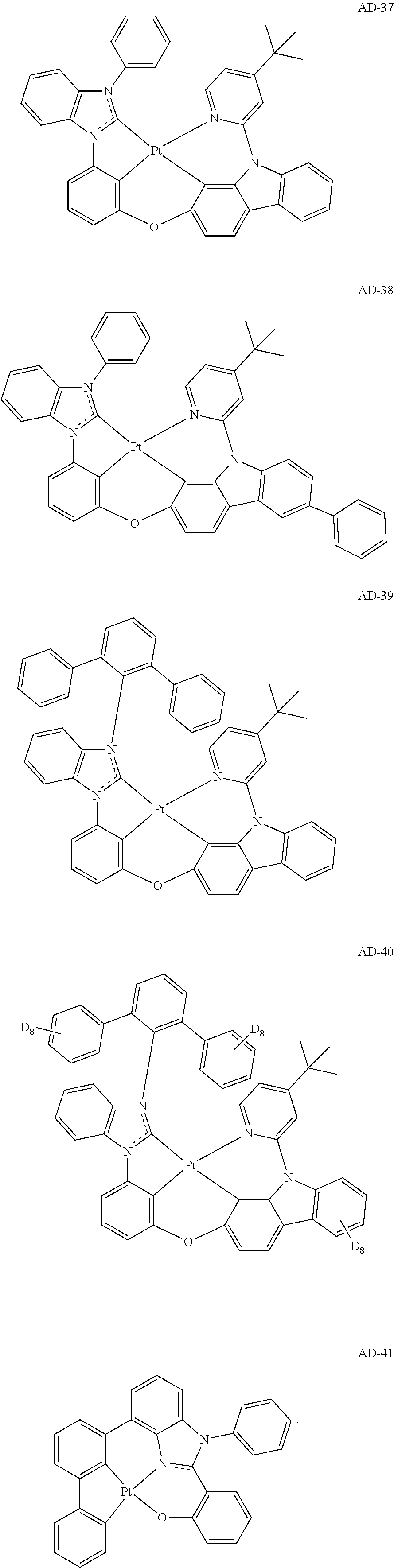

In Compound Group 4, D represents a deuterium atom.

In an embodiment, the light-emitting element ED may include multiple emission layers. The multiple emission layers may be provided as a stack, so that the light-emitting element ED may emit white light. The light-emitting element ED including multiple emission layers may have a tandem structure. When the light-emitting element ED includes multiple emission layers, at least one emission layer EML may each independently include a first compound represented by Formula 1. When the light-emitting element ED includes multiple emission layers, at least one emission layer EML may include the first compound, the third compound, and the fourth compound, or at least one emission layer EML may include the first compound, the second compound, the third compound, and the fourth compound.

When the emission layer EML includes the first compound, the second compound, the third compound, and the fourth compound, an amount of the first compound may be in a range of about 0.1 wt % to about 5 wt %, with respect to a total weight of the first compound, the second compound, the third compound, and the fourth compound. However, embodiments are not limited thereto. When an amount of the first compound satisfies the range described above, energy transfer from the second compound and the third compound to the first compound may increase, so that luminous efficiency and device service life may increase.

In the emission layer EML, a combined amount of the second compound and the third compound may be the remainder of the total weight of the first compound, the second compound, the third compound, and the fourth compound, excluding the amount of the first compound. For example, a combined amount of the second compound and the third compound in the emission layer EML may be in a range of about 65 wt % to about 95 wt %, with respect to a total weight of the first compound, the second compound, the third compound, and the fourth compound.

Within the combined amount of the second compound and the third compound, a weight ratio of the second compound to the third compound may be in a range of about 3:7 to about 7:3.

When the amounts of the second compound and the third compound satisfy the above-described ranges and ratios, charge balance characteristics of the emission layer EML may improve, and luminous efficiency and device service life may increase. When the amounts of the second compound and the third compound deviate from the above-described ranges and ratios, charge balance in the emission layer EML may not be achieved, so that luminous efficiency may be reduced and the element may readily deteriorate.

When the emission layer EML includes the fourth compound, an amount of the fourth compound may be in a range of about 10 wt % to about 30 wt %, with respect to a total weight of the first compound, the second compound, the third compound, and the fourth compound. However, embodiments are not limited thereto. When an amount of the fourth compound satisfies the above-described range, energy transfer from a host (for example, an exciplex host) to the first compound, which is a light emitting dopant, may increase, so that an emission ratio may improve, and thus luminous efficiency of the emission layer EML may be improved. When the amounts of the first compound, the second compound, the third compound, and the fourth compound included in the emission layer EML satisfy the above-described ranges and ratios, excellent luminous efficiency and long service life may be achieved.

In the light-emitting element ED, the emission layer EML may include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light-emitting element ED according to embodiments as shown in FIG. 3 to FIG. 6, the emission layer EML may include hosts and dopants of the related art, in addition to the host and dopant as described above. In an embodiment, the emission layer EML may include a compound represented by Formula E-1. The compound represented by Formula E-1 may be used as a host material for a fluorescent light-emitting element. In an embodiment, the emission layer EML may include the polycyclic compound according to an embodiment as a dopant material and the compound represented by Formula E-1 as a host material:

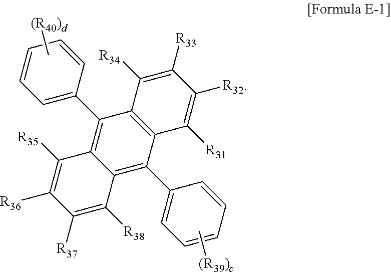

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E21:

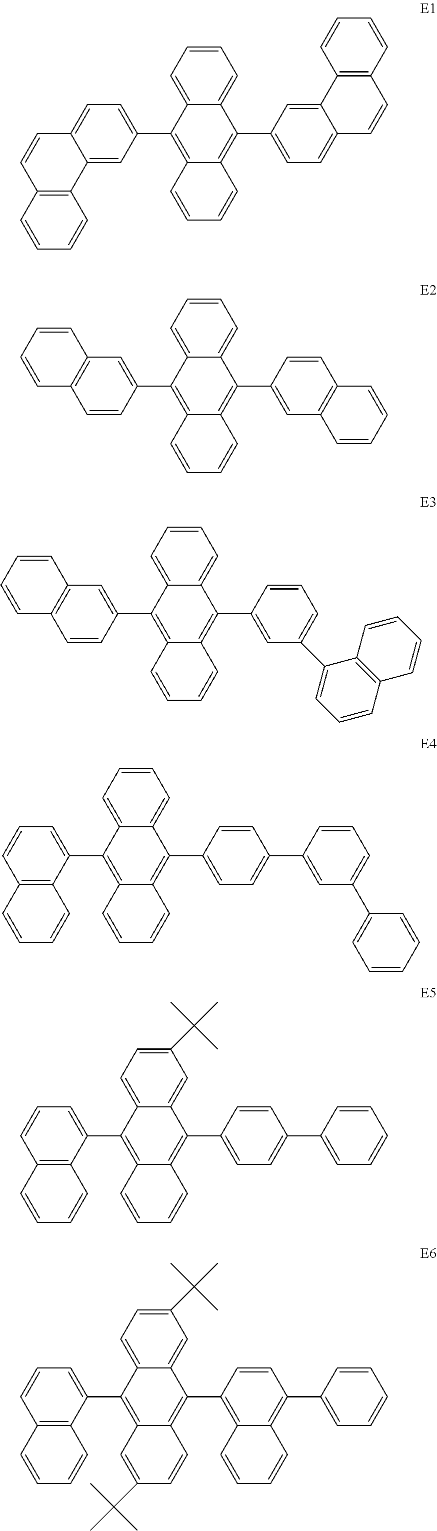

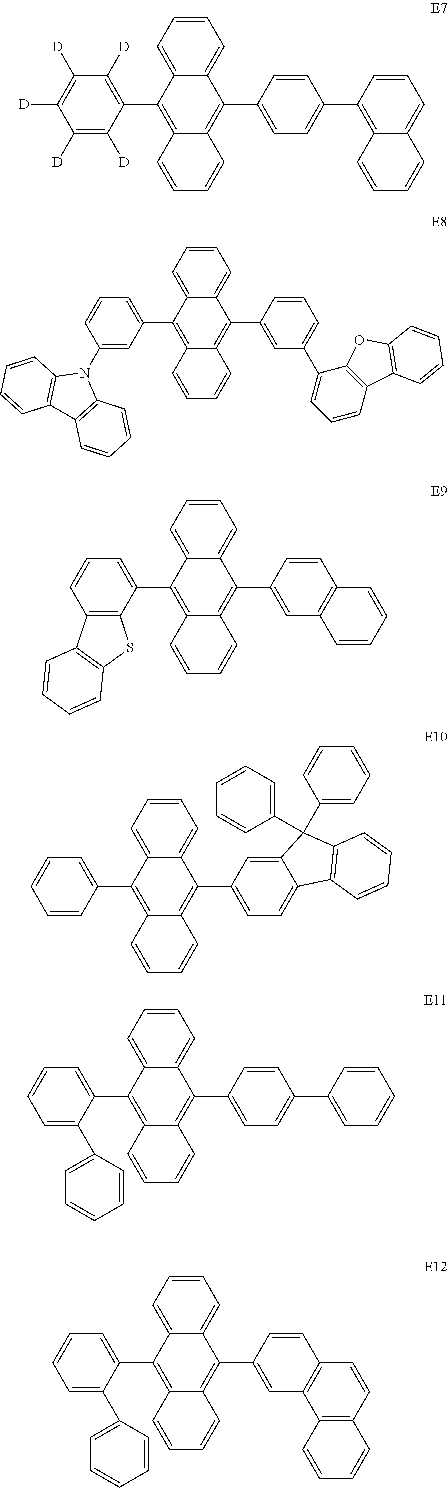

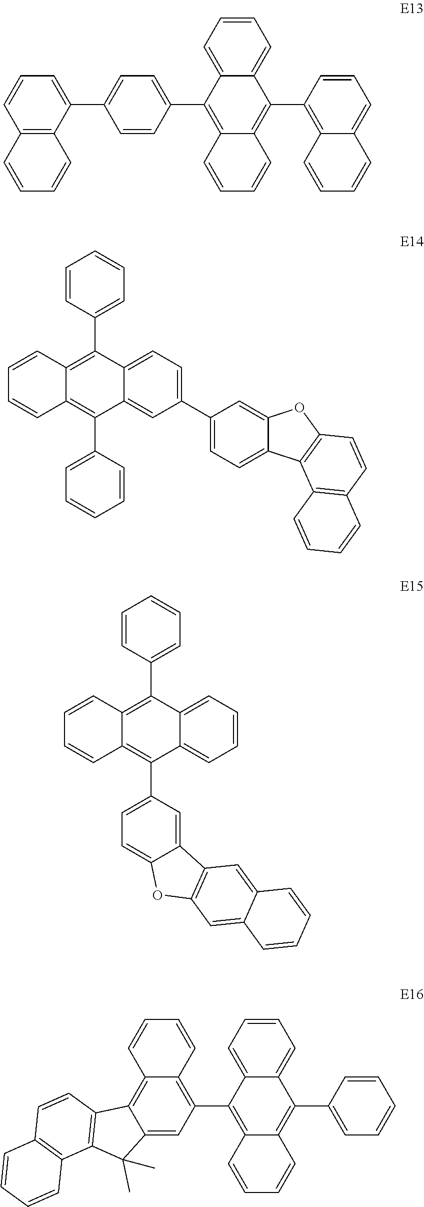

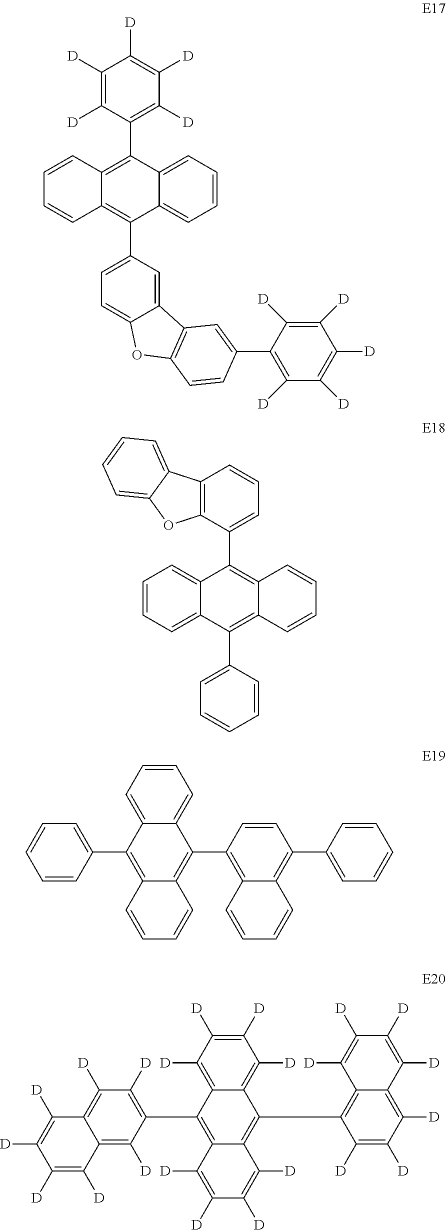

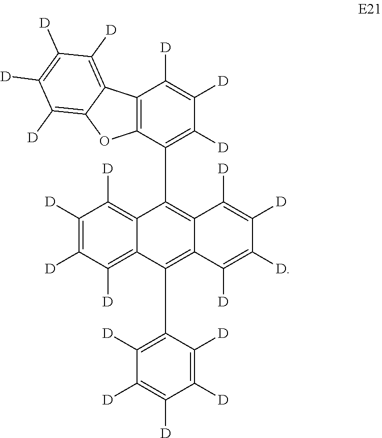

In an embodiment, the emission layer EML may include a compound represented by Formula E-2a or Formula E-2b. The compound represented by Formula E-2a or Formula E-2b may be used as a host material for a phosphorescent light emitting element.

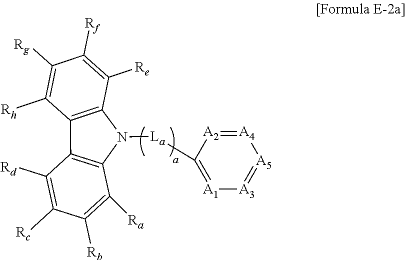

In Formula E-2a, a may be an integer from 0 to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, multiple Lₐ may each independently be a substituted or unsubstituted arylene group having 6 to 30 ring-forming carbon atoms or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, Rₐ to Rᵢ may be bonded to an adjacent group to form a hydrocarbon ring or a heterocycle containing N, O, S, etc., as a ring-forming atom.

In Formula E-2a, two or three of A₁ to A₅ may each be N, and the remainder of A₁ to A₅ may each independently be C(Rᵢ).

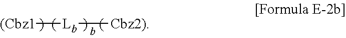

In Formula E-2b, Cbz1 and Cbz2 may each independently be an unsubstituted carbazole group or a carbazole group substituted with an aryl group having 6 to 30 ring-forming carbon atoms. In Formula E-2b, Le may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10. When b is 2 or more, multiple Le may each independently be a substituted or unsubstituted arylene group having 6 to 30 ring-forming carbon atoms or a substituted or unsubstituted heteroarylene group having 2 to 30 ring-forming carbon atoms.

In an embodiment, the compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2:

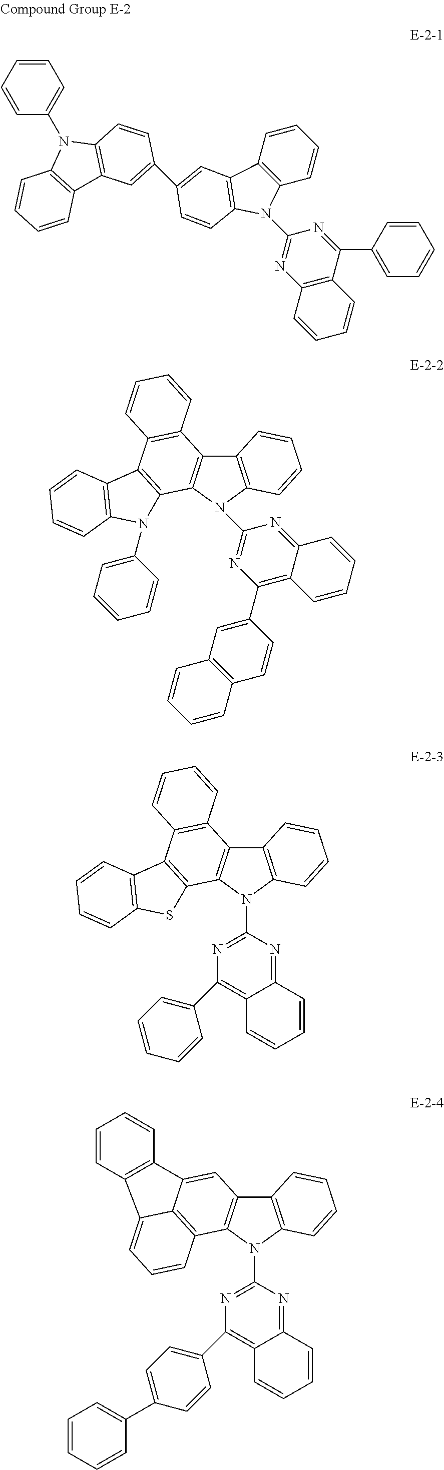

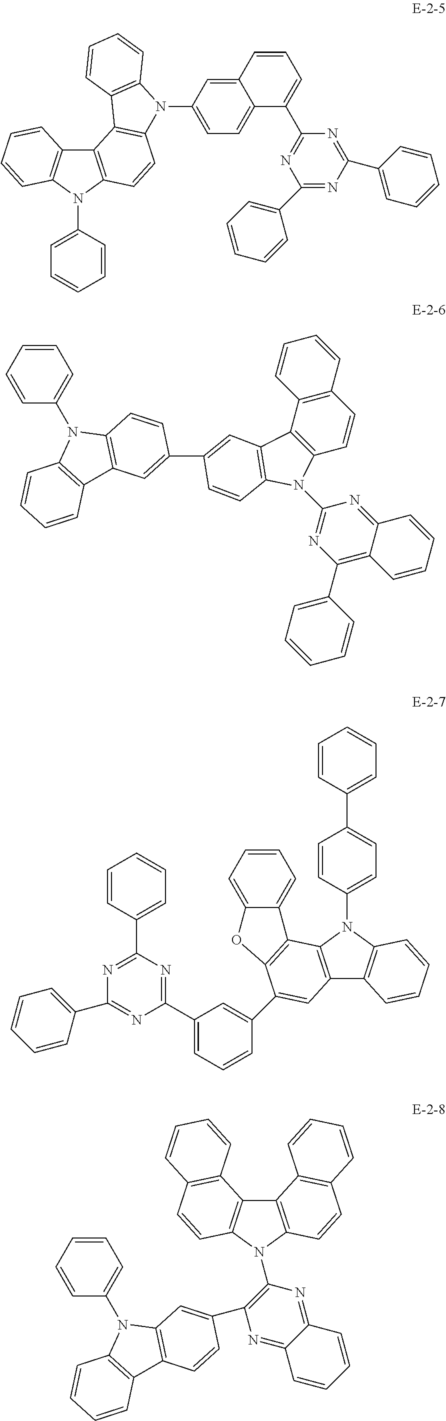 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

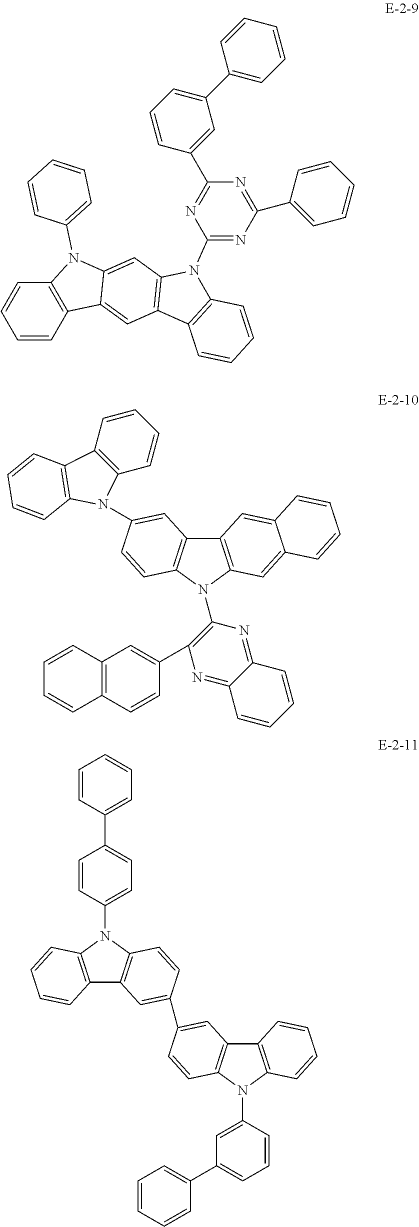 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc4ccccc4nc3-n3c4ccc(-n5c6ccccc6c6ccccc65)cc4c4cc5ccccc5cc43)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

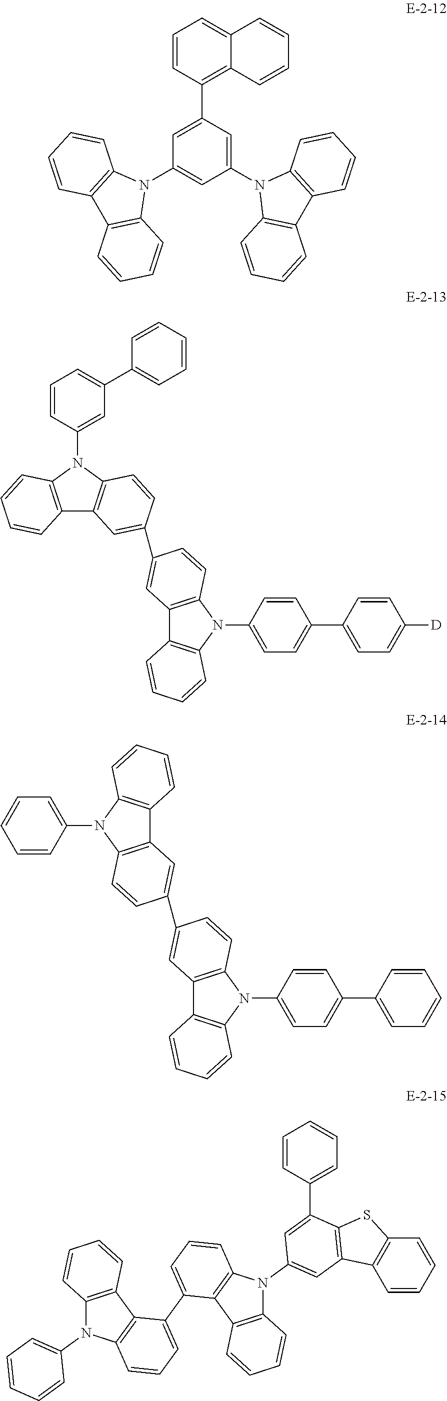 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

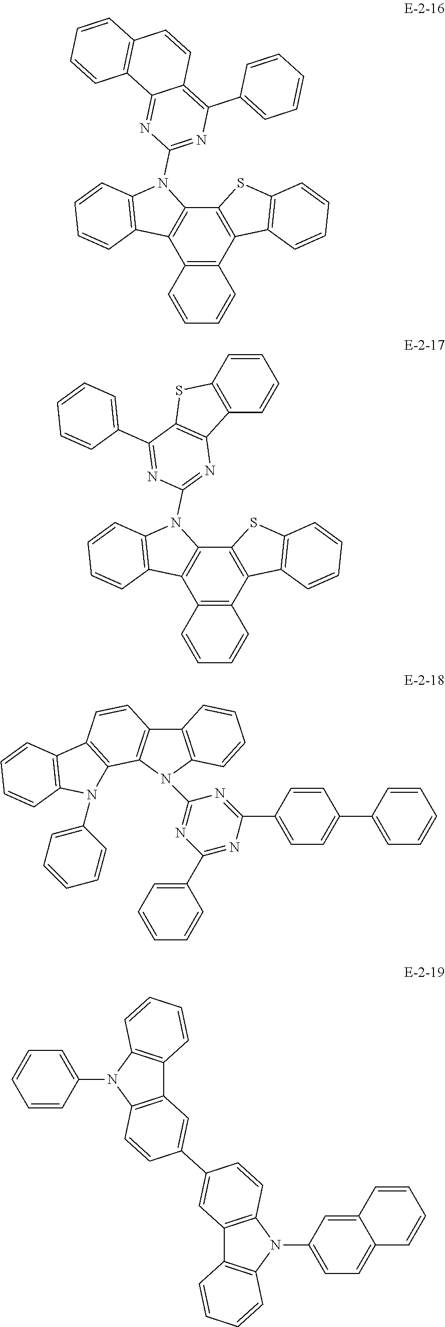

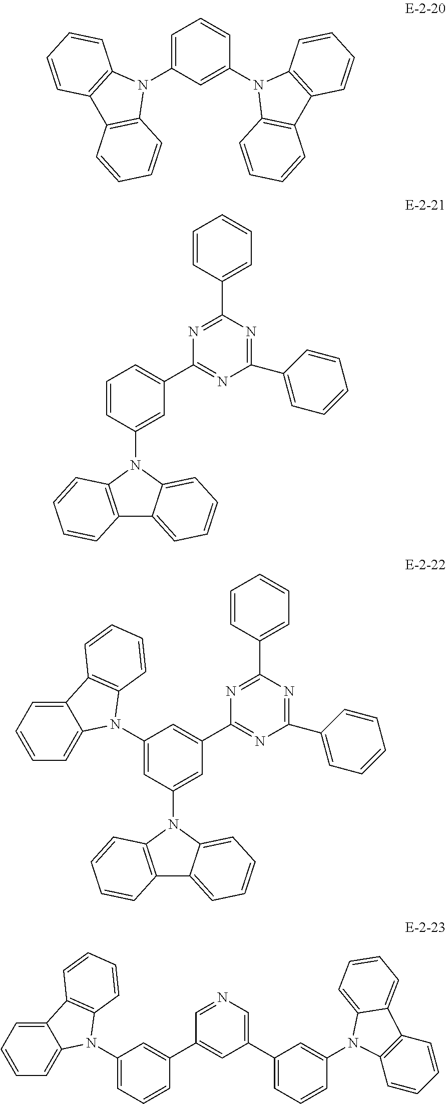 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

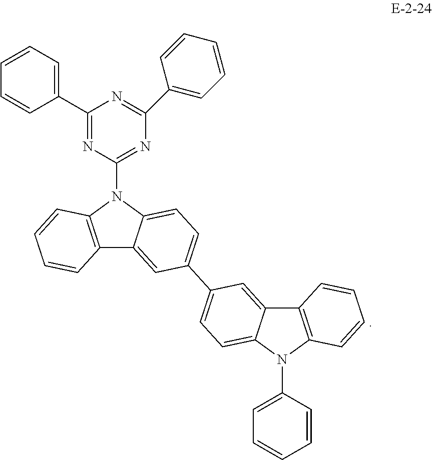 [SMILES: c1ccc(-c2nc(-c3ccccc3)nc(-n3c4ccccc4c4cc(-c5ccc6c(c5)c5ccccc5n6-c5ccccc5)ccc43)n2)cc1]

In embodiments, the emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be used as a host material.

In an embodiment, the emission layer EML may include a compound represented by Formula M-a. The compound represented by Formula M-a may be used as a phosphorescent dopant material.

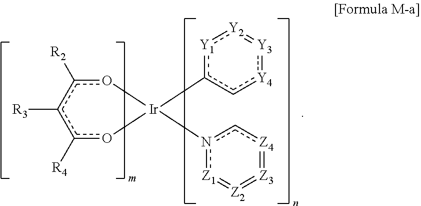

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In Formula M-a, m may be 0 or 1, and n may be 2 or 3. In Formula M-a, when m is 0, n may be 3, and when m is 1, n may be 2.

In an embodiment, the compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25:

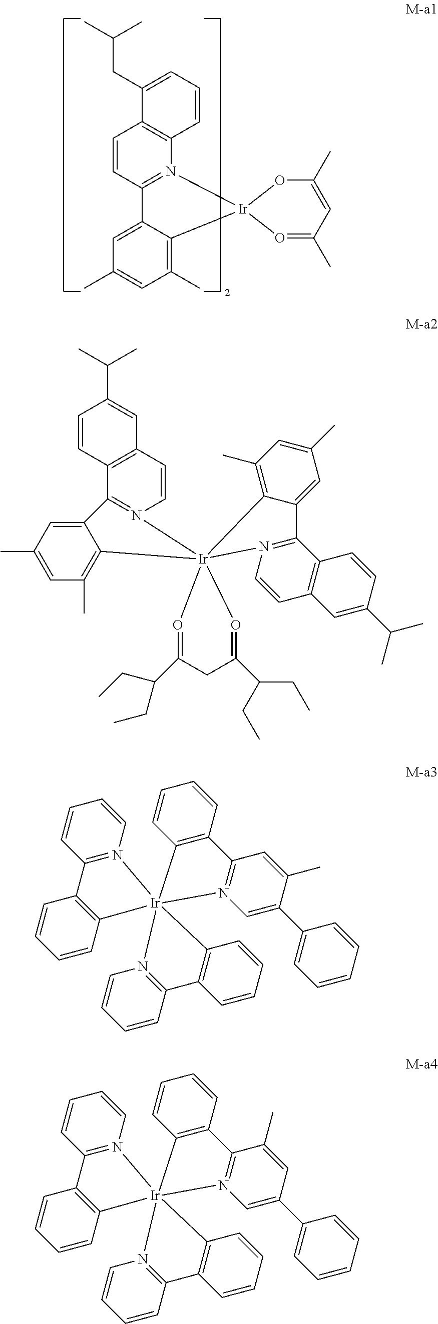

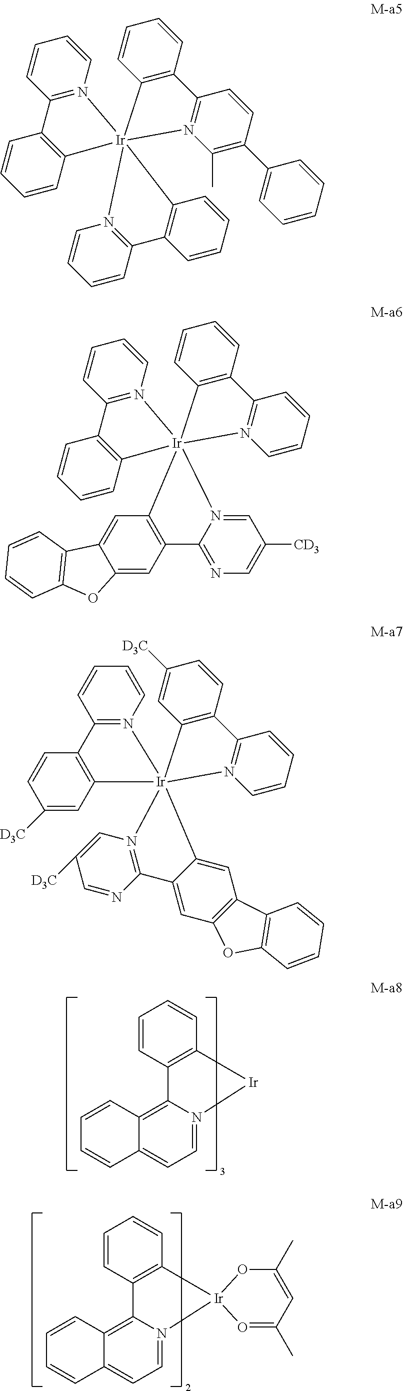

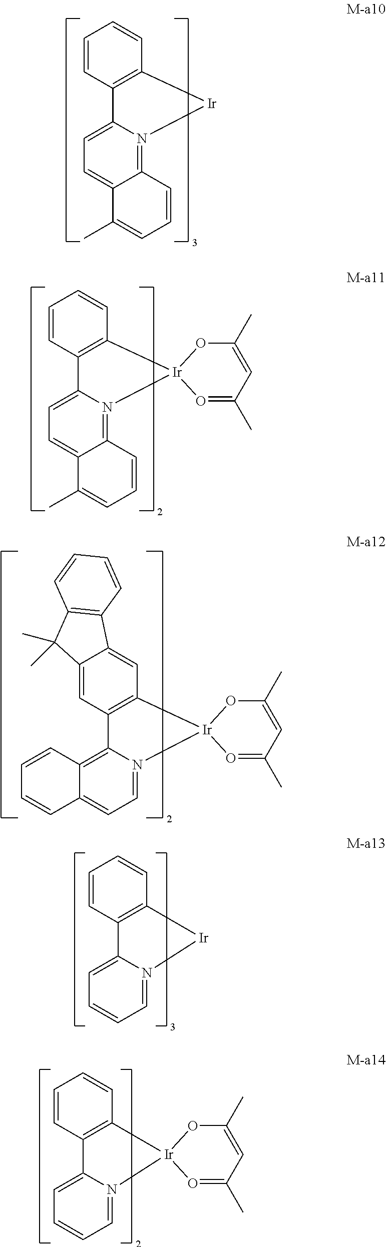

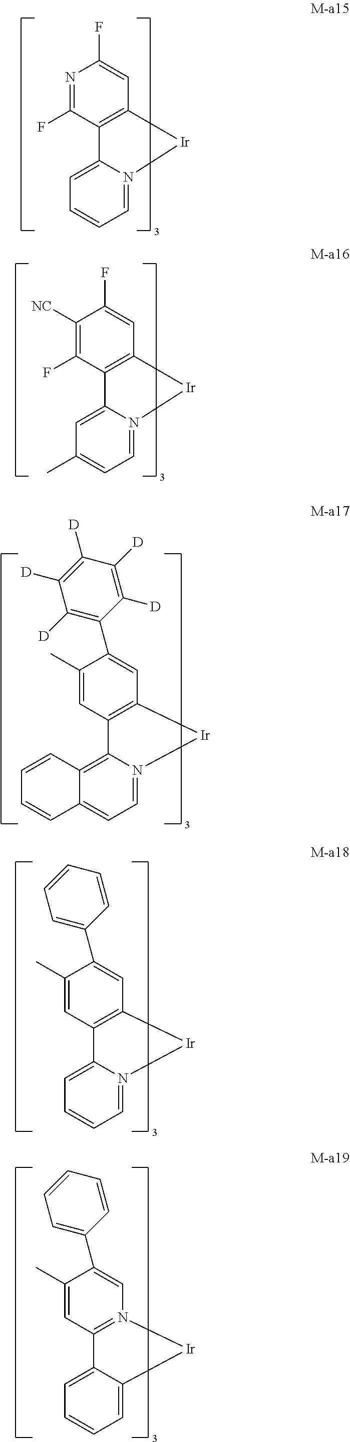

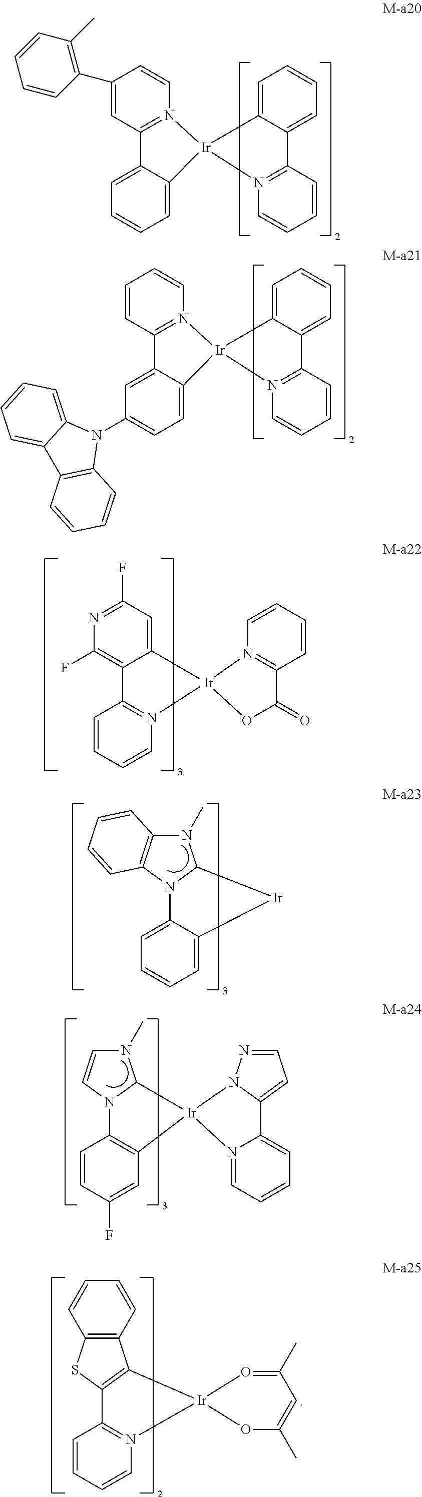

In an embodiment, the emission layer EML may include a compound represented by one of Formula F-a to Formula F-c. The compound represented by one of Formula F-a to Formula F-c may be used as a fluorescence dopant material.

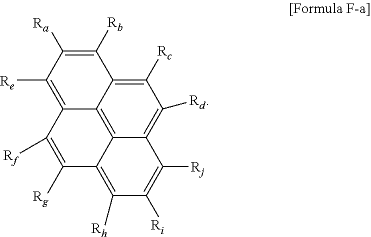

In Formula F-a, two of Rₐ to Rⱼ may each independently be substituted with a group represented by

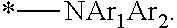

The remainder of Rₐ to Rⱼ that are not substituted with the group represented by

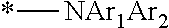

may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by

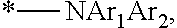

Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ and Ar₂ may each independently be a heteroaryl group containing O or S as a ring-forming atom.

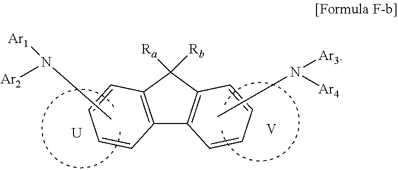

In Formula F-b, Rₐ and Rb may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ to Ar₄ may each independently be a heteroaryl group containing O or S as a ring-forming atom.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms.

In Formula F-b, the number of rings represented by U and V may each independently be 0 or 1. When the number of U or V is 1, a fused ring may be present at a portion respectively indicated by U or V, and when the number of U or V is 0, a fused ring may not be present at the portion respectively indicated by U or V. When the number of U is 0 and the number of V is 1, or when the number of U is 1 and the number of V is 0, a fused ring having the fluorene core of Formula F-b may be a cyclic compound having four rings. When the number of U and V is each 0, a fused ring having the fluorene core of Formula F-b may be a cyclic compound having three rings. When the number of U and V is 1, a fused ring having the fluorene core of Formula F-b may be a cyclic compound having five rings.

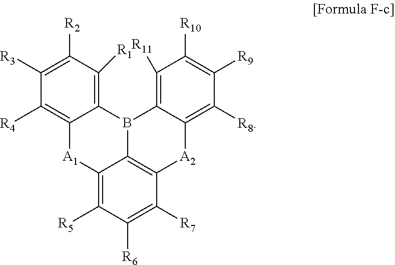

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula F-c, A₁ and A₂ may each independently be bonded to a substituent of an adjacent ring to form a fused ring. For example, when A₁ and A₂ are each independently N(Rₘ), A₁ may be bonded to R₄ or R₅ to form a ring, and/or A₂ may be bonded to R₇ or R₈ to form a ring.

In an embodiment, the emission layer EML may further include, as a dopant material of the related art, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi)), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), etc.

The emission layer EML may further include a phosphorescence dopant material of the related art. For example, a metal complex that includes iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2′) picolinato (FIrpic), bis(2,4-difluorophenylpyridinato)-tetrakis(1-pyrazolyl)borate iridium(III) (FIr6), or platinum octaethyl porphyrin (PtOEP) may be used as a phosphorescent dopant. However, embodiments are not limited thereto.

In embodiments, the emission layer EML may include a quantum dot. In the specification, a quantum dot may be a crystal of a semiconductor compound. A quantum dot may emit light of various emission wavelengths, depending on a size of the crystal. A quantum dot may emit light of various emission wavelengths by adjusting an elemental ratio of a quantum dot compound.

A quantum dot may have a diameter, for example, in a range of about 1 nm to about 10 nm.

The quantum dot may be synthesized by processes such as a wet chemical process, an organic metal chemical vapor deposition process, a molecular beam epitaxy process, or similar processes.

In a wet chemical process, an organic solvent and a precursor material are mixed to grow a quantum dot particle crystal. When the crystal grows, the organic solvent may naturally serve as a dispersant, which coordinates on a surface of the quantum dot crystal, and may adjust the growth of the crystal. Therefore, the wet chemical process may control the growth of the quantum dot particle through an and lower cost process than vapor deposition methods such as metal organic chemical vapor deposition (MOCVD) or molecular beam epitaxy (MBE) and.

The quantum dot may include a Group II-VI compound, a Group III-V compound, a Group III-VI compound, a Group 1-III-VI compound, a Group IV-VI compound, Group II-IV-V compound, a Group IV element, a Group IV compound, or a combination thereof.

Examples of a Group II-VI compound may include: a binary compound such as CdSe, CdTe, CdS, ZnS, ZnSe, ZnTe, ZnO, HgS, HgSe, HgTe, MgSe, MgS, and a mixture thereof; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound such as HgZnTeS, CdZnSeS, CdZnSeTe, CdZnSTe, CdHgSeS, CdHgSeTe, CdHgSTe, HgZnSeS, HgZnSeTe, and a mixture thereof; and any combination thereof. In an embodiment, a Group II-VI compound may further include a Group I metal and/or a Group IV element. Examples of a Group 1-II-VI compound may include CuZnS. Examples of a Group II-IV-VI compound may include ZnSnS, etc.

Examples of a Group I-II-IV-VI compound may include a quaternary compound such as Cu₂ZnSnS₂, Cu₂ZnSnS₄, Cu₂ZnSnSe₄, and a mixture thereof.

Examples of a Group III-VI compound may include: a binary compound such as In₂S₃ and In₂Se₃; a ternary compound such as InGaS₃ and InGaSe₃; and any combination thereof.

Examples of a Group 1-III-VI compound may include a ternary compound such as AgInS, AgInS₂, CuInS, CuInS₂, AgGaS₂, CuGaS₂, CuGaO₂, AgGaO₂, AgAlO₂, and a mixture thereof; a quaternary compound such as AgInGaS, AgInGaS₂, AgInGaSe, AgInGaSe₂, CuInGaS, and CuInGaS₂; and any combination thereof.

Examples of a Group III-V compound may include: a binary compound such as GaN, GaP, GaAs, GaSb, AlN, AlP, AlAs, AlSb, InN, InP, InAs, InSb, and a mixture thereof; a ternary compound such as GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; and any combination thereof. In an embodiment, a Group III-V compound may further include a Group II metal. Examples of a Group III-II-V compound may include InZnP, etc.

Examples of a Group IV-VI compound may include: a binary compound such as SnS, SnSe, SnTe, PbS, PbSe, PbTe, and a mixture thereof; a ternary compound such as SnSeS, SnSeTe, SnSTe, PbSeS, PbSeTe, PbSTe, SnPbS, SnPbSe, SnPbTe, and a mixture thereof; a quaternary compound such as SnPbSSe, SnPbSeTe, SnPbSTe, and a mixture thereof; and any combination thereof. Examples of a Group II-IV-V compound may include a ternary compound such as ZnSnP, ZnSnP₂, ZnSnAs₂, ZnGeP₂, ZnGeAs₂, CdSnP₂, CdGeP₂, and mixtures thereof.

Examples of a Group IV element may include Si, Ge, and a mixture thereof. Examples of a Group IV compound may include a binary compound such as SiC, SiGe, and a mixture thereof.

Each element included in a compound, such as a binary compound, a ternary compound, or a quaternary compound, may be present in a particle at a uniform concentration distribution or at a non-uniform concentration distribution. For examples, a formula may indicate the elements that are included in a compound, but an elemental ratio of the compound may vary. For example, AgInGaS₂ may indicate AgInₓGa₁₋ₓS₂ (wherein x is a real number between 0 to 1).

In an embodiment, a quantum dot may have a core/shell structure in which a quantum dot surrounds another quantum dot. In case that a quantum dot has a core/shell structure, an interface between the core and the shell may have a concentration gradient in which the concentration of an element that is present in the shell decreases toward the core.

In embodiments, a quantum dot may have the above-described core/shell structure that includes a core containing nanocrystals and a shell surrounding the core. The shell of a quantum dot may serve as a protection layer that prevents chemical deformation of the core to maintain semiconductor properties, and/or may serve as a charging layer that imparts electrophoretic properties to the quantum dot. The shell may be a single layer or multiple layers. An example of a shell of a quantum dot may include a metal oxide, a non-metal oxide, a semiconductor compound, or a combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO; or a ternary compound such as MgAl₂O₄, CoFe₂O₄, NiFe₂O₄, and CoMn₂O₄, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

A quantum dot may have a full width at half maximum (FWHM) of an emission wavelength spectrum equal to or less than about 45 nm. For example, the quantum dot may have an FWHM of an emission wavelength spectrum equal to or less than about 40 nm. For example, the quantum dot may have an FWHM of an emission wavelength spectrum equal to or less than about 30 nm. Color purity or color reproducibility may be improved in any of the above ranges. Light emitted through a quantum dot may be emitted in all directions, so that a wide viewing angle may be improved.

The form of a quantum dot is not particularly limited, and may be any form used in the related art. For example, a quantum dot may have a spherical shape, a pyramidal shape, a multi-arm shape, or a cubic shape, or a quantum dot may be in the form of nanoparticles, nanotubes, nanowires, nanofibers, nanoplate particles, etc.

As a size of a quantum dot is adjusted or an elemental ratio of a quantum dot compound is adjusted, an energy band gap may be changed accordingly, so that light in various wavelength ranges may be obtained from a quantum dot emission layer. Therefore, when a quantum dot is adjusted as described above (such as by using different sizes of quantum dots or different elemental ratios of a quantum dot compound), a light-emitting element that emits light in various wavelengths may be implemented. For example, a size of a quantum dot or an elemental ratio of a quantum dot compound may be adjusted to emit red light, green light, and/or blue light. In an embodiment, quantum dots may be configured to emit white light by combining various colors of light.

In the light-emitting element ED according to embodiments as shown in each of FIGS. 3 to 6, the electron transport region ETR may be provided on the emission layer EML. The electron transport region ETR may include at least one of a hole blocking layer HBL, an electron transport layer ETL, and an electron injection layer EIL, but embodiments are not limited thereto.

The electron transport region ETR may have a structure consisting of a layer consisting of a single material, a structure consisting of a layer including different materials, or a structure including multiple layers including different materials.

For example, the electron transport region ETR may have a single-layered structure of an electron injection layer EIL or an electron transport layer ETL, or the electron transport region ETR may have a single-layered structure formed of an electron injection material and an electron transport material. In embodiments, the electron transport region ETR may have an electron transport layer ETL/electron injection layer EIL structure, or a hole blocking layer HBL/electron transport layer ETL/electron injection layer EIL structure, in which the layers of each structure may be stacked in its respective stated order from the emission layer EML, but embodiments are not limited thereto. The electron transport region ETR may have a thickness, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light-emitting element ED according to an embodiment, the electron transport region ETR may include a compound represented by Formula ET-2:

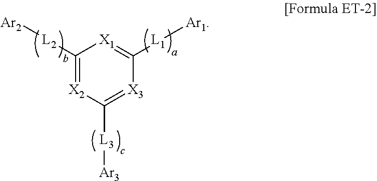

In Formula ET-2, at least one of X₁ to X₃ may each be N; and the remainder of X₁ to X₃ may each independently be C(Rₐ). In Formula ET-2, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-2, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each 2 or more, multiple groups of each of L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(biphenyl-4-yl)-5-(4-tert-butylphenyl)-4-phenyl-1,2,4-triazole (TAZ), 4-(naphthalen-1-yl)-3,5-diphenyl-4H-1,2,4-triazole (NTAZ), 2-(4-biphenyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), beryllium bis(benzoquinolin-10-olate) (Bebg₂), 9,10-di(naphthalene-2-yl)anthracene (ADN), 1,3-bis[3,5-di(pyridin-3-yl)phenyl]benzene (BmPyPhB), or a mixture thereof.

In an embodiment, the electron transport region ETR may include at least one of Compound ET1 to Compound ET38:

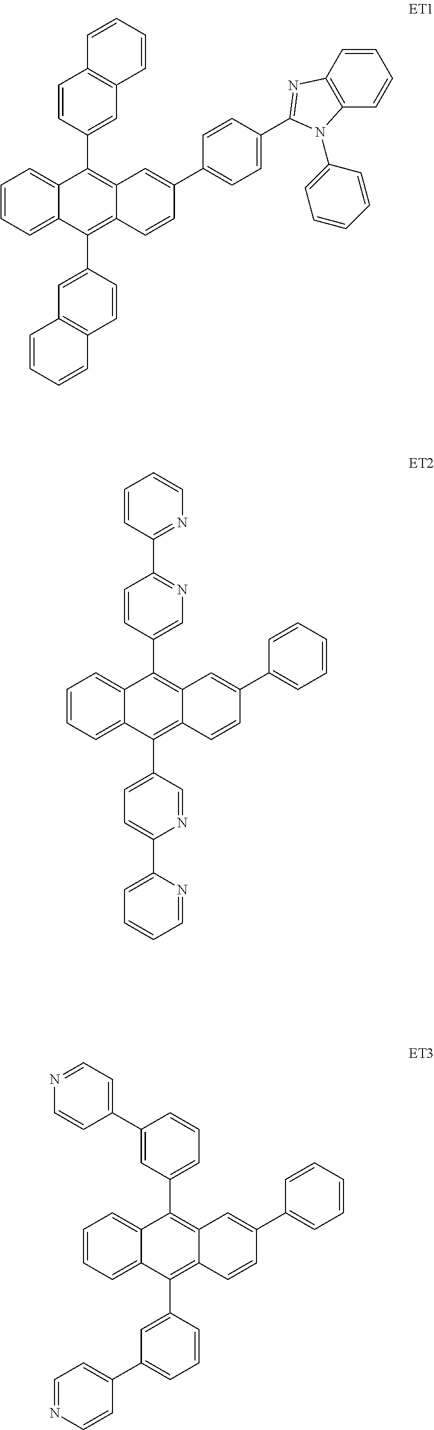 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

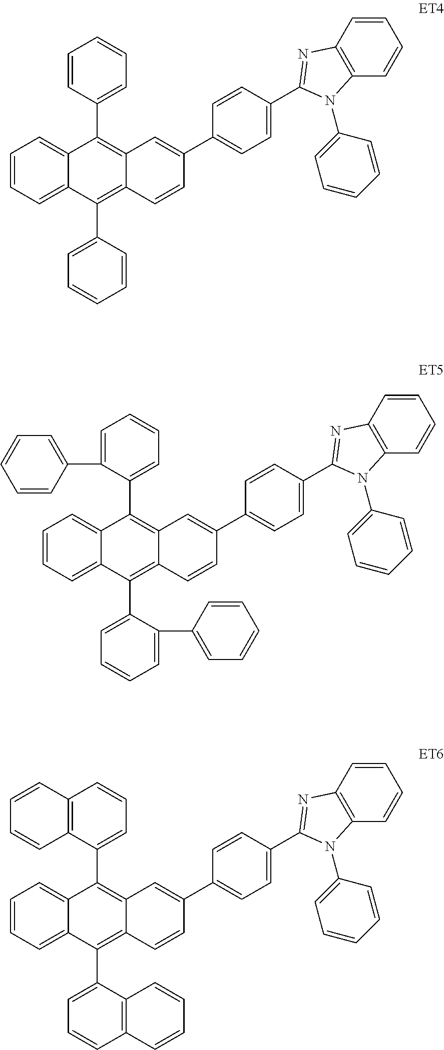 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

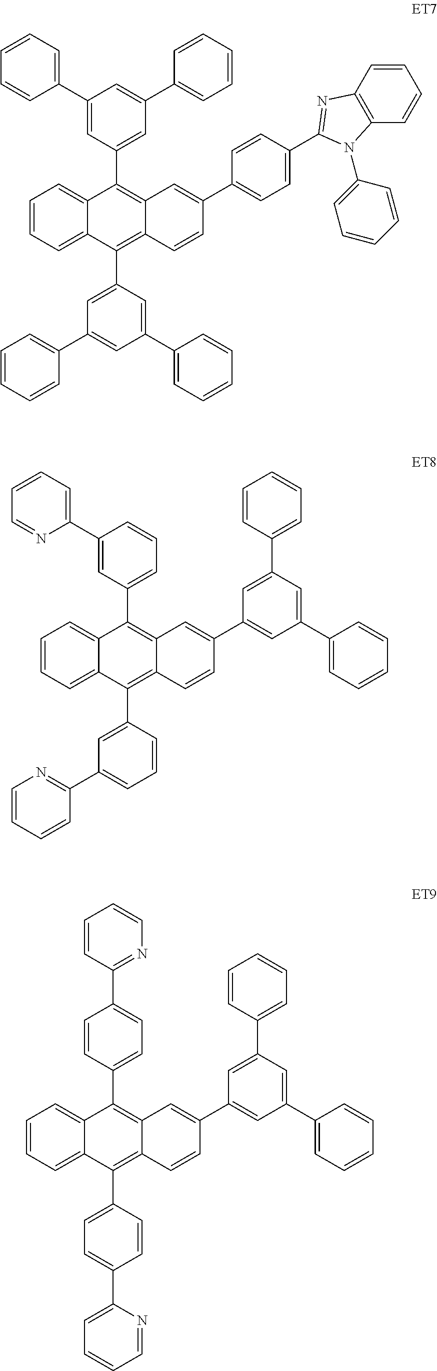 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

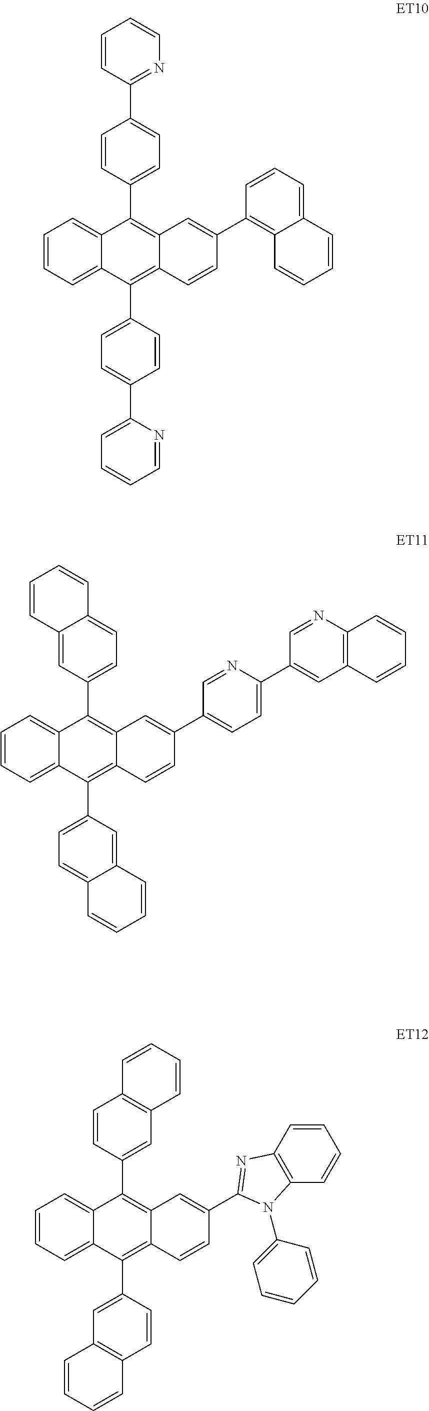 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

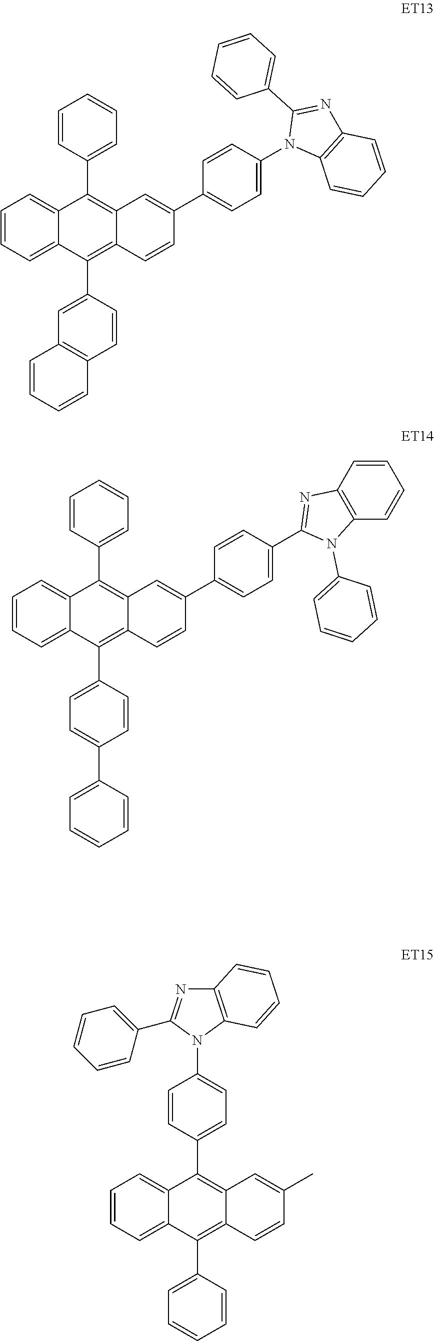 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5ccc(-c6nc7ccccc7n6-c6ccccc6)cc5)ccc34)cc2)cc1 ; Cc1ccc2c(-c3ccccc3)c3ccccc3c(-c3ccc(-n4c(-c5ccccc5)nc5ccccc54)cc3)c2c1]

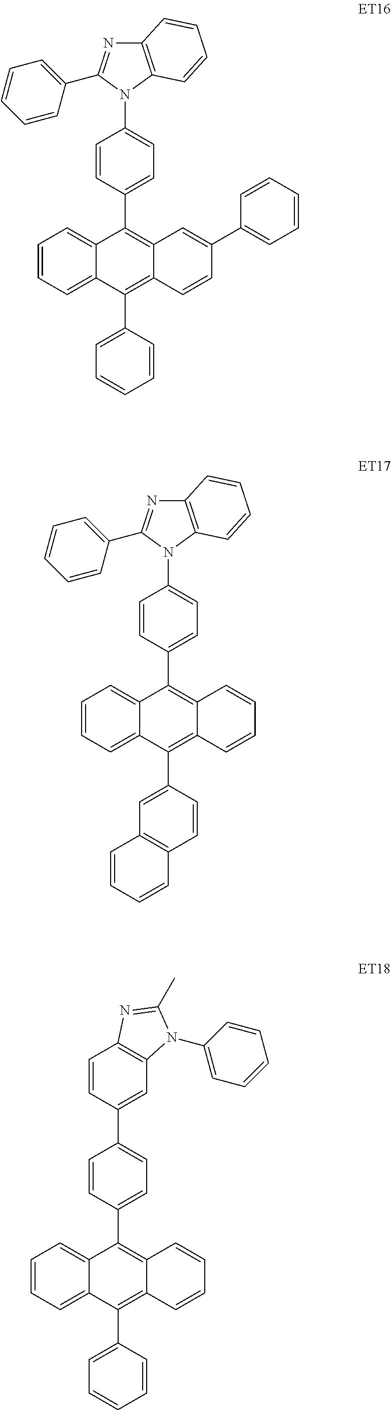 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

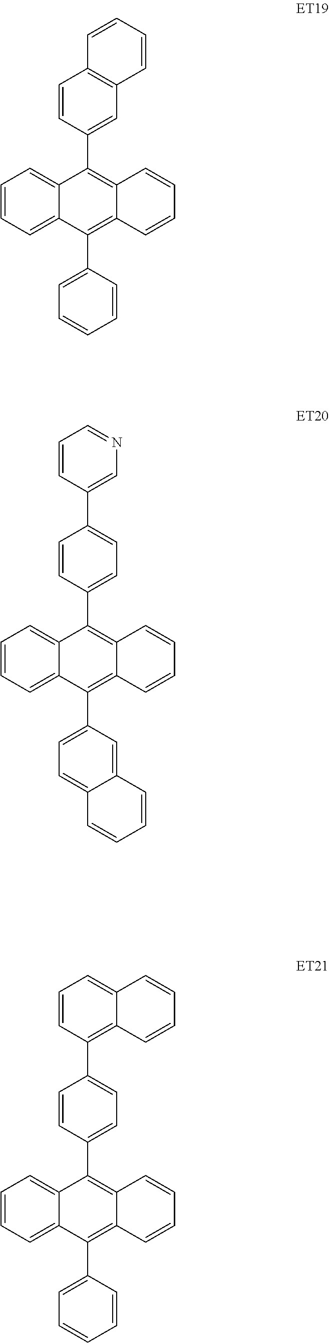

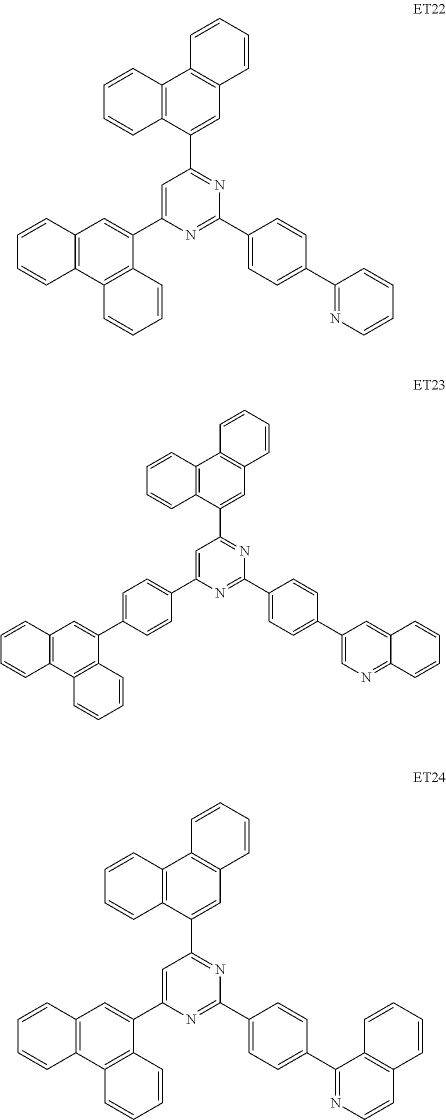 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

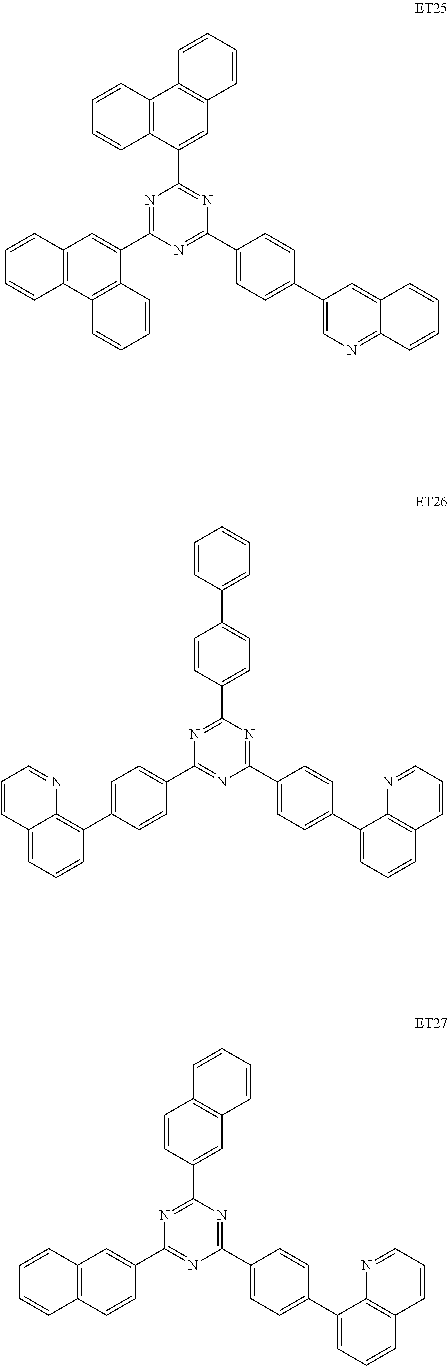 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

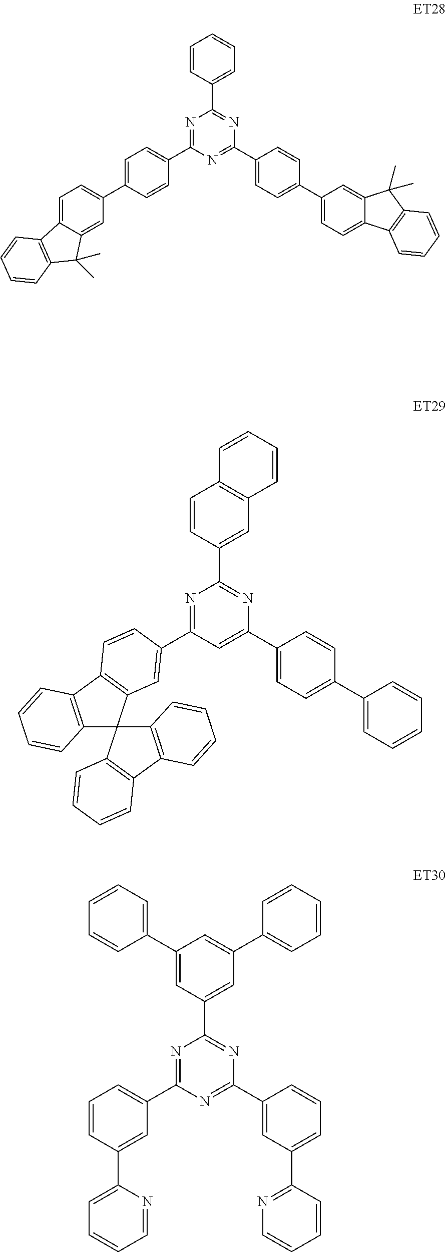 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

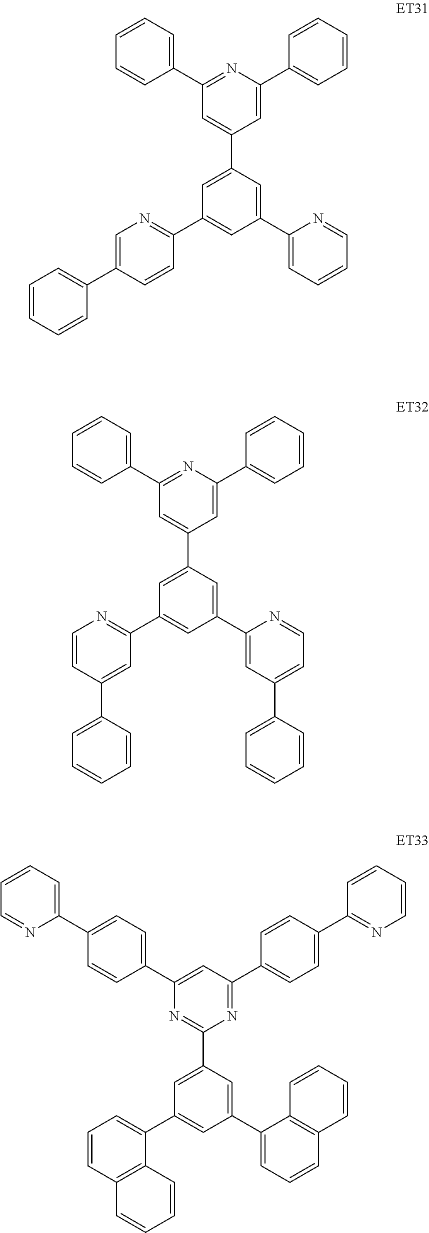 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

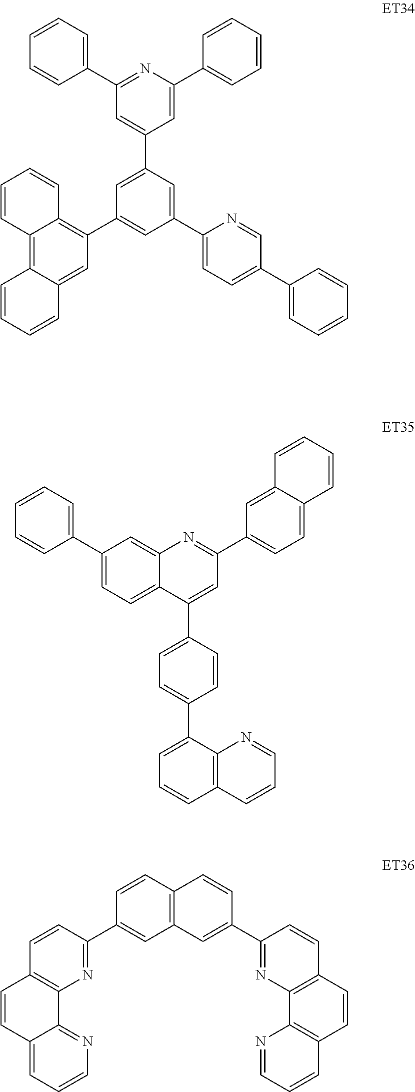 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

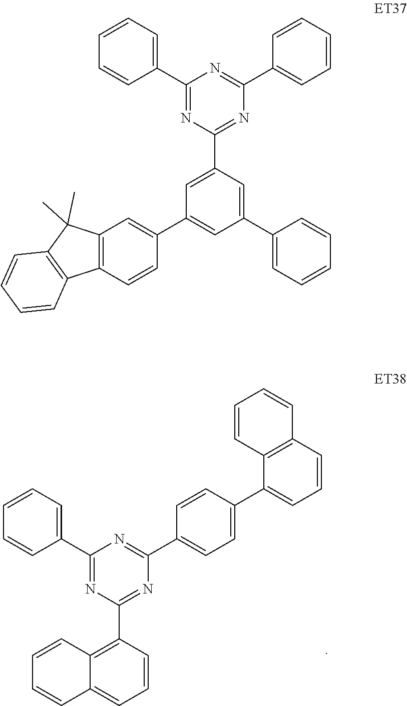 [SMILES: CC1(C)c2ccccc2-c2ccc(-c3cc(-c4ccccc4)cc(-c4nc(-c5ccccc5)nc(-c5ccccc5)n4)c3)cc21 ; c1ccc(-c2nc(-c3ccc(-c4cccc5ccccc45)cc3)nc(-c3cccc4ccccc34)n2)cc1]

In an embodiment, the electron transport region ETR may include: a metal halide such as LiF, NaCl, CsF, RbCl, RbI, CuI, and KI; a lanthanide metal such as Yb; or a co-deposited material of a metal halide and a lanthanide metal. For example, the electron transport region ETR may include KJ:Yb, RbJ:Yb, LiF:Yb, etc., as a co-deposited material. The electron transport region ETR may include a metal oxide such as LizO or BaO, or 8-hydroxyl-lithium quinolate (Liq), etc., but embodiments are not limited thereto. In another embodiment, the electron transport region ETR may include a mixture material of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen), in addition to the above-described materials, but embodiments are not limited thereto.

The electron transport region ETR may include the above-described compounds of the electron transport region in at least one of an electron injection layer EIL, an electron transport layer ETL, and a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies any of the aforementioned ranges, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies any of the above-described ranges, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is a transmissive electrode, the second electrode EL2 may include a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb).

In an embodiment, the second electrode EL2 may have a multilayered structure that includes a reflective film or a transflective film formed of the above-described materials, and a transparent conductive film formed of ITO, IZO, ZnO, ITZO, etc. For example, the second electrode EL2 may include the above-described metal materials, combinations of at least two of the above-described metal materials, oxides of the above-described metal materials, or the like.

Although not shown in the drawings, in an embodiment, the second electrode EL2 may be electrically connected to an auxiliary electrode. If the second electrode EL2 is electrically connected to an auxiliary electrode, resistance of the second electrode EL2 may decrease.

In an embodiment, the light-emitting element ED may further include a capping layer CPL disposed on the second electrode EL2. The capping layer CPL may have a multilayered structure or a single-layered structure.

In an embodiment, the capping layer CPL may be an organic layer or an inorganic layer. For example, when the capping layer CPL includes an inorganic material, the inorganic material may include an alkaline metal compound (e.g., LiF), an alkaline earth metal compound (e.g., MgF₂), SiON, SiNₓ, SiO_{y}, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or may include an epoxy resin, or an acrylate such as methacrylate. However, embodiments are not limited thereto. In an embodiment, the capping layer CPL may include at least one of Compounds P1 to P5:

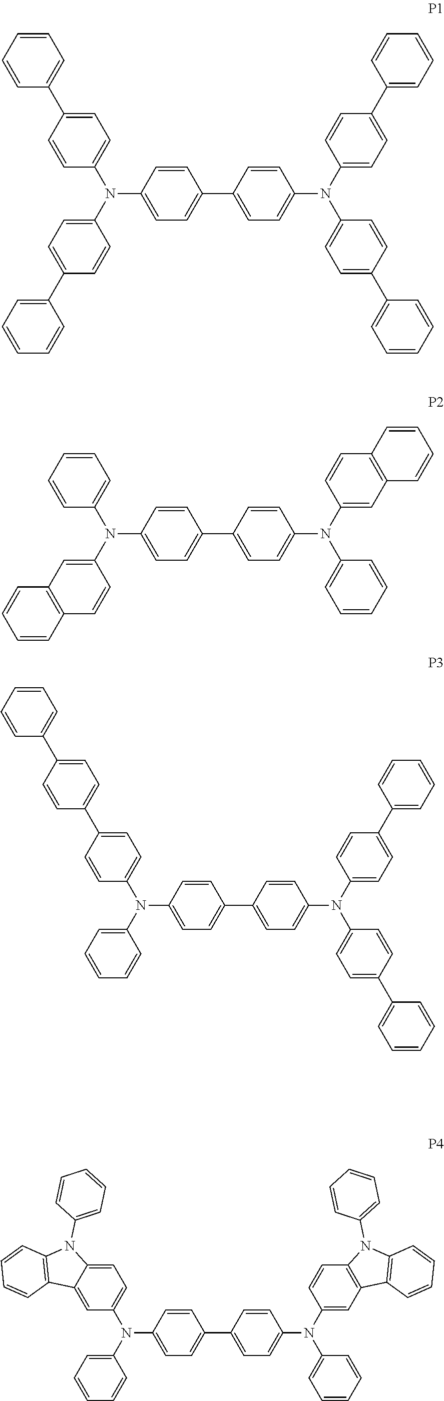 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

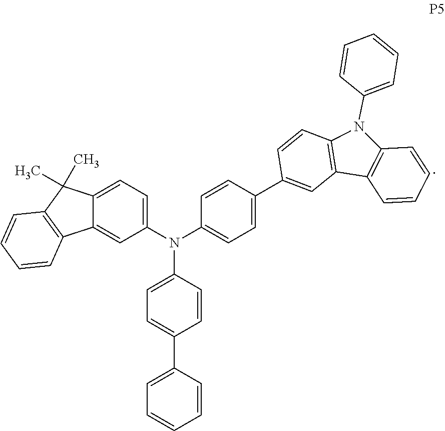 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, the refractive index of the capping layer CPL may be equal to or greater than about 1.6, with respect to light in a wavelength range of about 550 nm to about 660 nm.

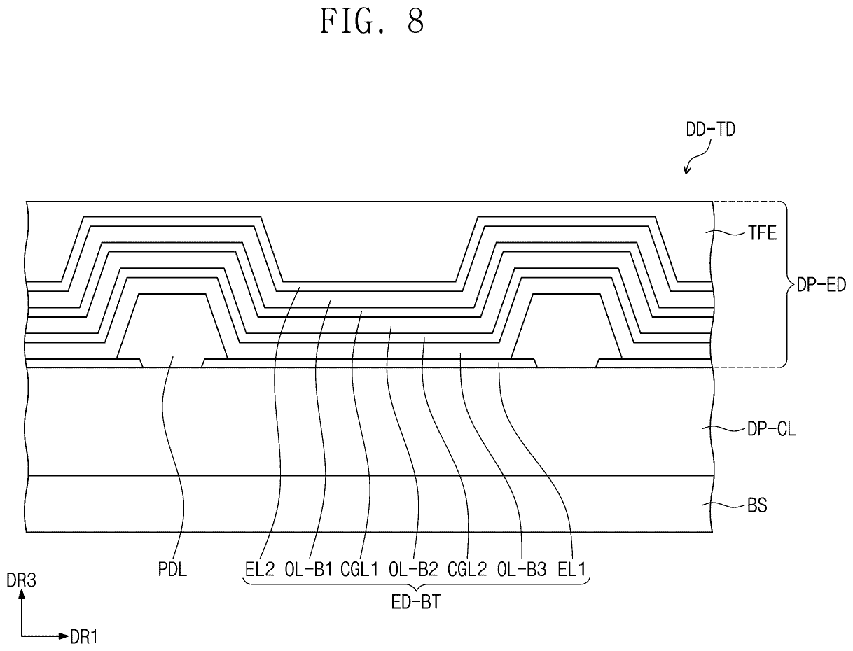

FIGS. 7 to 10 are each a schematic cross-sectional view of a display device according to an embodiment. Hereinafter, in describing the display devices according to embodiments as shown in FIGS. 7 to 10, the features that have been previously described above with respect to FIGS. 1 to 6 will not be described again, and the differing features will be described.

Referring to FIG. 7, a display device DD-a according to an embodiment may include a display panel DP that includes a display element layer DP-ED, a light control layer CCL disposed on the display panel DP, and a color filter layer CFL. In an embodiment shown in FIG. 7, the display panel DP may include a base layer BS, a circuit layer DP-CL provided on the base layer BS, and the display element layer DP-ED, and the display element layer DP-ED may include a light-emitting element ED.

The light-emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light-emitting element ED shown in FIG. 7 may be the same as a structure of a light-emitting element ED according to one of FIGS. 3 to 6 as described above.

An emission layer EML of a light-emitting element ED included in the display device DD-a according to an embodiment may include the polycyclic compound according to an embodiment as described above.

Referring to FIG. 7, the emission layer EML may be disposed in an opening OH defined in a pixel defining film PDL. For example, the emission layer EML, which is separated by the pixel defining film PDL and provided to correspond to each of the light emitting regions PXA-R, PXA-G, and PXA-B, may emit light in a same wavelength range. In the display device DD-a, the emission layer EML may emit blue light. Although not shown in the drawings, in an embodiment, the emission layer EML may be provided as a common layer throughout all of the light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light and emit the converted light. For example, the light control layer CCL may be a layer that includes a quantum dot or a layer that includes a phosphor.

The light control layer CCL may include light control parts CCP1, CCP2, and CCP3. The light control parts CCP1, CCP2, and CCP3 may be spaced apart from each other.

Referring to FIG. 7, divided patterns BMP may be disposed between the light control parts CCP1, CCP2, and CCP3 that are spaced apart from each other, but embodiments are not limited thereto. In FIG. 7, it is shown that the divided patterns BMP do not overlap the light control parts CCP1, CCP2, and CCP3, but the edges of the light control parts CCP1, CCP2, and CCP3 may overlap at least a portion of the divided patterns BMP.

The light control layer CCL may include a first light control part CCP1 including a first quantum dot QD1 that converts first color light provided from the light-emitting element ED into second color light, a second light control part CCP2 including a second quantum dot QD2 that converts the first color light into third color light, and a third light control part CCP3 that transmits the first color light.

In an embodiment, the first light control part CCP1 may provide red light that is the second color light, and the second light control part CCP2 may provide green light that is the third color light. The third light control part CCP3 may provide blue light by transmitting the blue light that is the first color light provided from the light-emitting element ED. For example, the first quantum dot QD1 may be a red quantum dot, and the second quantum dot QD2 may be a green quantum dot. The quantum dots QD1 and QD2 may each be a quantum dot as described above.

The light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include a quantum dot but may include the scatterer SP.

The scatterer SP may be inorganic particles. For example, the scatterer SP may include at least one of TiO₂, ZnO, Al₂O₃, SiO₂, and hollow silica. The scatterer SP may include one of TiO₂, ZnO, Al₂O₃, SiO₂, and hollow silica, or may be a mixture of at least two materials selected from TiO₂, ZnO, Al₂O₃, SiO₂, and hollow silica.

The first light control part CCP1, the second light control part CCP2, and the third light control part CCP3 may respectively include base resins BR1, BR2, and BR3, in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may include various resin compositions, which may be referred to as a binder. For example, the base resins BR1, BR2, and BR3 may be acrylic-based resins, urethane-based resins, silicone-based resins, epoxy-based resins, etc. The base resins BR1, BR2, and BR3 may each be a transparent resin. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may block the light control parts CCP1, CCP2, and CCP3 from exposure to moisture/oxygen. The barrier layer BFL1 may cover the light control parts CCP1, CCP2, and CCP3. In an embodiment, the barrier layer BFL2 may be provided between the light control parts CCP1, CCP2, and CCP3, and the color filter layer CFL.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film that secures light transmittance, etc. The barrier layers BFL1 and BFL2 may each independently further include an organic film. The barrier layers BFL1 and BFL2 may have a single-layered structure or a multilayered structure.

In the display device DD-a, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include filters CF1, CF2, and CF3. The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. In another embodiment, the first filter CF1 and the second filter CF2 may not be provided as separate filters and may be provided as a unitary filter.

Although not shown in the drawings, in an embodiment, the color filter layer CFL may further include a light shielding part (not shown). The light shielding part (not shown) may be a black matrix. The light shielding part (not shown) may include an organic light shielding material or an inorganic light shielding material, each including a black pigment or a black dye. The light shielding part (not shown) may prevent light leakage, and may separate boundaries between adjacent filters CF1, CF2, and CF3.

The first to third filters CF1, CF2, and CF3 may be disposed to respectively correspond the red light emitting region PXA-R, the green light emitting region PXA-G, and the blue light emitting region PXA-B.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

FIG. 8 is a schematic cross-sectional view of a portion of a display device according to an embodiment. In the display device DD-TD according to an embodiment, a light-emitting element ED-BT may include light emitting structures OL-B1, OL-B2, and OL-B3. The light-emitting element ED-BT may include a first electrode EL1 and a second electrode EL2 that face each other, and the light emitting structures OL-B1, OL-B2, and OL-B3, which are stacked in a thickness direction between the first electrode EL1 and the second electrode EL2. The light emitting structures OL-B1, OL-B2, and OL-B3 may each include a hole transport region HTR, an emission layer EML (FIG. 7), and an electron transport region ETR, which may be disposed in that order between the first electrode EL1 and the second electrode EL2.

For example, the light-emitting element ED-BT that is included in the display device DD-TD may be a light-emitting element having a tandem structure that includes multiple emission layers.

In an embodiment shown in FIG. 8, light emitted from the light emitting structures OL-B1, OL-B2, and OL-B3 may each be blue light. However, embodiments are not limited thereto, and the light emitted from each of the light emitting structures OL-B1, OL-B2, and OL-B3 may have wavelength ranges that are different from each other. For example, the light-emitting element ED-BT that includes the light emitting structures OL-B1, OL-B2, and OL-B3, which emit light having wavelength ranges that are different from each other, may emit white light.

Charge generation layers CGL1 and CGL2 may be respectively disposed between two adjacent light emitting structures among the light emitting structures OL-B1, OL-B2, and OL-B3. The charge generation layers CGL1 and CGL2 may each independently include a p-type charge generation layer and/or an n-type charge generation layer.

At least one of the emission structures OL-B1, OL-B2, and OL-B3 included in the display device DD-TD may include the polycyclic compound according to an embodiment as described above. For example, at least one of the emission layers included in the light-emitting element ED-BT may include the polycyclic compound according to an embodiment.

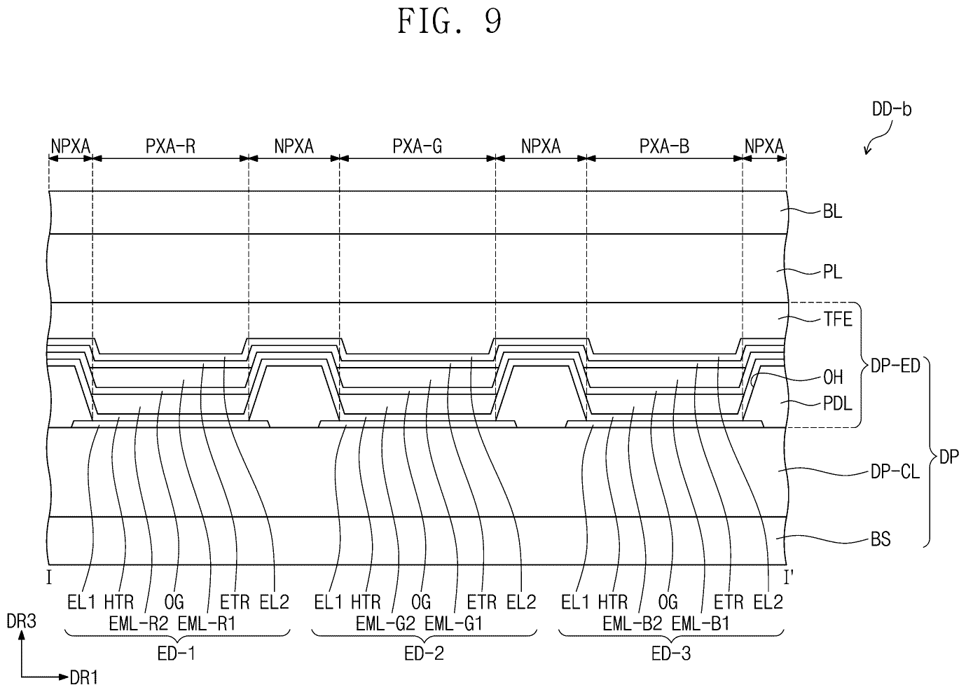

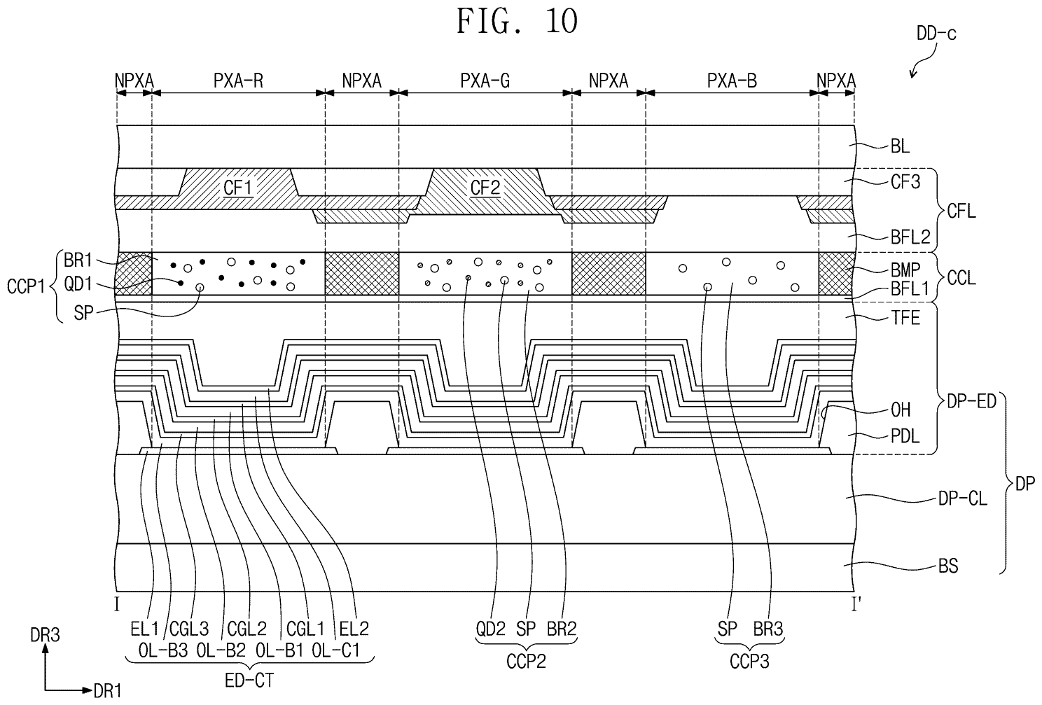

FIG. 9 is a schematic cross-sectional view of a display device DD-b according to an embodiment. FIG. 10 is a schematic cross-sectional view of a display device DD-c according to an embodiment.

Referring to FIG. 9, a display device DD-b according to an embodiment may include light-emitting elements ED-1, ED-2, and ED-3, in which two emission layers are stacked. In comparison to the display device DD shown in FIG. 2, the embodiment shown in FIG. 9 is different at least in that the first to third light-emitting elements ED-1, ED-2, and ED-3 each include two emission layers that are stacked in a thickness direction. In each of the first to third light-emitting elements ED-1, ED-2, and ED-3, the two emission layers may emit light in a same wavelength region.

The first light-emitting element ED-1 may include a first red emission layer EML-R1 and a second red emission layer EML-R2. The second light-emitting element ED-2 may include a first green emission layer EML-G1 and a second green emission layer EML-G2. The third light-emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may have a single-layered structure or a multilayered structure. The emission auxiliary part OG may include a charge generation layer. For example, the emission auxiliary part OG may include an electron transport region, a charge generation layer, and a hole transport region, which may be stacked in that order. The emission auxiliary part OG may be provided as a common layer throughout the first to third light-emitting elements ED-1, ED-2, and ED-3. However, embodiments are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may each be disposed between the emission auxiliary part OG and the electron transport region ETR. The second red emission layer EML-R2, the second green emission layer EML-G2, and the second blue emission layer EML-B2 may each be disposed between the hole transport region HTR and the emission auxiliary part OG.

The first light-emitting element ED-1 may include the first electrode EL1, the hole transport region HTR, the second red emission layer EML-R2, the emission auxiliary part OG, the first red emission layer EML-R1, the electron transport region ETR, and the second electrode EL2, which are stacked in that order. The second light-emitting element ED-2 may include the first electrode EL1, the hole transport region HTR, the second green emission layer EML-G2, the emission auxiliary part OG, the first green emission layer EML-G1, the electron transport region ETR, and the second electrode EL2, which are stacked in that order. The third light-emitting element ED-3 may include the first electrode EL1, the hole transport region HTR, the second blue emission layer EML-B2, the emission auxiliary part OG, the first blue emission layer EML-B1, the electron transport region ETR, and the second electrode EL2, which are stacked in that order.

An optical auxiliary layer PL may be disposed on the display element layer DP-ED. The optical auxiliary layer PL may include a polarizing layer. The optical auxiliary layer PL may be disposed on the display panel DP and may control light that is reflected at the display panel DP from an external light. Although not shown in the drawings, in an embodiment, the optical auxiliary layer PL may be omitted from the display device DD-b.

At least one emission layer included in the display device DD-b shown in FIG. 9 may include the polycyclic compound according to an embodiment as described above. For example, in an embodiment, at least one of the first blue emission layer EML-B1 and the second blue emission layer EML-B2 may include the polycyclic compound according to an embodiment.

In contrast to FIGS. 8 and 9, FIG. 10 shows a display device DD-c that is different at least in that it includes four light emitting structures OL-B1, OL-B2, OL-B3, and OL-C1. A light-emitting element ED-CT may include a first electrode EL1 and a second electrode EL2 that face each other, and first to fourth light emitting structures OL-B1, OL-B2, OL-B3, and OL-C1 that are stacked in a thickness direction between the first electrode EL1 and the second electrode EL2.

Charge generation layers CGL1, CGL2, and CGL3 may be respectively disposed between two adjacent light emitting structures among the first to fourth light emitting structures OL-B1, OL-B2, OL-B3, and OL-C1. In an embodiment, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light in different wavelength regions.

The charge generation layers CGL1, CGL2, and CGL3 may each independently include a p-type charge generation layer and/or an n-type charge generation layer.

At least one of the emission structures OL-B1, OL-B2, OL-B3, and OL-C1 included in the display device DD-c may include the polycyclic compound according to an embodiment as described above. For example, in an embodiment, at least one of the first to third emission structures OL-B1, OL-B2, and OL-B3 may include the polycyclic compound according to an embodiment.

The light-emitting element ED according to an embodiment may include the polycyclic compound represented by Formula 1 in at least one functional layer disposed between the first electrode EL1 and the second electrode EL2, thereby exhibiting excellent luminous efficiency and improved lifespan characteristics. For example, the polycyclic compound according to an embodiment may be included in the emission layer EML of the light-emitting element ED, and thus the light-emitting element ED may exhibit long lifespan characteristics.

In an embodiment, an electronic apparatus may include a display device that includes multiple light-emitting elements, and a control part that controls the display device. The electronic apparatus may be a device that is activated according to an electrical signal. The electronic apparatus may include display devices according to various embodiments. Examples of an electronic apparatus may include large, medium-sized, and small devices, such as a television set, a monitor, a billboard, a personal computer, a laptop computer, a personal digital terminal, a display device for a vehicle, a game console, a portable electronic apparatus, and a camera.

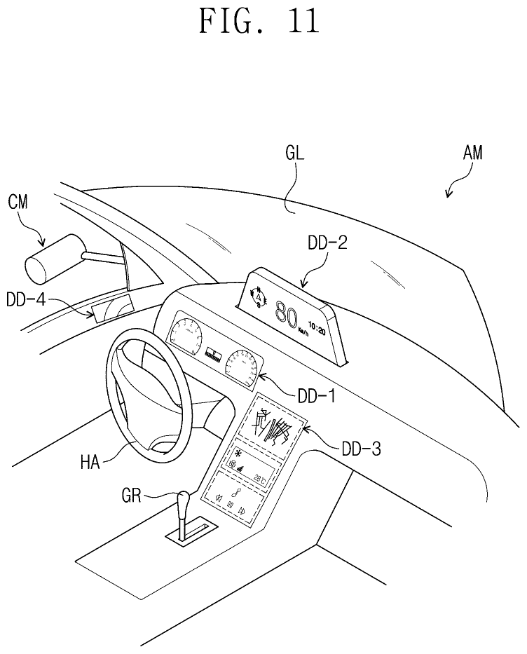

FIG. 11 is a schematic diagram of a vehicle AM in which first to fourth display devices DD-1, DD-2, DD-3, and DD-4 are disposed. At least one of the first to fourth display devices DD-1, DD-2, DD-3, and DD-4 may have a structure according to one of display devices DD, DD-TD, DD-a, DD-b, and DD-c, as described above with reference to FIGS. 1, 2, and 7 to 10.

FIG. 11 shows an automobile as a vehicle AM, but this is only an example, and the first to fourth display devices DD-1, DD-2, DD-3, and DD-4 may be disposed in various transportation means, such as a bicycle, a motorcycle, a train, a ship, and an airplane. In an embodiment, at least one of the first to fourth display devices DD-1, DD-2, DD-3, and DD-4, having a structure according to one of display devices DD, DD-TD, DD-a, DD-b, and DD-c, may be included in a personal computer, a laptop computer, a personal digital terminal, a game console, a portable electronic apparatus, a television, a monitor, a billboard, or the like. However, these are merely provided as examples, and the display device may be included in other electronic apparatuses.

At least one of the first to fourth display devices DD-1, DD-2, DD-3, and DD-4 may each independently include a light-emitting element ED according to an embodiment, as described with reference to any of FIGS. 3 to 6. The light-emitting element ED may include a polycyclic compound according to an embodiment. At least one of the first to fourth display devices DD-1, DD-2, DD-3, and DD-4 may each independently include a light-emitting element ED that include a polycyclic compound according to an embodiment, thereby improving display lifespan.

Referring to FIG. 11, the vehicle AM may include a steering wheel HA and a gearshift GR for driving the vehicle AM. The vehicle AM may include a front window GL that is disposed so as to face the driver.

A first display device DD-1 may be disposed in a first region that overlaps the steering wheel HA. For example, the first display device DD-1 may be a digital cluster that displays first information of the vehicle AM. The first information may include a first scale that indicates a driving speed of the vehicle AM, a second scale that indicates an engine speed (for example, as revolutions per minute (RPM)), an image that represents a fuel gauge, etc. The first scale and the second scale may each be represented by a digital image.

A second display device DD-2 may be disposed in a second region facing the driver's seat and overlapping the front window GL. The driver's seat may be a seat where the steering wheel HA is disposed. For example, the second display device DD-2 may be a head up display (HUD) that displays second information of the vehicle AM. The second display device DD-2 may be optically transparent. The second information may include digital numbers that indicate a driving speed, and may further include information such as the current time. Although not shown in the drawings, in an embodiment, the second information of the second display device DD-2 may be displayed by being projected onto the front window GL.

A third display device DD-3 may be disposed in a third region that is adjacent to the gearshift GR. For example, the third display device DD-3 may be disposed between the driver's seat and the passenger seat, and may be a center information display (CID) for a vehicle that displays third information. The passenger seat may be a seat that is spaced apart from the driver's seat, and the gearshift GR may be disposed between the driver's seat and the passenger seat. The third information may include information about traffic conditions (e.g., navigation information), about music or radio that is playing, about a video (or an image) that is displayed, about temperatures inside the vehicle AM, etc.

A fourth display device DD-4 may be spaced apart from the steering wheel HA and the gearshift GR, and may be disposed in a fourth region that is adjacent to a side of the vehicle AM. For example, the fourth display device DD-4 may be a digital side-view mirror that displays fourth information. The fourth display device DD-4 may display an image that is external to the vehicle AM, which may be taken by a camera module CM that is disposed on the exterior of the vehicle AM. The fourth information may include an exterior image of the vehicle AM.

The first to fourth information as described above are only provided as examples, and the first to fourth display devices DD-1, DD-2, DD-3, and DD-4 may further display information on the interior and exterior of the vehicle AM. The first to fourth information may include information that is different from each other. However, embodiments are not limited thereto, and a part of the first to fourth information may include a same information.

Hereinafter, a polycyclic compound according to an embodiment and a light-emitting element according to an embodiment will be described with reference to the Examples and the Comparative Examples. The Examples described below are only provided to assist in understanding the disclosure, and the scope thereof is not limited thereto.

### EXAMPLES

### 1. Synthesis of Polycyclic Compound

A synthesis method of a polycyclic compound according to an embodiment will be described in detail by describing synthesis methods for Compounds 8, 62, 4, 101, 117, 228, and 260. The methods for synthesizing a polycyclic compound according to an embodiment are provided only as examples, and the synthesis methods for the polycyclic compounds according to embodiments are not limited to the Examples below.

### (1) Synthesis of Compound 8

Compound 8 may be synthesized by, for example, Reaction Scheme 1:

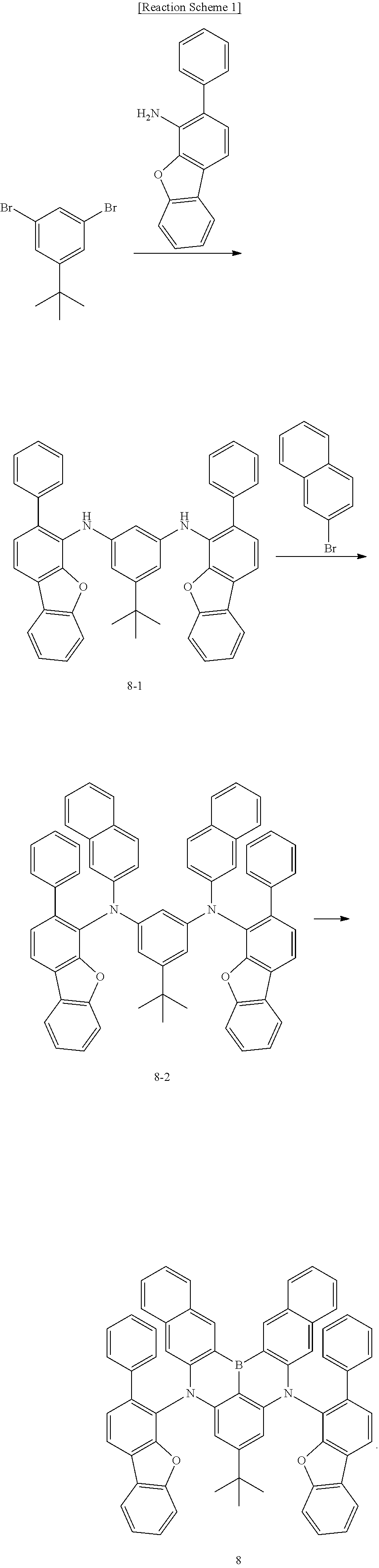

### 1) Synthesis of Intermediate Compound 8-1

1,3-dibromo-5-(tert-butyl)benzene (1 eq), 3-phenyldibenzo[b,d]furan-4-amine (2.3 eq), tris(dibenzylideneacetone)dipalladium(0) (0.05 eq), tri-tert-butylphosphine (0.1 eq), and sodium tert-butoxide (3 eq) were dissolved in toluene and stirred at about 90° C. for about 4 hours. After cooling, the resultant was washed with ethyl acetate and water three times, and an organic layer obtained by separation was dried over MgSO₄ and dried under reduced pressure. The resultant was purified by column chromatography with methylene chloride (MC) and n-Hexane to obtain Intermediate Compound 8-1 (yield of 71%).

### 2) Synthesis of Intermediate Compound 8-2

Intermediate Compound 8-1 (1 eq), 2-bromonaphthalene (2.2 eq), tris(dibenzylideneacetone)dipalladium(0) (0.05 eq), tri-tert-butylphosphine (0.1 eq), and sodium tert-butoxide (3 eq) were dissolved in toluene and stirred at about 110° C. for about 4 hours. After cooling, the resultant was washed with ethyl acetate and water three times, and an organic layer obtained by separation was dried over MgSO₄ and dried under reduced pressure. The resultant was purified by column chromatography with MC and n-Hexane to obtain Intermediate Compound 8-2 (yield of 79%)

### 3) Synthesis of Compound 8

Intermediate Compound 8-2 (1 eq) was dissolved in ortho dichlorobenzene and cooled to about 0° C., and BBr₃ (4 eq) was slowly added in nitrogen atmosphere. After dropwise addition was completed, the temperature was raised to about 180° C. and stirred for about 48 hours. After cooling, triethylamine was slowly added to the flask containing the reactant to quench the reaction. Ethyl alcohol was added to the reaction product, and the resulting product was precipitated and filtered to obtain solids. The obtained solids were purified by column chromatography using MC and n-Hexane and recrystallized using toluene and acetone to obtain Compound 8 (yield of 13%).

### (2) Synthesis of Compound 62

Compound 62 may be synthesized by, for example, Reaction Scheme 2:

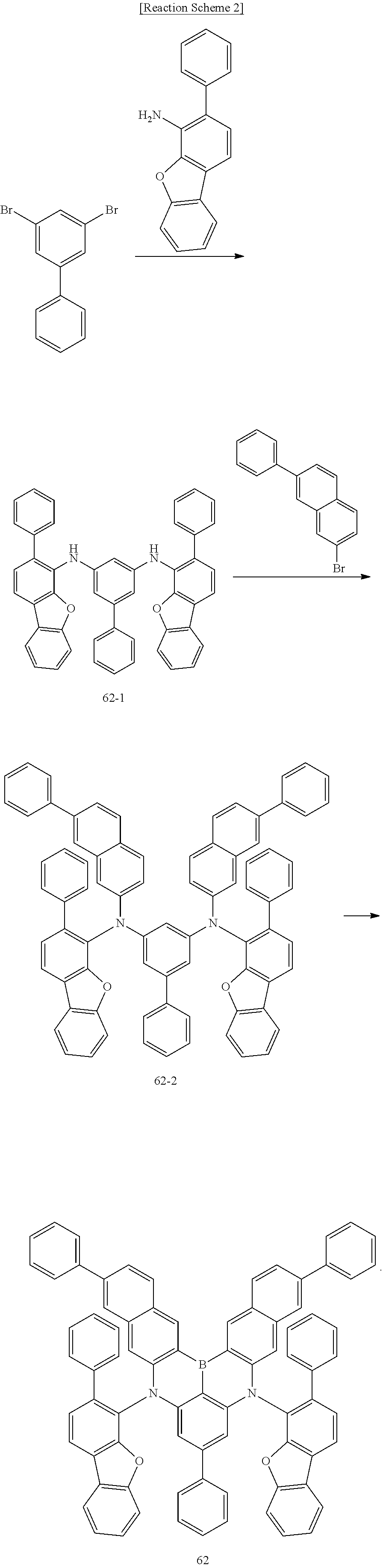 [SMILES: Brc1cc(Br)cc(-c2ccccc2)c1 ; Nc1c(-c2ccccc2)ccc2c1oc1ccccc12 ; c1ccc(-c2cc(Nc3c(-c4ccccc4)ccc4c3oc3ccccc34)cc(Nc3c(-c4ccccc4)ccc4c3oc3ccccc34)c2)cc1 ; Brc1ccc2ccc(-c3ccccc3)cc2c1 ; c1ccc(-c2cc(N(c3ccc4ccc(-c5ccccc5)cc4c3)c3c(-c4ccccc4)ccc4c3oc3ccccc34)cc(N(c3ccc4ccc(-c5ccccc5)cc4c3)c3c(-c4ccccc4)ccc4c3oc3ccccc34)c2)cc1 ; c1ccc(-c2cc3c4c(c2)N(c2c(-c5ccccc5)ccc5c2oc2ccccc25)c2cc5cc(-c6ccccc6)ccc5cc2B4c2cc4ccc(-c5ccccc5)cc4cc2N3c2c(-c3ccccc3)ccc3c2oc2ccccc23)cc1]

### 1) Synthesis of Intermediate Compound 62-1

3,5-dibromo-1,1′-biphenyl (1 eq), 3-phenyldibenzo[b,d]furan-4-amine (2.3 eq), tris(dibenzylideneacetone)dipalladium(0) (0.05 eq), tri-tert-butylphosphine (0.1 eq), and sodium tert-butoxide (3 eq) were dissolved in toluene and stirred at about 90° C. for about 4 hours. After cooling, the resultant was washed with ethyl acetate and water three times, and an organic layer obtained by separation was dried over MgSO₄ and dried under reduced pressure. The resultant was purified by column chromatography with MC and n-Hexane to obtain Intermediate Compound 62-1 (yield of 85%).

### 2) Synthesis of Intermediate Compound 62-2

Intermediate Compound 62-1 (1 eq), 2-bromo-7-phenylnaphthalene (2.2 eq), tris(dibenzylideneacetone)dipalladium(0) (0.05 eq), tri-tert-butylphosphine (0.1 eq), and sodium tert-butoxide (3 eq) were dissolved in toluene and stirred at about 110° C. for about 4 hours. After cooling, the resultant was washed with ethyl acetate and water three times, and an organic layer obtained by separation was dried over MgSO₄ and dried under reduced pressure. The resultant was purified by column chromatography with MC and n-Hexane to obtain Intermediate 62-2 (yield of 74%).

### 3) Synthesis of Compound 62

Intermediate Compound 62-2 (1 eq) was dissolved in ortho dichlorobenzene and cooled to about 0° C., and BBr₃ (4 eq) was slowly added in nitrogen atmosphere. After dropwise addition was completed, the temperature was raised to about 180° C. and stirred for about 48 hours. After cooling, triethylamine was slowly added to the flask containing the reactant to quench the reaction. Ethyl alcohol was added to the reaction product, and the resulting product was precipitated and filtered to obtain solids. The obtained solids were purified by column chromatography with MC and n-Hexane and recrystallized using toluene and acetone to obtain Compound 62 (yield of 11%).

### (3) Synthesis of Compound 4

Compound 4 may be synthesized by, for example, Reaction Scheme 3:

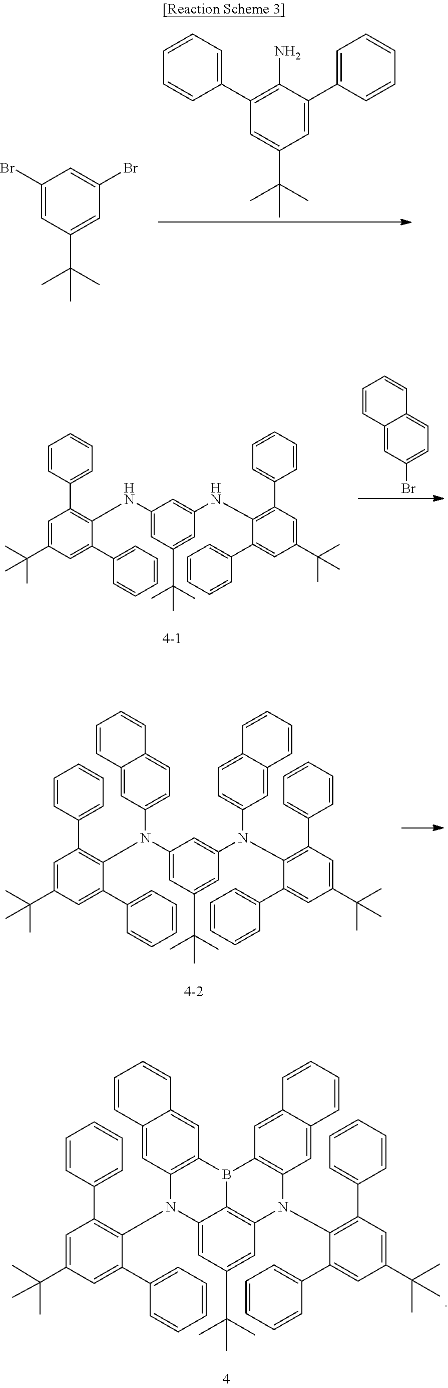

### 1) Synthesis of Intermediate Compound 4-1

1,3-dibromo-5-(tert-butyl)benzene (1 eq), 5′-(tert-butyl)-[1,1′: 3′,1″-terphenyl]-2′-amine (2.3 eq), tris(dibenzylideneacetone)dipalladium(0) (0.05 eq), tri-tert-butylphosphine (0.1 eq), and sodium tert-butoxide (3 eq) were dissolved in toluene and stirred at about 90° C. for about 4 hours. After cooling, the resultant was washed with ethyl acetate and water three times, and an organic layer obtained by separation was dried over MgSO₄ and dried under reduced pressure. The resulting product was purified by column chromatography with MC and n-Hexane to obtain Intermediate Compound 4-1 (yield of 87%).

### 2) Synthesis of Intermediate Compound 4-2

Intermediate Compound 4-1 (1 eq), 2-bromonaphthalene (2.2 eq), tris(dibenzylideneacetone)dipalladium(0) (0.05 eq), tri-tert-butylphosphine (0.1 eq), and sodium tert-butoxide (3 eq) were dissolved in toluene and stirred at about 110° C. for about 4 hours. After cooling, the resultant was washed with ethyl acetate and water three times, and an organic layer obtained by separation was dried over MgSO₄ and dried under reduced pressure. The resultant was purified by column chromatography with MC and n-Hexane to obtain Intermediate Compound 4-2 (yield of 77%).

### 3) Synthesis of Compound 4

Intermediate Compound 4-2 (1 eq) was dissolved in ortho dichlorobenzene and cooled to about 0° C., and BBr₃ (4 eq) was slowly added in nitrogen atmosphere. After dropwise addition was completed, the temperature was raised to about 180° C. and stirred for about 48 hours. After cooling, triethylamine was slowly added to the flask containing the reactant to quench the reaction. Ethyl alcohol was added to the reaction product, and the resulting product was precipitated and filtered to obtain solids. The obtained solids were purified by column chromatography with MC and n-Hexane and recrystallized using toluene and acetone to obtain Compound 4 (yield of 13%).

### (4) Synthesis of Compound 101

Compound 101 may be synthesized by, for example, Reaction Scheme 4:

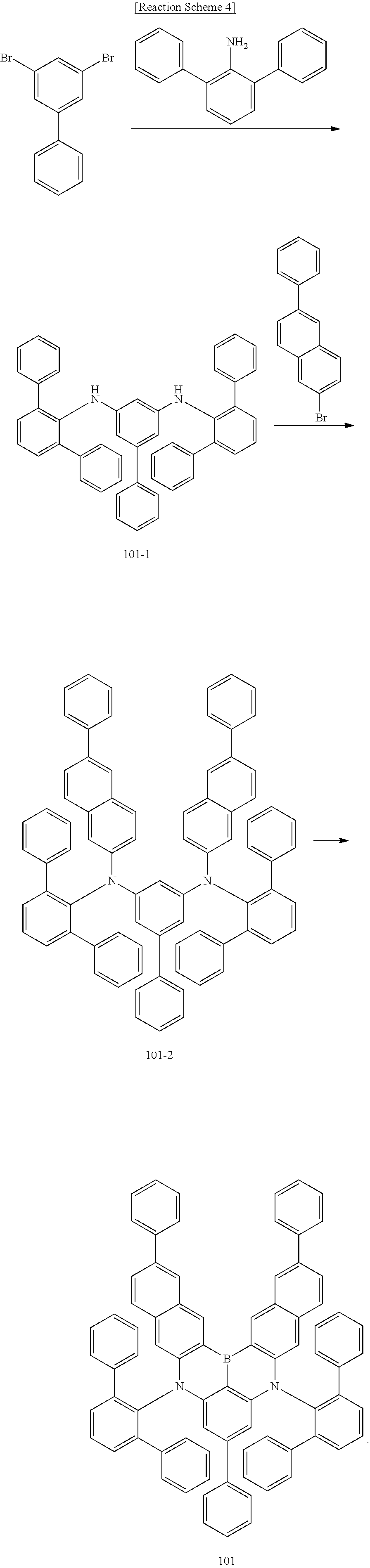

### 1) Synthesis of Intermediate Compound 101-1

3,5-dibromo-1,1′-biphenyl (1 eq), [1,1′: 3′,1″-terphenyl]-2′-amine (2.3 eq), tris(dibenzylideneacetone)dipalladium(0) (0.05 eq), tri-tert-butylphosphine (0.1 eq), and sodium tert-butoxide (3 eq) were dissolved in toluene and stirred at about 90° C. for about 4 hours. After cooling, the resultant was washed with ethyl acetate and water three times, and an organic layer obtained by separation was dried over MgSO₄ and dried under reduced pressure. The resultant was purified by column chromatography with MC and n-Hexane to obtain Intermediate Compound 101-1 (yield of 89%).

### 2) Synthesis of Intermediate Compound 101-2

Intermediate Compound 101-1 (1 eq), 2-bromo-6-phenylnaphthalene (2.2 eq), tris(dibenzylideneacetone)dipalladium(0) (0.05 eq), tri-tert-butylphosphine (0.1 eq), and sodium tert-butoxide (3 eq) were dissolved in toluene and stirred at about 110° C. for about 4 hours. After cooling, the resultant was washed with ethyl acetate and water three times, and an organic layer obtained by separation was dried over MgSO₄ and dried under reduced pressure. The resultant was purified by column chromatography with MC and n-Hexane to obtain Intermediate Compound 101-2 (yield of 78%).

### 3) Synthesis of Compound 101

Intermediate Compound 101-2 (1 eq) was dissolved in ortho dichlorobenzene and cooled to about 0° C., and BBr₃ (4 eq) was slowly added in nitrogen atmosphere. After dropwise addition was completed, the temperature was raised to about 180° C. and stirred for about 48 hours. After cooling, triethylamine was slowly added to the flask containing the reactant to quench the reaction. Ethyl alcohol was added to the reaction product, and the resulting product was precipitated and filtered to obtain solids. The obtained solids were purified by column chromatography with MC and n-Hexane, and recrystallized using toluene and acetone to obtain Compound 101 (yield of 12%).

### (5) Synthesis of Compound 117

Compound 117 may be synthesized by, for example, Reaction Scheme 5:

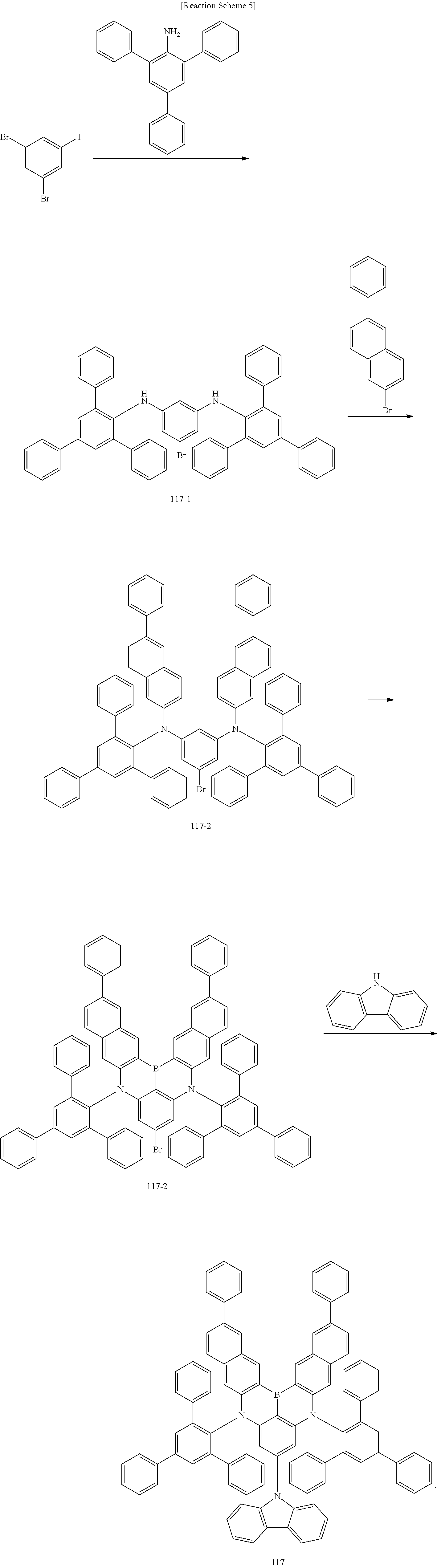

### 1) Synthesis of Intermediate Compound 117-1

1,3-dibromo-5-iodobenzene (1 eq), 5′-phenyl-[1,1′: 3′,1″-terphenyl]-2′-amine (2.3 eq), tris(dibenzylideneacetone)dipalladium(0) (0.05 eq), tri-tert-butylphosphine (0.1 eq), and sodium tert-butoxide (3 eq) were dissolved in toluene and stirred at about 90° C. for about 3 hours. After cooling, the resultant was washed with ethyl acetate and water three times, and an organic layer obtained by separation was dried over MgSO₄ and dried under reduced pressure. The resultant was purified by column chromatography with MC and n-Hexane to obtain Intermediate Compound 117-1 (yield of 71%).

### 2) Synthesis of Intermediate Compound 117-2

Intermediate Compound 117-1 (1 eq), 2-bromo-6-phenylnaphthalene (2.3 eq), tris(dibenzylideneacetone)dipalladium(0) (0.05 eq), tri-tert-butylphosphine (0.1 eq), and sodium tert-butoxide (3 eq) were dissolved in toluene and stirred at about 110° C. for about 4 hours. After cooling, the resultant was washed with ethyl acetate and water three times, and an organic layer obtained by separation was dried over MgSO₄ and dried under reduced pressure. The resultant was purified by column chromatography with MC and n-Hexane to obtain Intermediate Compound 117-2 (yield of 68%).

### 3) Synthesis of Intermediate Compound 117-3

Intermediate Compound 117-2 (1 eq) was dissolved in ortho dichlorobenzene and cooled to about 0° C., and BBr₃ (4 eq) was slowly added in nitrogen atmosphere. After dropwise addition was completed, the temperature was raised to about 180° C. and stirred for about 24 hours. After cooling, triethylamine was slowly added to the flask containing the reactant to quench the reaction. Ethyl alcohol was added to the reaction product, and the resulting product was precipitated and filtered to obtain solids. The obtained solids were purified by column chromatography with MC and n-Hexane and recrystallized using toluene and acetone to obtain Intermediate Compound 117-3 (yield of 12%).

### 4) Synthesis of Compound 117

Intermediate Compound 117-3 (1 eq), 9H-carbazole (1.5 eq), tris(dibenzylideneacetone)dipalladium(0) (0.05 eq), tri-tert-butylphosphine (0.1 eq), and sodium tert-butoxide (3 eq) were dissolved in toluene and stirred at about 110° C. for about 3 hours. After cooling, ethyl alcohol was added to the reactant, and the resulting product was precipitated and filtered to obtain solids. The obtained solids were purified by column chromatography with MC and n-Hexane and recrystallized using toluene and acetone to obtain Compound 117 (yield of 47%).

### (6) Synthesis of Compound 228

Compound 228 may be synthesized by, for example, Reaction Scheme 6:

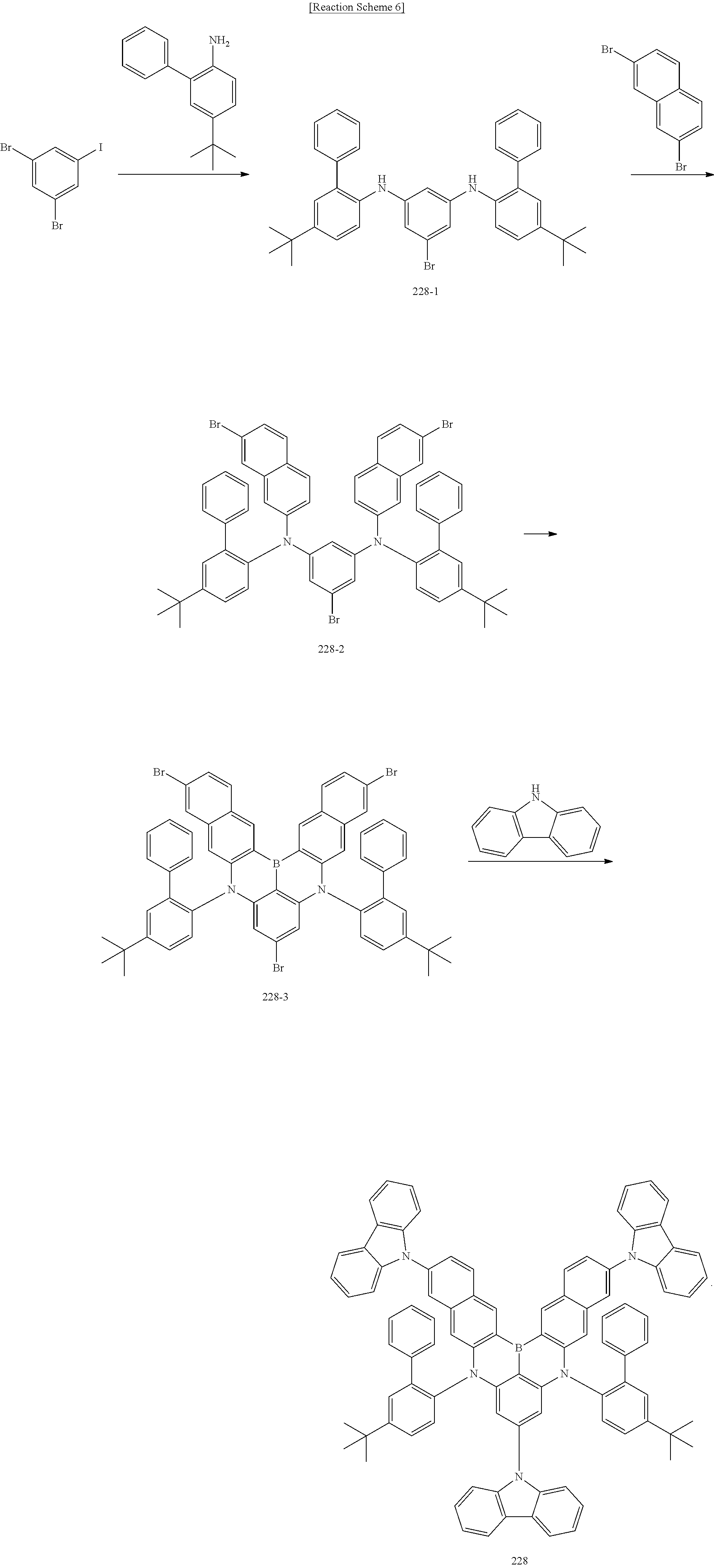

### 1) Synthesis of Intermediate Compound 228-1

1,3-dibromo-5-iodobenzene (1 eq), 5-(tert-butyl)-[1,1′-biphenyl]-2-amine (2.3 eq), tris(dibenzylideneacetone)dipalladium(0) (0.05 eq), tri-tert-butylphosphine (0.1 eq), and sodium tert-butoxide (3 eq) were dissolved in toluene and stirred at about 90° C. for about 3 hours. After cooling, the resultant was washed with ethyl acetate and water three times, and an organic layer obtained by separation was dried over MgSO₄ and dried under reduced pressure. The resultant was purified by column chromatography with MC and n-Hexane to obtain Intermediate Compound 228-1 (yield of 72%).

### 2) Synthesis of Intermediate Compound 228-2

Intermediate Compound 228-1 (1 eq), 2,7-dibromonaphthalene (3.0 eq), tris(dibenzylideneacetone)dipalladium(0) (0.05 eq), tri-tert-butylphosphine (0.1 eq), and sodium tert-butoxide (3 eq) were dissolved in toluene and stirred at about 110° C. for about 4 hours. After cooling, the resultant was washed with ethyl acetate and water three times, and an organic layer obtained by separation was dried over MgSO₄ and dried under reduced pressure. The resultant was purified by column chromatography with MC and n-Hexane to obtain Intermediate Compound 228-2 (yield of 68%).

### 3) Synthesis of Intermediate Compound 228-3

Intermediate Compound 228-2 (1 eq) was dissolved in ortho dichlorobenzene and cooled to about 0° C., and BBr₃ (4 eq) was slowly added in nitrogen atmosphere. After dropwise addition was completed, the temperature was raised to about 180° C. and stirred for about 24 hours. After cooling, triethylamine was slowly added to the flask containing the reactant to quench the reaction. Ethyl alcohol was added to the reaction product, and the resulting product was precipitated and filtered to obtain solids. The obtained solids were purified by column chromatography with MC and n-Hexane and recrystallized using toluene and acetone to obtain Intermediate Compound 228-3 (yield of 11%).

### 4) Synthesis of Compound 228

Intermediate Compound 228-3 (1 eq), 9H-carbazole (4.0 eq), tris(dibenzylideneacetone)dipalladium(0) (0.05 eq), tri-tert-butylphosphine (0.1 eq), and sodium tert-butoxide (3 eq) were dissolved in toluene and stirred at about 110° C. for about 3 hours. After cooling, ethyl alcohol was added to the reaction product, and the resulting product was precipitated and filtered to obtain solids. The obtained solids were purified by column chromatography with MC and n-Hexane and recrystallized using toluene and acetone to obtain Compound 228 (yield of 37%).

### (7) Synthesis of Compound 260

Compound 260 may be synthesized by, for example, Reaction Scheme 7:

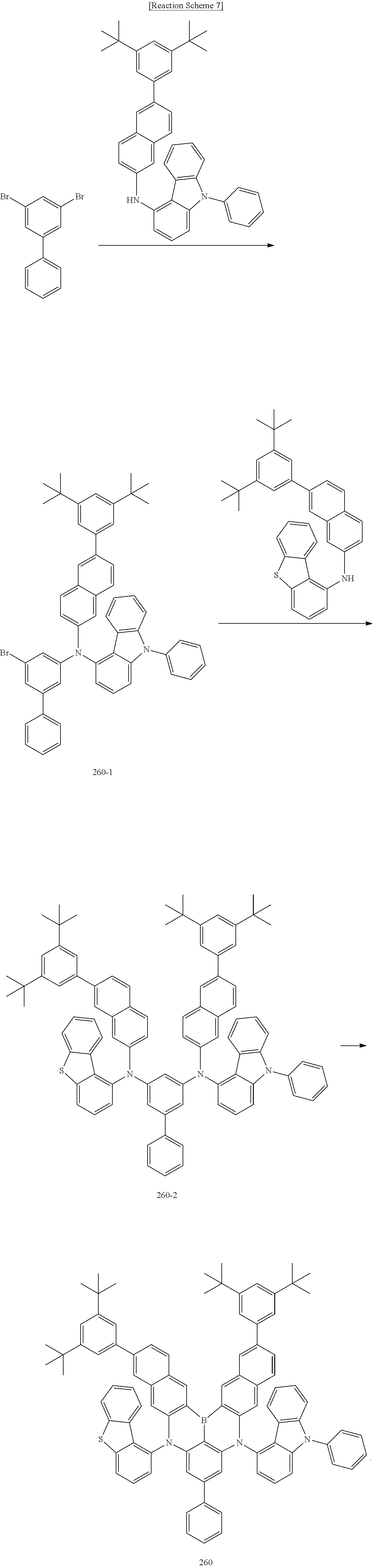

### 1) Synthesis of Intermediate Compound 260-1

3,5-dibromo-1,1′-biphenyl (1 eq), N-(6-(3,5-di-tert-butylphenyl)naphthalen-2-yl)-9-phenyl-9H-carbazol-4-amine (0.8 eq), tris(dibenzylideneacetone)dipalladium(0) (0.05 eq), BINAP (0.1 eq), and sodium tert-butoxide (3 eq) were dissolved in toluene and stirred at about 90° C. for about 3 hours. After cooling, the resultant was washed with ethyl acetate and water three times, and an organic layer obtained by separation was dried over MgSO₄ and dried under reduced pressure. The resultant was purified by column chromatography with MC and n-Hexane to obtain Intermediate Compound 260-1 (yield of 68%).

### 2) Synthesis of Intermediate Compound 260-2

Intermediate Compound 260-1 (1 eq), N-(7-(3,5-di-tert-butylphenyl)naphthalen-2-yl)dibenzo[b,d]thiophen-1-amine (1.1 eq), tris(dibenzylideneacetone)dipalladium(0) (0.05 eq), tri-tert-butylphosphine (0.1 eq), and sodium tert-butoxide (3 eq) were dissolved in toluene and stirred at about 110° C. for about 4 hours. After cooling, the resultant was washed with ethyl acetate and water three times, and an organic layer obtained by separation was dried over MgSO₄ and dried under reduced pressure. The resultant was purified by column chromatography with MC and n-Hexane to obtain Intermediate Compound 260-2 (yield of 72%).

### 3) Synthesis of Compound 260

Intermediate Compound 260-2 (1 eq) was dissolved in ortho dichlorobenzene and cooled to about 0° C., and BBr₃ (4 eq) was slowly added in nitrogen atmosphere. After dropwise addition was completed, the temperature was raised to about 180° C. and stirred for about 48 hours. After cooling, triethylamine was slowly added to the flask containing the reactant to quench the reaction. Ethyl alcohol was added to the reaction product, and the resulting product was precipitated and filtered to obtain solids. The obtained solids were purified by column chromatography with MC and n-Hexane and recrystallized using toluene and acetone to obtain Intermediate Compound 260 (yield of 11%).

2. Manufacture and Evaluation of Light-emitting element

The light-emitting elements according to an embodiment containing the polycyclic compound according to an embodiment were manufactured by the following method. The light-emitting elements according to Example 1 to Example 7 were respectively manufactured using Compounds 8, 62, 4, 101, 117, 228, and 260, which are the Example Compounds described above, as a dopant material in the emission layer. The light-emitting elements according to Comparative Example 1 to Comparative Example 7 correspond to the light-emitting elements that were respectively manufactured using Comparative Example Compounds C1 to C7 as a dopant material in the emission layer.

### Example Compound

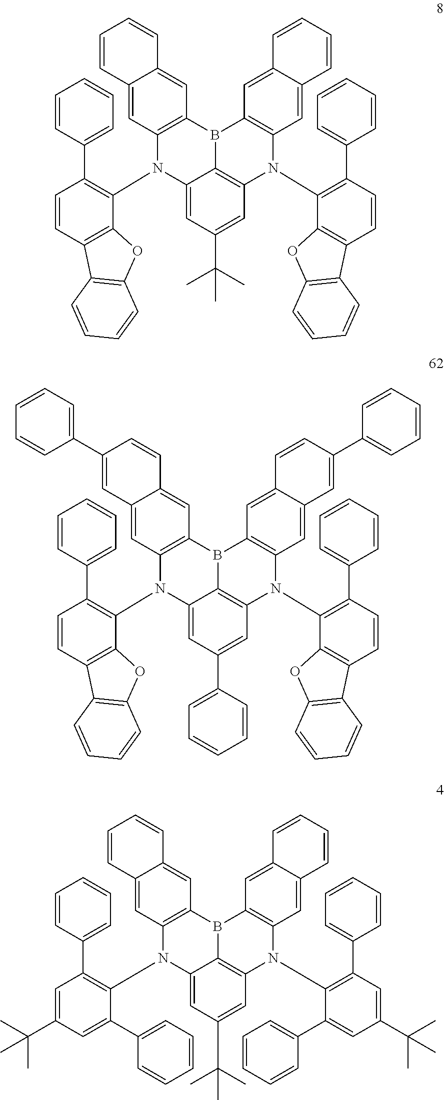 [SMILES: CC(C)(C)c1cc2c3c(c1)N(c1c(-c4ccccc4)ccc4c1oc1ccccc14)c1cc4ccccc4cc1B3c1cc3ccccc3cc1N2c1c(-c2ccccc2)ccc2c1oc1ccccc12 ; c1ccc(-c2cc3c4c(c2)N(c2c(-c5ccccc5)ccc5c2oc2ccccc25)c2cc5cc(-c6ccccc6)ccc5cc2B4c2cc4ccc(-c5ccccc5)cc4cc2N3c2c(-c3ccccc3)ccc3c2oc2ccccc23)cc1 ; CC(C)(C)c1cc(-c2ccccc2)c(N2c3cc4ccccc4cc3B3c4cc5ccccc5cc4N(c4c(-c5ccccc5)cc(C(C)(C)C)cc4-c4ccccc4)c4cc(C(C)(C)C)cc2c43)c(-c2ccccc2)c1]

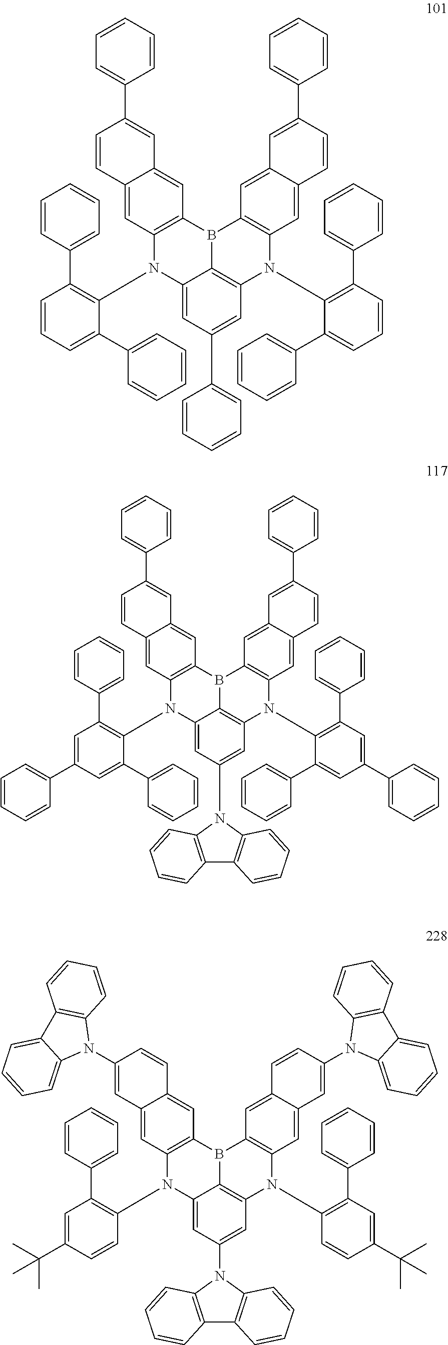 [SMILES: c1ccc(-c2cc3c4c(c2)N(c2c(-c5ccccc5)cccc2-c2ccccc2)c2cc5ccc(-c6ccccc6)cc5cc2B4c2cc4cc(-c5ccccc5)ccc4cc2N3c2c(-c3ccccc3)cccc2-c2ccccc2)cc1 ; c1ccc(-c2cc(-c3ccccc3)c(N3c4cc5ccc(-c6ccccc6)cc5cc4B4c5cc6cc(-c7ccccc7)ccc6cc5N(c5c(-c6ccccc6)cc(-c6ccccc6)cc5-c5ccccc5)c5cc(-n6c7ccccc7c7ccccc76)cc3c54)c(-c3ccccc3)c2)cc1 ; CC(C)(C)c1ccc(N2c3cc4cc(-n5c6ccccc6c6ccccc65)ccc4cc3B3c4cc5ccc(-n6c7ccccc7c7ccccc76)cc5cc4N(c4ccc(C(C)(C)C)cc4-c4ccccc4)c4cc(-n5c6ccccc6c6ccccc65)cc2c43)c(-c2ccccc2)c1]

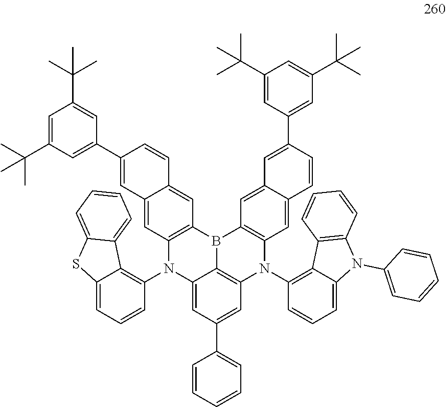 [SMILES: CC(C)(C)c1cc(-c2ccc3cc4c(cc3c2)B2c3cc5ccc(-c6cc(C(C)(C)C)cc(C(C)(C)C)c6)cc5cc3N(c3cccc5sc6ccccc6c35)c3cc(-c5ccccc5)cc(c32)N4c2cccc3c2c2ccccc2n3-c2ccccc2)cc(C(C)(C)C)c1]

### Comparative Example Compound

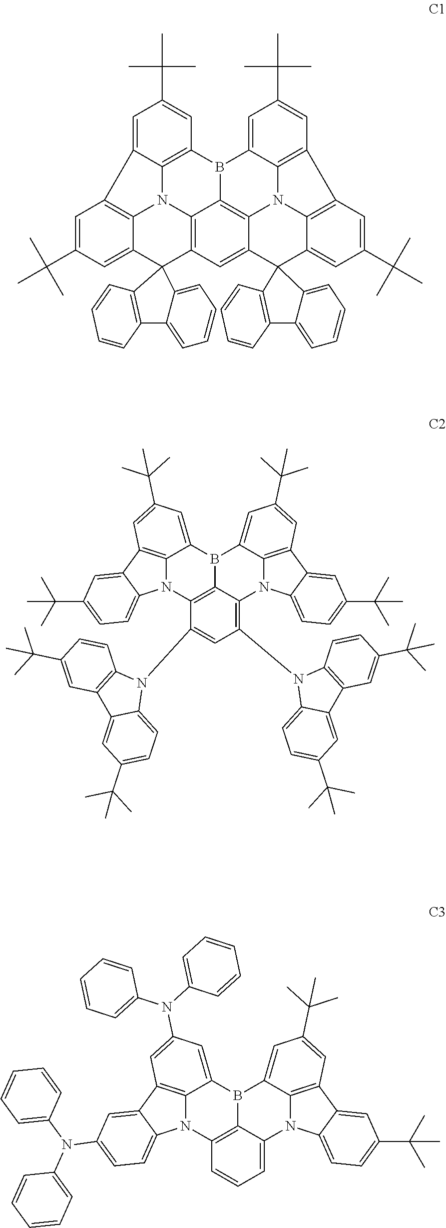

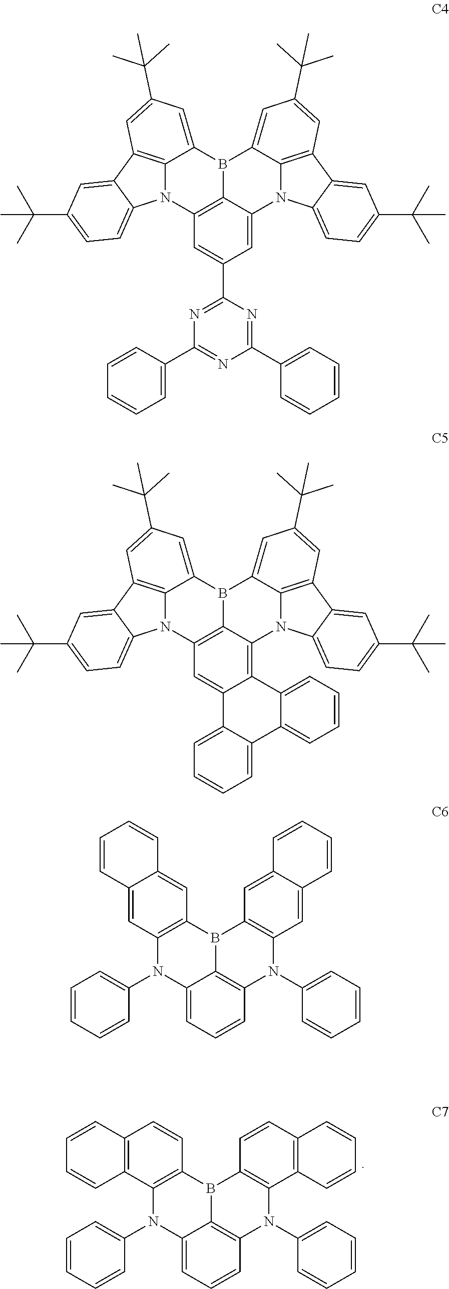

### (Manufacture of Light-Emitting Element)

In each light-emitting element according to the Examples and the Comparative Examples, a glass substrate (a product of Corning Inc.), on which an ITO electrode of about 15 Ω/cm² (1,200 Å) was formed as a first electrode, was cut to a size of about 50 mm×50 mm×0.7 mm, cleansed by ultrasonic waves using isopropyl alcohol and pure water for about five minutes each, and irradiated with ultraviolet rays for about 30 minutes and exposed to ozone to be cleansed. The glass substrate was mounted on a vacuum deposition apparatus.

Compound H-1-1 was deposited on the anode electrode to form a hole transport layer having a thickness of about 600 Å, and Compound H-1-20 was deposited on the hole transport layer to form an electron blocking layer having a thickness of about 100 Å.

A third compound, a fourth compound, and an Example Compound or a Comparative Example Compound were co-deposited at a weight ratio of about 85:13.5:1.5 to form an emission layer having a thickness of about 300 Å, and Compound ET37 was deposited on the emission layer to form a hole blocking layer. A mixture in which Compound ET38 and Liq were mixed at a weight ratio of about 5:5 was deposited to form an electron transport layer having a thickness of about 300 Å on the hole blocking layer, and Yb was deposited on the electron transport layer to form an electron injection layer having a thickness of about 10 Å. A second electrode having a thickness of about 3,000 Å was formed of aluminum (Al).

Each layer was formed by a vacuum deposition method. Compound ETH87 from Compound Group 3 as described above was used as the third compound, and Compound AD-41 from Compound Group 4 as described above was used as the fourth compound.

The compounds used in the manufacture of the light-emitting elements according to the Examples and the Comparative Examples are shown below. Commercial products were purified by sublimation and used for the manufacture of the light-emitting element.

(Material used in Manufacture of Light-emitting element)

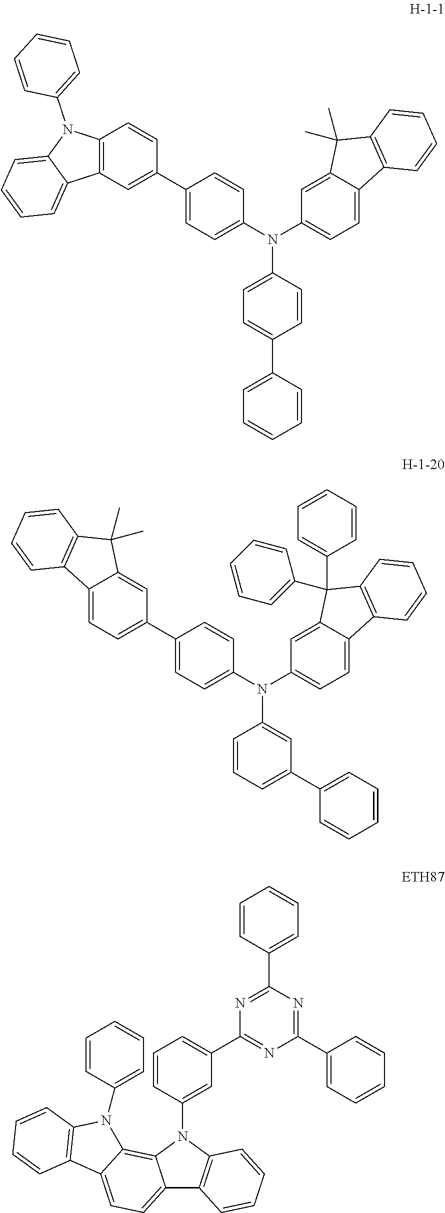 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(-c3ccc(N(c4cccc(-c5ccccc5)c4)c4ccc5c(c4)C(c4ccccc4)(c4ccccc4)c4ccccc4-5)cc3)cc21 ; c1ccc(-c2nc(-c3ccccc3)nc(-c3cccc(-n4c5ccccc5c5ccc6c7ccccc7n(-c7ccccc7)c6c54)c3)n2)cc1]

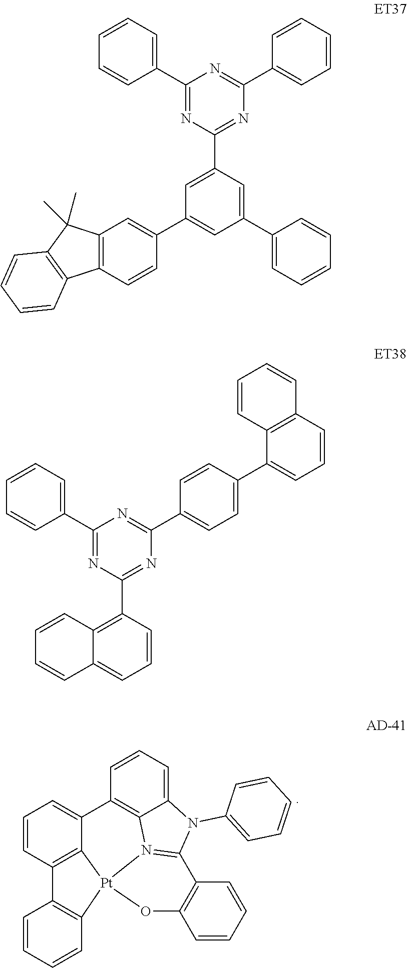

### (2) Evaluation of Light-Emitting Element Characteristics

For each of the light-emitting elements respectively using Compounds 8, 62, 4, 101, 117, 228, and 260, and Comparative Example Compounds C1 to C7 as emission materials, driving voltage, efficiency, emission wavelength, and lifespan were evaluated. The evaluation results for the light-emitting elements according to Example 1 to Example 7 and Comparative Example 1 to Comparative Example 7 are listed in Table 1 below. In the evaluation results of characteristics of the light-emitting elements according to the Examples and the Comparative Examples shown in Table 1, the driving voltage and the cumient density were measured using V7000 OLED JVL Test System (Polaronix). In order to evaluate of the characteristics of the light-emitting elements manufactured according to Examples 1 to 7 and Comparative Example 1 to Comparative Example 7, driving voltage and efficiency (cd/A) were measured at a current density of about 10 mA/cm², and the driving voltage in Table 1 is a value that is relative to the driving voltage of the light-emitting element according to Comparative Example 1. For the evaluation of lifespan (T95), the time taken for luminance to deteriorate from an initial value to 95% was measured from a light-emitting element being continuously operated at a current density of about 10 mA/cm², and a relative element lifespan was calculated by comparing the measured time value with the value of the light-emitting element according to Comparative Example 1, and the calculated relative element lifespan was listed as the lifespan (T95) in Table 1.

TABLE 1

| | Host | | Dopant | Driving | | Emission | |
|---|---|---|---|---|---|---|---|
| | (Third | Fourth | (First | Voltage | Efficiency | wavelength | Lifespan |
| | compound) | compound | Compound) | (V) | (cd/A) | (nm) | (T95) |
| Example 1 | ETH87 | AD-41 | 8 | 98% | 132 | 529 | 147% |
| Example 2 | ETH87 | AD-41 | 62 | 97% | 129 | 533 | 149% |
| Example 3 | ETH87 | AD-41 | 4 | 98% | 137 | 529 | 151% |
| Example 4 | ETH87 | AD-41 | 101 | 95% | 136 | 533 | 152% |
| Example 5 | ETH87 | AD-41 | 117 | 94% | 138 | 529 | 151% |
| Example 6 | ETH87 | AD-41 | 228 | 93% | 135 | 530 | 147% |
| Example 7 | ETH87 | AD-41 | 260 | 97% | 133 | 529 | 149% |
| Comparative | ETH87 | AD-41 | C1 | 100% | 100 | 534 | 100% |
| Example 1 | | | | | | | |
| Comparative | ETH87 | AD-41 | C2 | 100% | 100 | 534 | 42% |
| Example 2 | | | | | | | |
| Comparative | ETH87 | AD-41 | C3 | 100% | 100 | 534 | 26% |
| Example 3 | | | | | | | |
| Comparative | ETH87 | AD-41 | C4 | 100% | 100 | 532 | 60% |
| Example 4 | | | | | | | |
| Comparative | ETH87 | AD-41 | C5 | 100% | 100 | 530 | 53% |
| Example 5 | | | | | | | |
| Comparative | ETH87 | AD-41 | C6 | 95% | 140 | 529 | 43% |
| Example 6 | | | | | | | |
| Comparative | ETH87 | AD-41 | C7 | 96% | 142 | 527 | 27% |
| Example 7 | | | | | | | |

Referring to the results in Table 1, it can be seen that the light-emitting elements according to the Examples and the light-emitting elements according to the Comparative Examples emit light in a green wavelength region. However, it can be confirmed that the light-emitting elements according to Example 1 to Example 7 exhibit low-driving voltage characteristics as compared to the light-emitting elements according to Comparative Example 1 to Comparative Example 5 and have improved luminous efficiency and lifespan characteristics compared to the light-emitting elements according to Comparative Example 1 to Comparative Example 7.

In each of the Example Compounds, a conjugation length is extended by the fusion of two naphthalene at a specific location of the core, which induces a red shift, and thus high efficiency and long lifespan may be achieved in a green wavelength region. Each of the Example Compounds include a steric protection substituent connected to the nitrogen atom of the core, and thus the boron atom of the core may be effectively protected. By the inclusion of the steric protection substituent, intermolecular interactions are inhibited, which may prevent the formation of excimers or exciplexes, and thus luminous efficiency and lifespan may be improved. In each of the Example Compounds, the steric protection substituent increases intermolecular distance, which may inhibit Dexter energy transfer, and thus intermolecular interactions may be prevented, thereby inhibiting deterioration of lifespan.

By comparison, the light-emitting elements according to Comparative Example 1 to Comparative Example 5 may emit light in a green wavelength region. However, Comparative Example Compounds C1, C2, C3, C4, and C5 respectively used for Comparative Example 1 to Comparative Example 5 each have a planar structure, as compared to the Example Compounds, and thus Comparative Example Compounds C1 to C5 lack the structural characteristics that are sufficient to effectively protect a p-orbital of the boron atom with a steric protection substituent. In Comparative Example Compounds C1 to C5, there is insufficient space to bond a bulky substituent for increasing intermolecular distance, and even if a bulky substituent were to be connected to a fused ring core structure, side reactions may be caused due to intermolecular forces. Therefore, it can be seen that the light-emitting elements according to Comparative Examples 1 to 5 exhibit significantly reduced efficiency and lifespan compared to the light-emitting elements according to Examples.

Each of Comparative Example Compounds C6 and C7 has a structure in which a fused location of naphthalene is different from that of the polycyclic compound according to an embodiment. The light-emitting elements according to Comparative Examples 6 and 7, respectively using Comparative Example Compounds C6 and C7 as emission materials, exhibit significantly reduced lifespan as compared to the light-emitting elements according to the Examples.

Therefore, it can be confirmed that the polycyclic compound according to an embodiment may be used as an emission dopant material of a thermally activated delayed fluorescent (TADF) light-emitting element, which emits light in a wavelength region of green light and may exhibit low-driving voltage characteristics in a green wavelength region, and both high element efficiency and improved lifespan characteristics may be achieved.

The light-emitting element according to an embodiment may exhibit improved element characteristic of high efficiency and long lifespan.

The polycyclic compound according to an embodiment may be included in the emission layer of the light-emitting element, which may contribute to improvements in high efficiency and long lifespan of the light-emitting element.

The electronic apparatus according to an embodiment may exhibit excellent display quality.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light-emitting element comprising:
a first electrode;
a second electrode disposed on the first electrode; and
an emission layer disposed between the first electrode and the second electrode, wherein
the emission layer includes a first compound represented by Formula 1: 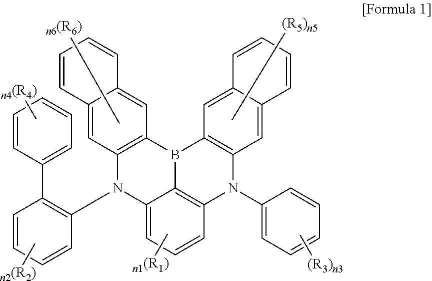
wherein in Formula 1,
R₁ to R₆ are each independently a hydrogen atom, a deuterium atom, a cyano group, a substituted or unsubstituted amine group, a substituted or unsubstituted oxy group, a substituted or unsubstituted thio group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, or bonded to an adjacent group to form a ring,
n1 is an integer from 0 to 3,
n2 is an integer from 0 to 4,
n3 and n4 are each independently an integer from 0 to 5, and
n5 and n6 are each independently an integer from 0 to 6.

2. The light-emitting element of claim 1, wherein the first compound is represented by Formula 2: 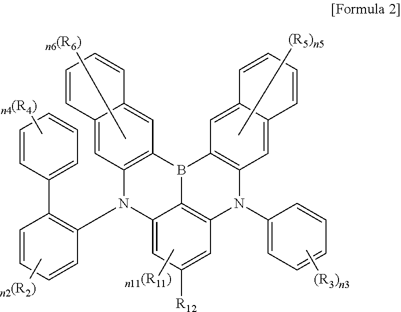
wherein in Formula 2,
R₁₁ is a hydrogen atom, a deuterium atom, a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons,
R₁₂ is a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons,
n11 is an integer from 0 to 2, and
R₂ to R₆ and n2 to n6 are the same as defined in Formula 1.

3. The light-emitting element of claim 1, wherein the first compound is represented by Formula 3: 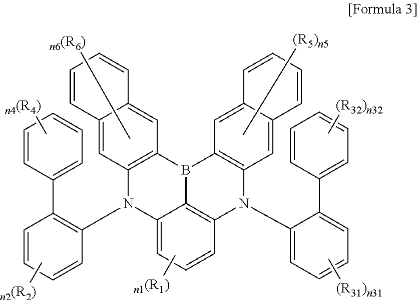
wherein in Formula 3,
R₃₁ and R₃₂ are each independently a hydrogen atom, a deuterium atom, a cyano group, a substituted or unsubstituted amine group, a substituted or unsubstituted oxy group, a substituted or unsubstituted thio group, a substituted or unsubstituted alkyl group having 1 to 30 carbons, a substituted or unsubstituted alkenyl group having 2 to 30 carbons, or a substituted or unsubstituted aryl group having 6 to 30 ring-forming carbons, or bonded to an adjacent group to form a ring,
n31 is an integer from 0 to 4,
n32 is an integer from 0 to 5, and
R₁, R₂, R₄ to R₆, n1, n2, and n4 to n6 are the same as defined in Formula 1.

4. The light-emitting element of claim 1, wherein the first compound is represented by one of Formula 4-1 to Formula 4-3: 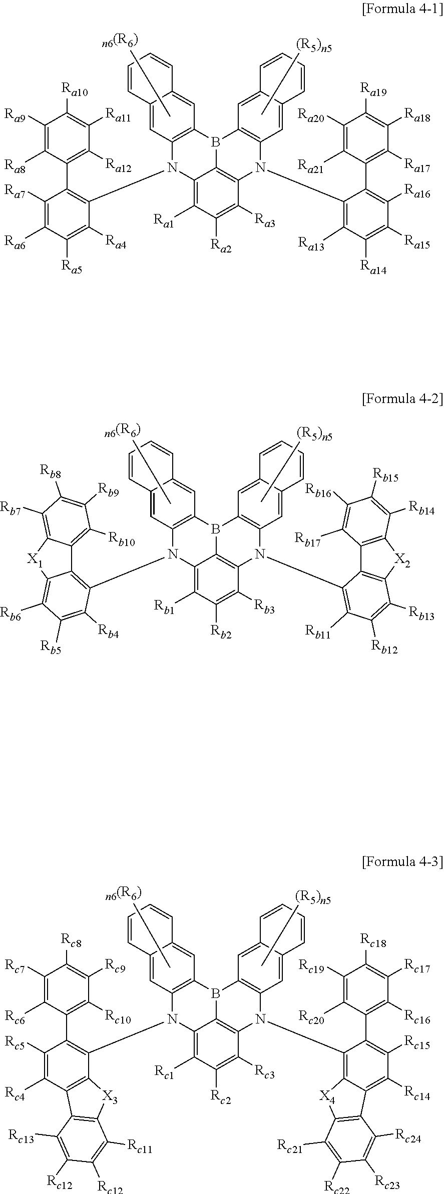
wherein in Formula 4-2 and Formula 4-3,
X₁ to X₄ are each independently O or S, and
wherein in Formula 4-1 to Formula 4-3,
Rₐ₁ to Rₐ₂₁, R_{b1} to R_{b17}, and R_{c1} to R_{c24} are each independently a hydrogen atom, a deuterium atom, a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons, and
R₅, R₆, n5, and n6 are the same as defined in Formula 1.

5. The light-emitting element of claim 1, wherein the first compound is represented by Formula 5-1 or Formula 5-2: 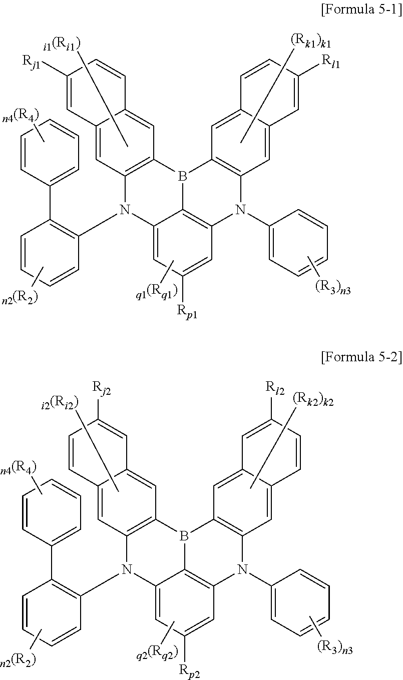
wherein in Formula 5-1 and Formula 5-2,
Rᵢ₁, Rᵢ₂, Rⱼ₁, Rⱼ₂, Rₖ₁, Rₖ₂, Rₗ₁, Rₗ₂, Rₚ₁, Rₚ₂, R_{q1}, and R_{q2} are each independently a hydrogen atom, a deuterium atom, a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons,
provided that at least one of Rⱼ₁, Rₗ₁, and Rₚ₁, and at least one of Rⱼ₂, Rₗ₂, and Rₚ₂ are each independently a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons,
i1, i2, k1, and k2 are each independently an integer from 0 to 5,
q1 and q2 are each independently an integer from 0 to 2, and
R₂ to R₄ and n2 to n4 are the same as defined in Formula 1.

6. The light-emitting element of claim 5, wherein the first compound is represented by Formula 5-1-1: 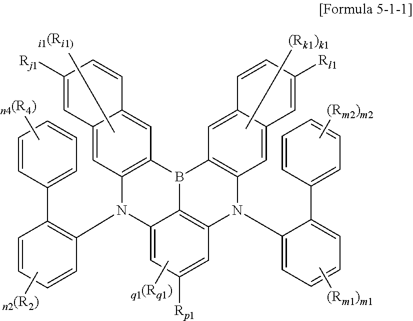
wherein in Formula 5-1-1,
Rₘ₁ and Rₘ₂ are each independently a hydrogen atom, a deuterium atom, a substituted or unsubstituted amine group, a substituted or unsubstituted oxy group, a substituted or unsubstituted thio group, a substituted or unsubstituted alkyl group having 1 to 30 carbons, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, a substituted or unsubstituted heteroaryl group having 2 to 30 ring-forming carbons, or bonded to an adjacent group to form a ring,
m1 is an integer from 0 to 4,
m2 is an integer from 0 to 5, and
R₂, R₄, Rᵢ₁, Rⱼ₁, Rₖ₁, Rₗ₁, Rₚ₁, R_{q1}, n2, n4, i1, k1, and q1 are the same as defined in Formula 1 and Formula 5-1.

7. The light-emitting element of claim 5, wherein the first compound is represented by Formula 5-2-1: 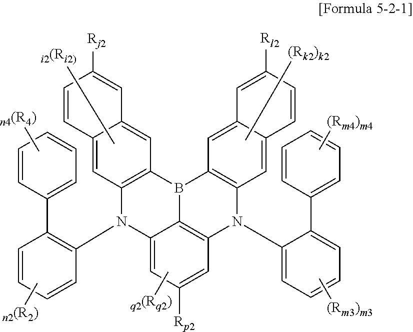
wherein in Formula 5-2-1,
Rₘ₃ and Rₘ₄ are each independently a hydrogen atom, a deuterium atom, a substituted or unsubstituted amine group, a substituted or unsubstituted oxy group, a substituted or unsubstituted thio group, a substituted or unsubstituted alkyl group having 1 to 30 carbons, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, a substituted or unsubstituted heteroaryl group having 2 to 30 ring-forming carbons, or bonded to an adjacent group to form a ring,
m3 is an integer from 0 to 4,
m4 is an integer from 0 to 5, and
R₂, R₄, Rᵢ₂, Rⱼ₂, Rₖ₂, Rₗ₂, Rₚ₂, R_{q2}, n2, n4, i2, k2, and q2 are the same as defined in Formula 1 and Formula 5-2.

8. The light-emitting element of claim 1, wherein the emission layer emits green light.

9. The light-emitting element of claim 1, wherein the emission layer further comprises:
at least one of a second compound represented by Formula HT-1, a third compound represented by Formula ET-1, and a fourth compound represented by Formula D-1: 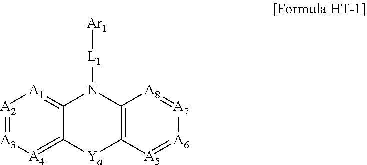
wherein in Formula HT-1,
A₁ to A₈ are each independently N or C(R₅₁),
L₁ is a direct linkage, a substituted or unsubstituted arylene group having 6 to 30 ring-forming carbons, or a substituted or unsubstituted heteroarylene group having 2 to 30 ring-forming carbons,
Yₐ is a direct linkage, C(R₅₂)(R₅₃), or Si(R₅₄)(R₅₅),
Ar₁ is a substituted or unsubstituted aryl group having 6 to 30 ring-forming carbons or a substituted or unsubstituted heteroaryl group having 2 to 30 ring-forming carbons,
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 60 ring-forming carbons, or a substituted or unsubstituted heteroaryl group having 2 to 60 ring-forming carbons, or bonded to an adjacent group to form a ring; 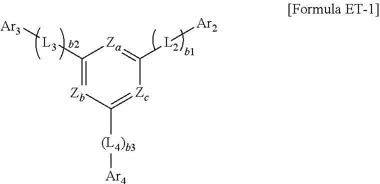
wherein in Formula ET-1,
at least one of Zₐ to Z_{c} is N,
the remainder of Zₐ to Z_{c} are each independently C(R₅₆),
R₅₆ is a hydrogen atom, a deuterium atom, a substituted or unsubstituted alkyl group having 1 to 20 carbons, a substituted or unsubstituted aryl group having 6 to 60 ring-forming carbons, or a substituted or unsubstituted heteroaryl group having 2 to 60 ring-forming carbons,
b1 to b3 are each independently an integer from 0 to 10,
Ar₂ to Ar₄ are each independently a hydrogen atom, a deuterium atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons, and
L₂ to L₄ are each independently a direct linkage, a substituted or unsubstituted arylene group having 6 to 30 ring-forming carbons, or a substituted or unsubstituted heteroarylene group having 2 to 30 ring-forming carbons; 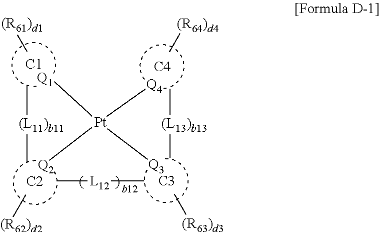
wherein in Formula D-1,
Q₁ to Q₄ are each independently C or N,
C1 to C4 are each independently a substituted or unsubstituted hydrocarbon ring having 5 to 30 ring-forming carbons or a substituted or unsubstituted heterocycle having 2 to 30 ring-forming carbons,
L₁₁ to L₁₃ are each independently a direct linkage, 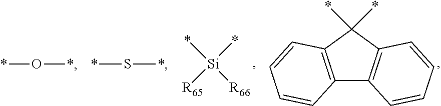
a substituted or unsubstituted alkylene group having 1 to 20 carbons, a substituted or unsubstituted arylene group having 6 to 30 ring-forming carbons, or a substituted or unsubstituted heteroarylene group having 2 to 30 ring-forming carbons,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 ring-forming carbons, a substituted or unsubstituted aryl group having 6 to 60 ring-forming carbons, or a substituted or unsubstituted heteroaryl group having 2 to 60 ring-forming carbons, or bonded to an adjacent group, and
d1 to d4 are each independently an integer from 0 to 4.

10. The light-emitting element of claim 1, wherein the first compound comprises at least one compound selected from Compound Group 1:

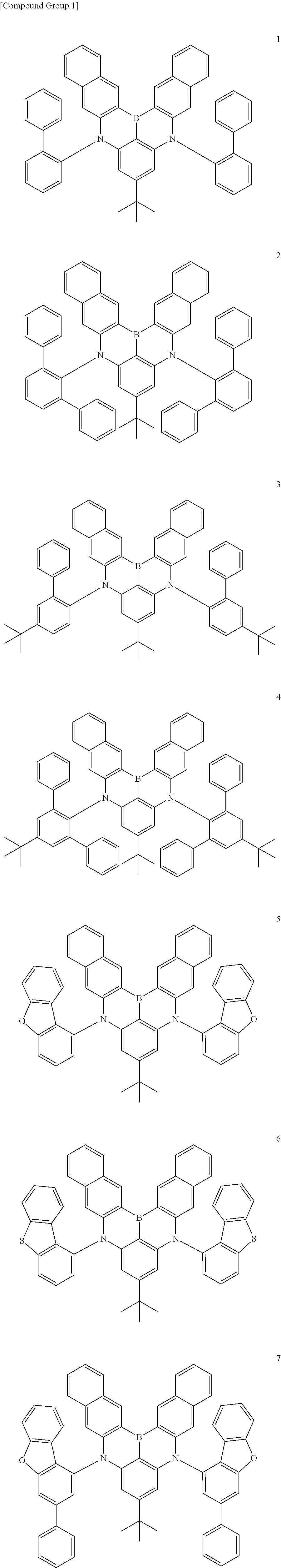

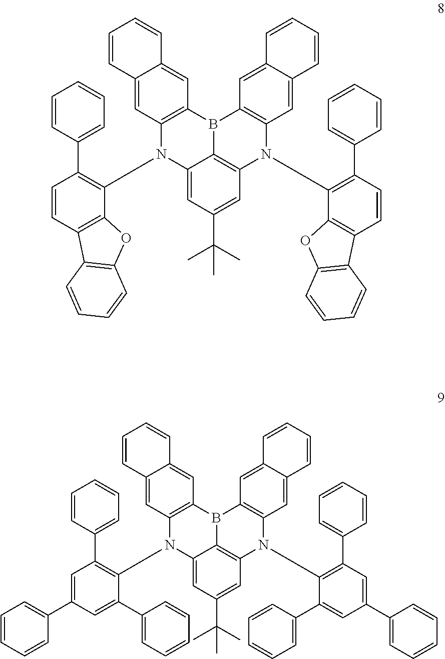 [SMILES: CC(C)(C)c1cc2c3c(c1)N(c1c(-c4ccccc4)ccc4c1oc1ccccc14)c1cc4ccccc4cc1B3c1cc3ccccc3cc1N2c1c(-c2ccccc2)ccc2c1oc1ccccc12 ; CC(C)(C)c1cc2c3c(c1)N(c1c(-c4ccccc4)cc(-c4ccccc4)cc1-c1ccccc1)c1cc4ccccc4cc1B3c1cc3ccccc3cc1N2c1c(-c2ccccc2)cc(-c2ccccc2)cc1-c1ccccc1]

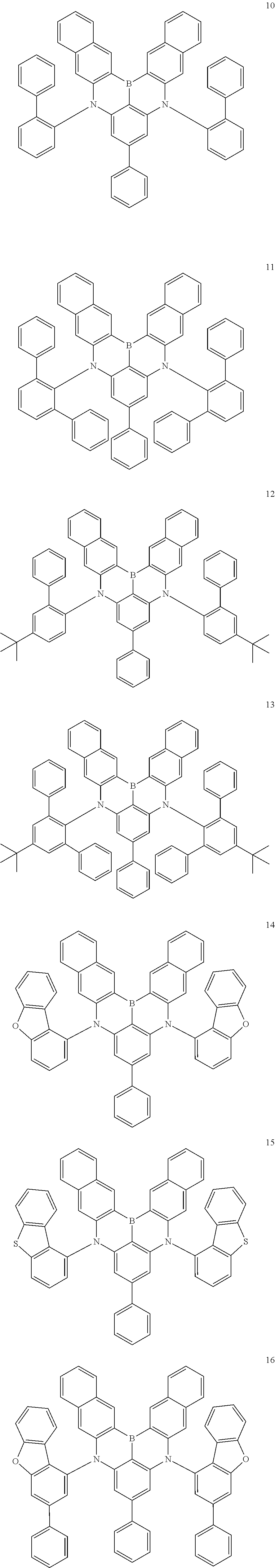

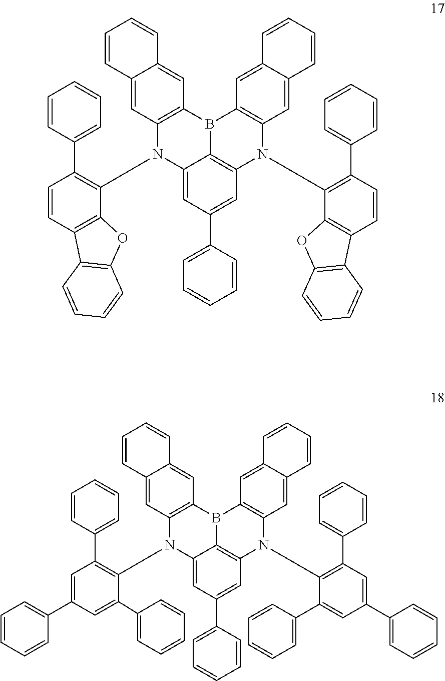 [SMILES: c1ccc(-c2cc3c4c(c2)N(c2c(-c5ccccc5)ccc5c2oc2ccccc25)c2cc5ccccc5cc2B4c2cc4ccccc4cc2N3c2c(-c3ccccc3)ccc3c2oc2ccccc23)cc1 ; c1ccc(-c2cc(-c3ccccc3)c(N3c4cc5ccccc5cc4B4c5cc6ccccc6cc5N(c5c(-c6ccccc6)cc(-c6ccccc6)cc5-c5ccccc5)c5cc(-c6ccccc6)cc3c54)c(-c3ccccc3)c2)cc1]

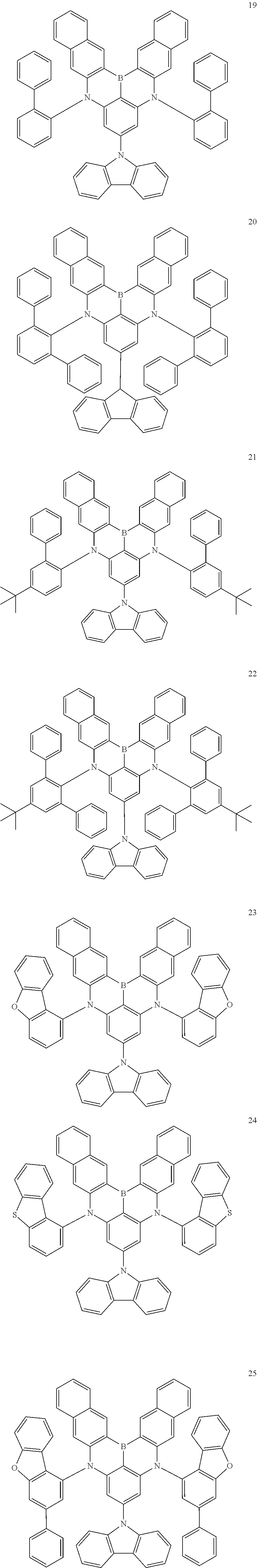

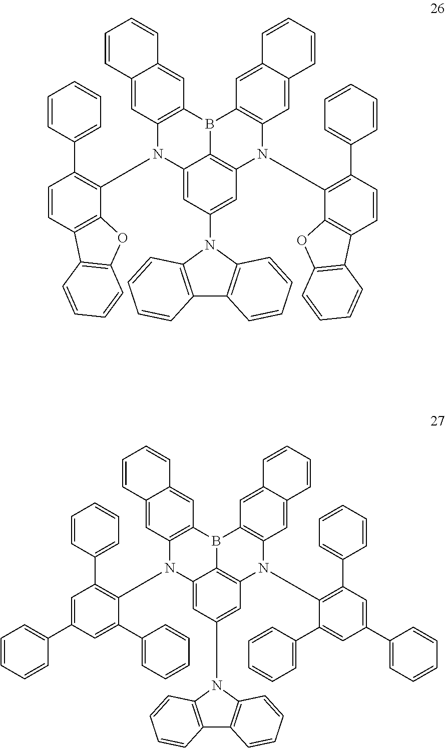 [SMILES: c1ccc(-c2ccc3c(oc4ccccc43)c2N2c3cc4ccccc4cc3B3c4cc5ccccc5cc4N(c4c(-c5ccccc5)ccc5c4oc4ccccc45)c4cc(-n5c6ccccc6c6ccccc65)cc2c43)cc1 ; c1ccc(-c2cc(-c3ccccc3)c(N3c4cc5ccccc5cc4B4c5cc6ccccc6cc5N(c5c(-c6ccccc6)cc(-c6ccccc6)cc5-c5ccccc5)c5cc(-n6c7ccccc7c7ccccc76)cc3c54)c(-c3ccccc3)c2)cc1]

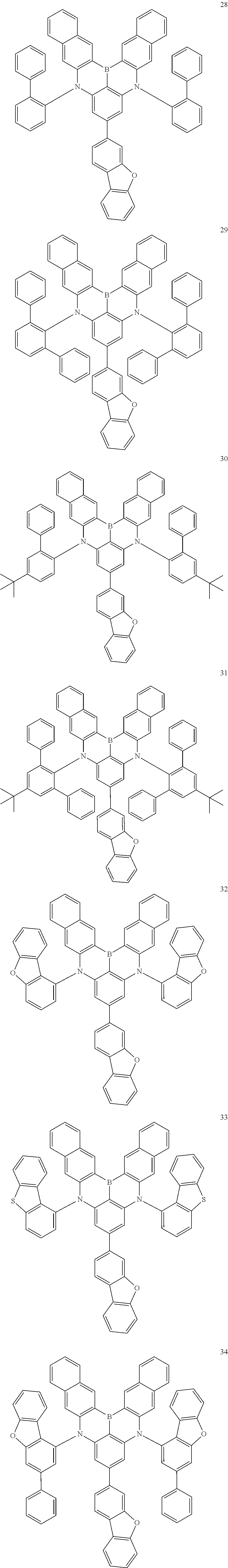

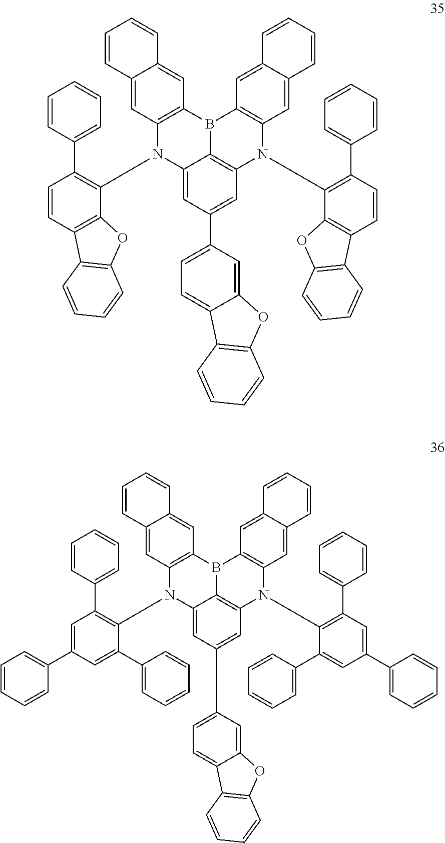 [SMILES: c1ccc(-c2ccc3c(oc4ccccc43)c2N2c3cc4ccccc4cc3B3c4cc5ccccc5cc4N(c4c(-c5ccccc5)ccc5c4oc4ccccc45)c4cc(-c5ccc6c(c5)oc5ccccc56)cc2c43)cc1 ; c1ccc(-c2cc(-c3ccccc3)c(N3c4cc5ccccc5cc4B4c5cc6ccccc6cc5N(c5c(-c6ccccc6)cc(-c6ccccc6)cc5-c5ccccc5)c5cc(-c6ccc7c(c6)oc6ccccc67)cc3c54)c(-c3ccccc3)c2)cc1]

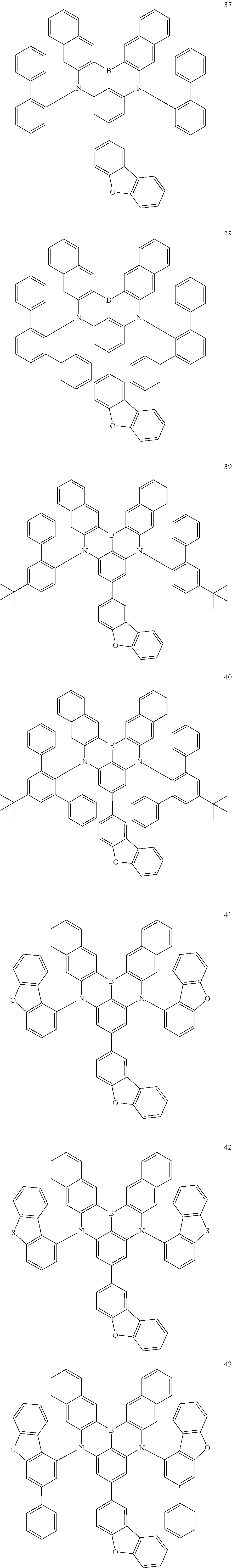

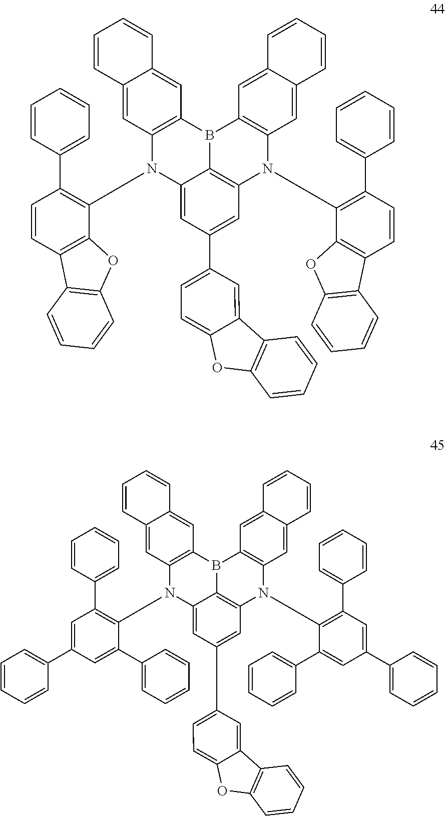 [SMILES: c1ccc(-c2ccc3c(oc4ccccc43)c2N2c3cc4ccccc4cc3B3c4cc5ccccc5cc4N(c4c(-c5ccccc5)ccc5c4oc4ccccc45)c4cc(-c5ccc6oc7ccccc7c6c5)cc2c43)cc1 ; c1ccc(-c2cc(-c3ccccc3)c(N3c4cc5ccccc5cc4B4c5cc6ccccc6cc5N(c5c(-c6ccccc6)cc(-c6ccccc6)cc5-c5ccccc5)c5cc(-c6ccc7oc8ccccc8c7c6)cc3c54)c(-c3ccccc3)c2)cc1]

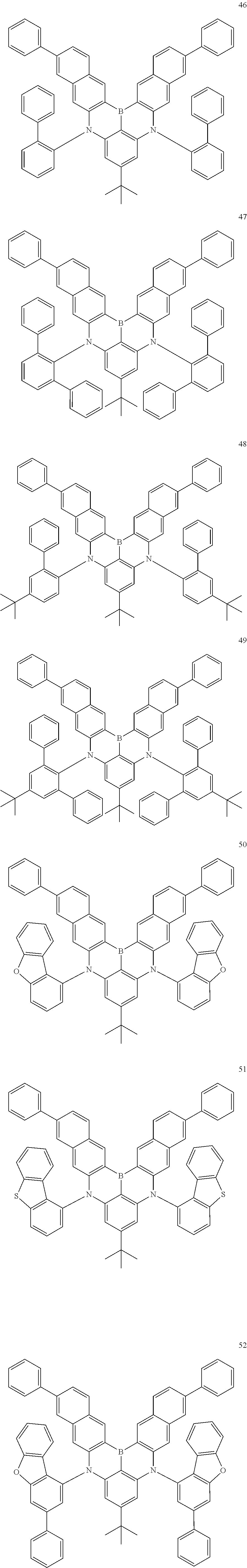

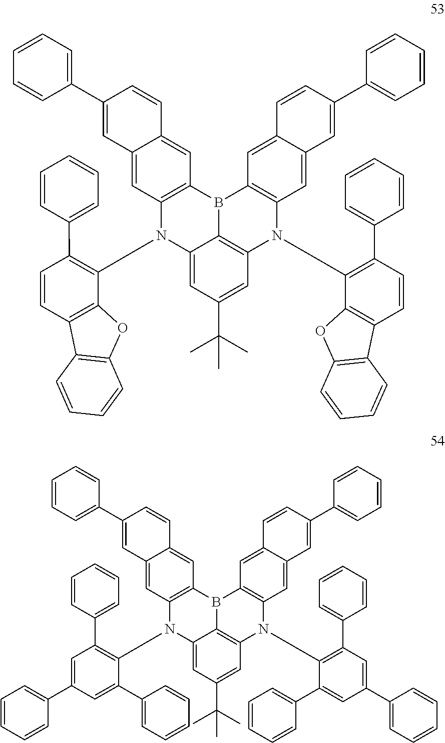 [SMILES: CC(C)(C)c1cc2c3c(c1)N(c1c(-c4ccccc4)ccc4c1oc1ccccc14)c1cc4cc(-c5ccccc5)ccc4cc1B3c1cc3ccc(-c4ccccc4)cc3cc1N2c1c(-c2ccccc2)ccc2c1oc1ccccc12 ; CC(C)(C)c1cc2c3c(c1)N(c1c(-c4ccccc4)cc(-c4ccccc4)cc1-c1ccccc1)c1cc4cc(-c5ccccc5)ccc4cc1B3c1cc3ccc(-c4ccccc4)cc3cc1N2c1c(-c2ccccc2)cc(-c2ccccc2)cc1-c1ccccc1]

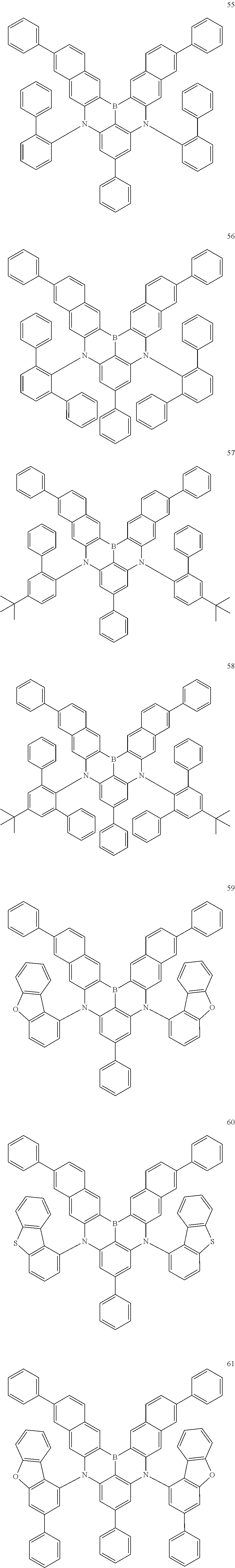

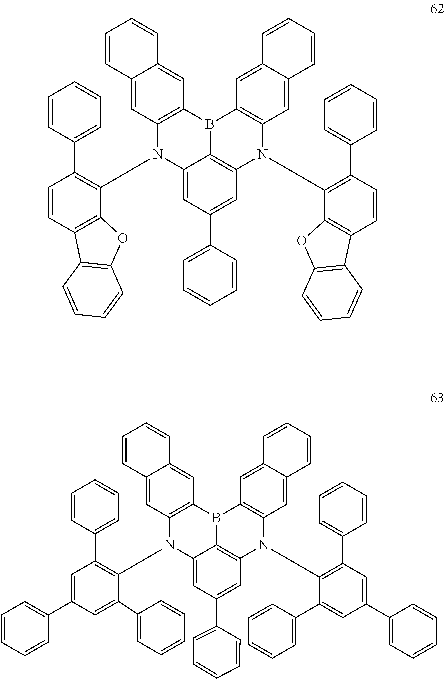 [SMILES: c1ccc(-c2cc3c4c(c2)N(c2c(-c5ccccc5)ccc5c2oc2ccccc25)c2cc5ccccc5cc2B4c2cc4ccccc4cc2N3c2c(-c3ccccc3)ccc3c2oc2ccccc23)cc1 ; c1ccc(-c2cc(-c3ccccc3)c(N3c4cc5ccccc5cc4B4c5cc6ccccc6cc5N(c5c(-c6ccccc6)cc(-c6ccccc6)cc5-c5ccccc5)c5cc(-c6ccccc6)cc3c54)c(-c3ccccc3)c2)cc1]

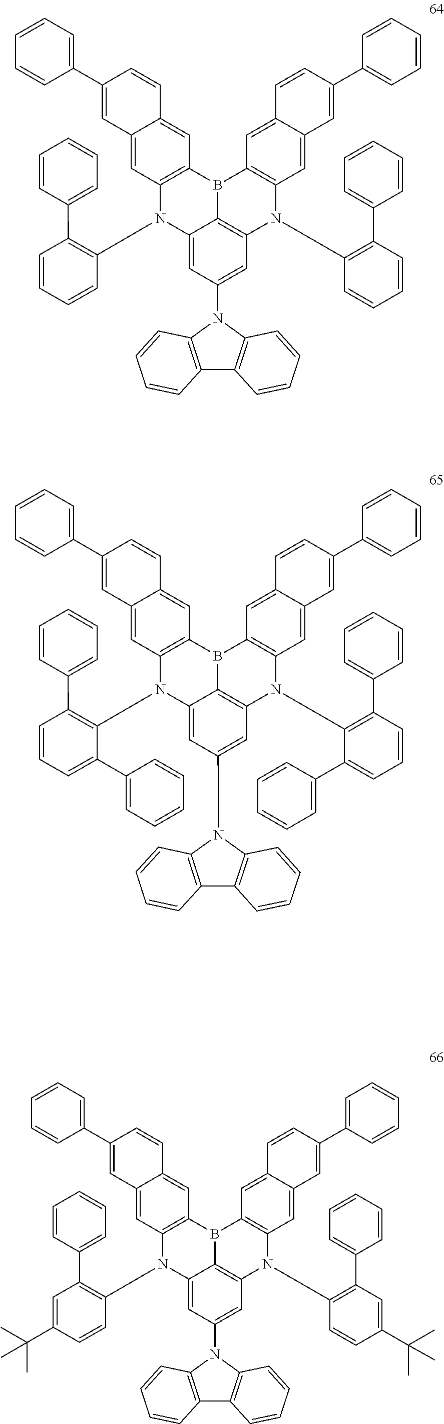 [SMILES: c1ccc(-c2ccc3cc4c(cc3c2)N(c2ccccc2-c2ccccc2)c2cc(-n3c5ccccc5c5ccccc53)cc3c2B4c2cc4ccc(-c5ccccc5)cc4cc2N3c2ccccc2-c2ccccc2)cc1 ; c1ccc(-c2ccc3cc4c(cc3c2)N(c2c(-c3ccccc3)cccc2-c2ccccc2)c2cc(-n3c5ccccc5c5ccccc53)cc3c2B4c2cc4ccc(-c5ccccc5)cc4cc2N3c2c(-c3ccccc3)cccc2-c2ccccc2)cc1 ; CC(C)(C)c1ccc(N2c3cc4cc(-c5ccccc5)ccc4cc3B3c4cc5ccc(-c6ccccc6)cc5cc4N(c4ccc(C(C)(C)C)cc4-c4ccccc4)c4cc(-n5c6ccccc6c6ccccc65)cc2c43)c(-c2ccccc2)c1]

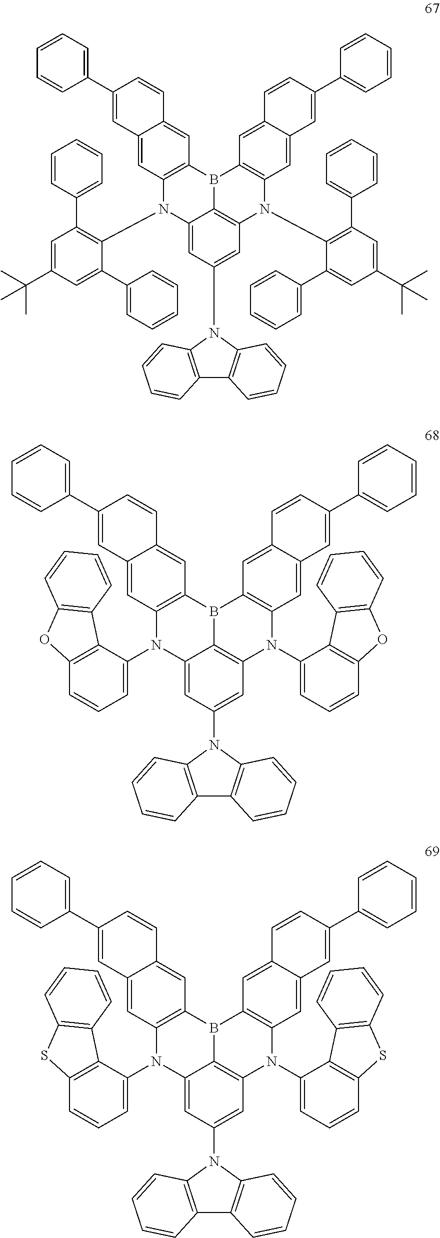 [SMILES: CC(C)(C)c1cc(-c2ccccc2)c(N2c3cc4cc(-c5ccccc5)ccc4cc3B3c4cc5ccc(-c6ccccc6)cc5cc4N(c4c(-c5ccccc5)cc(C(C)(C)C)cc4-c4ccccc4)c4cc(-n5c6ccccc6c6ccccc65)cc2c43)c(-c2ccccc2)c1 ; c1ccc(-c2ccc3cc4c(cc3c2)N(c2cccc3oc5ccccc5c23)c2cc(-n3c5ccccc5c5ccccc53)cc3c2B4c2cc4ccc(-c5ccccc5)cc4cc2N3c2cccc3oc4ccccc4c23)cc1 ; c1ccc(-c2ccc3cc4c(cc3c2)N(c2cccc3sc5ccccc5c23)c2cc(-n3c5ccccc5c5ccccc53)cc3c2B4c2cc4ccc(-c5ccccc5)cc4cc2N3c2cccc3sc4ccccc4c23)cc1]

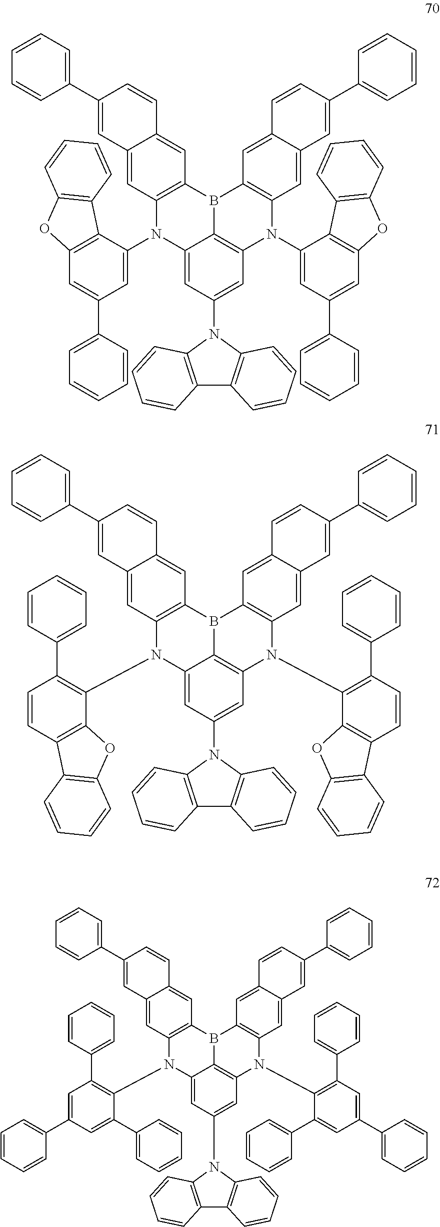 [SMILES: c1ccc(-c2ccc3cc4c(cc3c2)N(c2cc(-c3ccccc3)cc3oc5ccccc5c23)c2cc(-n3c5ccccc5c5ccccc53)cc3c2B4c2cc4ccc(-c5ccccc5)cc4cc2N3c2cc(-c3ccccc3)cc3oc4ccccc4c23)cc1 ; c1ccc(-c2ccc3cc4c(cc3c2)N(c2c(-c3ccccc3)ccc3c2oc2ccccc23)c2cc(-n3c5ccccc5c5ccccc53)cc3c2B4c2cc4ccc(-c5ccccc5)cc4cc2N3c2c(-c3ccccc3)ccc3c2oc2ccccc23)cc1 ; c1ccc(-c2cc(-c3ccccc3)c(N3c4cc5cc(-c6ccccc6)ccc5cc4B4c5cc6ccc(-c7ccccc7)cc6cc5N(c5c(-c6ccccc6)cc(-c6ccccc6)cc5-c5ccccc5)c5cc(-n6c7ccccc7c7ccccc76)cc3c54)c(-c3ccccc3)c2)cc1]

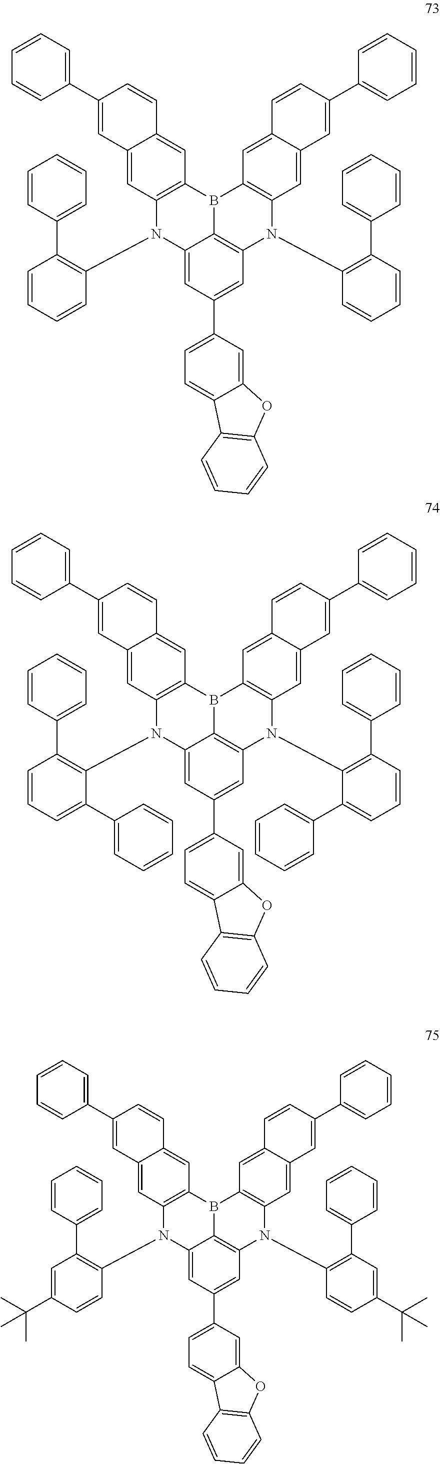 [SMILES: c1ccc(-c2ccc3cc4c(cc3c2)N(c2ccccc2-c2ccccc2)c2cc(-c3ccc5c(c3)oc3ccccc35)cc3c2B4c2cc4ccc(-c5ccccc5)cc4cc2N3c2ccccc2-c2ccccc2)cc1 ; c1ccc(-c2ccc3cc4c(cc3c2)N(c2c(-c3ccccc3)cccc2-c2ccccc2)c2cc(-c3ccc5c(c3)oc3ccccc35)cc3c2B4c2cc4ccc(-c5ccccc5)cc4cc2N3c2c(-c3ccccc3)cccc2-c2ccccc2)cc1 ; CC(C)(C)c1ccc(N2c3cc4cc(-c5ccccc5)ccc4cc3B3c4cc5ccc(-c6ccccc6)cc5cc4N(c4ccc(C(C)(C)C)cc4-c4ccccc4)c4cc(-c5ccc6c(c5)oc5ccccc56)cc2c43)c(-c2ccccc2)c1]

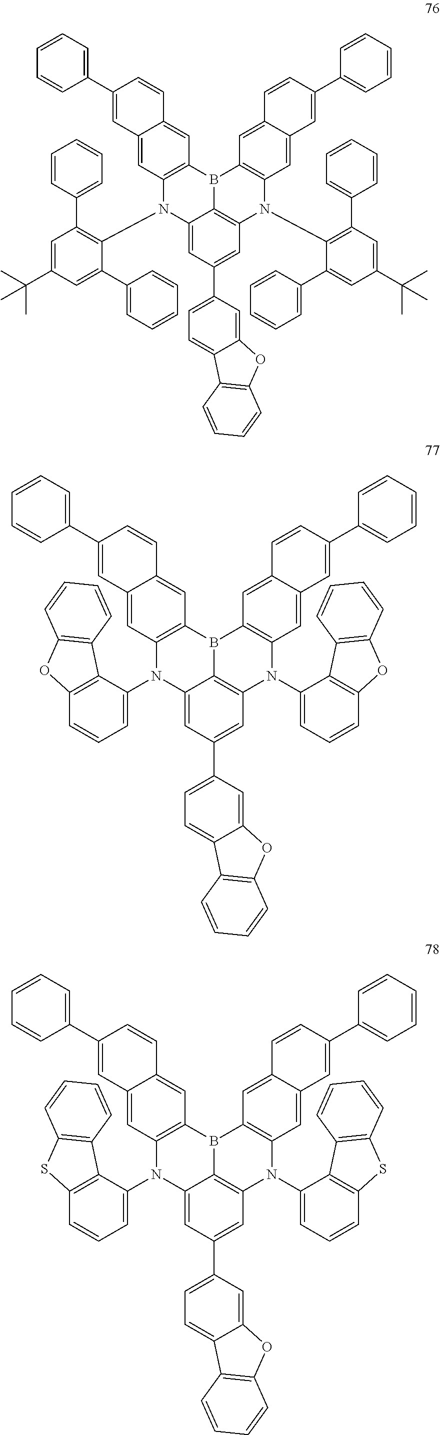 [SMILES: CC(C)(C)c1cc(-c2ccccc2)c(N2c3cc4cc(-c5ccccc5)ccc4cc3B3c4cc5ccc(-c6ccccc6)cc5cc4N(c4c(-c5ccccc5)cc(C(C)(C)C)cc4-c4ccccc4)c4cc(-c5ccc6c(c5)oc5ccccc56)cc2c43)c(-c2ccccc2)c1 ; c1ccc(-c2ccc3cc4c(cc3c2)N(c2cccc3oc5ccccc5c23)c2cc(-c3ccc5c(c3)oc3ccccc35)cc3c2B4c2cc4ccc(-c5ccccc5)cc4cc2N3c2cccc3oc4ccccc4c23)cc1 ; c1ccc(-c2ccc3cc4c(cc3c2)N(c2cccc3sc5ccccc5c23)c2cc(-c3ccc5c(c3)oc3ccccc35)cc3c2B4c2cc4ccc(-c5ccccc5)cc4cc2N3c2cccc3sc4ccccc4c23)cc1]

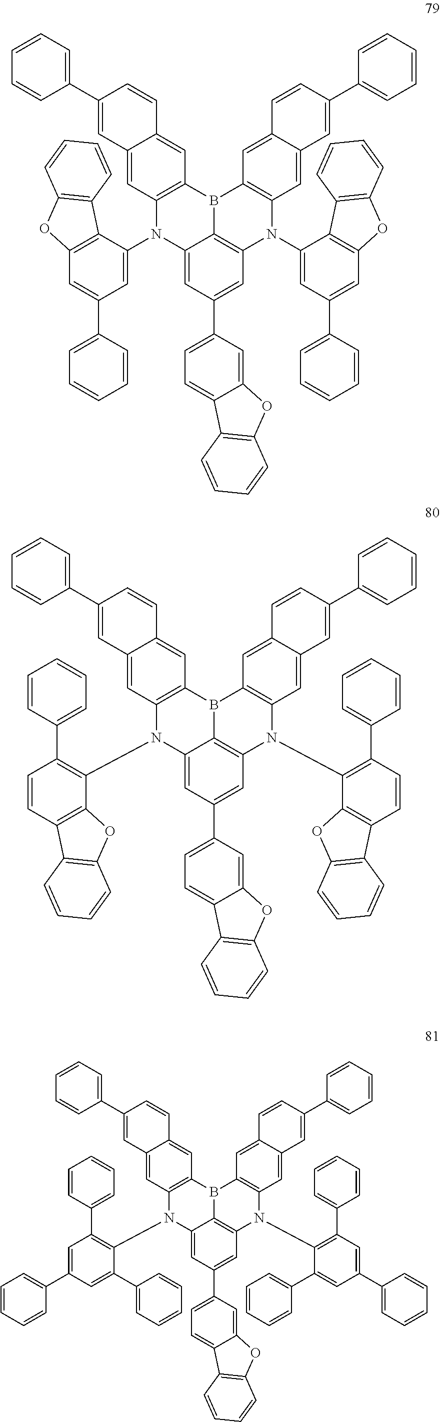 [SMILES: c1ccc(-c2ccc3cc4c(cc3c2)N(c2cc(-c3ccccc3)cc3oc5ccccc5c23)c2cc(-c3ccc5c(c3)oc3ccccc35)cc3c2B4c2cc4ccc(-c5ccccc5)cc4cc2N3c2cc(-c3ccccc3)cc3oc4ccccc4c23)cc1 ; c1ccc(-c2ccc3cc4c(cc3c2)N(c2c(-c3ccccc3)ccc3c2oc2ccccc23)c2cc(-c3ccc5c(c3)oc3ccccc35)cc3c2B4c2cc4ccc(-c5ccccc5)cc4cc2N3c2c(-c3ccccc3)ccc3c2oc2ccccc23)cc1 ; c1ccc(-c2cc(-c3ccccc3)c(N3c4cc5cc(-c6ccccc6)ccc5cc4B4c5cc6ccc(-c7ccccc7)cc6cc5N(c5c(-c6ccccc6)cc(-c6ccccc6)cc5-c5ccccc5)c5cc(-c6ccc7c(c6)oc6ccccc67)cc3c54)c(-c3ccccc3)c2)cc1]

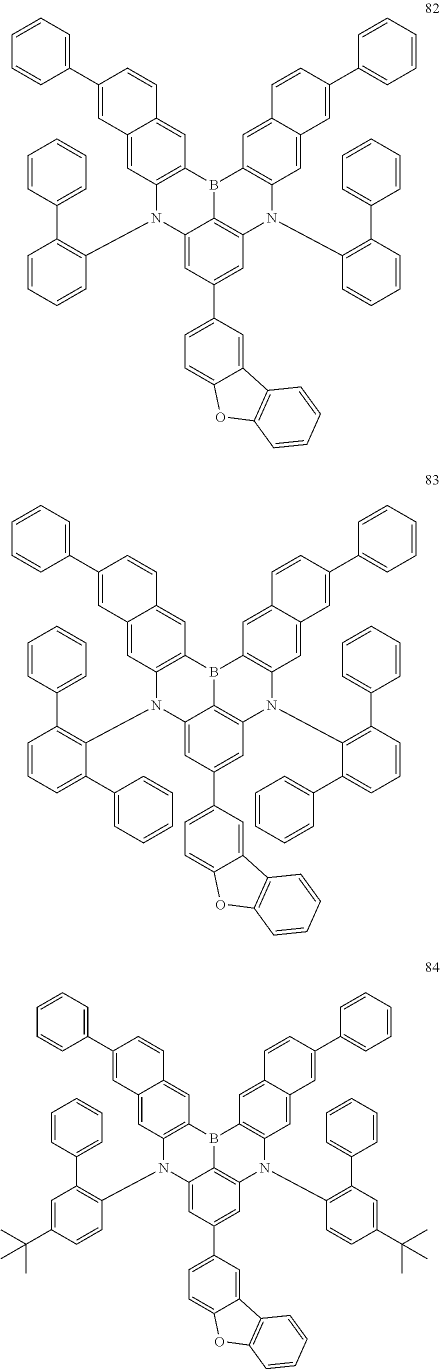 [SMILES: c1ccc(-c2ccc3cc4c(cc3c2)N(c2ccccc2-c2ccccc2)c2cc(-c3ccc5oc6ccccc6c5c3)cc3c2B4c2cc4ccc(-c5ccccc5)cc4cc2N3c2ccccc2-c2ccccc2)cc1 ; c1ccc(-c2ccc3cc4c(cc3c2)N(c2c(-c3ccccc3)cccc2-c2ccccc2)c2cc(-c3ccc5oc6ccccc6c5c3)cc3c2B4c2cc4ccc(-c5ccccc5)cc4cc2N3c2c(-c3ccccc3)cccc2-c2ccccc2)cc1 ; CC(C)(C)c1ccc(N2c3cc4cc(-c5ccccc5)ccc4cc3B3c4cc5ccc(-c6ccccc6)cc5cc4N(c4ccc(C(C)(C)C)cc4-c4ccccc4)c4cc(-c5ccc6oc7ccccc7c6c5)cc2c43)c(-c2ccccc2)c1]

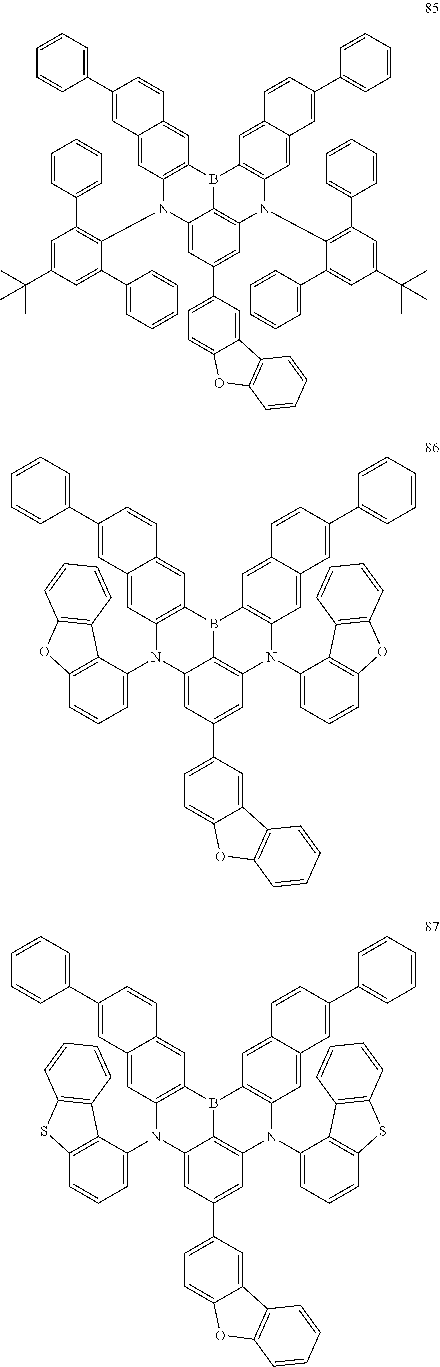 [SMILES: CC(C)(C)c1cc(-c2ccccc2)c(N2c3cc4cc(-c5ccccc5)ccc4cc3B3c4cc5ccc(-c6ccccc6)cc5cc4N(c4c(-c5ccccc5)cc(C(C)(C)C)cc4-c4ccccc4)c4cc(-c5ccc6oc7ccccc7c6c5)cc2c43)c(-c2ccccc2)c1 ; c1ccc(-c2ccc3cc4c(cc3c2)N(c2cccc3oc5ccccc5c23)c2cc(-c3ccc5oc6ccccc6c5c3)cc3c2B4c2cc4ccc(-c5ccccc5)cc4cc2N3c2cccc3oc4ccccc4c23)cc1 ; c1ccc(-c2ccc3cc4c(cc3c2)N(c2cccc3sc5ccccc5c23)c2cc(-c3ccc5oc6ccccc6c5c3)cc3c2B4c2cc4ccc(-c5ccccc5)cc4cc2N3c2cccc3sc4ccccc4c23)cc1]

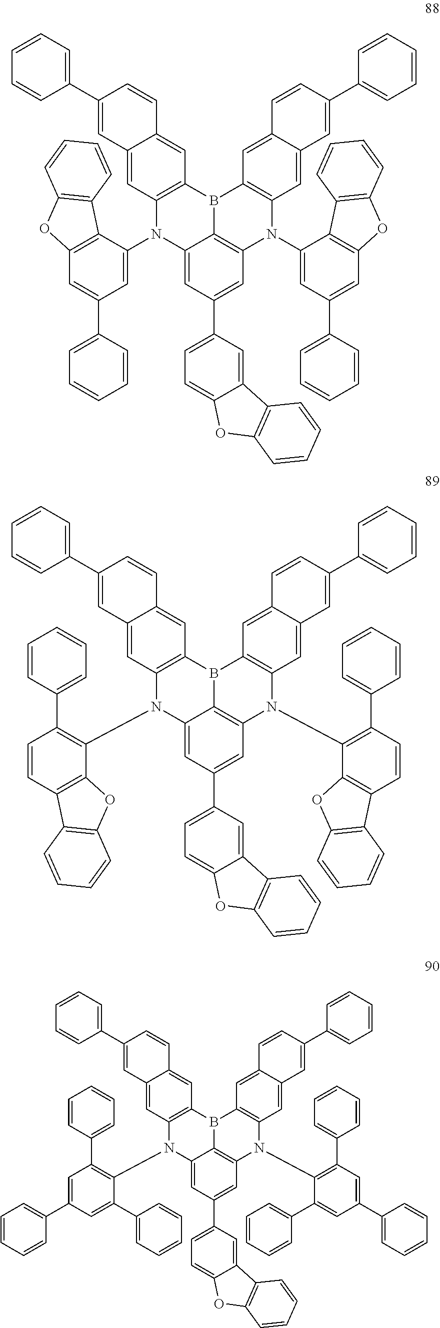 [SMILES: c1ccc(-c2ccc3cc4c(cc3c2)N(c2cc(-c3ccccc3)cc3oc5ccccc5c23)c2cc(-c3ccc5oc6ccccc6c5c3)cc3c2B4c2cc4ccc(-c5ccccc5)cc4cc2N3c2cc(-c3ccccc3)cc3oc4ccccc4c23)cc1 ; c1ccc(-c2ccc3cc4c(cc3c2)N(c2c(-c3ccccc3)ccc3c2oc2ccccc23)c2cc(-c3ccc5oc6ccccc6c5c3)cc3c2B4c2cc4ccc(-c5ccccc5)cc4cc2N3c2c(-c3ccccc3)ccc3c2oc2ccccc23)cc1 ; c1ccc(-c2cc(-c3ccccc3)c(N3c4cc5cc(-c6ccccc6)ccc5cc4B4c5cc6ccc(-c7ccccc7)cc6cc5N(c5c(-c6ccccc6)cc(-c6ccccc6)cc5-c5ccccc5)c5cc(-c6ccc7oc8ccccc8c7c6)cc3c54)c(-c3ccccc3)c2)cc1]

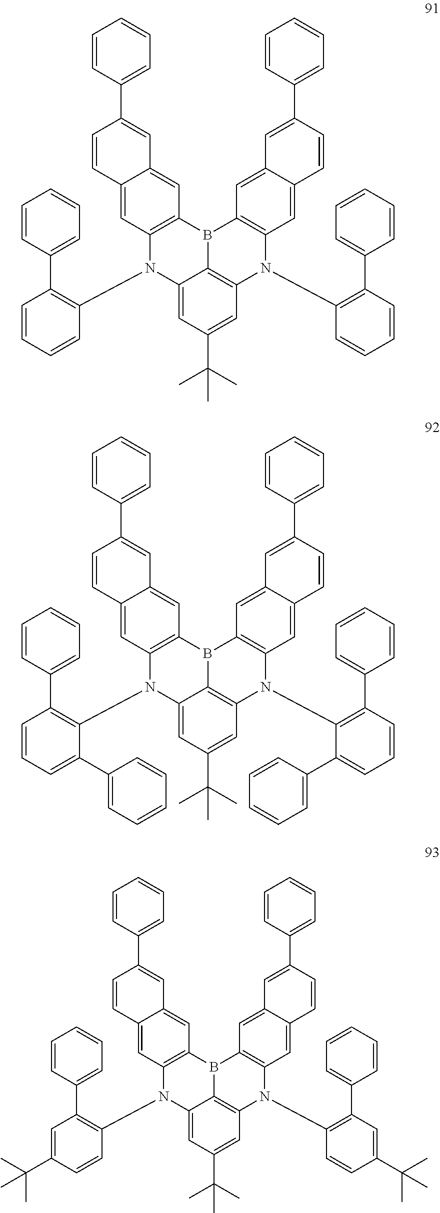 [SMILES: CC(C)(C)c1cc2c3c(c1)N(c1ccccc1-c1ccccc1)c1cc4ccc(-c5ccccc5)cc4cc1B3c1cc3cc(-c4ccccc4)ccc3cc1N2c1ccccc1-c1ccccc1 ; CC(C)(C)c1cc2c3c(c1)N(c1c(-c4ccccc4)cccc1-c1ccccc1)c1cc4ccc(-c5ccccc5)cc4cc1B3c1cc3cc(-c4ccccc4)ccc3cc1N2c1c(-c2ccccc2)cccc1-c1ccccc1 ; CC(C)(C)c1ccc(N2c3cc4ccc(-c5ccccc5)cc4cc3B3c4cc5cc(-c6ccccc6)ccc5cc4N(c4ccc(C(C)(C)C)cc4-c4ccccc4)c4cc(C(C)(C)C)cc2c43)c(-c2ccccc2)c1]

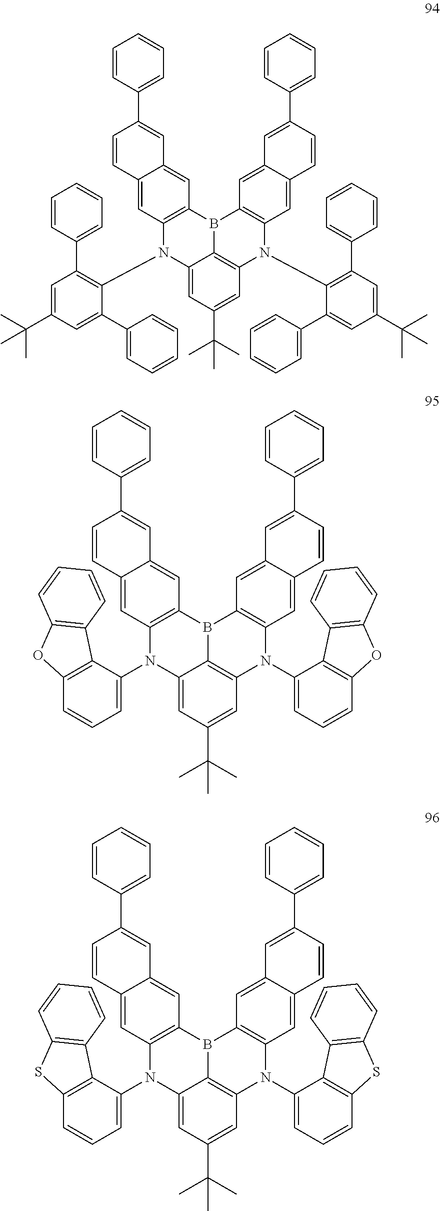

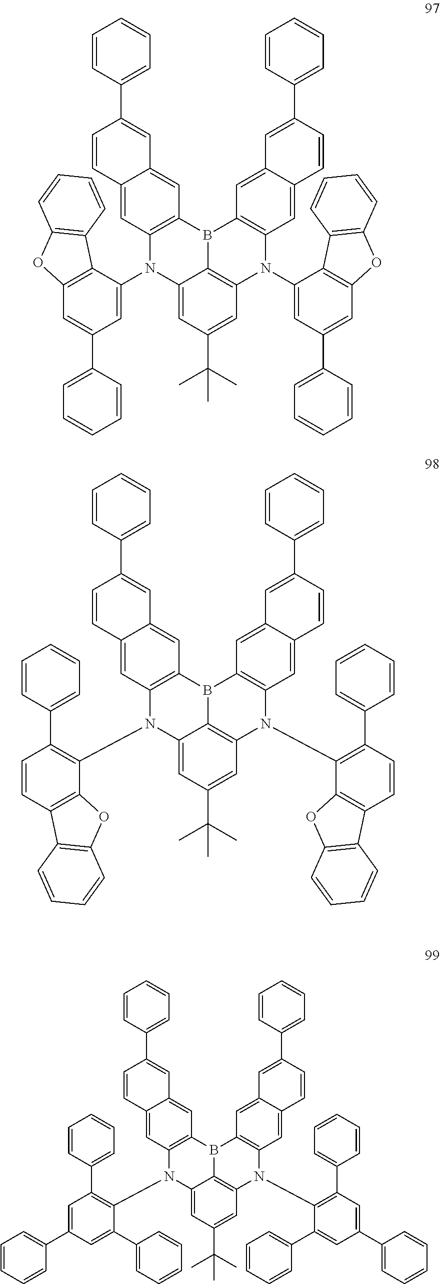 [SMILES: CC(C)(C)c1cc2c3c(c1)N(c1cc(-c4ccccc4)cc4oc5ccccc5c14)c1cc4ccc(-c5ccccc5)cc4cc1B3c1cc3cc(-c4ccccc4)ccc3cc1N2c1cc(-c2ccccc2)cc2oc3ccccc3c12 ; CC(C)(C)c1cc2c3c(c1)N(c1c(-c4ccccc4)ccc4c1oc1ccccc14)c1cc4ccc(-c5ccccc5)cc4cc1B3c1cc3cc(-c4ccccc4)ccc3cc1N2c1c(-c2ccccc2)ccc2c1oc1ccccc12 ; CC(C)(C)c1cc2c3c(c1)N(c1c(-c4ccccc4)cc(-c4ccccc4)cc1-c1ccccc1)c1cc4ccc(-c5ccccc5)cc4cc1B3c1cc3cc(-c4ccccc4)ccc3cc1N2c1c(-c2ccccc2)cc(-c2ccccc2)cc1-c1ccccc1]

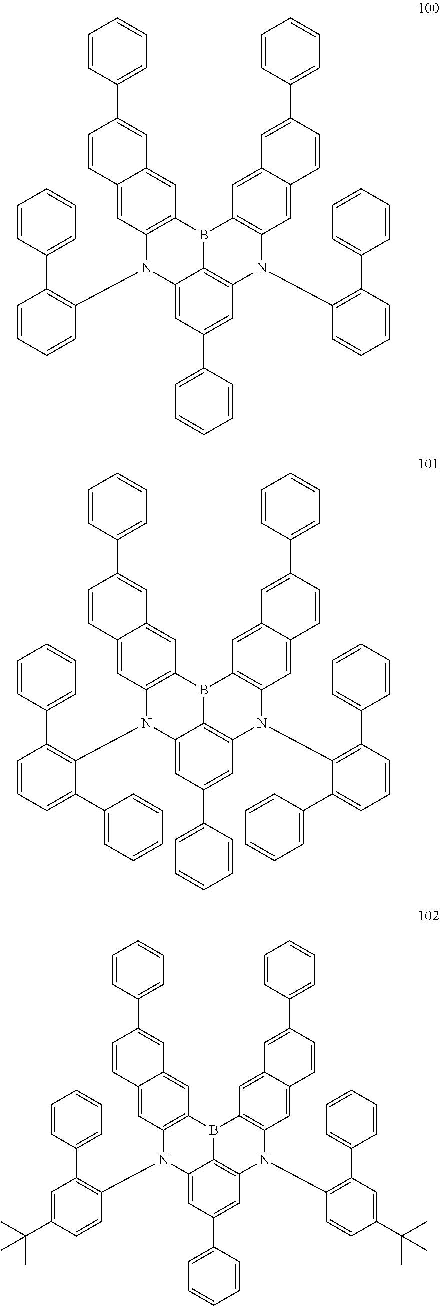 [SMILES: c1ccc(-c2cc3c4c(c2)N(c2ccccc2-c2ccccc2)c2cc5ccc(-c6ccccc6)cc5cc2B4c2cc4cc(-c5ccccc5)ccc4cc2N3c2ccccc2-c2ccccc2)cc1 ; c1ccc(-c2cc3c4c(c2)N(c2c(-c5ccccc5)cccc2-c2ccccc2)c2cc5ccc(-c6ccccc6)cc5cc2B4c2cc4cc(-c5ccccc5)ccc4cc2N3c2c(-c3ccccc3)cccc2-c2ccccc2)cc1 ; CC(C)(C)c1ccc(N2c3cc4ccc(-c5ccccc5)cc4cc3B3c4cc5cc(-c6ccccc6)ccc5cc4N(c4ccc(C(C)(C)C)cc4-c4ccccc4)c4cc(-c5ccccc5)cc2c43)c(-c2ccccc2)c1]

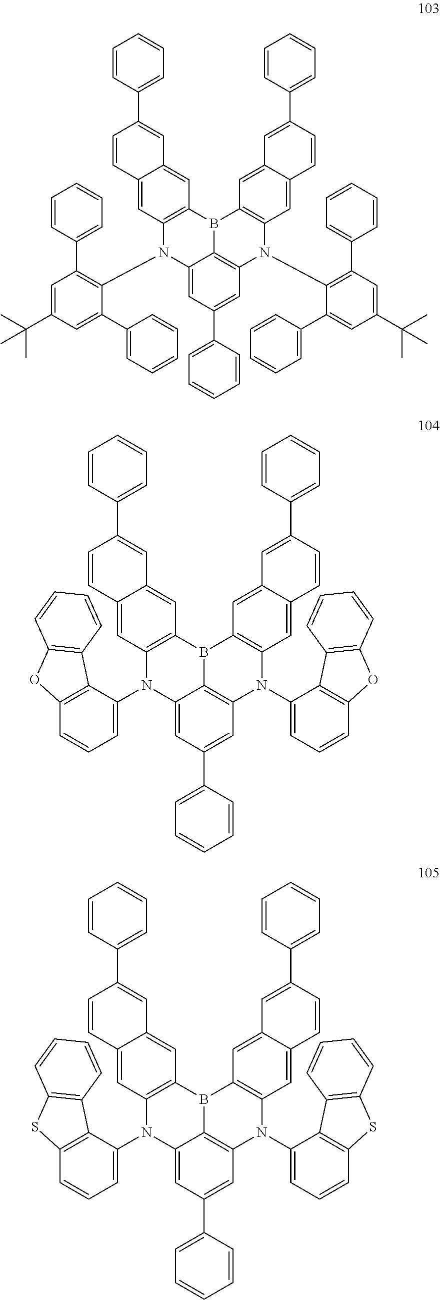 [SMILES: CC(C)(C)c1cc(-c2ccccc2)c(N2c3cc4ccc(-c5ccccc5)cc4cc3B3c4cc5cc(-c6ccccc6)ccc5cc4N(c4c(-c5ccccc5)cc(C(C)(C)C)cc4-c4ccccc4)c4cc(-c5ccccc5)cc2c43)c(-c2ccccc2)c1 ; c1ccc(-c2cc3c4c(c2)N(c2cccc5oc6ccccc6c25)c2cc5ccc(-c6ccccc6)cc5cc2B4c2cc4cc(-c5ccccc5)ccc4cc2N3c2cccc3oc4ccccc4c23)cc1 ; c1ccc(-c2cc3c4c(c2)N(c2cccc5sc6ccccc6c25)c2cc5ccc(-c6ccccc6)cc5cc2B4c2cc4cc(-c5ccccc5)ccc4cc2N3c2cccc3sc4ccccc4c23)cc1]

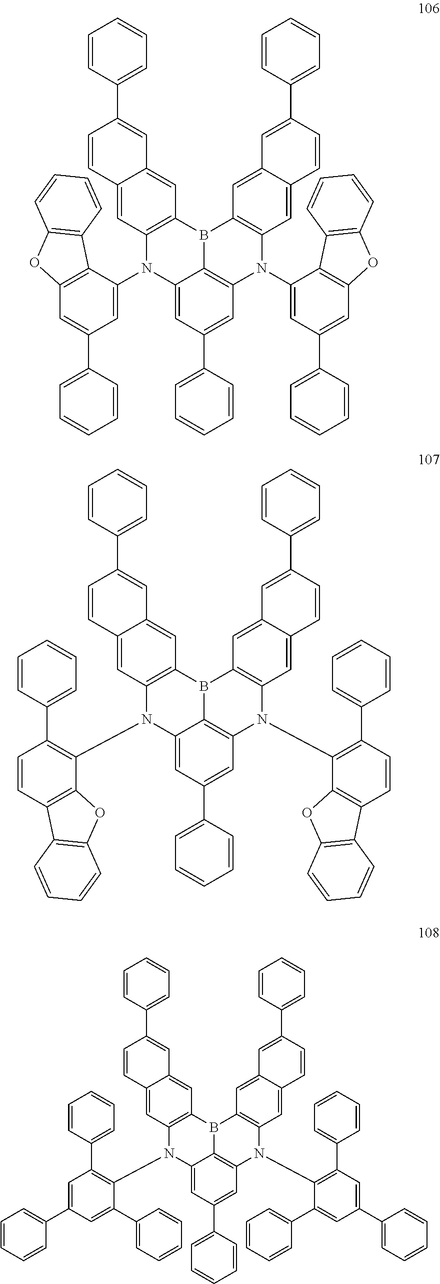

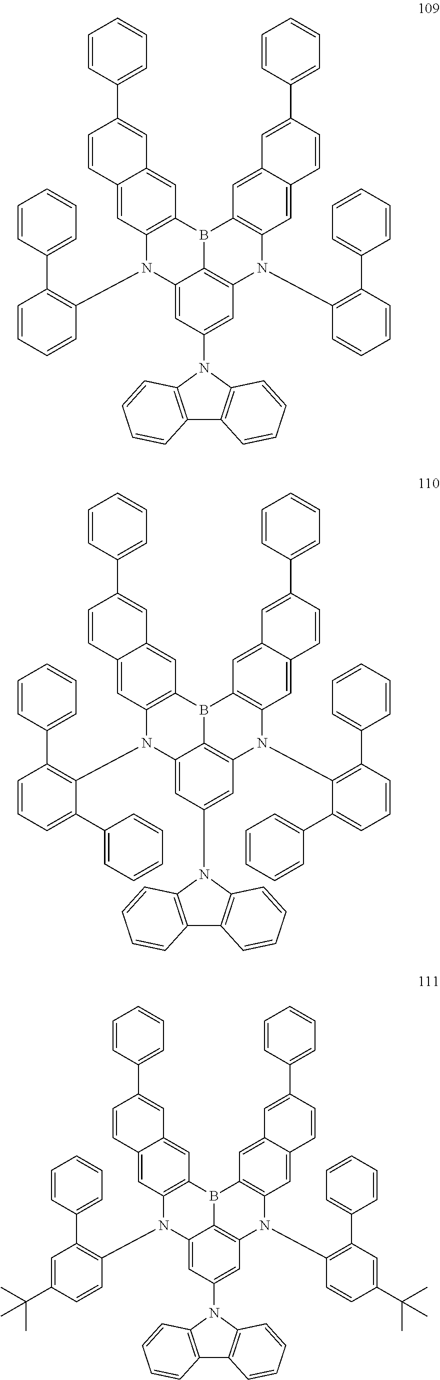 [SMILES: c1ccc(-c2ccc3cc4c(cc3c2)B2c3cc5cc(-c6ccccc6)ccc5cc3N(c3ccccc3-c3ccccc3)c3cc(-n5c6ccccc6c6ccccc65)cc(c32)N4c2ccccc2-c2ccccc2)cc1 ; c1ccc(-c2ccc3cc4c(cc3c2)B2c3cc5cc(-c6ccccc6)ccc5cc3N(c3c(-c5ccccc5)cccc3-c3ccccc3)c3cc(-n5c6ccccc6c6ccccc65)cc(c32)N4c2c(-c3ccccc3)cccc2-c2ccccc2)cc1 ; CC(C)(C)c1ccc(N2c3cc4ccc(-c5ccccc5)cc4cc3B3c4cc5cc(-c6ccccc6)ccc5cc4N(c4ccc(C(C)(C)C)cc4-c4ccccc4)c4cc(-n5c6ccccc6c6ccccc65)cc2c43)c(-c2ccccc2)c1]

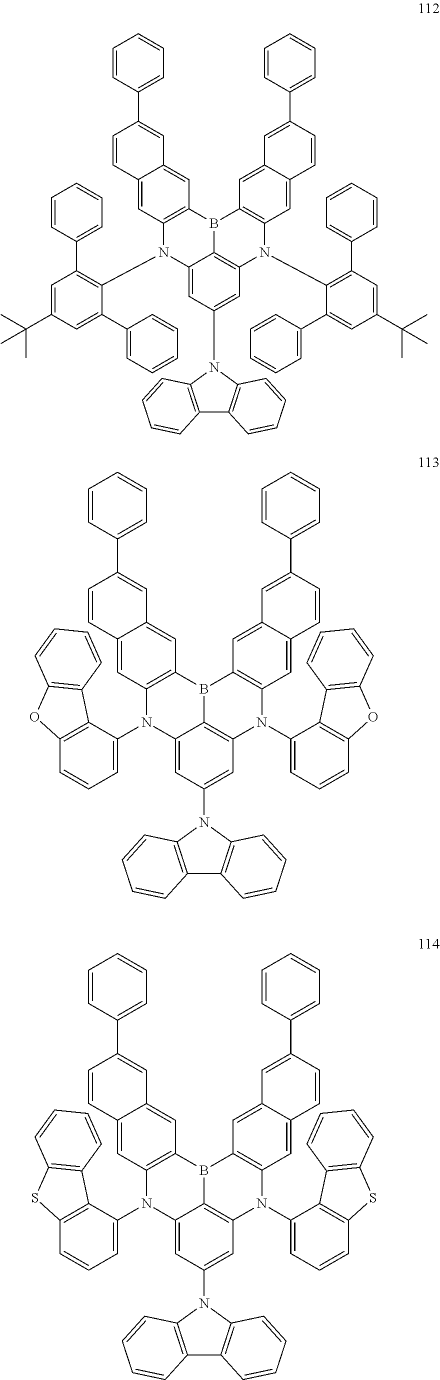

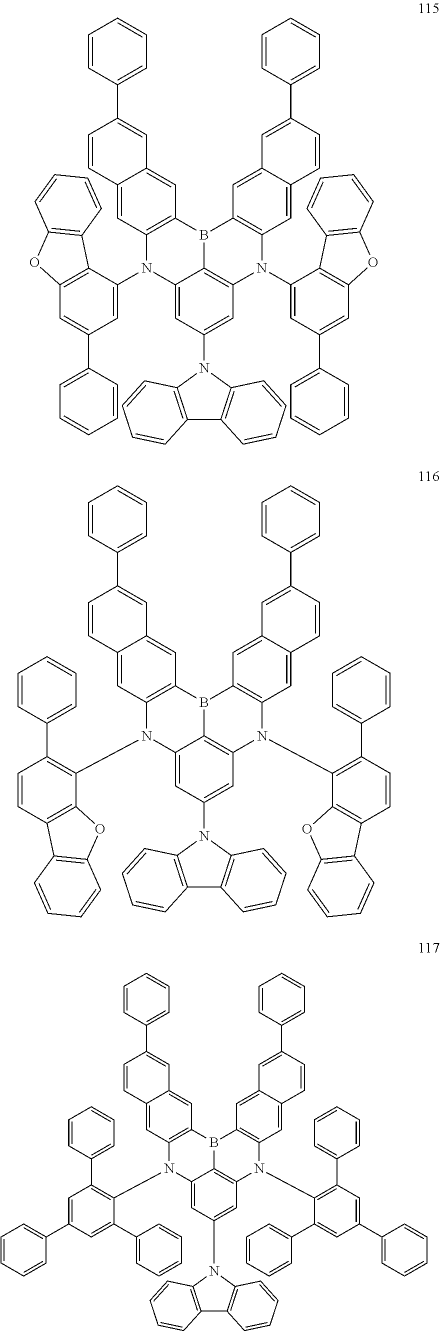 [SMILES: c1ccc(-c2ccc3cc4c(cc3c2)B2c3cc5cc(-c6ccccc6)ccc5cc3N(c3cc(-c5ccccc5)cc5oc6ccccc6c35)c3cc(-n5c6ccccc6c6ccccc65)cc(c32)N4c2cc(-c3ccccc3)cc3oc4ccccc4c23)cc1 ; c1ccc(-c2ccc3cc4c(cc3c2)B2c3cc5cc(-c6ccccc6)ccc5cc3N(c3c(-c5ccccc5)ccc5c3oc3ccccc35)c3cc(-n5c6ccccc6c6ccccc65)cc(c32)N4c2c(-c3ccccc3)ccc3c2oc2ccccc23)cc1 ; c1ccc(-c2cc(-c3ccccc3)c(N3c4cc5ccc(-c6ccccc6)cc5cc4B4c5cc6cc(-c7ccccc7)ccc6cc5N(c5c(-c6ccccc6)cc(-c6ccccc6)cc5-c5ccccc5)c5cc(-n6c7ccccc7c7ccccc76)cc3c54)c(-c3ccccc3)c2)cc1]

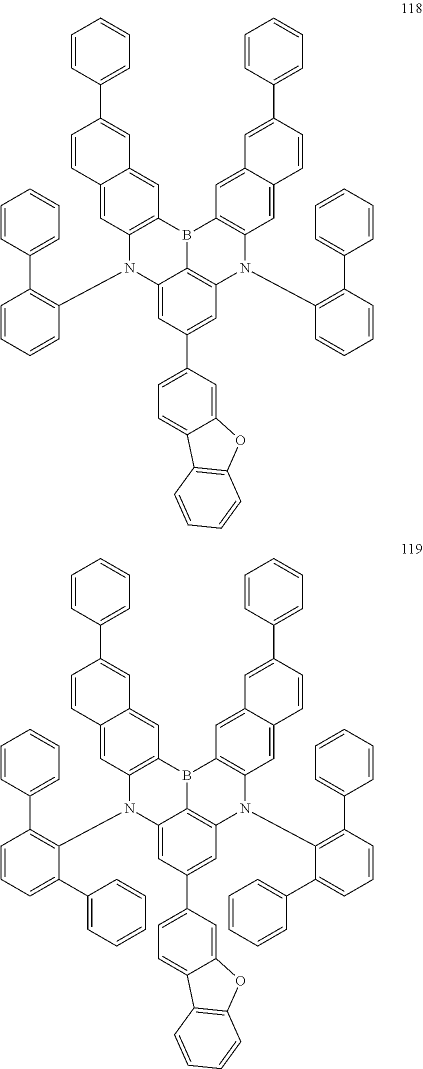 [SMILES: c1ccc(-c2ccc3cc4c(cc3c2)B2c3cc5cc(-c6ccccc6)ccc5cc3N(c3ccccc3-c3ccccc3)c3cc(-c5ccc6c(c5)oc5ccccc56)cc(c32)N4c2ccccc2-c2ccccc2)cc1 ; c1ccc(-c2ccc3cc4c(cc3c2)B2c3cc5cc(-c6ccccc6)ccc5cc3N(c3c(-c5ccccc5)cccc3-c3ccccc3)c3cc(-c5ccc6c(c5)oc5ccccc56)cc(c32)N4c2c(-c3ccccc3)cccc2-c2ccccc2)cc1]

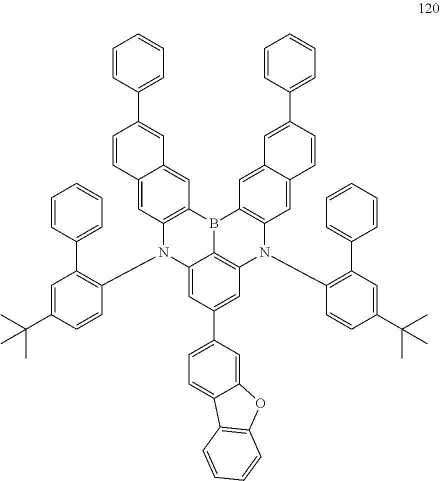 [SMILES: CC(C)(C)c1ccc(N2c3cc4ccc(-c5ccccc5)cc4cc3B3c4cc5cc(-c6ccccc6)ccc5cc4N(c4ccc(C(C)(C)C)cc4-c4ccccc4)c4cc(-c5ccc6c(c5)oc5ccccc56)cc2c43)c(-c2ccccc2)c1]

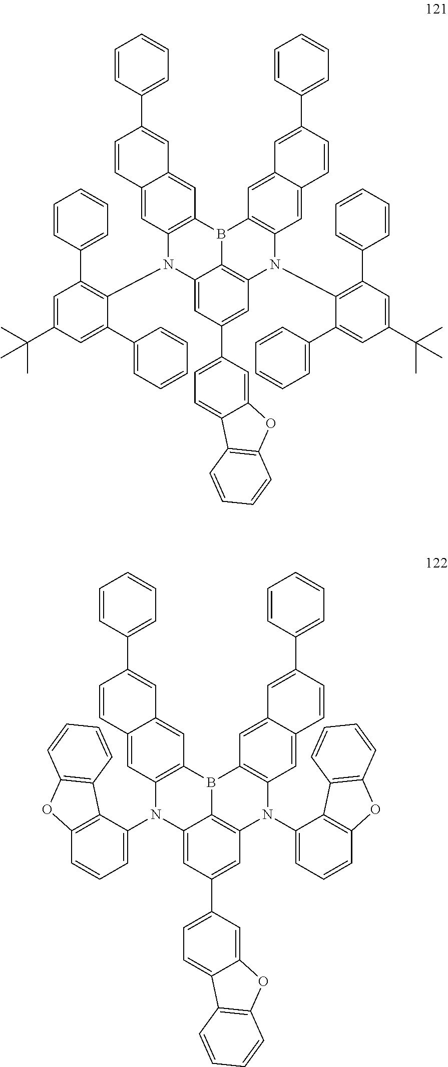 [SMILES: CC(C)(C)c1cc(-c2ccccc2)c(N2c3cc4ccc(-c5ccccc5)cc4cc3B3c4cc5cc(-c6ccccc6)ccc5cc4N(c4c(-c5ccccc5)cc(C(C)(C)C)cc4-c4ccccc4)c4cc(-c5ccc6c(c5)oc5ccccc56)cc2c43)c(-c2ccccc2)c1 ; c1ccc(-c2ccc3cc4c(cc3c2)B2c3cc5cc(-c6ccccc6)ccc5cc3N(c3cccc5oc6ccccc6c35)c3cc(-c5ccc6c(c5)oc5ccccc56)cc(c32)N4c2cccc3oc4ccccc4c23)cc1]

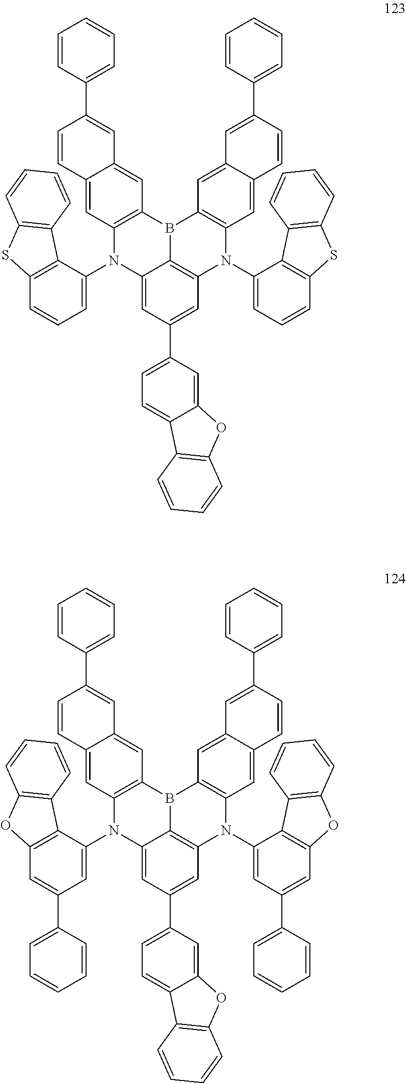 [SMILES: c1ccc(-c2ccc3cc4c(cc3c2)B2c3cc5cc(-c6ccccc6)ccc5cc3N(c3cccc5sc6ccccc6c35)c3cc(-c5ccc6c(c5)oc5ccccc56)cc(c32)N4c2cccc3sc4ccccc4c23)cc1 ; c1ccc(-c2ccc3cc4c(cc3c2)B2c3cc5cc(-c6ccccc6)ccc5cc3N(c3cc(-c5ccccc5)cc5oc6ccccc6c35)c3cc(-c5ccc6c(c5)oc5ccccc56)cc(c32)N4c2cc(-c3ccccc3)cc3oc4ccccc4c23)cc1]

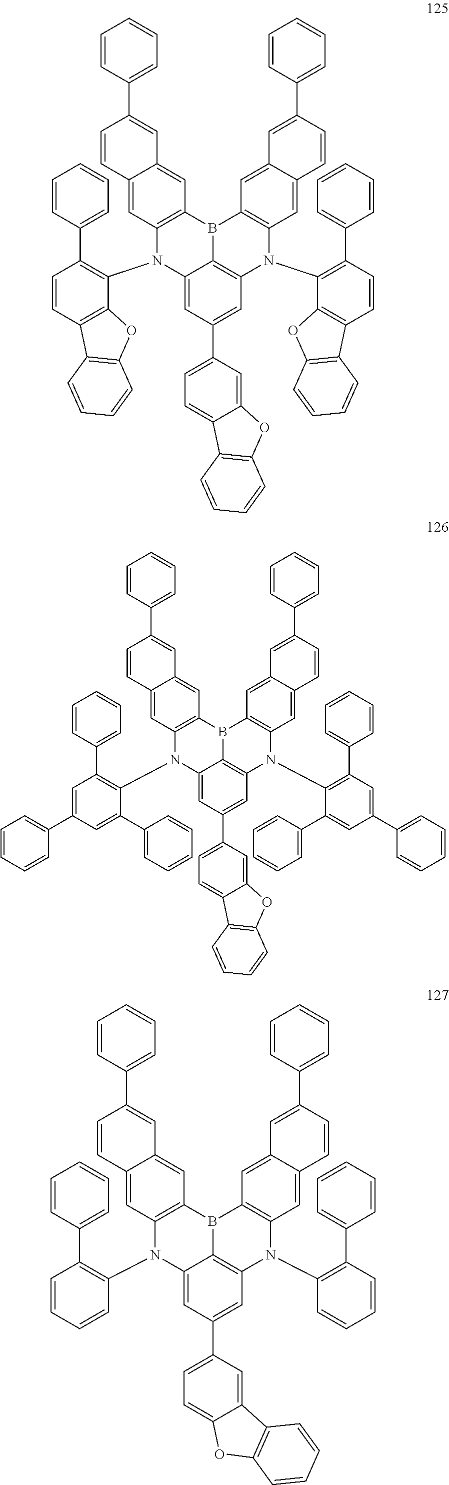 [SMILES: c1ccc(-c2ccc3cc4c(cc3c2)B2c3cc5cc(-c6ccccc6)ccc5cc3N(c3c(-c5ccccc5)ccc5c3oc3ccccc35)c3cc(-c5ccc6c(c5)oc5ccccc56)cc(c32)N4c2c(-c3ccccc3)ccc3c2oc2ccccc23)cc1 ; c1ccc(-c2cc(-c3ccccc3)c(N3c4cc5ccc(-c6ccccc6)cc5cc4B4c5cc6cc(-c7ccccc7)ccc6cc5N(c5c(-c6ccccc6)cc(-c6ccccc6)cc5-c5ccccc5)c5cc(-c6ccc7c(c6)oc6ccccc67)cc3c54)c(-c3ccccc3)c2)cc1 ; c1ccc(-c2ccc3cc4c(cc3c2)B2c3cc5cc(-c6ccccc6)ccc5cc3N(c3ccccc3-c3ccccc3)c3cc(-c5ccc6oc7ccccc7c6c5)cc(c32)N4c2ccccc2-c2ccccc2)cc1]

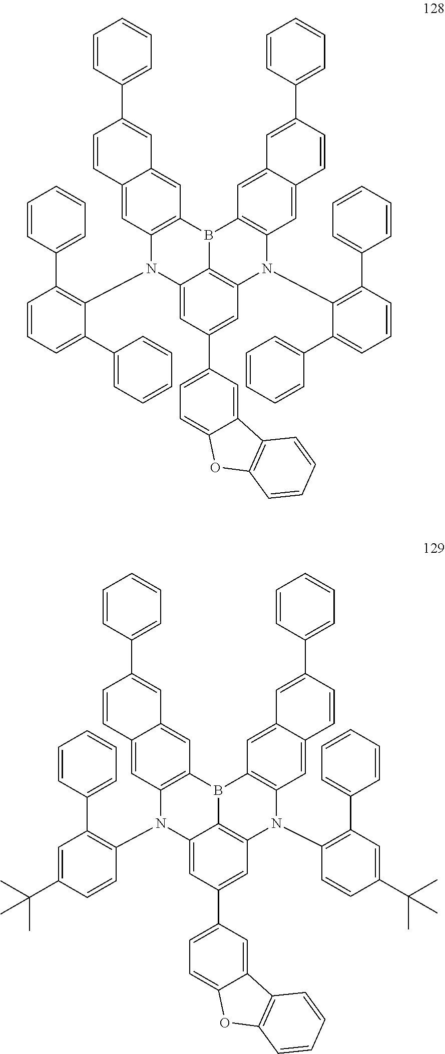 [SMILES: c1ccc(-c2ccc3cc4c(cc3c2)B2c3cc5cc(-c6ccccc6)ccc5cc3N(c3c(-c5ccccc5)cccc3-c3ccccc3)c3cc(-c5ccc6oc7ccccc7c6c5)cc(c32)N4c2c(-c3ccccc3)cccc2-c2ccccc2)cc1 ; CC(C)(C)c1ccc(N2c3cc4ccc(-c5ccccc5)cc4cc3B3c4cc5cc(-c6ccccc6)ccc5cc4N(c4ccc(C(C)(C)C)cc4-c4ccccc4)c4cc(-c5ccc6oc7ccccc7c6c5)cc2c43)c(-c2ccccc2)c1]

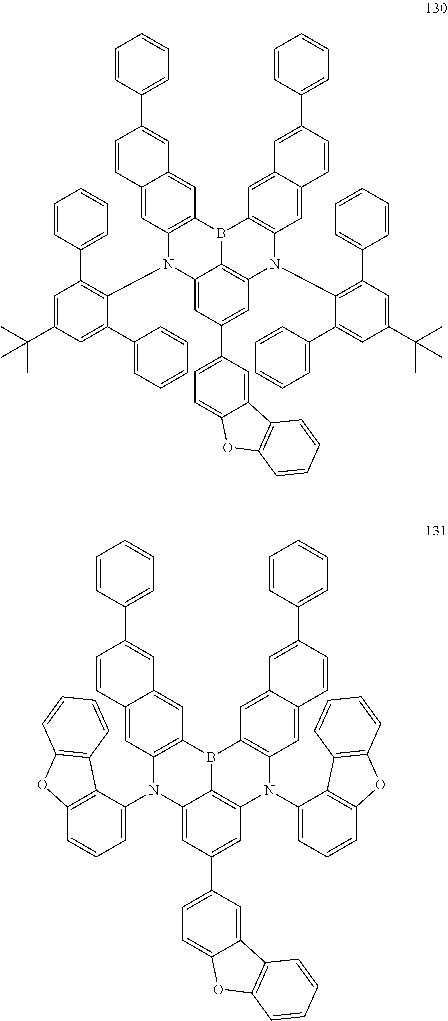 [SMILES: CC(C)(C)c1cc(-c2ccccc2)c(N2c3cc4ccc(-c5ccccc5)cc4cc3B3c4cc5cc(-c6ccccc6)ccc5cc4N(c4c(-c5ccccc5)cc(C(C)(C)C)cc4-c4ccccc4)c4cc(-c5ccc6oc7ccccc7c6c5)cc2c43)c(-c2ccccc2)c1 ; c1ccc(-c2ccc3cc4c(cc3c2)B2c3cc5cc(-c6ccccc6)ccc5cc3N(c3cccc5oc6ccccc6c35)c3cc(-c5ccc6oc7ccccc7c6c5)cc(c32)N4c2cccc3oc4ccccc4c23)cc1]

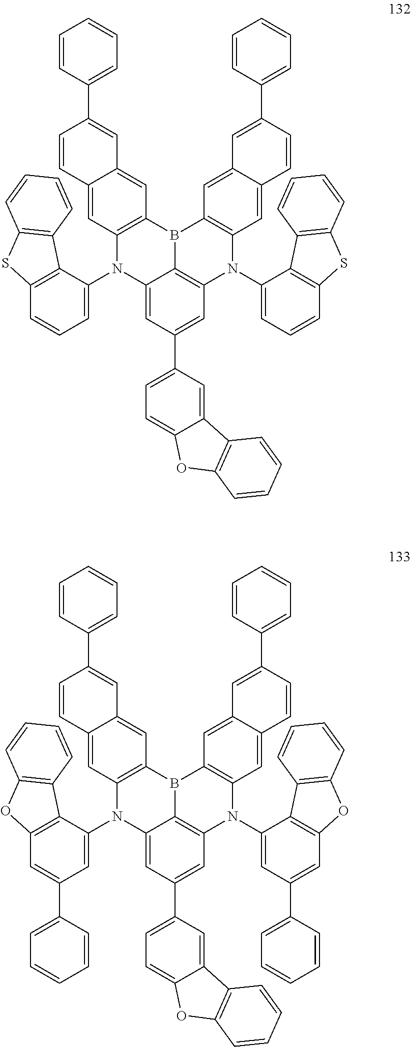 [SMILES: c1ccc(-c2ccc3cc4c(cc3c2)B2c3cc5cc(-c6ccccc6)ccc5cc3N(c3cccc5sc6ccccc6c35)c3cc(-c5ccc6oc7ccccc7c6c5)cc(c32)N4c2cccc3sc4ccccc4c23)cc1 ; c1ccc(-c2ccc3cc4c(cc3c2)B2c3cc5cc(-c6ccccc6)ccc5cc3N(c3cc(-c5ccccc5)cc5oc6ccccc6c35)c3cc(-c5ccc6oc7ccccc7c6c5)cc(c32)N4c2cc(-c3ccccc3)cc3oc4ccccc4c23)cc1]

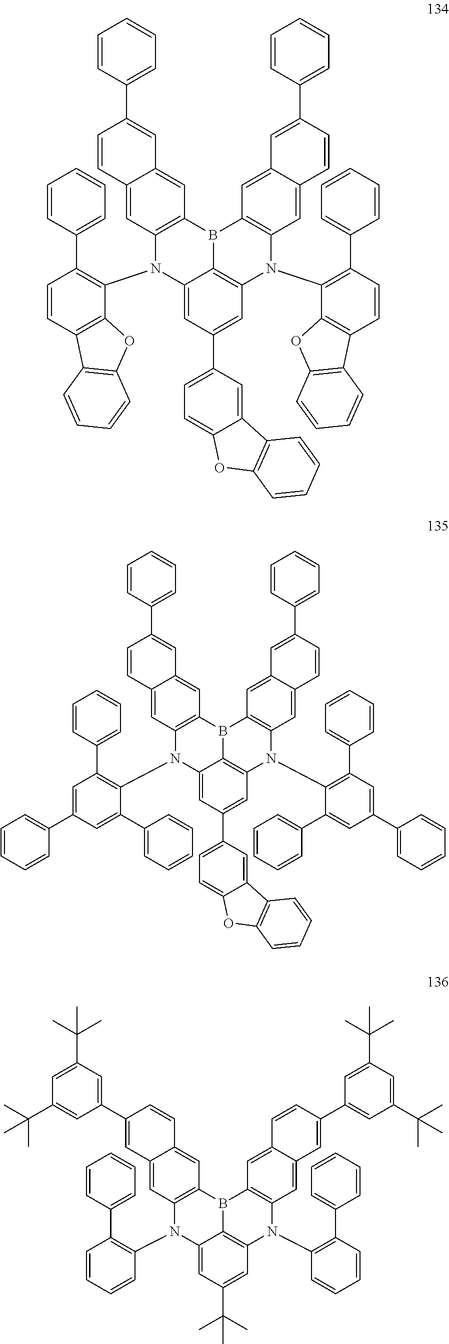 [SMILES: c1ccc(-c2ccc3cc4c(cc3c2)B2c3cc5cc(-c6ccccc6)ccc5cc3N(c3c(-c5ccccc5)ccc5c3oc3ccccc35)c3cc(-c5ccc6oc7ccccc7c6c5)cc(c32)N4c2c(-c3ccccc3)ccc3c2oc2ccccc23)cc1 ; c1ccc(-c2cc(-c3ccccc3)c(N3c4cc5ccc(-c6ccccc6)cc5cc4B4c5cc6cc(-c7ccccc7)ccc6cc5N(c5c(-c6ccccc6)cc(-c6ccccc6)cc5-c5ccccc5)c5cc(-c6ccc7oc8ccccc8c7c6)cc3c54)c(-c3ccccc3)c2)cc1 ; CC(C)(C)c1cc(-c2ccc3cc4c(cc3c2)N(c2ccccc2-c2ccccc2)c2cc(C(C)(C)C)cc3c2B4c2cc4ccc(-c5cc(C(C)(C)C)cc(C(C)(C)C)c5)cc4cc2N3c2ccccc2-c2ccccc2)cc(C(C)(C)C)c1]

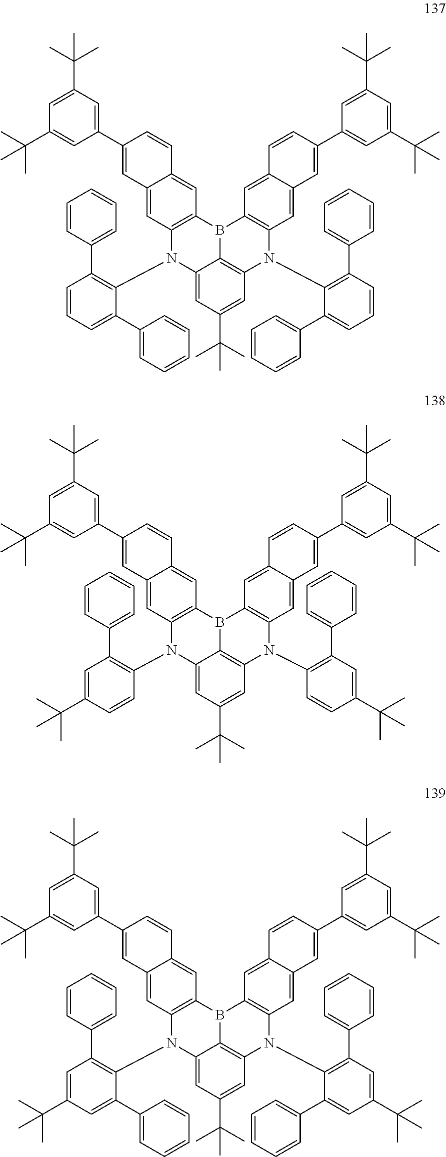

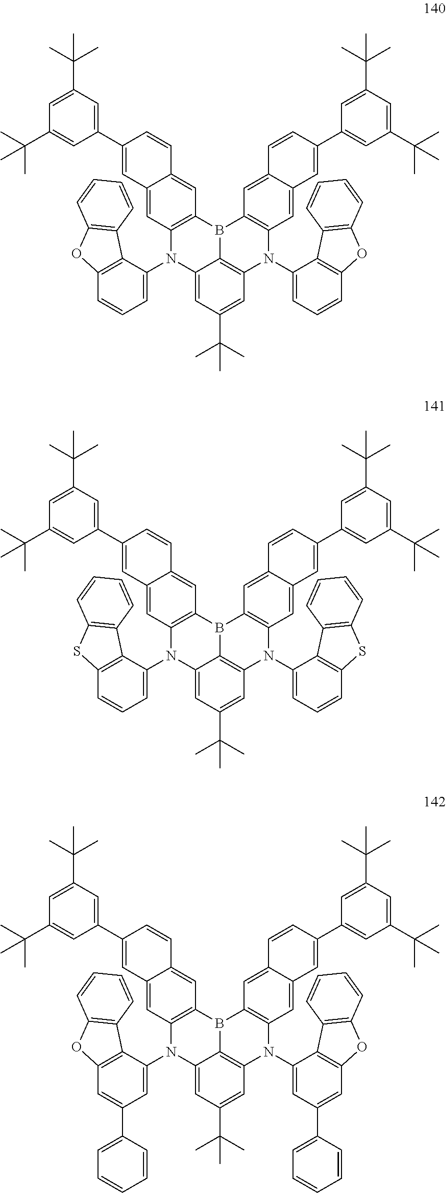

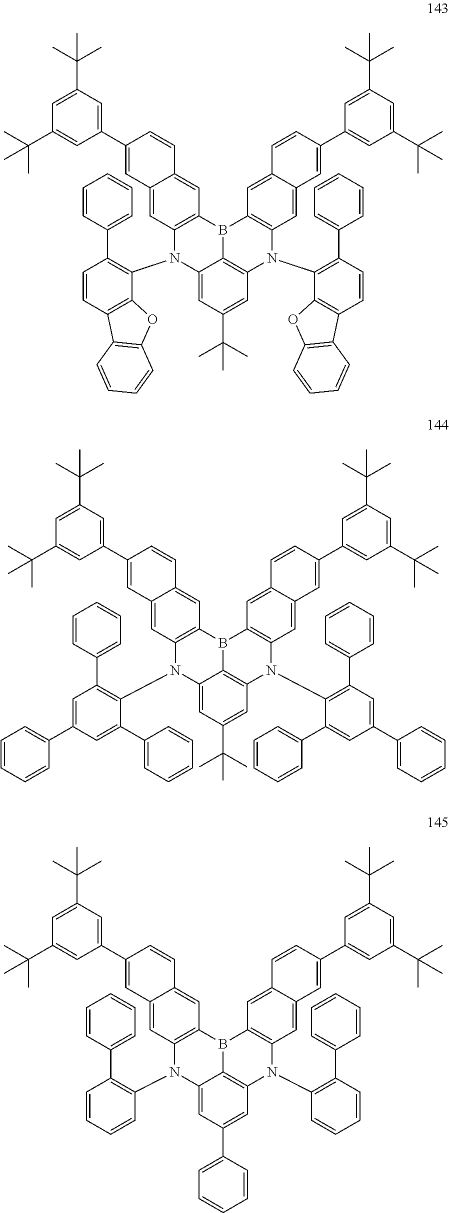

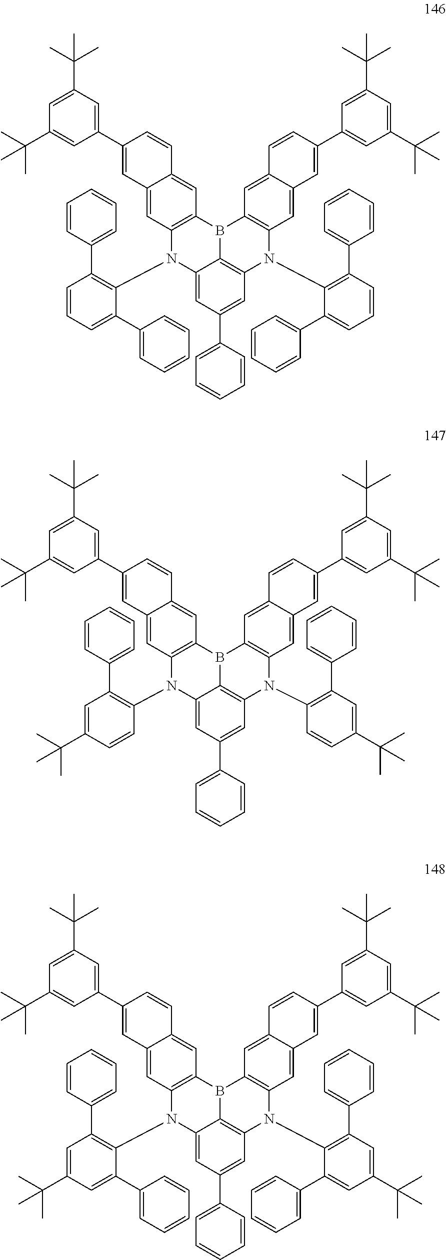

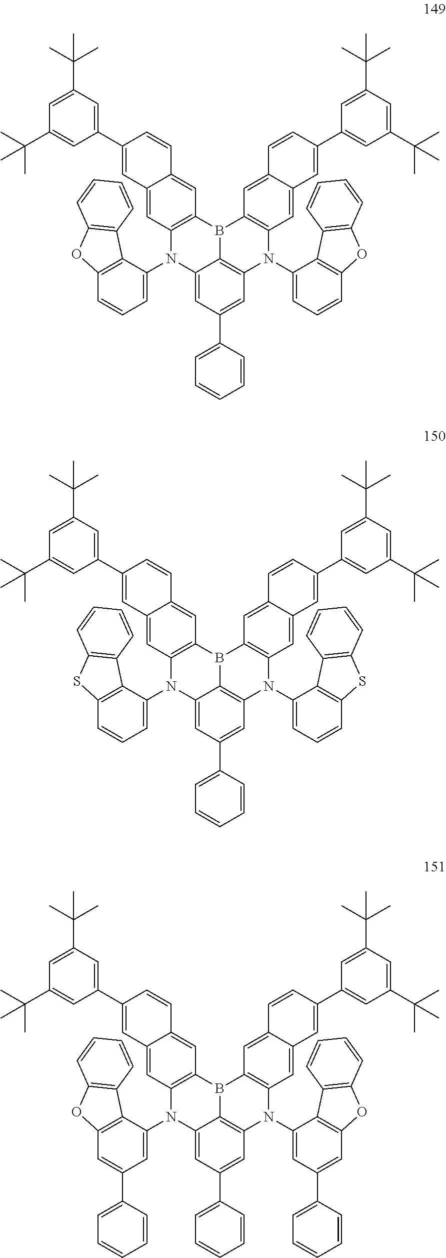

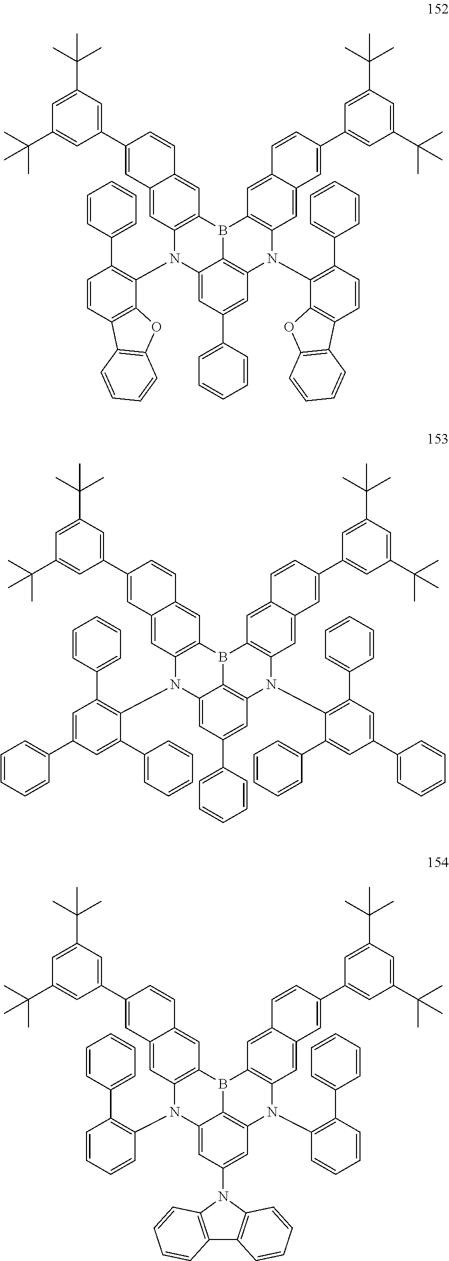

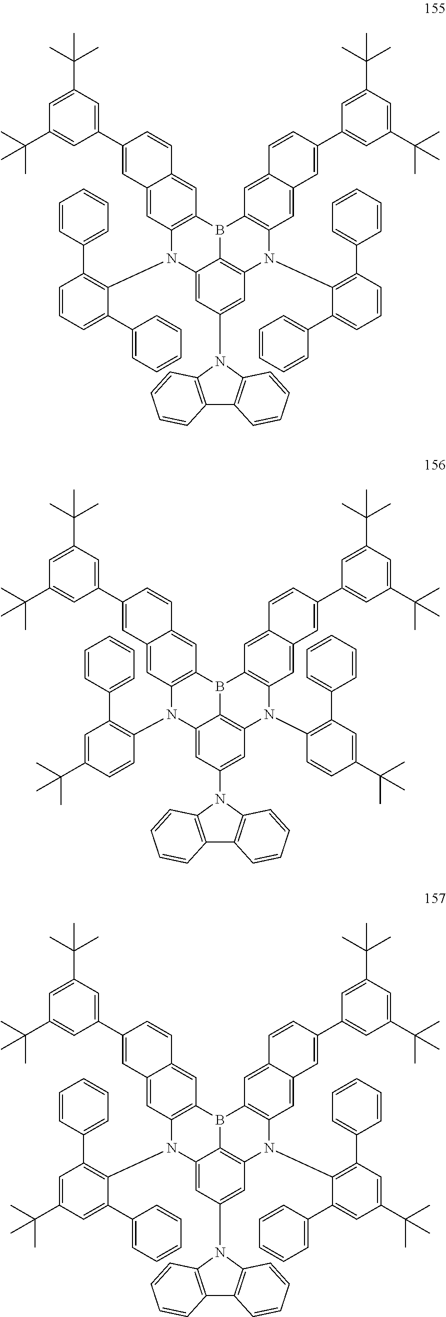

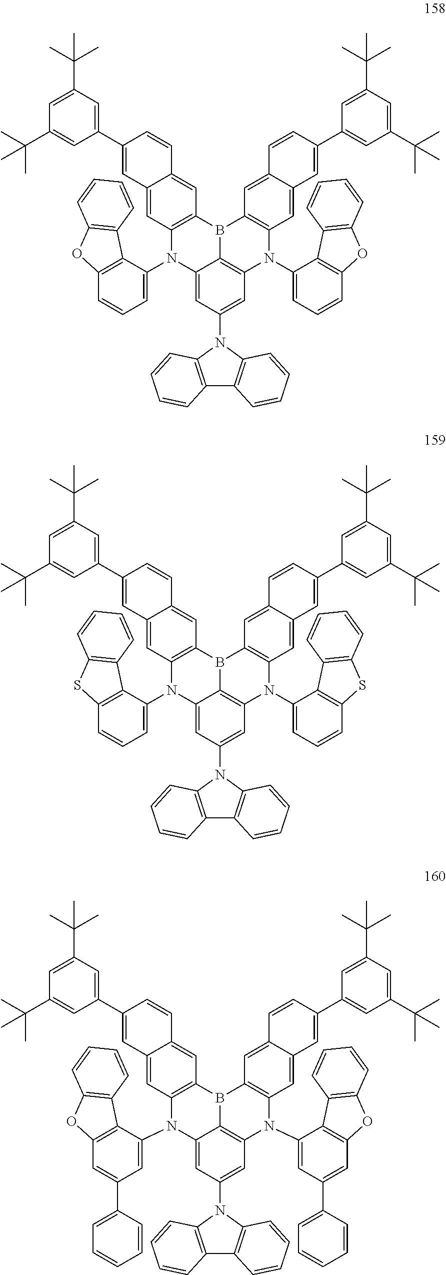

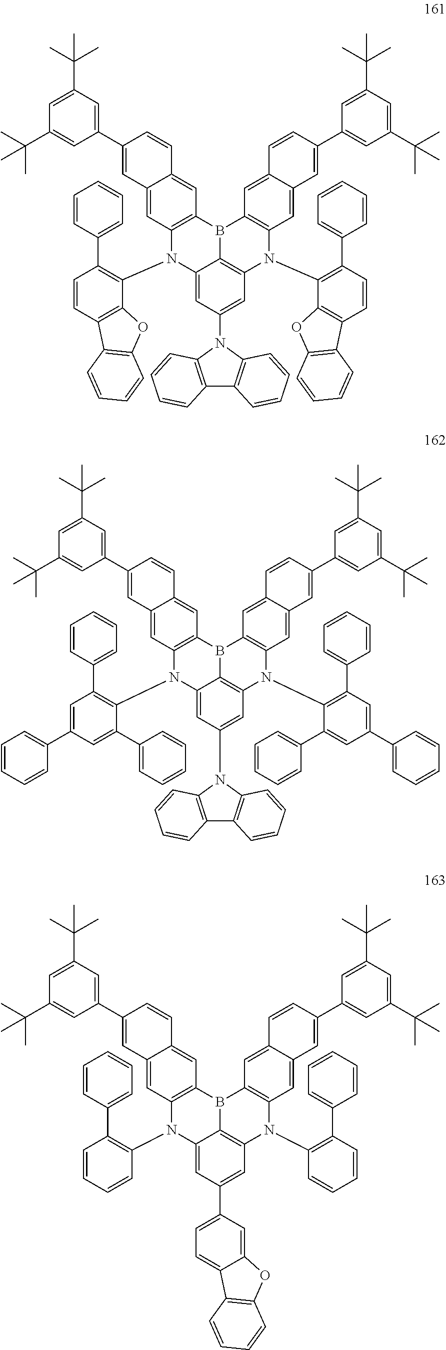

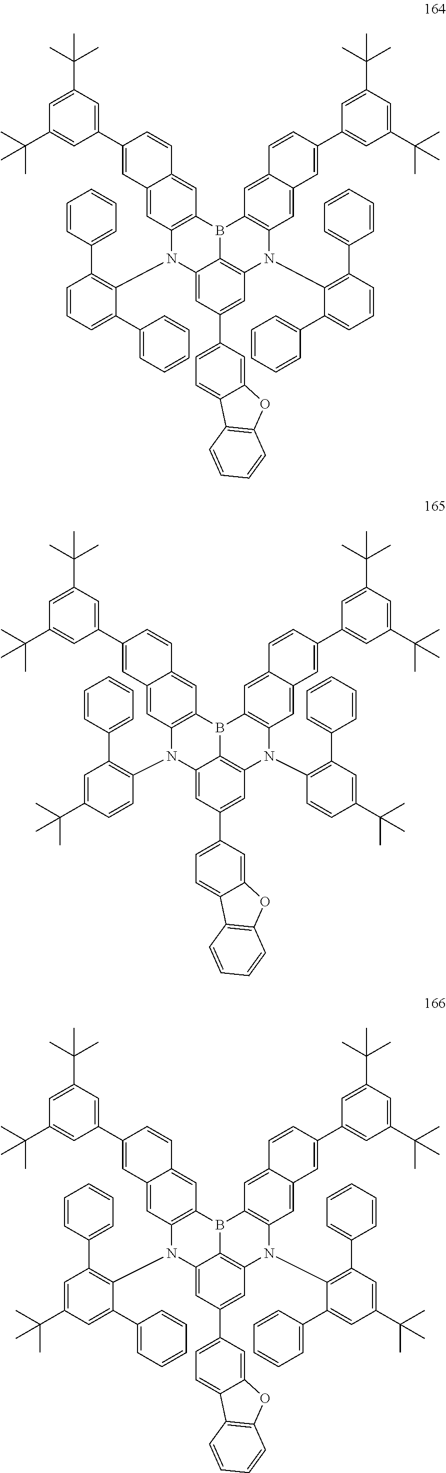

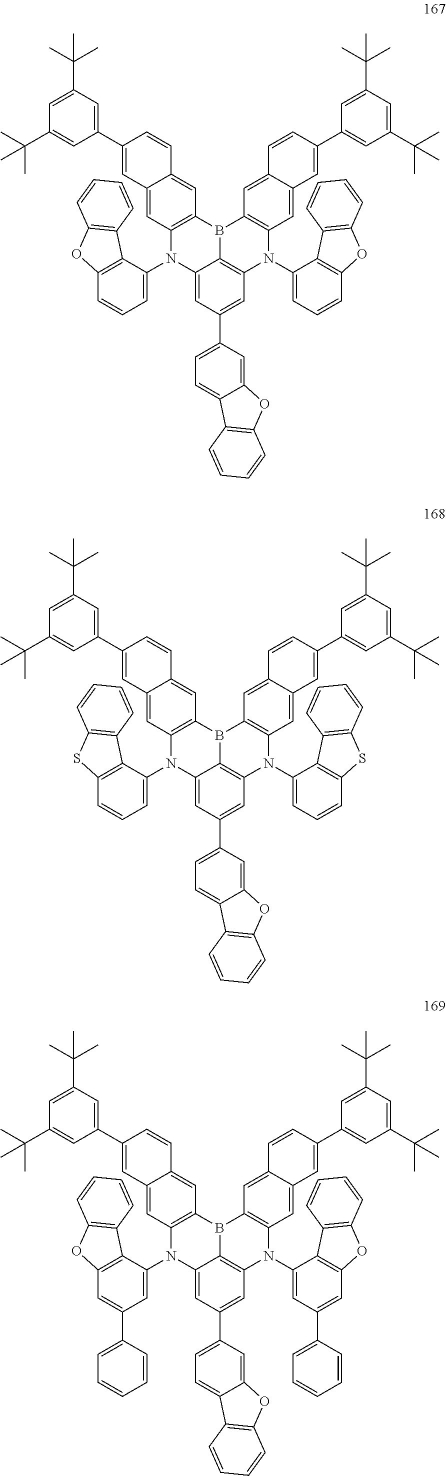

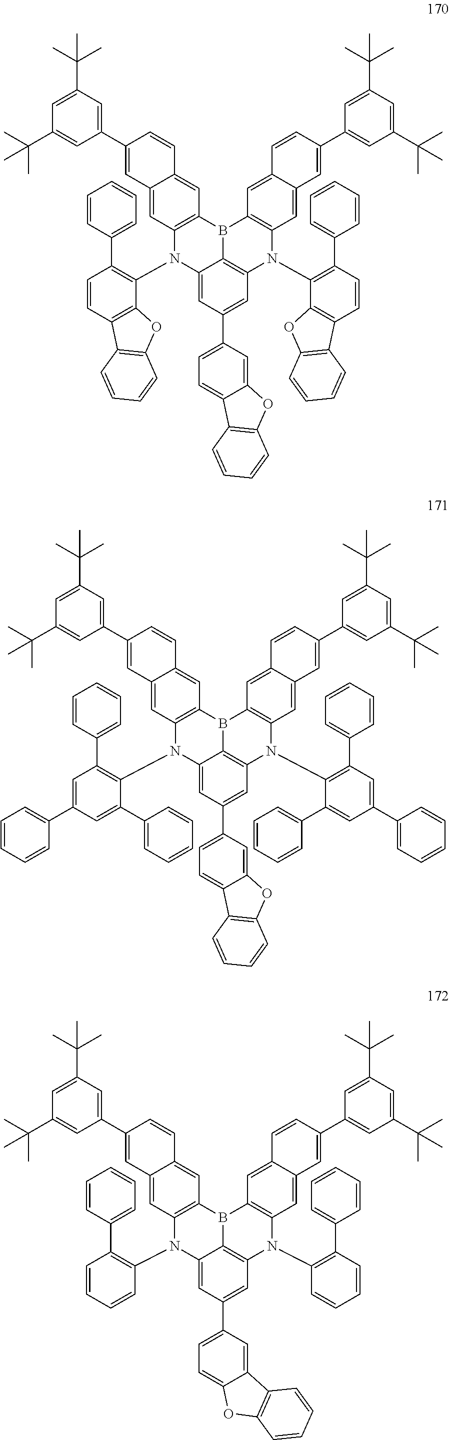

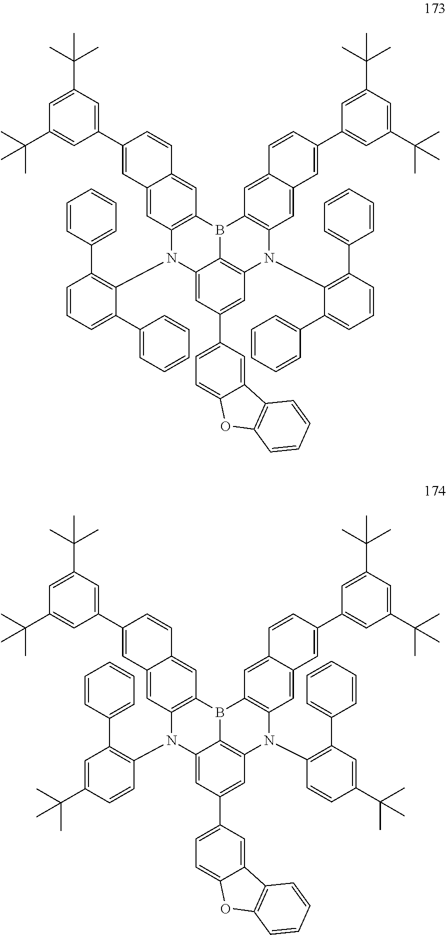

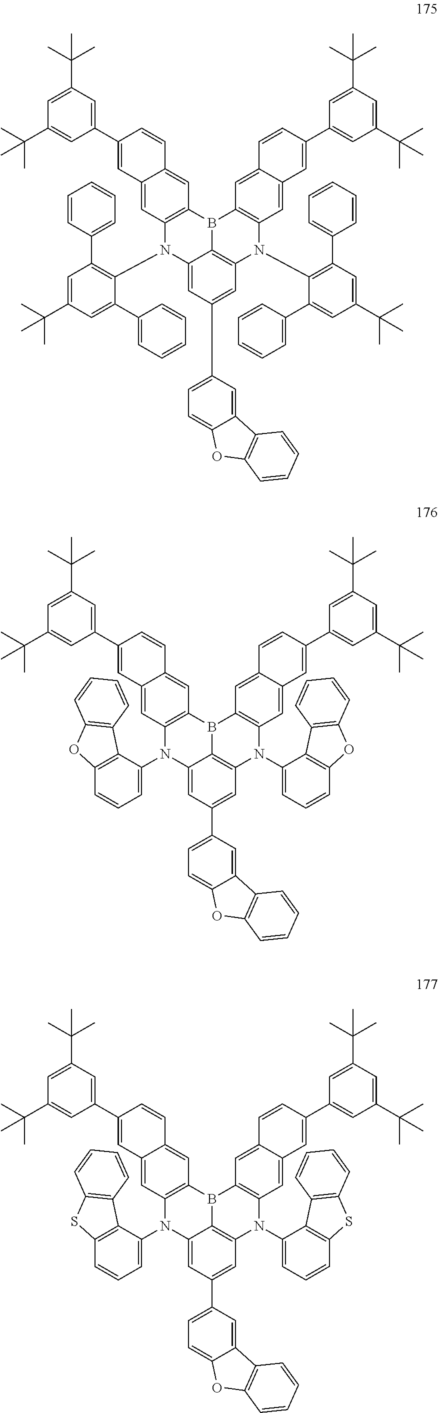

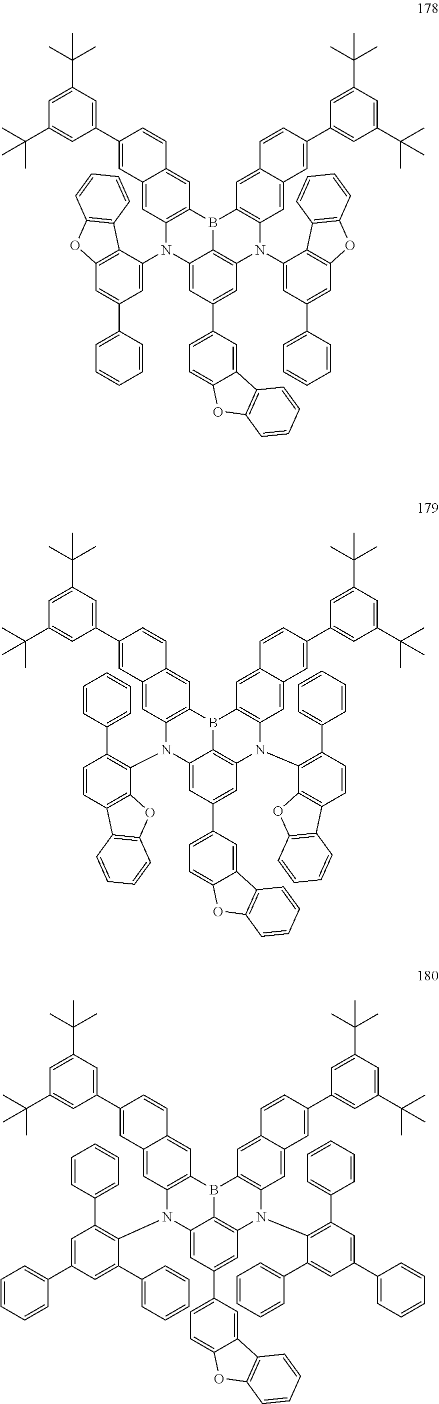

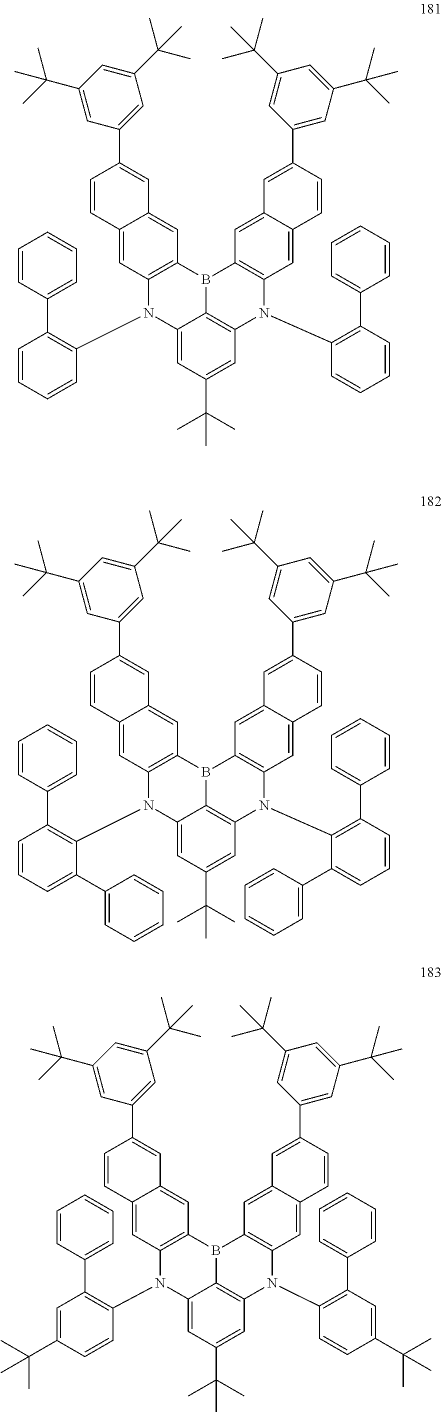

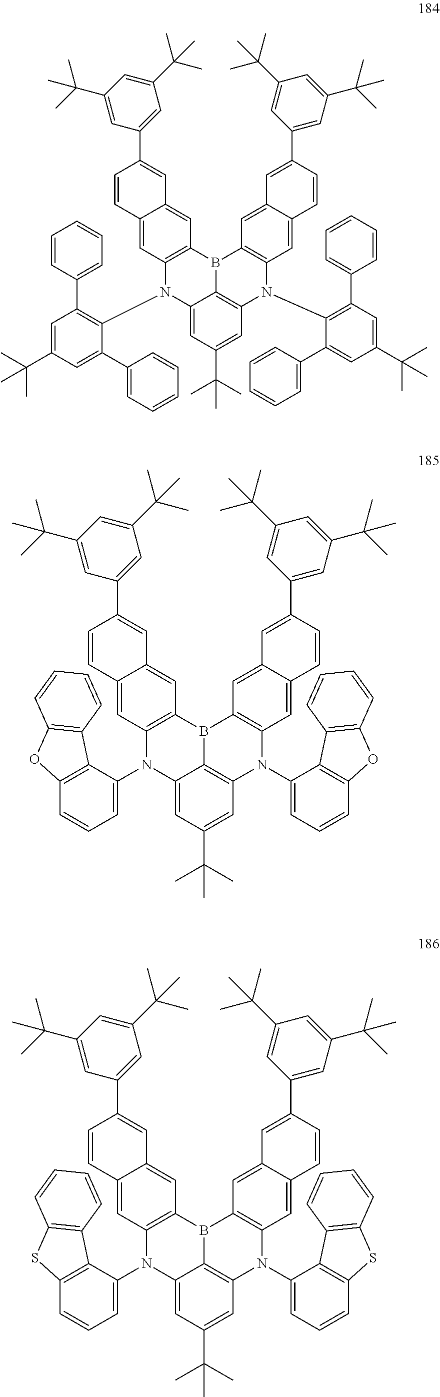

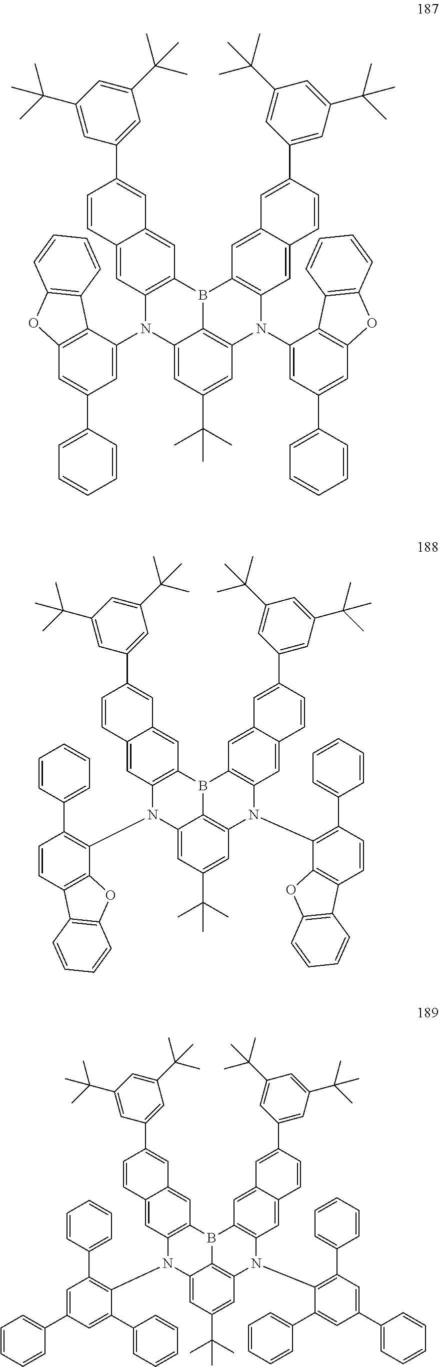

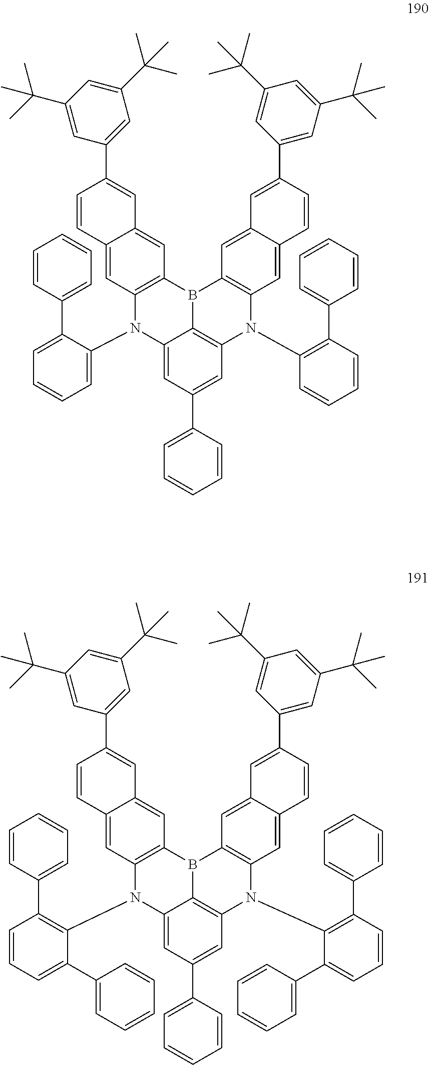

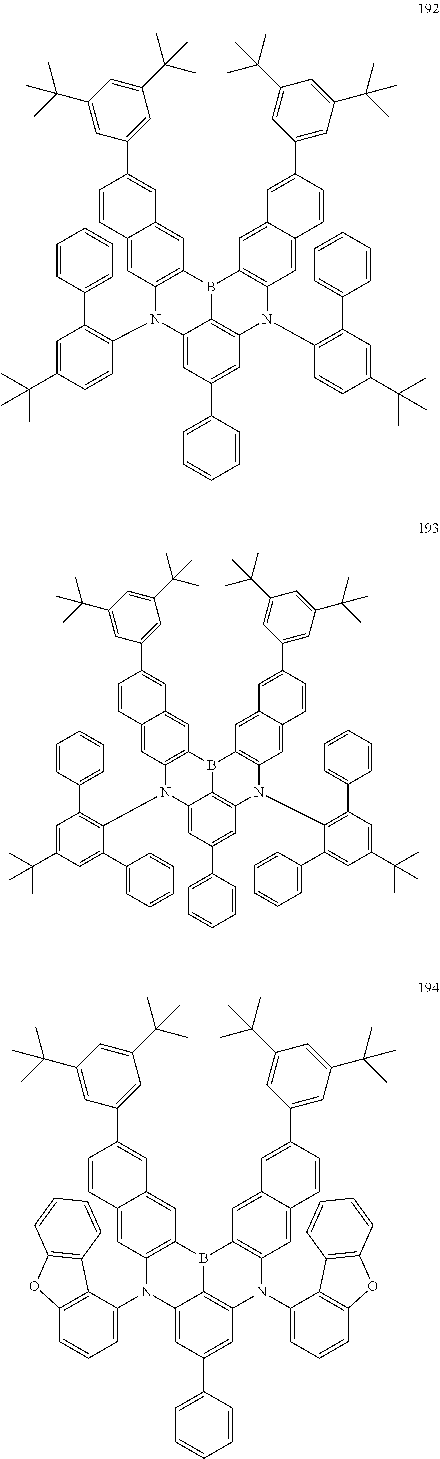

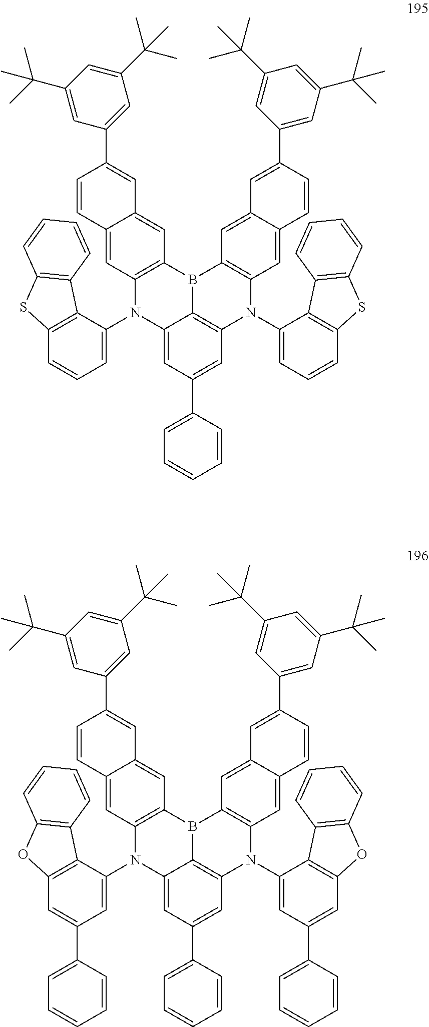

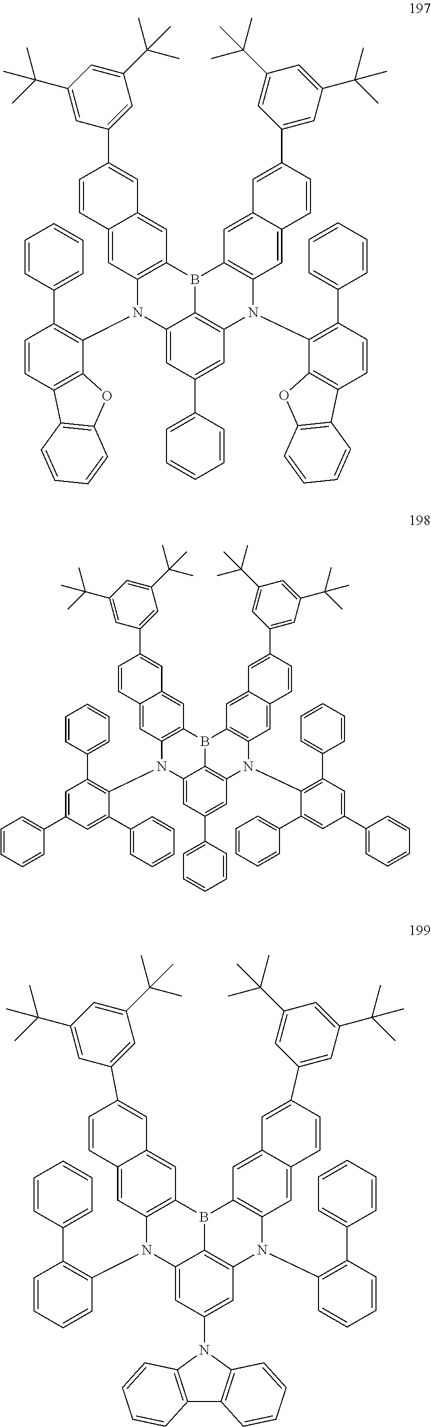

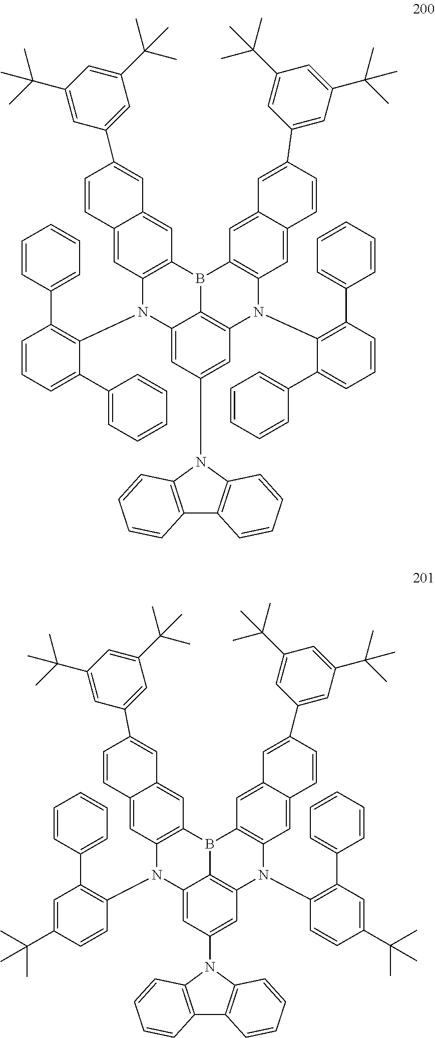

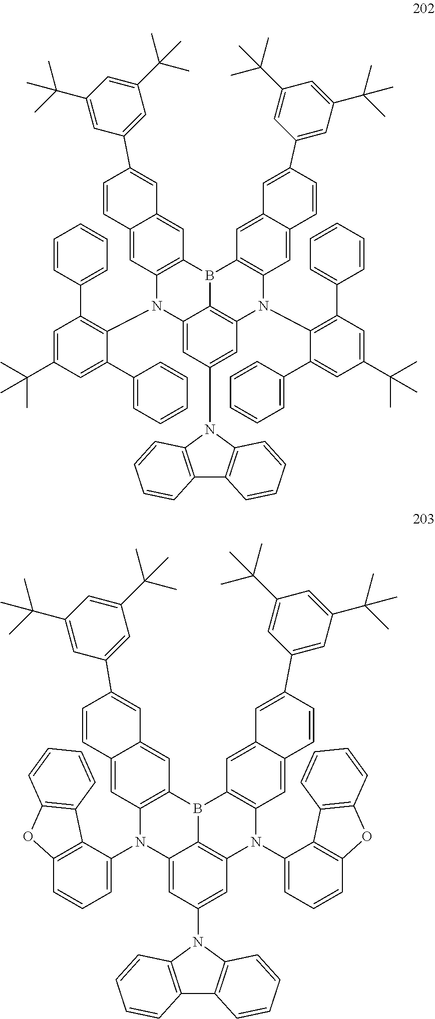

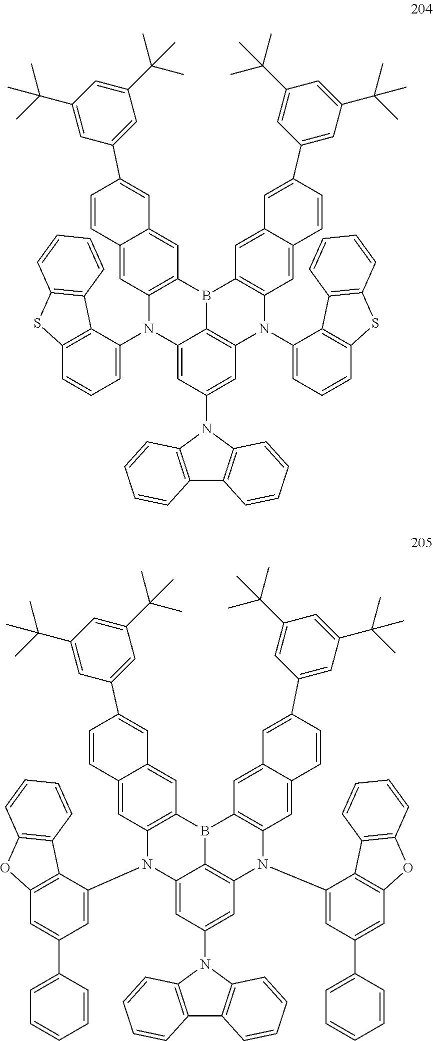 [SMILES: CC(C)(C)c1cc(-c2ccc3cc4c(cc3c2)B2c3cc5cc(-c6cc(C(C)(C)C)cc(C(C)(C)C)c6)ccc5cc3N(c3cccc5sc6ccccc6c35)c3cc(-n5c6ccccc6c6ccccc65)cc(c32)N4c2cccc3sc4ccccc4c23)cc(C(C)(C)C)c1 ; CC(C)(C)c1cc(-c2ccc3cc4c(cc3c2)B2c3cc5cc(-c6cc(C(C)(C)C)cc(C(C)(C)C)c6)ccc5cc3N(c3cc(-c5ccccc5)cc5oc6ccccc6c35)c3cc(-n5c6ccccc6c6ccccc65)cc(c32)N4c2cc(-c3ccccc3)cc3oc4ccccc4c23)cc(C(C)(C)C)c1]

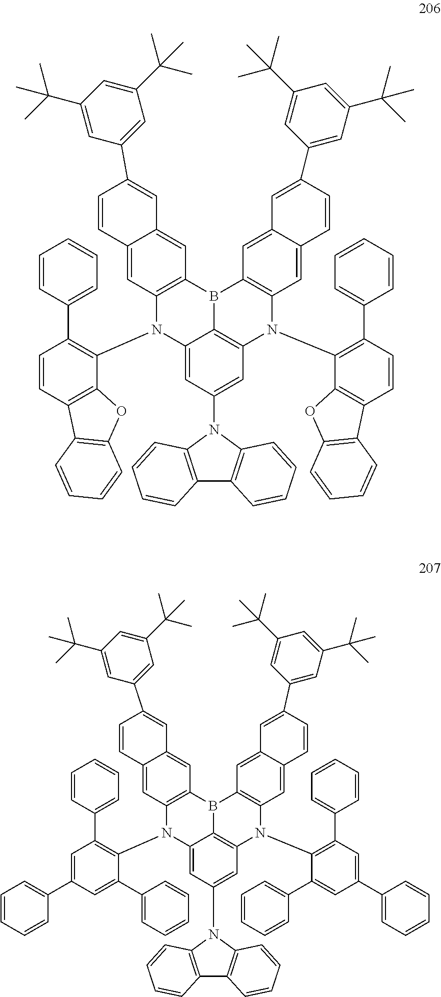 [SMILES: CC(C)(C)c1cc(-c2ccc3cc4c(cc3c2)B2c3cc5cc(-c6cc(C(C)(C)C)cc(C(C)(C)C)c6)ccc5cc3N(c3c(-c5ccccc5)ccc5c3oc3ccccc35)c3cc(-n5c6ccccc6c6ccccc65)cc(c32)N4c2c(-c3ccccc3)ccc3c2oc2ccccc23)cc(C(C)(C)C)c1 ; CC(C)(C)c1cc(-c2ccc3cc4c(cc3c2)B2c3cc5cc(-c6cc(C(C)(C)C)cc(C(C)(C)C)c6)ccc5cc3N(c3c(-c5ccccc5)cc(-c5ccccc5)cc3-c3ccccc3)c3cc(-n5c6ccccc6c6ccccc65)cc(c32)N4c2c(-c3ccccc3)cc(-c3ccccc3)cc2-c2ccccc2)cc(C(C)(C)C)c1]

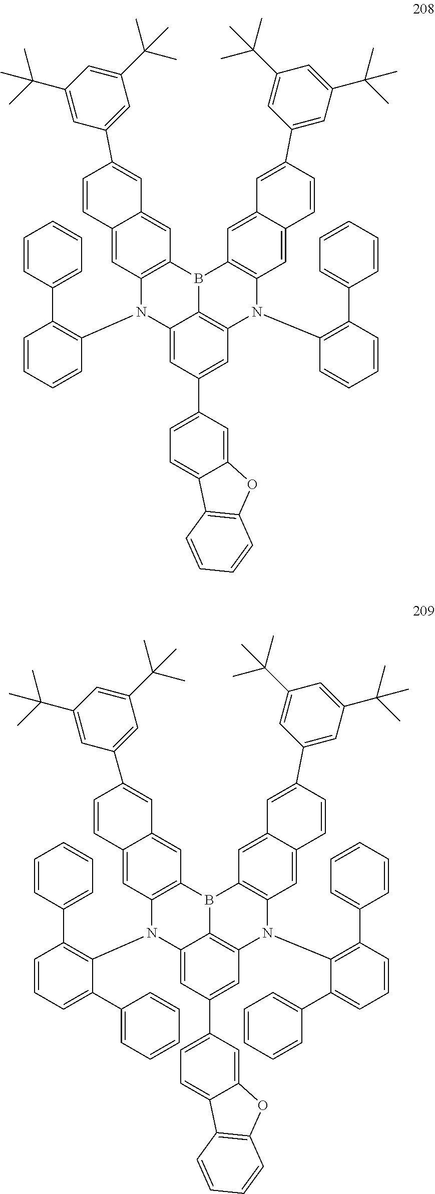

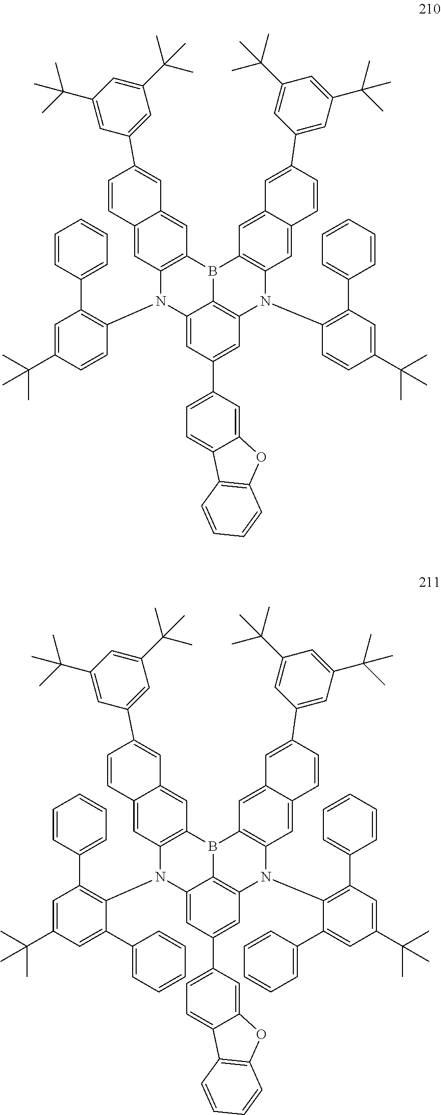

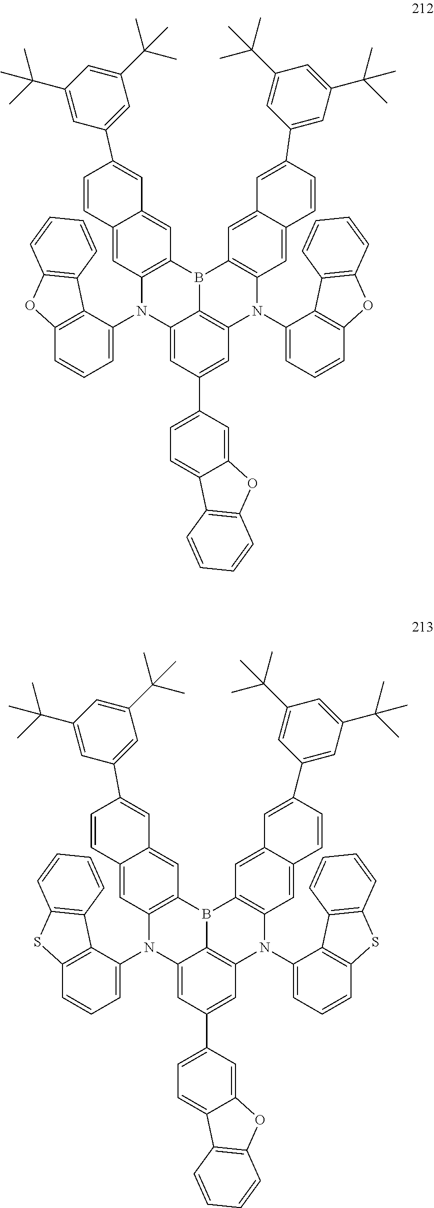

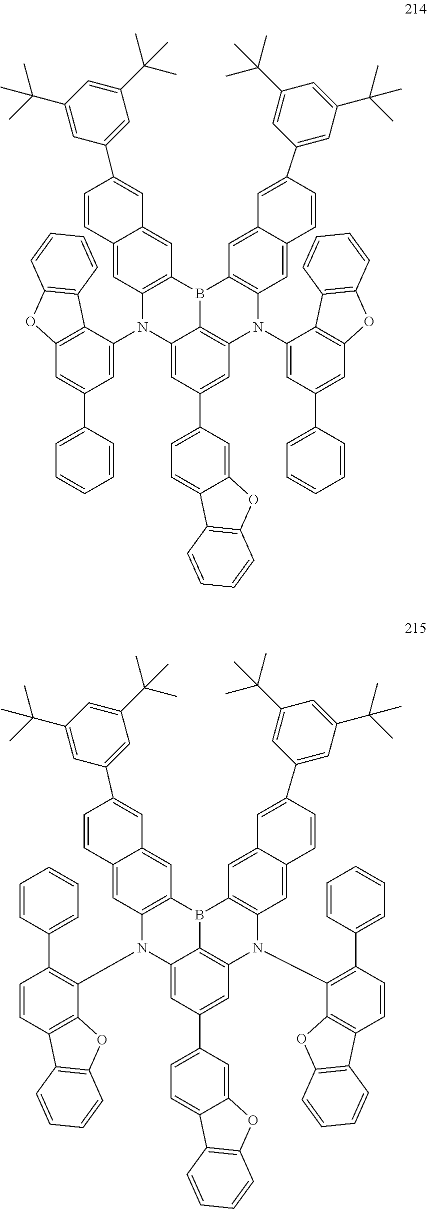

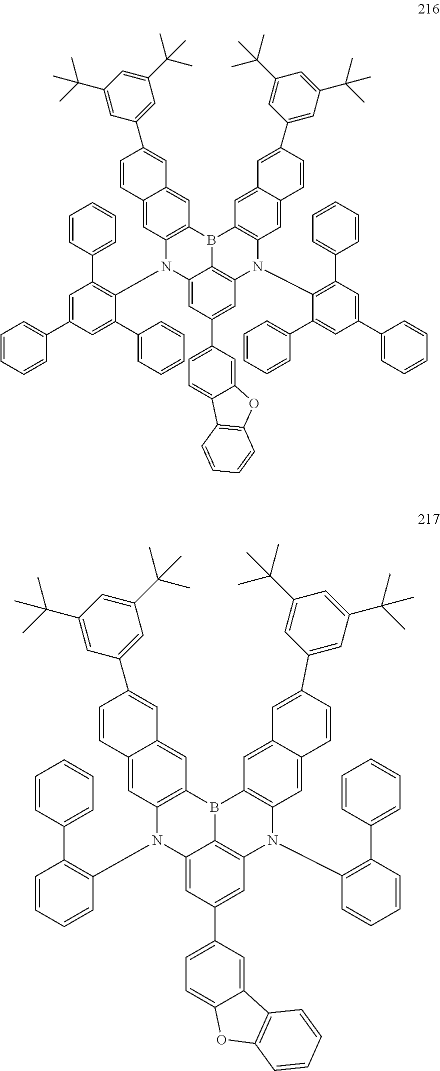 [SMILES: CC(C)(C)c1cc(-c2ccc3cc4c(cc3c2)B2c3cc5cc(-c6cc(C(C)(C)C)cc(C(C)(C)C)c6)ccc5cc3N(c3c(-c5ccccc5)cc(-c5ccccc5)cc3-c3ccccc3)c3cc(-c5ccc6c(c5)oc5ccccc56)cc(c32)N4c2c(-c3ccccc3)cc(-c3ccccc3)cc2-c2ccccc2)cc(C(C)(C)C)c1 ; CC(C)(C)c1cc(-c2ccc3cc4c(cc3c2)B2c3cc5cc(-c6cc(C(C)(C)C)cc(C(C)(C)C)c6)ccc5cc3N(c3ccccc3-c3ccccc3)c3cc(-c5ccc6oc7ccccc7c6c5)cc(c32)N4c2ccccc2-c2ccccc2)cc(C(C)(C)C)c1]

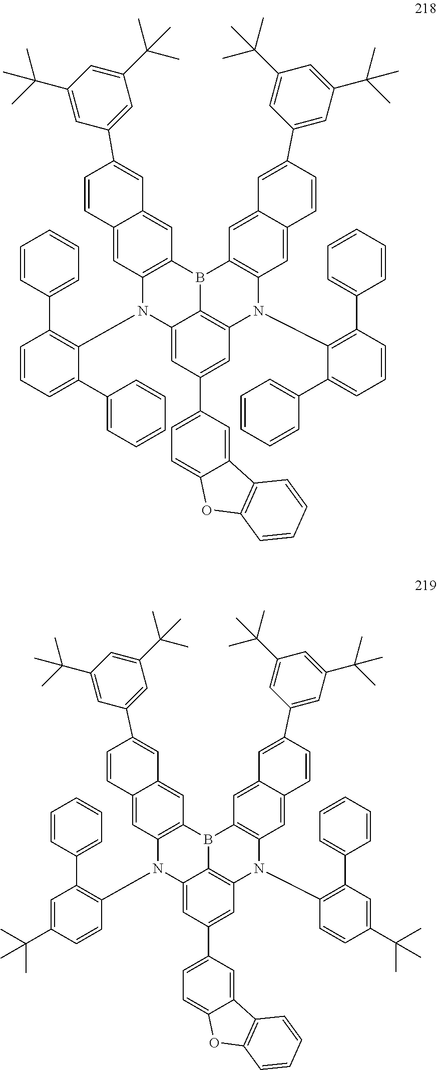

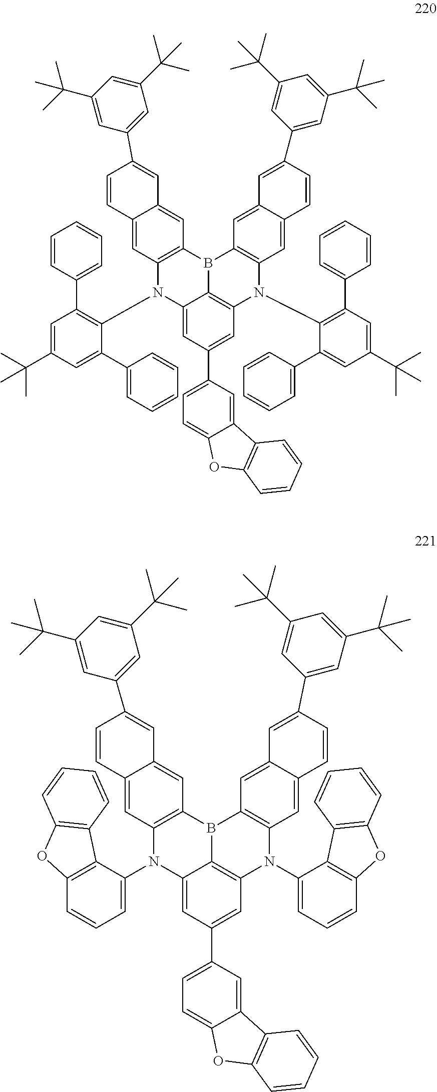

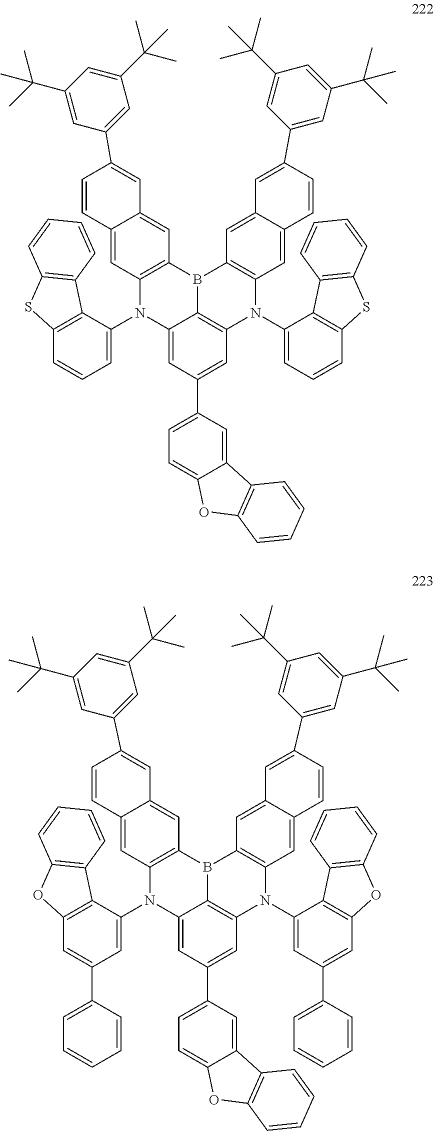

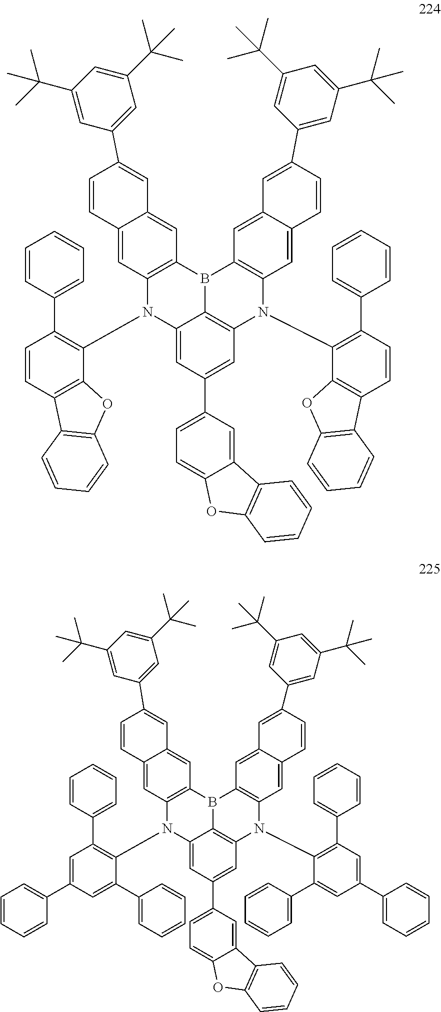 [SMILES: CC(C)(C)c1cc(-c2ccc3cc4c(cc3c2)B2c3cc5cc(-c6cc(C(C)(C)C)cc(C(C)(C)C)c6)ccc5cc3N(c3c(-c5ccccc5)ccc5c3oc3ccccc35)c3cc(-c5ccc6oc7ccccc7c6c5)cc(c32)N4c2c(-c3ccccc3)ccc3c2oc2ccccc23)cc(C(C)(C)C)c1 ; CC(C)(C)c1cc(-c2ccc3cc4c(cc3c2)B2c3cc5cc(-c6cc(C(C)(C)C)cc(C(C)(C)C)c6)ccc5cc3N(c3c(-c5ccccc5)cc(-c5ccccc5)cc3-c3ccccc3)c3cc(-c5ccc6oc7ccccc7c6c5)cc(c32)N4c2c(-c3ccccc3)cc(-c3ccccc3)cc2-c2ccccc2)cc(C(C)(C)C)c1]

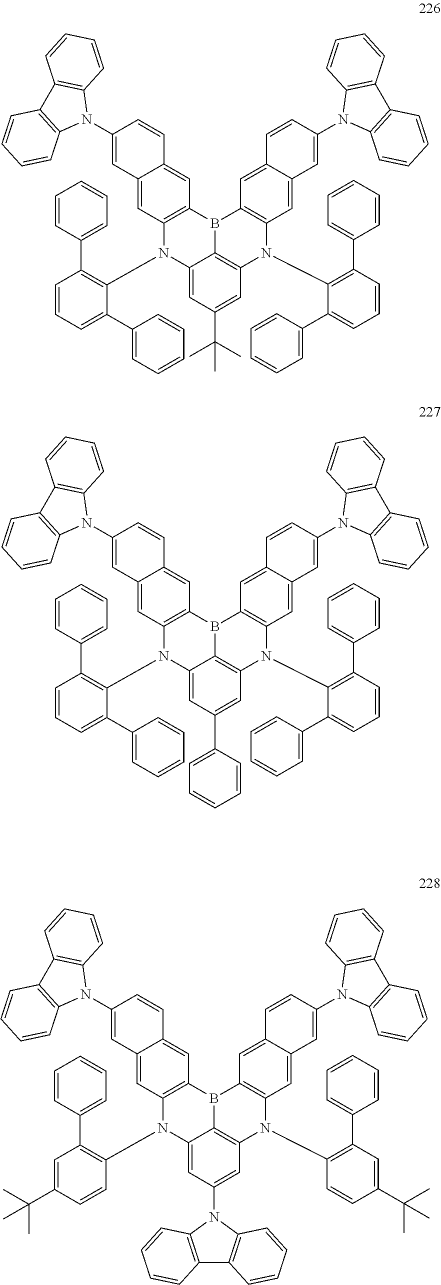 [SMILES: CC(C)(C)c1cc2c3c(c1)N(c1c(-c4ccccc4)cccc1-c1ccccc1)c1cc4cc(-n5c6ccccc6c6ccccc65)ccc4cc1B3c1cc3ccc(-n4c5ccccc5c5ccccc54)cc3cc1N2c1c(-c2ccccc2)cccc1-c1ccccc1 ; c1ccc(-c2cc3c4c(c2)N(c2c(-c5ccccc5)cccc2-c2ccccc2)c2cc5cc(-n6c7ccccc7c7ccccc76)ccc5cc2B4c2cc4ccc(-n5c6ccccc6c6ccccc65)cc4cc2N3c2c(-c3ccccc3)cccc2-c2ccccc2)cc1 ; CC(C)(C)c1ccc(N2c3cc4cc(-n5c6ccccc6c6ccccc65)ccc4cc3B3c4cc5ccc(-n6c7ccccc7c7ccccc76)cc5cc4N(c4ccc(C(C)(C)C)cc4-c4ccccc4)c4cc(-n5c6ccccc6c6ccccc65)cc2c43)c(-c2ccccc2)c1]

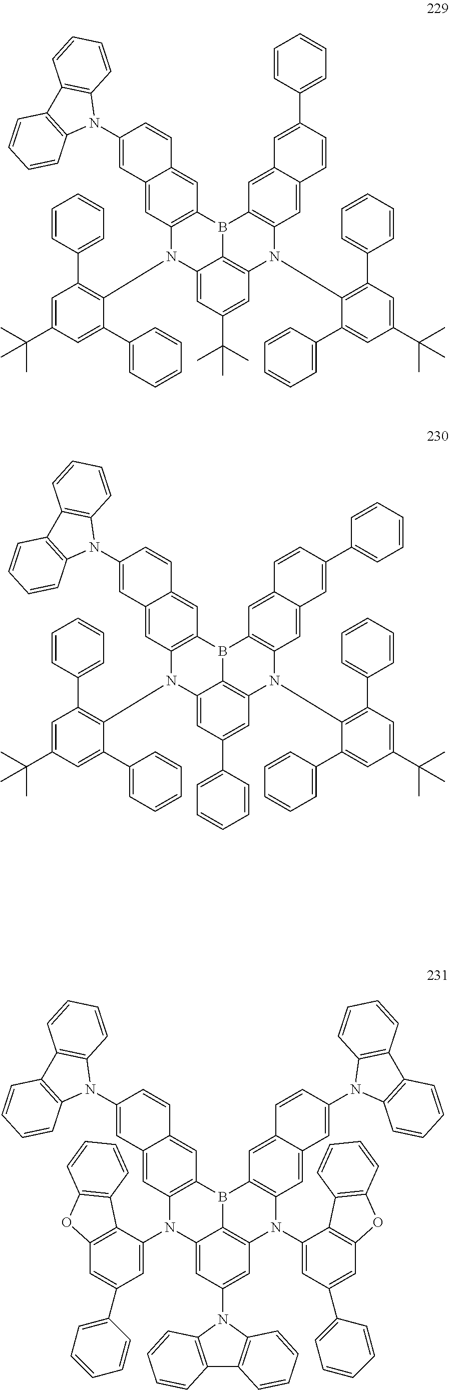

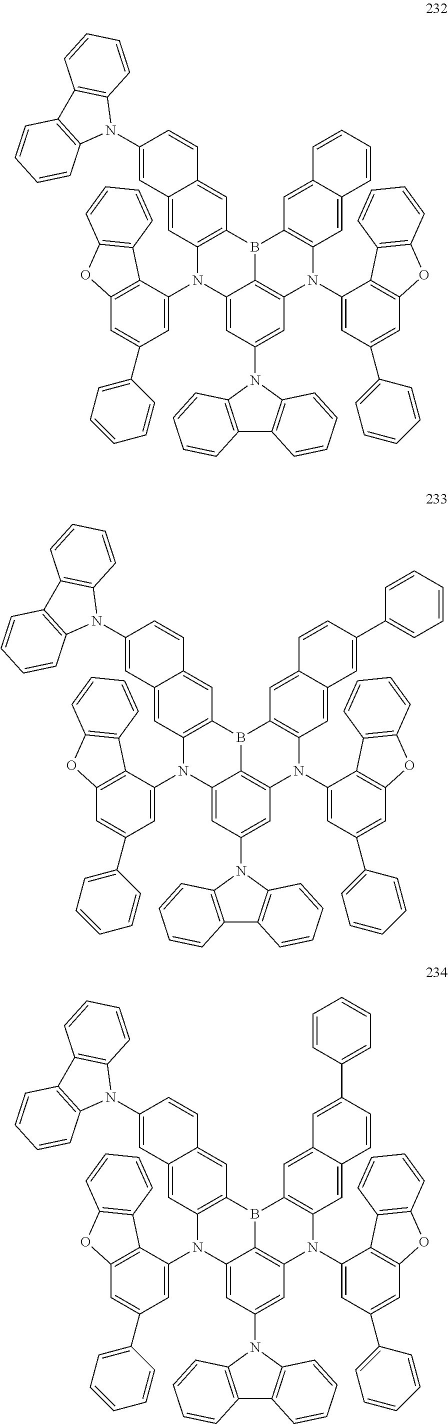 [SMILES: c1ccc(-c2cc(N3c4cc5ccccc5cc4B4c5cc6ccc(-n7c8ccccc8c8ccccc87)cc6cc5N(c5cc(-c6ccccc6)cc6oc7ccccc7c56)c5cc(-n6c7ccccc7c7ccccc76)cc3c54)c3c(c2)oc2ccccc23)cc1 ; c1ccc(-c2ccc3cc4c(cc3c2)N(c2cc(-c3ccccc3)cc3oc5ccccc5c23)c2cc(-n3c5ccccc5c5ccccc53)cc3c2B4c2cc4ccc(-n5c6ccccc6c6ccccc65)cc4cc2N3c2cc(-c3ccccc3)cc3oc4ccccc4c23)cc1 ; c1ccc(-c2ccc3cc4c(cc3c2)B2c3cc5ccc(-n6c7ccccc7c7ccccc76)cc5cc3N(c3cc(-c5ccccc5)cc5oc6ccccc6c35)c3cc(-n5c6ccccc6c6ccccc65)cc(c32)N4c2cc(-c3ccccc3)cc3oc4ccccc4c23)cc1]

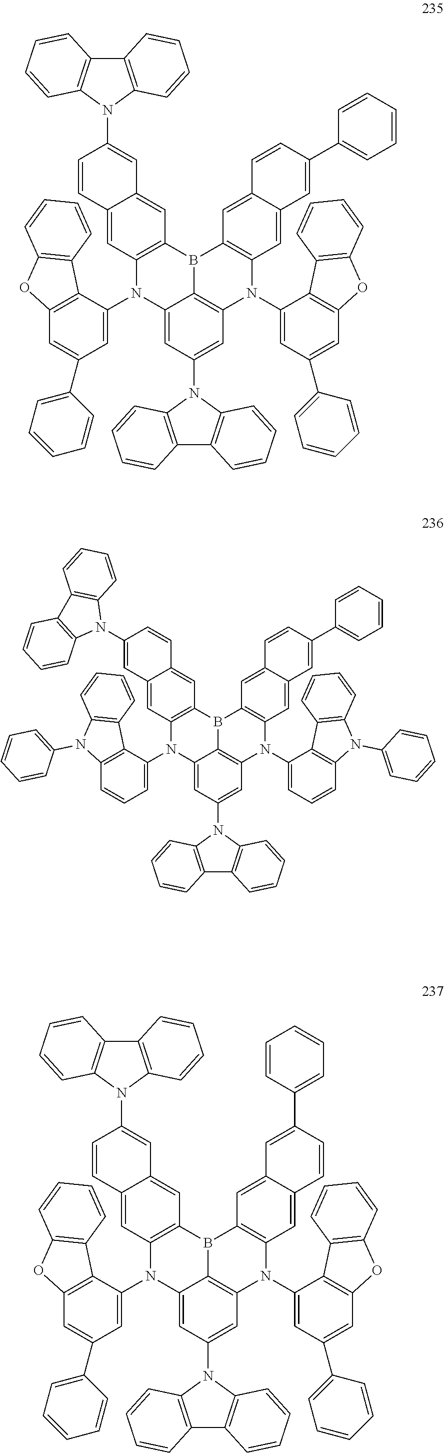 [SMILES: c1ccc(-c2ccc3cc4c(cc3c2)N(c2cc(-c3ccccc3)cc3oc5ccccc5c23)c2cc(-n3c5ccccc5c5ccccc53)cc3c2B4c2cc4cc(-n5c6ccccc6c6ccccc65)ccc4cc2N3c2cc(-c3ccccc3)cc3oc4ccccc4c23)cc1 ; c1ccc(-c2ccc3cc4c(cc3c2)N(c2cccc3c2c2ccccc2n3-c2ccccc2)c2cc(-n3c5ccccc5c5ccccc53)cc3c2B4c2cc4ccc(-n5c6ccccc6c6ccccc65)cc4cc2N3c2cccc3c2c2ccccc2n3-c2ccccc2)cc1 ; c1ccc(-c2ccc3cc4c(cc3c2)B2c3cc5cc(-n6c7ccccc7c7ccccc76)ccc5cc3N(c3cc(-c5ccccc5)cc5oc6ccccc6c35)c3cc(-n5c6ccccc6c6ccccc65)cc(c32)N4c2cc(-c3ccccc3)cc3oc4ccccc4c23)cc1]

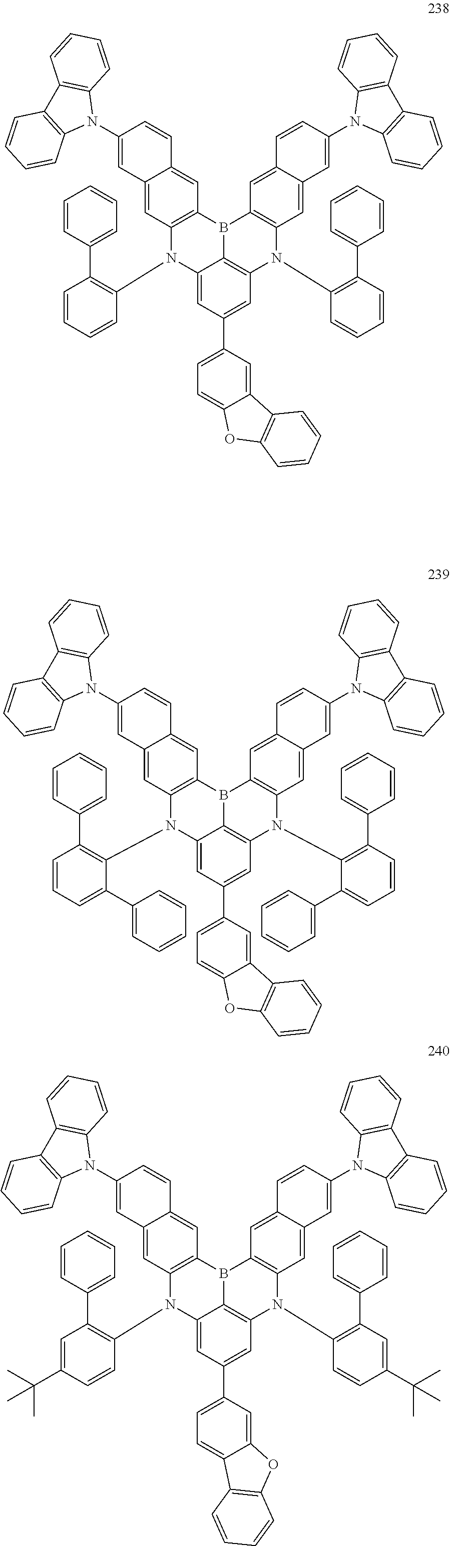 [SMILES: c1ccc(-c2ccccc2N2c3cc4cc(-n5c6ccccc6c6ccccc65)ccc4cc3B3c4cc5ccc(-n6c7ccccc7c7ccccc76)cc5cc4N(c4ccccc4-c4ccccc4)c4cc(-c5ccc6oc7ccccc7c6c5)cc2c43)cc1 ; c1ccc(-c2cccc(-c3ccccc3)c2N2c3cc4cc(-n5c6ccccc6c6ccccc65)ccc4cc3B3c4cc5ccc(-n6c7ccccc7c7ccccc76)cc5cc4N(c4c(-c5ccccc5)cccc4-c4ccccc4)c4cc(-c5ccc6oc7ccccc7c6c5)cc2c43)cc1 ; CC(C)(C)c1ccc(N2c3cc4cc(-n5c6ccccc6c6ccccc65)ccc4cc3B3c4cc5ccc(-n6c7ccccc7c7ccccc76)cc5cc4N(c4ccc(C(C)(C)C)cc4-c4ccccc4)c4cc(-c5ccc6c(c5)oc5ccccc56)cc2c43)c(-c2ccccc2)c1]

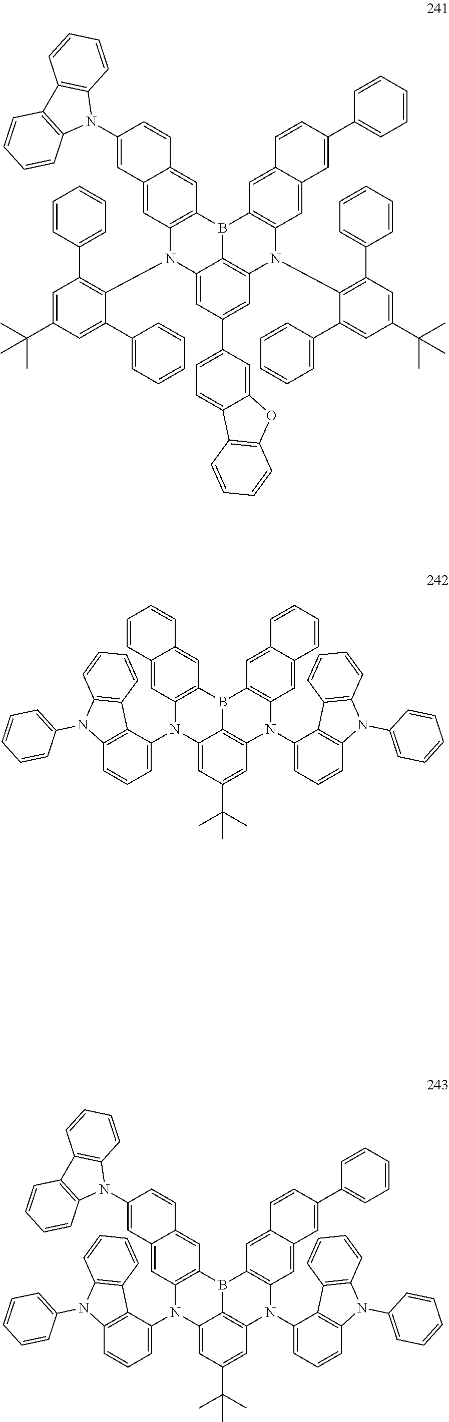 [SMILES: CC(C)(C)c1cc(-c2ccccc2)c(N2c3cc4cc(-c5ccccc5)ccc4cc3B3c4cc5ccc(-n6c7ccccc7c7ccccc76)cc5cc4N(c4c(-c5ccccc5)cc(C(C)(C)C)cc4-c4ccccc4)c4cc(-c5ccc6c(c5)oc5ccccc56)cc2c43)c(-c2ccccc2)c1 ; CC(C)(C)c1cc2c3c(c1)N(c1cccc4c1c1ccccc1n4-c1ccccc1)c1cc4ccccc4cc1B3c1cc3ccccc3cc1N2c1cccc2c1c1ccccc1n2-c1ccccc1 ; CC(C)(C)c1cc2c3c(c1)N(c1cccc4c1c1ccccc1n4-c1ccccc1)c1cc4cc(-n5c6ccccc6c6ccccc65)ccc4cc1B3c1cc3ccc(-c4ccccc4)cc3cc1N2c1cccc2c1c1ccccc1n2-c1ccccc1]

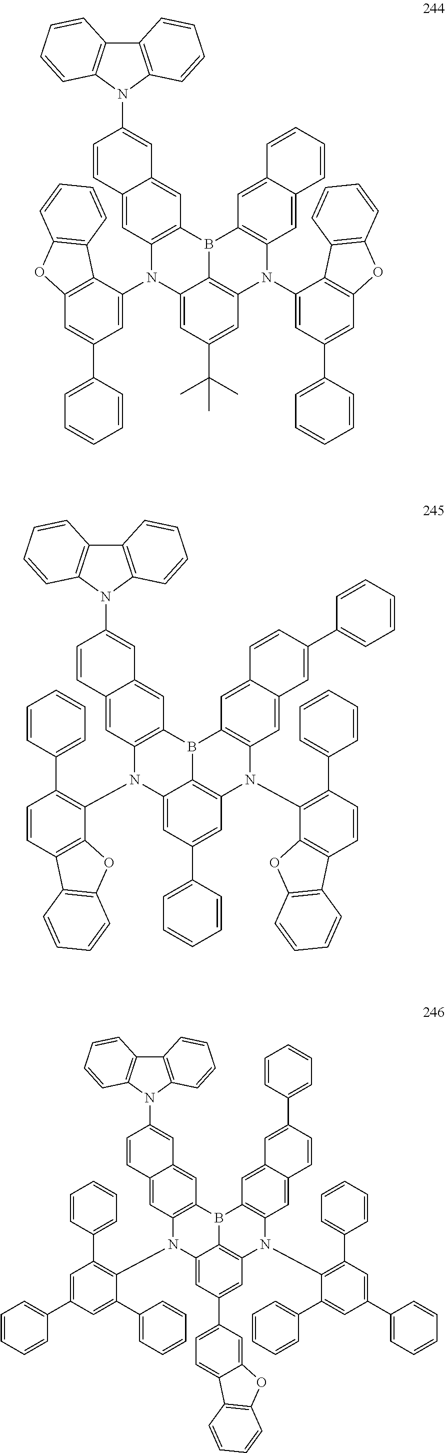 [SMILES: CC(C)(C)c1cc2c3c(c1)N(c1cc(-c4ccccc4)cc4oc5ccccc5c14)c1cc4ccc(-n5c6ccccc6c6ccccc65)cc4cc1B3c1cc3ccccc3cc1N2c1cc(-c2ccccc2)cc2oc3ccccc3c12 ; c1ccc(-c2cc3c4c(c2)N(c2c(-c5ccccc5)ccc5c2oc2ccccc25)c2cc5cc(-c6ccccc6)ccc5cc2B4c2cc4cc(-n5c6ccccc6c6ccccc65)ccc4cc2N3c2c(-c3ccccc3)ccc3c2oc2ccccc23)cc1 ; c1ccc(-c2cc(-c3ccccc3)c(N3c4cc5ccc(-c6ccccc6)cc5cc4B4c5cc6cc(-n7c8ccccc8c8ccccc87)ccc6cc5N(c5c(-c6ccccc6)cc(-c6ccccc6)cc5-c5ccccc5)c5cc(-c6ccc7c(c6)oc6ccccc67)cc3c54)c(-c3ccccc3)c2)cc1]

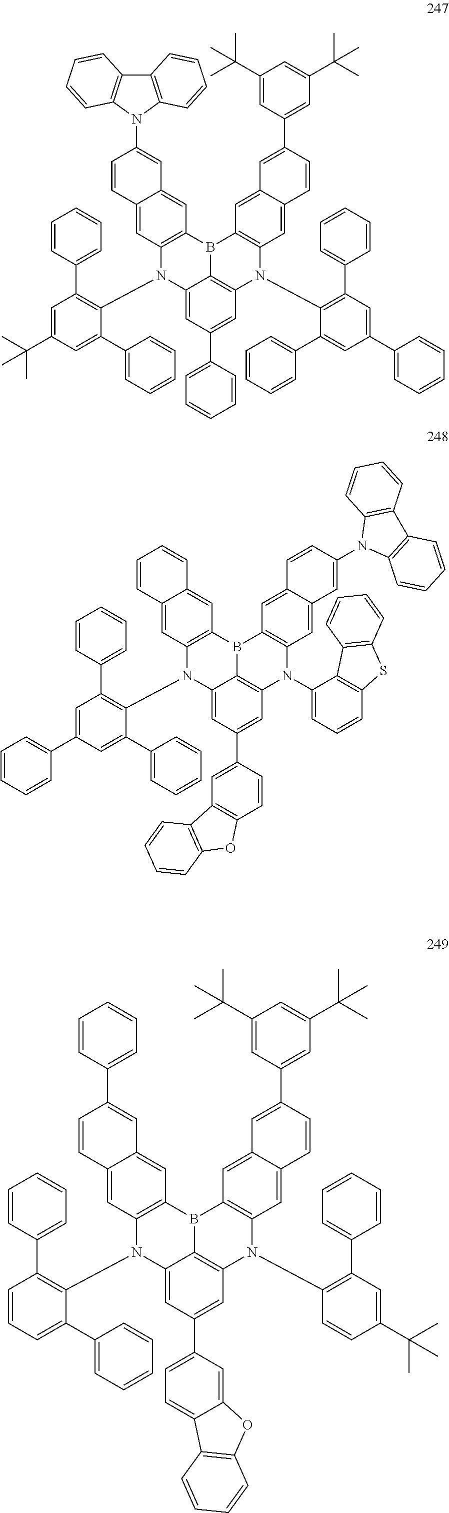

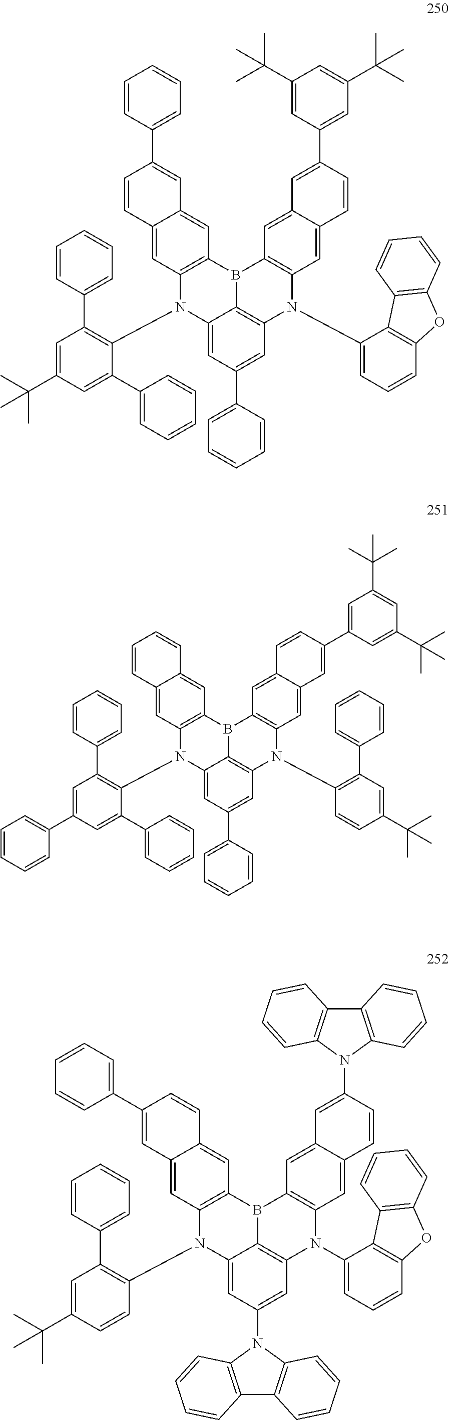

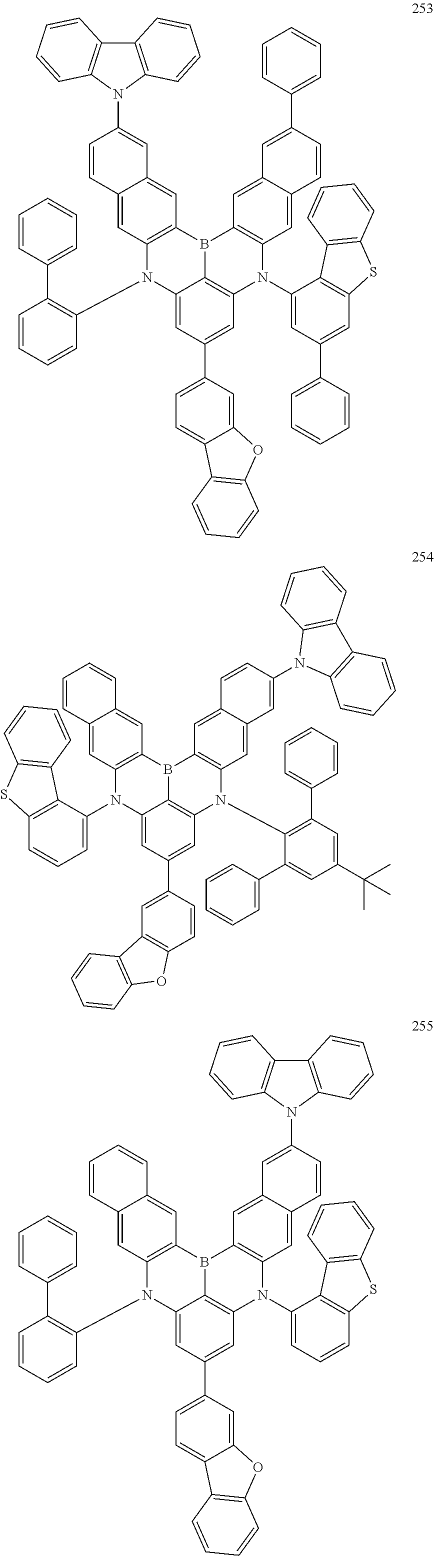 [SMILES: c1ccc(-c2ccc3cc4c(cc3c2)B2c3cc5cc(-n6c7ccccc7c7ccccc76)ccc5cc3N(c3ccccc3-c3ccccc3)c3cc(-c5ccc6c(c5)oc5ccccc56)cc(c32)N4c2cc(-c3ccccc3)cc3sc4ccccc4c23)cc1 ; CC(C)(C)c1cc(-c2ccccc2)c(N2c3cc4cc(-n5c6ccccc6c6ccccc65)ccc4cc3B3c4cc5ccccc5cc4N(c4cccc5sc6ccccc6c45)c4cc(-c5ccc6oc7ccccc7c6c5)cc2c43)c(-c2ccccc2)c1 ; c1ccc(-c2ccccc2N2c3cc4ccccc4cc3B3c4cc5cc(-n6c7ccccc7c7ccccc76)ccc5cc4N(c4cccc5sc6ccccc6c45)c4cc(-c5ccc6c(c5)oc5ccccc56)cc2c43)cc1]

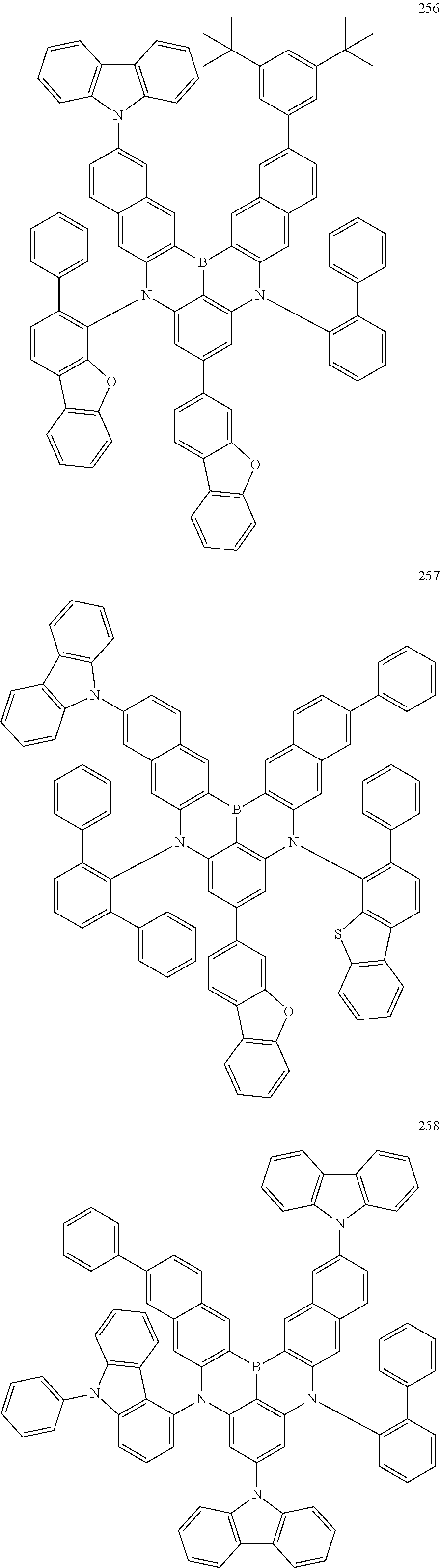 [SMILES: CC(C)(C)c1cc(-c2ccc3cc4c(cc3c2)B2c3cc5cc(-n6c7ccccc7c7ccccc76)ccc5cc3N(c3c(-c5ccccc5)ccc5c3oc3ccccc35)c3cc(-c5ccc6c(c5)oc5ccccc56)cc(c32)N4c2ccccc2-c2ccccc2)cc(C(C)(C)C)c1 ; c1ccc(-c2ccc3cc4c(cc3c2)N(c2c(-c3ccccc3)ccc3c2sc2ccccc23)c2cc(-c3ccc5c(c3)oc3ccccc35)cc3c2B4c2cc4ccc(-n5c6ccccc6c6ccccc65)cc4cc2N3c2c(-c3ccccc3)cccc2-c2ccccc2)cc1 ; c1ccc(-c2ccc3cc4c(cc3c2)N(c2cccc3c2c2ccccc2n3-c2ccccc2)c2cc(-n3c5ccccc5c5ccccc53)cc3c2B4c2cc4cc(-n5c6ccccc6c6ccccc65)ccc4cc2N3c2ccccc2-c2ccccc2)cc1]

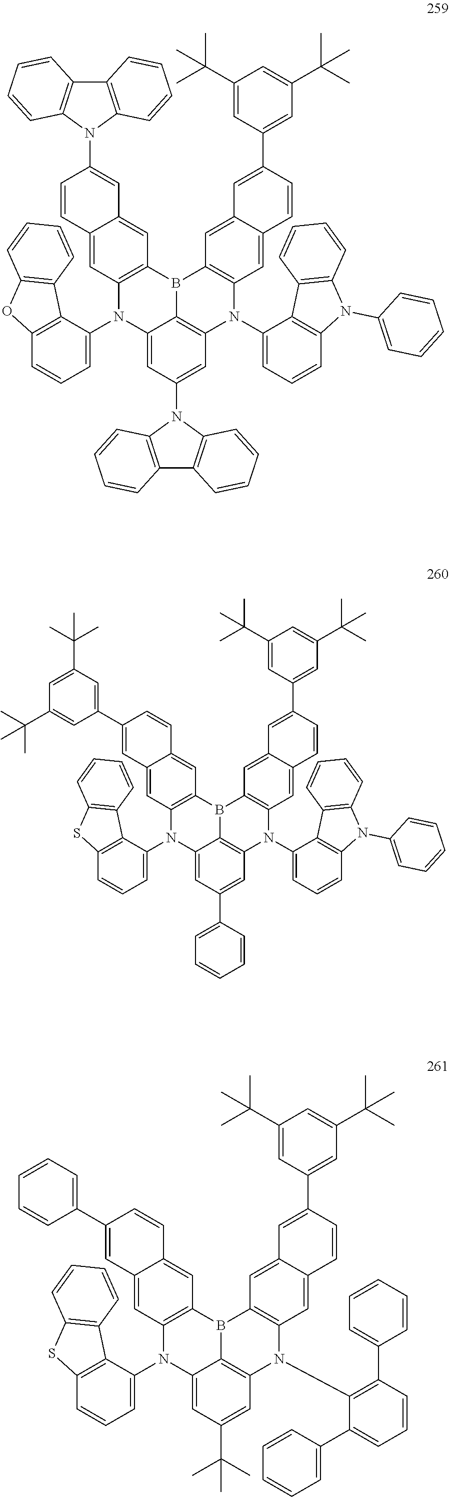 [SMILES: CC(C)(C)c1cc(-c2ccc3cc4c(cc3c2)B2c3cc5cc(-n6c7ccccc7c7ccccc76)ccc5cc3N(c3cccc5oc6ccccc6c35)c3cc(-n5c6ccccc6c6ccccc65)cc(c32)N4c2cccc3c2c2ccccc2n3-c2ccccc2)cc(C(C)(C)C)c1 ; CC(C)(C)c1cc(-c2ccc3cc4c(cc3c2)B2c3cc5ccc(-c6cc(C(C)(C)C)cc(C(C)(C)C)c6)cc5cc3N(c3cccc5sc6ccccc6c35)c3cc(-c5ccccc5)cc(c32)N4c2cccc3c2c2ccccc2n3-c2ccccc2)cc(C(C)(C)C)c1 ; CC(C)(C)c1cc(-c2ccc3cc4c(cc3c2)B2c3cc5ccc(-c6ccccc6)cc5cc3N(c3cccc5sc6ccccc6c35)c3cc(C(C)(C)C)cc(c32)N4c2c(-c3ccccc3)cccc2-c2ccccc2)cc(C(C)(C)C)c1]

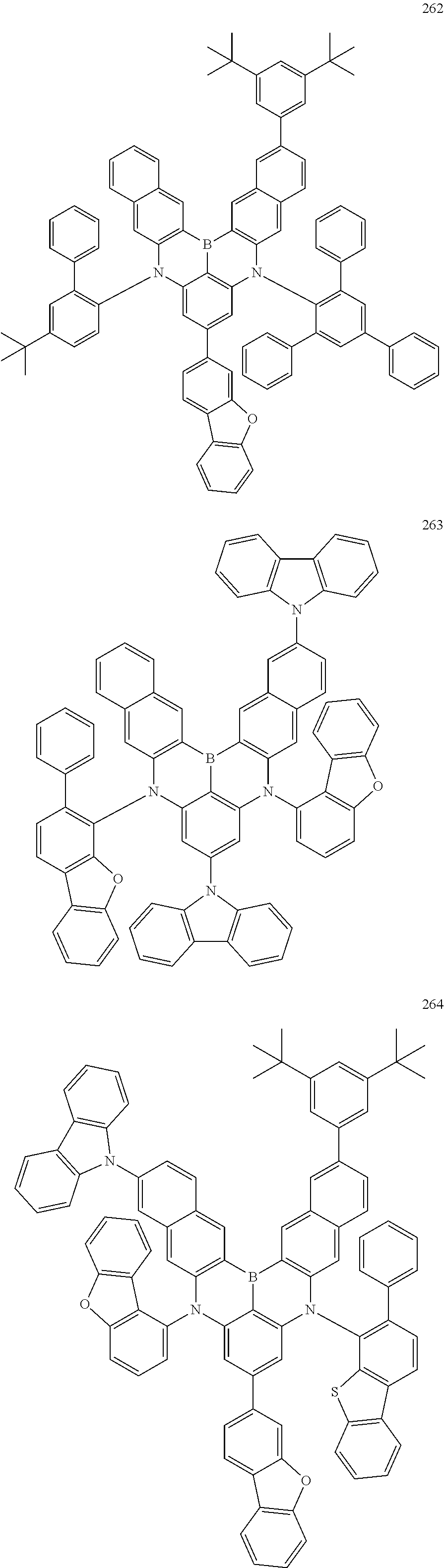 [SMILES: CC(C)(C)c1cc(-c2ccc3cc4c(cc3c2)B2c3cc5ccccc5cc3N(c3ccc(C(C)(C)C)cc3-c3ccccc3)c3cc(-c5ccc6c(c5)oc5ccccc56)cc(c32)N4c2c(-c3ccccc3)cc(-c3ccccc3)cc2-c2ccccc2)cc(C(C)(C)C)c1 ; c1ccc(-c2ccc3c(oc4ccccc43)c2N2c3cc4ccccc4cc3B3c4cc5cc(-n6c7ccccc7c7ccccc76)ccc5cc4N(c4cccc5oc6ccccc6c45)c4cc(-n5c6ccccc6c6ccccc65)cc2c43)cc1 ; CC(C)(C)c1cc(-c2ccc3cc4c(cc3c2)B2c3cc5ccc(-n6c7ccccc7c7ccccc76)cc5cc3N(c3cccc5oc6ccccc6c35)c3cc(-c5ccc6c(c5)oc5ccccc56)cc(c32)N4c2c(-c3ccccc3)ccc3c2sc2ccccc23)cc(C(C)(C)C)c1]

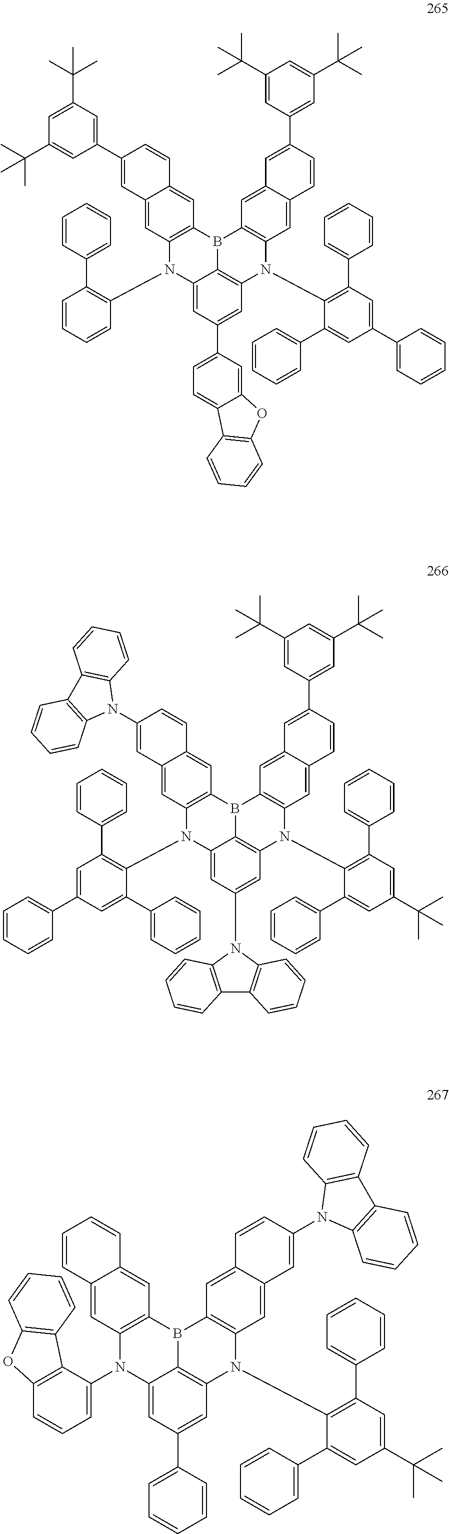

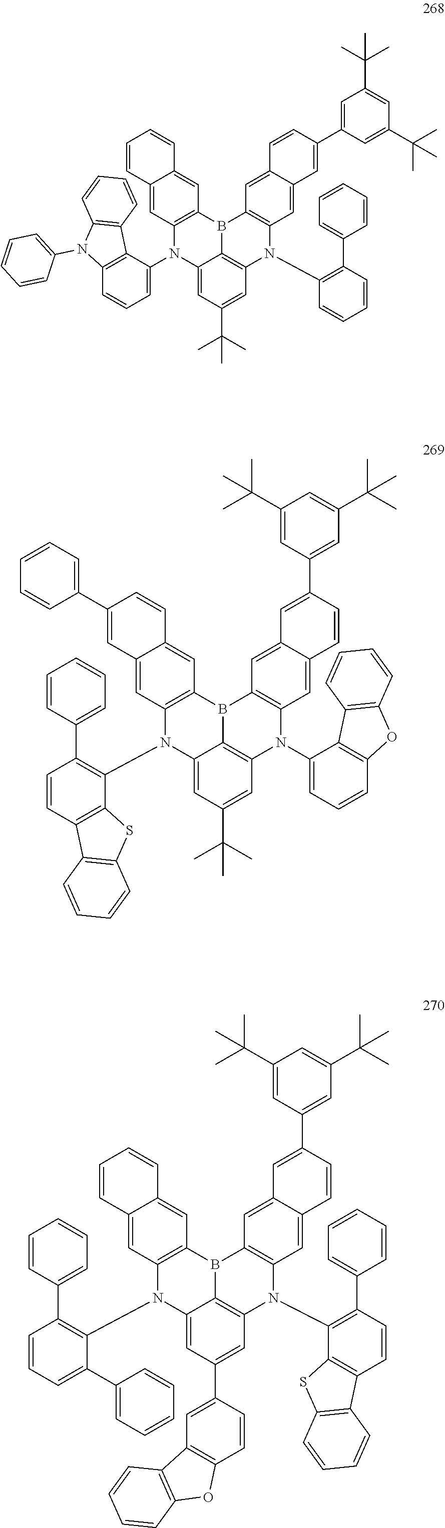 [SMILES: CC(C)(C)c1cc(-c2ccc3cc4c(cc3c2)N(c2ccccc2-c2ccccc2)c2cc(C(C)(C)C)cc3c2B4c2cc4ccccc4cc2N3c2cccc3c2c2ccccc2n3-c2ccccc2)cc(C(C)(C)C)c1 ; CC(C)(C)c1cc(-c2ccc3cc4c(cc3c2)B2c3cc5ccc(-c6ccccc6)cc5cc3N(c3c(-c5ccccc5)ccc5c3sc3ccccc35)c3cc(C(C)(C)C)cc(c32)N4c2cccc3oc4ccccc4c23)cc(C(C)(C)C)c1 ; CC(C)(C)c1cc(-c2ccc3cc4c(cc3c2)B2c3cc5ccccc5cc3N(c3c(-c5ccccc5)cccc3-c3ccccc3)c3cc(-c5ccc6oc7ccccc7c6c5)cc(c32)N4c2c(-c3ccccc3)ccc3c2sc2ccccc23)cc(C(C)(C)C)c1]

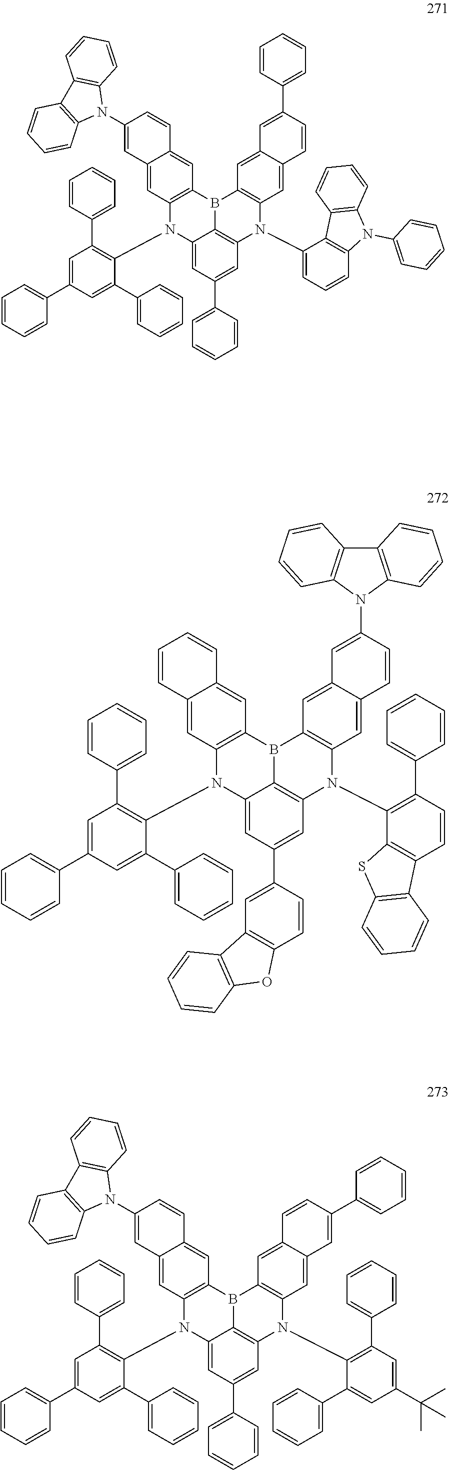 [SMILES: c1ccc(-c2cc(-c3ccccc3)c(N3c4cc5cc(-n6c7ccccc7c7ccccc76)ccc5cc4B4c5cc6cc(-c7ccccc7)ccc6cc5N(c5cccc6c5c5ccccc5n6-c5ccccc5)c5cc(-c6ccccc6)cc3c54)c(-c3ccccc3)c2)cc1 ; c1ccc(-c2cc(-c3ccccc3)c(N3c4cc5ccccc5cc4B4c5cc6cc(-n7c8ccccc8c8ccccc87)ccc6cc5N(c5c(-c6ccccc6)ccc6c5sc5ccccc56)c5cc(-c6ccc7oc8ccccc8c7c6)cc3c54)c(-c3ccccc3)c2)cc1 ; CC(C)(C)c1cc(-c2ccccc2)c(N2c3cc4cc(-c5ccccc5)ccc4cc3B3c4cc5ccc(-n6c7ccccc7c7ccccc76)cc5cc4N(c4c(-c5ccccc5)cc(-c5ccccc5)cc4-c4ccccc4)c4cc(-c5ccccc5)cc2c43)c(-c2ccccc2)c1]

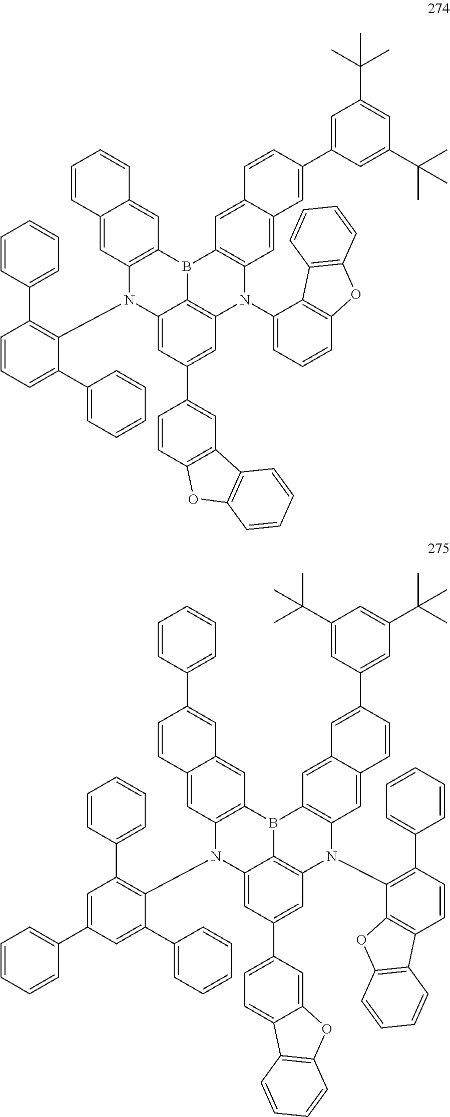 [SMILES: CC(C)(C)c1cc(-c2ccc3cc4c(cc3c2)N(c2cccc3oc5ccccc5c23)c2cc(-c3ccc5oc6ccccc6c5c3)cc3c2B4c2cc4ccccc4cc2N3c2c(-c3ccccc3)cccc2-c2ccccc2)cc(C(C)(C)C)c1 ; CC(C)(C)c1cc(-c2ccc3cc4c(cc3c2)B2c3cc5cc(-c6ccccc6)ccc5cc3N(c3c(-c5ccccc5)cc(-c5ccccc5)cc3-c3ccccc3)c3cc(-c5ccc6c(c5)oc5ccccc56)cc(c32)N4c2c(-c3ccccc3)ccc3c2oc2ccccc23)cc(C(C)(C)C)c1]

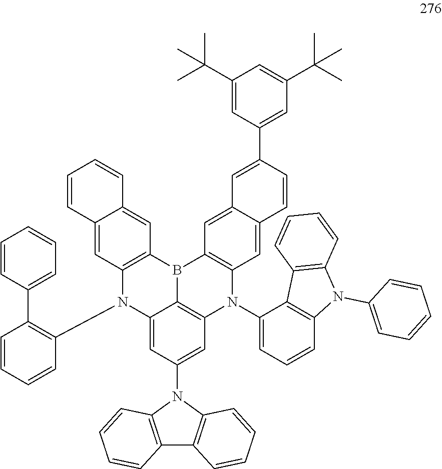 [SMILES: CC(C)(C)c1cc(-c2ccc3cc4c(cc3c2)B2c3cc5ccccc5cc3N(c3ccccc3-c3ccccc3)c3cc(-n5c6ccccc6c6ccccc65)cc(c32)N4c2cccc3c2c2ccccc2n3-c2ccccc2)cc(C(C)(C)C)c1]

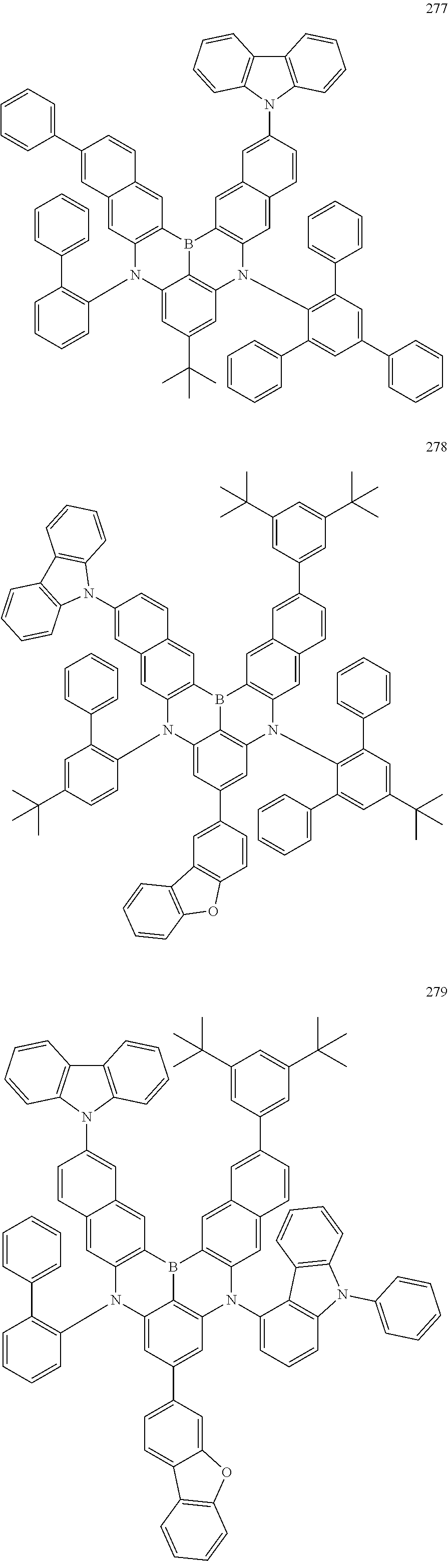

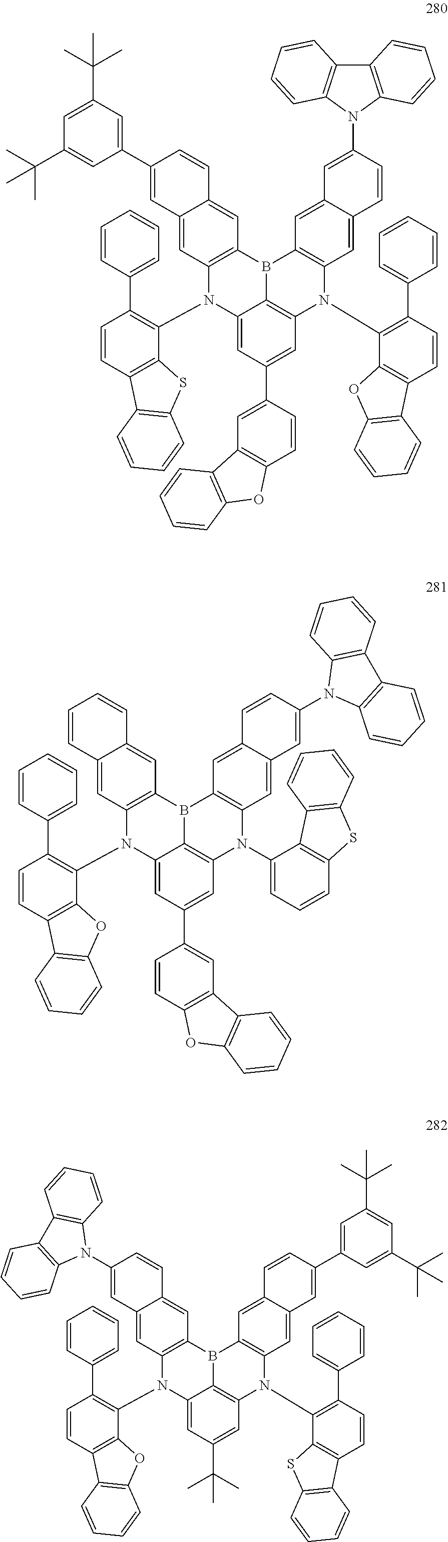 [SMILES: CC(C)(C)c1cc(-c2ccc3cc4c(cc3c2)N(c2c(-c3ccccc3)ccc3c2sc2ccccc23)c2cc(-c3ccc5oc6ccccc6c5c3)cc3c2B4c2cc4cc(-n5c6ccccc6c6ccccc65)ccc4cc2N3c2c(-c3ccccc3)ccc3c2oc2ccccc23)cc(C(C)(C)C)c1 ; c1ccc(-c2ccc3c(oc4ccccc43)c2N2c3cc4ccccc4cc3B3c4cc5ccc(-n6c7ccccc7c7ccccc76)cc5cc4N(c4cccc5sc6ccccc6c45)c4cc(-c5ccc6oc7ccccc7c6c5)cc2c43)cc1 ; CC(C)(C)c1cc(-c2ccc3cc4c(cc3c2)N(c2c(-c3ccccc3)ccc3c2sc2ccccc23)c2cc(C(C)(C)C)cc3c2B4c2cc4ccc(-n5c6ccccc6c6ccccc65)cc4cc2N3c2c(-c3ccccc3)ccc3c2oc2ccccc23)cc(C(C)(C)C)c1]

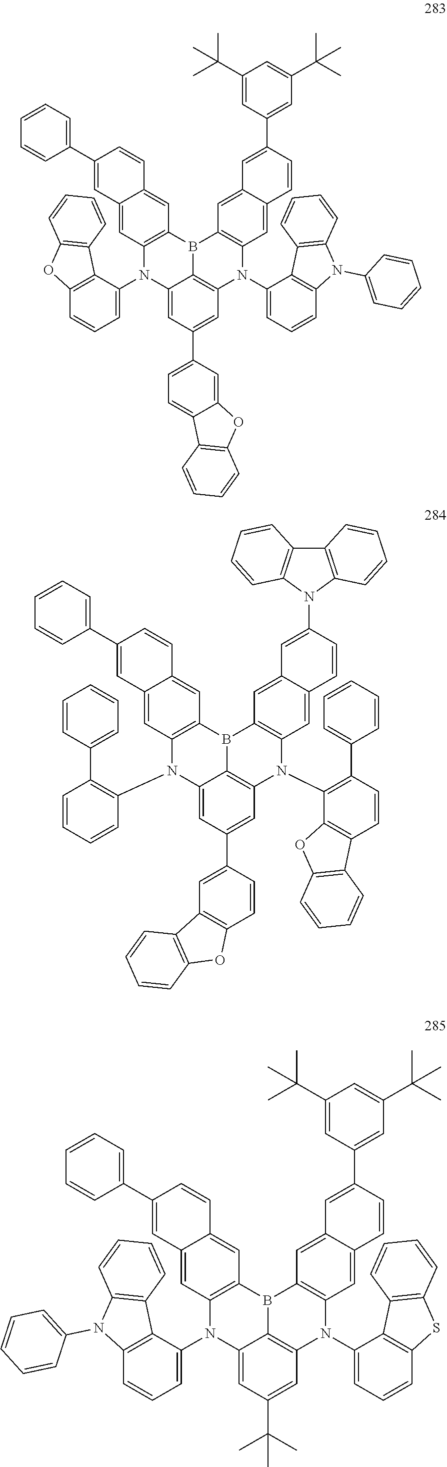

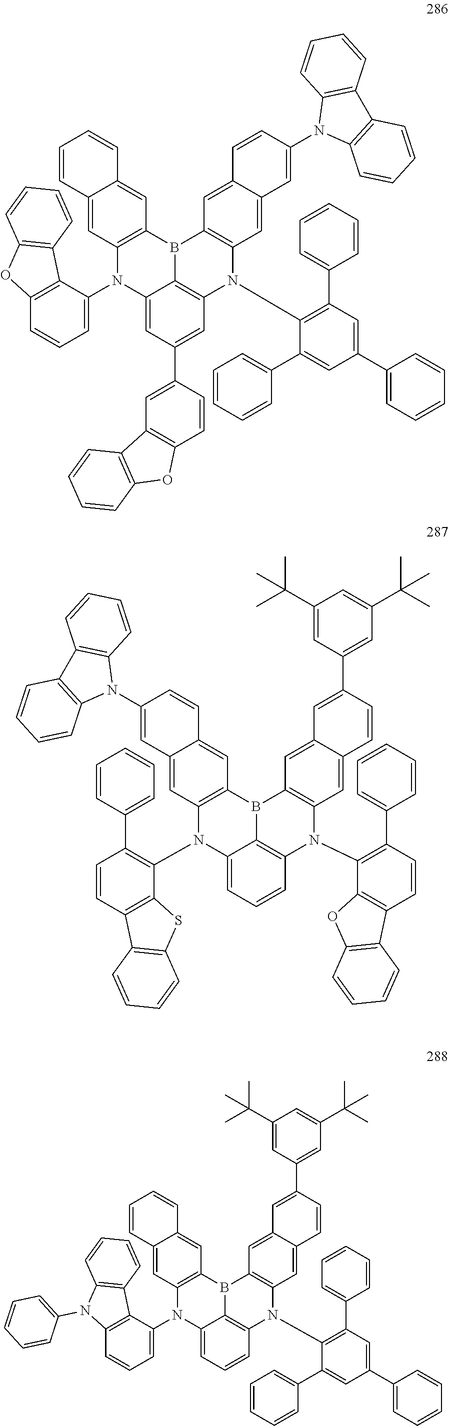 [SMILES: c1ccc(-c2cc(-c3ccccc3)c(N3c4cc5cc(-n6c7ccccc7c7ccccc76)ccc5cc4B4c5cc6ccccc6cc5N(c5cccc6oc7ccccc7c56)c5cc(-c6ccc7oc8ccccc8c7c6)cc3c54)c(-c3ccccc3)c2)cc1 ; CC(C)(C)c1cc(-c2ccc3cc4c(cc3c2)B2c3cc5ccc(-n6c7ccccc7c7ccccc76)cc5cc3N(c3c(-c5ccccc5)ccc5c3sc3ccccc35)c3cccc(c32)N4c2c(-c3ccccc3)ccc3c2oc2ccccc23)cc(C(C)(C)C)c1 ; CC(C)(C)c1cc(-c2ccc3cc4c(cc3c2)B2c3cc5ccccc5cc3N(c3cccc5c3c3ccccc3n5-c3ccccc3)c3cccc(c32)N4c2c(-c3ccccc3)cc(-c3ccccc3)cc2-c2ccccc2)cc(C(C)(C)C)c1]

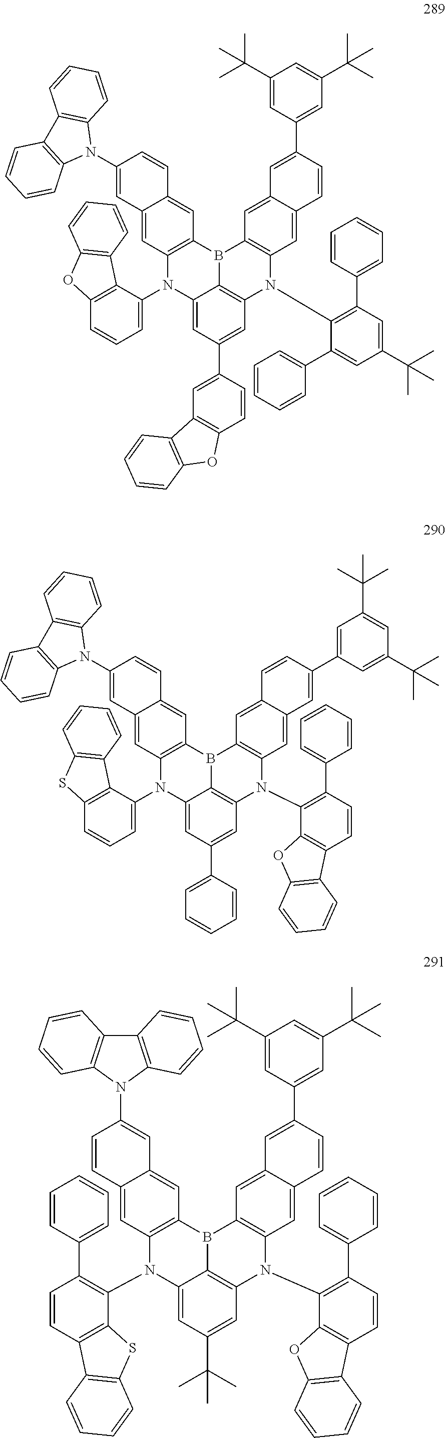

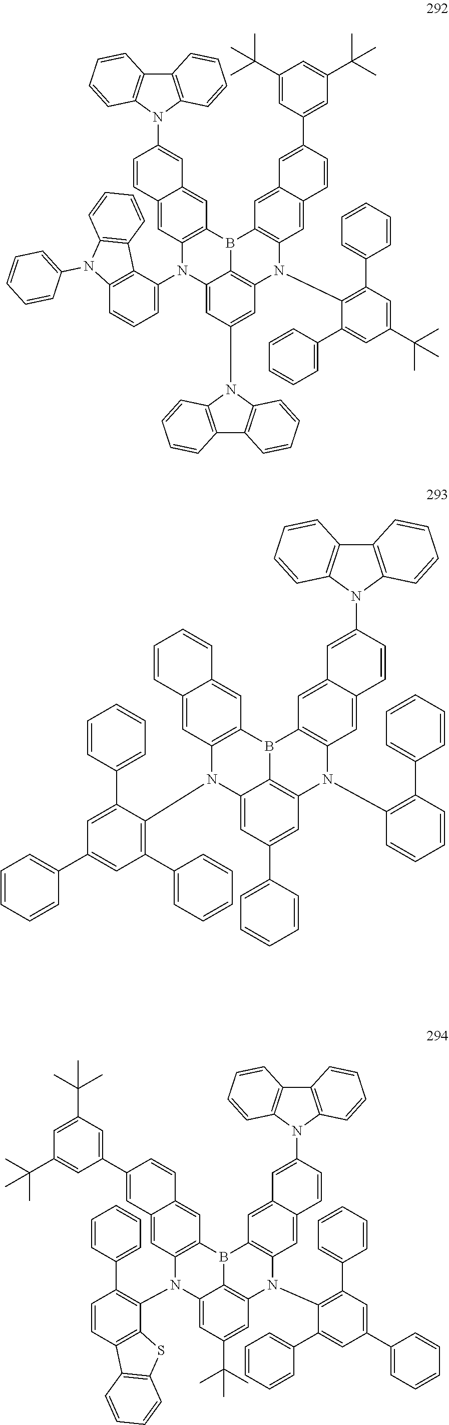

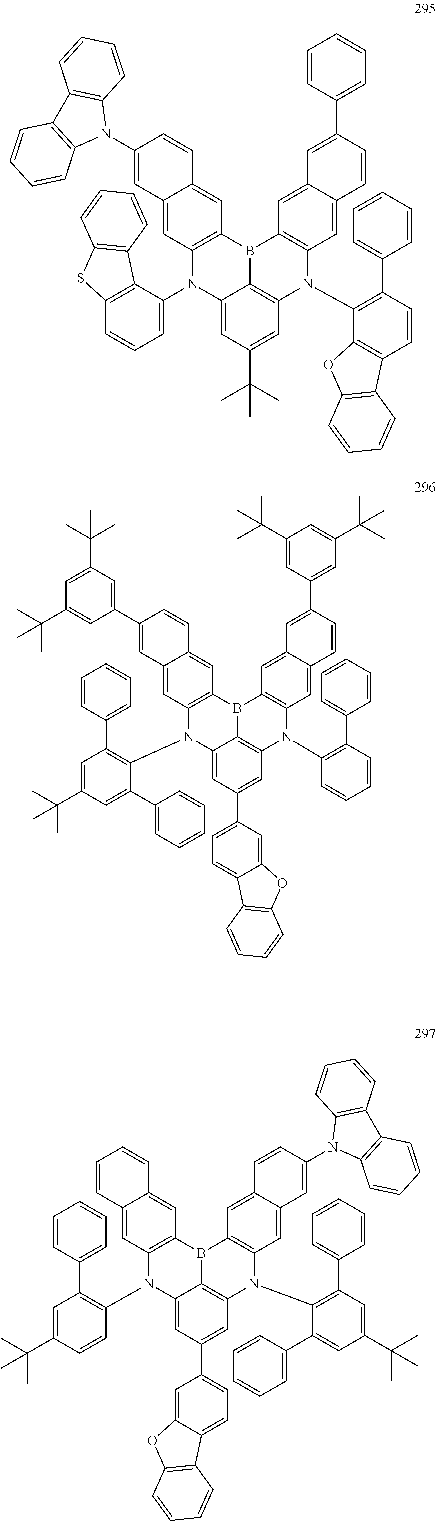

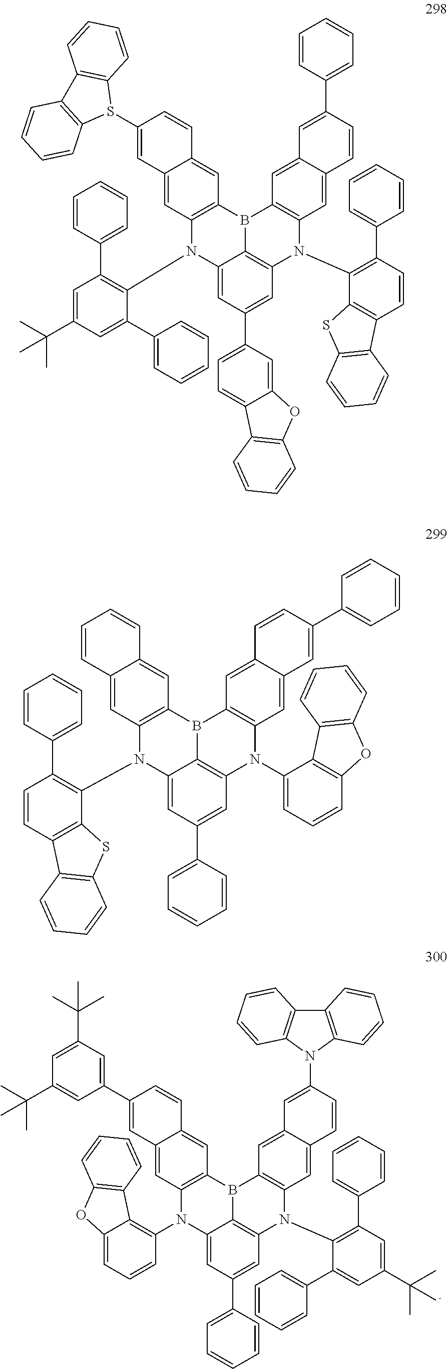

11. A polycyclic compound represented by Formula 1: 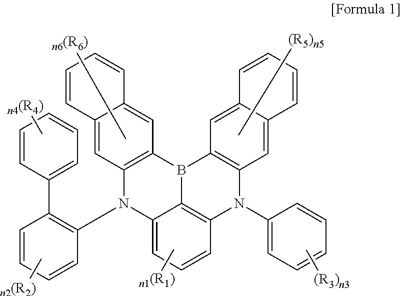
wherein in Formula 1,
R₁ to R₆ are each independently a hydrogen atom, a deuterium atom, a cyano group, a substituted or unsubstituted amine group, a substituted or unsubstituted oxy group, a substituted or unsubstituted thio group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, or bonded to an adjacent group to form a ring,
n1 is an integer from 0 to 3,
n2 is an integer from 0 to 4,
n3 and n4 are each independently an integer from 0 to 5, and
n5 and n6 are each independently an integer from 0 to 6.

12. The polycyclic compound of claim 11, wherein the polycyclic compound is represented by Formula 2: 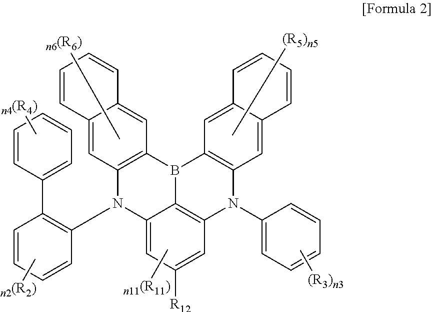
wherein in Formula 2,
R₁₁ is a hydrogen atom, a deuterium atom, a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons,
R₁₂ is a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons,
n11 is an integer from 0 to 2, and
R₂ to R₆ and n2 to n6 are the same as defined in Formula 1.

13. The polycyclic compound of claim 11, wherein the polycyclic compound is represented by Formula 3: 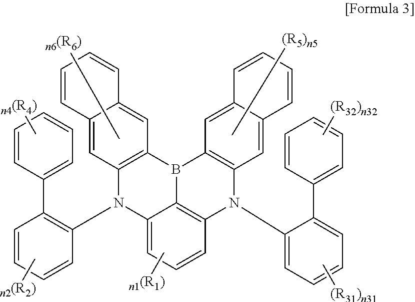
wherein in Formula 3,
R₃₁ and R₃₂ are each independently a hydrogen atom, a deuterium atom, a cyano group, a substituted or unsubstituted amine group, a substituted or unsubstituted oxy group, a substituted or unsubstituted thio group, a substituted or unsubstituted alkyl group having 1 to 30 carbons, a substituted or unsubstituted alkenyl group having 2 to 30 carbons, or a substituted or unsubstituted aryl group having 6 to 30 ring-forming carbons, or bonded to an adjacent group to form a ring,
n31 is an integer from 0 to 4,
n32 is an integer from 0 to 5, and
R₁, R₂, R₄ to R₆, n1, n2, and n4 to n6 are the same as defined in Formula 1.

14. The polycyclic compound of claim 11, wherein the polycyclic compound is represented by one of Formula 4-1 to Formula 4-3: 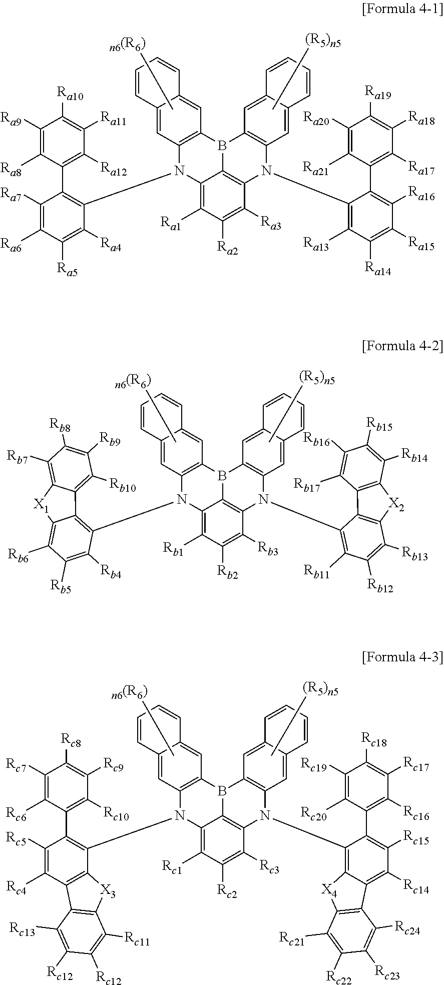
wherein Formula 4-2 to Formula 4-3,
X₁ to X₄ are each independently O or S, and
wherein in Formula 4-1 to Formula 4-3,
Rₐ₁ to Rₐ₂₁, R_{b1} to R_{b17}, and R_{c1} to R_{c24} are each independently a hydrogen atom, a deuterium atom, a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons, and
R₅, R₆, n5, and n6 are the same as defined in Formula 1.

15. The polycyclic compound of claim 11, wherein the polycyclic compound is represented by Formula 5-1 or Formula 5-2: 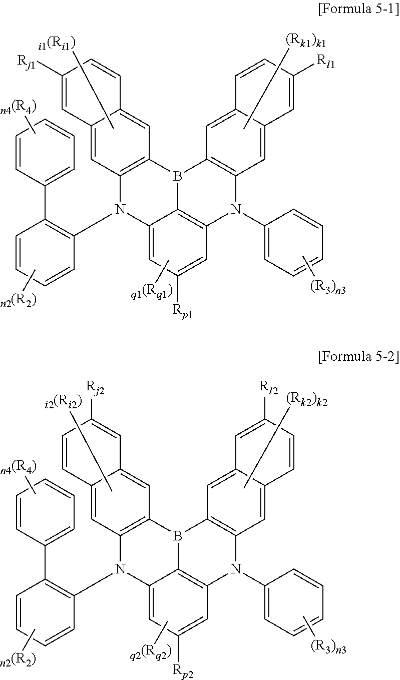
wherein in Formula 5-1 and Formula 5-2,
Rᵢ₁, Rᵢ₂, Rᵢ₁, Rⱼ₂, Rₖ₁, Rₖ₂, Rₗ₁, Rₗ₂, Rₚ₁, Rₚ₂, R_{q1}, and R_{q2} are each independently a hydrogen atom, a deuterium atom, a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons,
provided that at least one of Rⱼ₁, Rₗ₁, and Rₚ₁ and at least one of Rⱼ₂, Rₗ₂, and Rₚ₂ are each independently a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons,
i1, i2, k1, and k2 are each independently an integer from 0 to 5,
q1 and q2 are each independently an integer from 0 to 2, and
R₂ to R₄ and n2 to n4 are the same as defined in Formula 1.

16. The polycyclic compound of claim 15, wherein the polycyclic compound is represented by Formula 5-1-1 or Formula 5-2-1: 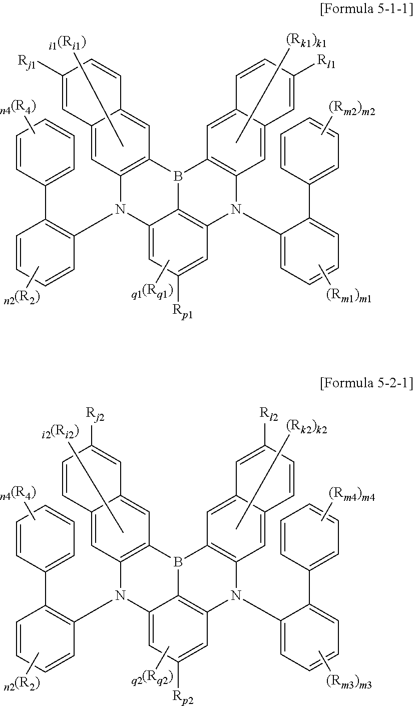
wherein in Formula 5-1-1 and Formula 5-2-1,
Rₘ₁, Rₘ₂, Rₘ₃, and Rₘ₄ are each independently a hydrogen atom, a deuterium atom, a substituted or unsubstituted amine group, a substituted or unsubstituted oxy group, a substituted or unsubstituted thio group, a substituted or unsubstituted alkyl group having 1 to 30 carbons, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, a substituted or unsubstituted heteroaryl group having 2 to 30 ring-forming carbons, or bonded to an adjacent group to form a ring,
m1 and m3 are each independently an integer from 0 to 4,
m2 and m4 are each independently an integer from 0 to 5, and
R₂, R₄, Rᵢ₁, Rᵢ₂, Rⱼ₁, Rⱼ₂, Rₖ₁, Rₖ₂, Rₗ₁, Rₗ₂, Rₚ₁, Rₚ₂, R_{q1}, R_{q2}, n2, n4, i1, i2, k1, k2, q1, and q2 are the same as defined in Formula 1, Formula 5-1, and Formula 5-2.

17. The polycyclic compound of claim 11, wherein the polycyclic compound has peak emission wavelength in a range of about 490 nm to about 550 nm.

18. The polycyclic compound of claim 11, wherein the polycyclic compound is selected from Compound Group 1:

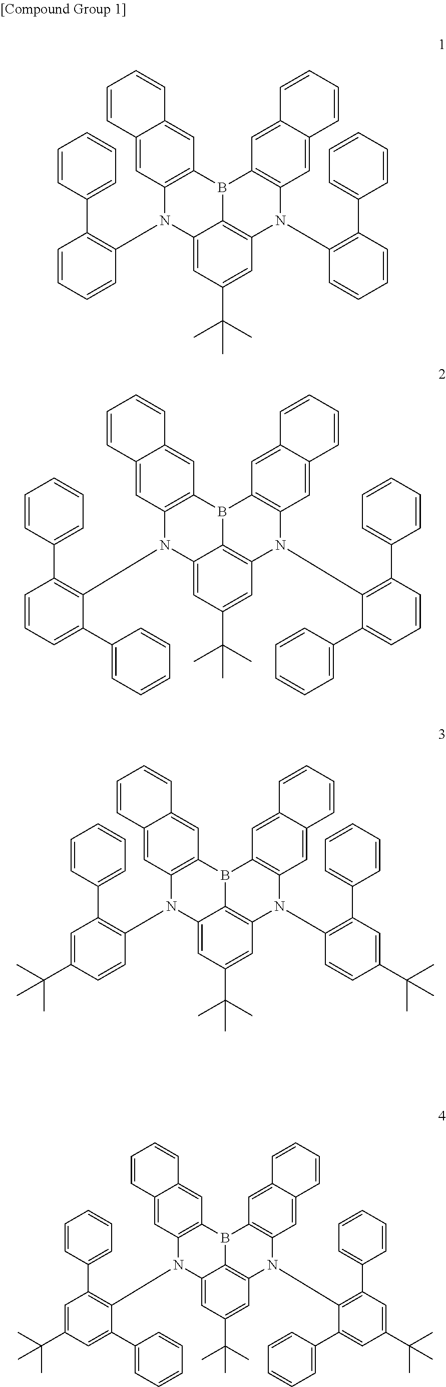

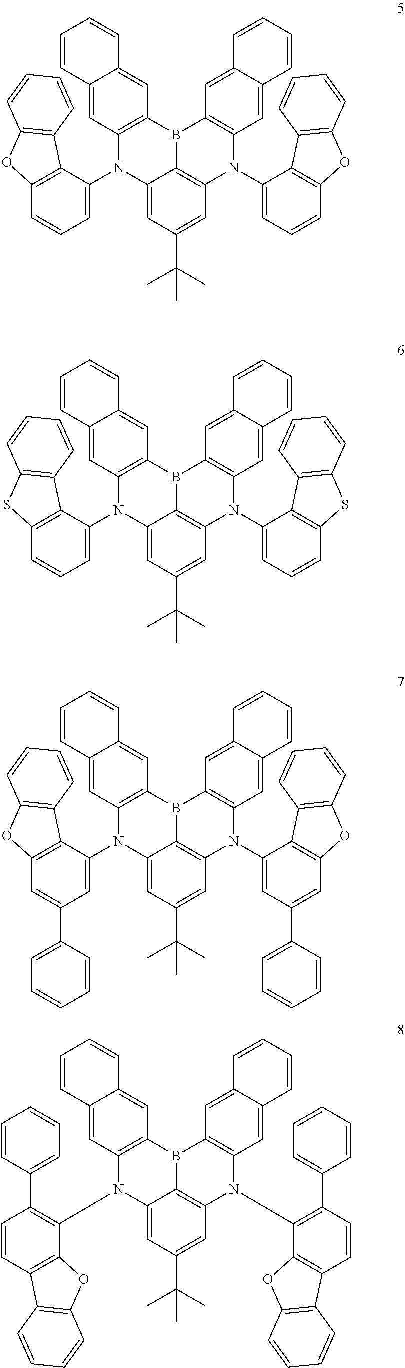

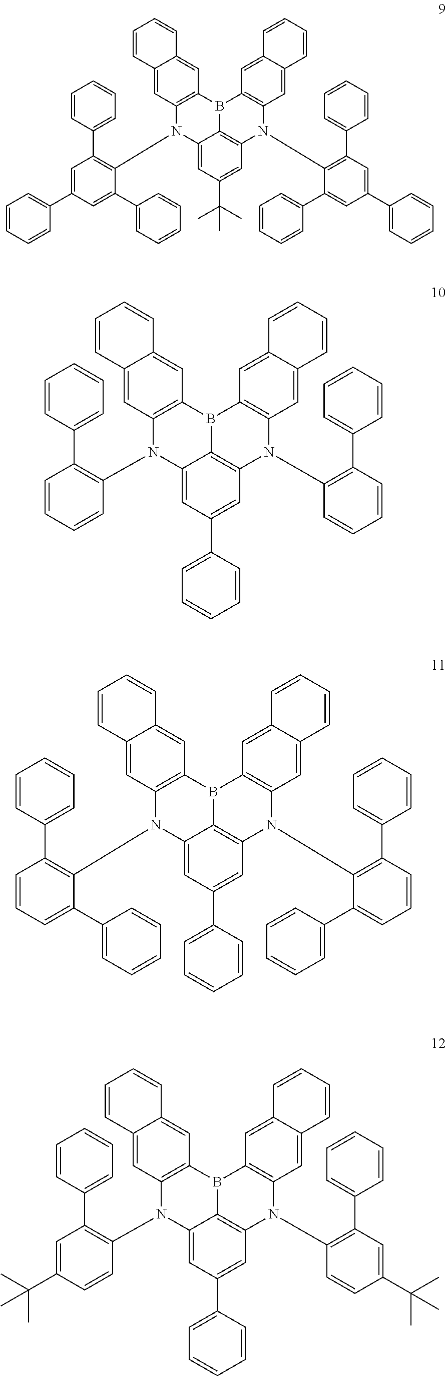 [SMILES: CC(C)(C)c1cc2c3c(c1)N(c1c(-c4ccccc4)cc(-c4ccccc4)cc1-c1ccccc1)c1cc4ccccc4cc1B3c1cc3ccccc3cc1N2c1c(-c2ccccc2)cc(-c2ccccc2)cc1-c1ccccc1 ; c1ccc(-c2cc3c4c(c2)N(c2ccccc2-c2ccccc2)c2cc5ccccc5cc2B4c2cc4ccccc4cc2N3c2ccccc2-c2ccccc2)cc1 ; c1ccc(-c2cc3c4c(c2)N(c2c(-c5ccccc5)cccc2-c2ccccc2)c2cc5ccccc5cc2B4c2cc4ccccc4cc2N3c2c(-c3ccccc3)cccc2-c2ccccc2)cc1 ; CC(C)(C)c1ccc(N2c3cc4ccccc4cc3B3c4cc5ccccc5cc4N(c4ccc(C(C)(C)C)cc4-c4ccccc4)c4cc(-c5ccccc5)cc2c43)c(-c2ccccc2)c1]

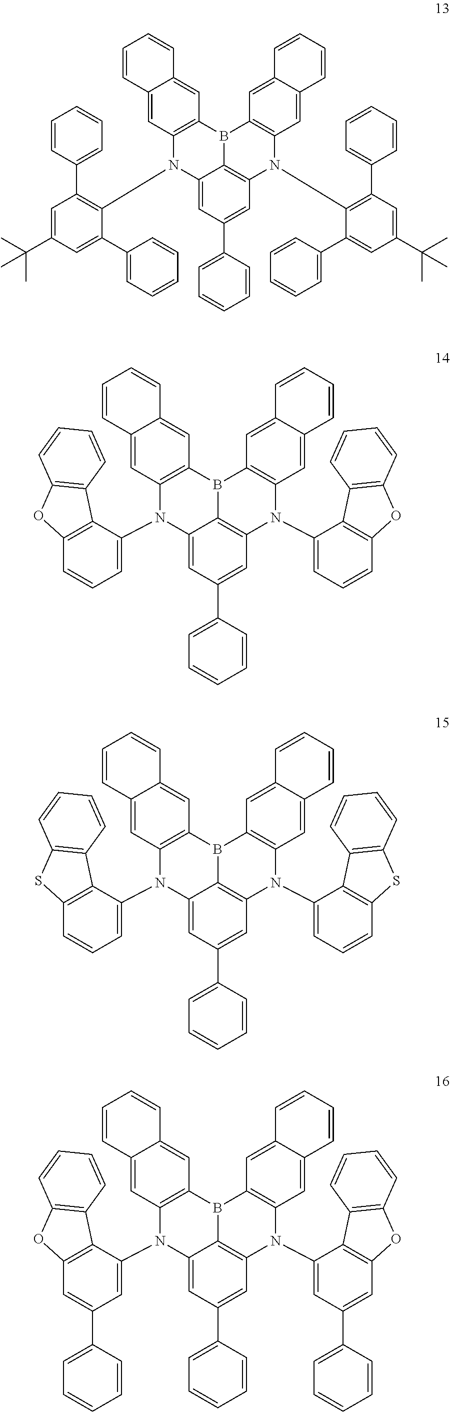 [SMILES: CC(C)(C)c1cc(-c2ccccc2)c(N2c3cc4ccccc4cc3B3c4cc5ccccc5cc4N(c4c(-c5ccccc5)cc(C(C)(C)C)cc4-c4ccccc4)c4cc(-c5ccccc5)cc2c43)c(-c2ccccc2)c1 ; c1ccc(-c2cc3c4c(c2)N(c2cccc5oc6ccccc6c25)c2cc5ccccc5cc2B4c2cc4ccccc4cc2N3c2cccc3oc4ccccc4c23)cc1 ; c1ccc(-c2cc3c4c(c2)N(c2cccc5sc6ccccc6c25)c2cc5ccccc5cc2B4c2cc4ccccc4cc2N3c2cccc3sc4ccccc4c23)cc1 ; c1ccc(-c2cc3c4c(c2)N(c2cc(-c5ccccc5)cc5oc6ccccc6c25)c2cc5ccccc5cc2B4c2cc4ccccc4cc2N3c2cc(-c3ccccc3)cc3oc4ccccc4c23)cc1]

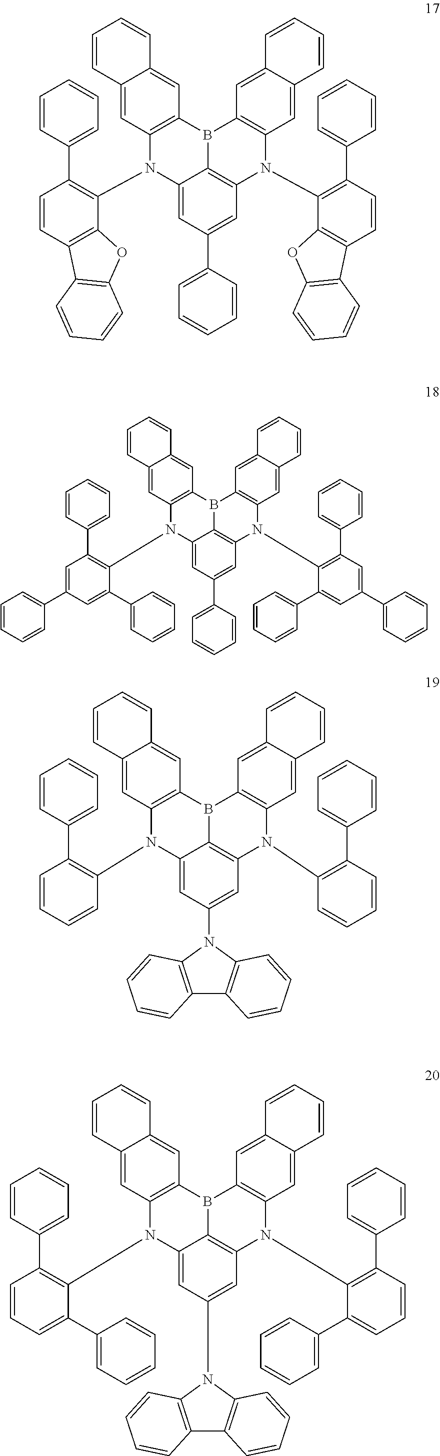 [SMILES: c1ccc(-c2cc3c4c(c2)N(c2c(-c5ccccc5)ccc5c2oc2ccccc25)c2cc5ccccc5cc2B4c2cc4ccccc4cc2N3c2c(-c3ccccc3)ccc3c2oc2ccccc23)cc1 ; c1ccc(-c2cc(-c3ccccc3)c(N3c4cc5ccccc5cc4B4c5cc6ccccc6cc5N(c5c(-c6ccccc6)cc(-c6ccccc6)cc5-c5ccccc5)c5cc(-c6ccccc6)cc3c54)c(-c3ccccc3)c2)cc1 ; c1ccc(-c2ccccc2N2c3cc4ccccc4cc3B3c4cc5ccccc5cc4N(c4ccccc4-c4ccccc4)c4cc(-n5c6ccccc6c6ccccc65)cc2c43)cc1 ; c1ccc(-c2cccc(-c3ccccc3)c2N2c3cc4ccccc4cc3B3c4cc5ccccc5cc4N(c4c(-c5ccccc5)cccc4-c4ccccc4)c4cc(-n5c6ccccc6c6ccccc65)cc2c43)cc1]

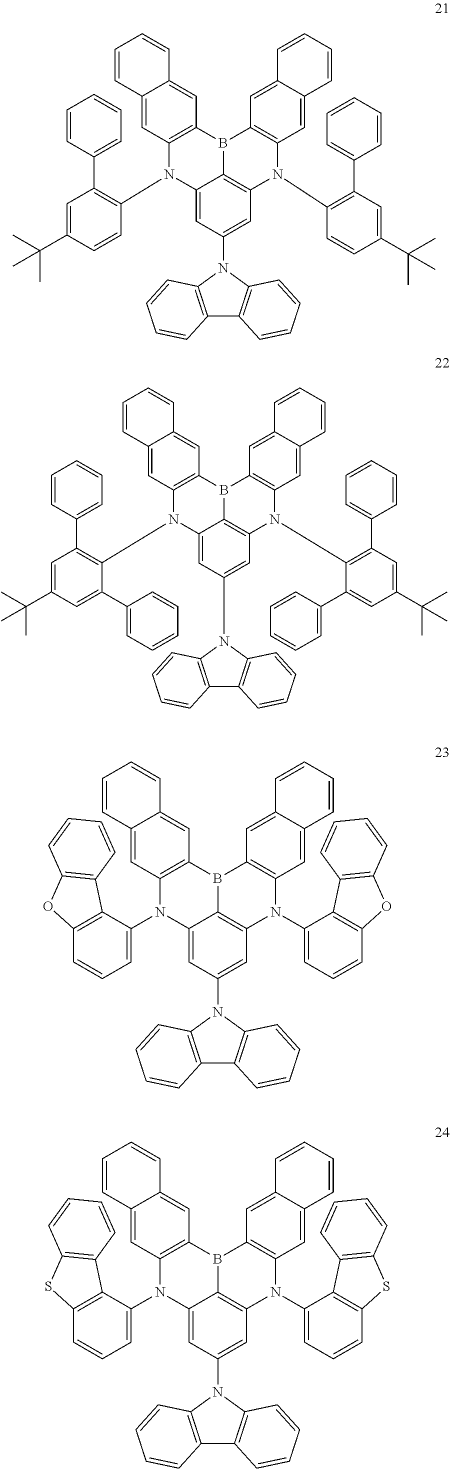

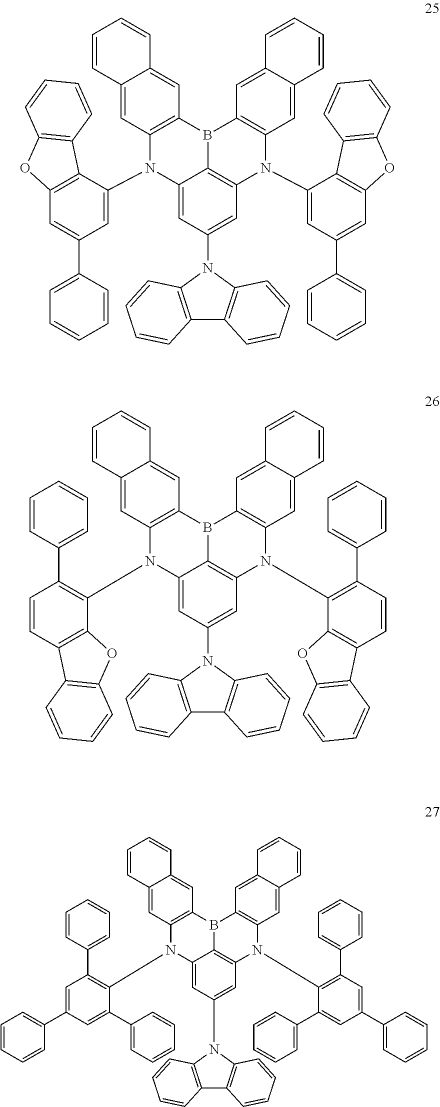 [SMILES: c1ccc(-c2cc(N3c4cc5ccccc5cc4B4c5cc6ccccc6cc5N(c5cc(-c6ccccc6)cc6oc7ccccc7c56)c5cc(-n6c7ccccc7c7ccccc76)cc3c54)c3c(c2)oc2ccccc23)cc1 ; c1ccc(-c2ccc3c(oc4ccccc43)c2N2c3cc4ccccc4cc3B3c4cc5ccccc5cc4N(c4c(-c5ccccc5)ccc5c4oc4ccccc45)c4cc(-n5c6ccccc6c6ccccc65)cc2c43)cc1 ; c1ccc(-c2cc(-c3ccccc3)c(N3c4cc5ccccc5cc4B4c5cc6ccccc6cc5N(c5c(-c6ccccc6)cc(-c6ccccc6)cc5-c5ccccc5)c5cc(-n6c7ccccc7c7ccccc76)cc3c54)c(-c3ccccc3)c2)cc1]

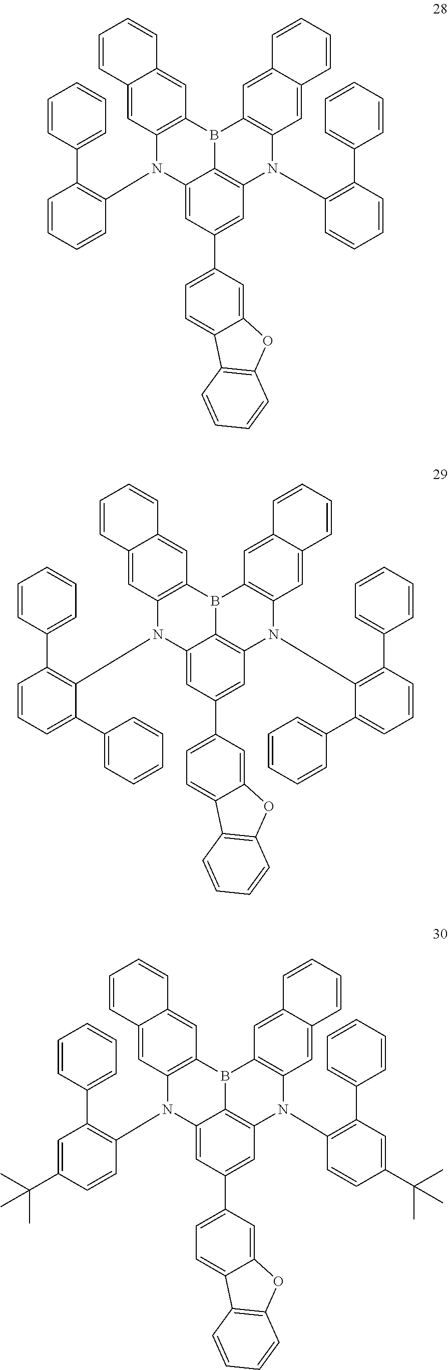 [SMILES: c1ccc(-c2ccccc2N2c3cc4ccccc4cc3B3c4cc5ccccc5cc4N(c4ccccc4-c4ccccc4)c4cc(-c5ccc6c(c5)oc5ccccc56)cc2c43)cc1 ; c1ccc(-c2cccc(-c3ccccc3)c2N2c3cc4ccccc4cc3B3c4cc5ccccc5cc4N(c4c(-c5ccccc5)cccc4-c4ccccc4)c4cc(-c5ccc6c(c5)oc5ccccc56)cc2c43)cc1 ; CC(C)(C)c1ccc(N2c3cc4ccccc4cc3B3c4cc5ccccc5cc4N(c4ccc(C(C)(C)C)cc4-c4ccccc4)c4cc(-c5ccc6c(c5)oc5ccccc56)cc2c43)c(-c2ccccc2)c1]

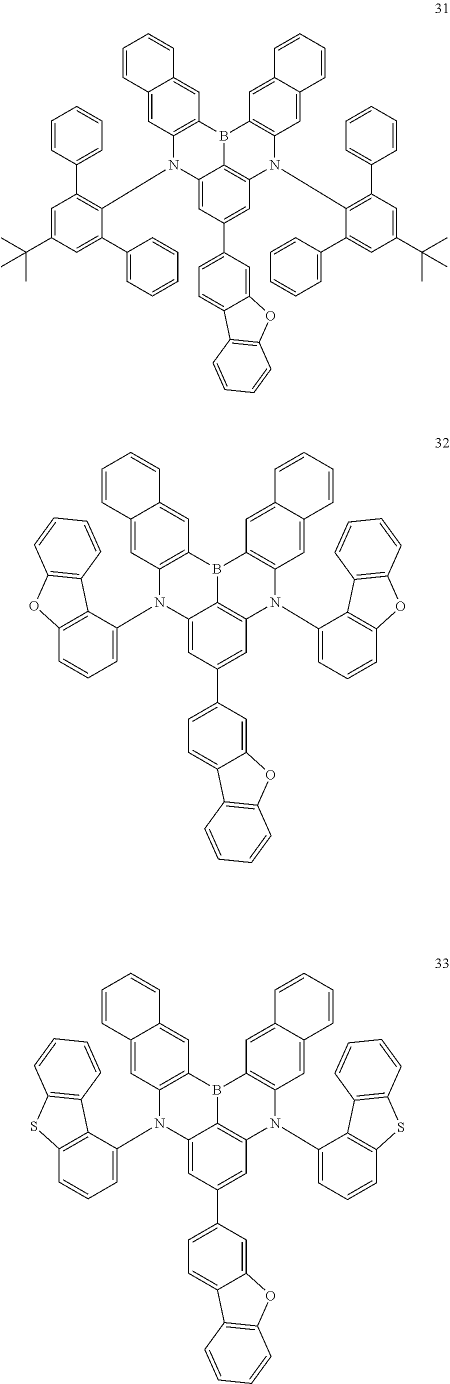 [SMILES: CC(C)(C)c1cc(-c2ccccc2)c(N2c3cc4ccccc4cc3B3c4cc5ccccc5cc4N(c4c(-c5ccccc5)cc(C(C)(C)C)cc4-c4ccccc4)c4cc(-c5ccc6c(c5)oc5ccccc56)cc2c43)c(-c2ccccc2)c1 ; c1ccc2cc3c(cc2c1)B1c2cc4ccccc4cc2N(c2cccc4oc5ccccc5c24)c2cc(-c4ccc5c(c4)oc4ccccc45)cc(c21)N3c1cccc2oc3ccccc3c12 ; c1ccc2cc3c(cc2c1)B1c2cc4ccccc4cc2N(c2cccc4sc5ccccc5c24)c2cc(-c4ccc5c(c4)oc4ccccc45)cc(c21)N3c1cccc2sc3ccccc3c12]

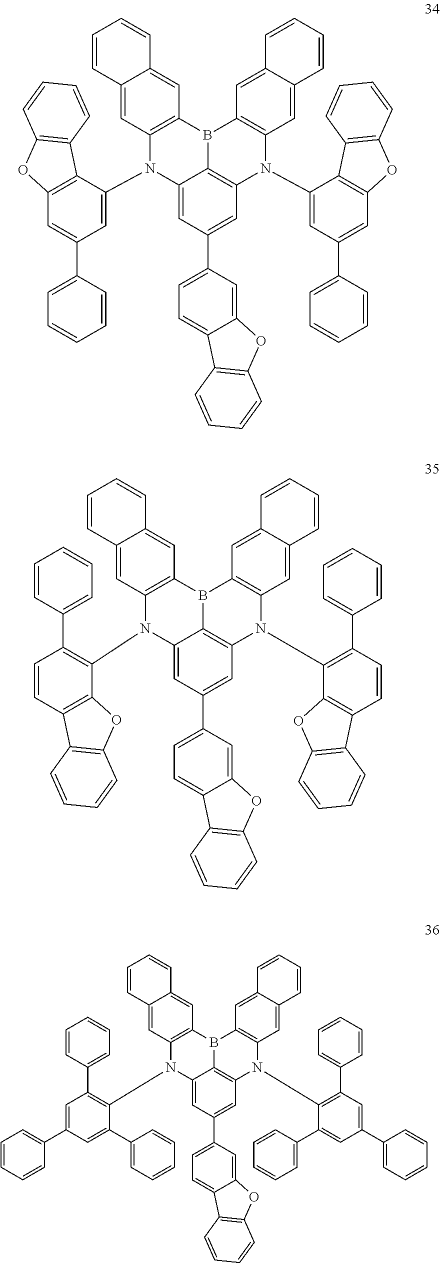 [SMILES: c1ccc(-c2cc(N3c4cc5ccccc5cc4B4c5cc6ccccc6cc5N(c5cc(-c6ccccc6)cc6oc7ccccc7c56)c5cc(-c6ccc7c(c6)oc6ccccc67)cc3c54)c3c(c2)oc2ccccc23)cc1 ; c1ccc(-c2ccc3c(oc4ccccc43)c2N2c3cc4ccccc4cc3B3c4cc5ccccc5cc4N(c4c(-c5ccccc5)ccc5c4oc4ccccc45)c4cc(-c5ccc6c(c5)oc5ccccc56)cc2c43)cc1 ; c1ccc(-c2cc(-c3ccccc3)c(N3c4cc5ccccc5cc4B4c5cc6ccccc6cc5N(c5c(-c6ccccc6)cc(-c6ccccc6)cc5-c5ccccc5)c5cc(-c6ccc7c(c6)oc6ccccc67)cc3c54)c(-c3ccccc3)c2)cc1]

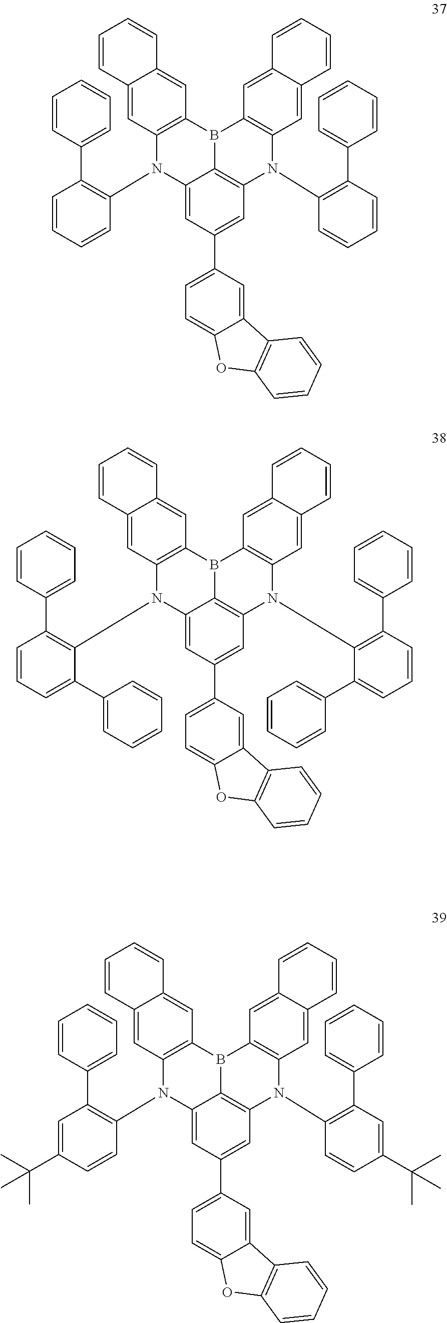 [SMILES: c1ccc(-c2ccccc2N2c3cc4ccccc4cc3B3c4cc5ccccc5cc4N(c4ccccc4-c4ccccc4)c4cc(-c5ccc6oc7ccccc7c6c5)cc2c43)cc1 ; c1ccc(-c2cccc(-c3ccccc3)c2N2c3cc4ccccc4cc3B3c4cc5ccccc5cc4N(c4c(-c5ccccc5)cccc4-c4ccccc4)c4cc(-c5ccc6oc7ccccc7c6c5)cc2c43)cc1 ; CC(C)(C)c1ccc(N2c3cc4ccccc4cc3B3c4cc5ccccc5cc4N(c4ccc(C(C)(C)C)cc4-c4ccccc4)c4cc(-c5ccc6oc7ccccc7c6c5)cc2c43)c(-c2ccccc2)c1]

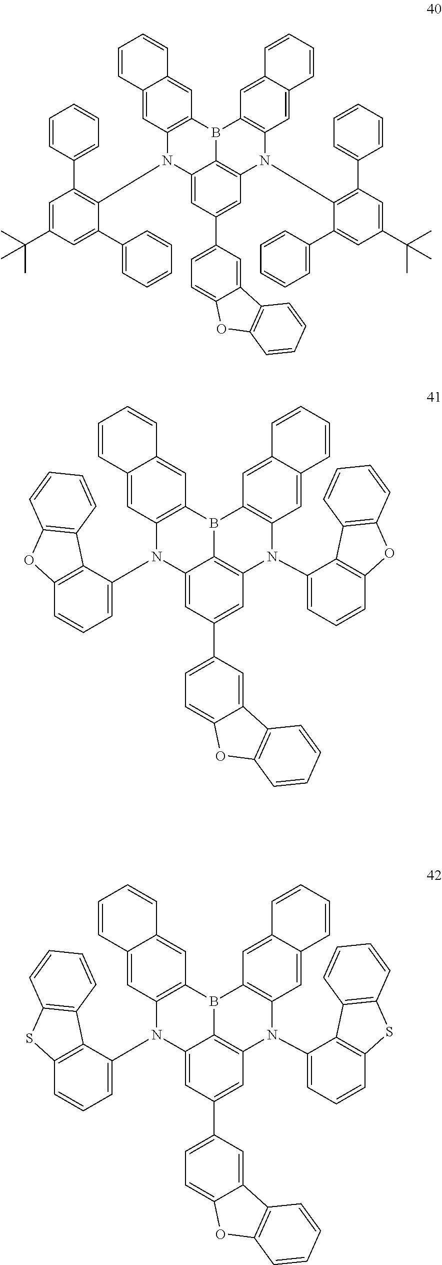 [SMILES: CC(C)(C)c1cc(-c2ccccc2)c(N2c3cc4ccccc4cc3B3c4cc5ccccc5cc4N(c4c(-c5ccccc5)cc(C(C)(C)C)cc4-c4ccccc4)c4cc(-c5ccc6oc7ccccc7c6c5)cc2c43)c(-c2ccccc2)c1 ; c1ccc2cc3c(cc2c1)B1c2cc4ccccc4cc2N(c2cccc4oc5ccccc5c24)c2cc(-c4ccc5oc6ccccc6c5c4)cc(c21)N3c1cccc2oc3ccccc3c12 ; c1ccc2cc3c(cc2c1)B1c2cc4ccccc4cc2N(c2cccc4sc5ccccc5c24)c2cc(-c4ccc5oc6ccccc6c5c4)cc(c21)N3c1cccc2sc3ccccc3c12]

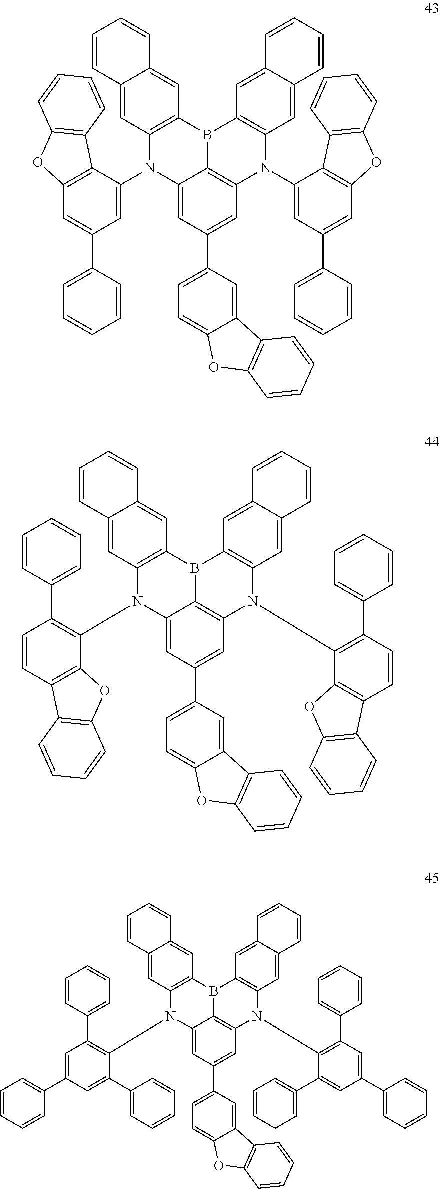

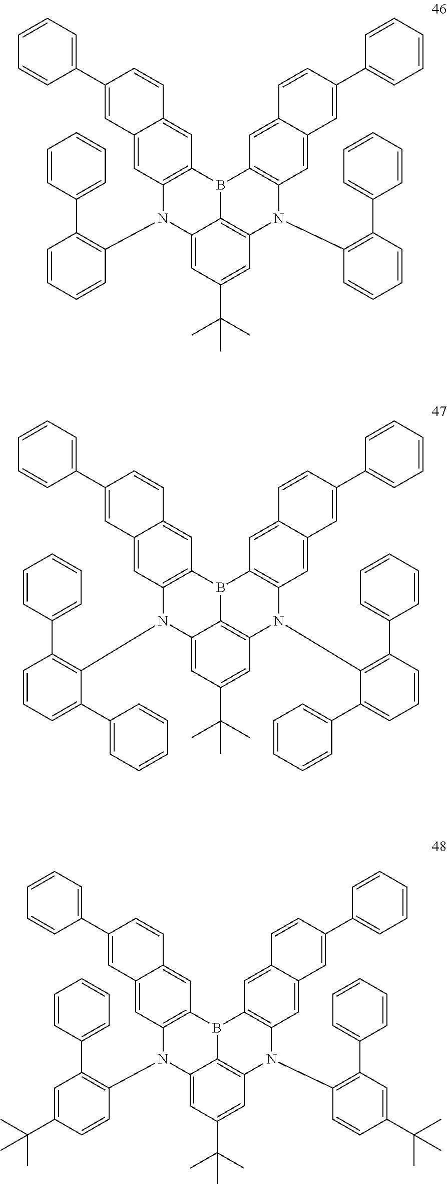 [SMILES: CC(C)(C)c1cc2c3c(c1)N(c1ccccc1-c1ccccc1)c1cc4cc(-c5ccccc5)ccc4cc1B3c1cc3ccc(-c4ccccc4)cc3cc1N2c1ccccc1-c1ccccc1 ; CC(C)(C)c1cc2c3c(c1)N(c1c(-c4ccccc4)cccc1-c1ccccc1)c1cc4cc(-c5ccccc5)ccc4cc1B3c1cc3ccc(-c4ccccc4)cc3cc1N2c1c(-c2ccccc2)cccc1-c1ccccc1 ; CC(C)(C)c1ccc(N2c3cc4cc(-c5ccccc5)ccc4cc3B3c4cc5ccc(-c6ccccc6)cc5cc4N(c4ccc(C(C)(C)C)cc4-c4ccccc4)c4cc(C(C)(C)C)cc2c43)c(-c2ccccc2)c1]

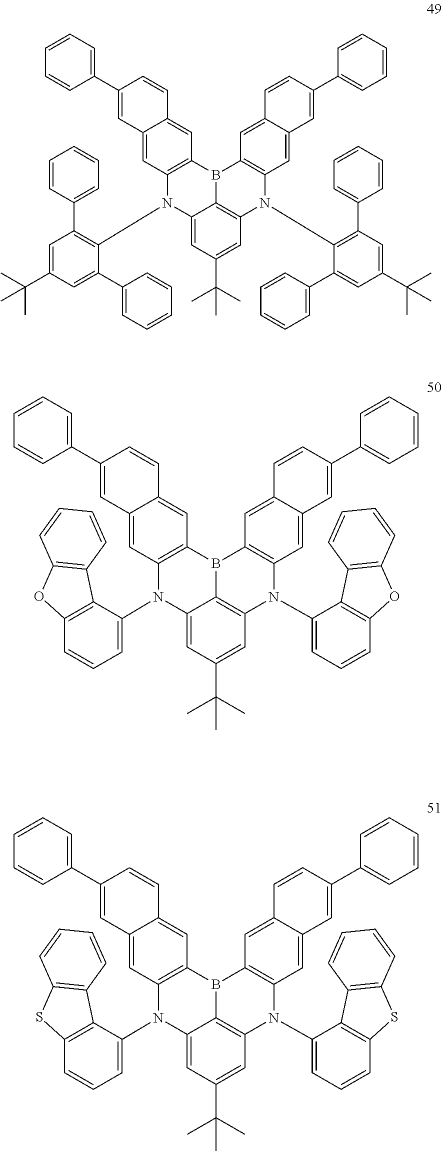 [SMILES: CC(C)(C)c1cc(-c2ccccc2)c(N2c3cc4cc(-c5ccccc5)ccc4cc3B3c4cc5ccc(-c6ccccc6)cc5cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc2c3c(c1)N(c1cccc4oc5ccccc5c14)c1cc4cc(-c5ccccc5)ccc4cc1B3c1cc3ccc(-c4ccccc4)cc3cc1N2c1cccc2oc3ccccc3c12 ; CC(C)(C)c1cc2c3c(c1)N(c1cccc4sc5ccccc5c14)c1cc4cc(-c5ccccc5)ccc4cc1B3c1cc3ccc(-c4ccccc4)cc3cc1N2c1cccc2sc3ccccc3c12]

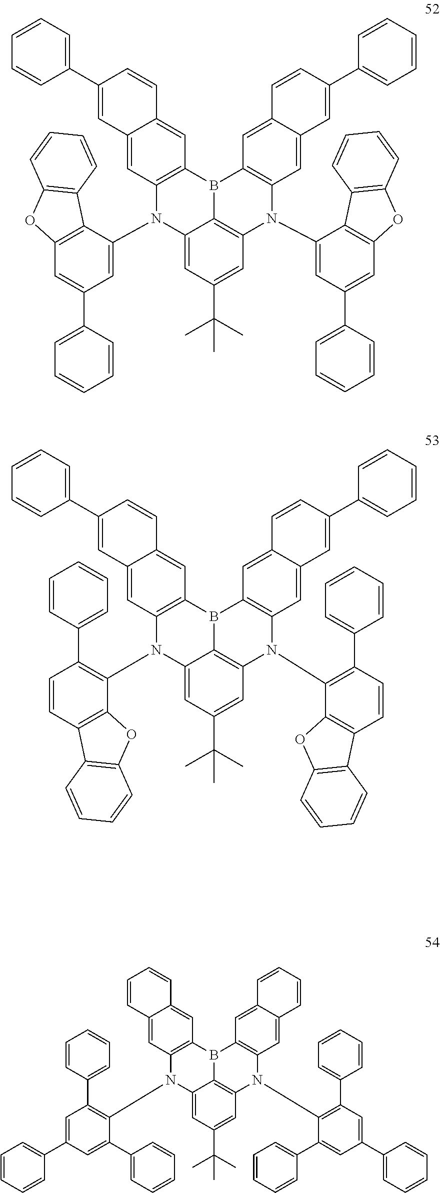 [SMILES: CC(C)(C)c1cc2c3c(c1)N(c1cc(-c4ccccc4)cc4oc5ccccc5c14)c1cc4cc(-c5ccccc5)ccc4cc1B3c1cc3ccc(-c4ccccc4)cc3cc1N2c1cc(-c2ccccc2)cc2oc3ccccc3c12 ; CC(C)(C)c1cc2c3c(c1)N(c1c(-c4ccccc4)ccc4c1oc1ccccc14)c1cc4cc(-c5ccccc5)ccc4cc1B3c1cc3ccc(-c4ccccc4)cc3cc1N2c1c(-c2ccccc2)ccc2c1oc1ccccc12 ; CC(C)(C)c1cc2c3c(c1)N(c1c(-c4ccccc4)cc(-c4ccccc4)cc1-c1ccccc1)c1cc4ccccc4cc1B3c1cc3ccccc3cc1N2c1c(-c2ccccc2)cc(-c2ccccc2)cc1-c1ccccc1]

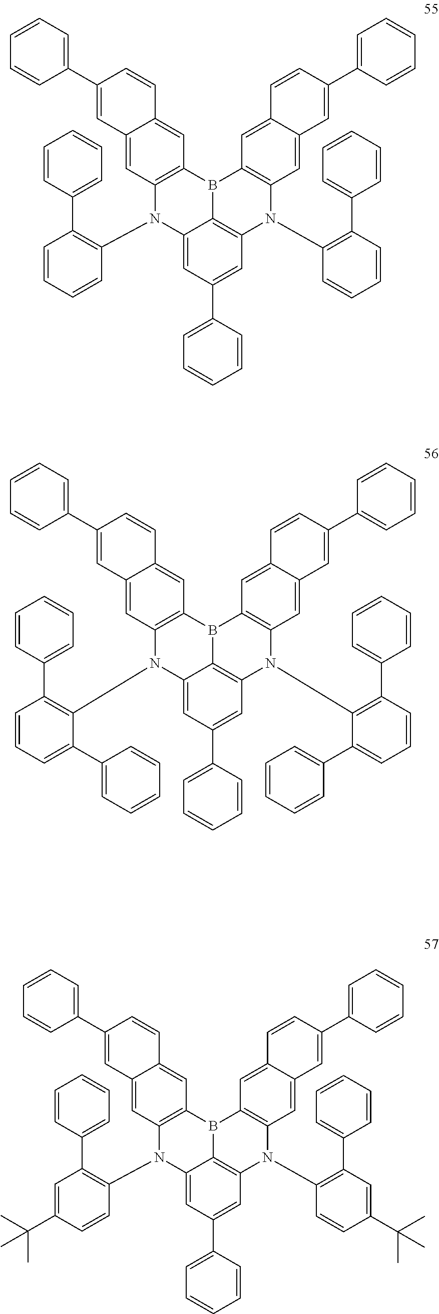 [SMILES: c1ccc(-c2cc3c4c(c2)N(c2ccccc2-c2ccccc2)c2cc5cc(-c6ccccc6)ccc5cc2B4c2cc4ccc(-c5ccccc5)cc4cc2N3c2ccccc2-c2ccccc2)cc1 ; c1ccc(-c2cc3c4c(c2)N(c2c(-c5ccccc5)cccc2-c2ccccc2)c2cc5cc(-c6ccccc6)ccc5cc2B4c2cc4ccc(-c5ccccc5)cc4cc2N3c2c(-c3ccccc3)cccc2-c2ccccc2)cc1 ; CC(C)(C)c1ccc(N2c3cc4cc(-c5ccccc5)ccc4cc3B3c4cc5ccc(-c6ccccc6)cc5cc4N(c4ccc(C(C)(C)C)cc4-c4ccccc4)c4cc(-c5ccccc5)cc2c43)c(-c2ccccc2)c1]

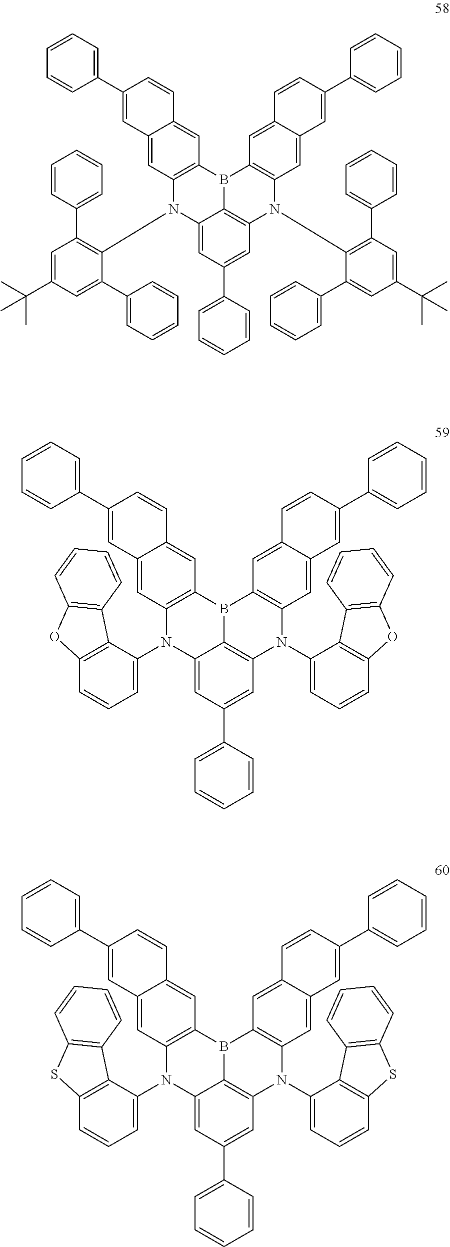 [SMILES: CC(C)(C)c1cc(-c2ccccc2)c(N2c3cc4cc(-c5ccccc5)ccc4cc3B3c4cc5ccc(-c6ccccc6)cc5cc4N(c4c(-c5ccccc5)cc(C(C)(C)C)cc4-c4ccccc4)c4cc(-c5ccccc5)cc2c43)c(-c2ccccc2)c1 ; c1ccc(-c2cc3c4c(c2)N(c2cccc5oc6ccccc6c25)c2cc5cc(-c6ccccc6)ccc5cc2B4c2cc4ccc(-c5ccccc5)cc4cc2N3c2cccc3oc4ccccc4c23)cc1 ; c1ccc(-c2cc3c4c(c2)N(c2cccc5sc6ccccc6c25)c2cc5cc(-c6ccccc6)ccc5cc2B4c2cc4ccc(-c5ccccc5)cc4cc2N3c2cccc3sc4ccccc4c23)cc1]

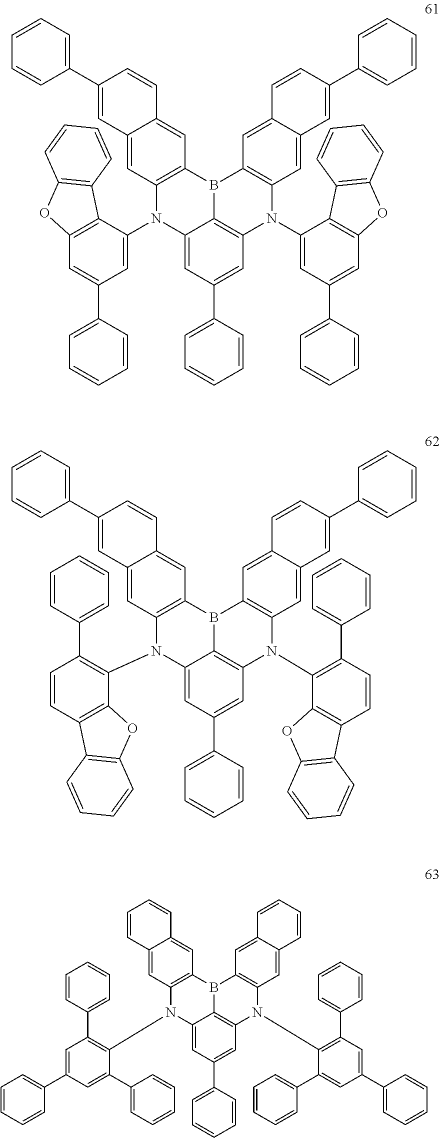 [SMILES: c1ccc(-c2cc3c4c(c2)N(c2cc(-c5ccccc5)cc5oc6ccccc6c25)c2cc5cc(-c6ccccc6)ccc5cc2B4c2cc4ccc(-c5ccccc5)cc4cc2N3c2cc(-c3ccccc3)cc3oc4ccccc4c23)cc1 ; c1ccc(-c2cc3c4c(c2)N(c2c(-c5ccccc5)ccc5c2oc2ccccc25)c2cc5cc(-c6ccccc6)ccc5cc2B4c2cc4ccc(-c5ccccc5)cc4cc2N3c2c(-c3ccccc3)ccc3c2oc2ccccc23)cc1 ; c1ccc(-c2cc(-c3ccccc3)c(N3c4cc5ccccc5cc4B4c5cc6ccccc6cc5N(c5c(-c6ccccc6)cc(-c6ccccc6)cc5-c5ccccc5)c5cc(-c6ccccc6)cc3c54)c(-c3ccccc3)c2)cc1]

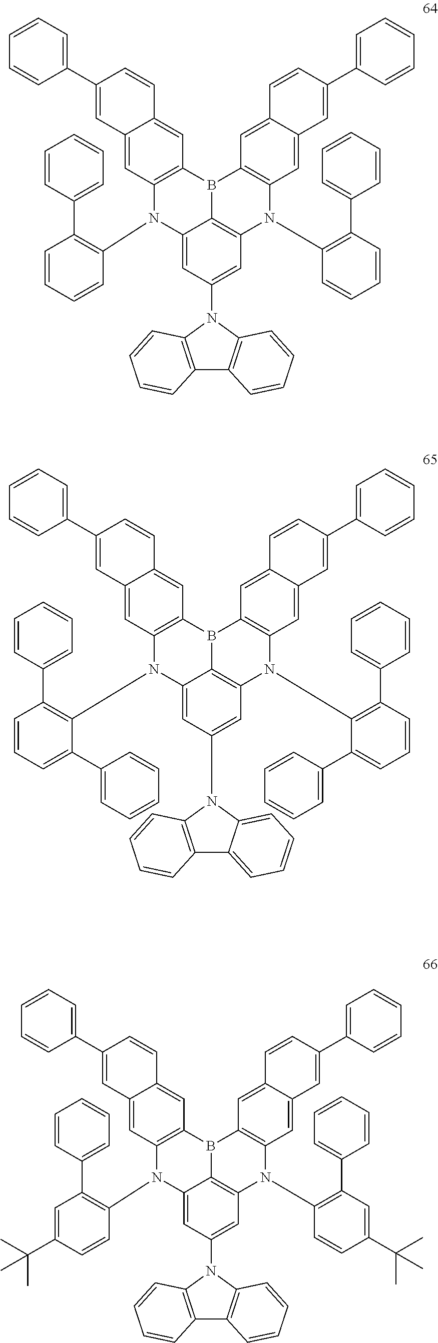 [SMILES: c1ccc(-c2ccc3cc4c(cc3c2)N(c2ccccc2-c2ccccc2)c2cc(-n3c5ccccc5c5ccccc53)cc3c2B4c2cc4ccc(-c5ccccc5)cc4cc2N3c2ccccc2-c2ccccc2)cc1 ; c1ccc(-c2ccc3cc4c(cc3c2)N(c2c(-c3ccccc3)cccc2-c2ccccc2)c2cc(-n3c5ccccc5c5ccccc53)cc3c2B4c2cc4ccc(-c5ccccc5)cc4cc2N3c2c(-c3ccccc3)cccc2-c2ccccc2)cc1 ; CC(C)(C)c1ccc(N2c3cc4cc(-c5ccccc5)ccc4cc3B3c4cc5ccc(-c6ccccc6)cc5cc4N(c4ccc(C(C)(C)C)cc4-c4ccccc4)c4cc(-n5c6ccccc6c6ccccc65)cc2c43)c(-c2ccccc2)c1]

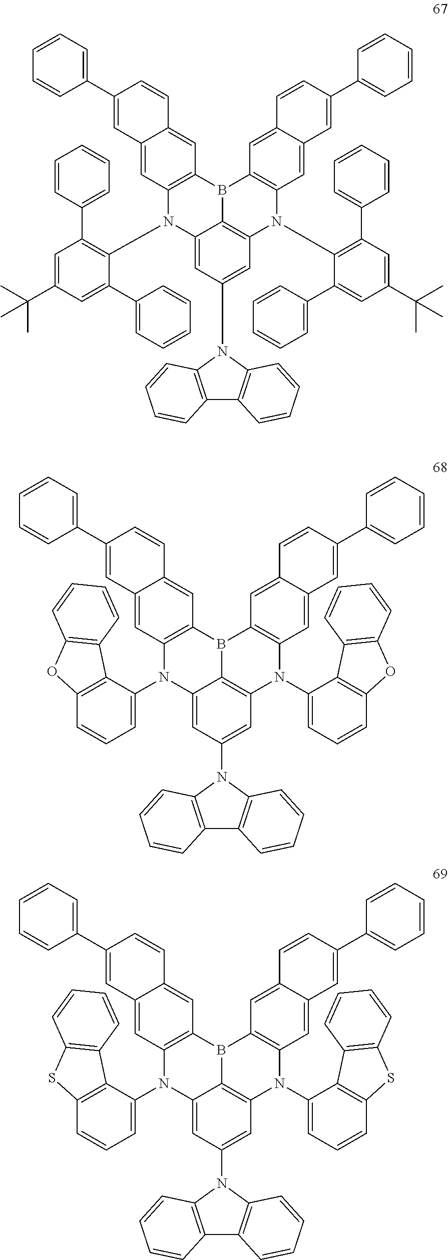 [SMILES: CC(C)(C)c1cc(-c2ccccc2)c(N2c3cc4cc(-c5ccccc5)ccc4cc3B3c4cc5ccc(-c6ccccc6)cc5cc4N(c4c(-c5ccccc5)cc(C(C)(C)C)cc4-c4ccccc4)c4cc(-n5c6ccccc6c6ccccc65)cc2c43)c(-c2ccccc2)c1 ; c1ccc(-c2ccc3cc4c(cc3c2)N(c2cccc3oc5ccccc5c23)c2cc(-n3c5ccccc5c5ccccc53)cc3c2B4c2cc4ccc(-c5ccccc5)cc4cc2N3c2cccc3oc4ccccc4c23)cc1 ; c1ccc(-c2ccc3cc4c(cc3c2)N(c2cccc3sc5ccccc5c23)c2cc(-n3c5ccccc5c5ccccc53)cc3c2B4c2cc4ccc(-c5ccccc5)cc4cc2N3c2cccc3sc4ccccc4c23)cc1]

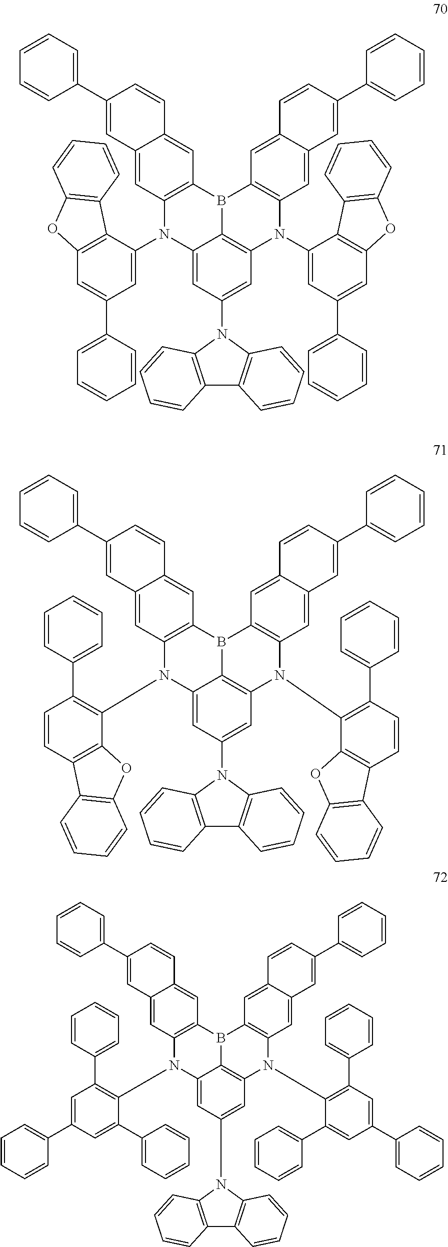

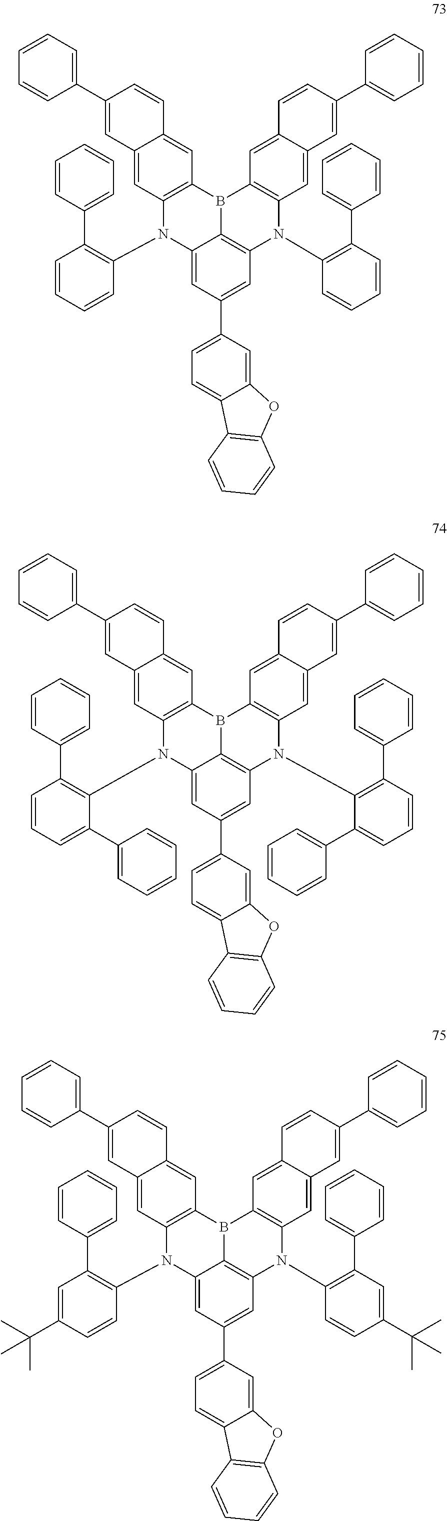 [SMILES: c1ccc(-c2ccc3cc4c(cc3c2)N(c2ccccc2-c2ccccc2)c2cc(-c3ccc5c(c3)oc3ccccc35)cc3c2B4c2cc4ccc(-c5ccccc5)cc4cc2N3c2ccccc2-c2ccccc2)cc1 ; c1ccc(-c2ccc3cc4c(cc3c2)N(c2c(-c3ccccc3)cccc2-c2ccccc2)c2cc(-c3ccc5c(c3)oc3ccccc35)cc3c2B4c2cc4ccc(-c5ccccc5)cc4cc2N3c2c(-c3ccccc3)cccc2-c2ccccc2)cc1 ; CC(C)(C)c1ccc(N2c3cc4cc(-c5ccccc5)ccc4cc3B3c4cc5ccc(-c6ccccc6)cc5cc4N(c4ccc(C(C)(C)C)cc4-c4ccccc4)c4cc(-c5ccc6c(c5)oc5ccccc56)cc2c43)c(-c2ccccc2)c1]

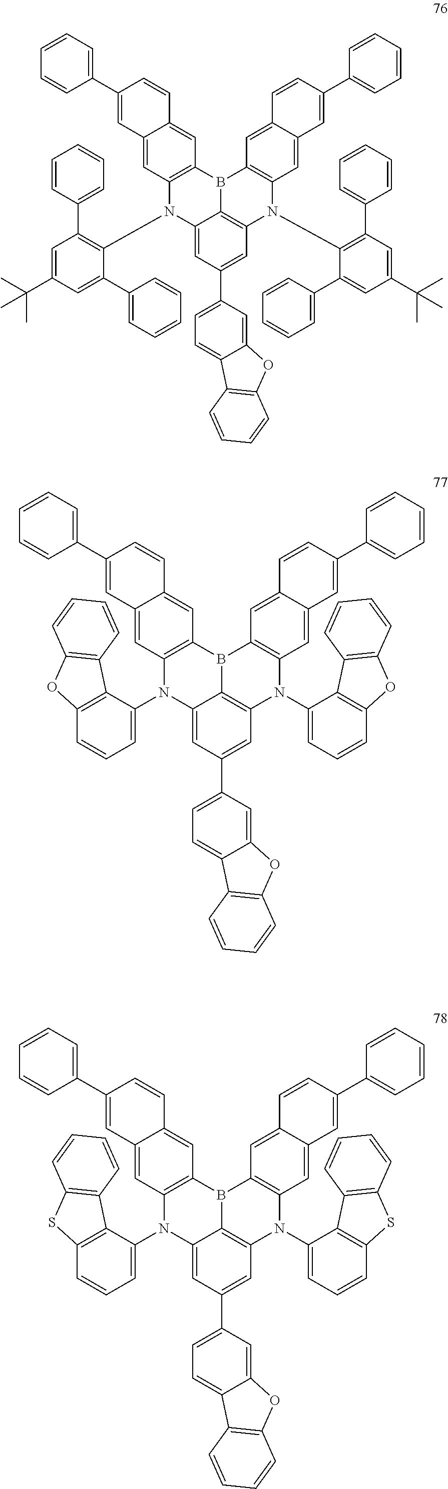 [SMILES: CC(C)(C)c1cc(-c2ccccc2)c(N2c3cc4cc(-c5ccccc5)ccc4cc3B3c4cc5ccc(-c6ccccc6)cc5cc4N(c4c(-c5ccccc5)cc(C(C)(C)C)cc4-c4ccccc4)c4cc(-c5ccc6c(c5)oc5ccccc56)cc2c43)c(-c2ccccc2)c1 ; c1ccc(-c2ccc3cc4c(cc3c2)N(c2cccc3oc5ccccc5c23)c2cc(-c3ccc5c(c3)oc3ccccc35)cc3c2B4c2cc4ccc(-c5ccccc5)cc4cc2N3c2cccc3oc4ccccc4c23)cc1 ; c1ccc(-c2ccc3cc4c(cc3c2)N(c2cccc3sc5ccccc5c23)c2cc(-c3ccc5c(c3)oc3ccccc35)cc3c2B4c2cc4ccc(-c5ccccc5)cc4cc2N3c2cccc3sc4ccccc4c23)cc1]

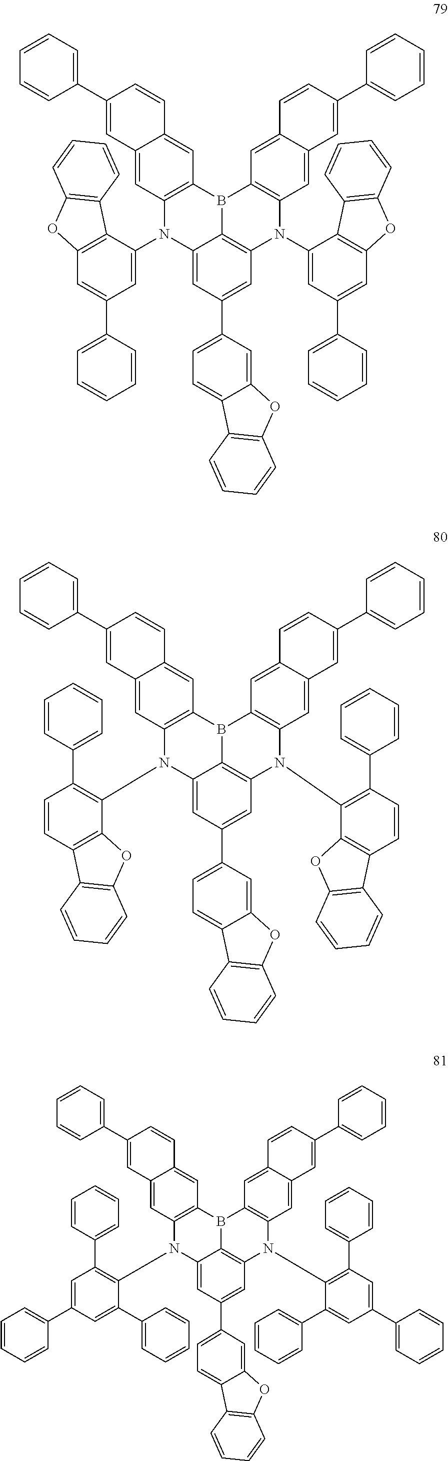 [SMILES: c1ccc(-c2ccc3cc4c(cc3c2)N(c2cc(-c3ccccc3)cc3oc5ccccc5c23)c2cc(-c3ccc5c(c3)oc3ccccc35)cc3c2B4c2cc4ccc(-c5ccccc5)cc4cc2N3c2cc(-c3ccccc3)cc3oc4ccccc4c23)cc1 ; c1ccc(-c2ccc3cc4c(cc3c2)N(c2c(-c3ccccc3)ccc3c2oc2ccccc23)c2cc(-c3ccc5c(c3)oc3ccccc35)cc3c2B4c2cc4ccc(-c5ccccc5)cc4cc2N3c2c(-c3ccccc3)ccc3c2oc2ccccc23)cc1 ; c1ccc(-c2cc(-c3ccccc3)c(N3c4cc5cc(-c6ccccc6)ccc5cc4B4c5cc6ccc(-c7ccccc7)cc6cc5N(c5c(-c6ccccc6)cc(-c6ccccc6)cc5-c5ccccc5)c5cc(-c6ccc7c(c6)oc6ccccc67)cc3c54)c(-c3ccccc3)c2)cc1]

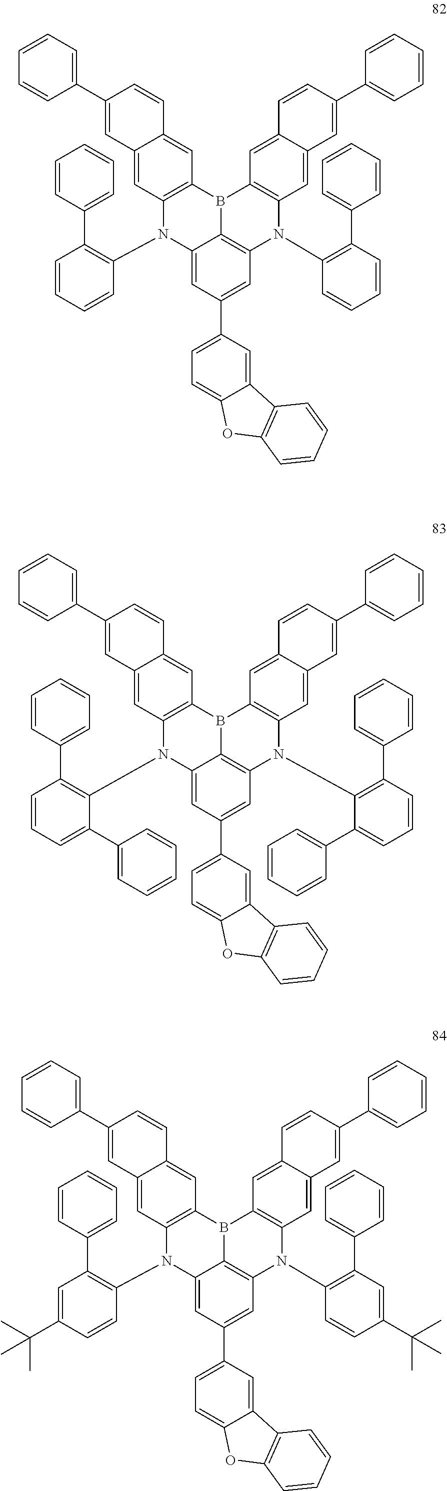 [SMILES: c1ccc(-c2ccc3cc4c(cc3c2)N(c2ccccc2-c2ccccc2)c2cc(-c3ccc5oc6ccccc6c5c3)cc3c2B4c2cc4ccc(-c5ccccc5)cc4cc2N3c2ccccc2-c2ccccc2)cc1 ; c1ccc(-c2ccc3cc4c(cc3c2)N(c2c(-c3ccccc3)cccc2-c2ccccc2)c2cc(-c3ccc5oc6ccccc6c5c3)cc3c2B4c2cc4ccc(-c5ccccc5)cc4cc2N3c2c(-c3ccccc3)cccc2-c2ccccc2)cc1 ; CC(C)(C)c1ccc(N2c3cc4cc(-c5ccccc5)ccc4cc3B3c4cc5ccc(-c6ccccc6)cc5cc4N(c4ccc(C(C)(C)C)cc4-c4ccccc4)c4cc(-c5ccc6oc7ccccc7c6c5)cc2c43)c(-c2ccccc2)c1]

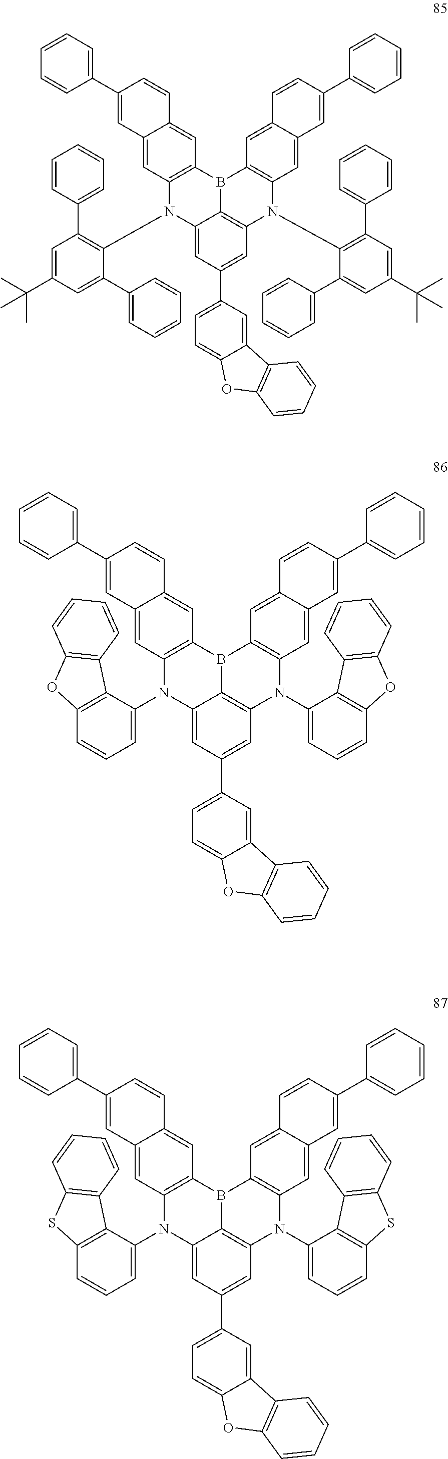 [SMILES: CC(C)(C)c1cc(-c2ccccc2)c(N2c3cc4cc(-c5ccccc5)ccc4cc3B3c4cc5ccc(-c6ccccc6)cc5cc4N(c4c(-c5ccccc5)cc(C(C)(C)C)cc4-c4ccccc4)c4cc(-c5ccc6oc7ccccc7c6c5)cc2c43)c(-c2ccccc2)c1 ; c1ccc(-c2ccc3cc4c(cc3c2)N(c2cccc3oc5ccccc5c23)c2cc(-c3ccc5oc6ccccc6c5c3)cc3c2B4c2cc4ccc(-c5ccccc5)cc4cc2N3c2cccc3oc4ccccc4c23)cc1 ; c1ccc(-c2ccc3cc4c(cc3c2)N(c2cccc3sc5ccccc5c23)c2cc(-c3ccc5oc6ccccc6c5c3)cc3c2B4c2cc4ccc(-c5ccccc5)cc4cc2N3c2cccc3sc4ccccc4c23)cc1]

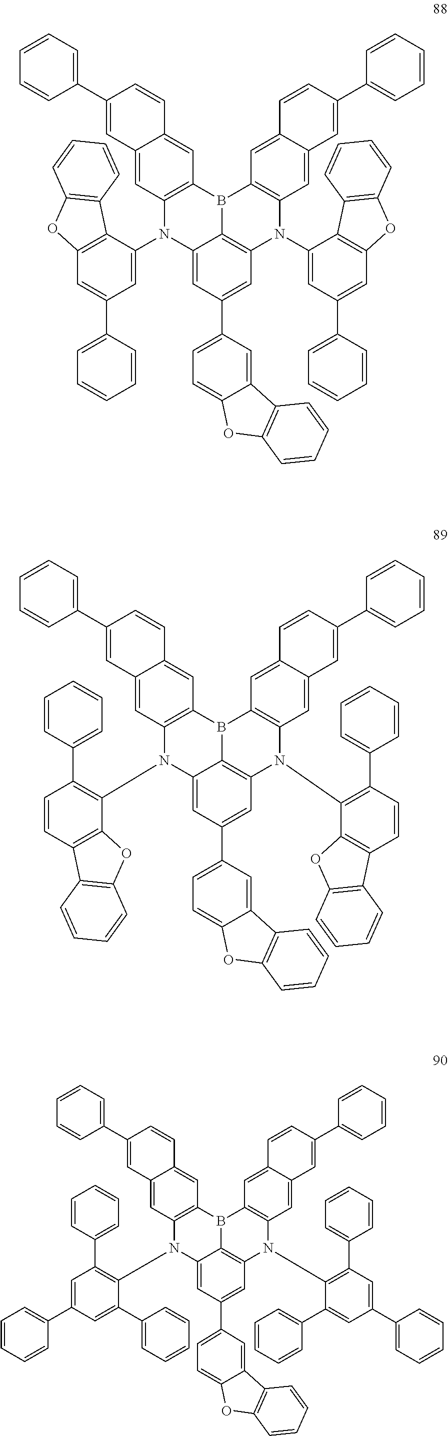 [SMILES: c1ccc(-c2ccc3cc4c(cc3c2)N(c2cc(-c3ccccc3)cc3oc5ccccc5c23)c2cc(-c3ccc5oc6ccccc6c5c3)cc3c2B4c2cc4ccc(-c5ccccc5)cc4cc2N3c2cc(-c3ccccc3)cc3oc4ccccc4c23)cc1 ; c1ccc(-c2ccc3cc4c(cc3c2)N(c2c(-c3ccccc3)ccc3c2oc2ccccc23)c2cc(-c3ccc5oc6ccccc6c5c3)cc3c2B4c2cc4ccc(-c5ccccc5)cc4cc2N3c2c(-c3ccccc3)ccc3c2oc2ccccc23)cc1 ; c1ccc(-c2cc(-c3ccccc3)c(N3c4cc5cc(-c6ccccc6)ccc5cc4B4c5cc6ccc(-c7ccccc7)cc6cc5N(c5c(-c6ccccc6)cc(-c6ccccc6)cc5-c5ccccc5)c5cc(-c6ccc7oc8ccccc8c7c6)cc3c54)c(-c3ccccc3)c2)cc1]

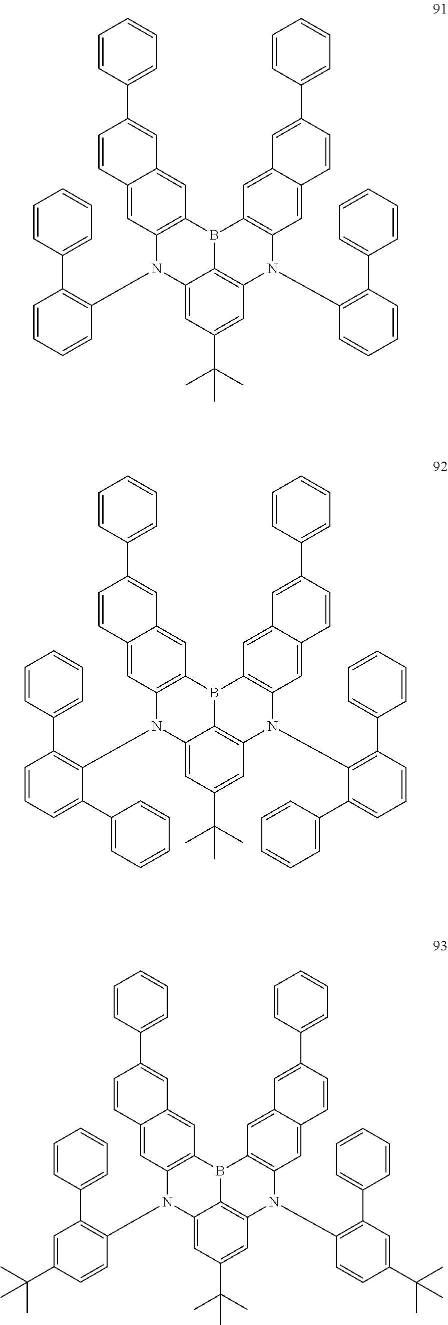 [SMILES: CC(C)(C)c1cc2c3c(c1)N(c1ccccc1-c1ccccc1)c1cc4ccc(-c5ccccc5)cc4cc1B3c1cc3cc(-c4ccccc4)ccc3cc1N2c1ccccc1-c1ccccc1 ; CC(C)(C)c1cc2c3c(c1)N(c1c(-c4ccccc4)cccc1-c1ccccc1)c1cc4ccc(-c5ccccc5)cc4cc1B3c1cc3cc(-c4ccccc4)ccc3cc1N2c1c(-c2ccccc2)cccc1-c1ccccc1 ; CC(C)(C)c1ccc(N2c3cc4ccc(-c5ccccc5)cc4cc3B3c4cc5cc(-c6ccccc6)ccc5cc4N(c4ccc(C(C)(C)C)cc4-c4ccccc4)c4cc(C(C)(C)C)cc2c43)c(-c2ccccc2)c1]

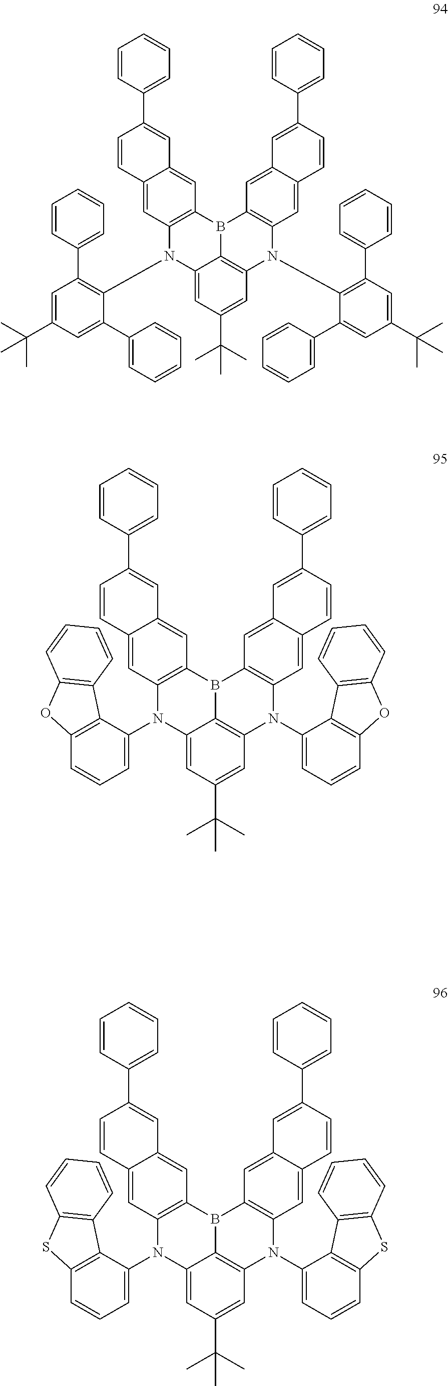 [SMILES: CC(C)(C)c1cc(-c2ccccc2)c(N2c3cc4ccc(-c5ccccc5)cc4cc3B3c4cc5cc(-c6ccccc6)ccc5cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc2c3c(c1)N(c1cccc4oc5ccccc5c14)c1cc4ccc(-c5ccccc5)cc4cc1B3c1cc3cc(-c4ccccc4)ccc3cc1N2c1cccc2oc3ccccc3c12 ; CC(C)(C)c1cc2c3c(c1)N(c1cccc4sc5ccccc5c14)c1cc4ccc(-c5ccccc5)cc4cc1B3c1cc3cc(-c4ccccc4)ccc3cc1N2c1cccc2sc3ccccc3c12]

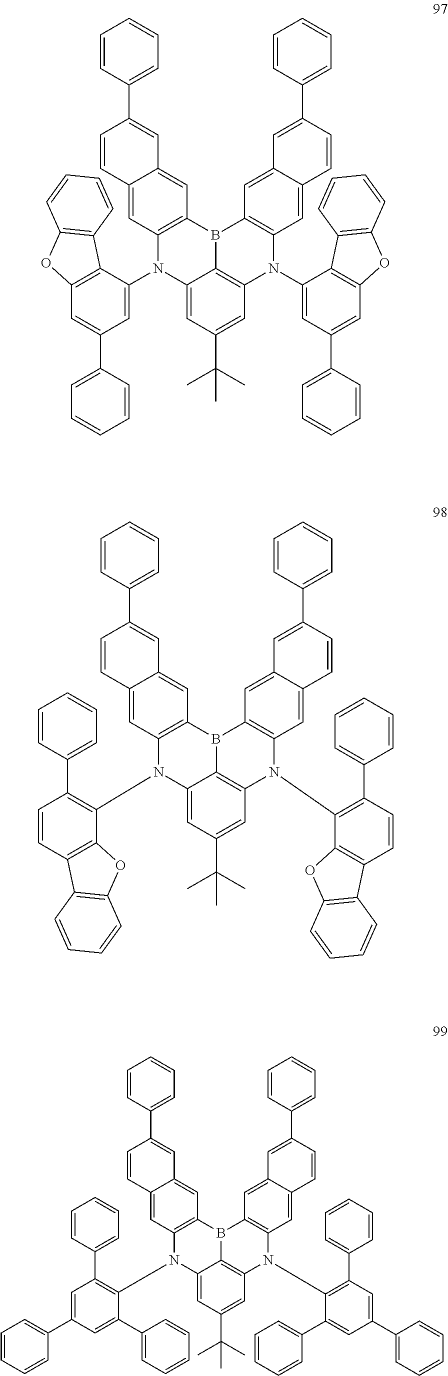 [SMILES: CC(C)(C)c1cc2c3c(c1)N(c1cc(-c4ccccc4)cc4oc5ccccc5c14)c1cc4ccc(-c5ccccc5)cc4cc1B3c1cc3cc(-c4ccccc4)ccc3cc1N2c1cc(-c2ccccc2)cc2oc3ccccc3c12 ; CC(C)(C)c1cc2c3c(c1)N(c1c(-c4ccccc4)ccc4c1oc1ccccc14)c1cc4ccc(-c5ccccc5)cc4cc1B3c1cc3cc(-c4ccccc4)ccc3cc1N2c1c(-c2ccccc2)ccc2c1oc1ccccc12 ; CC(C)(C)c1cc2c3c(c1)N(c1c(-c4ccccc4)cc(-c4ccccc4)cc1-c1ccccc1)c1cc4ccc(-c5ccccc5)cc4cc1B3c1cc3cc(-c4ccccc4)ccc3cc1N2c1c(-c2ccccc2)cc(-c2ccccc2)cc1-c1ccccc1]

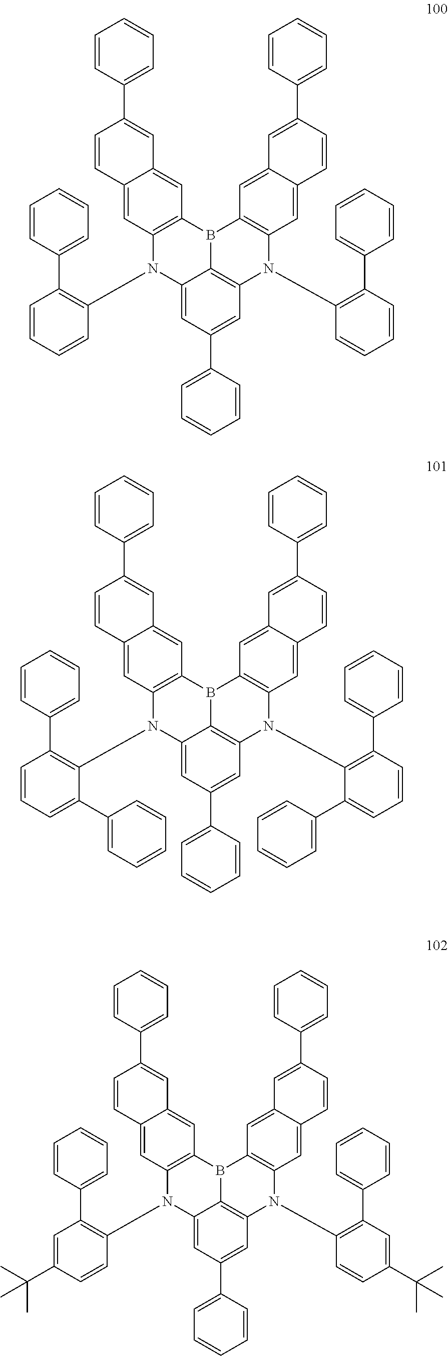 [SMILES: c1ccc(-c2cc3c4c(c2)N(c2ccccc2-c2ccccc2)c2cc5ccc(-c6ccccc6)cc5cc2B4c2cc4cc(-c5ccccc5)ccc4cc2N3c2ccccc2-c2ccccc2)cc1 ; c1ccc(-c2cc3c4c(c2)N(c2c(-c5ccccc5)cccc2-c2ccccc2)c2cc5ccc(-c6ccccc6)cc5cc2B4c2cc4cc(-c5ccccc5)ccc4cc2N3c2c(-c3ccccc3)cccc2-c2ccccc2)cc1 ; CC(C)(C)c1ccc(N2c3cc4ccc(-c5ccccc5)cc4cc3B3c4cc5cc(-c6ccccc6)ccc5cc4N(c4ccc(C(C)(C)C)cc4-c4ccccc4)c4cc(-c5ccccc5)cc2c43)c(-c2ccccc2)c1]

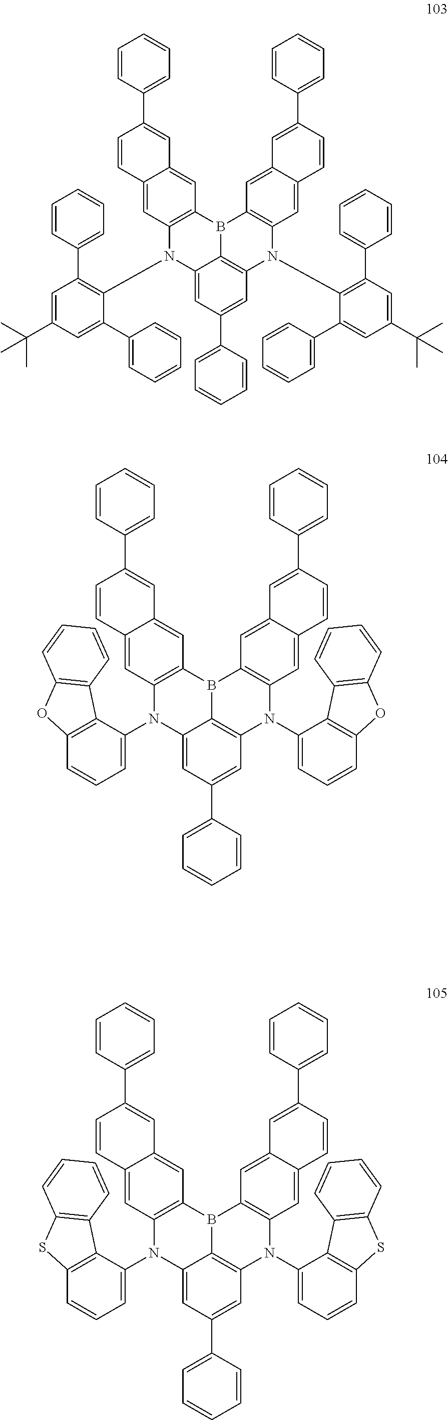 [SMILES: CC(C)(C)c1cc(-c2ccccc2)c(N2c3cc4ccc(-c5ccccc5)cc4cc3B3c4cc5cc(-c6ccccc6)ccc5cc4N(c4c(-c5ccccc5)cc(C(C)(C)C)cc4-c4ccccc4)c4cc(-c5ccccc5)cc2c43)c(-c2ccccc2)c1 ; c1ccc(-c2cc3c4c(c2)N(c2cccc5oc6ccccc6c25)c2cc5ccc(-c6ccccc6)cc5cc2B4c2cc4cc(-c5ccccc5)ccc4cc2N3c2cccc3oc4ccccc4c23)cc1 ; c1ccc(-c2cc3c4c(c2)N(c2cccc5sc6ccccc6c25)c2cc5ccc(-c6ccccc6)cc5cc2B4c2cc4cc(-c5ccccc5)ccc4cc2N3c2cccc3sc4ccccc4c23)cc1]

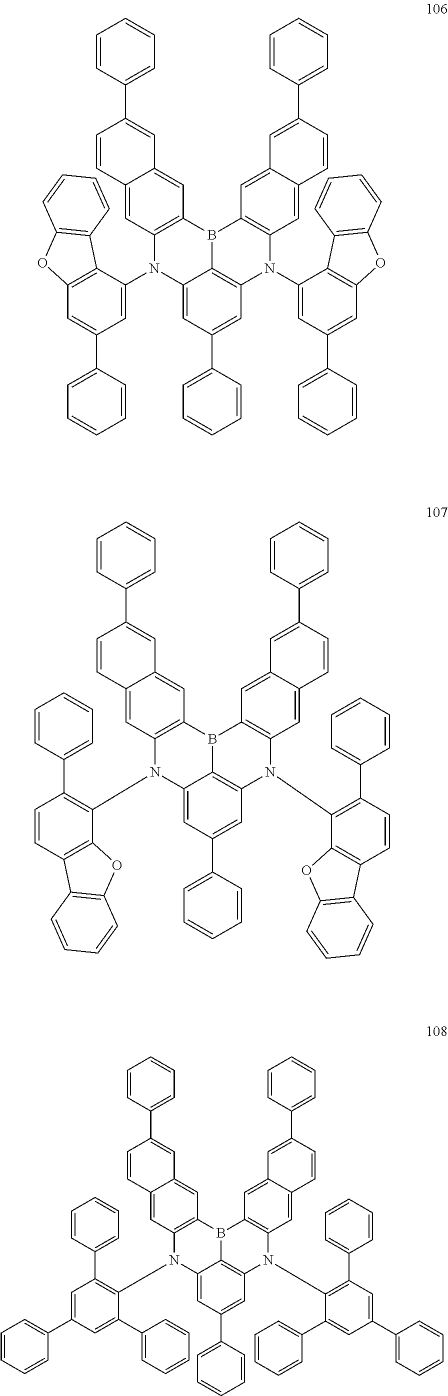 [SMILES: c1ccc(-c2cc3c4c(c2)N(c2cc(-c5ccccc5)cc5oc6ccccc6c25)c2cc5ccc(-c6ccccc6)cc5cc2B4c2cc4cc(-c5ccccc5)ccc4cc2N3c2cc(-c3ccccc3)cc3oc4ccccc4c23)cc1 ; c1ccc(-c2cc3c4c(c2)N(c2c(-c5ccccc5)ccc5c2oc2ccccc25)c2cc5ccc(-c6ccccc6)cc5cc2B4c2cc4cc(-c5ccccc5)ccc4cc2N3c2c(-c3ccccc3)ccc3c2oc2ccccc23)cc1 ; c1ccc(-c2cc(-c3ccccc3)c(N3c4cc5ccc(-c6ccccc6)cc5cc4B4c5cc6cc(-c7ccccc7)ccc6cc5N(c5c(-c6ccccc6)cc(-c6ccccc6)cc5-c5ccccc5)c5cc(-c6ccccc6)cc3c54)c(-c3ccccc3)c2)cc1]

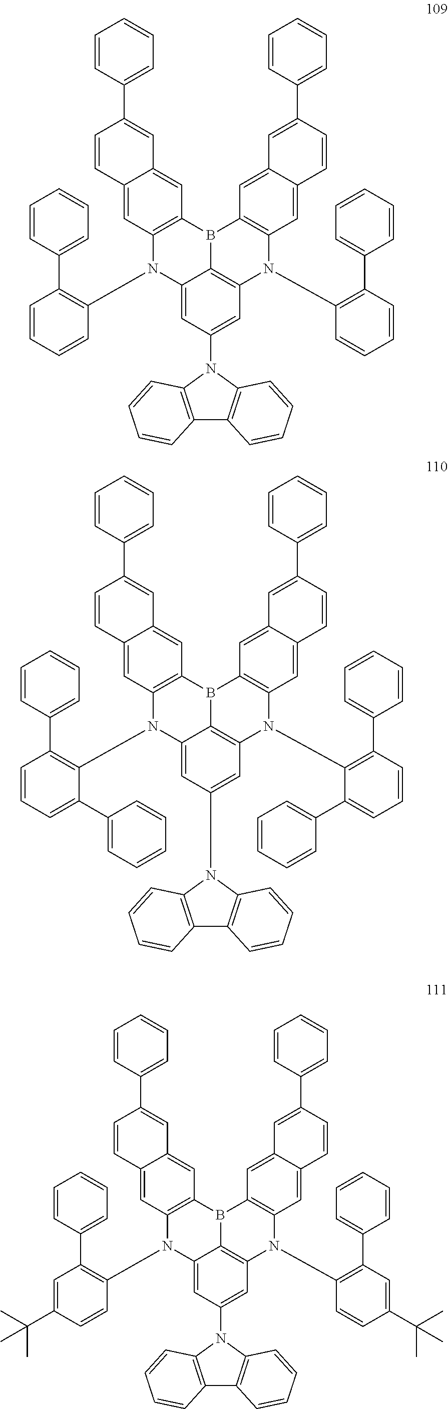

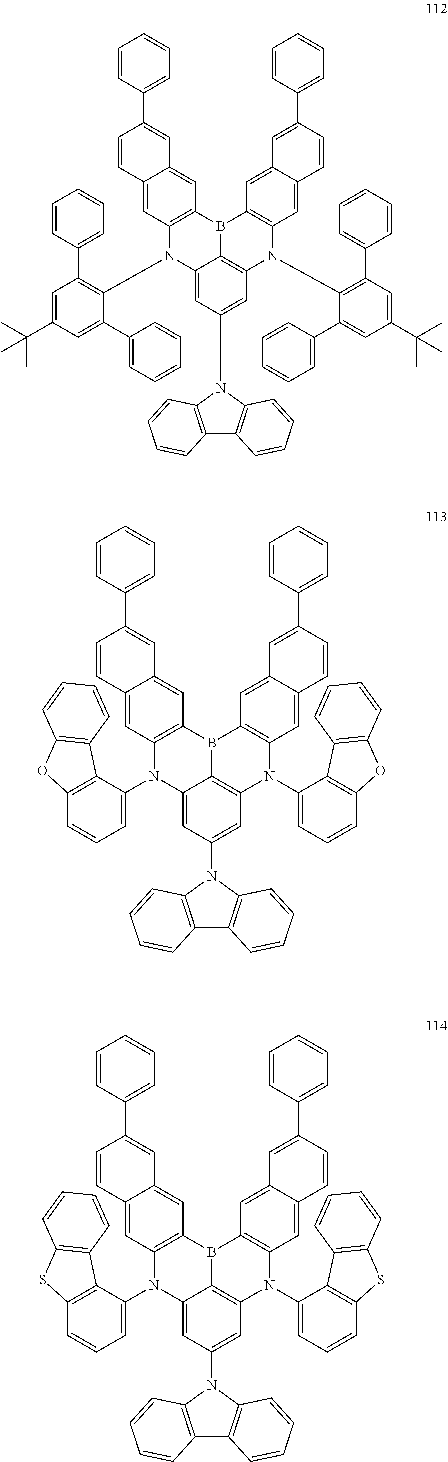 [SMILES: CC(C)(C)c1cc(-c2ccccc2)c(N2c3cc4ccc(-c5ccccc5)cc4cc3B3c4cc5cc(-c6ccccc6)ccc5cc4N(c4c(-c5ccccc5)cc(C(C)(C)C)cc4-c4ccccc4)c4cc(-n5c6ccccc6c6ccccc65)cc2c43)c(-c2ccccc2)c1 ; c1ccc(-c2ccc3cc4c(cc3c2)B2c3cc5cc(-c6ccccc6)ccc5cc3N(c3cccc5oc6ccccc6c35)c3cc(-n5c6ccccc6c6ccccc65)cc(c32)N4c2cccc3oc4ccccc4c23)cc1 ; c1ccc(-c2ccc3cc4c(cc3c2)B2c3cc5cc(-c6ccccc6)ccc5cc3N(c3cccc5sc6ccccc6c35)c3cc(-n5c6ccccc6c6ccccc65)cc(c32)N4c2cccc3sc4ccccc4c23)cc1]

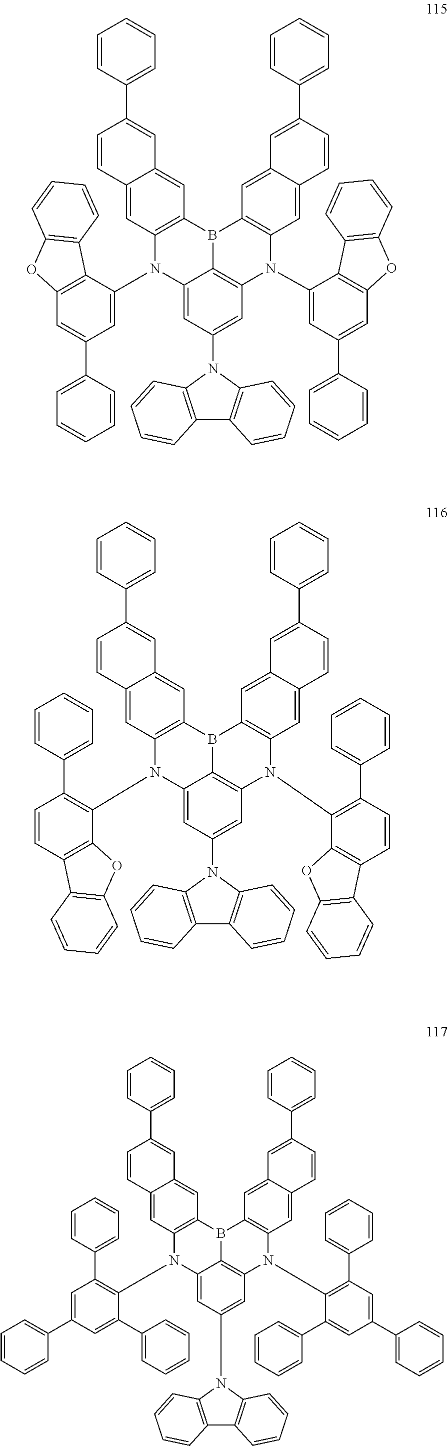 [SMILES: c1ccc(-c2ccc3cc4c(cc3c2)B2c3cc5cc(-c6ccccc6)ccc5cc3N(c3cc(-c5ccccc5)cc5oc6ccccc6c35)c3cc(-n5c6ccccc6c6ccccc65)cc(c32)N4c2cc(-c3ccccc3)cc3oc4ccccc4c23)cc1 ; c1ccc(-c2ccc3cc4c(cc3c2)B2c3cc5cc(-c6ccccc6)ccc5cc3N(c3c(-c5ccccc5)ccc5c3oc3ccccc35)c3cc(-n5c6ccccc6c6ccccc65)cc(c32)N4c2c(-c3ccccc3)ccc3c2oc2ccccc23)cc1 ; c1ccc(-c2cc(-c3ccccc3)c(N3c4cc5ccc(-c6ccccc6)cc5cc4B4c5cc6cc(-c7ccccc7)ccc6cc5N(c5c(-c6ccccc6)cc(-c6ccccc6)cc5-c5ccccc5)c5cc(-n6c7ccccc7c7ccccc76)cc3c54)c(-c3ccccc3)c2)cc1]

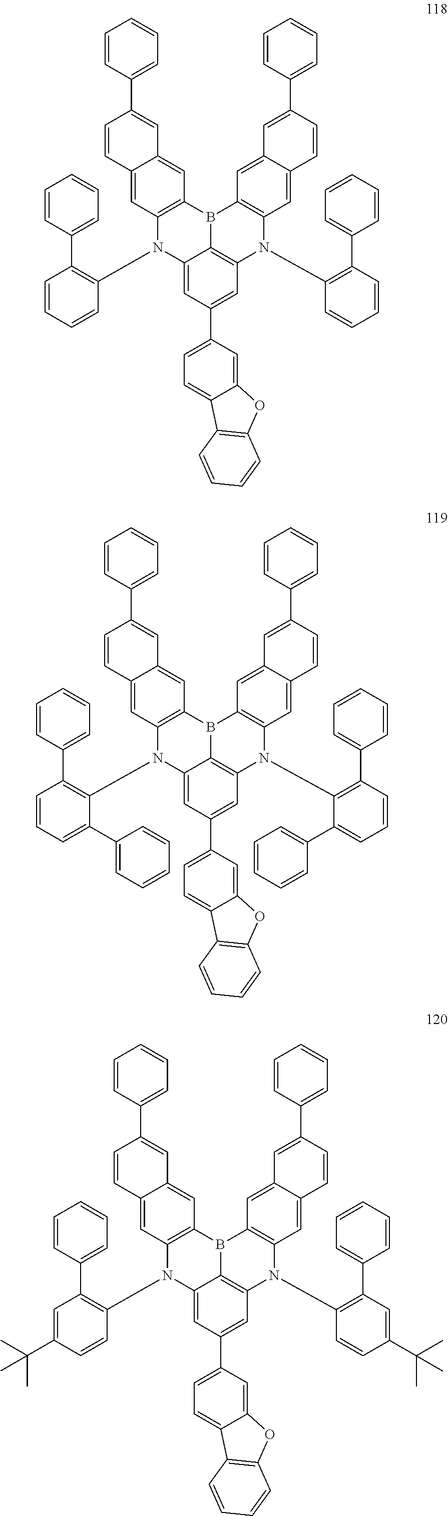 [SMILES: c1ccc(-c2ccc3cc4c(cc3c2)B2c3cc5cc(-c6ccccc6)ccc5cc3N(c3ccccc3-c3ccccc3)c3cc(-c5ccc6c(c5)oc5ccccc56)cc(c32)N4c2ccccc2-c2ccccc2)cc1 ; c1ccc(-c2ccc3cc4c(cc3c2)B2c3cc5cc(-c6ccccc6)ccc5cc3N(c3c(-c5ccccc5)cccc3-c3ccccc3)c3cc(-c5ccc6c(c5)oc5ccccc56)cc(c32)N4c2c(-c3ccccc3)cccc2-c2ccccc2)cc1 ; CC(C)(C)c1ccc(N2c3cc4ccc(-c5ccccc5)cc4cc3B3c4cc5cc(-c6ccccc6)ccc5cc4N(c4ccc(C(C)(C)C)cc4-c4ccccc4)c4cc(-c5ccc6c(c5)oc5ccccc56)cc2c43)c(-c2ccccc2)c1]

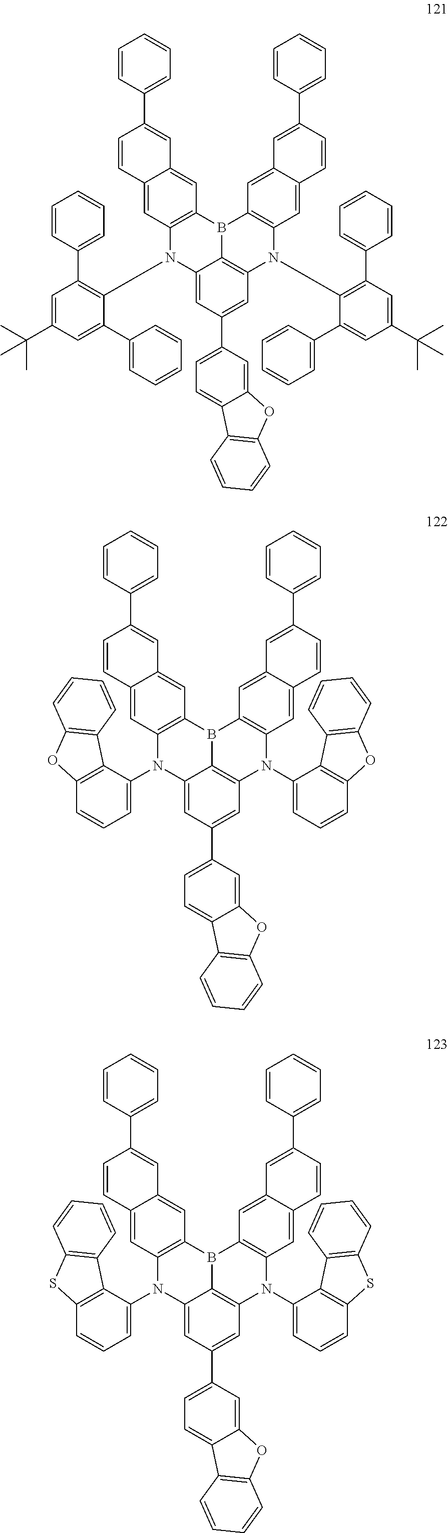 [SMILES: CC(C)(C)c1cc(-c2ccccc2)c(N2c3cc4ccc(-c5ccccc5)cc4cc3B3c4cc5cc(-c6ccccc6)ccc5cc4N(c4c(-c5ccccc5)cc(C(C)(C)C)cc4-c4ccccc4)c4cc(-c5ccc6c(c5)oc5ccccc56)cc2c43)c(-c2ccccc2)c1 ; c1ccc(-c2ccc3cc4c(cc3c2)B2c3cc5cc(-c6ccccc6)ccc5cc3N(c3cccc5oc6ccccc6c35)c3cc(-c5ccc6c(c5)oc5ccccc56)cc(c32)N4c2cccc3oc4ccccc4c23)cc1 ; c1ccc(-c2ccc3cc4c(cc3c2)B2c3cc5cc(-c6ccccc6)ccc5cc3N(c3cccc5sc6ccccc6c35)c3cc(-c5ccc6c(c5)oc5ccccc56)cc(c32)N4c2cccc3sc4ccccc4c23)cc1]

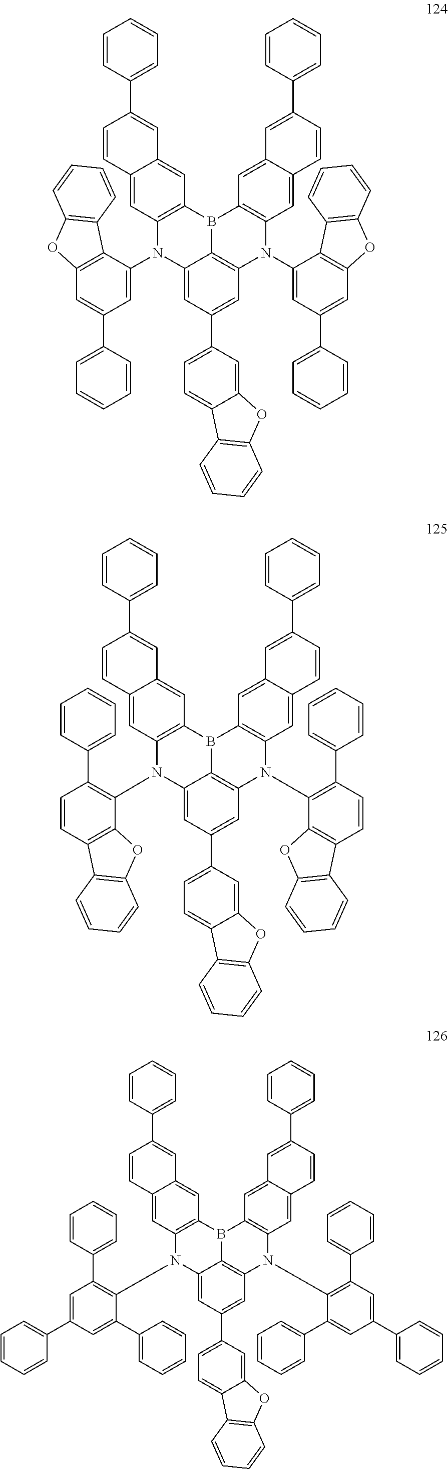 [SMILES: c1ccc(-c2ccc3cc4c(cc3c2)B2c3cc5cc(-c6ccccc6)ccc5cc3N(c3cc(-c5ccccc5)cc5oc6ccccc6c35)c3cc(-c5ccc6c(c5)oc5ccccc56)cc(c32)N4c2cc(-c3ccccc3)cc3oc4ccccc4c23)cc1 ; c1ccc(-c2ccc3cc4c(cc3c2)B2c3cc5cc(-c6ccccc6)ccc5cc3N(c3c(-c5ccccc5)ccc5c3oc3ccccc35)c3cc(-c5ccc6c(c5)oc5ccccc56)cc(c32)N4c2c(-c3ccccc3)ccc3c2oc2ccccc23)cc1 ; c1ccc(-c2cc(-c3ccccc3)c(N3c4cc5ccc(-c6ccccc6)cc5cc4B4c5cc6cc(-c7ccccc7)ccc6cc5N(c5c(-c6ccccc6)cc(-c6ccccc6)cc5-c5ccccc5)c5cc(-c6ccc7c(c6)oc6ccccc67)cc3c54)c(-c3ccccc3)c2)cc1]

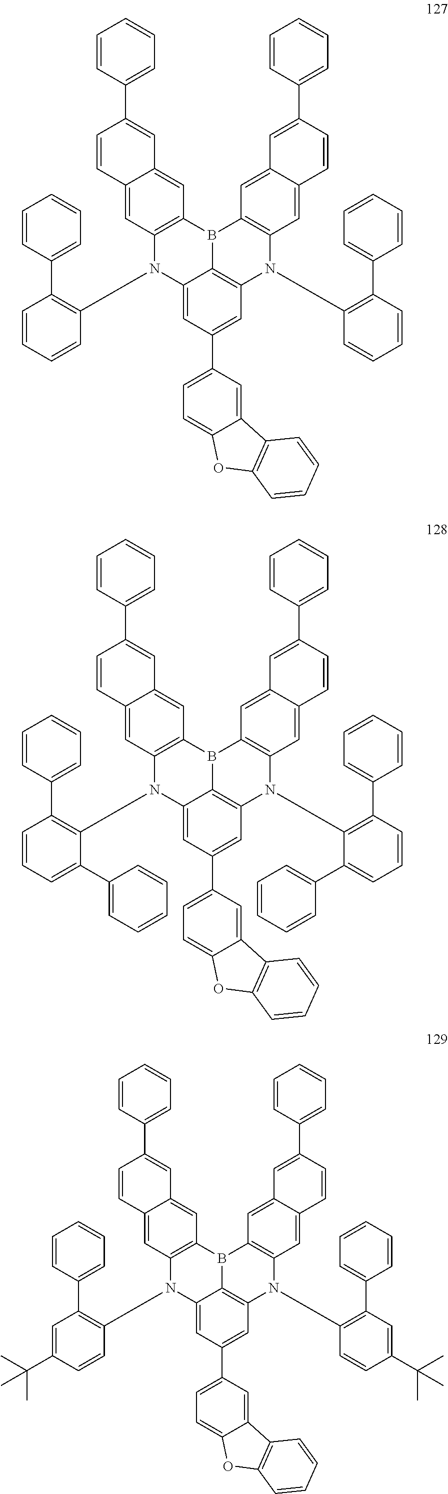

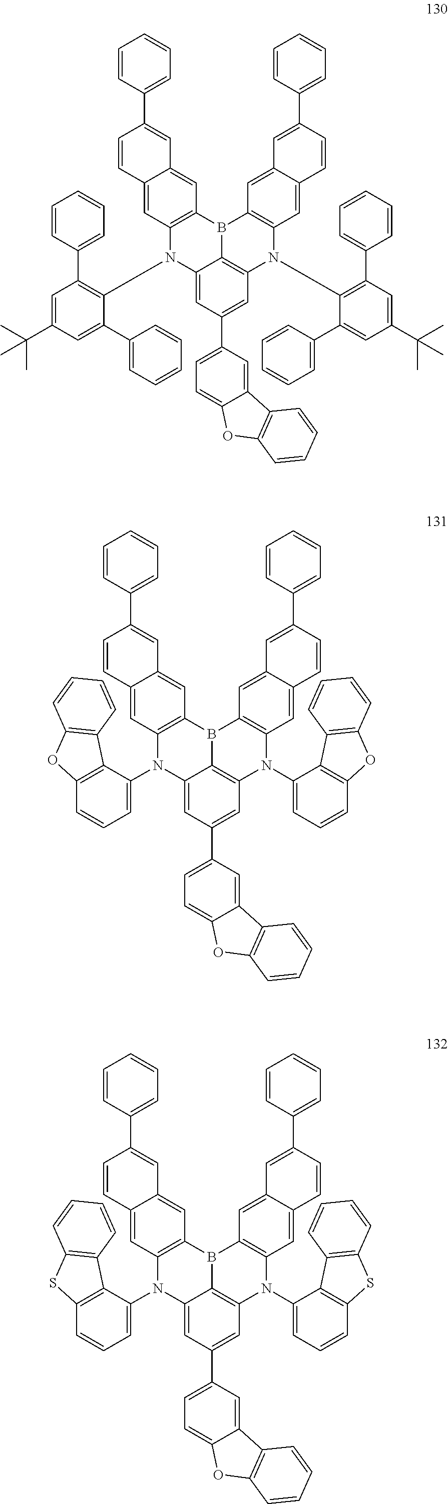 [SMILES: CC(C)(C)c1cc(-c2ccccc2)c(N2c3cc4ccc(-c5ccccc5)cc4cc3B3c4cc5cc(-c6ccccc6)ccc5cc4N(c4c(-c5ccccc5)cc(C(C)(C)C)cc4-c4ccccc4)c4cc(-c5ccc6oc7ccccc7c6c5)cc2c43)c(-c2ccccc2)c1 ; c1ccc(-c2ccc3cc4c(cc3c2)B2c3cc5cc(-c6ccccc6)ccc5cc3N(c3cccc5oc6ccccc6c35)c3cc(-c5ccc6oc7ccccc7c6c5)cc(c32)N4c2cccc3oc4ccccc4c23)cc1 ; c1ccc(-c2ccc3cc4c(cc3c2)B2c3cc5cc(-c6ccccc6)ccc5cc3N(c3cccc5sc6ccccc6c35)c3cc(-c5ccc6oc7ccccc7c6c5)cc(c32)N4c2cccc3sc4ccccc4c23)cc1]

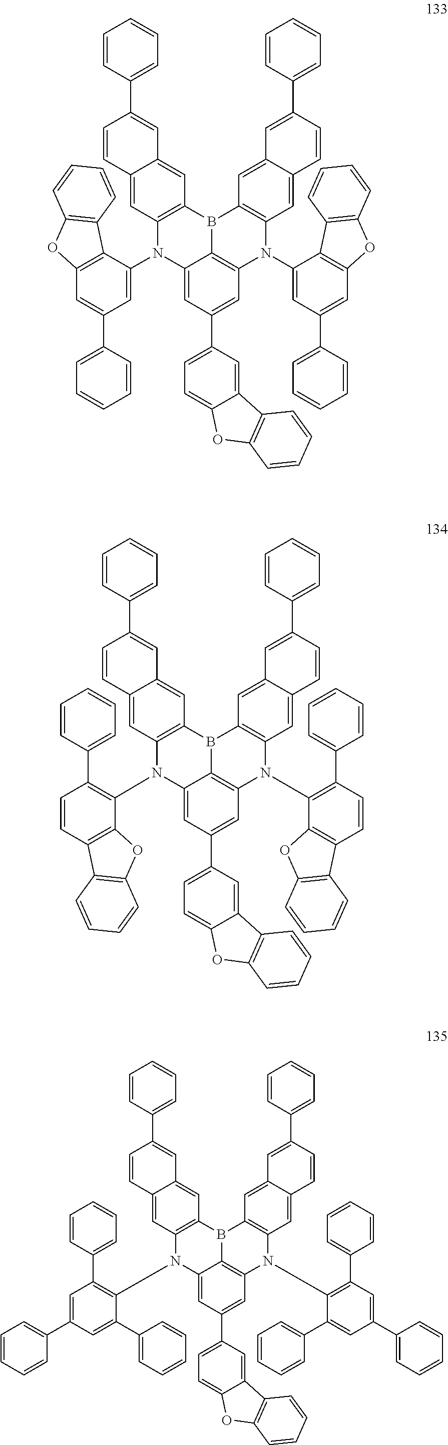 [SMILES: c1ccc(-c2ccc3cc4c(cc3c2)B2c3cc5cc(-c6ccccc6)ccc5cc3N(c3cc(-c5ccccc5)cc5oc6ccccc6c35)c3cc(-c5ccc6oc7ccccc7c6c5)cc(c32)N4c2cc(-c3ccccc3)cc3oc4ccccc4c23)cc1 ; c1ccc(-c2ccc3cc4c(cc3c2)B2c3cc5cc(-c6ccccc6)ccc5cc3N(c3c(-c5ccccc5)ccc5c3oc3ccccc35)c3cc(-c5ccc6oc7ccccc7c6c5)cc(c32)N4c2c(-c3ccccc3)ccc3c2oc2ccccc23)cc1 ; c1ccc(-c2cc(-c3ccccc3)c(N3c4cc5ccc(-c6ccccc6)cc5cc4B4c5cc6cc(-c7ccccc7)ccc6cc5N(c5c(-c6ccccc6)cc(-c6ccccc6)cc5-c5ccccc5)c5cc(-c6ccc7oc8ccccc8c7c6)cc3c54)c(-c3ccccc3)c2)cc1]

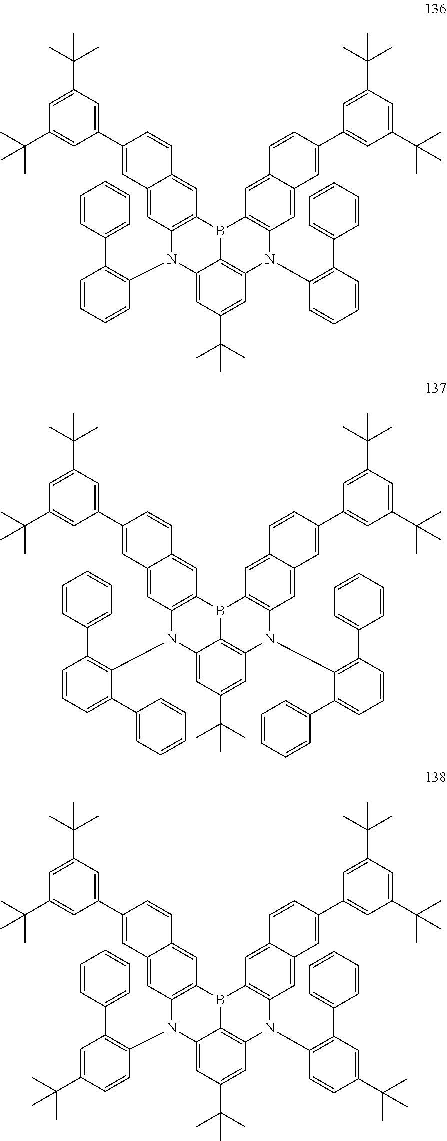

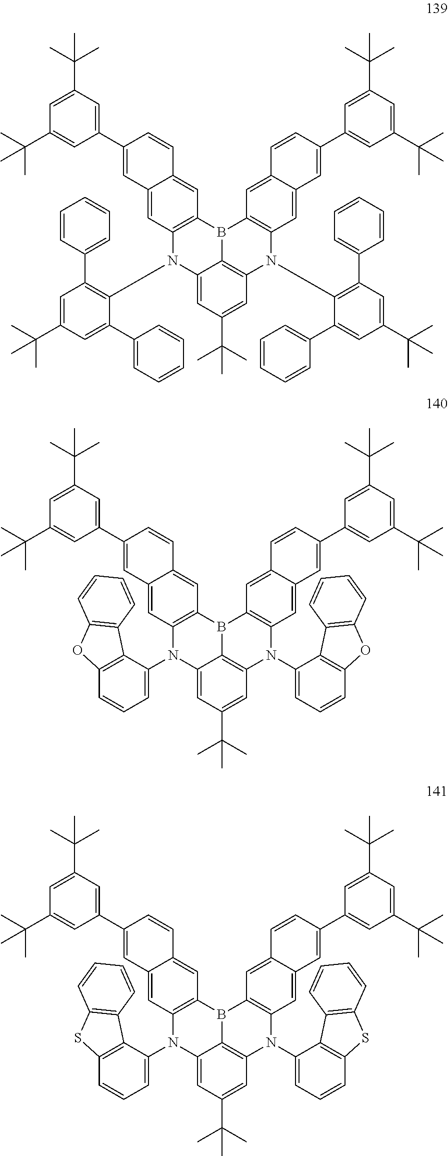

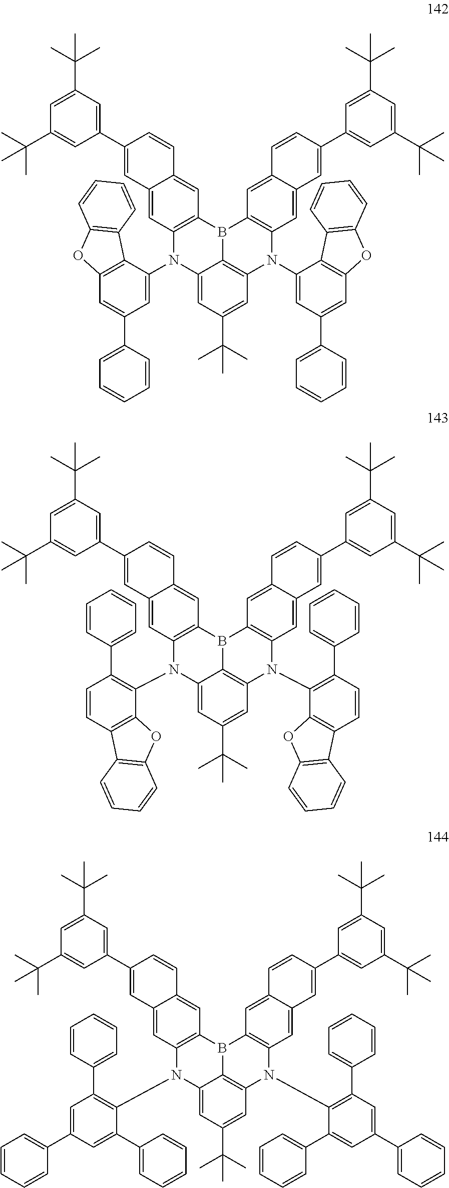

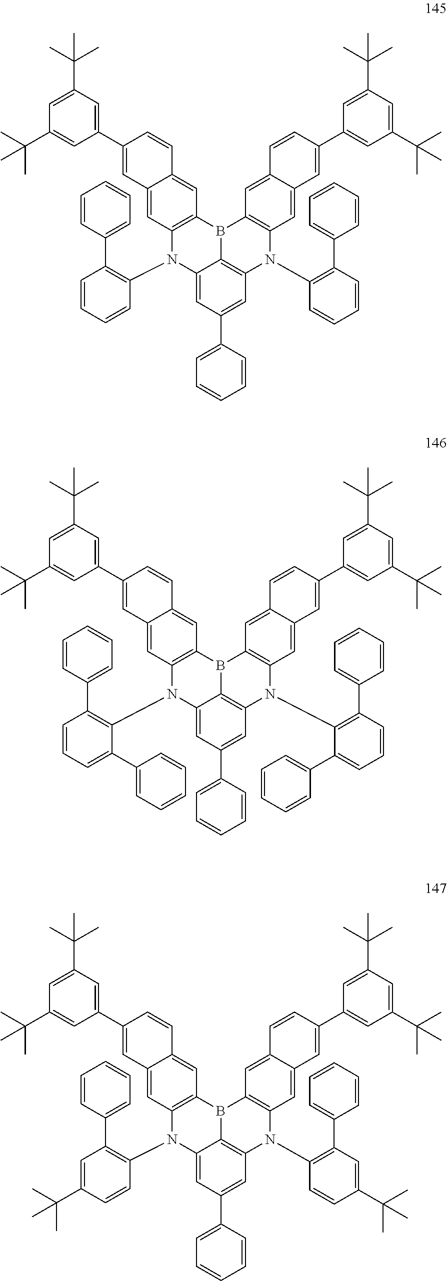

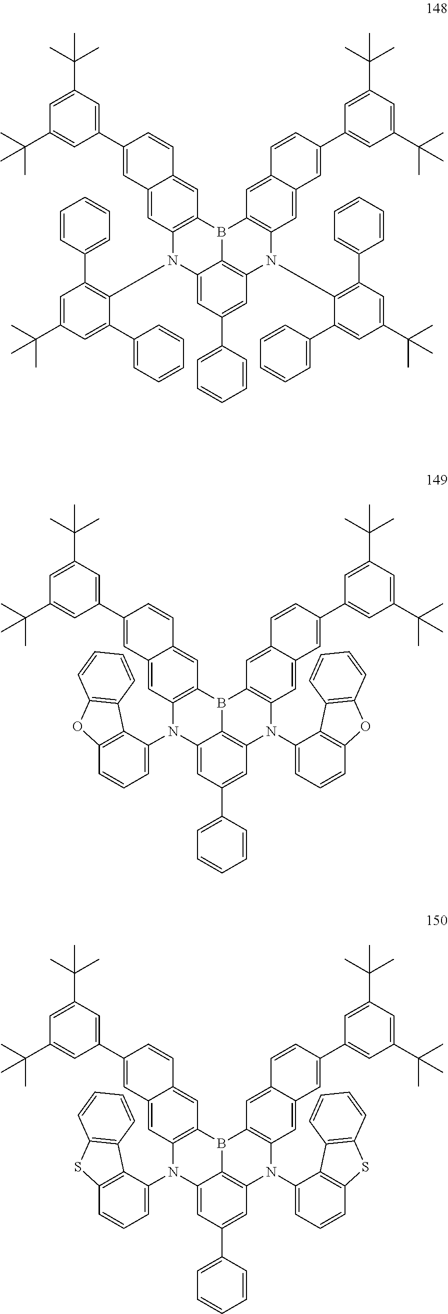

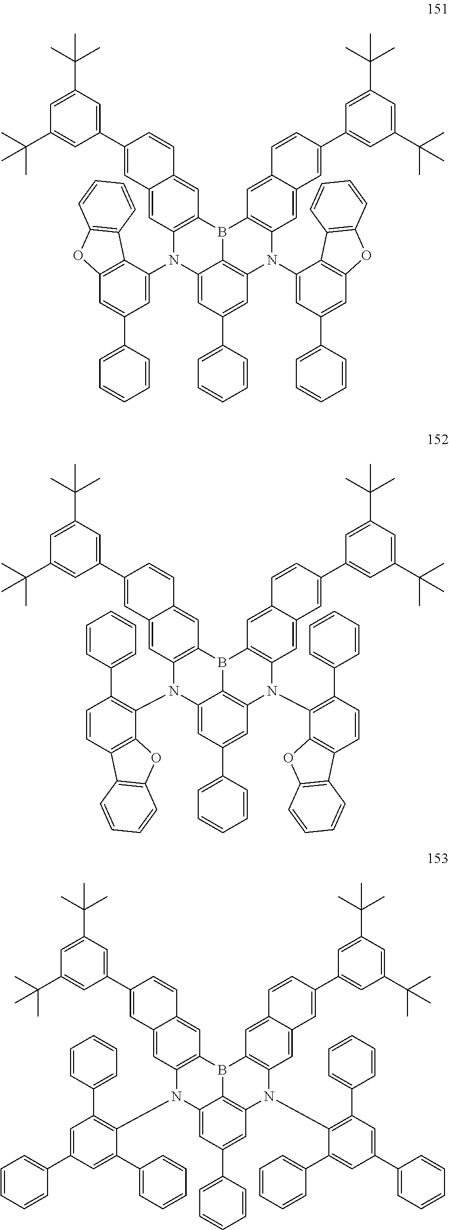

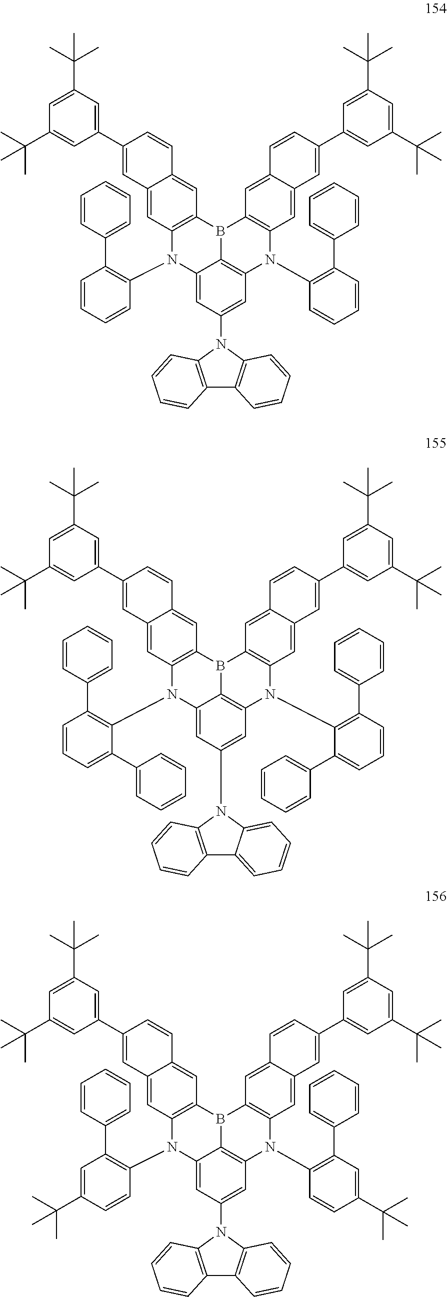

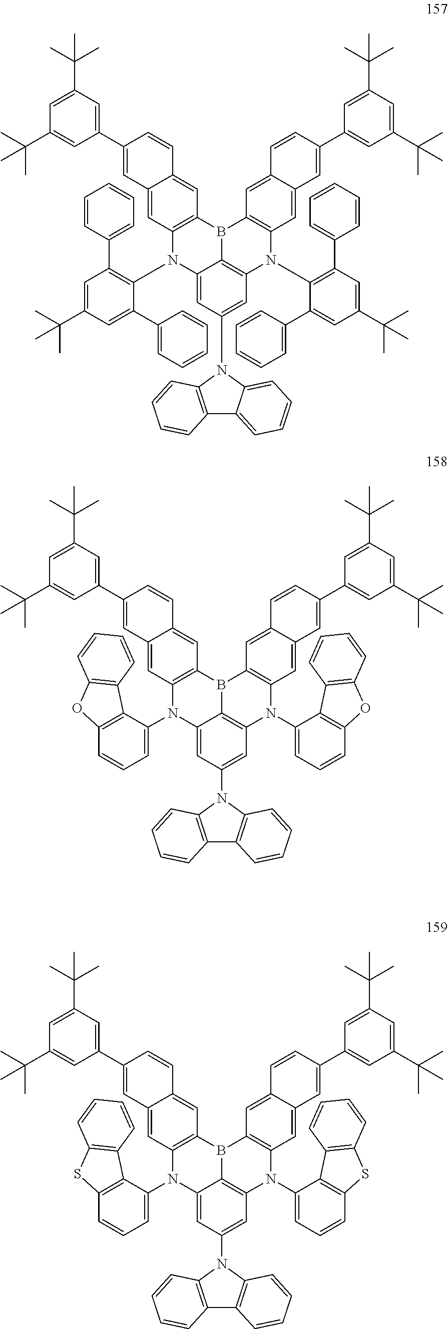

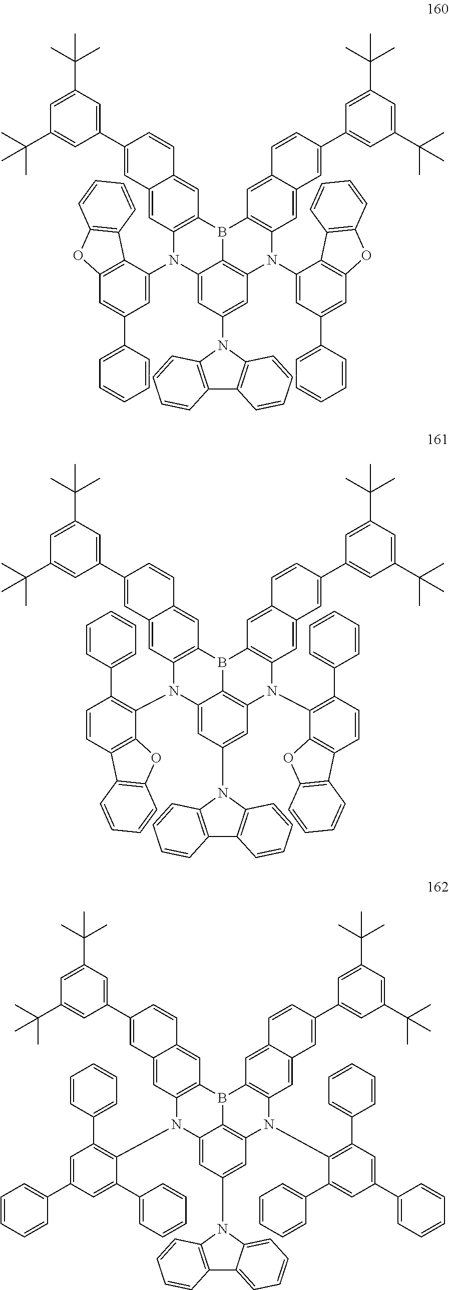

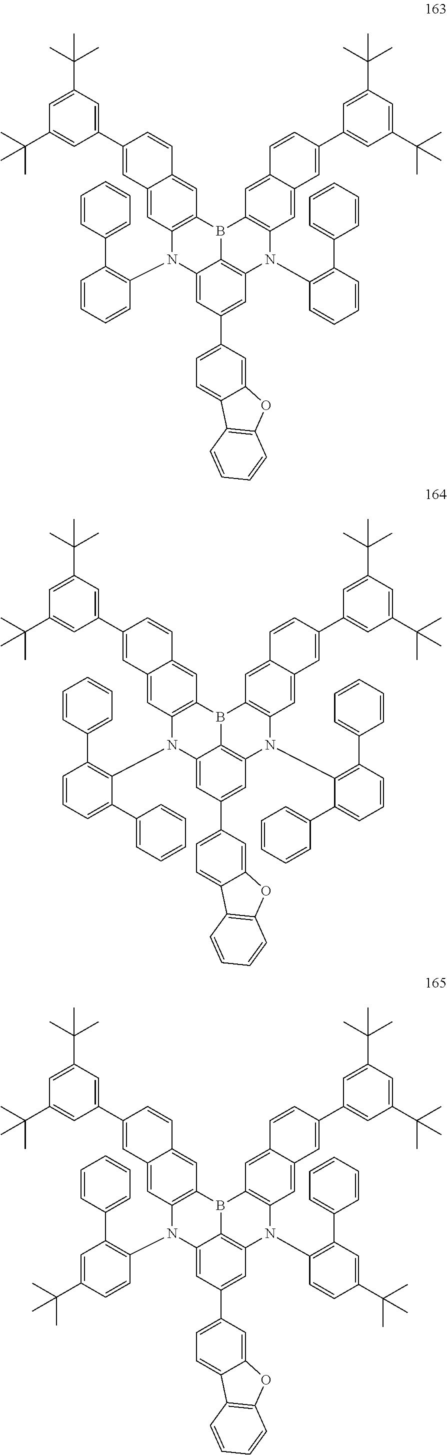

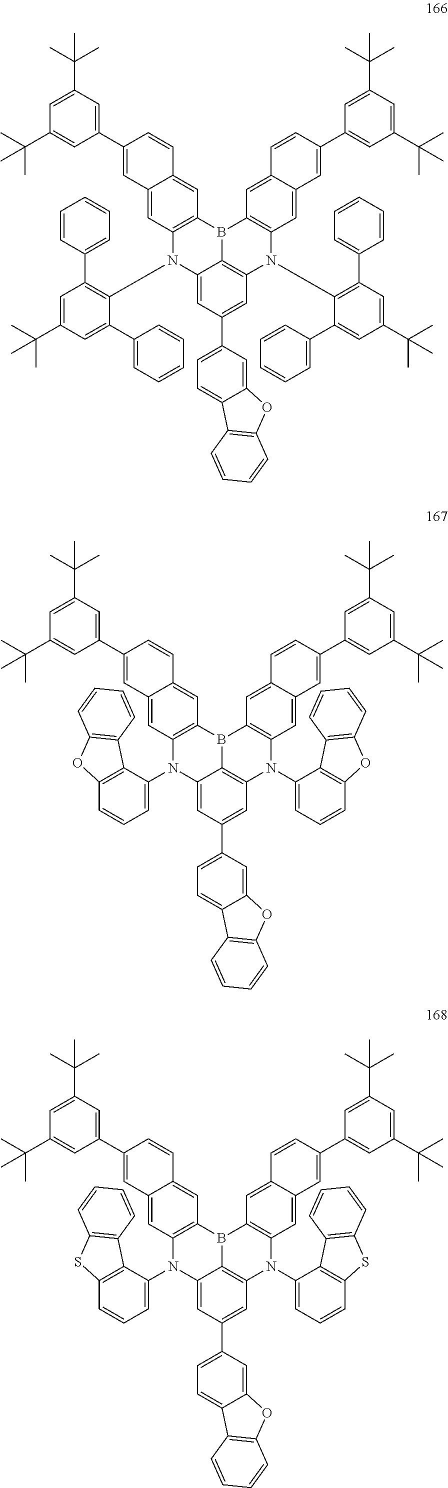

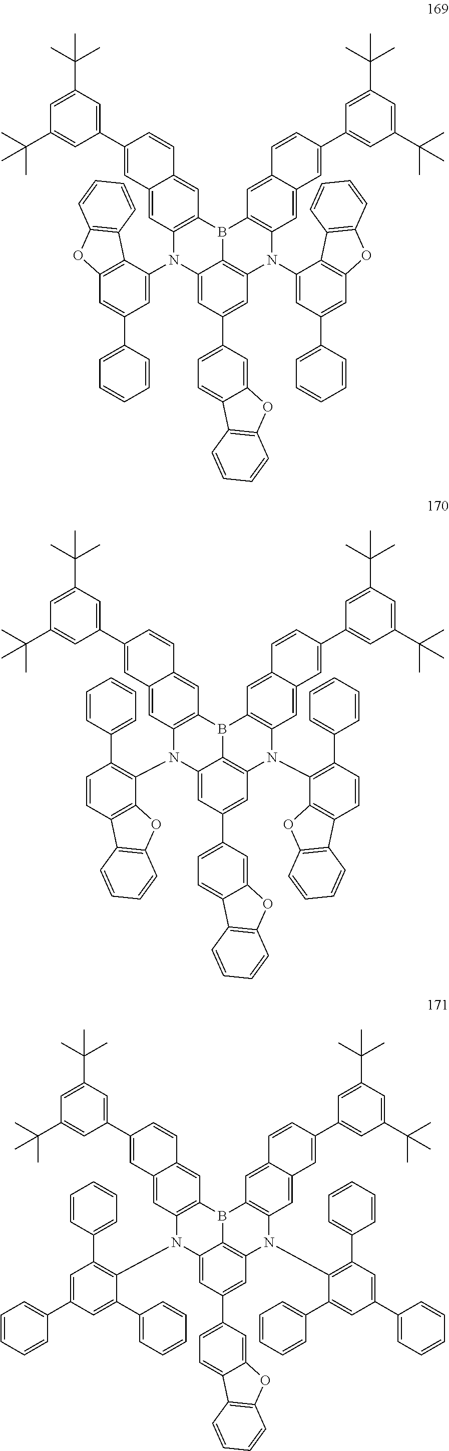

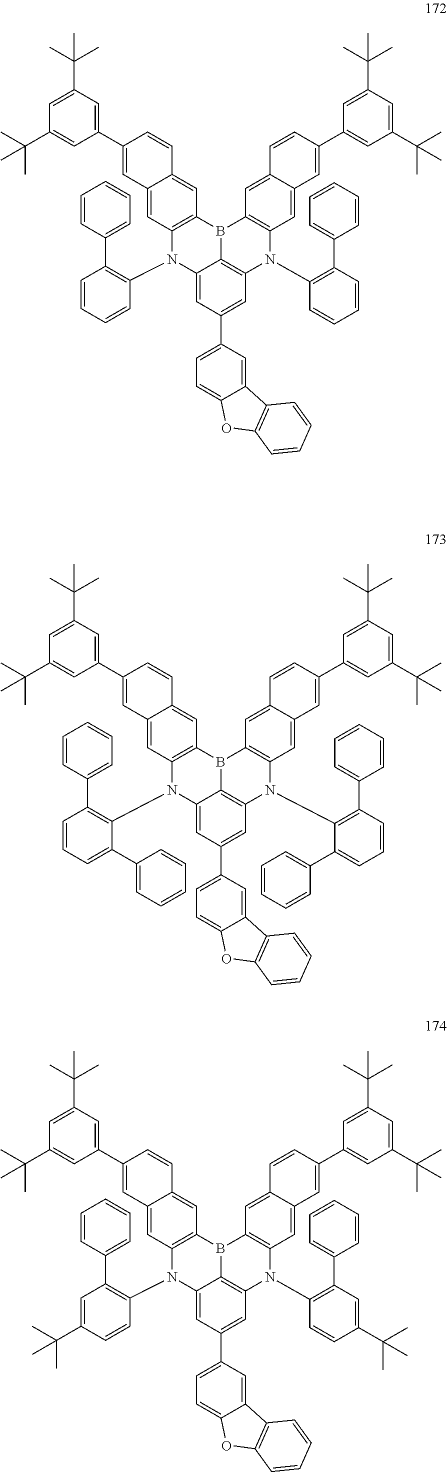

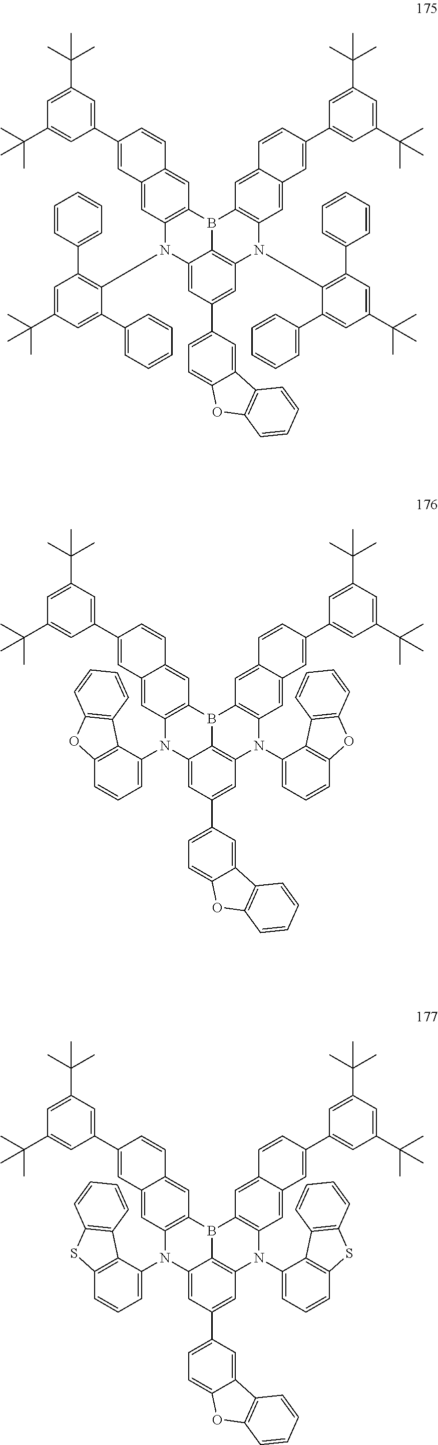

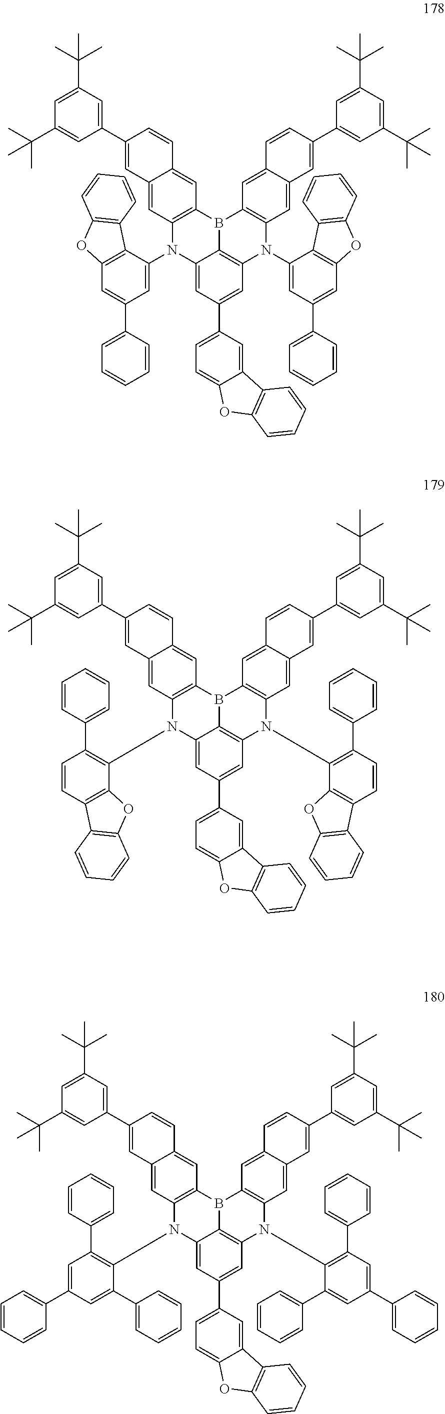

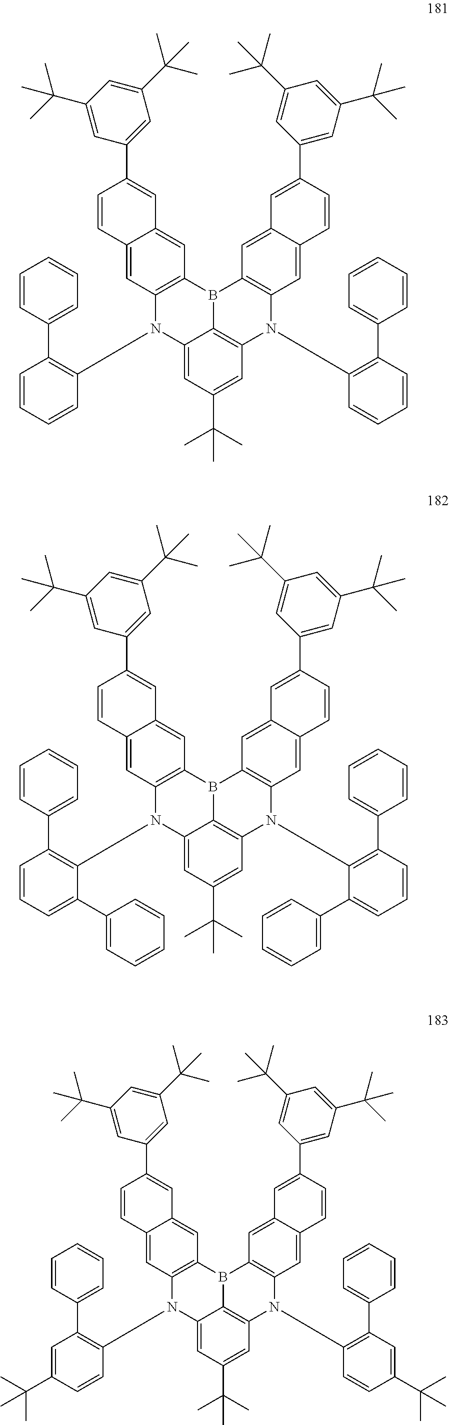

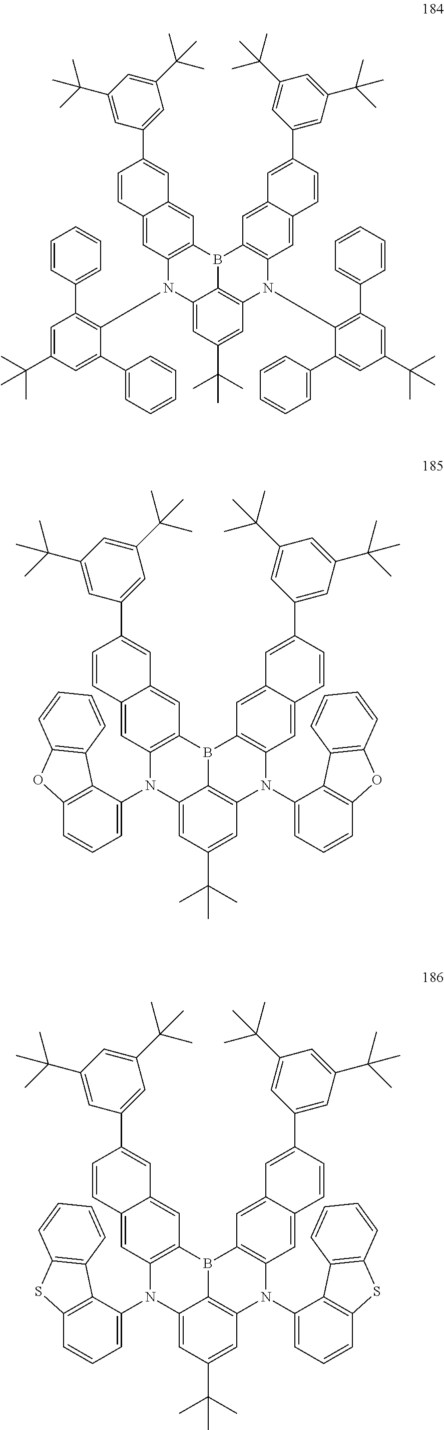

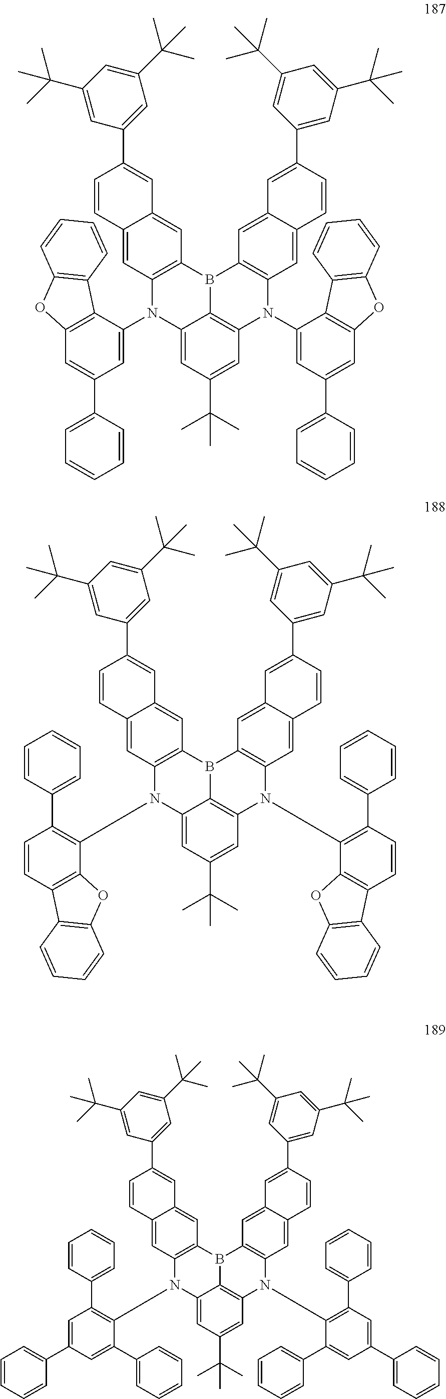

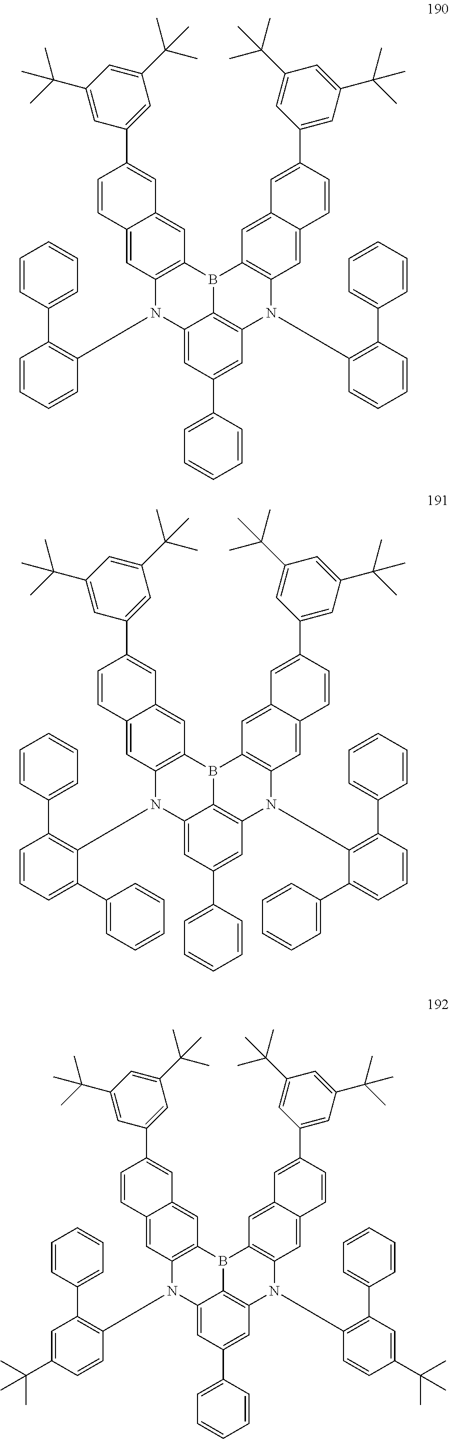

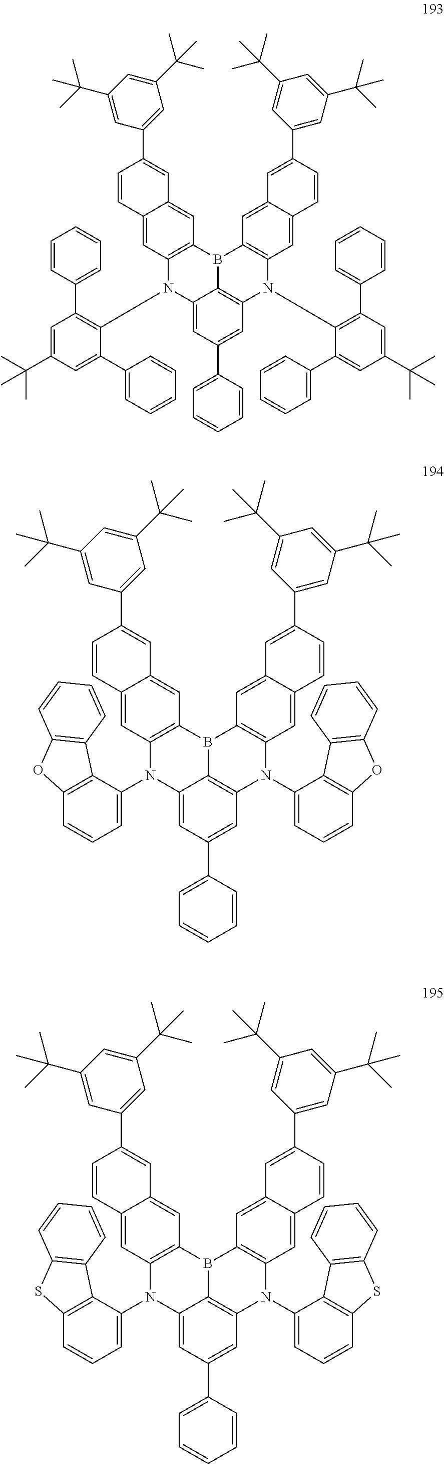

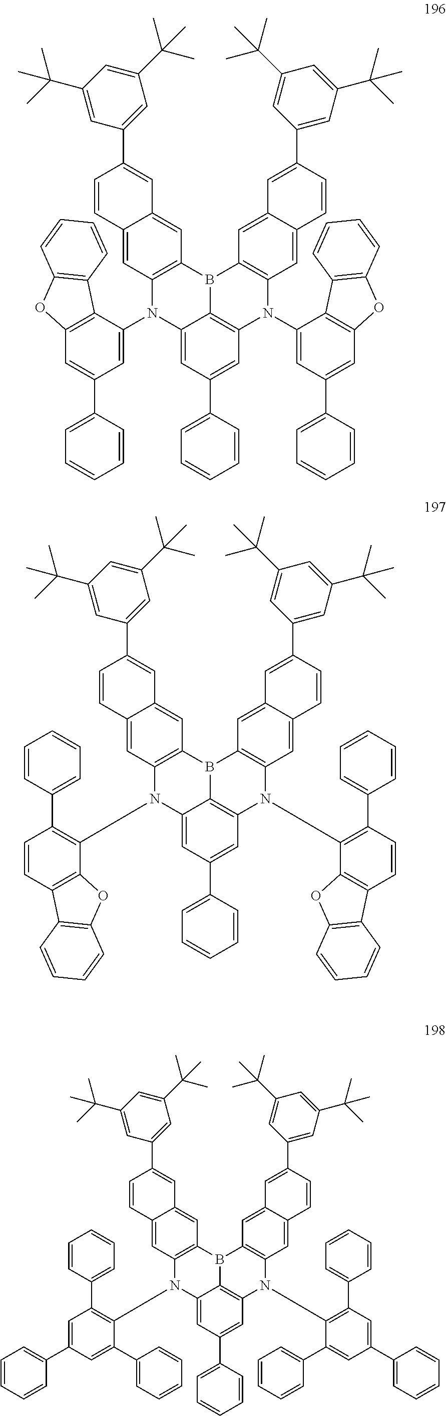

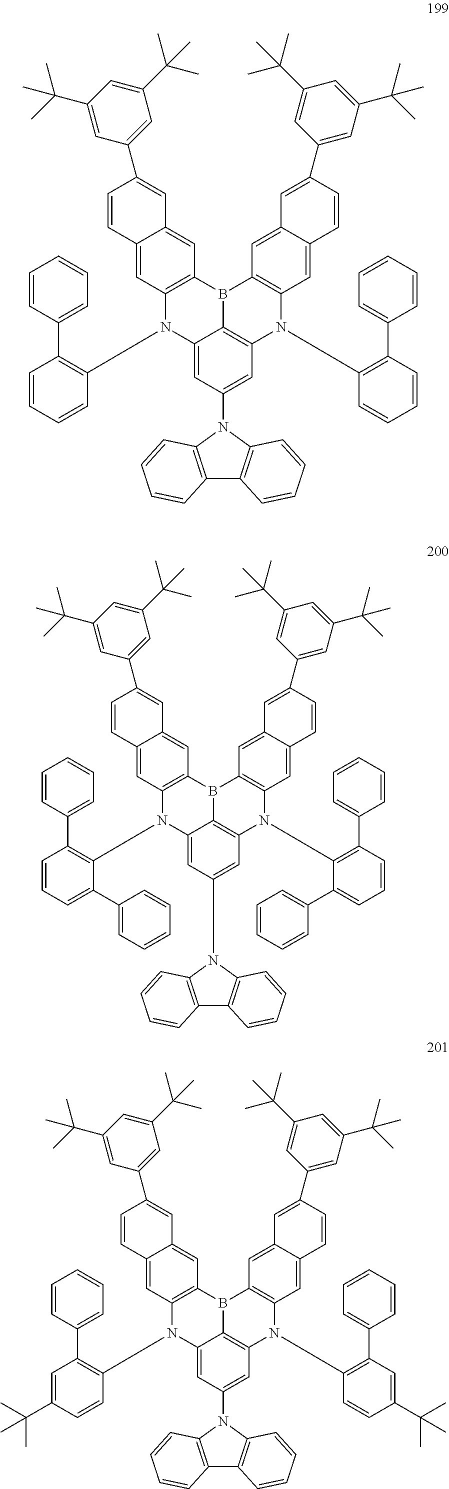

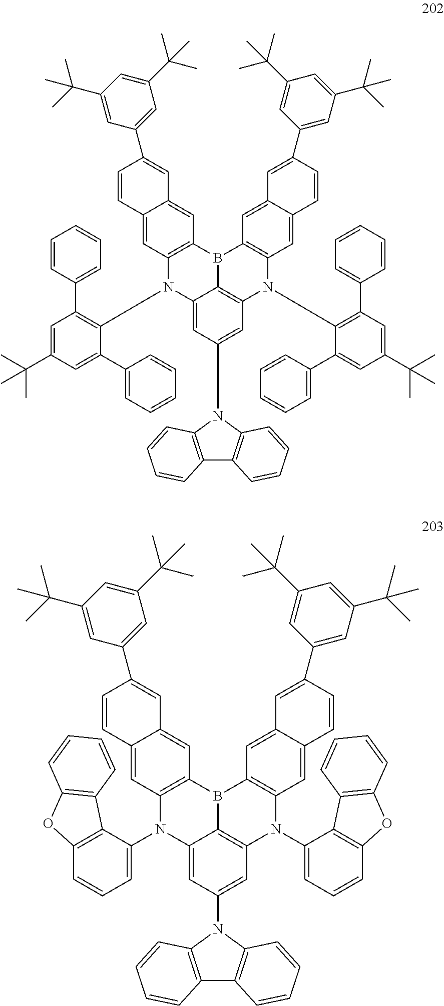

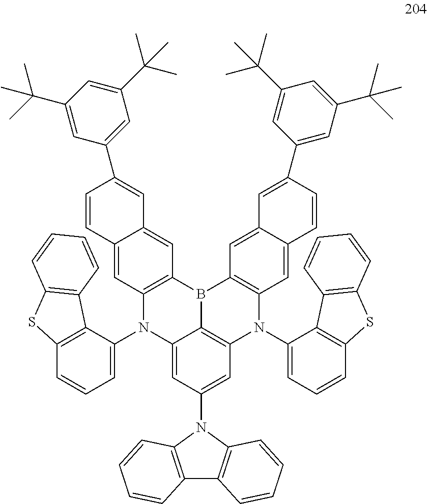 [SMILES: CC(C)(C)c1cc(-c2ccc3cc4c(cc3c2)B2c3cc5cc(-c6cc(C(C)(C)C)cc(C(C)(C)C)c6)ccc5cc3N(c3cccc5sc6ccccc6c35)c3cc(-n5c6ccccc6c6ccccc65)cc(c32)N4c2cccc3sc4ccccc4c23)cc(C(C)(C)C)c1]

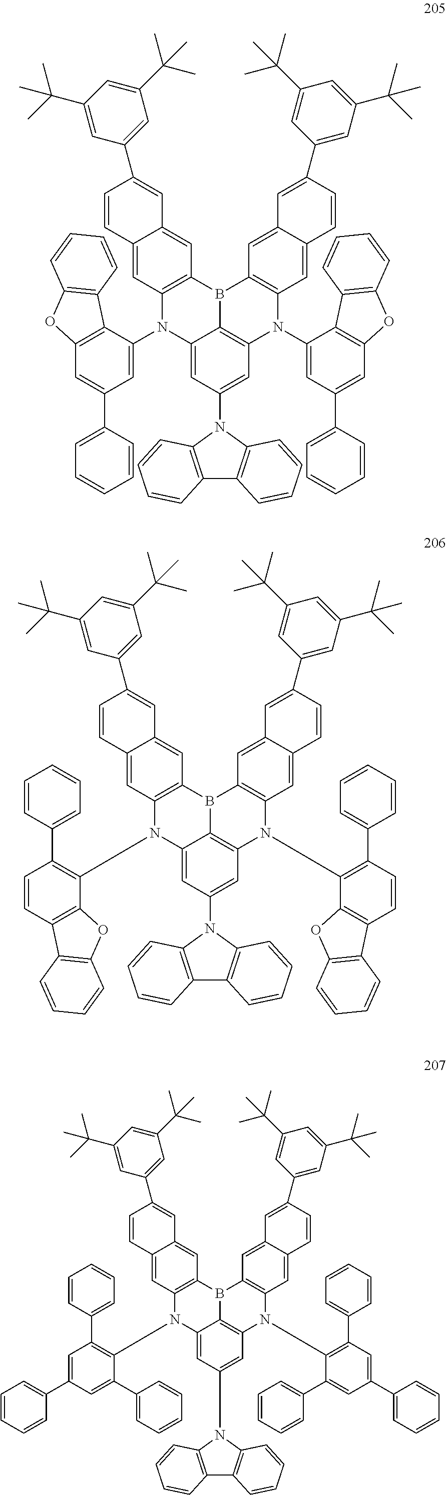

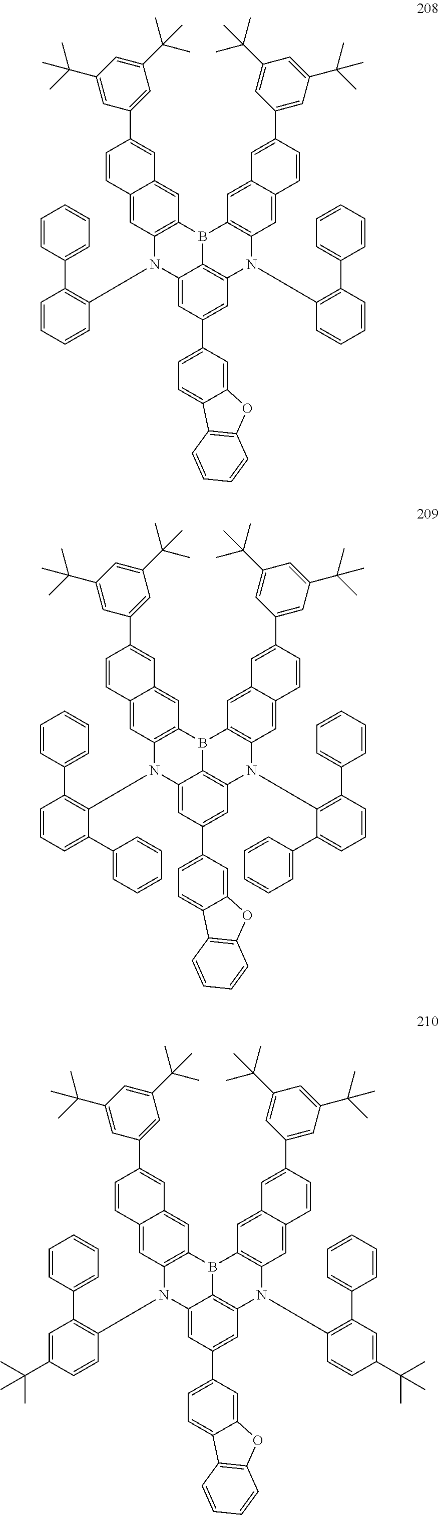

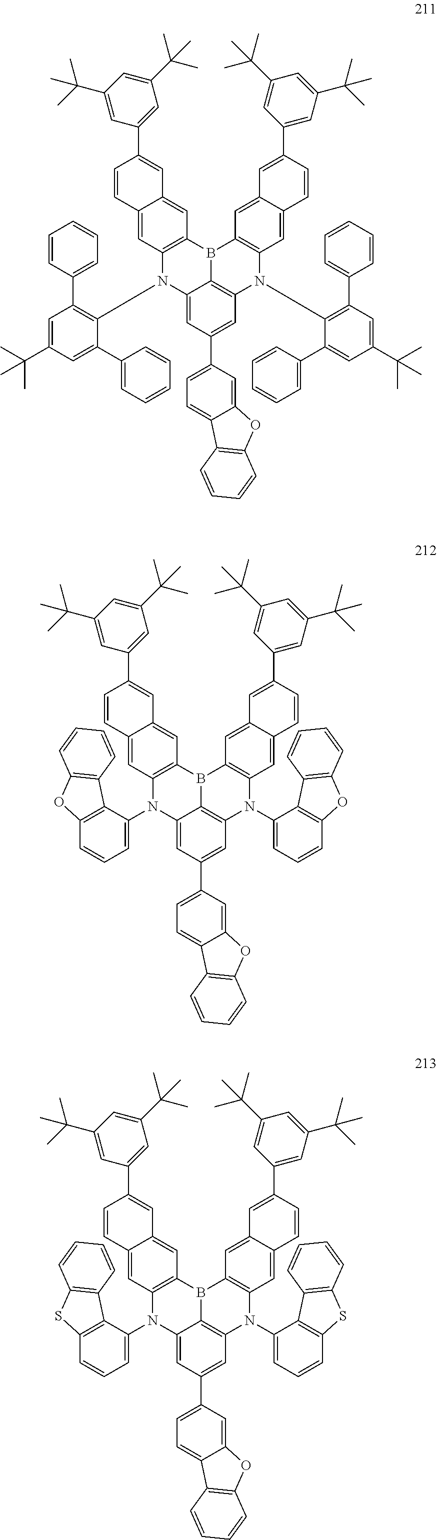

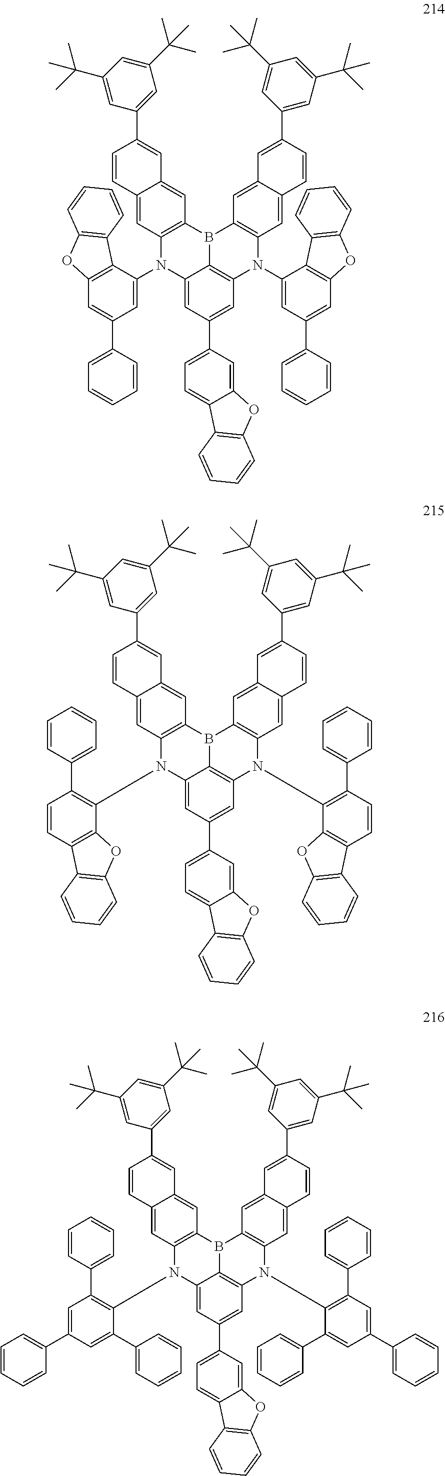

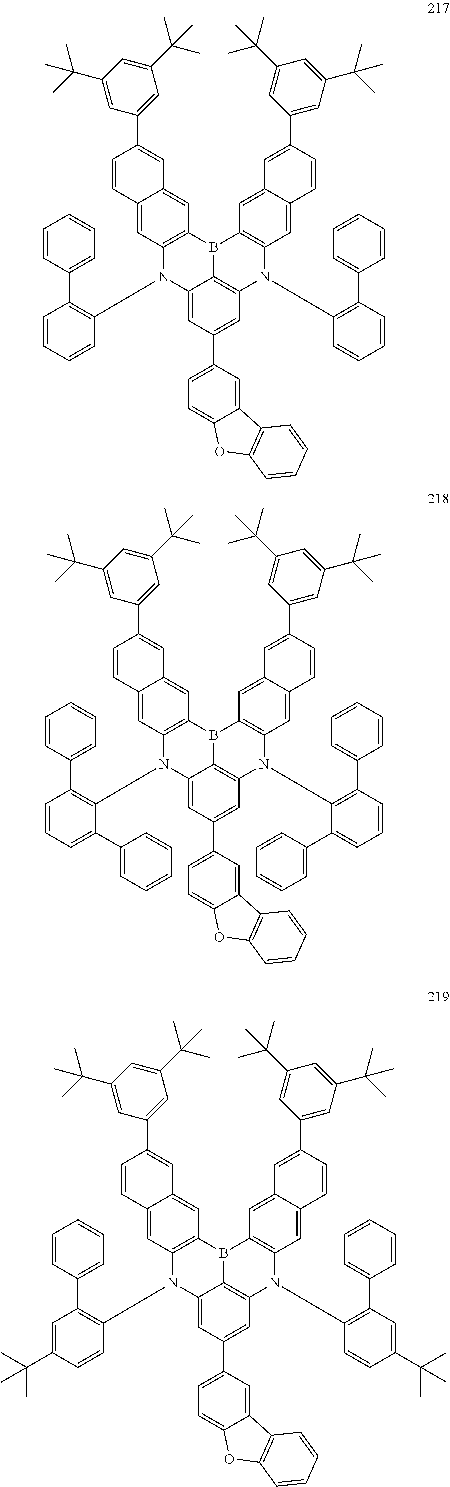

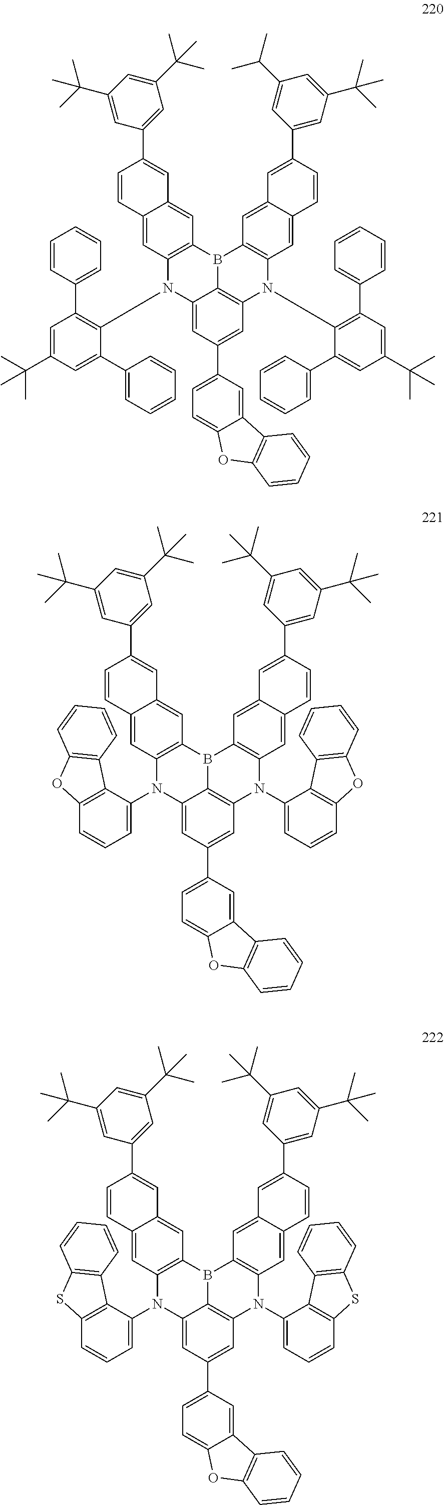

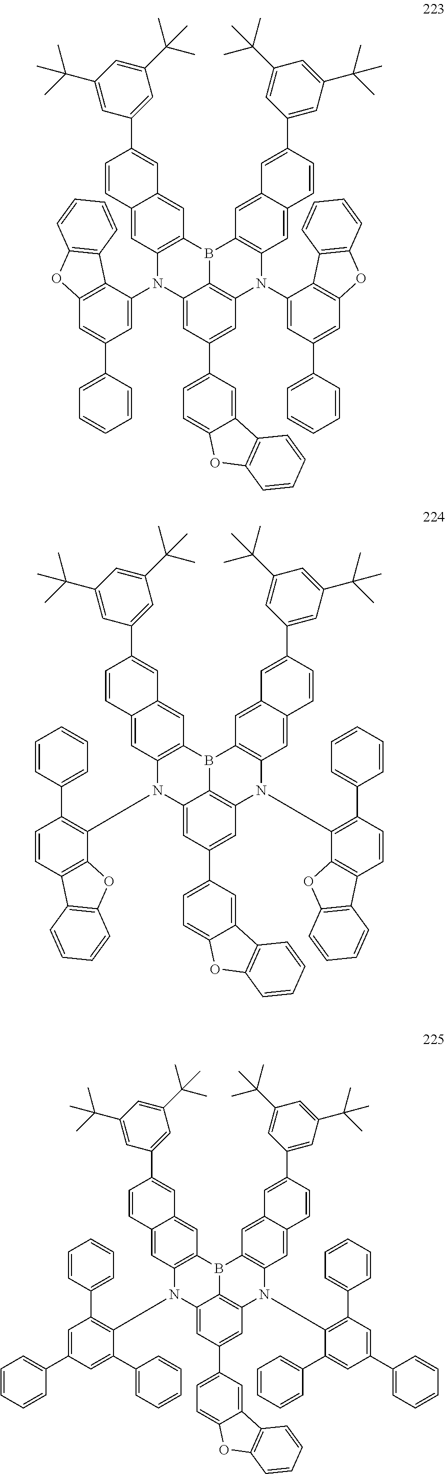

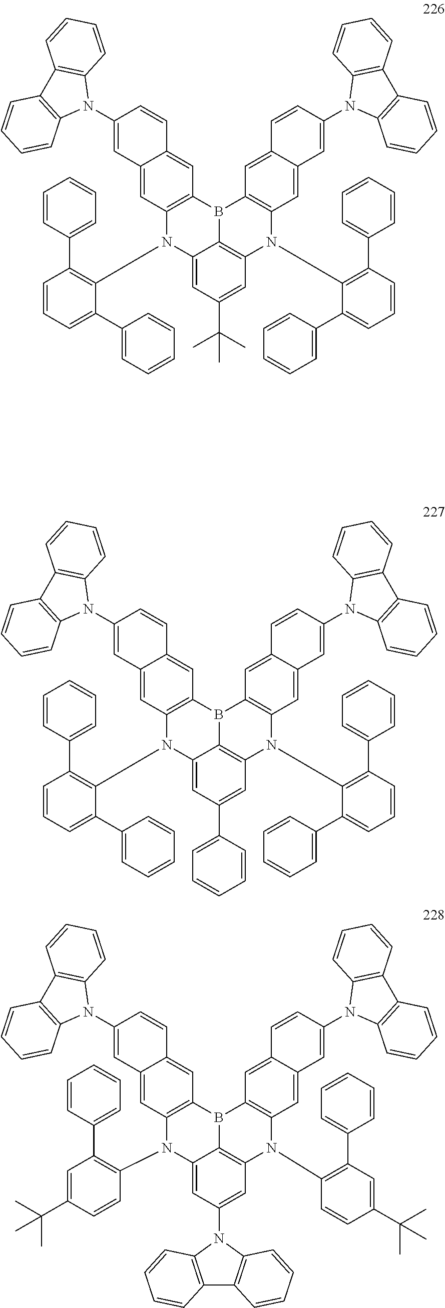 [SMILES: CC(C)(C)c1cc2c3c(c1)N(c1c(-c4ccccc4)cccc1-c1ccccc1)c1cc4cc(-n5c6ccccc6c6ccccc65)ccc4cc1B3c1cc3ccc(-n4c5ccccc5c5ccccc54)cc3cc1N2c1c(-c2ccccc2)cccc1-c1ccccc1 ; c1ccc(-c2cc3c4c(c2)N(c2c(-c5ccccc5)cccc2-c2ccccc2)c2cc5cc(-n6c7ccccc7c7ccccc76)ccc5cc2B4c2cc4ccc(-n5c6ccccc6c6ccccc65)cc4cc2N3c2c(-c3ccccc3)cccc2-c2ccccc2)cc1 ; CC(C)(C)c1ccc(N2c3cc4cc(-n5c6ccccc6c6ccccc65)ccc4cc3B3c4cc5ccc(-n6c7ccccc7c7ccccc76)cc5cc4N(c4ccc(C(C)(C)C)cc4-c4ccccc4)c4cc(-n5c6ccccc6c6ccccc65)cc2c43)c(-c2ccccc2)c1]

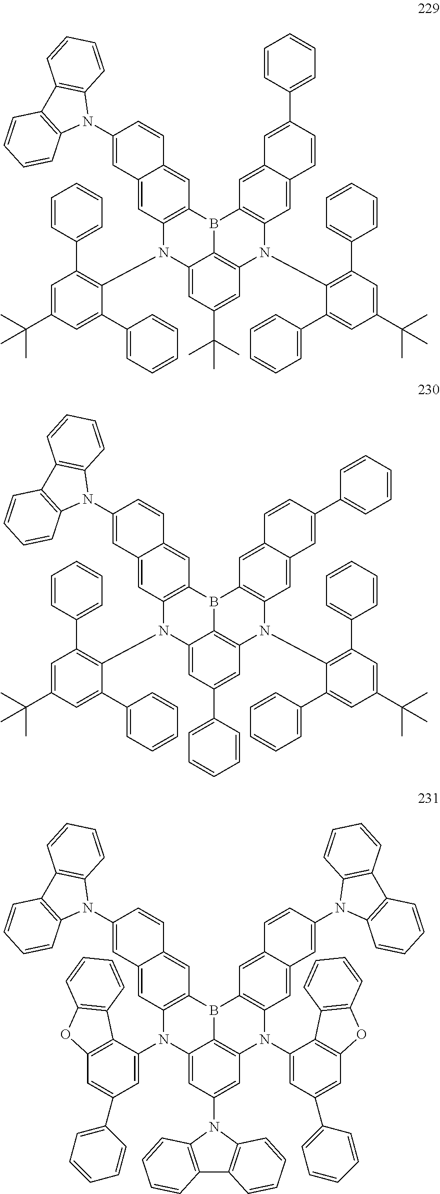

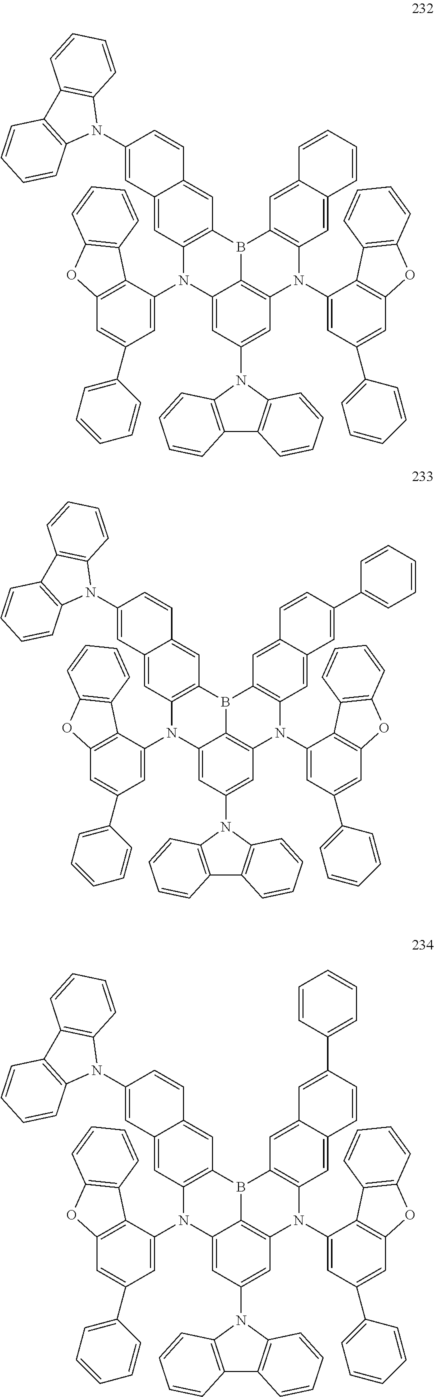 [SMILES: c1ccc(-c2cc(N3c4cc5ccccc5cc4B4c5cc6ccc(-n7c8ccccc8c8ccccc87)cc6cc5N(c5cc(-c6ccccc6)cc6oc7ccccc7c56)c5cc(-n6c7ccccc7c7ccccc76)cc3c54)c3c(c2)oc2ccccc23)cc1 ; c1ccc(-c2ccc3cc4c(cc3c2)N(c2cc(-c3ccccc3)cc3oc5ccccc5c23)c2cc(-n3c5ccccc5c5ccccc53)cc3c2B4c2cc4ccc(-n5c6ccccc6c6ccccc65)cc4cc2N3c2cc(-c3ccccc3)cc3oc4ccccc4c23)cc1 ; c1ccc(-c2ccc3cc4c(cc3c2)B2c3cc5ccc(-n6c7ccccc7c7ccccc76)cc5cc3N(c3cc(-c5ccccc5)cc5oc6ccccc6c35)c3cc(-n5c6ccccc6c6ccccc65)cc(c32)N4c2cc(-c3ccccc3)cc3oc4ccccc4c23)cc1]

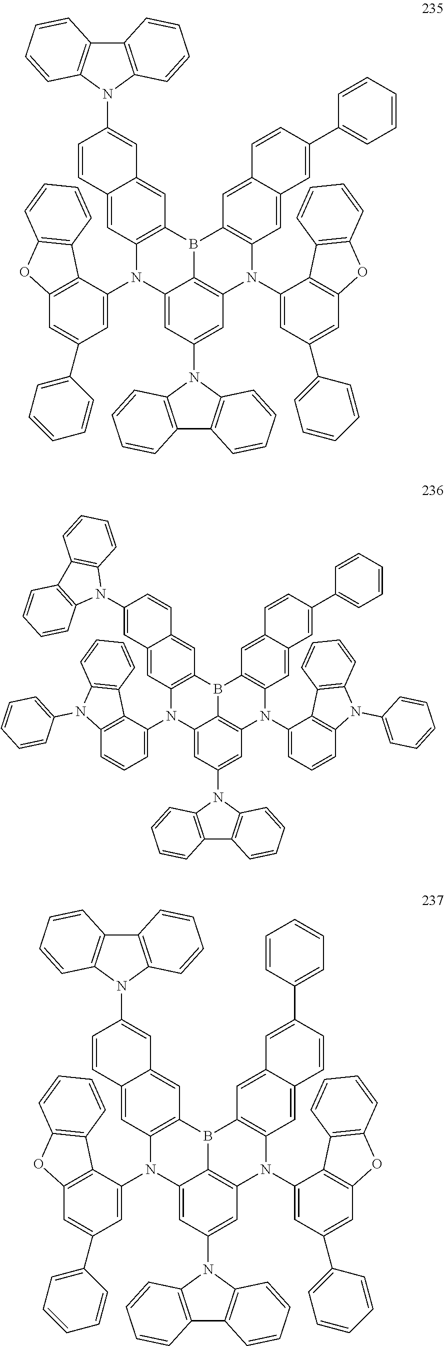 [SMILES: c1ccc(-c2ccc3cc4c(cc3c2)N(c2cc(-c3ccccc3)cc3oc5ccccc5c23)c2cc(-n3c5ccccc5c5ccccc53)cc3c2B4c2cc4cc(-n5c6ccccc6c6ccccc65)ccc4cc2N3c2cc(-c3ccccc3)cc3oc4ccccc4c23)cc1 ; c1ccc(-c2ccc3cc4c(cc3c2)N(c2cccc3c2c2ccccc2n3-c2ccccc2)c2cc(-n3c5ccccc5c5ccccc53)cc3c2B4c2cc4ccc(-n5c6ccccc6c6ccccc65)cc4cc2N3c2cccc3c2c2ccccc2n3-c2ccccc2)cc1 ; c1ccc(-c2ccc3cc4c(cc3c2)B2c3cc5cc(-n6c7ccccc7c7ccccc76)ccc5cc3N(c3cc(-c5ccccc5)cc5oc6ccccc6c35)c3cc(-n5c6ccccc6c6ccccc65)cc(c32)N4c2cc(-c3ccccc3)cc3oc4ccccc4c23)cc1]

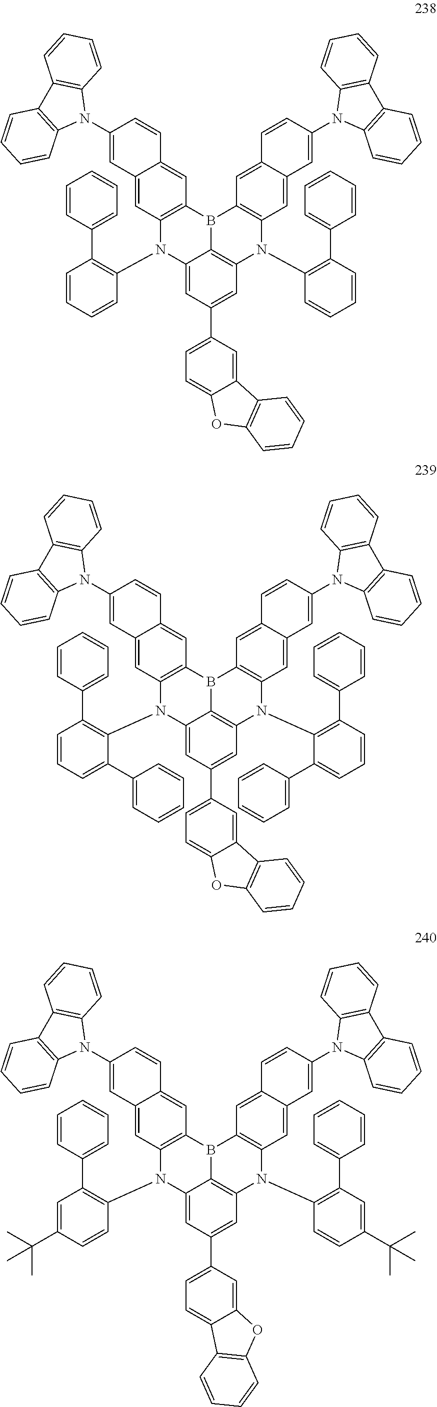 [SMILES: c1ccc(-c2ccccc2N2c3cc4cc(-n5c6ccccc6c6ccccc65)ccc4cc3B3c4cc5ccc(-n6c7ccccc7c7ccccc76)cc5cc4N(c4ccccc4-c4ccccc4)c4cc(-c5ccc6oc7ccccc7c6c5)cc2c43)cc1 ; c1ccc(-c2cccc(-c3ccccc3)c2N2c3cc4cc(-n5c6ccccc6c6ccccc65)ccc4cc3B3c4cc5ccc(-n6c7ccccc7c7ccccc76)cc5cc4N(c4c(-c5ccccc5)cccc4-c4ccccc4)c4cc(-c5ccc6oc7ccccc7c6c5)cc2c43)cc1 ; CC(C)(C)c1ccc(N2c3cc4cc(-n5c6ccccc6c6ccccc65)ccc4cc3B3c4cc5ccc(-n6c7ccccc7c7ccccc76)cc5cc4N(c4ccc(C(C)(C)C)cc4-c4ccccc4)c4cc(-c5ccc6c(c5)oc5ccccc56)cc2c43)c(-c2ccccc2)c1]

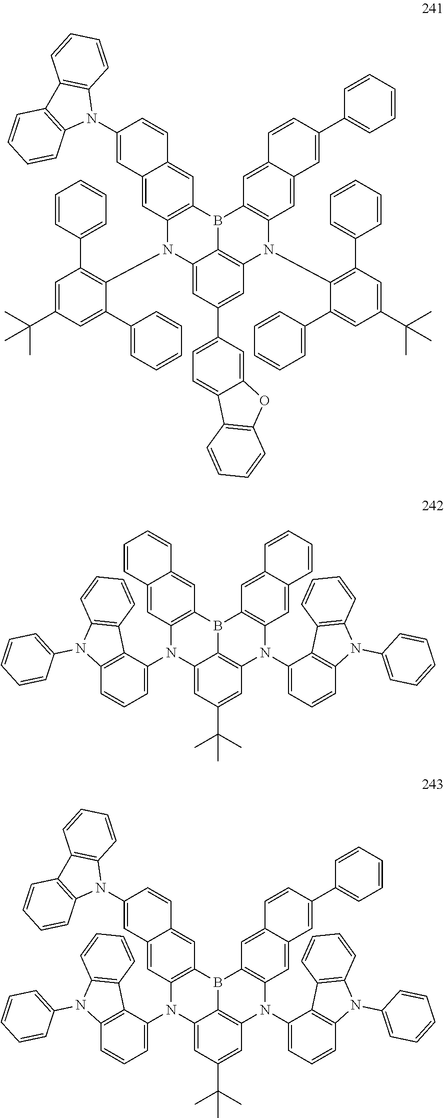 [SMILES: CC(C)(C)c1cc(-c2ccccc2)c(N2c3cc4cc(-c5ccccc5)ccc4cc3B3c4cc5ccc(-n6c7ccccc7c7ccccc76)cc5cc4N(c4c(-c5ccccc5)cc(C(C)(C)C)cc4-c4ccccc4)c4cc(-c5ccc6c(c5)oc5ccccc56)cc2c43)c(-c2ccccc2)c1 ; CC(C)(C)c1cc2c3c(c1)N(c1cccc4c1c1ccccc1n4-c1ccccc1)c1cc4ccccc4cc1B3c1cc3ccccc3cc1N2c1cccc2c1c1ccccc1n2-c1ccccc1 ; CC(C)(C)c1cc2c3c(c1)N(c1cccc4c1c1ccccc1n4-c1ccccc1)c1cc4cc(-n5c6ccccc6c6ccccc65)ccc4cc1B3c1cc3ccc(-c4ccccc4)cc3cc1N2c1cccc2c1c1ccccc1n2-c1ccccc1]

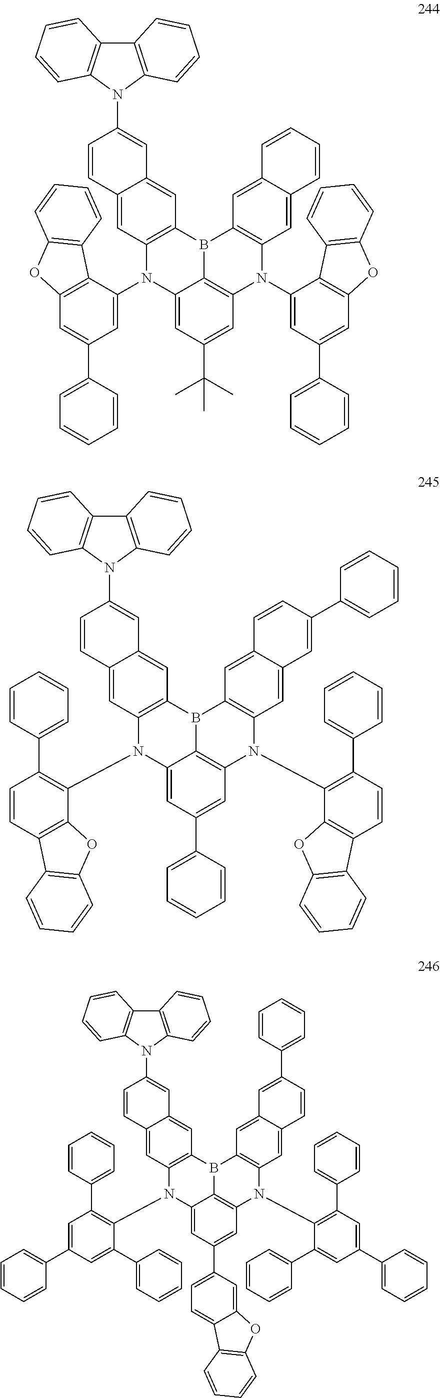 [SMILES: CC(C)(C)c1cc2c3c(c1)N(c1cc(-c4ccccc4)cc4oc5ccccc5c14)c1cc4ccc(-n5c6ccccc6c6ccccc65)cc4cc1B3c1cc3ccccc3cc1N2c1cc(-c2ccccc2)cc2oc3ccccc3c12 ; c1ccc(-c2cc3c4c(c2)N(c2c(-c5ccccc5)ccc5c2oc2ccccc25)c2cc5cc(-c6ccccc6)ccc5cc2B4c2cc4cc(-n5c6ccccc6c6ccccc65)ccc4cc2N3c2c(-c3ccccc3)ccc3c2oc2ccccc23)cc1 ; c1ccc(-c2cc(-c3ccccc3)c(N3c4cc5ccc(-c6ccccc6)cc5cc4B4c5cc6cc(-n7c8ccccc8c8ccccc87)ccc6cc5N(c5c(-c6ccccc6)cc(-c6ccccc6)cc5-c5ccccc5)c5cc(-c6ccc7c(c6)oc6ccccc67)cc3c54)c(-c3ccccc3)c2)cc1]

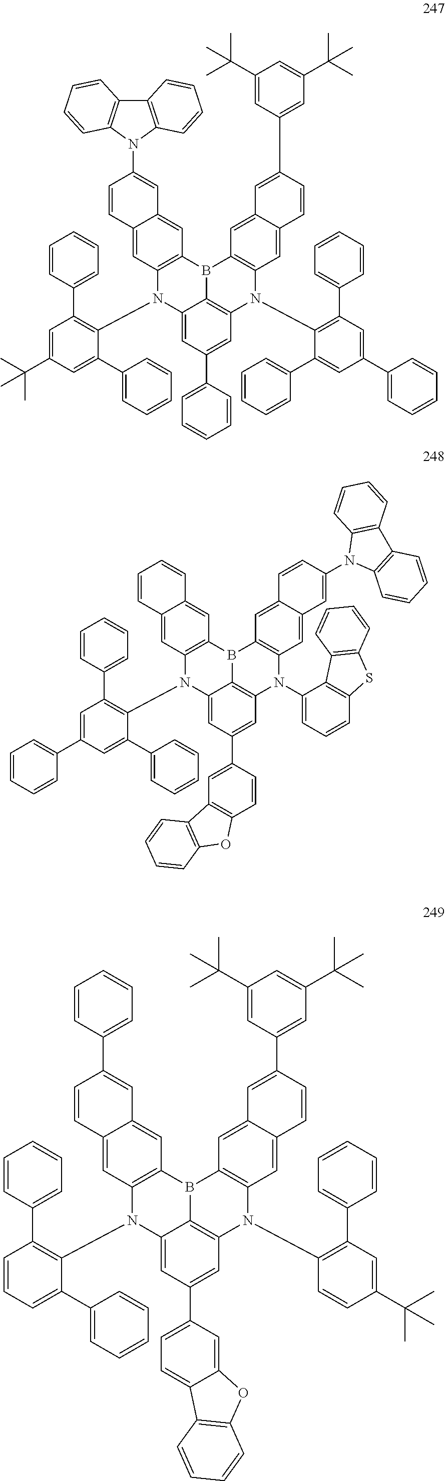

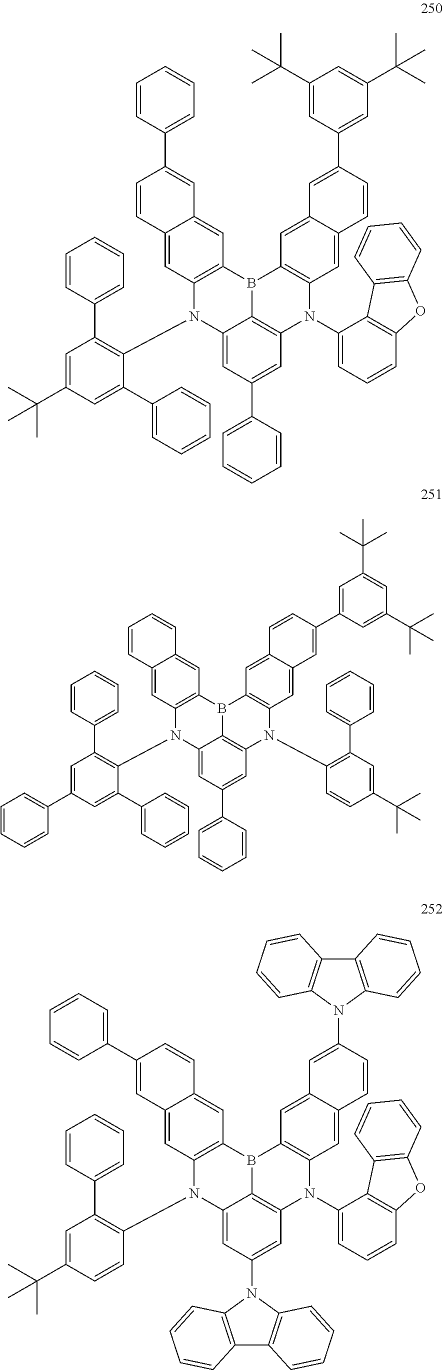

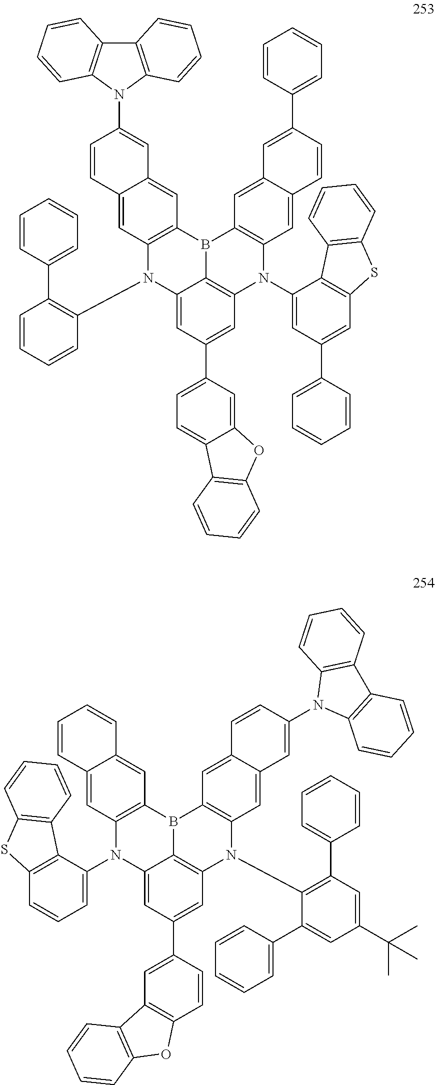 [SMILES: c1ccc(-c2ccc3cc4c(cc3c2)B2c3cc5cc(-n6c7ccccc7c7ccccc76)ccc5cc3N(c3ccccc3-c3ccccc3)c3cc(-c5ccc6c(c5)oc5ccccc56)cc(c32)N4c2cc(-c3ccccc3)cc3sc4ccccc4c23)cc1 ; CC(C)(C)c1cc(-c2ccccc2)c(N2c3cc4cc(-n5c6ccccc6c6ccccc65)ccc4cc3B3c4cc5ccccc5cc4N(c4cccc5sc6ccccc6c45)c4cc(-c5ccc6oc7ccccc7c6c5)cc2c43)c(-c2ccccc2)c1]

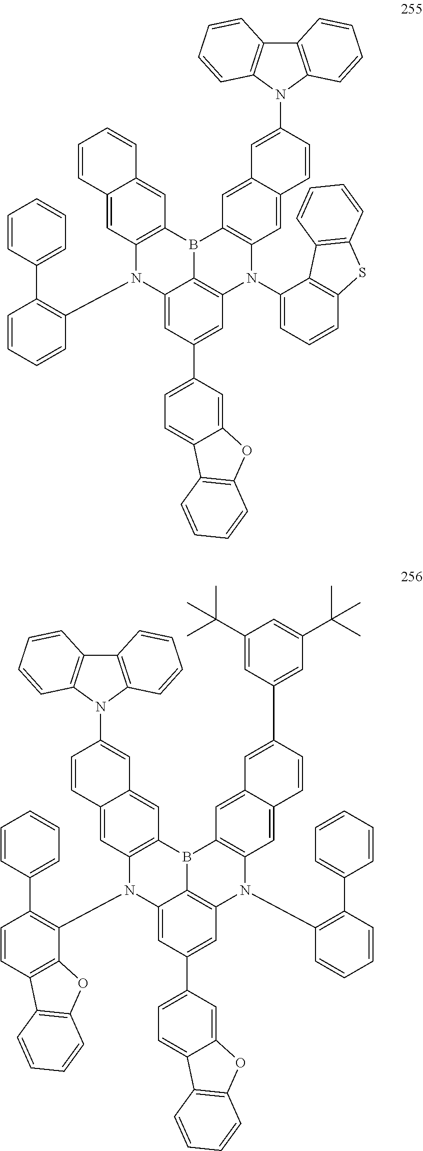 [SMILES: c1ccc(-c2ccccc2N2c3cc4ccccc4cc3B3c4cc5cc(-n6c7ccccc7c7ccccc76)ccc5cc4N(c4cccc5sc6ccccc6c45)c4cc(-c5ccc6c(c5)oc5ccccc56)cc2c43)cc1 ; CC(C)(C)c1cc(-c2ccc3cc4c(cc3c2)B2c3cc5cc(-n6c7ccccc7c7ccccc76)ccc5cc3N(c3c(-c5ccccc5)ccc5c3oc3ccccc35)c3cc(-c5ccc6c(c5)oc5ccccc56)cc(c32)N4c2ccccc2-c2ccccc2)cc(C(C)(C)C)c1]

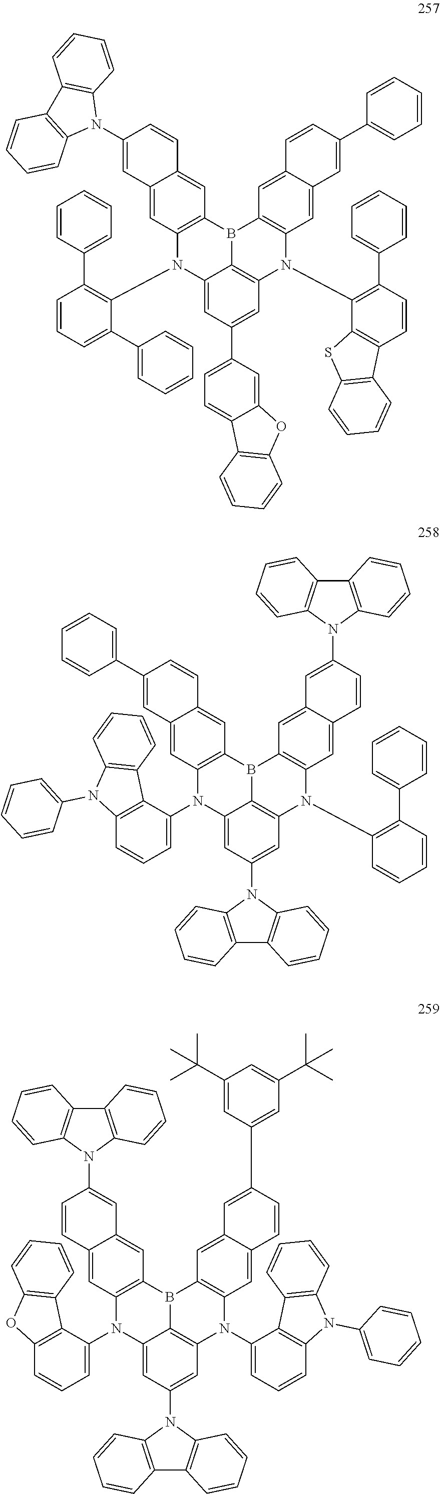 [SMILES: c1ccc(-c2ccc3cc4c(cc3c2)N(c2c(-c3ccccc3)ccc3c2sc2ccccc23)c2cc(-c3ccc5c(c3)oc3ccccc35)cc3c2B4c2cc4ccc(-n5c6ccccc6c6ccccc65)cc4cc2N3c2c(-c3ccccc3)cccc2-c2ccccc2)cc1 ; c1ccc(-c2ccc3cc4c(cc3c2)N(c2cccc3c2c2ccccc2n3-c2ccccc2)c2cc(-n3c5ccccc5c5ccccc53)cc3c2B4c2cc4cc(-n5c6ccccc6c6ccccc65)ccc4cc2N3c2ccccc2-c2ccccc2)cc1 ; CC(C)(C)c1cc(-c2ccc3cc4c(cc3c2)B2c3cc5cc(-n6c7ccccc7c7ccccc76)ccc5cc3N(c3cccc5oc6ccccc6c35)c3cc(-n5c6ccccc6c6ccccc65)cc(c32)N4c2cccc3c2c2ccccc2n3-c2ccccc2)cc(C(C)(C)C)c1]

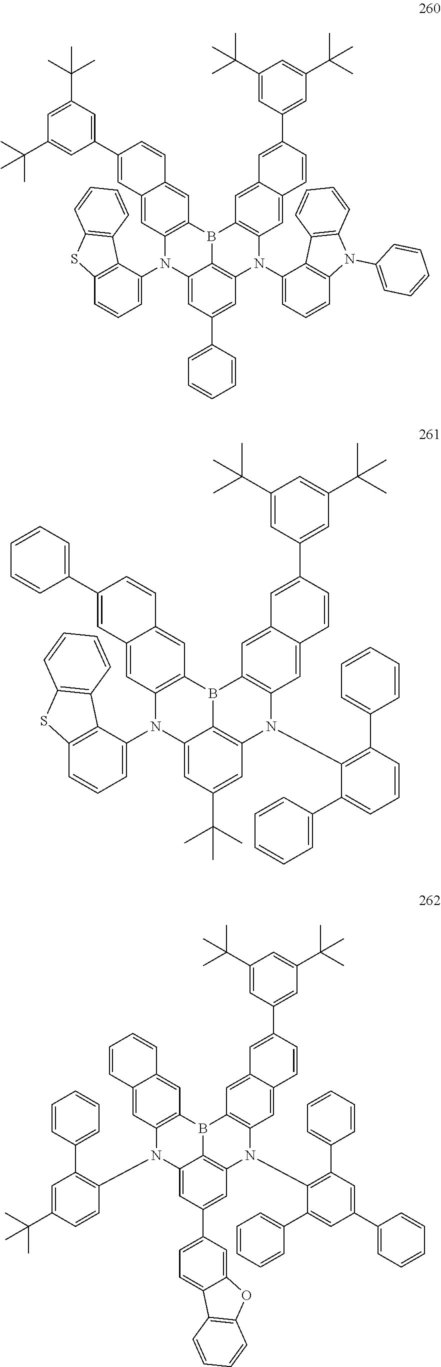 [SMILES: CC(C)(C)c1cc(-c2ccc3cc4c(cc3c2)B2c3cc5ccc(-c6cc(C(C)(C)C)cc(C(C)(C)C)c6)cc5cc3N(c3cccc5sc6ccccc6c35)c3cc(-c5ccccc5)cc(c32)N4c2cccc3c2c2ccccc2n3-c2ccccc2)cc(C(C)(C)C)c1 ; CC(C)(C)c1cc(-c2ccc3cc4c(cc3c2)B2c3cc5ccc(-c6ccccc6)cc5cc3N(c3cccc5sc6ccccc6c35)c3cc(C(C)(C)C)cc(c32)N4c2c(-c3ccccc3)cccc2-c2ccccc2)cc(C(C)(C)C)c1 ; CC(C)(C)c1cc(-c2ccc3cc4c(cc3c2)B2c3cc5ccccc5cc3N(c3ccc(C(C)(C)C)cc3-c3ccccc3)c3cc(-c5ccc6c(c5)oc5ccccc56)cc(c32)N4c2c(-c3ccccc3)cc(-c3ccccc3)cc2-c2ccccc2)cc(C(C)(C)C)c1]

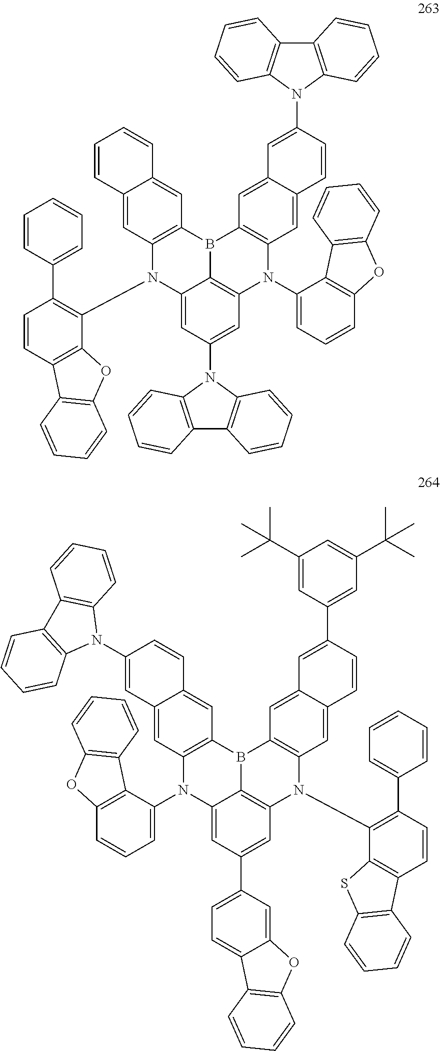 [SMILES: c1ccc(-c2ccc3c(oc4ccccc43)c2N2c3cc4ccccc4cc3B3c4cc5cc(-n6c7ccccc7c7ccccc76)ccc5cc4N(c4cccc5oc6ccccc6c45)c4cc(-n5c6ccccc6c6ccccc65)cc2c43)cc1 ; CC(C)(C)c1cc(-c2ccc3cc4c(cc3c2)B2c3cc5ccc(-n6c7ccccc7c7ccccc76)cc5cc3N(c3cccc5oc6ccccc6c35)c3cc(-c5ccc6c(c5)oc5ccccc56)cc(c32)N4c2c(-c3ccccc3)ccc3c2sc2ccccc23)cc(C(C)(C)C)c1]

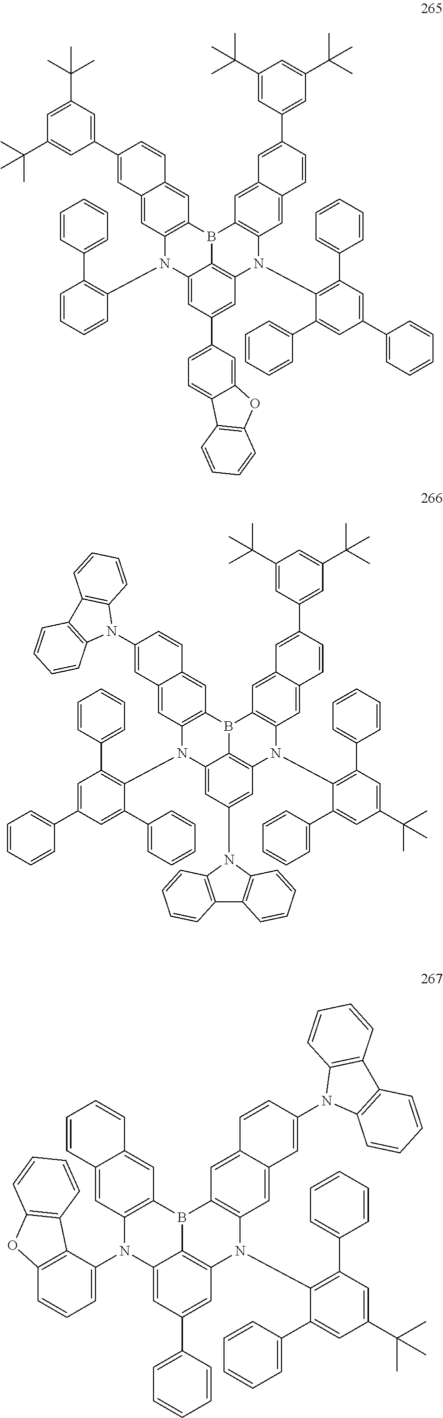

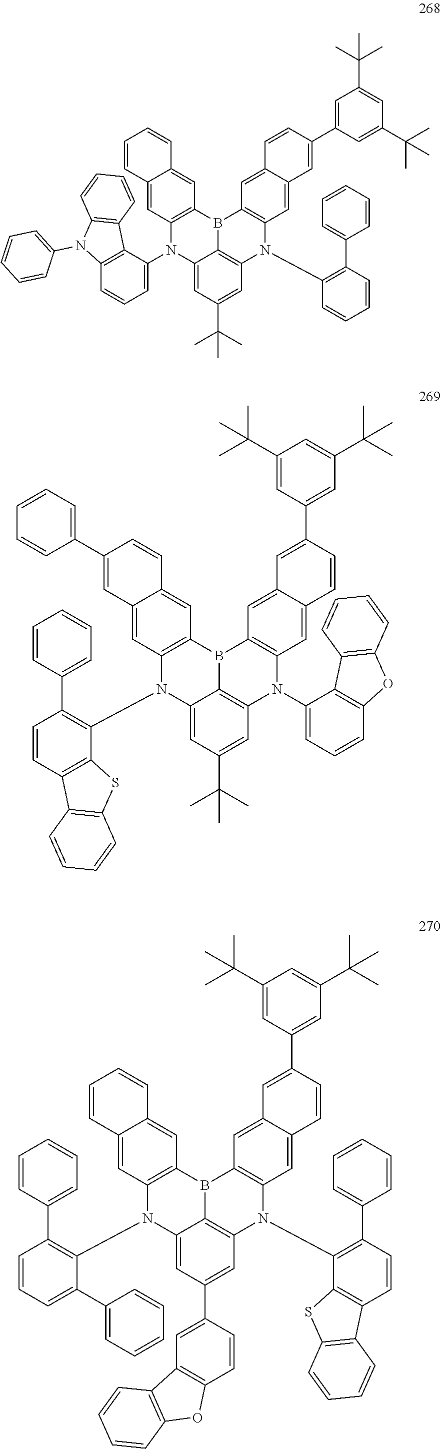 [SMILES: CC(C)(C)c1cc(-c2ccc3cc4c(cc3c2)N(c2ccccc2-c2ccccc2)c2cc(C(C)(C)C)cc3c2B4c2cc4ccccc4cc2N3c2cccc3c2c2ccccc2n3-c2ccccc2)cc(C(C)(C)C)c1 ; CC(C)(C)c1cc(-c2ccc3cc4c(cc3c2)B2c3cc5ccc(-c6ccccc6)cc5cc3N(c3c(-c5ccccc5)ccc5c3sc3ccccc35)c3cc(C(C)(C)C)cc(c32)N4c2cccc3oc4ccccc4c23)cc(C(C)(C)C)c1 ; CC(C)(C)c1cc(-c2ccc3cc4c(cc3c2)B2c3cc5ccccc5cc3N(c3c(-c5ccccc5)cccc3-c3ccccc3)c3cc(-c5ccc6oc7ccccc7c6c5)cc(c32)N4c2c(-c3ccccc3)ccc3c2sc2ccccc23)cc(C(C)(C)C)c1]

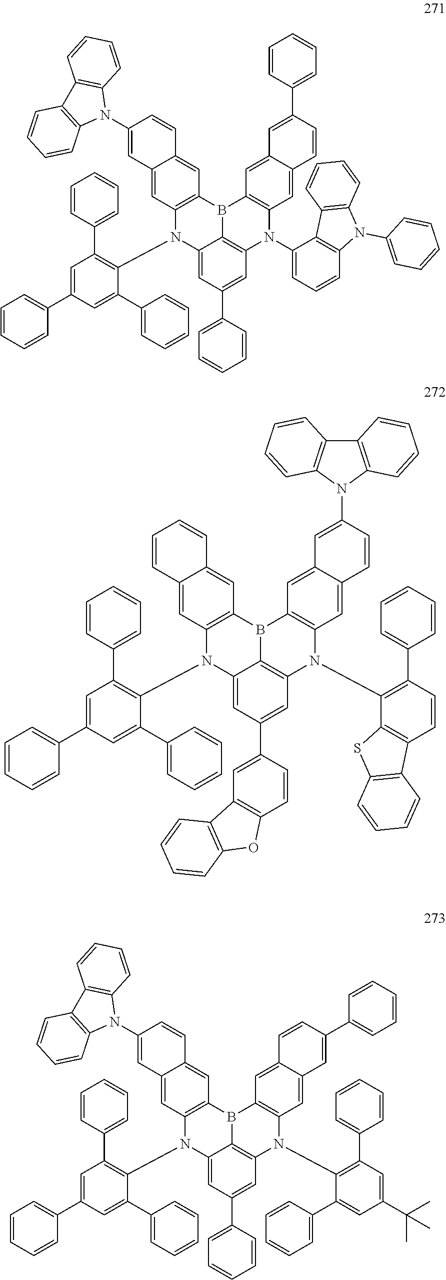 [SMILES: c1ccc(-c2cc(-c3ccccc3)c(N3c4cc5cc(-n6c7ccccc7c7ccccc76)ccc5cc4B4c5cc6cc(-c7ccccc7)ccc6cc5N(c5cccc6c5c5ccccc5n6-c5ccccc5)c5cc(-c6ccccc6)cc3c54)c(-c3ccccc3)c2)cc1 ; c1ccc(-c2cc(-c3ccccc3)c(N3c4cc5ccccc5cc4B4c5cc6cc(-n7c8ccccc8c8ccccc87)ccc6cc5N(c5c(-c6ccccc6)ccc6c5sc5ccccc56)c5cc(-c6ccc7oc8ccccc8c7c6)cc3c54)c(-c3ccccc3)c2)cc1 ; CC(C)(C)c1cc(-c2ccccc2)c(N2c3cc4cc(-c5ccccc5)ccc4cc3B3c4cc5ccc(-n6c7ccccc7c7ccccc76)cc5cc4N(c4c(-c5ccccc5)cc(-c5ccccc5)cc4-c4ccccc4)c4cc(-c5ccccc5)cc2c43)c(-c2ccccc2)c1]

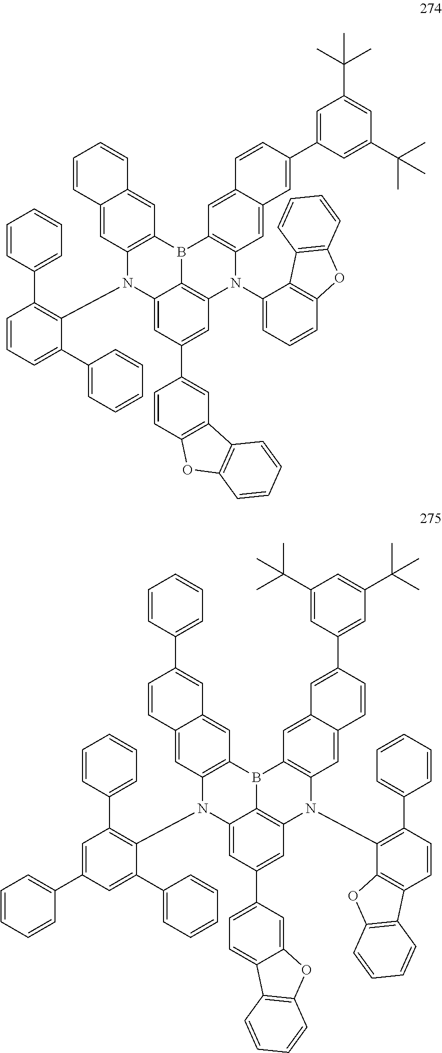 [SMILES: CC(C)(C)c1cc(-c2ccc3cc4c(cc3c2)N(c2cccc3oc5ccccc5c23)c2cc(-c3ccc5oc6ccccc6c5c3)cc3c2B4c2cc4ccccc4cc2N3c2c(-c3ccccc3)cccc2-c2ccccc2)cc(C(C)(C)C)c1 ; CC(C)(C)c1cc(-c2ccc3cc4c(cc3c2)B2c3cc5cc(-c6ccccc6)ccc5cc3N(c3c(-c5ccccc5)cc(-c5ccccc5)cc3-c3ccccc3)c3cc(-c5ccc6c(c5)oc5ccccc56)cc(c32)N4c2c(-c3ccccc3)ccc3c2oc2ccccc23)cc(C(C)(C)C)c1]

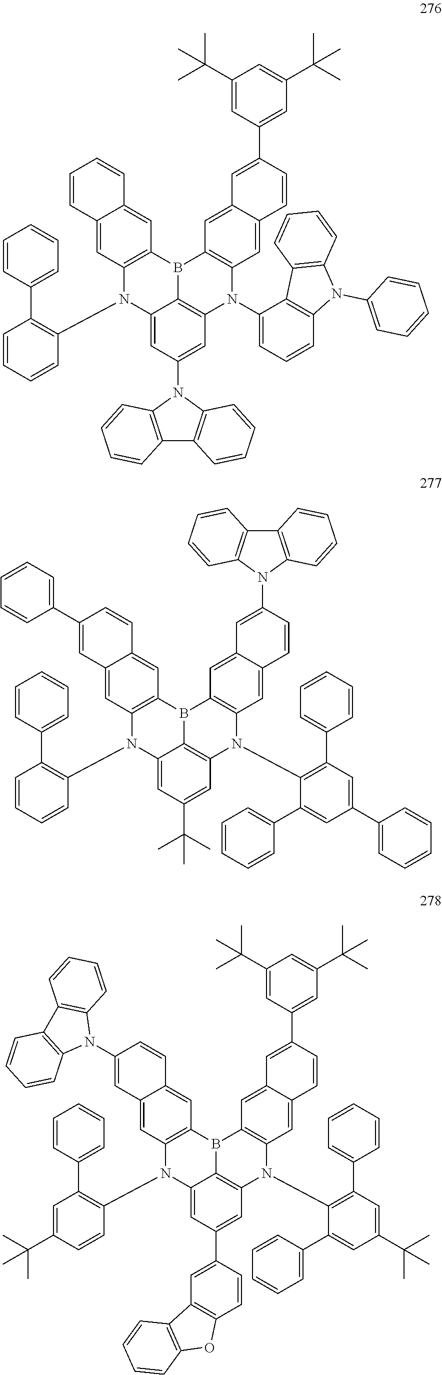 [SMILES: CC(C)(C)c1cc(-c2ccc3cc4c(cc3c2)B2c3cc5ccccc5cc3N(c3ccccc3-c3ccccc3)c3cc(-n5c6ccccc6c6ccccc65)cc(c32)N4c2cccc3c2c2ccccc2n3-c2ccccc2)cc(C(C)(C)C)c1 ; CC(C)(C)c1cc2c3c(c1)N(c1c(-c4ccccc4)cc(-c4ccccc4)cc1-c1ccccc1)c1cc4ccc(-n5c6ccccc6c6ccccc65)cc4cc1B3c1cc3ccc(-c4ccccc4)cc3cc1N2c1ccccc1-c1ccccc1 ; CC(C)(C)c1cc(-c2ccc3cc4c(cc3c2)B2c3cc5ccc(-n6c7ccccc7c7ccccc76)cc5cc3N(c3ccc(C(C)(C)C)cc3-c3ccccc3)c3cc(-c5ccc6oc7ccccc7c6c5)cc(c32)N4c2c(-c3ccccc3)cc(C(C)(C)C)cc2-c2ccccc2)cc(C(C)(C)C)c1]

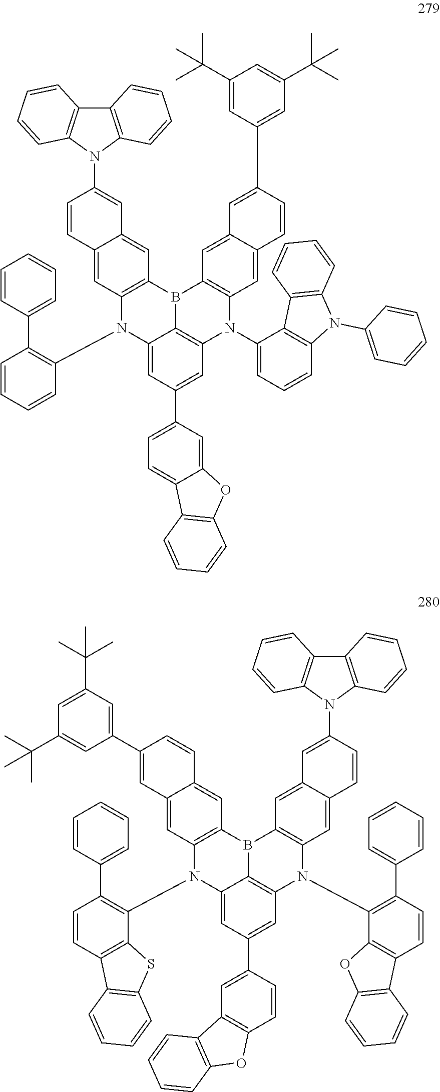 [SMILES: CC(C)(C)c1cc(-c2ccc3cc4c(cc3c2)B2c3cc5cc(-n6c7ccccc7c7ccccc76)ccc5cc3N(c3ccccc3-c3ccccc3)c3cc(-c5ccc6c(c5)oc5ccccc56)cc(c32)N4c2cccc3c2c2ccccc2n3-c2ccccc2)cc(C(C)(C)C)c1 ; CC(C)(C)c1cc(-c2ccc3cc4c(cc3c2)N(c2c(-c3ccccc3)ccc3c2sc2ccccc23)c2cc(-c3ccc5oc6ccccc6c5c3)cc3c2B4c2cc4cc(-n5c6ccccc6c6ccccc65)ccc4cc2N3c2c(-c3ccccc3)ccc3c2oc2ccccc23)cc(C(C)(C)C)c1]

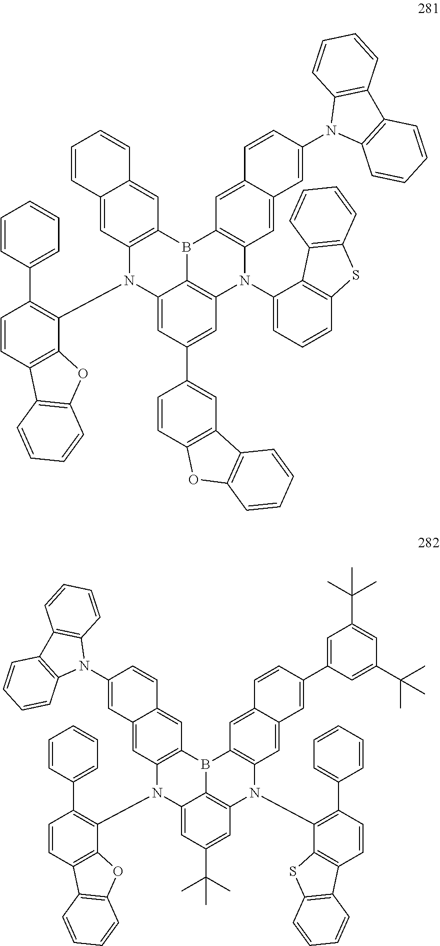 [SMILES: c1ccc(-c2ccc3c(oc4ccccc43)c2N2c3cc4ccccc4cc3B3c4cc5ccc(-n6c7ccccc7c7ccccc76)cc5cc4N(c4cccc5sc6ccccc6c45)c4cc(-c5ccc6oc7ccccc7c6c5)cc2c43)cc1 ; CC(C)(C)c1cc(-c2ccc3cc4c(cc3c2)N(c2c(-c3ccccc3)ccc3c2sc2ccccc23)c2cc(C(C)(C)C)cc3c2B4c2cc4ccc(-n5c6ccccc6c6ccccc65)cc4cc2N3c2c(-c3ccccc3)ccc3c2oc2ccccc23)cc(C(C)(C)C)c1]

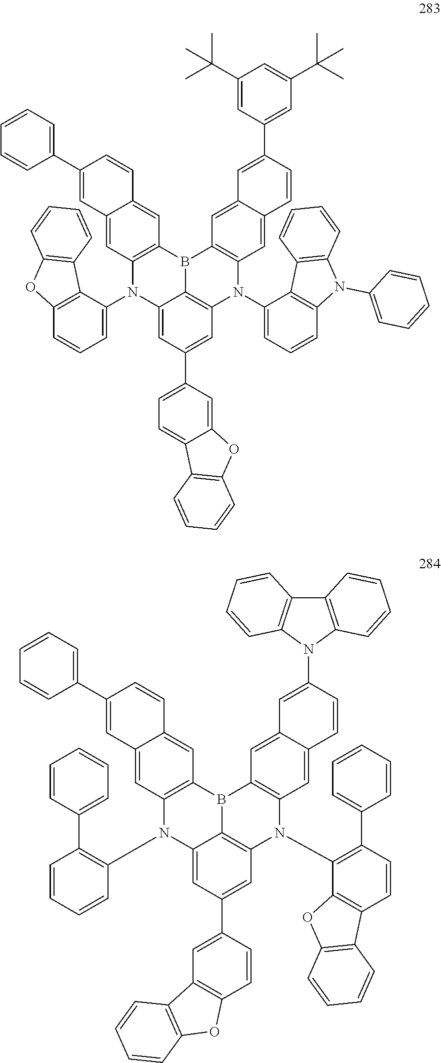 [SMILES: CC(C)(C)c1cc(-c2ccc3cc4c(cc3c2)B2c3cc5ccc(-c6ccccc6)cc5cc3N(c3cccc5oc6ccccc6c35)c3cc(-c5ccc6c(c5)oc5ccccc56)cc(c32)N4c2cccc3c2c2ccccc2n3-c2ccccc2)cc(C(C)(C)C)c1 ; c1ccc(-c2ccc3cc4c(cc3c2)N(c2ccccc2-c2ccccc2)c2cc(-c3ccc5oc6ccccc6c5c3)cc3c2B4c2cc4cc(-n5c6ccccc6c6ccccc65)ccc4cc2N3c2c(-c3ccccc3)ccc3c2oc2ccccc23)cc1]

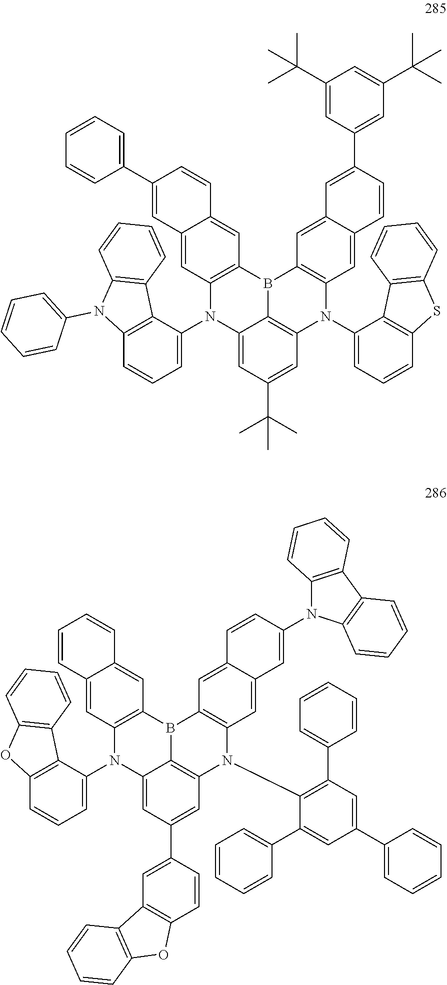 [SMILES: CC(C)(C)c1cc(-c2ccc3cc4c(cc3c2)B2c3cc5ccc(-c6ccccc6)cc5cc3N(c3cccc5c3c3ccccc3n5-c3ccccc3)c3cc(C(C)(C)C)cc(c32)N4c2cccc3sc4ccccc4c23)cc(C(C)(C)C)c1 ; c1ccc(-c2cc(-c3ccccc3)c(N3c4cc5cc(-n6c7ccccc7c7ccccc76)ccc5cc4B4c5cc6ccccc6cc5N(c5cccc6oc7ccccc7c56)c5cc(-c6ccc7oc8ccccc8c7c6)cc3c54)c(-c3ccccc3)c2)cc1]

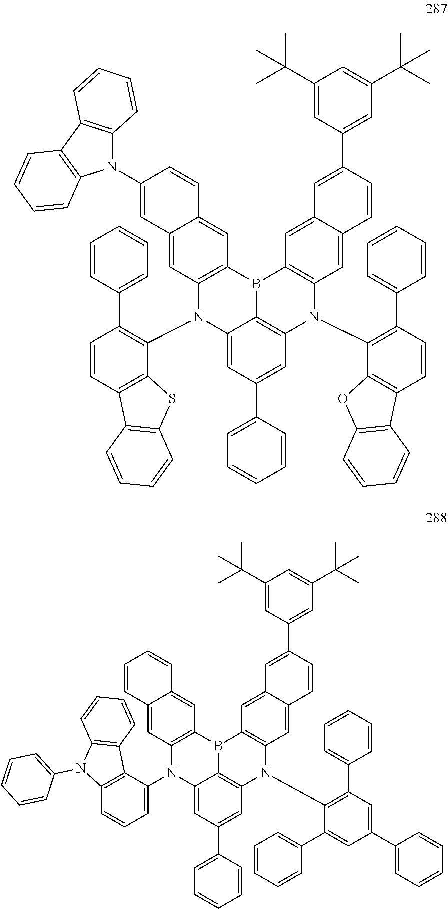 [SMILES: CC(C)(C)c1cc(-c2ccc3cc4c(cc3c2)B2c3cc5ccc(-n6c7ccccc7c7ccccc76)cc5cc3N(c3c(-c5ccccc5)ccc5c3sc3ccccc35)c3cc(-c5ccccc5)cc(c32)N4c2c(-c3ccccc3)ccc3c2oc2ccccc23)cc(C(C)(C)C)c1 ; CC(C)(C)c1cc(-c2ccc3cc4c(cc3c2)B2c3cc5ccccc5cc3N(c3cccc5c3c3ccccc3n5-c3ccccc3)c3cc(-c5ccccc5)cc(c32)N4c2c(-c3ccccc3)cc(-c3ccccc3)cc2-c2ccccc2)cc(C(C)(C)C)c1]

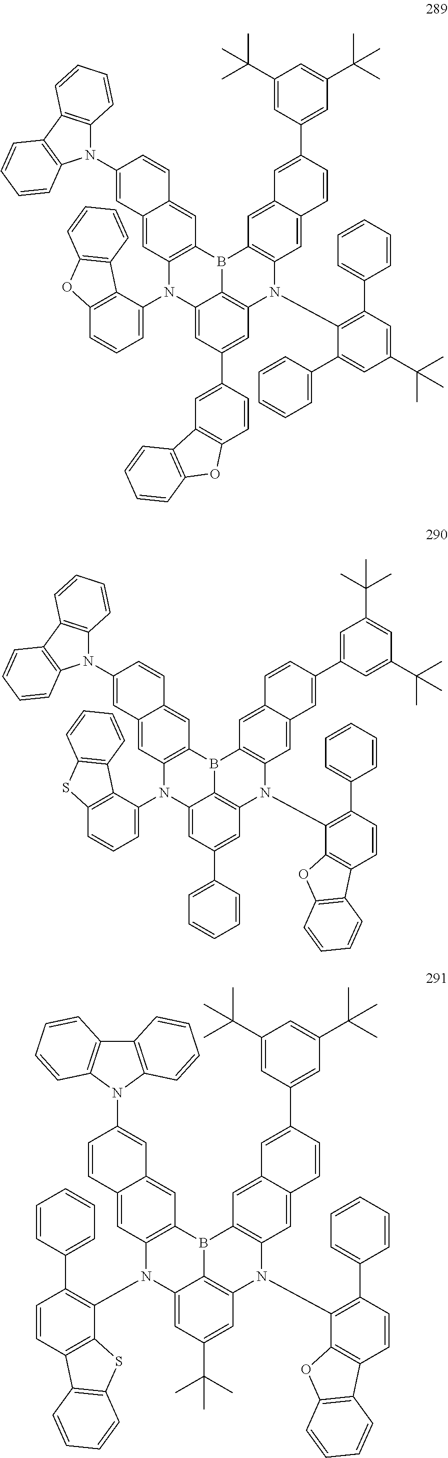

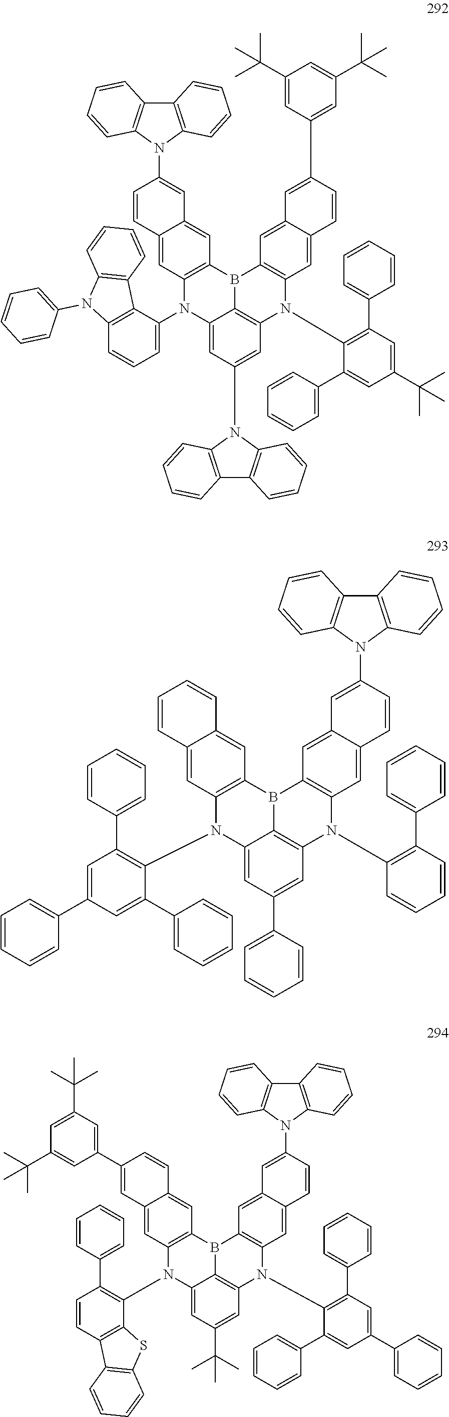

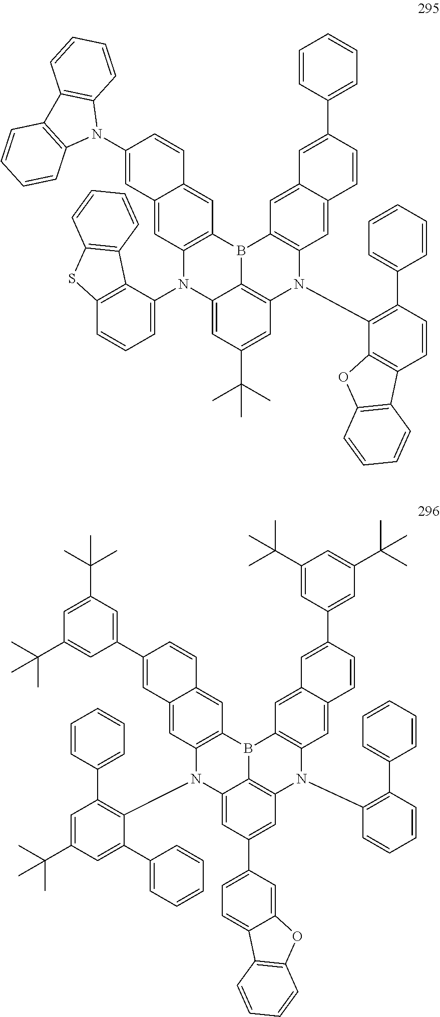 [SMILES: CC(C)(C)c1cc2c3c(c1)N(c1cccc4sc5ccccc5c14)c1cc4cc(-n5c6ccccc6c6ccccc65)ccc4cc1B3c1cc3cc(-c4ccccc4)ccc3cc1N2c1c(-c2ccccc2)ccc2c1oc1ccccc12 ; CC(C)(C)c1cc(-c2ccc3cc4c(cc3c2)B2c3cc5ccc(-c6cc(C(C)(C)C)cc(C(C)(C)C)c6)cc5cc3N(c3c(-c5ccccc5)cc(C(C)(C)C)cc3-c3ccccc3)c3cc(-c5ccc6c(c5)oc5ccccc56)cc(c32)N4c2ccccc2-c2ccccc2)cc(C(C)(C)C)c1]

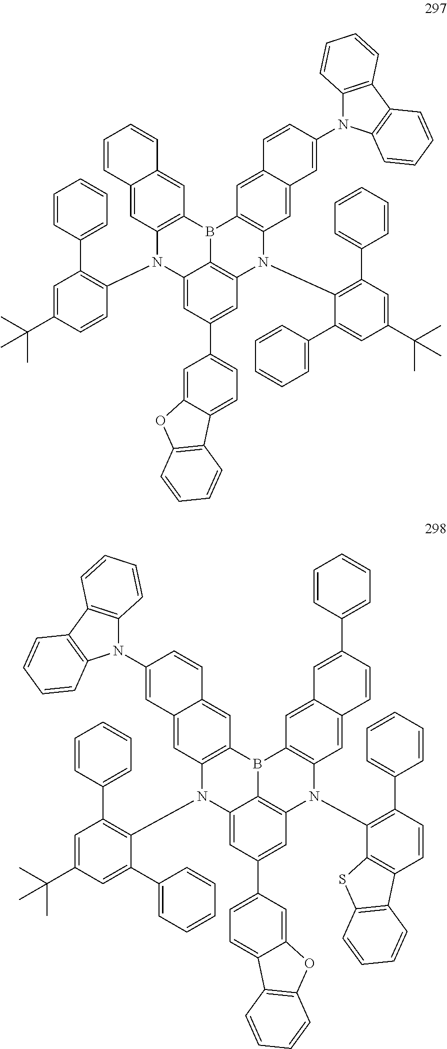

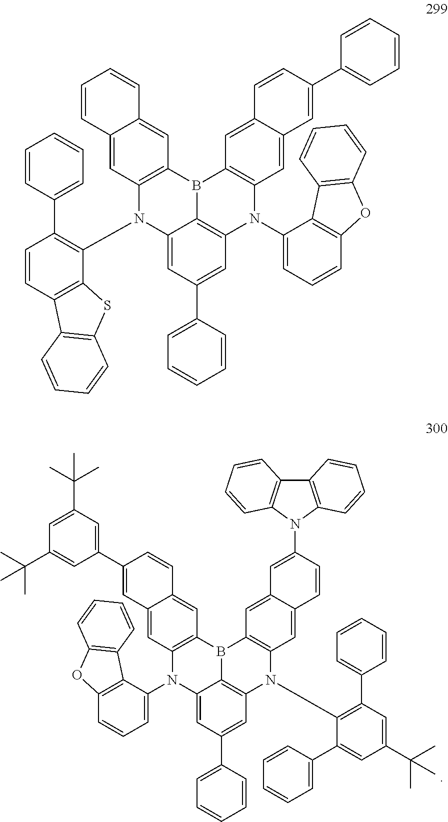 [SMILES: c1ccc(-c2cc3c4c(c2)N(c2cccc5oc6ccccc6c25)c2cc5cc(-c6ccccc6)ccc5cc2B4c2cc4ccccc4cc2N3c2c(-c3ccccc3)ccc3c2sc2ccccc23)cc1 ; CC(C)(C)c1cc(-c2ccc3cc4c(cc3c2)N(c2cccc3oc5ccccc5c23)c2cc(-c3ccccc3)cc3c2B4c2cc4cc(-n5c6ccccc6c6ccccc65)ccc4cc2N3c2c(-c3ccccc3)cc(C(C)(C)C)cc2-c2ccccc2)cc(C(C)(C)C)c1]

19. An electronic apparatus comprising:
a display device that includes a display panel, the display device displaying an image, wherein
the display panel comprises:
a circuit layer disposed on a base layer; and
a display element layer disposed on the circuit layer and including a light-emitting element,
the light-emitting element comprises:
a first electrode;
a second electrode disposed on the first electrode; and
an emission layer disposed between the first electrode and the second electrode, and
the emission layer comprises a polycyclic compound represented by Formula 1: 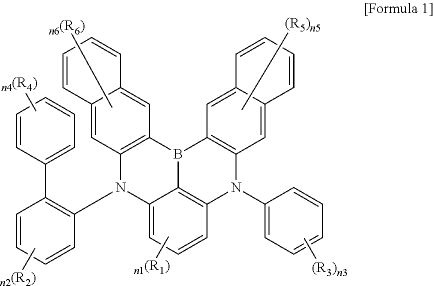
wherein in Formula 1,
R₁ to R₆ are each independently a hydrogen atom, a deuterium atom, a substituted or unsubstituted amine group, a substituted or unsubstituted oxy group, a substituted or unsubstituted thio group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, or bonded to an adjacent group to form a ring,
n1 is an integer from 0 to 3,
n2 is an integer from 0 to 4,
n3 and n4 are each independently an integer from 0 to 5, and
n5 and n6 are each independently an integer from 0 to 6.

20. The electronic apparatus of claim 19, further comprising:
at least one of a polarizing layer, a color filter layer, and an optical control layer.

21. The electronic apparatus of claim 20, wherein the optical control layer comprises a quantum dot.
